(19) United States
(12) Patent Application Publication
(10) Pub. No.: US 2023/0200233 A1
(43) Pub. Date: Jun. 22, 2023

(54) COMPOSITION, ELECTRONIC COMPOMENT AND ELECTRONIC DEVICE CONTAINING THE COMPOSITION

(71) Applicant: Shaanxi Lighte Optoelectronics Material Co., Ltd., Xi'an (CN)

(72) Inventors: Tiantian MA, Xi'an (CN); Kongyan ZHANG, Xi'an (CN); Peng NAN, Xi'an (CN)

(21) Appl. No.: 18/011,723

(22) PCT Filed: Aug. 11, 2021
(86) PCT No.: PCT/CN2021/112152

§ 371 Date: Dec. 20, 2022

(30) Foreign Application Priority Data
Apr. 13, 2021 (CN) 202110397589.3
Jun. 11, 2021 (CN) 202110657299.8

(51) Int. Cl. H10K 85/60; H10K 50/11

(52) U.S. Cl. CPC H10K 85/6572; H10K 85/6574; H10K 85/6576; H10K 85/652; H10K 85/657; H10K 85/654; H10K 85/615; H10K 50/11

(57) ABSTRACT

The present disclosure provides a composition for an organic optoelectronic device, an electronic component comprising the same, and an electronic device, belonging to the technical field of organic electroluminescence. The composition provided by the present disclosure includes a first compound and a second compound; and the first compound is represented by a Formula I and the second compound is represented by a Formula II:

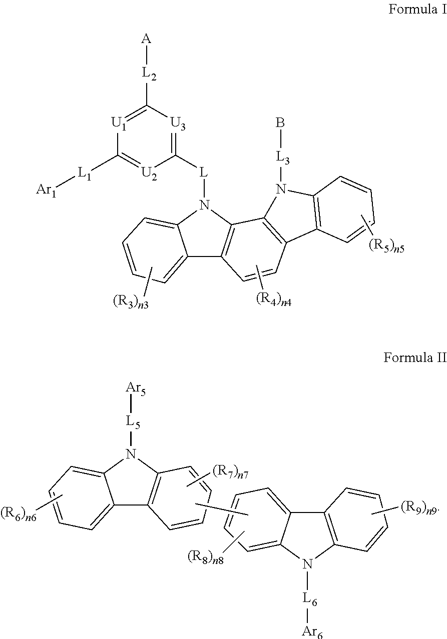

### CROSS REFERENCE TO RELATED APPLICATIONS

The present application claims the priority of Chinese Patent Application No. CN202110397589.3, filed on Apr. 13, 2021, and Chinese Patent Application No. CN202110657299.8, filed on Jun. 11, 2021, the contents of which are incorporated herein by reference in their entirety as part of the present application.

### FIELD

The present disclosure relates to the technical field of organic electroluminescence, in particular to a composition, an electronic component and an electronic device comprising thereof.

### BACKGROUND

In recent years, organic electroluminescent devices (OLEDs) have received extensive attention as a next-generation flat panel display technology. Compared with liquid crystal displays (LCDs), OLEDs have wider color gamut, higher contrast ratio, wider temperature adaptation range, and faster response time, and can realize flexible display, etc.

An organic electroluminescent device (OLED) generally includes an anode, a cathode and an organic layer between the two electrodes. The organic layer may include a hole injection layer, a hole transport layer, a hole auxiliary layer, an electron blocking layer, a light-emitting layer (containing a host and a dopant material), a hole blocking layer, an electron transport layer, an electron injection layer, and the like. If an electric voltage is applied to the organic electroluminescent device, holes and electrons are injected into the light-emitting layer from the anode and the cathode, respectively. The injected holes and electrons are then recombined in the light-emitting layer to form excitons. The excitons are in an excited state and release energy outwards, which in turn causes the light-emitting layer to emit light outwards.

According to the statistical rule of electron spin, singlet excitons and triplet excitons are generated in a ratio of 25%:75%. Furthermore, according to the classification of the light emitting principle, fluorescence emission is light emission using the singlet excitons, so 25% is a limit of the internal quantum efficiency of an organic electroluminescent element. While phosphorescence emission is light emission using the triplet excitons, and thus, theoretically the internal quantum efficiency can reach 100% (i.e., using all singlet and triplet excitons) when intersystem crossing is effectively performed by the triplet excitons. For the organic electroluminescent device, elements with optimal performance are designed corresponding to fluorescent and phosphorescent light-emitting mechanisms. Especially for a phosphorescent organic electroluminescent device, known from its light-emitting properties, a high-performance element is not obtained when simply misappropriating a fluorescent element technology. However, with the acceleration of an industrialization process, OLED material and device designs with low power consumption, high efficiency and long service life have attracted more and more attention. In the more common OLED device structures at present, by taking a green light device as an example, a light-emitting layer (EML) of a green light OLED device is usually made of a single host material doped with dyes. Since the mobility of hole-type (P) materials is generally higher than that of electron-type (N) materials, green light host materials are typically single N-type materials, the use of single N-type green light host materials tends to have low hole mobility and even a strong hole blocking effect, thus leading to insufficient recombination of electrons and holes in the light-emitting layer, and low energy utilization, eventually leading to low current efficiency and severely affecting the service life of the device.

In addition, for phosphorescent emission, the energy gap of a compound used in a light-emitting layer of a phosphorescent device must be large. This is due to the fact that the value of the singlet energy of a certain compound is typically greater than the value of the triplet energy of this compound. Thus, in order to effectively close the triplet energy in the light-emitting layer of the phosphorescent device within an element, when an electron transport layer and a hole transport layer which are adjacent to the light-emitting layer are arranged, compounds having a larger triplet energy than a phosphorescent light-emitting material in an electron transport layer and a hole transport layer have to be used.

Currently, there is still a problem of poor performance during use of an organic electroluminescent device, for example, there are problems such as too high driving voltage, too low luminous efficiency, or short service life, which affect the field of use of the organic electroluminescent device, and thus, there is still a need for further investigation into this field to improve the performance of the organic electroluminescent device.

### SUMMARY

The present disclosure aims to overcome the above-mentioned deficiencies in the prior art and provide a composition, an electronic component comprising the same, and an electronic device. The luminous efficiency can be increased, and the service life of the device can be prolonged.

In order to achieve the above-mentioned inventive purpose, the present disclosure adopts the following technical solutions:

according to a first aspect of the present disclosure, there is provided a composition for an organic optoelectronic device, and the composition comprises a first compound and a second compound;

Based on the total weight of the composition, the mass percentage of the first compound is 1% to 99%, and the mass percentage of the second compound is 1% to 99%;

the first compound is represented by a Formula I:

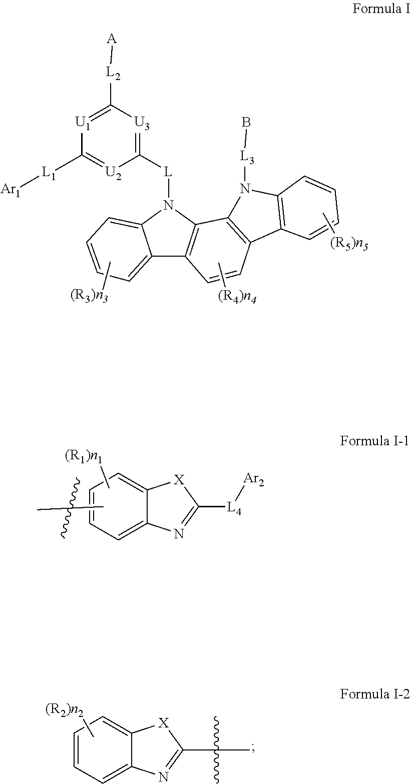

wherein

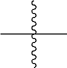

represents a chemical bond, A and B are the same or different, and are respectively and independently selected from substituted or unsubstituted aryl with 6 to 30 carbon atoms, substituted or unsubstituted heteroaryl with 3 to 30 carbon atoms, a group represented by a Formula I-1 or a group represented by a Formula I-2, and at least one of A and B is selected from the group represented by the Formula I-1 or the group represented by the Formula I-2;

U₁, U₂ and U₃ are the same or different, and are respectively and independently selected from N or C(R), and at least one of U₁, U₂ and U₃ is N;

each R, R₁, R₂, R₃, R₄, and R₅ are respectively and independently selected from hydrogen, deuterium, a halogen group, cyano, aryl with 6 to 12 carbon atoms, heteroaryl with 5 to 12 carbon atoms, alkyl with 1 to 5 carbon atoms, haloalkyl with 1 to 5 carbon atoms, and cycloalkyl with 3 to 10 carbon atoms;

n₁ represents the number of a substituent R₁, n₁ is selected from 1, 2 or 3, and when n₁ is greater than 1, any two R₁s are the same or different;

n₂ represents the number of a substituent R₂, n₂ is selected from 1, 2, 3 or 4, and when n₂ is greater than 1, any two R₂s are the same or different, and optionally, any two adjacent R₂s form a ring;

n₃ represents the number of a substituent R₃, n₃ is selected from 1, 2, 3 or 4, and when n₃ is greater than 1, any two R₃s are the same or different;

n₄ represents the number of a substituent R₄, n₄ is selected from 1 or 2, and when n₄ is 2, any two R₄s are the same or different;

n₅ represents the number of a substituent R₅, n₅ is selected from 1, 2, 3 or 4, and when n₅ is greater than 1, any two R₅s are the same or different;

X is selected from S or O;

L, L₁, L₂, L₃ and L₄ are the same or different, and are respectively and independently selected from a single bond, substituted or unsubstituted arylene with 6 to 30 carbon atoms, and substituted or unsubstituted heteroarylene with 3 to 30 carbon atoms;

Ar₁ and Ar₂ are the same or different, and are respectively and independently selected from substituted or unsubstituted aryl with 6 to 30 carbon atoms, and substituted or unsubstituted heteroaryl with 3 to 30 carbon atoms;

substituents in the A, B, L, L₁, L₂, L₃, L₄, Ar₁ and Ar₂ are the same or different, and are respectively and independently selected from deuterium, a halogen group, cyano, heteroaryl with 3 to 20 carbon atoms, aryl with 6 to 20 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, or alkoxy with 1 to 10 carbon atoms;

optionally, in Ar₁ and Ar₂, any two adjacent substituents form a ring;

the second compound is represented by a Formula II:

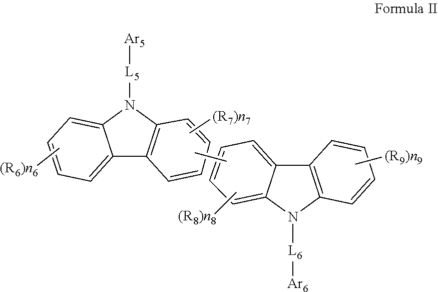

wherein

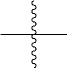

represents a chemical bond,

each R₆, R₇, R₈, and R₉ are respectively and independently selected from hydrogen, deuterium, a halogen group, cyano, aryl with 6 to 25 carbon atoms, heteroaryl with 5 to 25 carbon atoms, alkyl with 1 to 10 carbon atoms, haloalkyl with 1 to 10 carbon atoms, and cycloalkyl with 3 to 10 carbon atoms;

n₆ represents the number of a substituent R₆, n₆ is selected from 1, 2, 3 or 4, and when n₆ is greater than 1, any two R₆s are the same or different;

n₇ represents the number of a substituent R₇, n₇ is selected from 1, 2 or 3, and when n₇ is greater than 1, any two R₇s are the same or different;

n₈ represents the number of a substituent R₈, n₈ is selected from 1, 2 or 3, and when n₈ is greater than 1, any two R₈s are the same or different;

n₉ represents the number of a substituent R₉, n₉ is selected from 1, 2, 3 or 4, and when n₉ is greater than 1, any two R₉s are the same or different;

L₅ and L₆ are the same or different, and are respectively and independently selected from a single bond, substituted or unsubstituted arylene with 6 to 30 carbon atoms, and substituted or unsubstituted heteroarylene with 3 to 30 carbon atoms;

Ar₅ and Ar₆ are the same or different, and are respectively and independently selected from substituted or unsubstituted aryl with 6 to 30 carbon atoms, and substituted or unsubstituted heteroaryl with 3 to 30 carbon atoms;

substituents in L₅, L₆, Ar₅ and Ar₆ are the same or different, and are respectively and independently selected from deuterium, a halogen group, cyano, heteroaryl with 3 to 20 carbon atoms, aryl with 6 to 20 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, or alkoxy with 1 to 10 carbon atoms;

optionally, in Ar₅ and Ar₆, any two adjacent substituents form a ring.

In the present disclosure, GH-N is an electron-type host material and GH-P is a hole-type host material.

The composition provided in the present disclosure includes the first compound and the second compound, the first compound has a bipolar characteristic in which electron characteristics are relatively strong, while the second compound has a bipolar characteristic in which hole characteristics are relatively strong, and thus, the first compound and the second compound can be used together to increase charge mobility and stability, thus significantly improving the luminous efficiency and service life characteristics. Specifically, the first compound includes a nitrogen-containing six-membered ring having high electron transfer properties to stably and efficiently transfer electrons, thus reducing the driving voltage, improving the current efficiency and realizing long service life characteristics of the device; the second compound includes a carbazole structure having a high HOMO energy, which efficiently injects and transfers holes, thus contributing to improving device characteristics; and through the composition including the first compound and the second compound, the adjustment of the electron and hole characteristics within the device stack is ultimately achieved to achieve an optimal balance.

According to a second aspect of the present disclosure, there is provided an electronic component comprising an anode, a cathode, and at least one functional layer between the anode and the cathode, and the functional layer comprises the composition of the first aspect of the present disclosure;

preferably, the functional layer comprises an organic electroluminescent layer, and the organic electroluminescent layer comprises the composition.

According to a third aspect of the present disclosure, there is provided an electronic device, comprising the electronic component of the second aspect of the present disclosure.

It should be understood that the above general description and the following detailed description are only exemplary and explanatory, and are not intended to limit the present disclosure.

### BRIEF DESCRIPTION OF THE DRAWINGS

The accompanying drawings are used to provide a further understanding of the present disclosure, and constitute a part of the description, and together with the following specific embodiments, are used to explain the present disclosure, but do not constitute a limitation to the present disclosure.

In the drawings:

FIG. 1 is a structural schematic diagram of an organic electroluminescent device of the present disclosure.

FIG. 2 is a structural schematic diagram of an electronic device according to one embodiment of the present disclosure.

### DESCRIPTION OF REFERENCE SIGNS

100, anode; 200, cathode; 300, functional layer; 310, hole injection layer; 320, hole transport layer; 321, first hole transport layer; 322, second hole transport layer; 330, organic electroluminescent layer; 340, hole blocking layer; 350, electron transport layer; 360, electron injection layer; and 400, electronic device.

### DETAILED DESCRIPTION

Exemplary embodiments will now be described more fully with reference to the accompanying drawings. However, the exemplary embodiments can be implemented in various forms and should not be construed as limited to the examples set forth here; and on the contrary, these exemplary embodiments are provided so that the present disclosure will be thorough and complete, and the concept of the exemplary embodiments is fully conveyed to those skilled in the art. The described features, structures, or characteristics may be combined in any suitable manner in one or more embodiments. In the following description, many specific details are provided to provide a thorough understanding of the embodiments of the present disclosure.

In the drawings, the thicknesses of regions and layers may be exaggerated for clarity. The same reference signs denote the same or similar structures in the drawings, and thus their detailed description will be omitted.

The present disclosure provides a composition for an organic optoelectronic device, and the composition comprises a first compound and a second compound;

Based on the total weight of the composition, the mass percentage of the first compound is 1% to 99%, and the mass percentage of the second compound is 1% to 99%;

the first compound is represented by a Formula I;

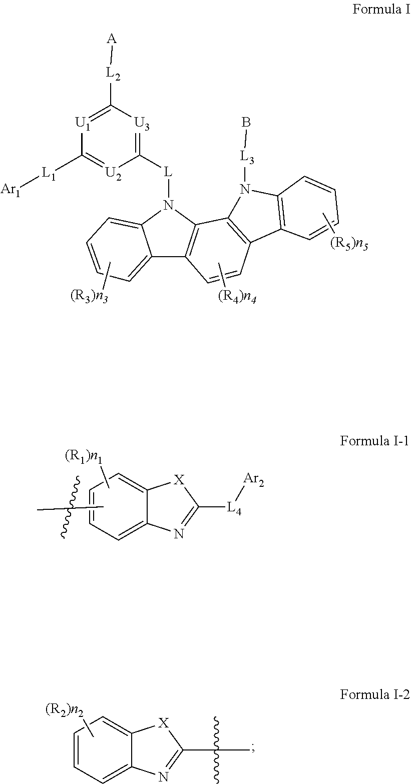

wherein represents a chemical bond, A and B are the same or different, and are respectively and independently selected from substituted or unsubstituted aryl with 6 to 30 carbon atoms, substituted or unsubstituted heteroaryl with 3 to 30 carbon atoms, a group represented by a Formula I-1 or a group represented by a Formula I-2, and at least one of A and B is selected from the group represented by the Formula I-1 or the group represented by the Formula I-2;

U₁, U₂ and U₃ are the same or different, and are respectively and independently selected from N or C(R), and at least one of U₁, U₂ and U₃ is N;

each R, R₁, R₂, R₃, R₄, and R₅ are respectively and independently selected from hydrogen, deuterium, a halogen group, cyano, aryl with 6 to 12 carbon atoms, heteroaryl with 5 to 12 carbon atoms, alkyl with 1 to 5 carbon atoms, haloalkyl with 1 to 5 carbon atoms, and cycloalkyl with 3 to 10 carbon atoms;

n₁ represents the number of a substituent R₁, n₁ is selected from 1, 2 or 3, and when n₁ is greater than 1, any two R₁s are the same or different;

n₂ represents the number of a substituent R₂, n₂ is selected from 1, 2, 3 or 4, and when n₂ is greater than 1, any two R₂s are the same or different, and optionally, any two adjacent R₂ form a ring;

n₃ represents the number of a substituent R₃, n₃ is selected from 1, 2, 3 or 4, and when n₃ is greater than 1, any two R₃s are the same or different;

n₄ represents the number of a substituent R₄, n₄ is selected from 1 or 2, and when n₄ is 2, any two R₄s are the same or different;

n₅ represents the number of a substituent R₅, n₅ is selected from 1, 2, 3 or 4, and when n₅ is greater than 1, any two R₅s are the same or different;

X is selected from S or O;

L, L₁, L₂, L₃ and L₄ are the same or different, and are respectively and independently selected from a single bond, substituted or unsubstituted arylene with 6 to 30 carbon atoms, and substituted or unsubstituted heteroarylene with 3 to 30 carbon atoms;

Ar₁ and Ar₂ are the same or different, and are respectively and independently selected from substituted or unsubstituted aryl with 6 to 30 carbon atoms, and substituted or unsubstituted heteroaryl with 3 to 30 carbon atoms;

substituents in the A, B, L, L₁, L₂, L₃, L₄, Ar₁ and Ar₂ are the same or different, and are respectively and independently selected from deuterium, a halogen group, cyano, heteroaryl with 3 to 20 carbon atoms, aryl with 6 to 20 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, or alkoxy with 1 to 10 carbon atoms;

optionally, in Ar₁ and Ar₂, any two adjacent substituents form a ring;

the second compound is represented by a Formula II:

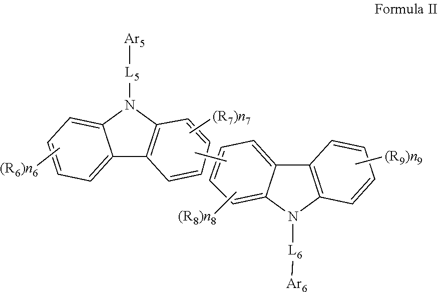

wherein

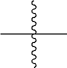

represents a chemical bond,

each R₆, R₇, R₈, and R₉ are respectively and independently selected from hydrogen, deuterium, a halogen group, cyano, aryl with 6 to 25 carbon atoms, heteroaryl with 5 to 25 carbon atoms, alkyl with 1 to 10 carbon atoms, haloalkyl with 1 to 10 carbon atoms, and cycloalkyl with 3 to 10 carbon atoms;

n₆ represents the number of a substituent R₆, n₆ is selected from 1, 2, 3 or 4, and when n₆ is greater than 1, any two R₆s are the same or different;

n₇ represents the number of a substituent R₇, n₇ is selected from 1, 2 or 3, and when n₇ is greater than 1, any two R₇s are the same or different;

n₈ represents the number of a substituent R₈, n₈ is selected from 1, 2 or 3, and when n₈ is greater than 1, any two R₈s are the same or different;

n₉ represents the number of a substituent R₉, n₉ is selected from 1, 2, 3 or 4, and when n₉ is greater than 1, any two R₉s are the same or different;

L₅ and L₆ are the same or different, and are respectively and independently selected from a single bond, substituted or unsubstituted arylene with 6 to 30 carbon atoms, and substituted or unsubstituted heteroarylene with 3 to 30 carbon atoms;

Ar₅ and Ar₆ are the same or different, and are respectively and independently selected from substituted or unsubstituted aryl with 6 to 30 carbon atoms, and substituted or unsubstituted heteroaryl with 3 to 30 carbon atoms;

substituents in L₅, L₆, Ar₅ and Ar₆ are the same or different, and are respectively and independently selected from deuterium, a halogen group, cyano, heteroaryl with 3 to 20 carbon atoms, aryl with 6 to 20 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, or alkoxy with 1 to 10 carbon atoms;

optionally, in Ar₅ and Ar₆, any two adjacent substituents form a ring.

In the present disclosure, the used description modes “each independently selected from” and “respectively and independently selected from” can be exchanged, which should be understood in a broad sense, and means that specific options expressed by a same signs in different groups do not affect each other, or specific options expressed by a same signs in a same group do not affect each other. For example, the meaning of “

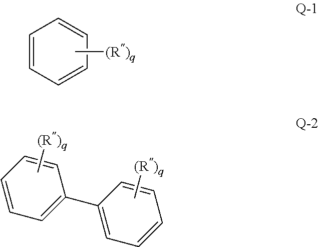

where each q is independently 0, 1, 2 or 3 and each R″ is independently selected from hydrogen, deuterium, fluorine, and chlorine” is as follows: a formula Q-1 represents that there are q substituents R″ on a benzene ring, each R″ may be the same or different, and options for each R″ do not influence each other; and a formula Q-2 represents that there are q substituents R″ on each benzene ring of biphenyl, the number q of the substituents R″ on the two benzene rings may be the same or different, each R″ may be the same or different, and options for each R″ do not influence each other.

In the present disclosure, the terms “optional” and “optionally” mean that the subsequently described event or circumstance can but need not occur, and that the description includes occasions where the event or circumstance occurs or does not occur. For example, “optionally, two adjacent substituents form a ring;”, which means that the two substituents may, but do not have to, form a ring, including a scenario in which two adjacent substituents form a ring and a scenario in which two adjacent substituents do not form a ring.

In the present disclosure, in the case that “any two adjacent substituents form a ring”, “any two adjacent substituents” can include two substituents on a same atom and one substituent on each of two adjacent atoms; when there are two substituents on the same atom, the two substituents may form a saturated or unsaturated ring with the atom to which they are jointly connected; and when two adjacent atoms each have one substituent, the two substituents may be fused to form a ring. For example, when Ar₁ has two or more substituents and any adjacent substituents form a ring, a saturated or unsaturated ring with 5 to 13 carbon atoms may be formed, for example, a benzene ring, a naphthalene ring, a fluorene ring, a phenanthrene ring, an anthracene ring, cyclopentane, cyclohexane, adamantane, and the like.

In the present disclosure, the term “substituted or unsubstituted” means that a functional group described behind the term may or may not have a substituent (the substituent is collectively referred to as Rc below for ease of description). For example, “substituted or unsubstituted aryl” refers to aryl with a substituent Rc or unsubstituted aryl. The above-mentioned substituent, i.e., Rc, may be, for example, deuterium, a halogen group, cyano, heteroaryl with 3 to 20 carbon atoms, aryl with 6 to 20 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, and alkoxy with 1 to 10 carbon atoms. In the present disclosure, a “substituted” functional group can be substituted by one or two or more substituents in the above Rc; when two substituents Rc are connected to a same atom, the two substituents Rc may independently be present or may be connected to each other to form a ring with the atom; and when two adjacent substituents Rc are present on a functional group, the two adjacent substituents Rc may independently be present or fused to form a ring with the functional group to which they are connected.

In the present disclosure, the number of carbon atoms of a substituted or unsubstituted functional group refers to the number of all carbon atoms. For example, if L is selected from substituted arylene with 12 carbon atoms, the number of all carbon atoms of the arylene and substituents on the arylene is 12. For example, if Ar₁ is

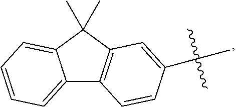 [SMILES: *c1ccc2c(c1)C(C)(C)c1ccccc1-2]

then the number of carbon atoms is 15; and if L₁ is

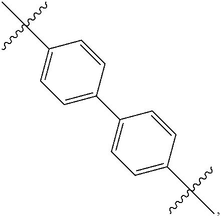 [SMILES: *c1ccc(-c2ccc(*)cc2)cc1]

the number of carbon atoms is 12.

In the present disclosure, when a specific definition is not otherwise provided, “hetero” means that at least one heteroatom selected from B, N, O, S, P, Si or Se is included in one functional group and the remaining atoms are carbon and hydrogen. Unsubstituted alkyl may be “a saturated alkyl group” without any double or triple bonds.

In the present disclosure, “alkyl” may include linear alkyl or branched alkyl. The alkyl may have 1 to 10 carbon atoms, and in the present disclosure, a numerical range such as “1 to 10” refers to each integer in a given range; for example, “1 to 10 carbon atoms” refers to alkyl that may include 1 carbon atom, 2 carbon atoms, 3 carbon atoms, 4 carbon atoms, 5 carbon atoms, 6 carbon atoms, 7 carbon atoms, 8 carbon atoms, 9 carbon atoms, or 10 carbon atoms. In addition, the alkyl can be substituted or unsubstituted.

Optionally, the alkyl is selected from alkyl with 1 to 5 carbon atoms, and specific examples include, but are not limited to, methyl, ethyl, propyl, isopropyl, n-butyl, isobutyl, sec-butyl, tert-butyl, and pentyl.

In the present disclosure, cycloalkyl refers to saturated hydrocarbons containing an alicyclic structure, including monocyclic and fused ring structures. The cycloalkyl can have 3 to 10 carbon atoms, and a numerical range such as “3 to 10” refers to each integer in a given range; for example, “3 to 10 carbon atoms” refers to cycloalkyl that may include 3 carbon atoms, 4 carbon atoms, 5 carbon atoms, 6 carbon atoms, 7 carbon atoms, 8 carbon atoms, 9 carbon atoms, or 10 carbon atoms. In addition, the cycloalkyl can be substituted or unsubstituted. For example, cyclohexyl.

In the present disclosure, aryl refers to an optional functional group or substituent derived from an aromatic carbocyclic ring. The aryl can be monocyclic aryl (e.g., phenyl) or polycyclic aryl, in other words, the aryl can be monocyclic aryl, fused aryl, two or more monocyclic aryl conjugatedly linked by carbon-carbon bonds, monocyclic aryl and fused aryl which are conjugatedly linked by a carbon-carbon bond, and two or more fused aryl conjugatedly linked by carbon-carbon bonds. That is, unless specified otherwise, two or more aromatic groups conjugatedly linked by carbon-carbon bonds can also be regarded as aryl of the present disclosure. The fused aryl may, for example, include bicyclic fused aryl (e.g., naphthyl), tricyclic fused aryl (e.g., phenanthryl, fluorenyl, and anthryl), and the like. The aryl does not contain heteroatoms such as B, N, O, S, P, Se, and Si. Examples of the aryl can include, but are not limited to, phenyl, naphthyl, fluorenyl, anthryl, phenanthryl, biphenyl, terphenyl, quaterphenyl, quinquephenyl, benzo[9,10]phenanthryl, pyrenyl, benzofluoranthenyl, chrysenyl, and the like.

“Substituted or unsubstituted aryl” of the present disclosure contains 6 to 30 carbon atoms, in some embodiments, the number of carbon atoms in the substituted or unsubstituted aryl is 6 to 25, in some embodiments, the number of carbon atoms in the substituted or unsubstituted aryl is 6 to 20, in other embodiments, the number of carbon atoms in the substituted or unsubstituted aryl is 6 to 18, and in other embodiments, the number of carbon atoms in the substituted or unsubstituted aryl is 6 to 12. For example, in the present disclosure, the number of carbon atoms in the substituted or unsubstituted aryl can be 6, 12, 13, 14, 15, 18, 20, 24, 25, or 30, and of course, the number of carbon atoms can also be other numbers, which will not be listed here. In the present disclosure, biphenyl can be understood as phenyl-substituted aryl and can also be understood as unsubstituted aryl.

In the present disclosure, the related arylene refers to a divalent group formed by further loss of one hydrogen atom of the aryl.

In the present disclosure, substituted aryl can be that one or two or more hydrogen atoms in the aryl are substituted with groups such as a deuterium atom, a halogen group, cyano, aryl, heteroaryl, trialkylsilyl, alkyl, cycloalkyl, alkoxy, and the like. Specific examples of heteroaryl-substituted aryl include, but are not limited to, carbazolyl-substituted phenyl, dibenzothiophenyl-substituted phenyl, quinoxalinyl-substituted phenyl, and the like. It should be understood that the number of carbon atoms of the substituted aryl refers to the total number of carbon atoms of the aryl and substituents on the aryl, e.g., substituted aryl with 18 carbon atoms means that the total number of carbon atoms of the aryl and its substituents is 18.

In the present disclosure, specific examples of aryl as a substituent include, but are not limited to, phenyl, naphthyl, anthryl, phenanthryl, dimethylfluorenyl, biphenyl, and the like.

In the present disclosure, heteroaryl refers to a monovalent aromatic ring containing 1, 2, 3, 4, 5, 6, or 7 heteroatoms in the ring, or its derivative, and the heteroatom may be at least one of B, O, N, P, Si, Se, and S. The heteroaryl can be monocyclic heteroaryl or polycyclic heteroaryl, in other words, the heteroaryl can be a single aromatic ring system or a multiple of aromatic ring systems conjugatedly linked by carbon-carbon bonds, and any one aromatic ring system is one aromatic monocyclic ring or one aromatic fused ring. For example, the heteroaryl may include thienyl, furyl, pyrrolyl, imidazolyl, thiazolyl, oxazolyl, oxadiazolyl, triazolyl, pyridyl, bipyridyl, pyrimidinyl, triazinyl, acridinyl, pyridazinyl, pyrazinyl, quinolyl, quinazolinyl, quinoxalinyl, phenoxazinyl, phthalazinyl, pyridopyrimidinyl, pyridopyrazinyl, pyrazinopyrazinyl, isoquinolyl, indolyl, carbazolyl, benzoxazolyl, benzimidazolyl, benzothiazolyl, benzocarbazolyl, benzothienyl, dibenzothienyl, thienothienyl, benzofuranyl, phenanthrolinyl, isoxazolyl, thiadiazolyl, benzothiazolyl, phenothiazinyl, silafluorenyl, dibenzofuranyl, as well as N-arylcarbazolyl (e.g., N-phenylcarbazolyl), N-heteroarylcarbazolyl (e.g., N-pyridylcarbazolyl), N-alkylcarbazolyl (e.g., N-methylcarbazolyl), and the like, but is not limited to this. Wherein, thienyl, furyl, phenanthrolinyl, etc. are heteroaryl of the single aromatic ring system, and N-phenylcarbazolyl, and N-pyridylcarbazolyl are heteroaryl of the multiple of aromatic ring systems conjugatedly linked by carbon-carbon bonds.

“substituted or unsubstituted heteroaryl” of the present disclosure contains 3 to 30 carbon atoms, in some embodiments, the number of carbon atoms in the substituted or unsubstituted heteroaryl is 5 to 25, in other embodiments, the number of carbon atoms in the substituted or unsubstituted heteroaryl is 3 to 20, in other embodiments, the number of carbon atoms in the substituted or unsubstituted heteroaryl is 3 to 12, in other embodiments, the number of carbon atoms in the substituted or unsubstituted heteroaryl is 3 to 20, and in other embodiments, the number of carbon atoms in the substituted or unsubstituted heteroaryl can be 5 to 12. For example, the number of carbon atoms may be 3, 4, 5, 7, 12, 13, 18, 20, 24, 25 or 30, and of course, the number of carbon atoms may also be other numbers, which will not be listed here.

In the present disclosure, the related heteroarylene refers to a divalent group formed by further loss of one hydrogen atom of the heteroaryl.

In the present disclosure, substituted heteroaryl can be that one or two or more hydrogen atoms in the heteroaryl are substituted with groups such as a deuterium atom, a hydrogen group, cyano, aryl, heteroaryl, trialkylsilyl, alkyl, cycloalkyl, alkoxy, and the like. Specific examples of aryl-substituted heteroaryl include, but are not limited to, phenyl-substituted dibenzofuranyl, phenyl-substituted dibenzothienyl, N-phenylcarbazolyl, and the like. It should be understood that the number of carbon atoms of the substituted heteroaryl refers to the total number of carbon atoms of the heteroaryl and substituents on the heteroaryl.

In the present disclosure, specific examples of heteroaryl as a substituent include, but are not limited to, carbazolyl, dibenzofuranyl, and dibenzothienyl.

In the present disclosure, the halogen group may include fluorine, iodine, bromine, chlorine, and the like.

In the present disclosure, an unpositioned connecting bond refers to a single bond

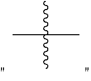

extending from a ring system, which means that one end of the connecting bond can be connected to any position in the ring system through which the bond penetrates, and the other end of the connecting bond is connected to the remaining part of a compound molecule.

For example, as shown in a formula (f) below, naphthyl represented by the formula (f) is connected to other positions of a molecule via two unpositioned connecting bonds penetrating a bicyclic ring, and its meaning includes any one possible connecting mode represented by formulae (f-1)-(f-10).

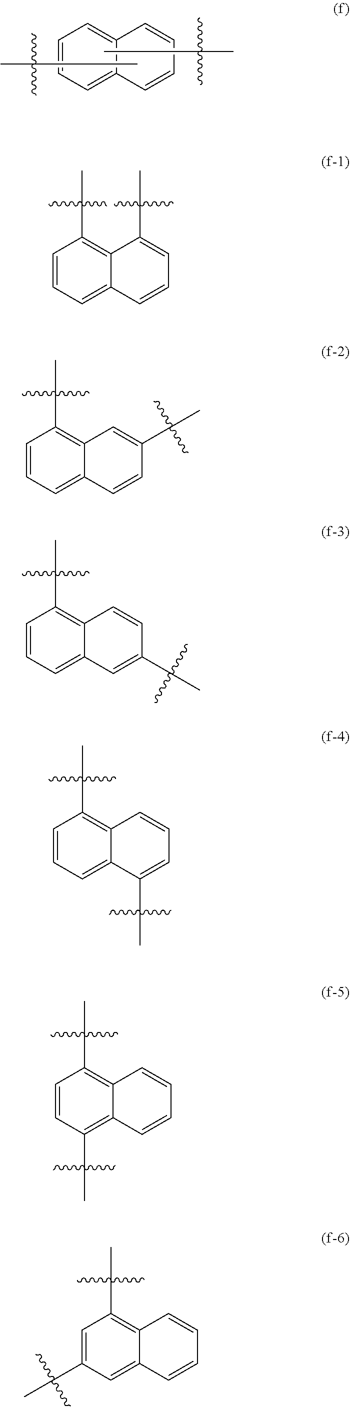

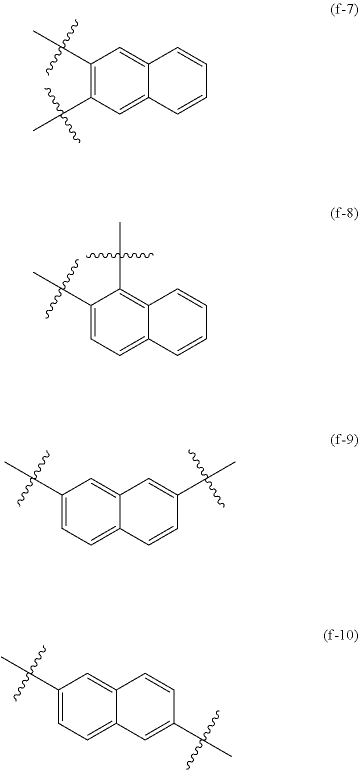 [SMILES: *c1cc2ccccc2cc1* ; *c1ccc2ccccc2c1* ; *c1ccc2ccc(*)cc2c1 ; *c1ccc2cc(*)ccc2c1]

For another example, as shown in a formula (X′) below, dibenzofuranyl represented by the formula (X′) is connected to other positions of a molecule via one unpositioned connecting bond extending from the middle of a benzene ring on one side, and its meaning includes any one possible connecting mode represented by formulae (X′-1)-(X′-4).

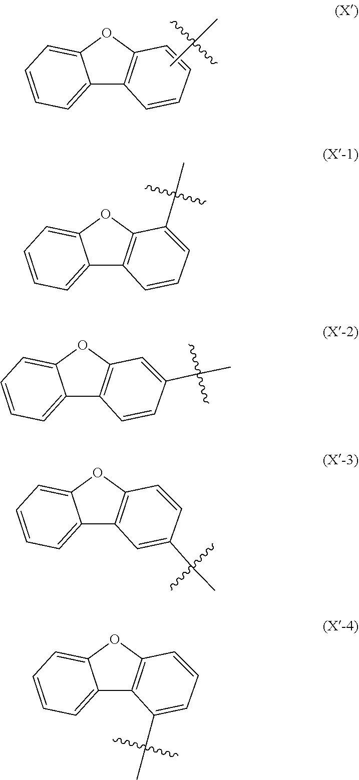

The meaning for unpositioned connection or unpositioned substitution is the same as that here, which will not be repeated later.

In one embodiment of the present disclosure, two of U₁, U₂, and U₃ are N and the other is C(R); or U₁, U₂, and U₃ are all N.

In one embodiment of the present disclosure, each R, R₁, R₂, R₃, R₄, and R₅ are respectively and independently selected from hydrogen, deuterium, fluorine, cyano, methyl, ethyl, n-propyl, isopropyl, tert-butyl, phenyl, pyridyl, trifluoromethyl, and biphenyl, or any two adjacent R₂s form a benzene ring, a naphthalene ring, or a phenanthrene ring.

Optionally, each R, R₁, R₃, R₄, and R₅ are all hydrogen.

Optionally, R₂ is independently selected from hydrogen, deuterium, fluorine, cyano, methyl, ethyl, n-propyl, isopropyl, tert-butyl, phenyl, naphthyl, pyridyl, trifluoromethyl, or biphenyl, or any two adjacent R₂s are connected to each other to form a 5- to 13-membered ring, for example, any two adjacent R₂s are connected to each other to form a benzene ring, a naphthalene ring, or a phenanthrene ring.

Specifically, each R₂ is independently selected from deuterium, fluorine, cyano, methyl, ethyl, n-propyl, isopropyl, tert-butyl, phenyl, naphthyl, biphenyl, pyridyl, carbazolyl, dibenzofuranyl, dibenzothienyl, cyclopentyl, cyclohexyl, or trifluoromethyl.

In the present disclosure, the “saturated or unsaturated ring with 5 to 13 carbon atoms” means that the number of ring-forming carbon atoms is 5 to 13.

In the present disclosure, the group represented by the Formula I-1

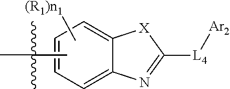

is selected from the following structures:

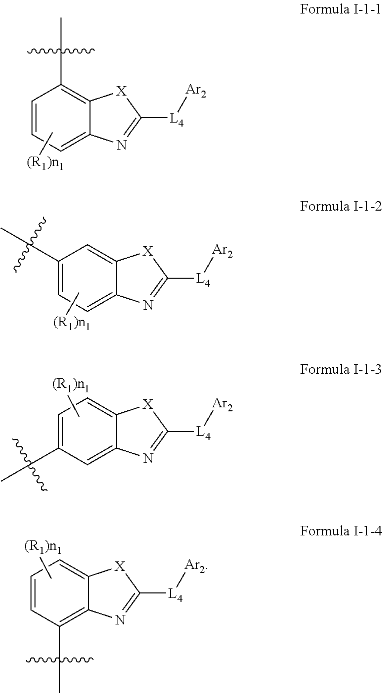

In one embodiment of the present disclosure, in the first compound, the A and B are respectively and independently selected from substituted or unsubstituted aryl with 6 to 25 carbon atoms, substituted or unsubstituted heteroaryl with 5 to 20 carbon atoms, the group represented by the Formula I-1 or the group represented by the Formula I-2, and one and only one of A and B is selected from the group represented by the Formula I-1 or the group represented by the Formula I-2.

Optionally, substituents in the A and B are respectively and independently selected from deuterium, a halogen group, cyano, aryl with 6 to 12 carbon atoms, heteroaryl with 5 to 12 carbon atoms, alkyl with 1 to 5 carbon atoms, or cycloalkyl with 3 to 10 carbon atoms.

In another embodiment of the present disclosure, further preferably, in the first compound, the A and B are respectively and independently selected from substituted or unsubstituted phenyl, substituted or unsubstituted naphthyl, substituted or unsubstituted biphenyl, substituted or unsubstituted phenanthryl, substituted or unsubstituted anthryl, substituted or unsubstituted benzophenanthryl, substituted or unsubstituted spirobifluorenyl, substituted or unsubstituted pyridyl, substituted or unsubstituted quinolyl, substituted or unsubstituted isoquinolyl, substituted or unsubstituted dibenzofuranyl, substituted or unsubstituted carbazolyl, substituted or unsubstituted dibenzothienyl, substituted or unsubstituted fluorenyl, substituted or unsubstituted pyrenyl, substituted or unsubstituted phenanthrolinyl, the group represented by the Formula I-1 or the group represented by the Formula I-2, and one and only one of A and B is selected from the group represented by the Formula I-1 or the group represented by the Formula I-2.

Optionally, substituents in the A and B are each independently selected from deuterium, fluorine, cyano, methyl, ethyl, n-propyl, isopropyl, tert-butyl, phenyl, naphthyl, biphenyl, pyridyl, carbazolyl, dibenzofuranyl, dibenzothienyl, cyclopentyl, or cyclohexyl.

In one embodiment of the present disclosure, in the first compound, the L, L₁, L₂, L₃ and L₄ are the same or different, and are respectively and independently selected from a single bond, substituted or unsubstituted arylene with 6 to 20 carbon atoms, and substituted or unsubstituted heteroarylene with 5 to 20 carbon atoms.

Optionally, substituents in the L, L₁, L₂, L₃ and L₄ are respectively and independently selected from deuterium, a halogen group, cyano, aryl with 6 to 12 carbon atoms and alkyl with 1 to 5 carbon atoms.

In one embodiment of the present disclosure, in the first compound, the L, L₁, L₂, L₃ and L₄ are the same or different, and are respectively and independently selected from a single bond, substituted or unsubstituted phenylene, substituted or unsubstituted naphthylene, substituted or unsubstituted biphenylene, substituted or unsubstituted pyridylene, substituted or unsubstituted dibenzofurylene, substituted or unsubstituted dibenzothienylene, substituted or unsubstituted fluorenylene, substituted or unsubstituted carbazolylene, and substituted or unsubstituted anthrylene;

optionally, substituents in the L, L₁, L₂, L₃ and L₄ are respectively and independently selected from deuterium, cyano, fluorine, methyl, ethyl, n-propyl, isopropyl, tert-butyl or phenyl.

In another embodiment of the present disclosure, in the first compound, the L, L₁, L₂, L₃ and L₄ are the same or different, and are respectively and independently selected from a single bond or a substituted or unsubstituted group V, and the unsubstituted group V is selected from a group consisting of the following groups:

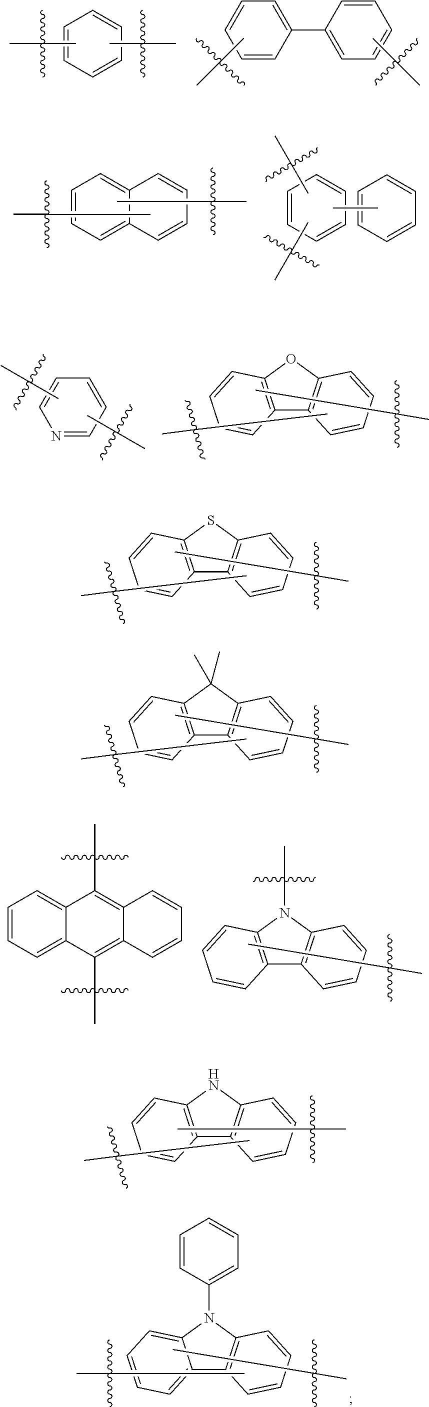

wherein

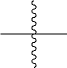

substituted group V has one or more substituents, and the substituents are each independently selected from deuterium, cyano, fluorine, methyl, ethyl, n-propyl, isopropyl, tert-butyl, and phenyl; and when the number of the substituents in the group V is greater than 1, the substituents are the same or different.

Optionally, L, L₁, L₂, L₃ and L₄ are respectively and independently selected from a single bond or a group consisting of the following groups:

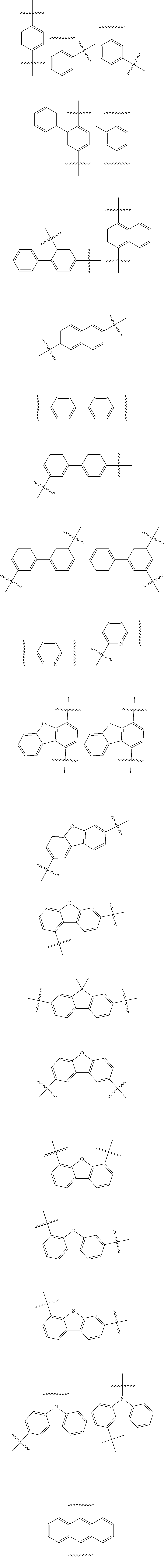

In one embodiment of the present disclosure, in the first compound, the Ar₁ and Ar₂ are each independently selected from substituted or unsubstituted aryl with 6 to 25 carbon atoms, and substituted or unsubstituted heteroaryl with 4 to 20 carbon atoms;

optionally, substituents in the Ar₁ are respectively and independently selected from deuterium, a halogen group, cyano, aryl with 6 to 12 carbon atoms, heteroaryl with 5 to 12 carbon atoms, alkyl with 1 to 5 carbon atoms, or cycloalkyl with 3 to 10 carbon atoms;

optionally, any two adjacent substituents in the Ar₁ form a saturated or unsaturated ring with 5 to 13 carbon atoms. For example, in Ar₁, any two adjacent substituents form cyclopentane, cyclohexane, adamantane, or a fluorene ring.

Optionally, substituents in the Ar₂ are respectively and independently selected from deuterium, a halogen group, cyano, aryl with 6 to 12 carbon atoms, heteroaryl with 5 to 12 carbon atoms, alkyl with 1 to 5 carbon atoms, haloalkyl with 1 to 5 carbon atoms, and cycloalkyl with 3 to 10 carbon atoms;

optionally, any two adjacent substituents in the Ar₂ form a saturated or unsaturated ring with 5 to 13 carbon atoms. For example, in Ar₂, any two adjacent substituents form cyclopentane, cyclohexane, adamantane, or a fluorene ring.

In one embodiment of the present disclosure, in the first compound, the Ar₁ and Ar₂ are each independently selected from substituted or unsubstituted phenyl, substituted or unsubstituted biphenyl, substituted or unsubstituted naphthyl, substituted or unsubstituted dibenzofuranyl, substituted or unsubstituted dibenzothienyl, substituted or unsubstituted fluorenyl, substituted or unsubstituted N-phenylcarbazolyl, substituted or unsubstituted carbazolyl, substituted or unsubstituted phenanthryl, substituted or unsubstituted anthryl, substituted or unsubstituted terphenyl, substituted or unsubstituted pyridyl, substituted or unsubstituted pyrenyl, substituted or unsubstituted quinolyl, substituted or unsubstituted isoquinolyl, substituted or unsubstituted phenanthrolinyl, substituted or unsubstituted benzophenanthryl, substituted or unsubstituted furyl, substituted or unsubstituted thienyl or the following group substituted or unsubstituted:

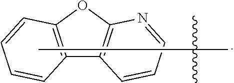

Optionally, substituents in the Ar₁ and Ar₂ are respectively and independently selected from deuterium, cyano, fluorine, methyl, ethyl, n-propyl, isopropyl, tert-butyl, phenyl, naphthyl, biphenyl, or carbazolyl;

optionally, in Ar₁ and Ar₂, any two adjacent substituents form cyclopentane, cyclohexane, adamantane, or a fluorene ring

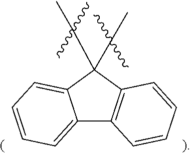 [SMILES: *C1(*)c2ccccc2-c2ccccc21]

In one embodiment of the present disclosure, in the first compound, the Ar₁ and Ar₂ are each independently selected from a substituted or unsubstituted group W₁, and the unsubstituted group W₁ is selected from a group consisting of the following groups:

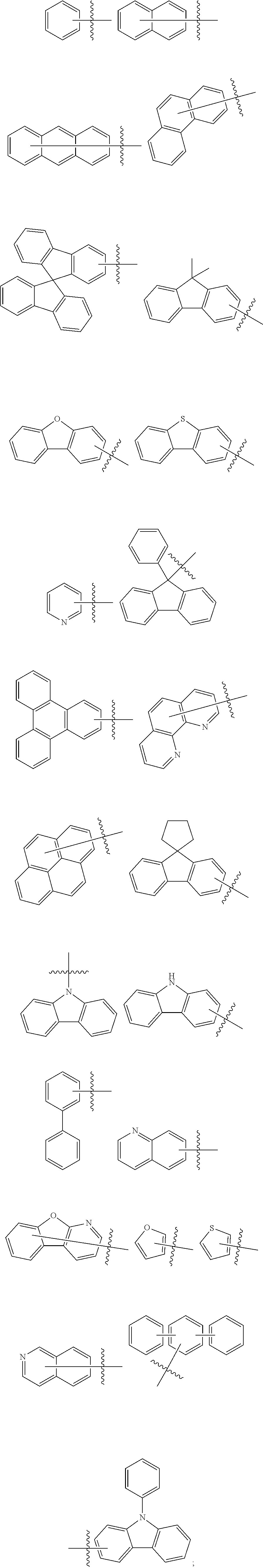

wherein

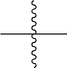

represents a chemical bond; the substituted group W₁ has one or more substituents, and the substituents are each independently selected from deuterium, cyano, fluorine, methyl, ethyl, n-propyl, isopropyl, tert-butyl, phenyl, naphthyl, biphenyl, or carbazolyl; and when the number of the substituents in the group W₁ is greater than 1, the substituents are the same or different.

Optionally, the Ar₁ is selected from a group consisting of the following groups:

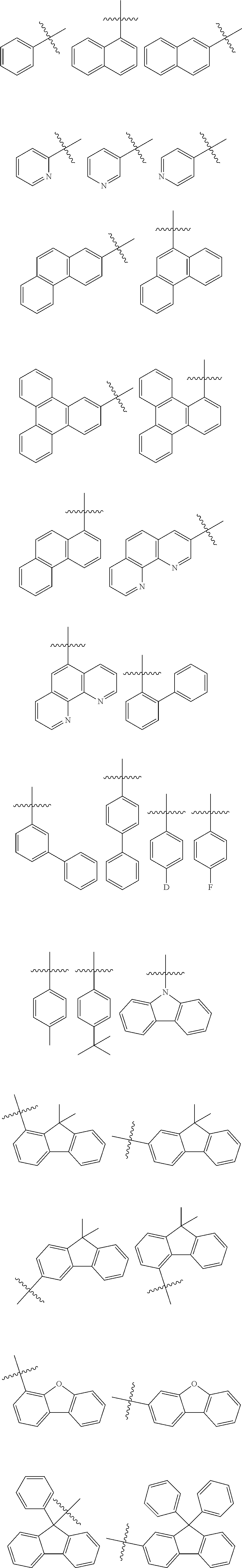

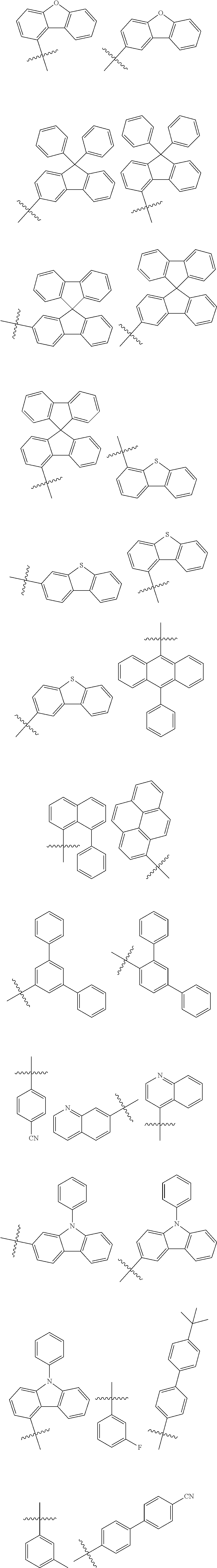

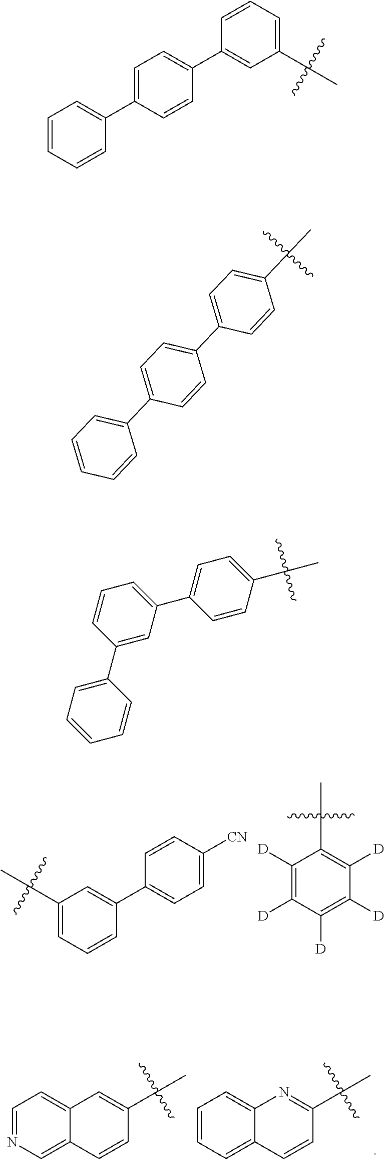

Optionally, the Ara is selected from a group consisting of the following groups:

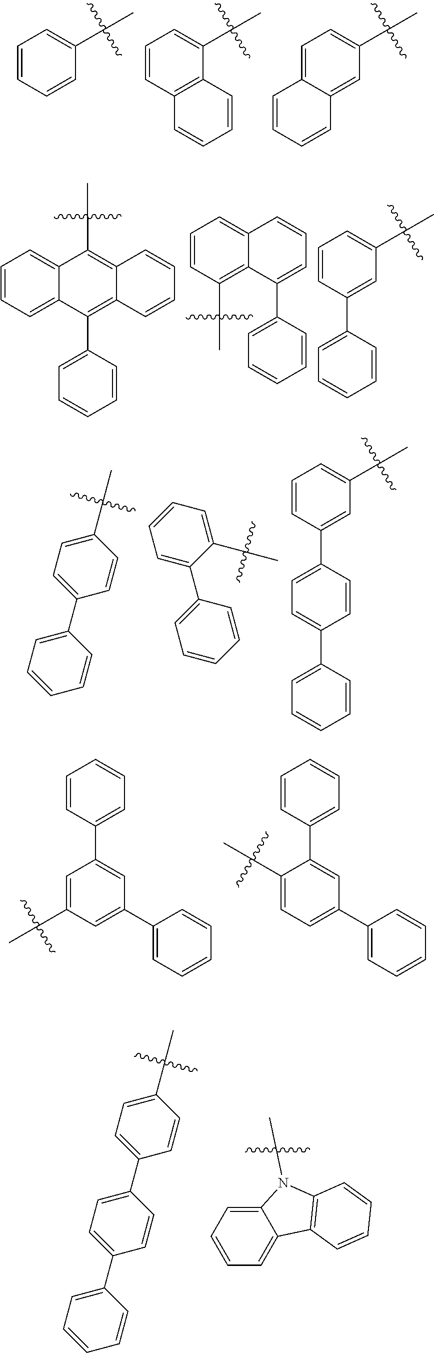

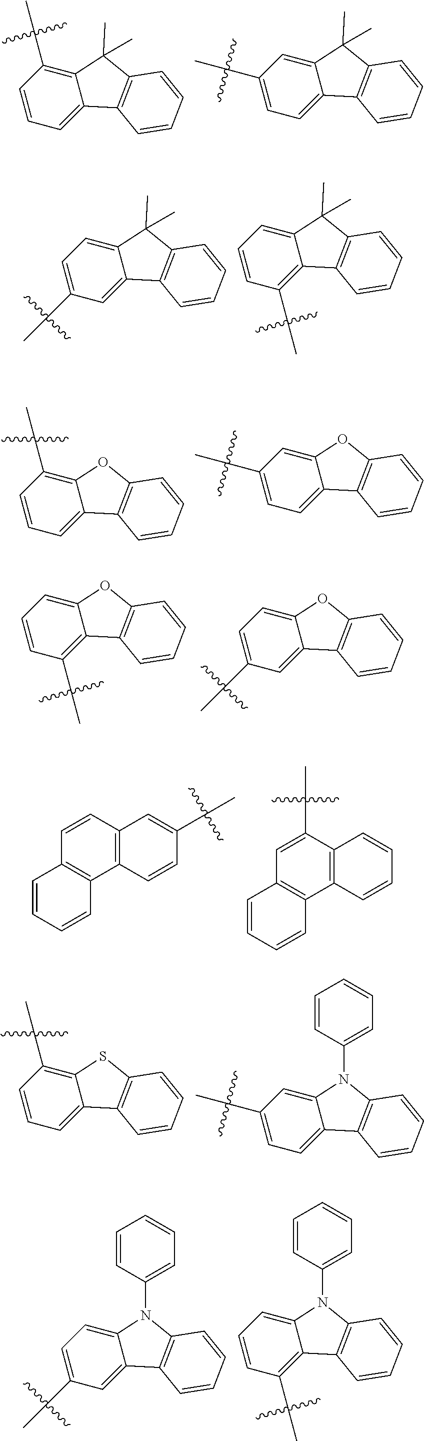

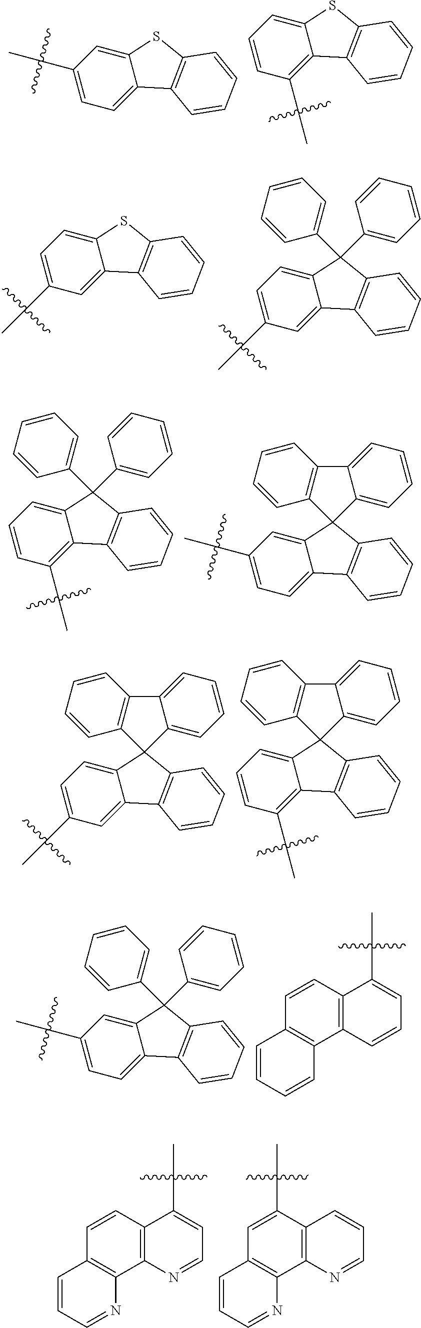

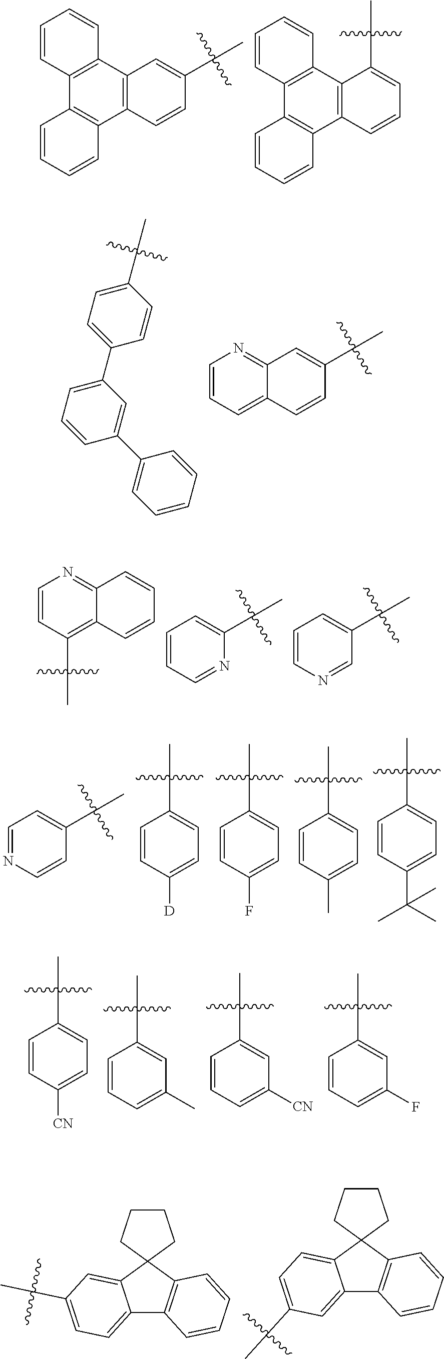

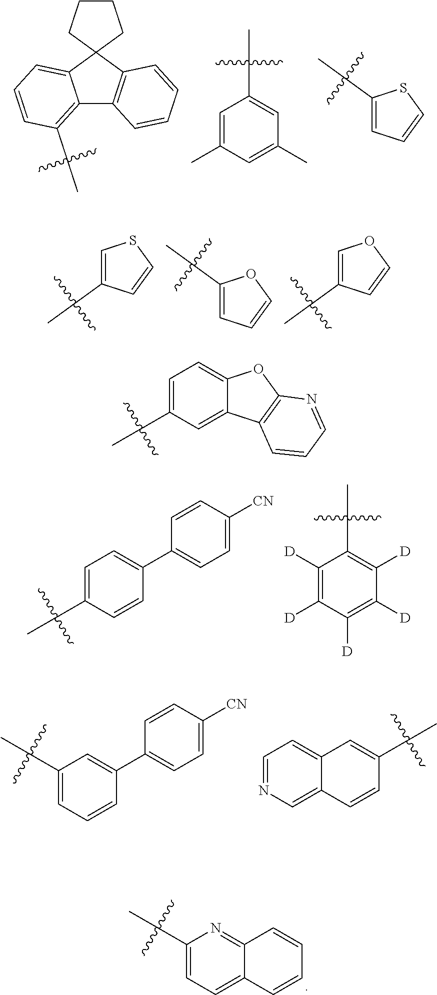

In some embodiments, any one of the A and B is selected from the group represented by the Formula I-1 or the group represented by the Formula I-2, and the other is selected from the following groups:

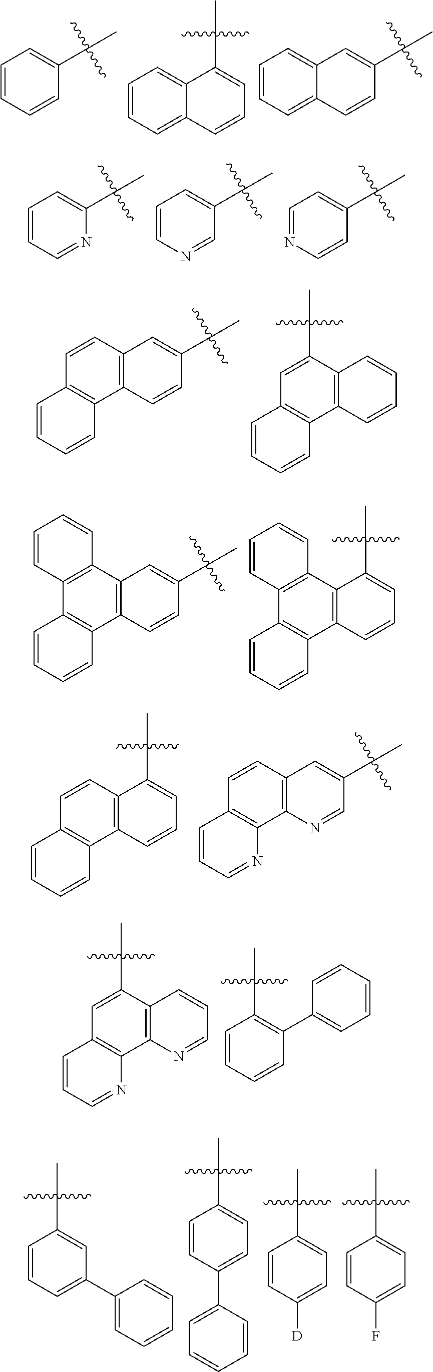

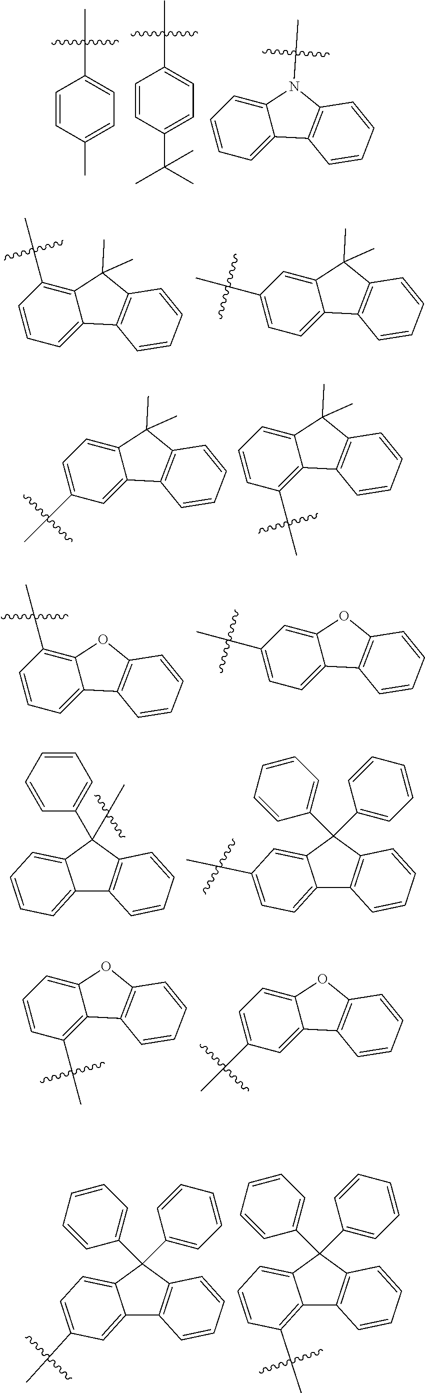

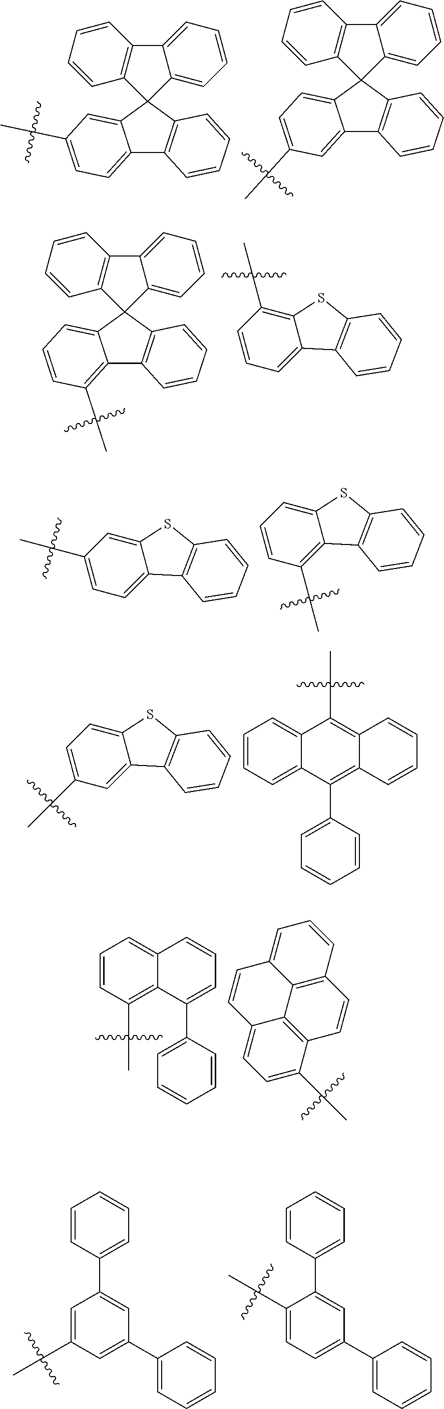

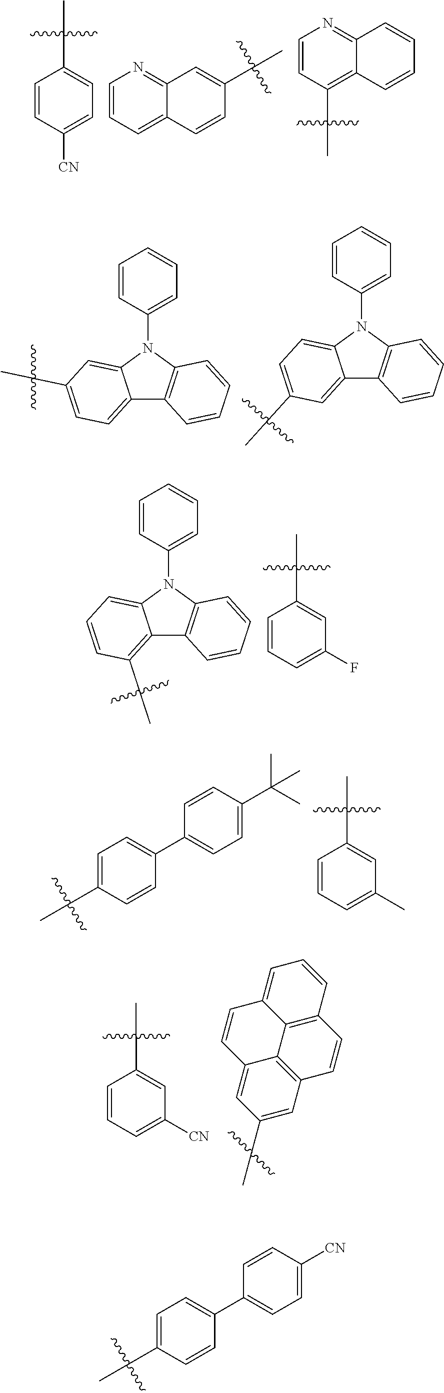

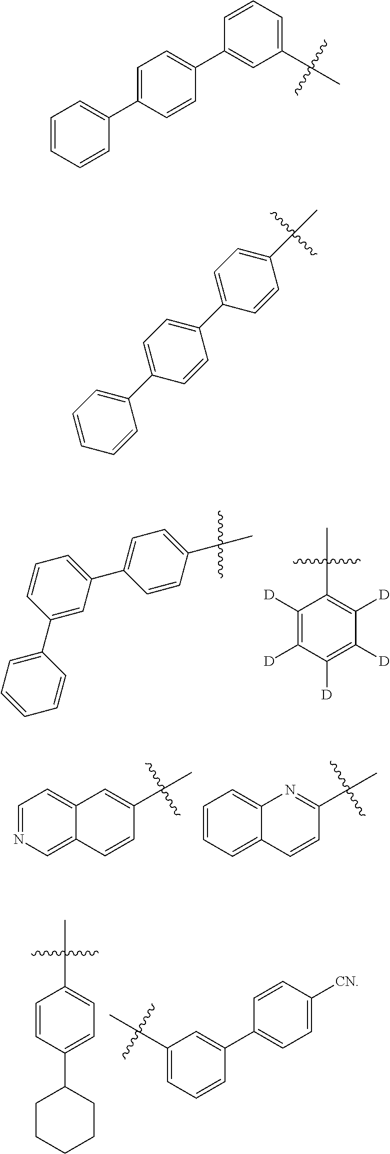

In one embodiment of the present disclosure, A is the group represented by the Formula I-1, and B is selected from a group consisting of substituted or unsubstituted phenyl, substituted or unsubstituted naphthyl, substituted or unsubstituted biphenyl, substituted or unsubstituted phenanthryl, substituted or unsubstituted anthryl, substituted or unsubstituted pyridyl, substituted or unsubstituted benzophenanthryl, substituted or unsubstituted spirobifluorenyl, substituted or unsubstituted quinolyl, substituted or unsubstituted isoquinolyl, substituted or unsubstituted dibenzofuranyl, substituted or unsubstituted carbazolyl, substituted or unsubstituted dibenzothienyl, substituted or unsubstituted fluorenyl, substituted or unsubstituted pyrenyl, and substituted or unsubstituted phenanthrolinyl.

In one embodiment of the present disclosure, A is the group represented by the Formula I-2, and B is selected from a group consisting of substituted or unsubstituted phenyl, substituted or unsubstituted naphthyl, substituted or unsubstituted biphenyl, substituted or unsubstituted phenanthryl, substituted or unsubstituted anthryl, substituted or unsubstituted pyridyl, substituted or unsubstituted benzophenanthryl, substituted or unsubstituted spirobifluorenyl, substituted or unsubstituted quinolyl, substituted or unsubstituted isoquinolyl, substituted or unsubstituted dibenzofuranyl, substituted or unsubstituted carbazolyl, substituted or unsubstituted dibenzothienyl, substituted or unsubstituted fluorenyl, substituted or unsubstituted pyrenyl, and substituted or unsubstituted phenanthrolinyl.

In one embodiment of the present disclosure, B is the group represented by the Formula I-1, and A is selected from a group consisting of substituted or unsubstituted phenyl, substituted or unsubstituted naphthyl, substituted or unsubstituted biphenyl, substituted or unsubstituted phenanthryl, substituted or unsubstituted anthryl, substituted or unsubstituted benzophenanthryl, substituted or unsubstituted spirobifluorenyl, substituted or unsubstituted pyridyl, substituted or unsubstituted quinolyl, substituted or unsubstituted isoquinolyl, substituted or unsubstituted dibenzofuranyl, substituted or unsubstituted carbazolyl, substituted or unsubstituted dibenzothienyl, substituted or unsubstituted fluorenyl, substituted or unsubstituted pyrenyl, and substituted or unsubstituted phenanthrolinyl.

In one example of the present disclosure, B is the group represented by the Formula I-2, and A is selected from a group consisting of substituted or unsubstituted phenyl, substituted or unsubstituted naphthyl, substituted or unsubstituted biphenyl, substituted or unsubstituted phenanthryl, substituted or unsubstituted anthryl, substituted or unsubstituted benzophenanthryl, substituted or unsubstituted spirobifluorenyl, substituted or unsubstituted pyridyl, substituted or unsubstituted quinolyl, substituted or unsubstituted isoquinolyl, substituted or unsubstituted dibenzofuranyl, substituted or unsubstituted carbazolyl, substituted or unsubstituted dibenzothienyl, substituted or unsubstituted fluorenyl, substituted or unsubstituted pyrenyl, and substituted or unsubstituted phenanthrolinyl.

In one embodiment of the present disclosure, X is O when A is selected from the group represented by the Formula I-1 or the group represented by the Formula I-2.

Optionally, the first compound is selected from a group consisting of the following compounds:

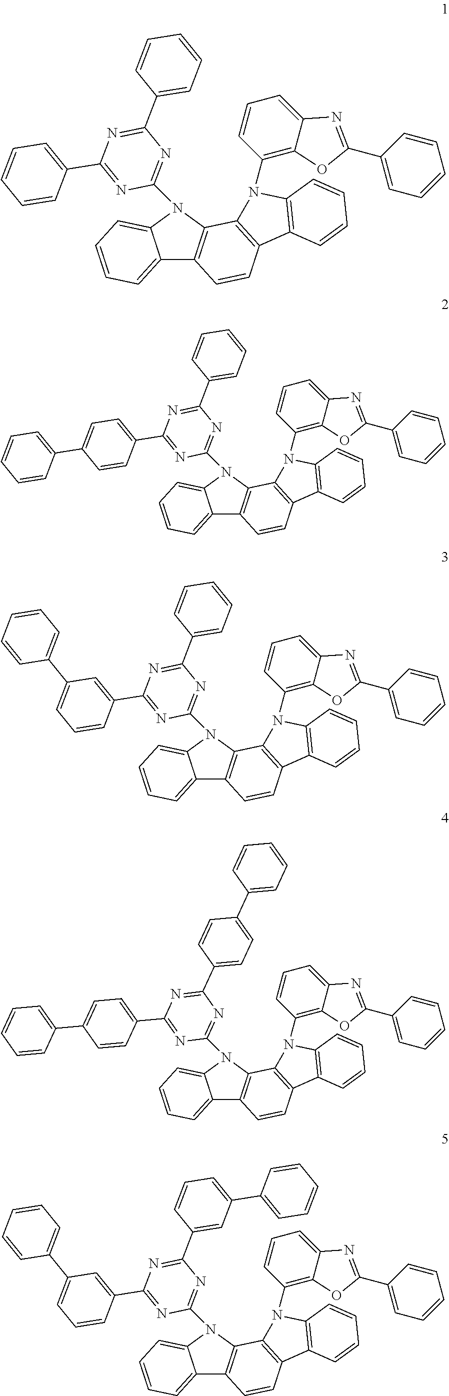

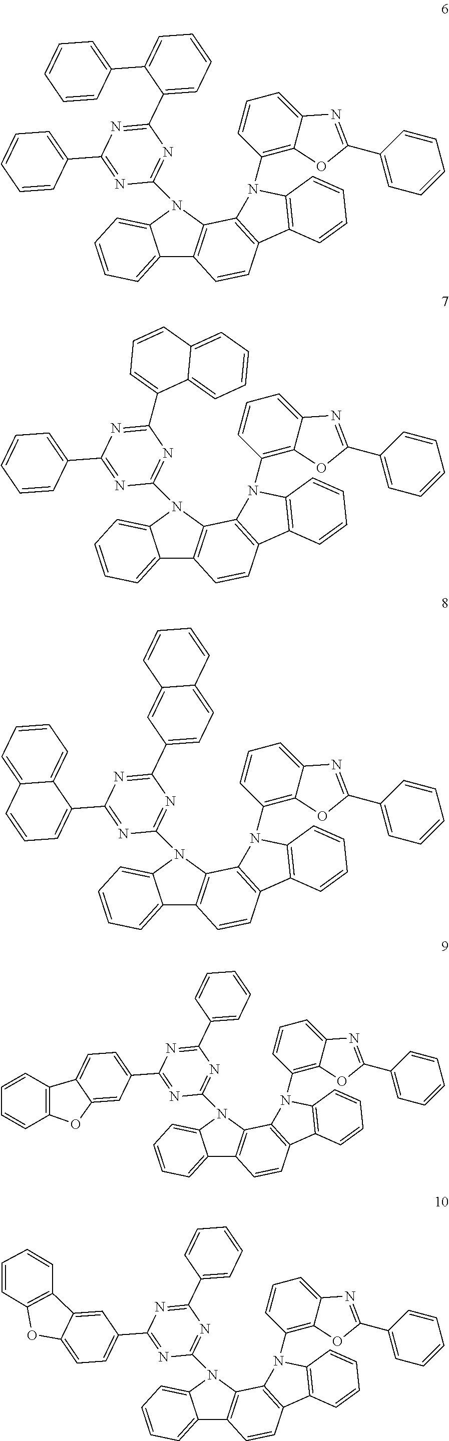

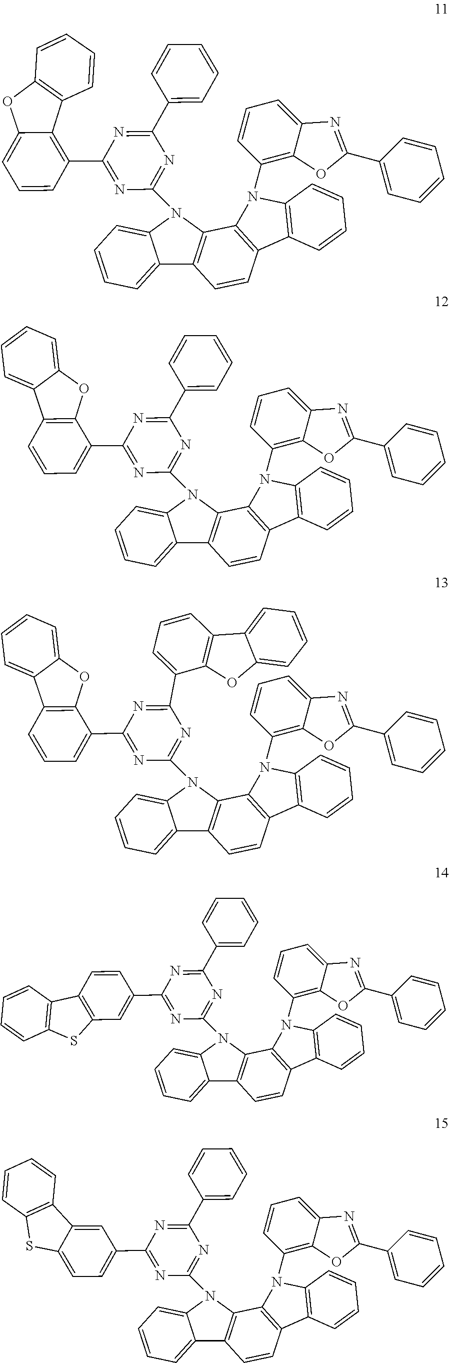

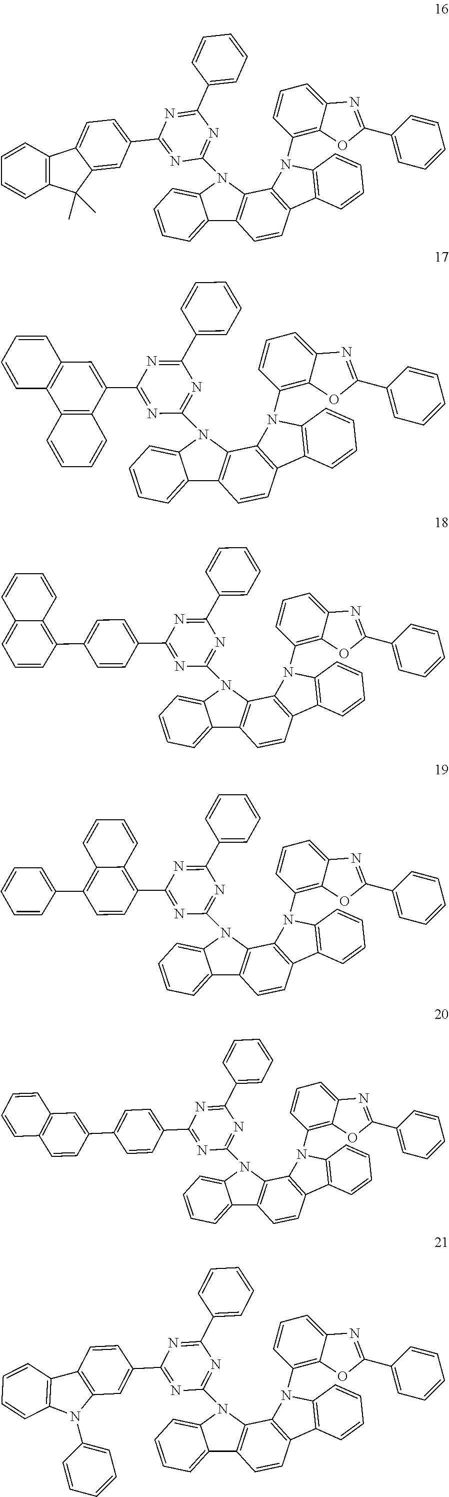

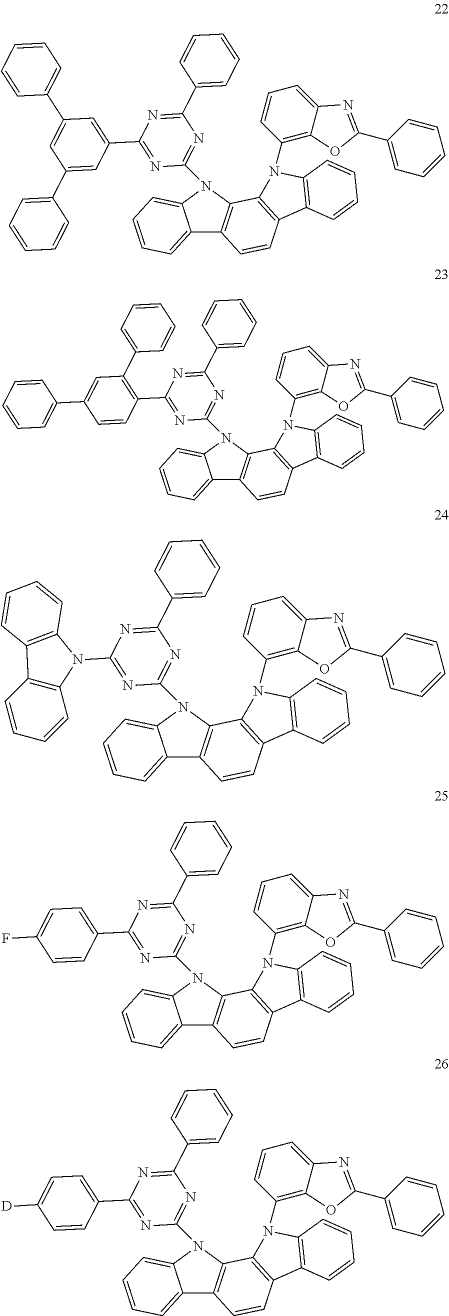

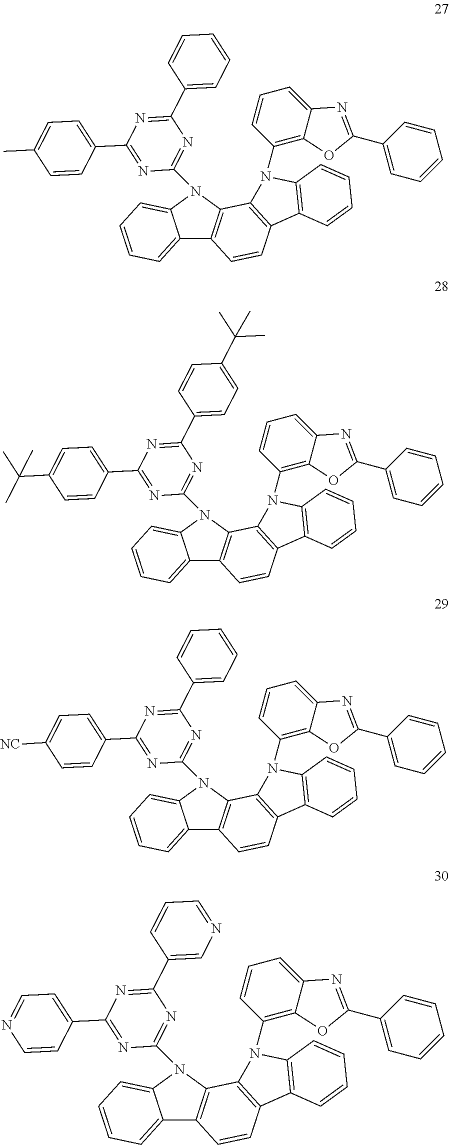 [SMILES: Cc1ccc(-c2nc(-c3ccccc3)nc(-n3c4ccccc4c4ccc5c6ccccc6n(-c6cccc7nc(-c8ccccc8)oc67)c5c43)n2)cc1 ; CC(C)(C)c1ccc(-c2nc(-c3ccc(C(C)(C)C)cc3)nc(-n3c4ccccc4c4ccc5c6ccccc6n(-c6cccc7nc(-c8ccccc8)oc67)c5c43)n2)cc1 ; N#Cc1ccc(-c2nc(-c3ccccc3)nc(-n3c4ccccc4c4ccc5c6ccccc6n(-c6cccc7nc(-c8ccccc8)oc67)c5c43)n2)cc1 ; c1ccc(-c2nc3cccc(-n4c5ccccc5c5ccc6c7ccccc7n(-c7nc(-c8ccncc8)nc(-c8cccnc8)n7)c6c54)c3o2)cc1]

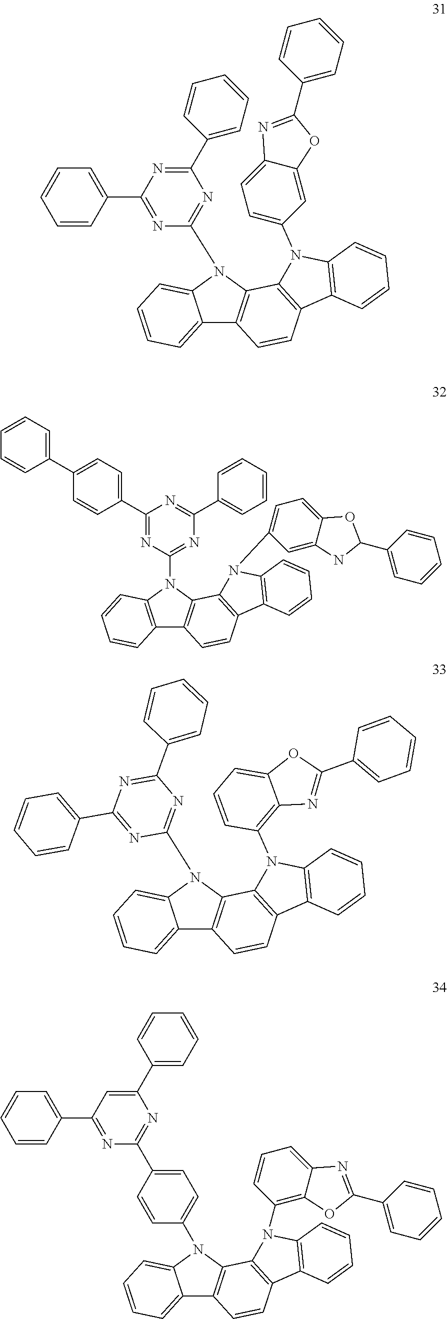

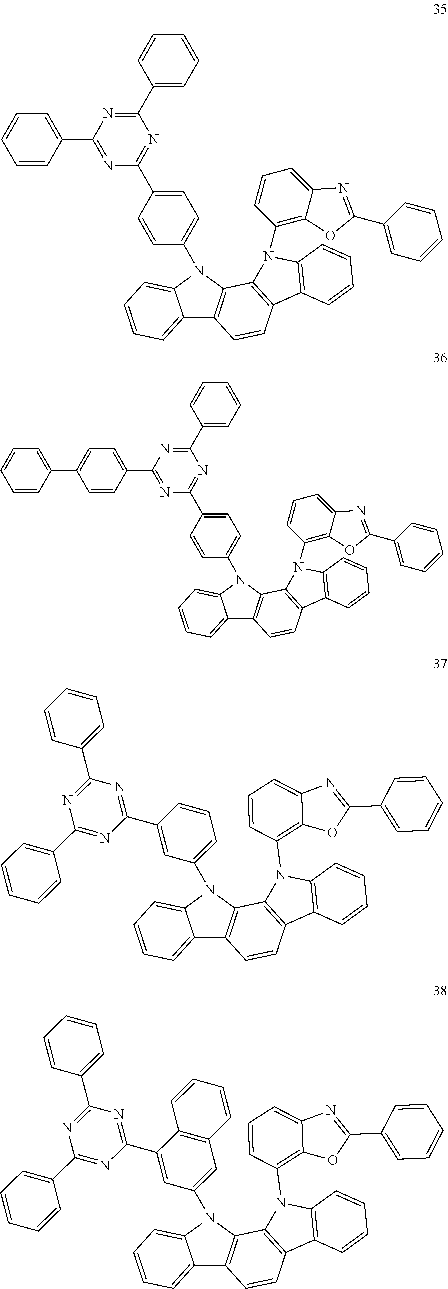 [SMILES: c1ccc(-c2nc(-c3ccccc3)nc(-c3ccc(-n4c5ccccc5c5ccc6c7ccccc7n(-c7cccc8nc(-c9ccccc9)oc78)c6c54)cc3)n2)cc1 ; c1ccc(-c2ccc(-c3nc(-c4ccccc4)nc(-c4ccc(-n5c6ccccc6c6ccc7c8ccccc8n(-c8cccc9nc(-c%10ccccc%10)oc89)c7c65)cc4)n3)cc2)cc1 ; c1ccc(-c2nc(-c3ccccc3)nc(-c3cccc(-n4c5ccccc5c5ccc6c7ccccc7n(-c7cccc8nc(-c9ccccc9)oc78)c6c54)c3)n2)cc1 ; c1ccc(-c2nc(-c3ccccc3)nc(-c3cc(-n4c5ccccc5c5ccc6c7ccccc7n(-c7cccc8nc(-c9ccccc9)oc78)c6c54)cc4ccccc34)n2)cc1]

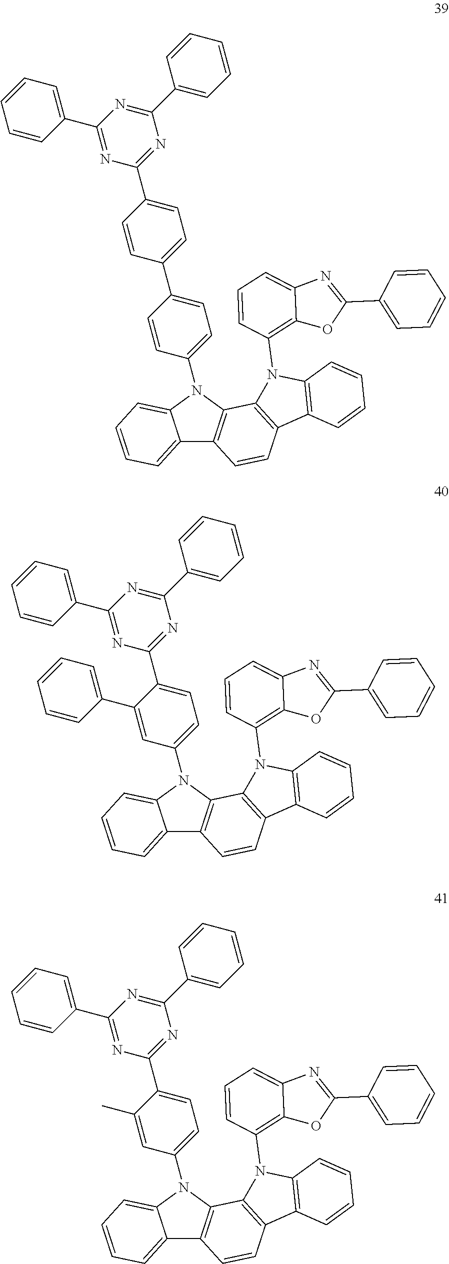 [SMILES: c1ccc(-c2nc(-c3ccccc3)nc(-c3ccc(-c4ccc(-n5c6ccccc6c6ccc7c8ccccc8n(-c8cccc9nc(-c%10ccccc%10)oc89)c7c65)cc4)cc3)n2)cc1 ; c1ccc(-c2nc(-c3ccccc3)nc(-c3ccc(-n4c5ccccc5c5ccc6c7ccccc7n(-c7cccc8nc(-c9ccccc9)oc78)c6c54)cc3-c3ccccc3)n2)cc1 ; Cc1cc(-n2c3ccccc3c3ccc4c5ccccc5n(-c5cccc6nc(-c7ccccc7)oc56)c4c32)ccc1-c1nc(-c2ccccc2)nc(-c2ccccc2)n1]

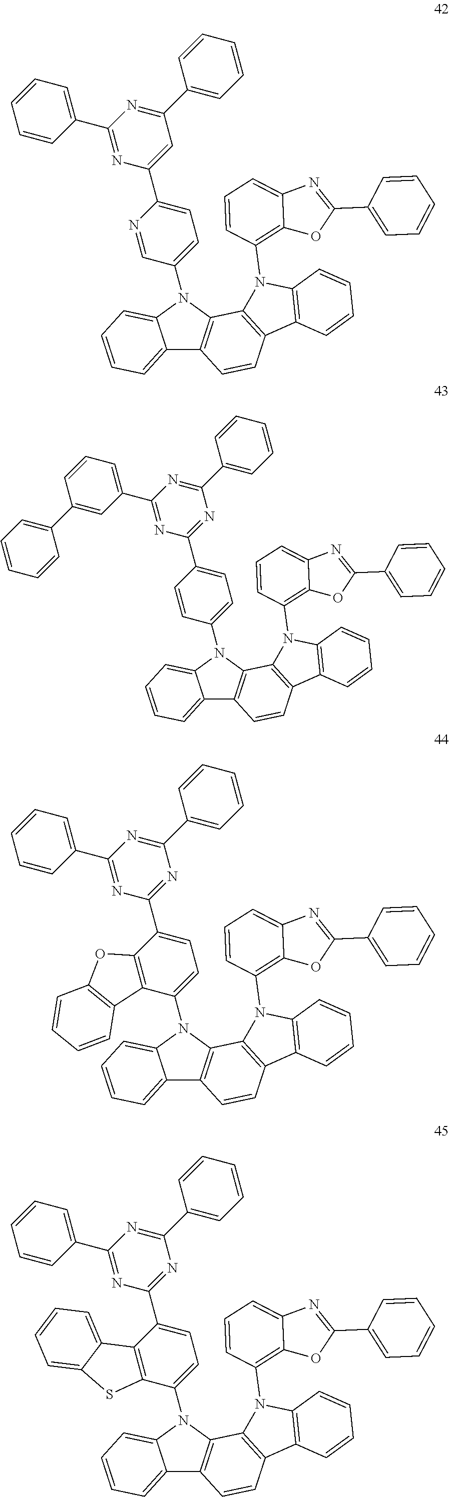

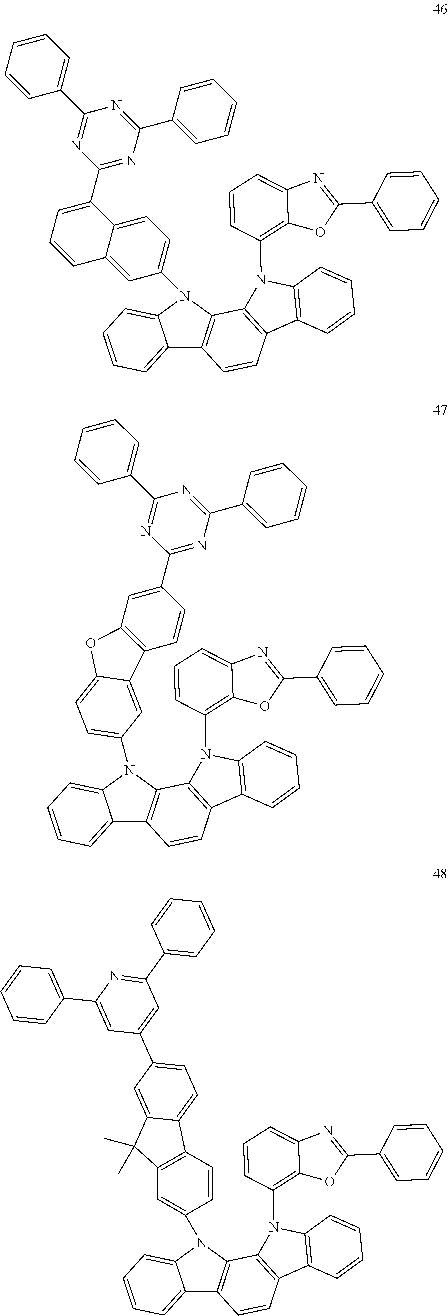 [SMILES: c1ccc(-c2nc(-c3ccccc3)nc(-c3cccc4cc(-n5c6ccccc6c6ccc7c8ccccc8n(-c8cccc9nc(-c%10ccccc%10)oc89)c7c65)ccc34)n2)cc1 ; c1ccc(-c2nc(-c3ccccc3)nc(-c3ccc4c(c3)oc3ccc(-n5c6ccccc6c6ccc7c8ccccc8n(-c8cccc9nc(-c%10ccccc%10)oc89)c7c65)cc34)n2)cc1 ; CC1(C)c2cc(-c3cc(-c4ccccc4)nc(-c4ccccc4)c3)ccc2-c2ccc(-n3c4ccccc4c4ccc5c6ccccc6n(-c6cccc7nc(-c8ccccc8)oc67)c5c43)cc21]

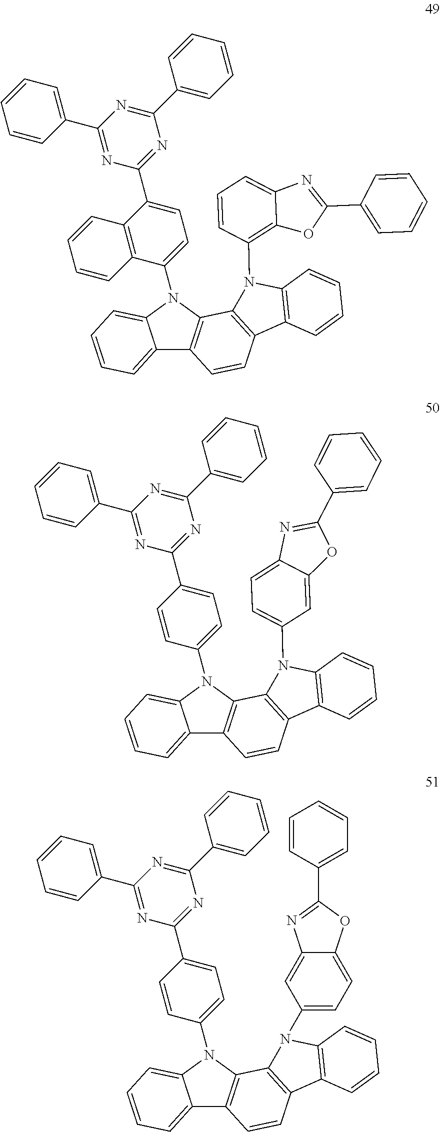

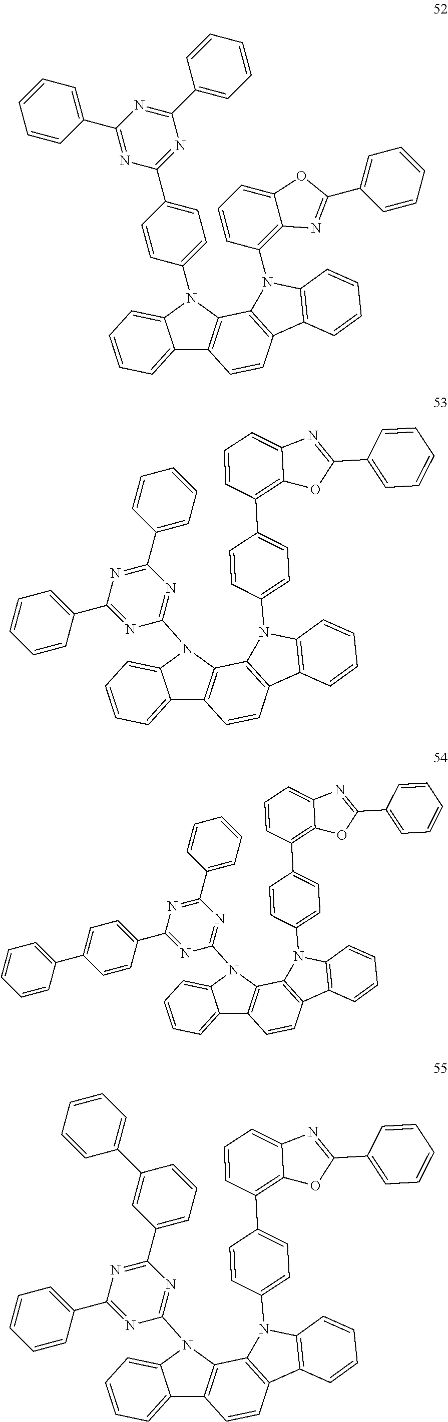 [SMILES: c1ccc(-c2nc(-c3ccccc3)nc(-c3ccc(-n4c5ccccc5c5ccc6c7ccccc7n(-c7cccc8oc(-c9ccccc9)nc78)c6c54)cc3)n2)cc1 ; c1ccc(-c2nc(-c3ccccc3)nc(-n3c4ccccc4c4ccc5c6ccccc6n(-c6ccc(-c7cccc8nc(-c9ccccc9)oc78)cc6)c5c43)n2)cc1 ; c1ccc(-c2ccc(-c3nc(-c4ccccc4)nc(-n4c5ccccc5c5ccc6c7ccccc7n(-c7ccc(-c8cccc9nc(-c%10ccccc%10)oc89)cc7)c6c54)n3)cc2)cc1 ; c1ccc(-c2cccc(-c3nc(-c4ccccc4)nc(-n4c5ccccc5c5ccc6c7ccccc7n(-c7ccc(-c8cccc9nc(-c%10ccccc%10)oc89)cc7)c6c54)n3)c2)cc1]

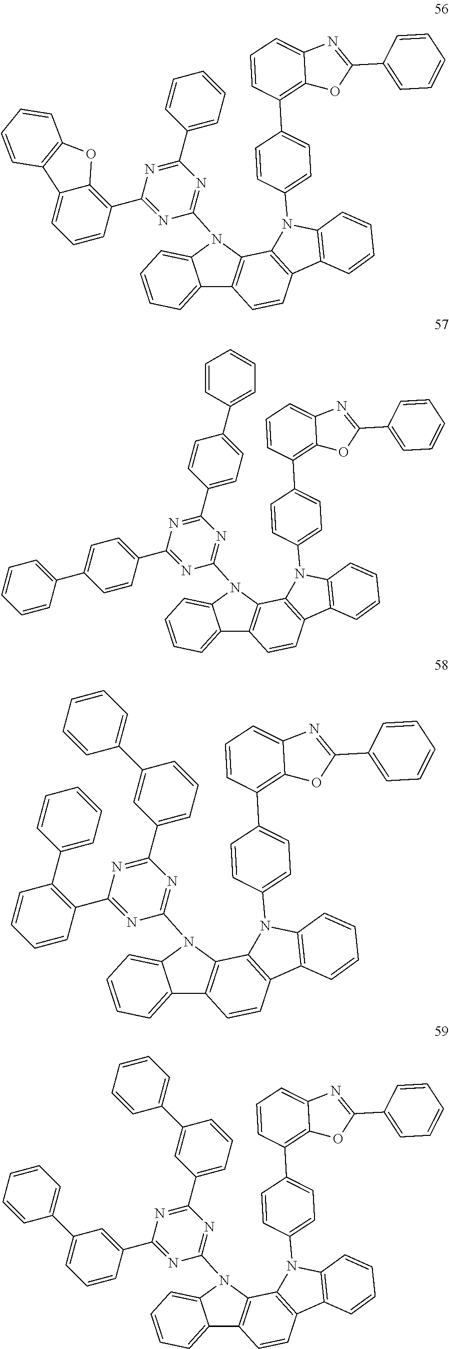

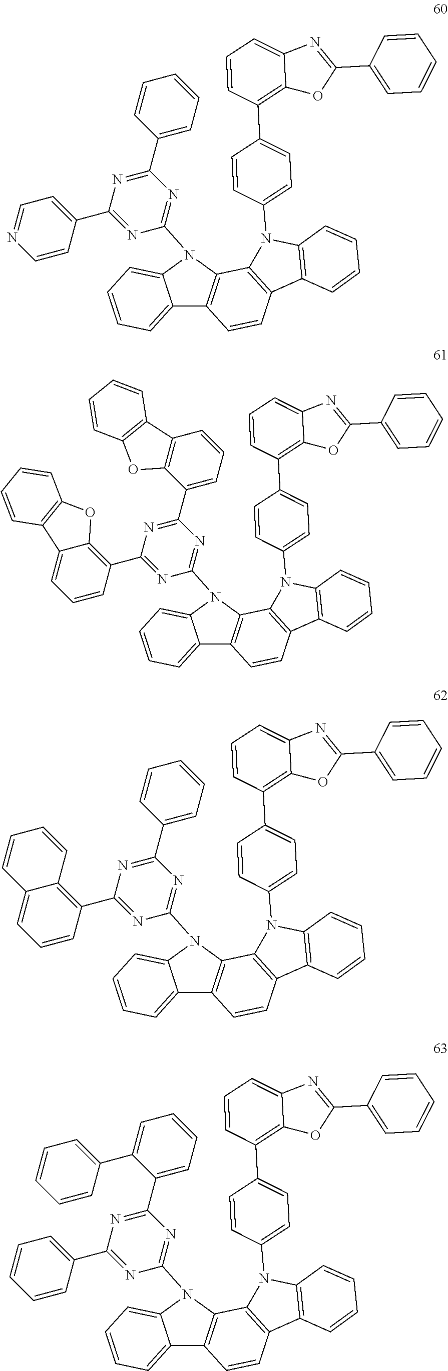 [SMILES: c1ccc(-c2nc(-c3ccncc3)nc(-n3c4ccccc4c4ccc5c6ccccc6n(-c6ccc(-c7cccc8nc(-c9ccccc9)oc78)cc6)c5c43)n2)cc1 ; c1ccc(-c2nc3cccc(-c4ccc(-n5c6ccccc6c6ccc7c8ccccc8n(-c8nc(-c9cccc%10c9oc9ccccc9%10)nc(-c9cccc%10c9oc9ccccc9%10)n8)c7c65)cc4)c3o2)cc1 ; c1ccc(-c2nc(-c3cccc4ccccc34)nc(-n3c4ccccc4c4ccc5c6ccccc6n(-c6ccc(-c7cccc8nc(-c9ccccc9)oc78)cc6)c5c43)n2)cc1 ; c1ccc(-c2nc(-c3ccccc3-c3ccccc3)nc(-n3c4ccccc4c4ccc5c6ccccc6n(-c6ccc(-c7cccc8nc(-c9ccccc9)oc78)cc6)c5c43)n2)cc1]

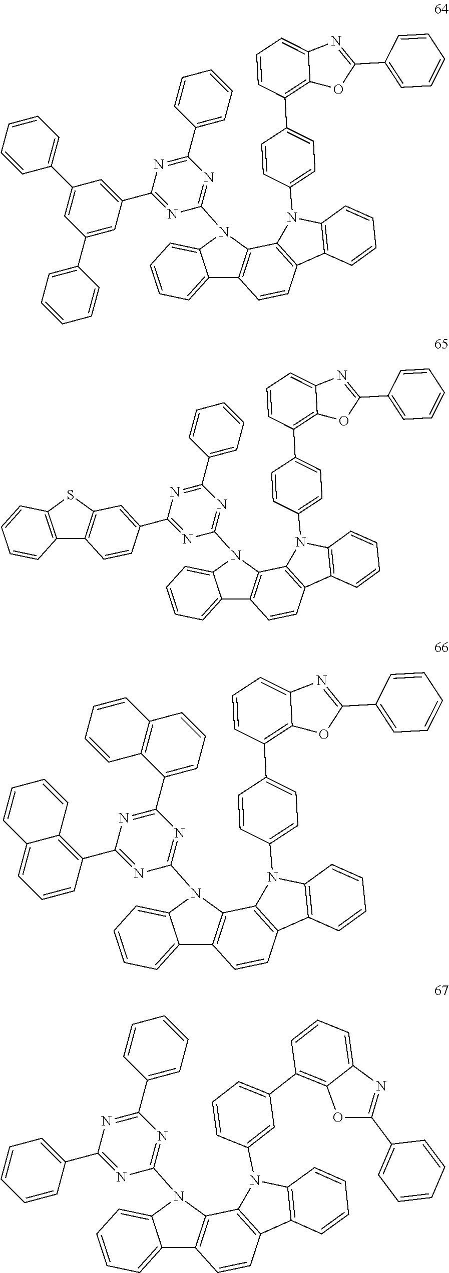 [SMILES: c1ccc(-c2cc(-c3ccccc3)cc(-c3nc(-c4ccccc4)nc(-n4c5ccccc5c5ccc6c7ccccc7n(-c7ccc(-c8cccc9nc(-c%10ccccc%10)oc89)cc7)c6c54)n3)c2)cc1 ; c1ccc(-c2nc(-c3ccc4c(c3)sc3ccccc34)nc(-n3c4ccccc4c4ccc5c6ccccc6n(-c6ccc(-c7cccc8nc(-c9ccccc9)oc78)cc6)c5c43)n2)cc1 ; c1ccc(-c2nc3cccc(-c4ccc(-n5c6ccccc6c6ccc7c8ccccc8n(-c8nc(-c9cccc%10ccccc9%10)nc(-c9cccc%10ccccc9%10)n8)c7c65)cc4)c3o2)cc1 ; c1ccc(-c2nc(-c3ccccc3)nc(-n3c4ccccc4c4ccc5c6ccccc6n(-c6cccc(-c7cccc8nc(-c9ccccc9)oc78)c6)c5c43)n2)cc1]

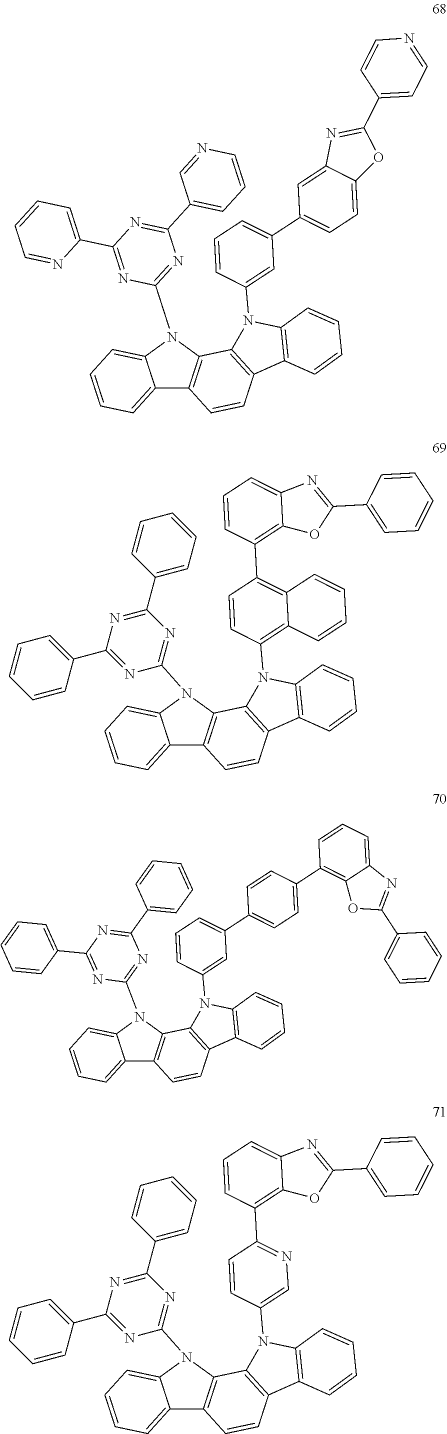 [SMILES: c1ccc(-c2nc(-c3cccnc3)nc(-n3c4ccccc4c4ccc5c6ccccc6n(-c6cccc(-c7ccc8oc(-c9ccncc9)nc8c7)c6)c5c43)n2)nc1 ; c1ccc(-c2nc(-c3ccccc3)nc(-n3c4ccccc4c4ccc5c6ccccc6n(-c6ccc(-c7cccc8nc(-c9ccccc9)oc78)c7ccccc67)c5c43)n2)cc1 ; c1ccc(-c2nc(-c3ccccc3)nc(-n3c4ccccc4c4ccc5c6ccccc6n(-c6cccc(-c7ccc(-c8cccc9nc(-c%10ccccc%10)oc89)cc7)c6)c5c43)n2)cc1 ; c1ccc(-c2nc(-c3ccccc3)nc(-n3c4ccccc4c4ccc5c6ccccc6n(-c6ccc(-c7cccc8nc(-c9ccccc9)oc78)nc6)c5c43)n2)cc1]

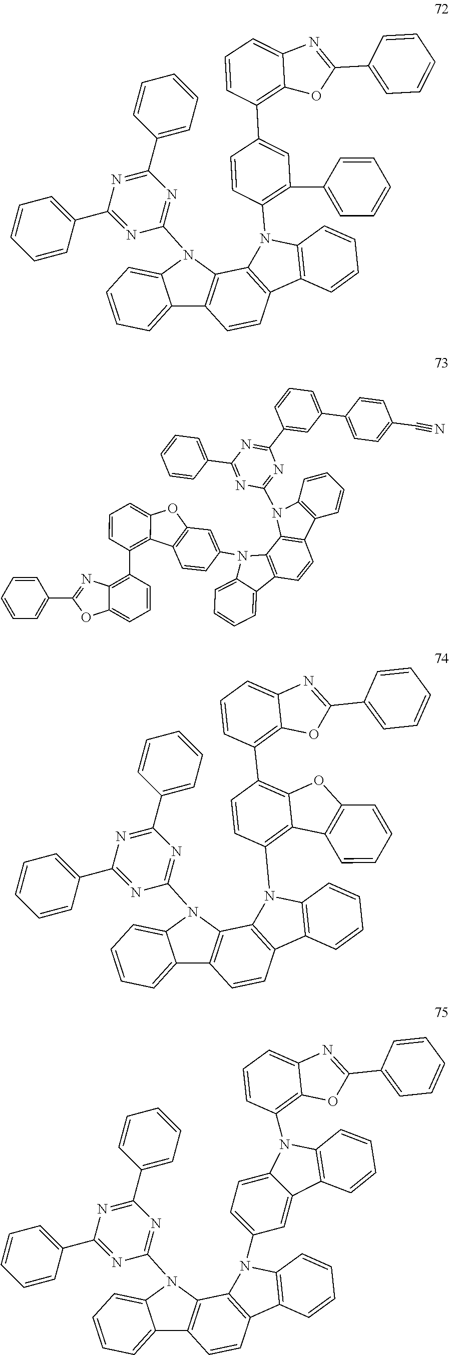 [SMILES: c1ccc(-c2nc(-c3ccccc3)nc(-n3c4ccccc4c4ccc5c6ccccc6n(-c6ccc(-c7cccc8nc(-c9ccccc9)oc78)cc6-c6ccccc6)c5c43)n2)cc1 ; N#Cc1ccc(-c2cccc(-c3nc(-c4ccccc4)nc(-n4c5ccccc5c5ccc6c7ccccc7n(-c7ccc8c(c7)oc7cccc(-c9cccc%10oc(-c%11ccccc%11)nc9%10)c78)c6c54)n3)c2)cc1 ; c1ccc(-c2nc(-c3ccccc3)nc(-n3c4ccccc4c4ccc5c6ccccc6n(-c6ccc(-c7cccc8nc(-c9ccccc9)oc78)c7oc8ccccc8c67)c5c43)n2)cc1 ; c1ccc(-c2nc(-c3ccccc3)nc(-n3c4ccccc4c4ccc5c6ccccc6n(-c6ccc7c(c6)c6ccccc6n7-c6cccc7nc(-c8ccccc8)oc67)c5c43)n2)cc1]

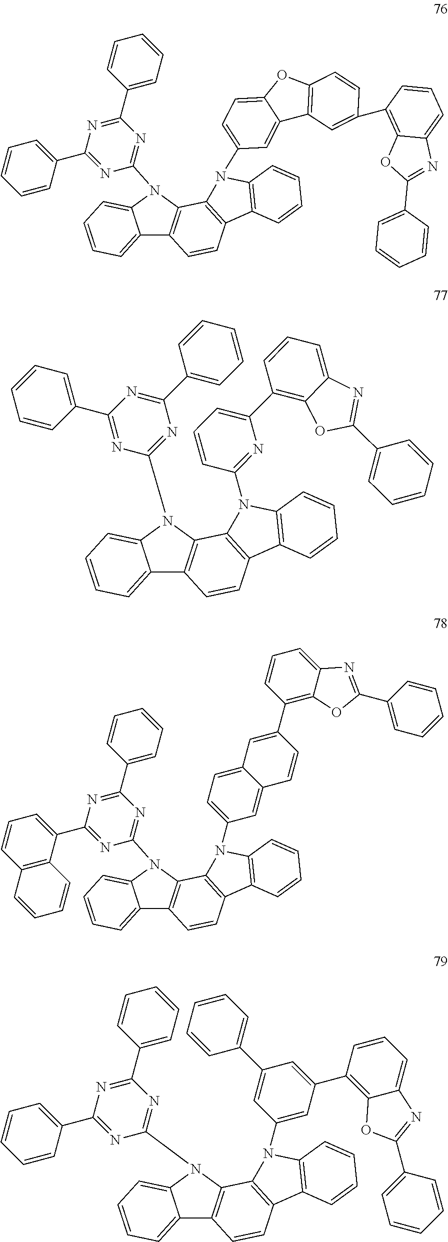 [SMILES: c1ccc(-c2nc(-c3ccccc3)nc(-n3c4ccccc4c4ccc5c6ccccc6n(-c6ccc7oc8ccc(-c9cccc%10nc(-c%11ccccc%11)oc9%10)cc8c7c6)c5c43)n2)cc1 ; c1ccc(-c2nc(-c3ccccc3)nc(-n3c4ccccc4c4ccc5c6ccccc6n(-c6cccc(-c7cccc8nc(-c9ccccc9)oc78)n6)c5c43)n2)cc1 ; c1ccc(-c2nc(-c3cccc4ccccc34)nc(-n3c4ccccc4c4ccc5c6ccccc6n(-c6ccc7cc(-c8cccc9nc(-c%10ccccc%10)oc89)ccc7c6)c5c43)n2)cc1 ; c1ccc(-c2cc(-c3cccc4nc(-c5ccccc5)oc34)cc(-n3c4ccccc4c4ccc5c6ccccc6n(-c6nc(-c7ccccc7)nc(-c7ccccc7)n6)c5c43)c2)cc1]

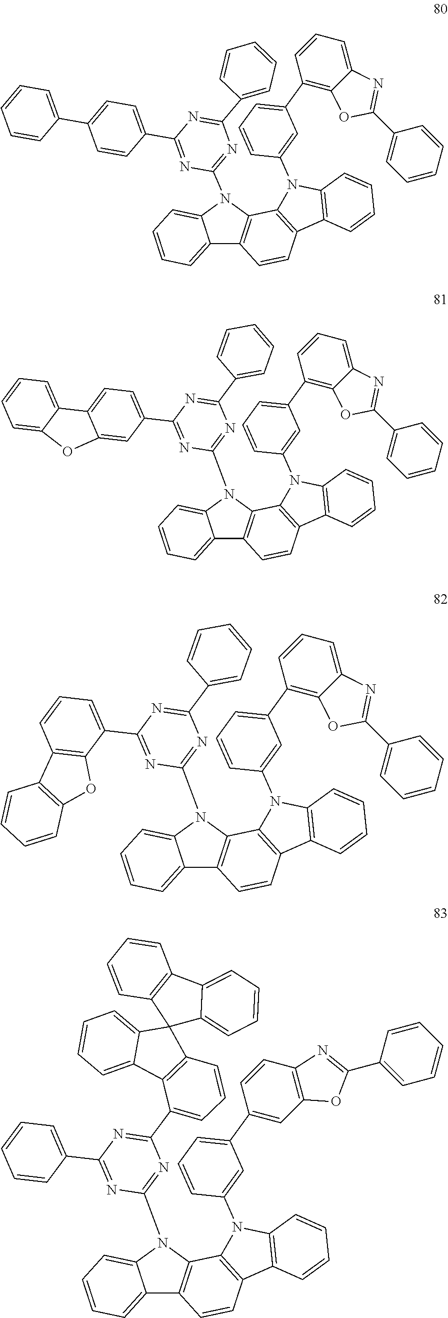 [SMILES: c1ccc(-c2ccc(-c3nc(-c4ccccc4)nc(-n4c5ccccc5c5ccc6c7ccccc7n(-c7cccc(-c8cccc9nc(-c%10ccccc%10)oc89)c7)c6c54)n3)cc2)cc1 ; c1ccc(-c2nc(-c3ccc4c(c3)oc3ccccc34)nc(-n3c4ccccc4c4ccc5c6ccccc6n(-c6cccc(-c7cccc8nc(-c9ccccc9)oc78)c6)c5c43)n2)cc1 ; c1ccc(-c2nc(-c3cccc4c3oc3ccccc34)nc(-n3c4ccccc4c4ccc5c6ccccc6n(-c6cccc(-c7cccc8nc(-c9ccccc9)oc78)c6)c5c43)n2)cc1 ; c1ccc(-c2nc(-c3cccc4c3-c3ccccc3C43c4ccccc4-c4ccccc43)nc(-n3c4ccccc4c4ccc5c6ccccc6n(-c6cccc(-c7ccc8nc(-c9ccccc9)oc8c7)c6)c5c43)n2)cc1]

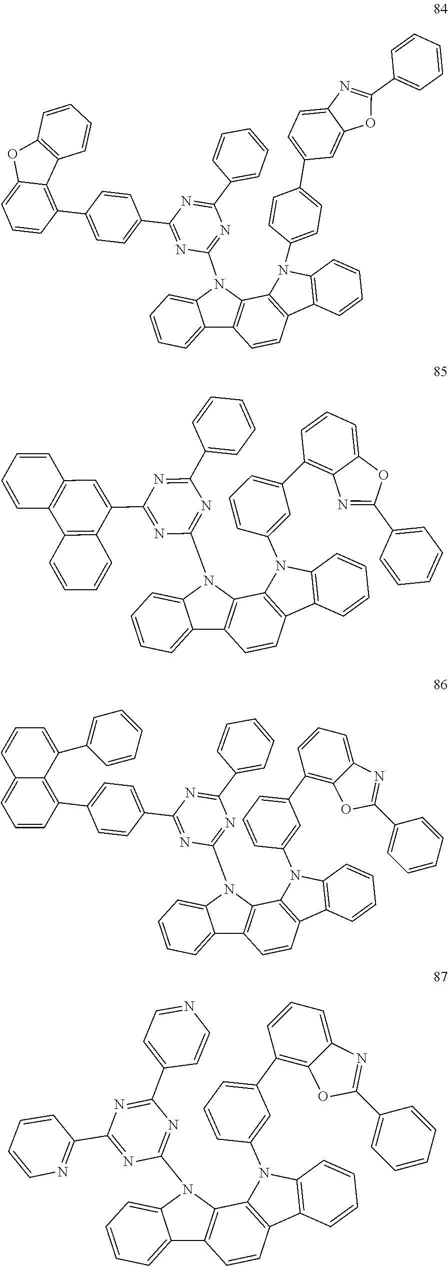 [SMILES: c1ccc(-c2nc(-c3ccc(-c4cccc5oc6ccccc6c45)cc3)nc(-n3c4ccccc4c4ccc5c6ccccc6n(-c6ccc(-c7ccc8nc(-c9ccccc9)oc8c7)cc6)c5c43)n2)cc1 ; c1ccc(-c2nc(-c3cc4ccccc4c4ccccc34)nc(-n3c4ccccc4c4ccc5c6ccccc6n(-c6cccc(-c7cccc8oc(-c9ccccc9)nc78)c6)c5c43)n2)cc1 ; c1ccc(-c2nc(-c3ccc(-c4cccc5cccc(-c6ccccc6)c45)cc3)nc(-n3c4ccccc4c4ccc5c6ccccc6n(-c6cccc(-c7cccc8nc(-c9ccccc9)oc78)c6)c5c43)n2)cc1 ; c1ccc(-c2nc3cccc(-c4cccc(-n5c6ccccc6c6ccc7c8ccccc8n(-c8nc(-c9ccncc9)nc(-c9ccccn9)n8)c7c65)c4)c3o2)cc1]

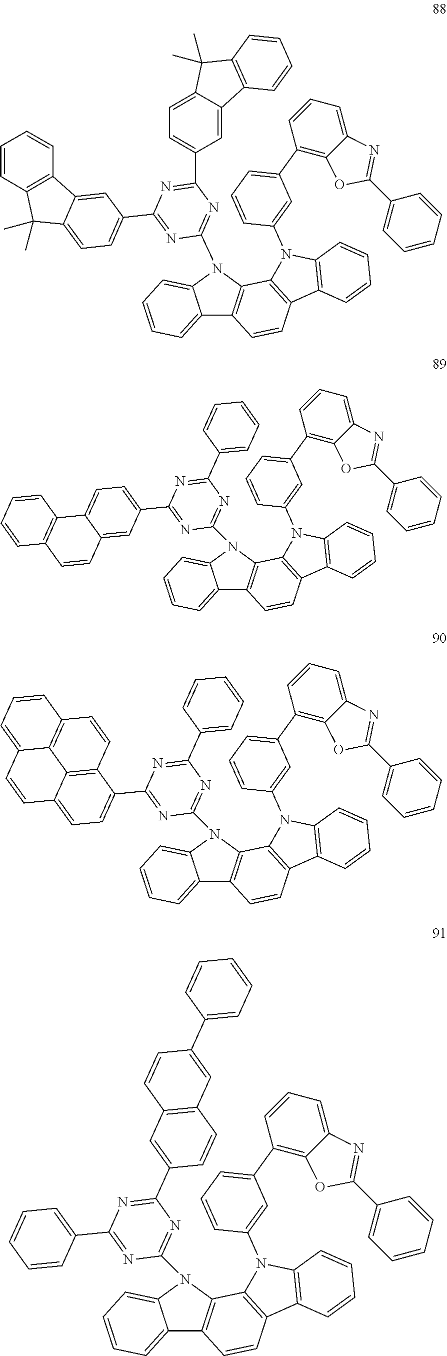

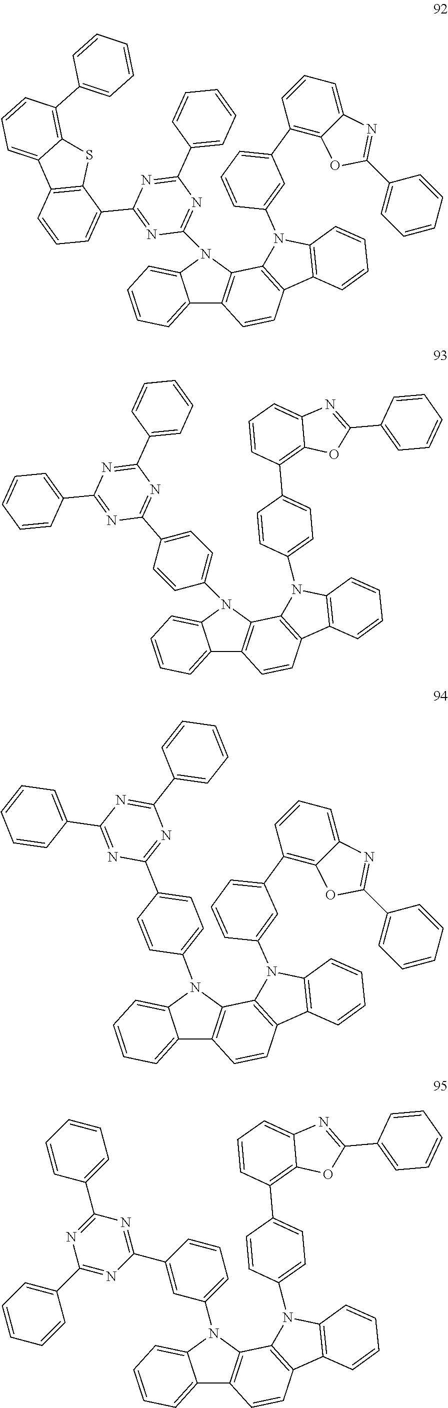 [SMILES: c1ccc(-c2nc(-c3cccc4c3sc3c(-c5ccccc5)cccc34)nc(-n3c4ccccc4c4ccc5c6ccccc6n(-c6cccc(-c7cccc8nc(-c9ccccc9)oc78)c6)c5c43)n2)cc1 ; c1ccc(-c2nc(-c3ccccc3)nc(-c3ccc(-n4c5ccccc5c5ccc6c7ccccc7n(-c7ccc(-c8cccc9nc(-c%10ccccc%10)oc89)cc7)c6c54)cc3)n2)cc1 ; c1ccc(-c2nc(-c3ccccc3)nc(-c3ccc(-n4c5ccccc5c5ccc6c7ccccc7n(-c7cccc(-c8cccc9nc(-c%10ccccc%10)oc89)c7)c6c54)cc3)n2)cc1 ; c1ccc(-c2nc(-c3ccccc3)nc(-c3cccc(-n4c5ccccc5c5ccc6c7ccccc7n(-c7ccc(-c8cccc9nc(-c%10ccccc%10)oc89)cc7)c6c54)c3)n2)cc1]

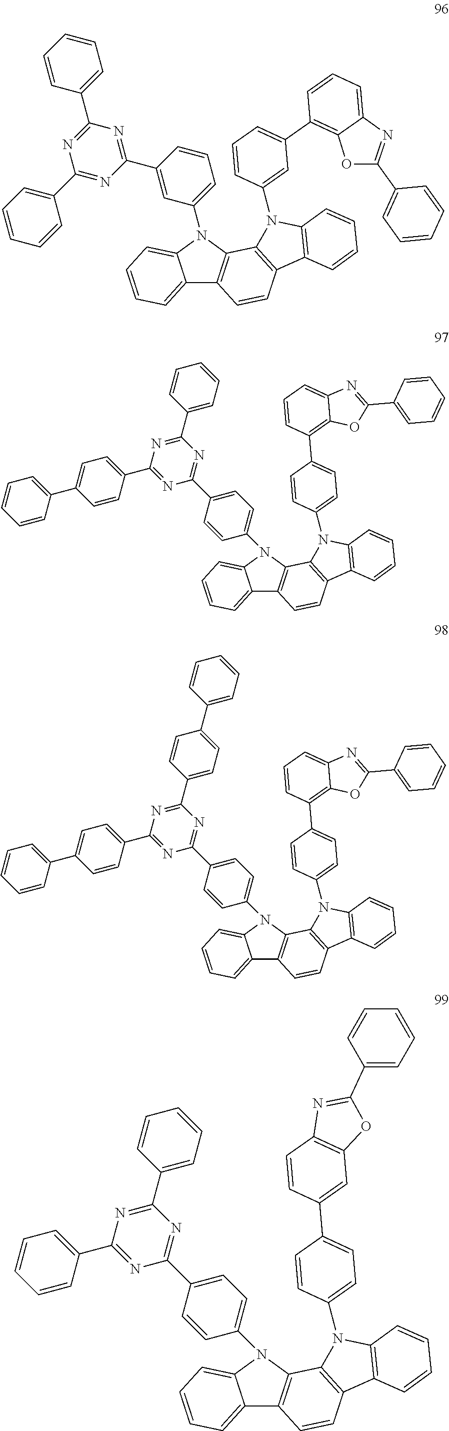

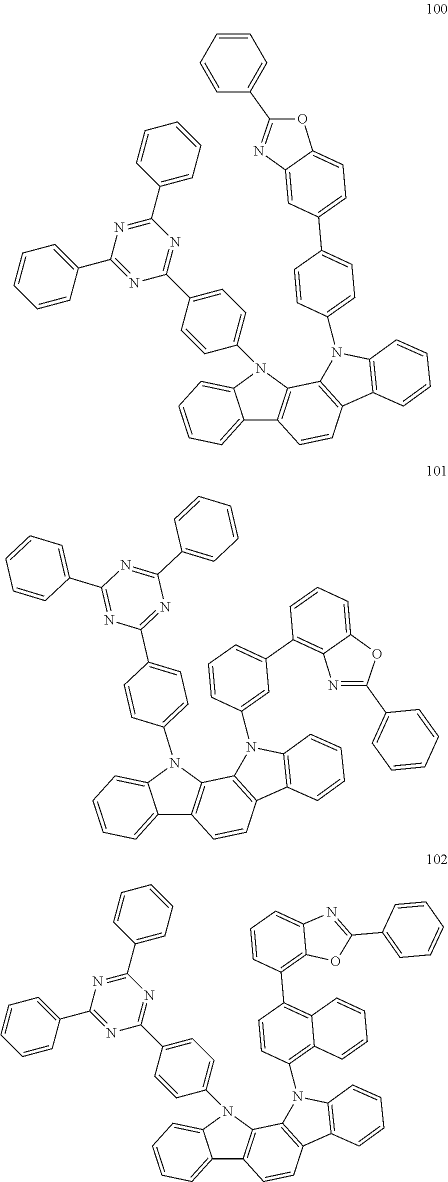 [SMILES: c1ccc(-c2nc(-c3ccccc3)nc(-c3ccc(-n4c5ccccc5c5ccc6c7ccccc7n(-c7ccc(-c8ccc9oc(-c%10ccccc%10)nc9c8)cc7)c6c54)cc3)n2)cc1 ; c1ccc(-c2nc(-c3ccccc3)nc(-c3ccc(-n4c5ccccc5c5ccc6c7ccccc7n(-c7cccc(-c8cccc9oc(-c%10ccccc%10)nc89)c7)c6c54)cc3)n2)cc1 ; c1ccc(-c2nc(-c3ccccc3)nc(-c3ccc(-n4c5ccccc5c5ccc6c7ccccc7n(-c7ccc(-c8cccc9nc(-c%10ccccc%10)oc89)c8ccccc78)c6c54)cc3)n2)cc1]

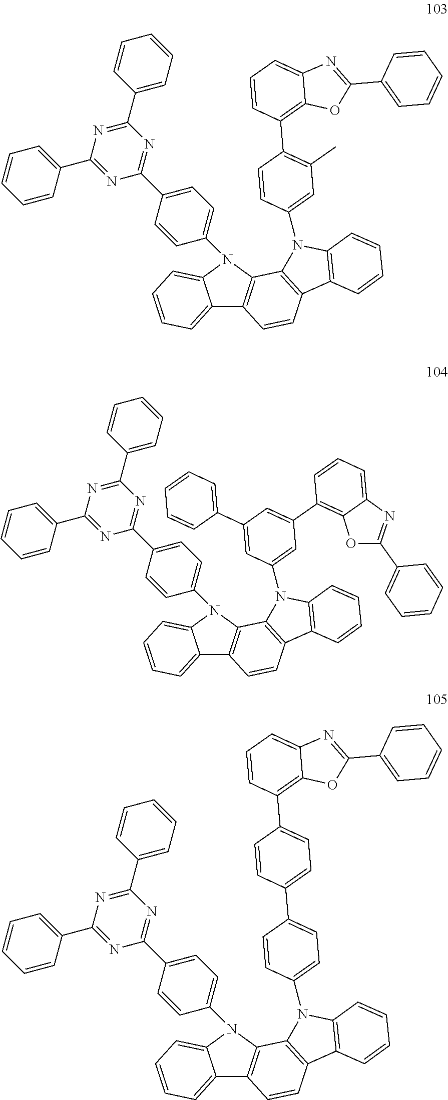 [SMILES: Cc1cc(-n2c3ccccc3c3ccc4c5ccccc5n(-c5ccc(-c6nc(-c7ccccc7)nc(-c7ccccc7)n6)cc5)c4c32)ccc1-c1cccc2nc(-c3ccccc3)oc12 ; c1ccc(-c2cc(-c3cccc4nc(-c5ccccc5)oc34)cc(-n3c4ccccc4c4ccc5c6ccccc6n(-c6ccc(-c7nc(-c8ccccc8)nc(-c8ccccc8)n7)cc6)c5c43)c2)cc1 ; c1ccc(-c2nc(-c3ccccc3)nc(-c3ccc(-n4c5ccccc5c5ccc6c7ccccc7n(-c7ccc(-c8ccc(-c9cccc%10nc(-c%11ccccc%11)oc9%10)cc8)cc7)c6c54)cc3)n2)cc1]

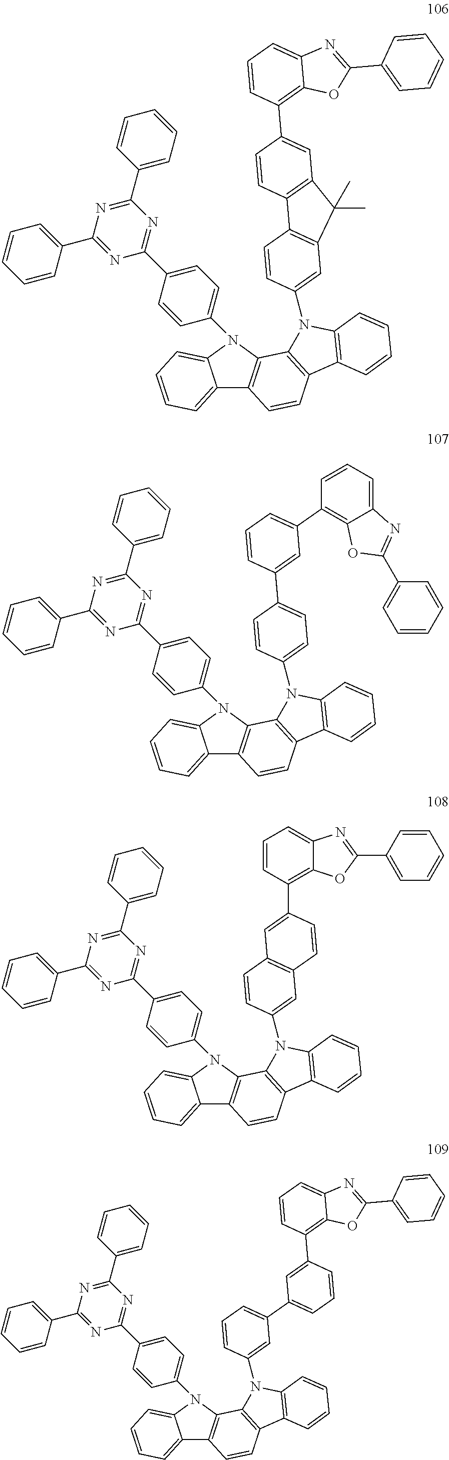

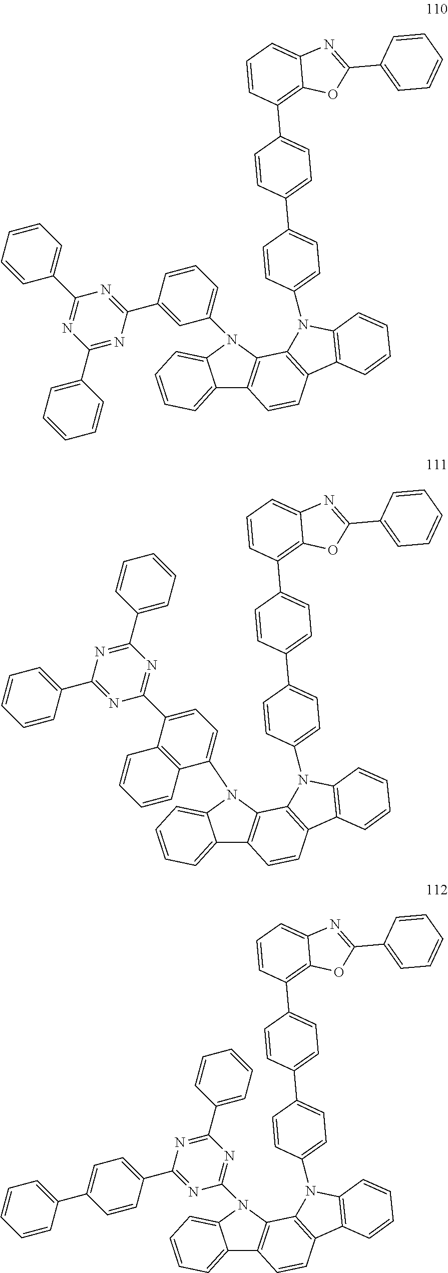 [SMILES: c1ccc(-c2nc(-c3ccccc3)nc(-c3cccc(-n4c5ccccc5c5ccc6c7ccccc7n(-c7ccc(-c8ccc(-c9cccc%10nc(-c%11ccccc%11)oc9%10)cc8)cc7)c6c54)c3)n2)cc1 ; c1ccc(-c2nc(-c3ccccc3)nc(-c3ccc(-n4c5ccccc5c5ccc6c7ccccc7n(-c7ccc(-c8ccc(-c9cccc%10nc(-c%11ccccc%11)oc9%10)cc8)cc7)c6c54)c4ccccc34)n2)cc1 ; c1ccc(-c2ccc(-c3nc(-c4ccccc4)nc(-n4c5ccccc5c5ccc6c7ccccc7n(-c7ccc(-c8ccc(-c9cccc%10nc(-c%11ccccc%11)oc9%10)cc8)cc7)c6c54)n3)cc2)cc1]

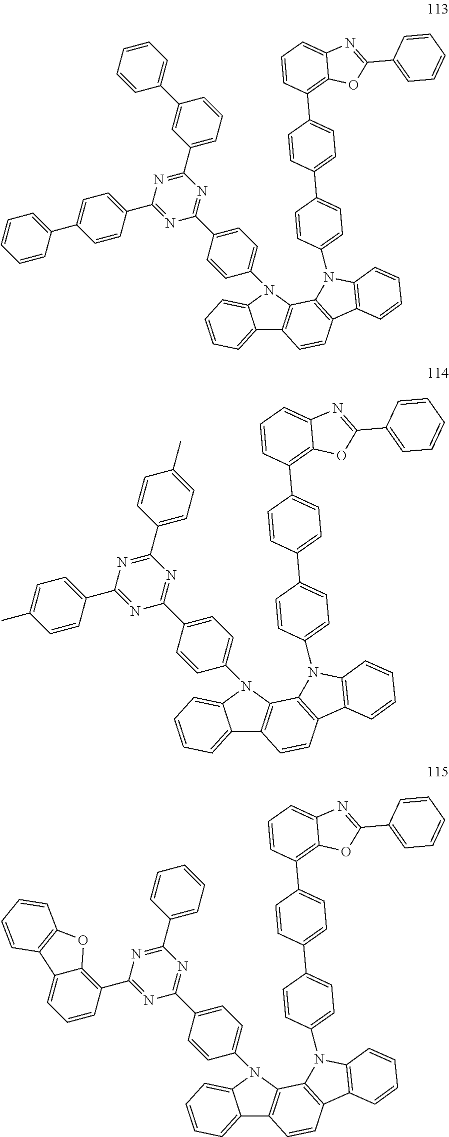 [SMILES: c1ccc(-c2ccc(-c3nc(-c4ccc(-n5c6ccccc6c6ccc7c8ccccc8n(-c8ccc(-c9ccc(-c%10cccc%11nc(-c%12ccccc%12)oc%10%11)cc9)cc8)c7c65)cc4)nc(-c4cccc(-c5ccccc5)c4)n3)cc2)cc1 ; Cc1ccc(-c2nc(-c3ccc(C)cc3)nc(-c3ccc(-n4c5ccccc5c5ccc6c7ccccc7n(-c7ccc(-c8ccc(-c9cccc%10nc(-c%11ccccc%11)oc9%10)cc8)cc7)c6c54)cc3)n2)cc1 ; c1ccc(-c2nc(-c3ccc(-n4c5ccccc5c5ccc6c7ccccc7n(-c7ccc(-c8ccc(-c9cccc%10nc(-c%11ccccc%11)oc9%10)cc8)cc7)c6c54)cc3)nc(-c3cccc4c3oc3ccccc34)n2)cc1]

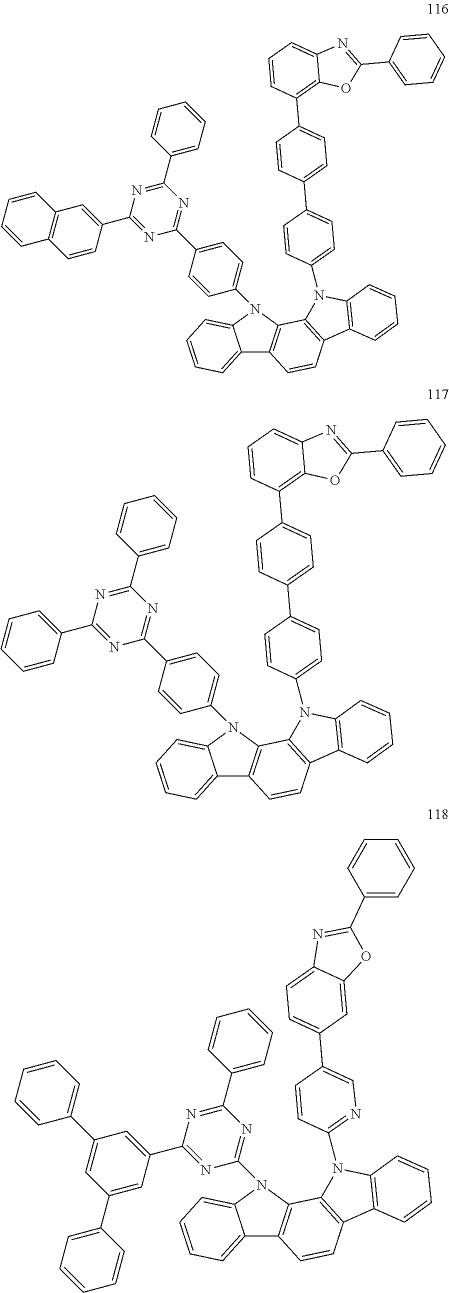 [SMILES: c1ccc(-c2nc(-c3ccc(-n4c5ccccc5c5ccc6c7ccccc7n(-c7ccc(-c8ccc(-c9cccc%10nc(-c%11ccccc%11)oc9%10)cc8)cc7)c6c54)cc3)nc(-c3ccc4ccccc4c3)n2)cc1 ; c1ccc(-c2nc(-c3ccccc3)nc(-c3ccc(-n4c5ccccc5c5ccc6c7ccccc7n(-c7ccc(-c8ccc(-c9cccc%10nc(-c%11ccccc%11)oc9%10)cc8)cc7)c6c54)cc3)n2)cc1 ; c1ccc(-c2cc(-c3ccccc3)cc(-c3nc(-c4ccccc4)nc(-n4c5ccccc5c5ccc6c7ccccc7n(-c7ccc(-c8ccc9nc(-c%10ccccc%10)oc9c8)cn7)c6c54)n3)c2)cc1]

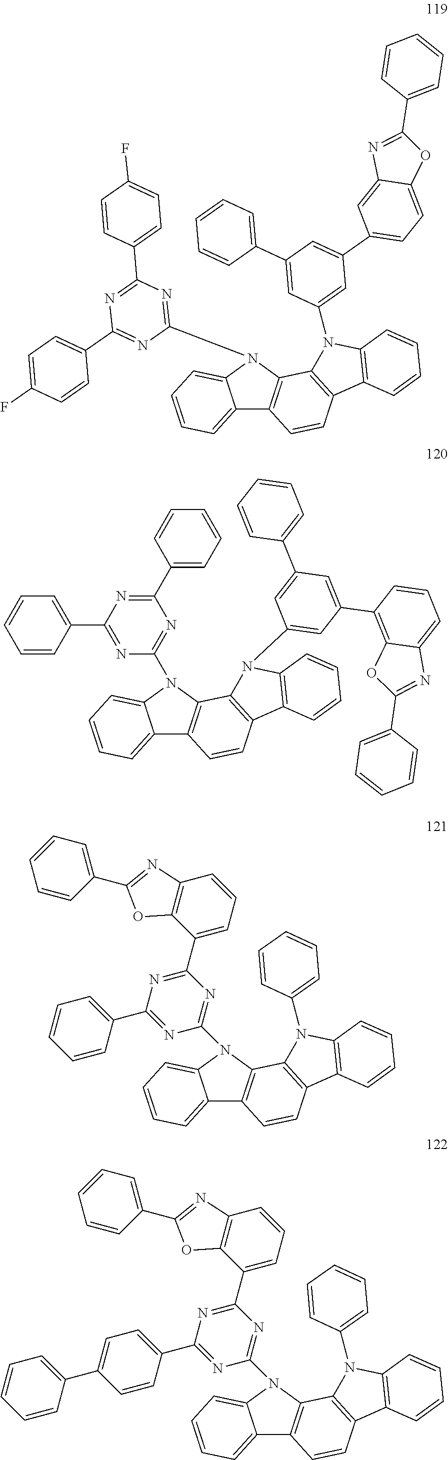 [SMILES: Fc1ccc(-c2nc(-c3ccc(F)cc3)nc(-n3c4ccccc4c4ccc5c6ccccc6n(-c6cc(-c7ccccc7)cc(-c7ccc8oc(-c9ccccc9)nc8c7)c6)c5c43)n2)cc1 ; c1ccc(-c2cc(-c3cccc4nc(-c5ccccc5)oc34)cc(-n3c4ccccc4c4ccc5c6ccccc6n(-c6nc(-c7ccccc7)nc(-c7ccccc7)n6)c5c43)c2)cc1 ; c1ccc(-c2nc(-c3cccc4nc(-c5ccccc5)oc34)nc(-n3c4ccccc4c4ccc5c6ccccc6n(-c6ccccc6)c5c43)n2)cc1 ; c1ccc(-c2ccc(-c3nc(-c4cccc5nc(-c6ccccc6)oc45)nc(-n4c5ccccc5c5ccc6c7ccccc7n(-c7ccccc7)c6c54)n3)cc2)cc1]

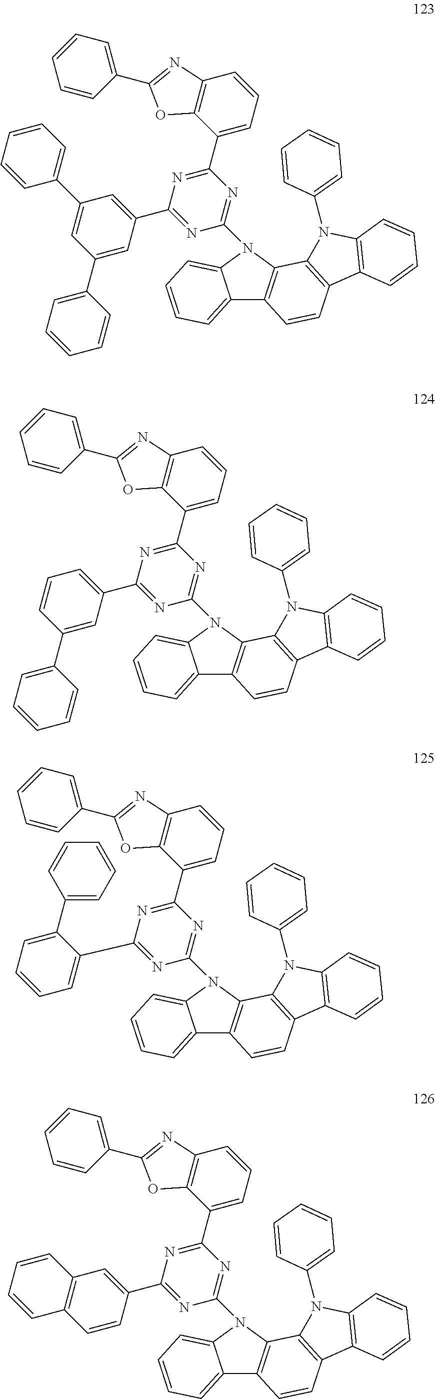

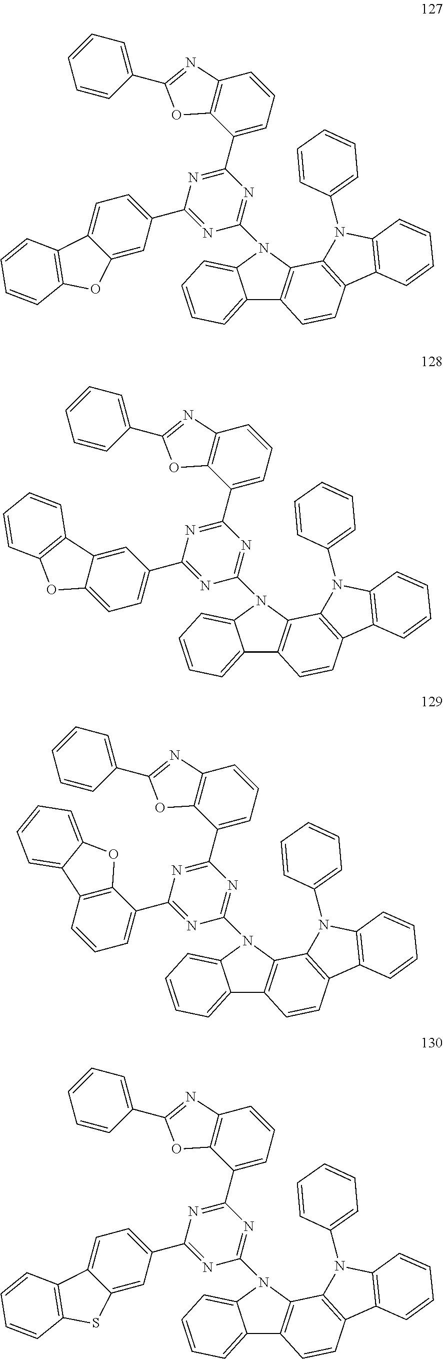 [SMILES: c1ccc(-c2nc3cccc(-c4nc(-c5ccc6c(c5)oc5ccccc56)nc(-n5c6ccccc6c6ccc7c8ccccc8n(-c8ccccc8)c7c65)n4)c3o2)cc1 ; c1ccc(-c2nc3cccc(-c4nc(-c5ccc6oc7ccccc7c6c5)nc(-n5c6ccccc6c6ccc7c8ccccc8n(-c8ccccc8)c7c65)n4)c3o2)cc1 ; c1ccc(-c2nc3cccc(-c4nc(-c5cccc6c5oc5ccccc56)nc(-n5c6ccccc6c6ccc7c8ccccc8n(-c8ccccc8)c7c65)n4)c3o2)cc1 ; c1ccc(-c2nc3cccc(-c4nc(-c5ccc6c(c5)sc5ccccc56)nc(-n5c6ccccc6c6ccc7c8ccccc8n(-c8ccccc8)c7c65)n4)c3o2)cc1]

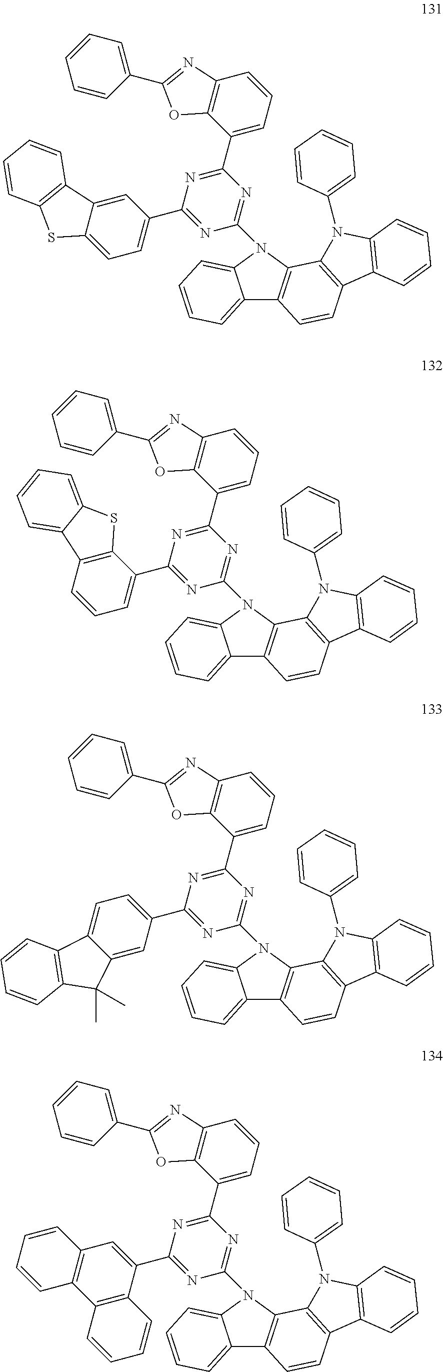 [SMILES: c1ccc(-c2nc3cccc(-c4nc(-c5ccc6sc7ccccc7c6c5)nc(-n5c6ccccc6c6ccc7c8ccccc8n(-c8ccccc8)c7c65)n4)c3o2)cc1 ; c1ccc(-c2nc3cccc(-c4nc(-c5cccc6c5sc5ccccc56)nc(-n5c6ccccc6c6ccc7c8ccccc8n(-c8ccccc8)c7c65)n4)c3o2)cc1 ; CC1(C)c2ccccc2-c2ccc(-c3nc(-c4cccc5nc(-c6ccccc6)oc45)nc(-n4c5ccccc5c5ccc6c7ccccc7n(-c7ccccc7)c6c54)n3)cc21 ; c1ccc(-c2nc3cccc(-c4nc(-c5cc6ccccc6c6ccccc56)nc(-n5c6ccccc6c6ccc7c8ccccc8n(-c8ccccc8)c7c65)n4)c3o2)cc1]

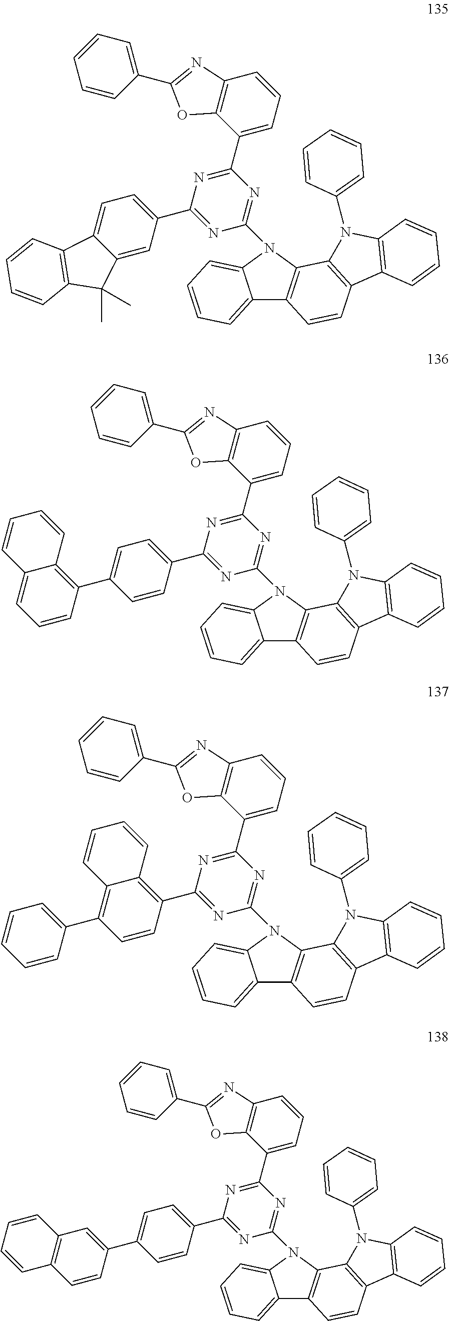 [SMILES: CC1(C)c2ccccc2-c2ccc(-c3nc(-c4cccc5nc(-c6ccccc6)oc45)nc(-n4c5ccccc5c5ccc6c7ccccc7n(-c7ccccc7)c6c54)n3)cc21 ; c1ccc(-c2nc3cccc(-c4nc(-c5ccc(-c6cccc7ccccc67)cc5)nc(-n5c6ccccc6c6ccc7c8ccccc8n(-c8ccccc8)c7c65)n4)c3o2)cc1 ; c1ccc(-c2nc3cccc(-c4nc(-c5ccc(-c6ccccc6)c6ccccc56)nc(-n5c6ccccc6c6ccc7c8ccccc8n(-c8ccccc8)c7c65)n4)c3o2)cc1 ; c1ccc(-c2nc3cccc(-c4nc(-c5ccc(-c6ccc7ccccc7c6)cc5)nc(-n5c6ccccc6c6ccc7c8ccccc8n(-c8ccccc8)c7c65)n4)c3o2)cc1]

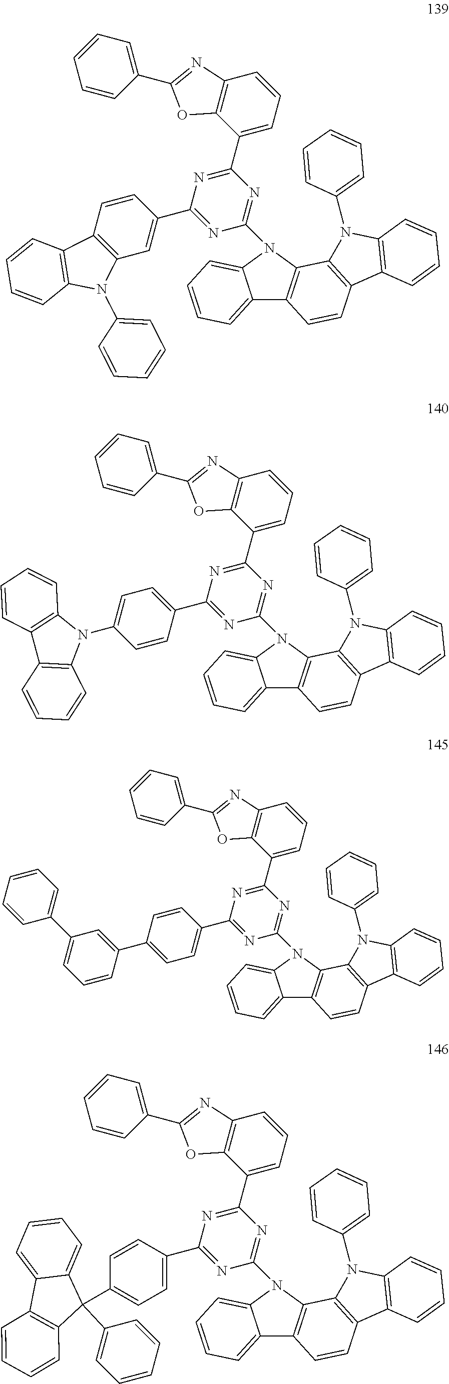 [SMILES: c1ccc(-c2nc3cccc(-c4nc(-c5ccc6c7ccccc7n(-c7ccccc7)c6c5)nc(-n5c6ccccc6c6ccc7c8ccccc8n(-c8ccccc8)c7c65)n4)c3o2)cc1 ; c1ccc(-c2nc3cccc(-c4nc(-c5ccc(-n6c7ccccc7c7ccccc76)cc5)nc(-n5c6ccccc6c6ccc7c8ccccc8n(-c8ccccc8)c7c65)n4)c3o2)cc1 ; c1ccc(-c2cccc(-c3ccc(-c4nc(-c5cccc6nc(-c7ccccc7)oc56)nc(-n5c6ccccc6c6ccc7c8ccccc8n(-c8ccccc8)c7c65)n4)cc3)c2)cc1 ; c1ccc(-c2nc3cccc(-c4nc(-c5ccc(C6(c7ccccc7)c7ccccc7-c7ccccc76)cc5)nc(-n5c6ccccc6c6ccc7c8ccccc8n(-c8ccccc8)c7c65)n4)c3o2)cc1]

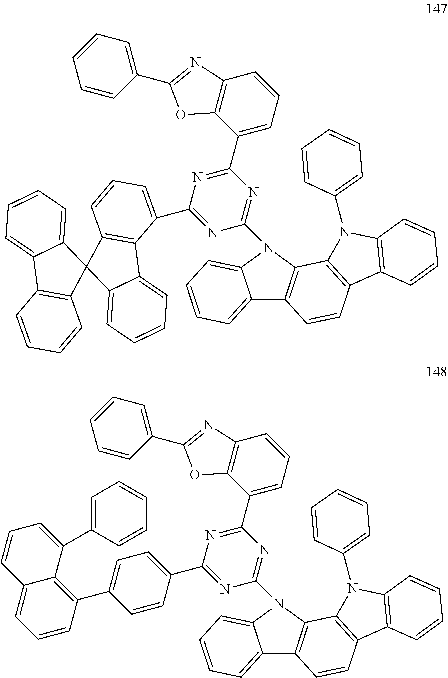 [SMILES: c1ccc(-c2nc3cccc(-c4nc(-c5cccc6c5-c5ccccc5C65c6ccccc6-c6ccccc65)nc(-n5c6ccccc6c6ccc7c8ccccc8n(-c8ccccc8)c7c65)n4)c3o2)cc1 ; c1ccc(-c2nc3cccc(-c4nc(-c5ccc(-c6cccc7cccc(-c8ccccc8)c67)cc5)nc(-n5c6ccccc6c6ccc7c8ccccc8n(-c8ccccc8)c7c65)n4)c3o2)cc1]

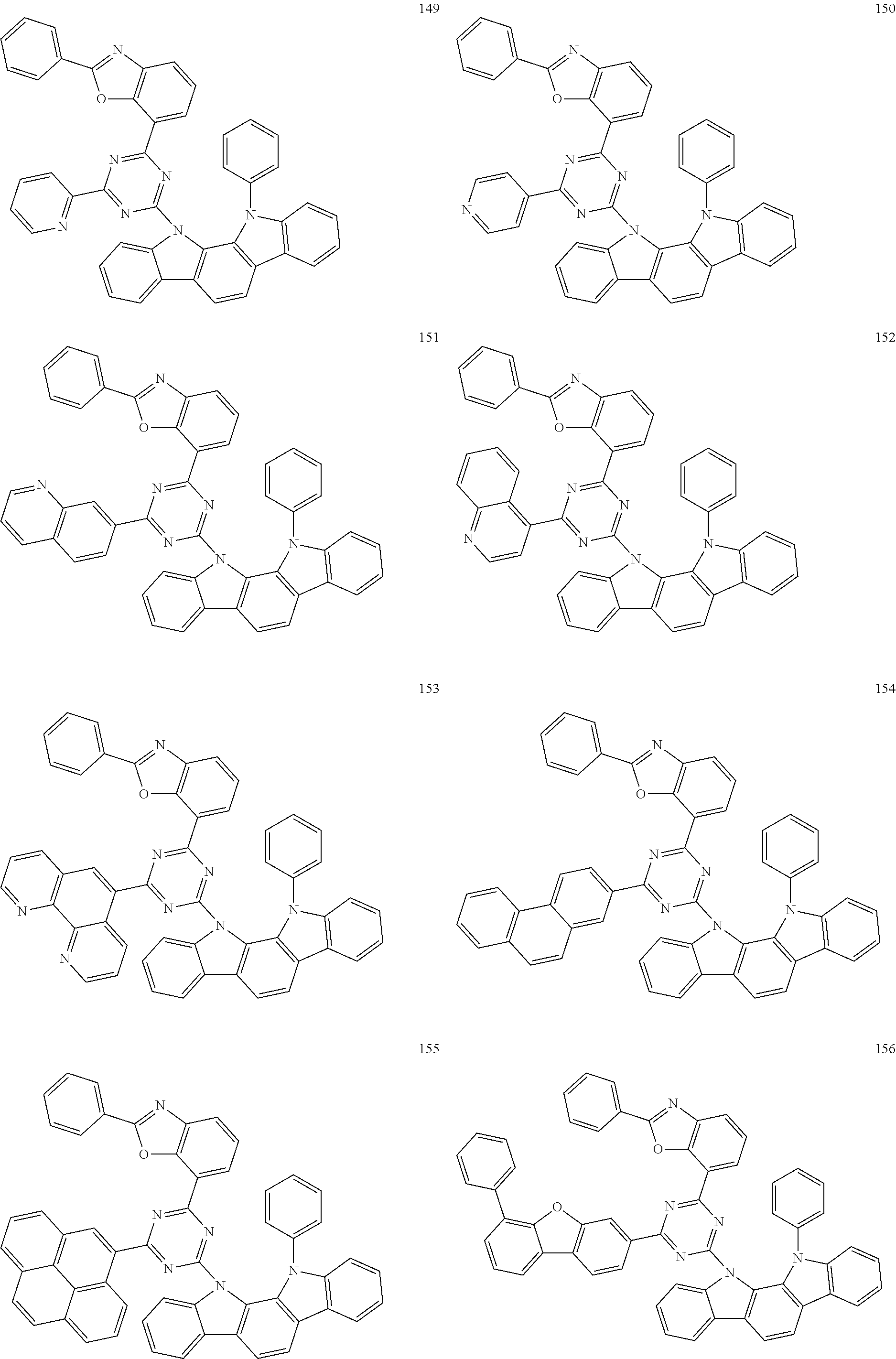

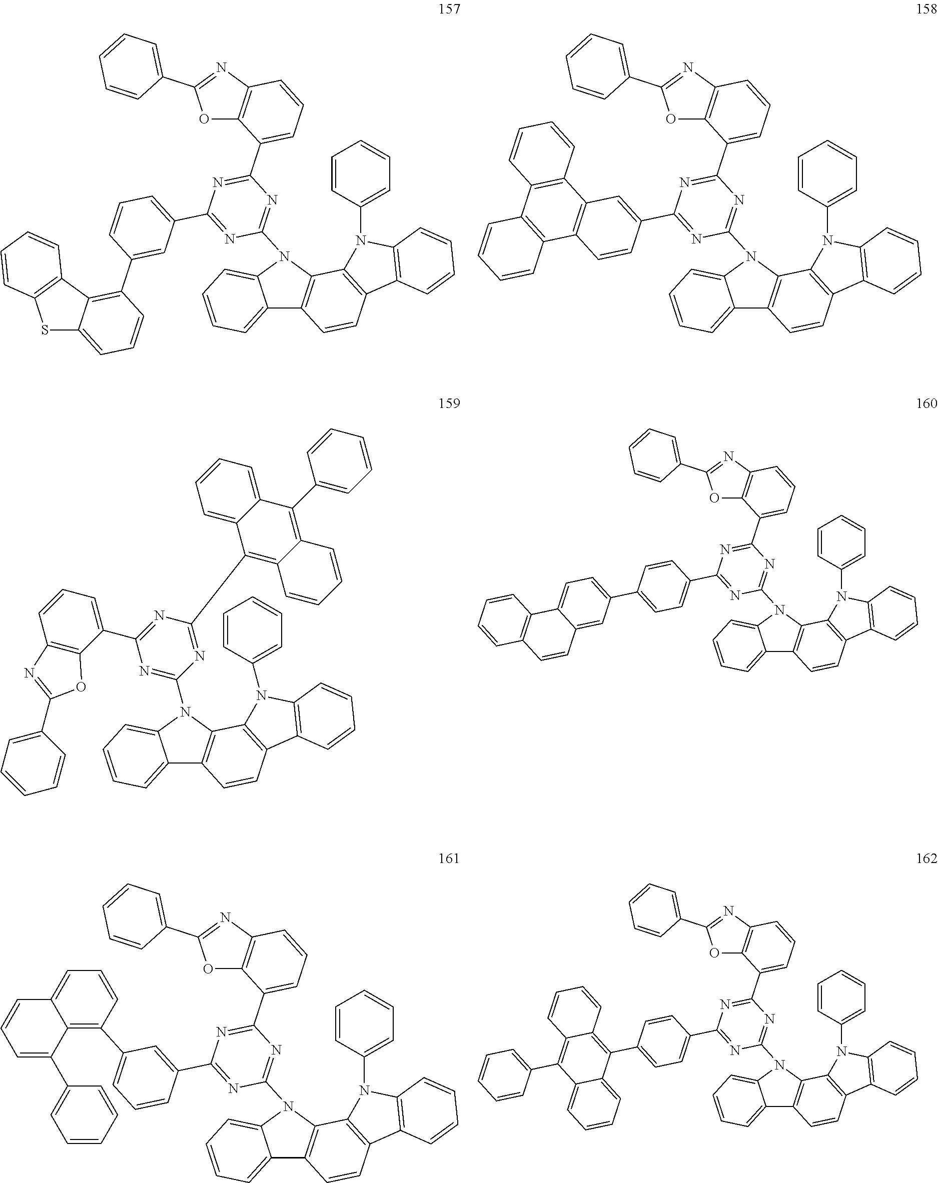

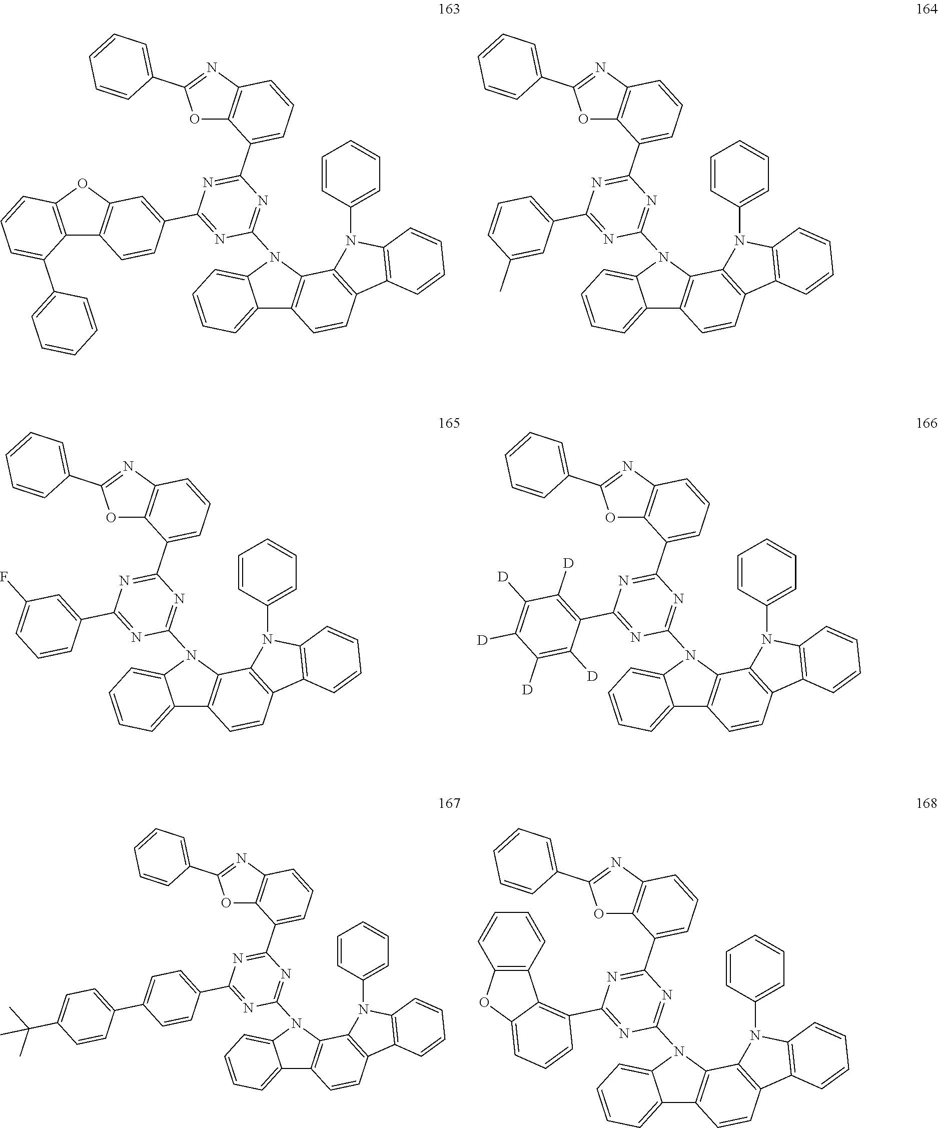

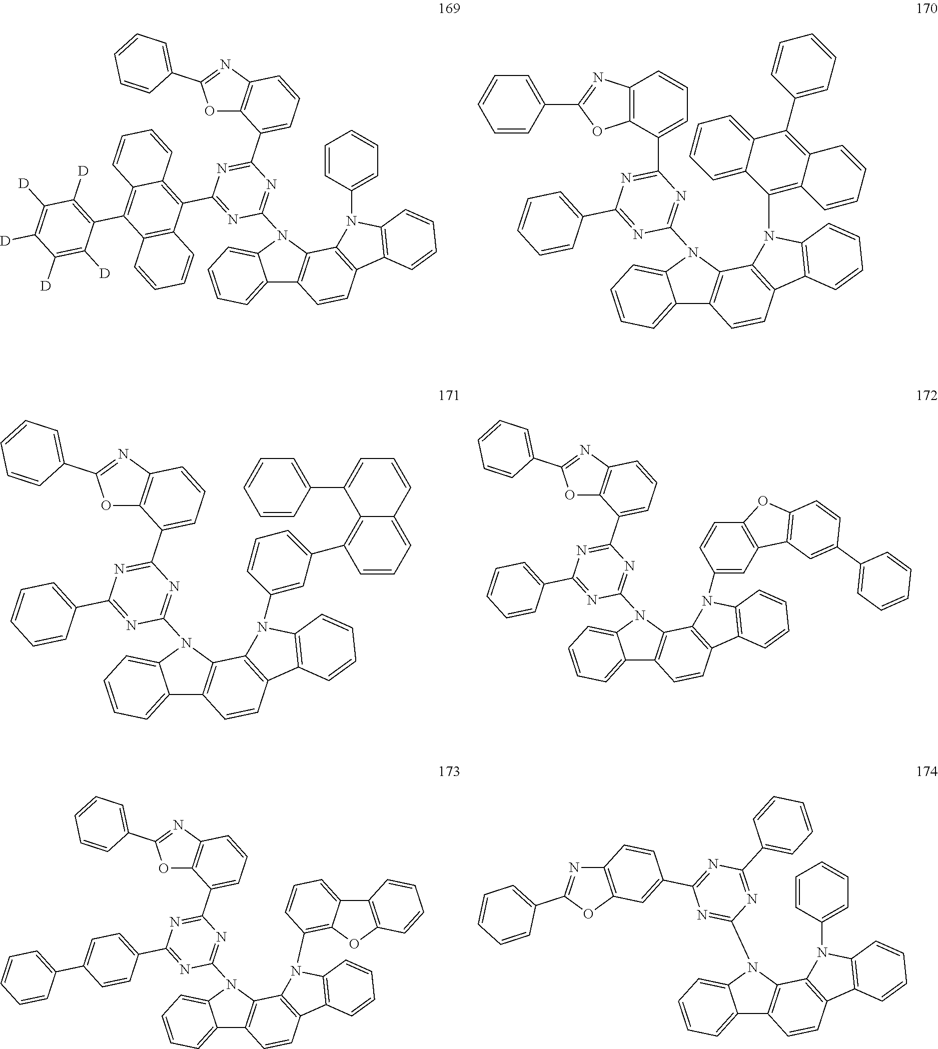

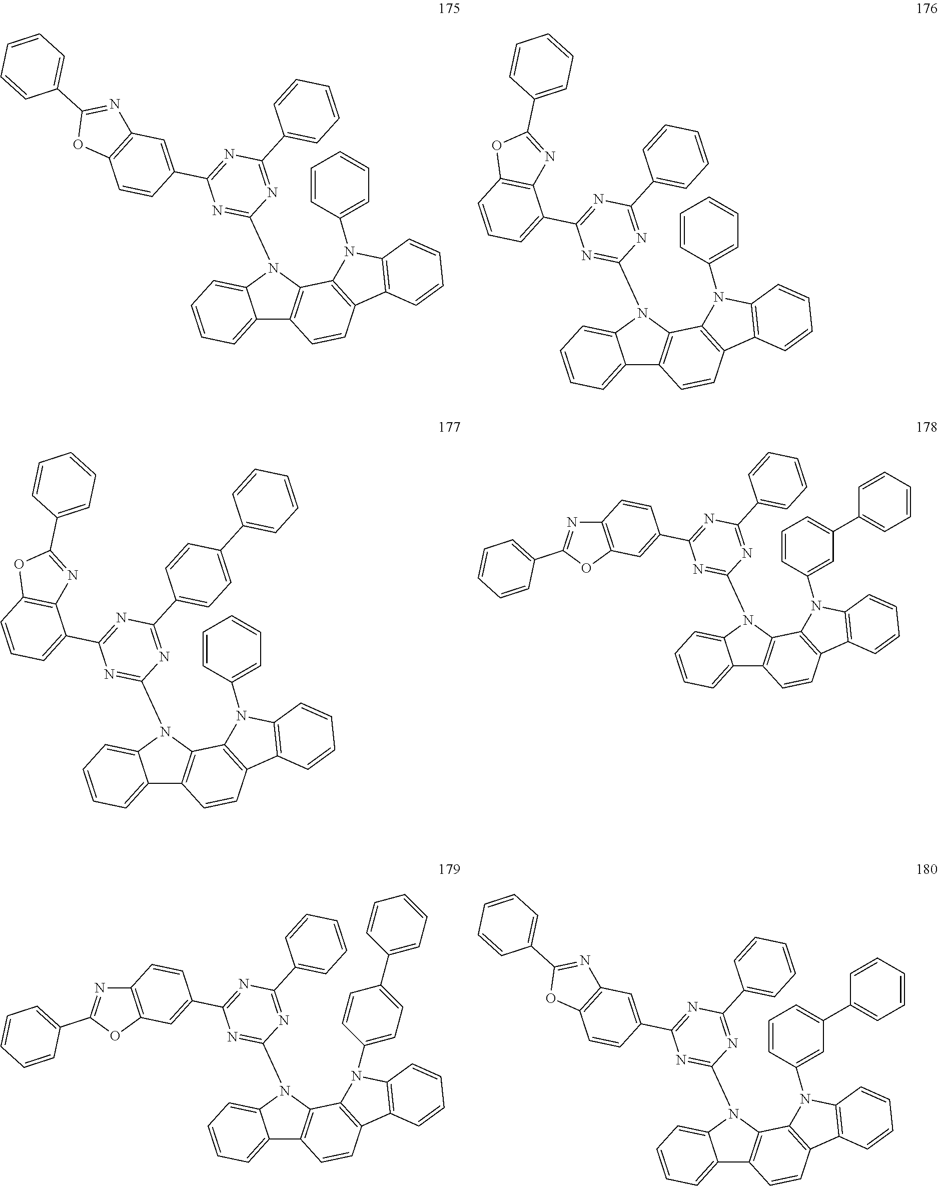

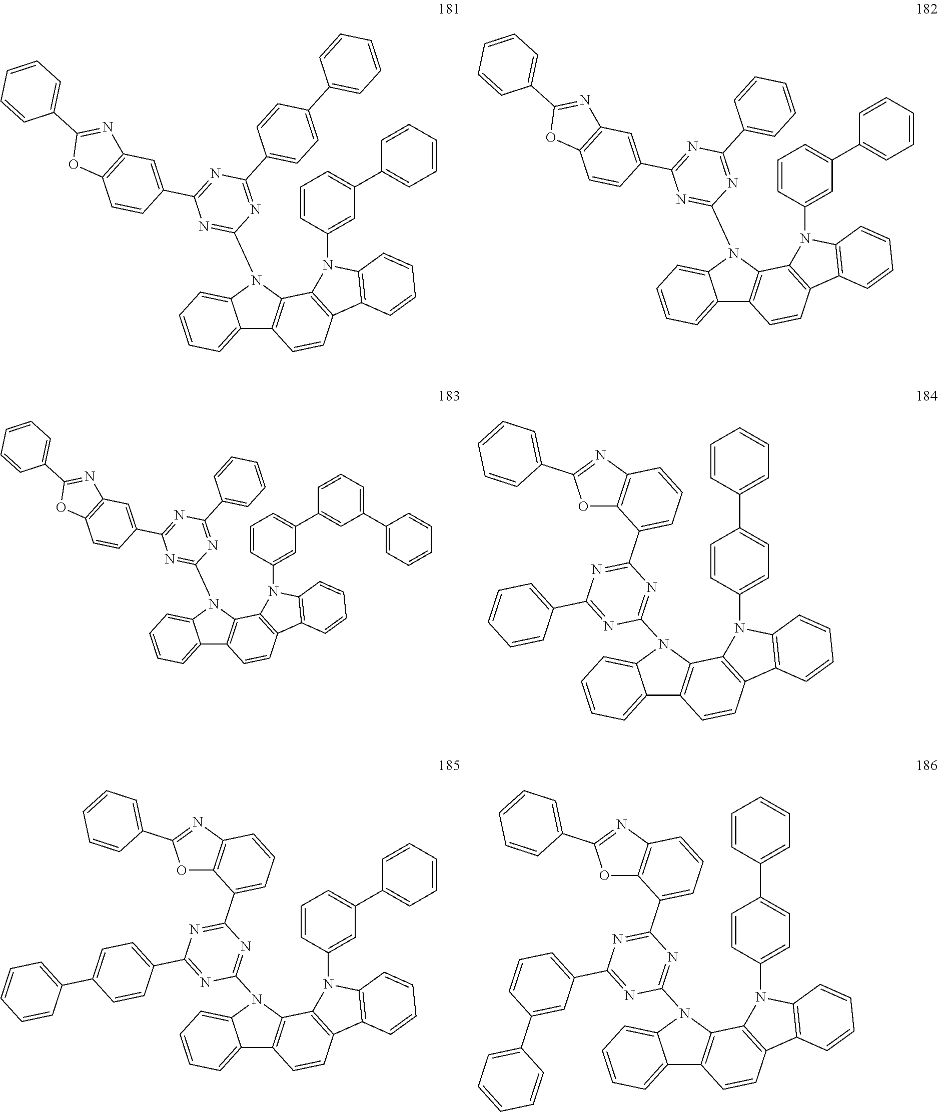

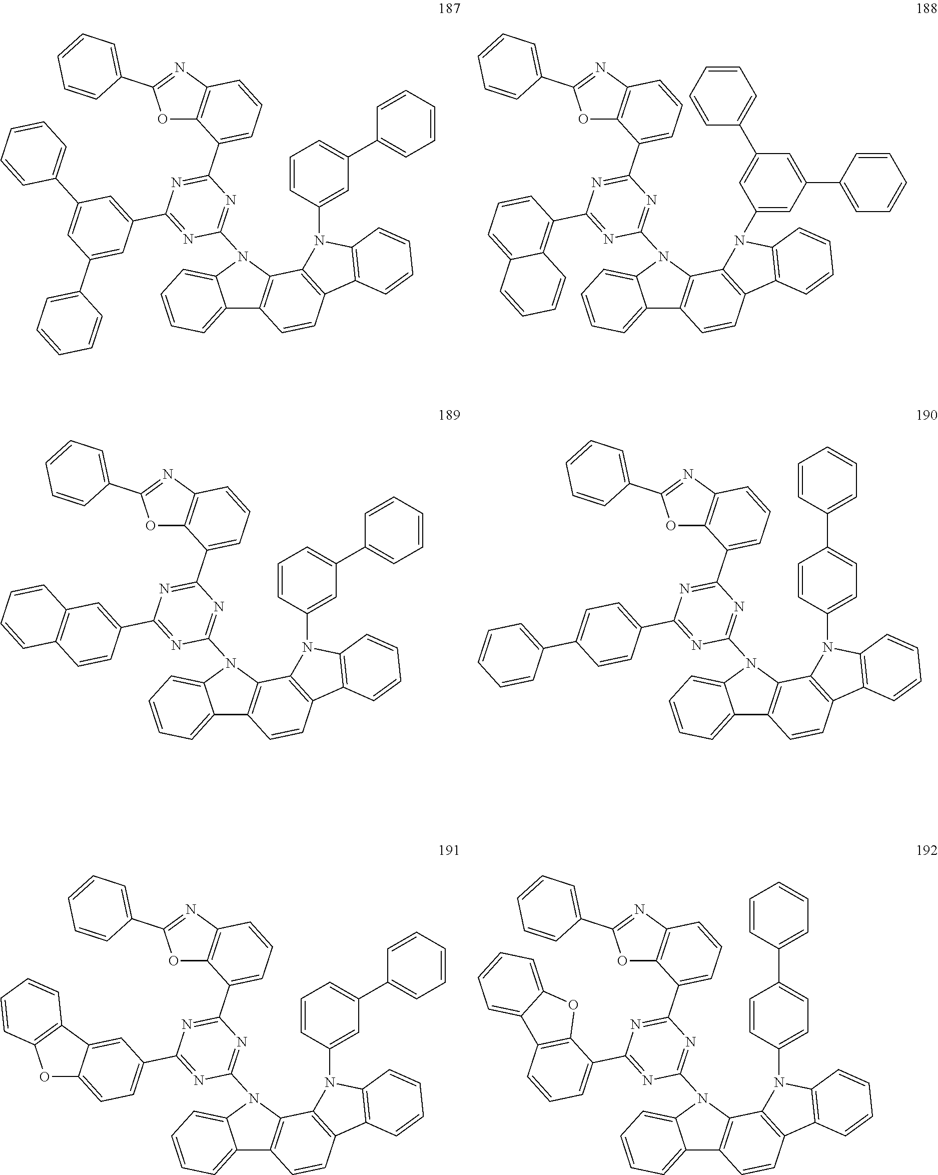

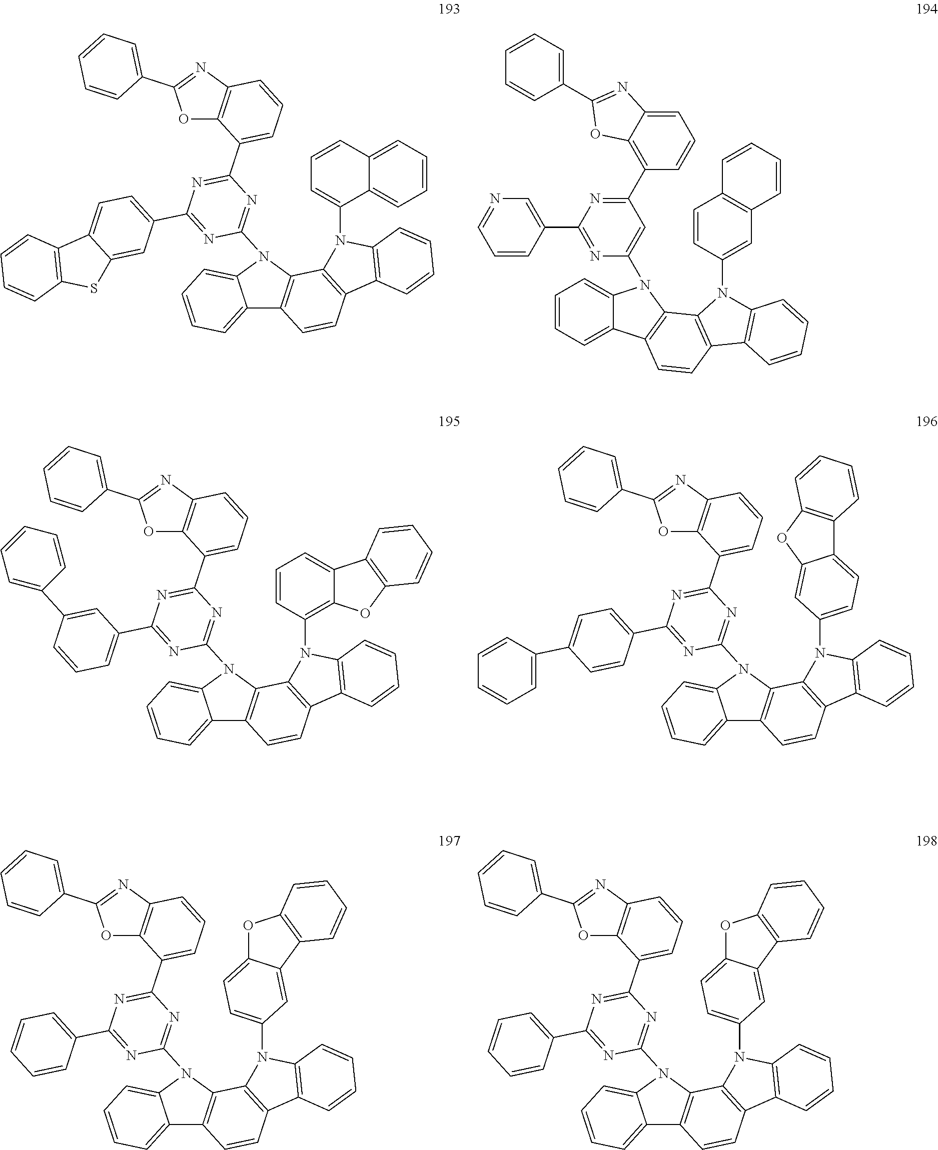

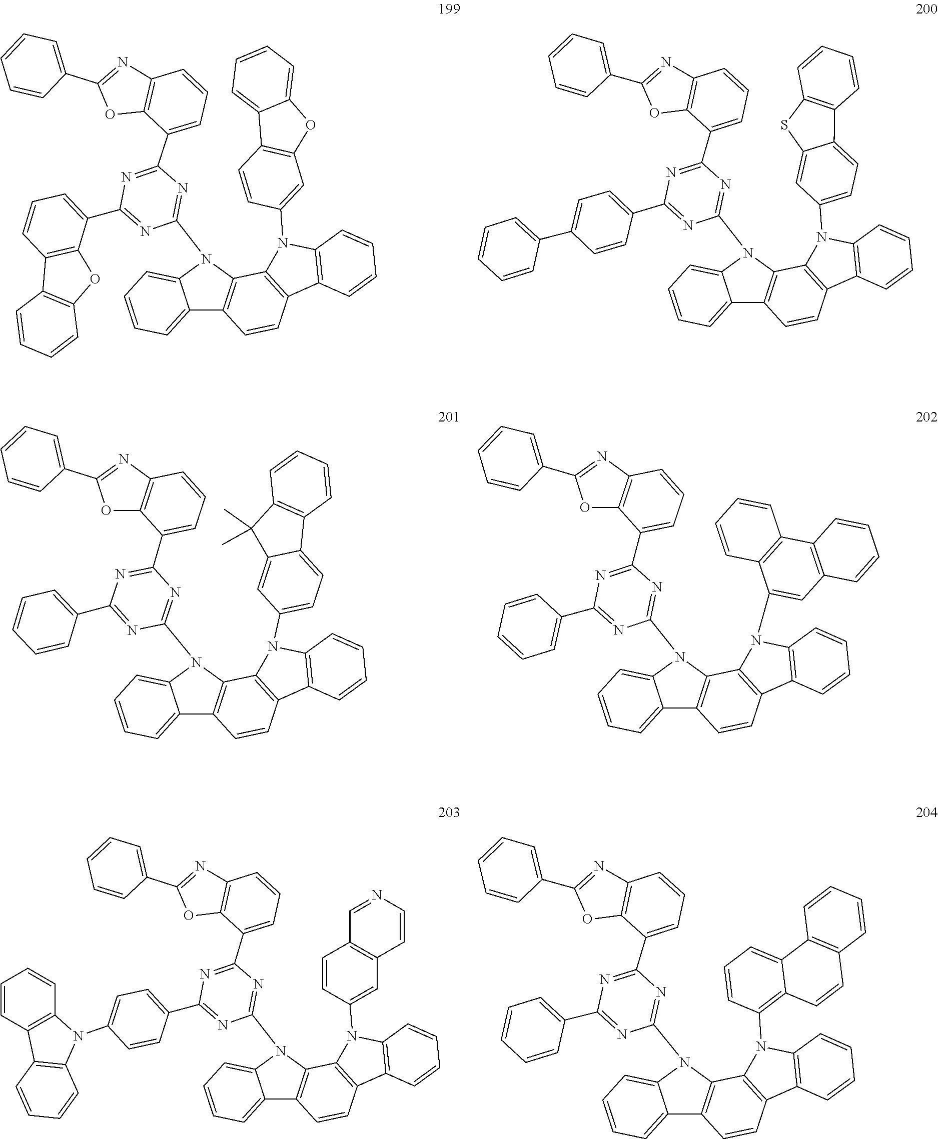

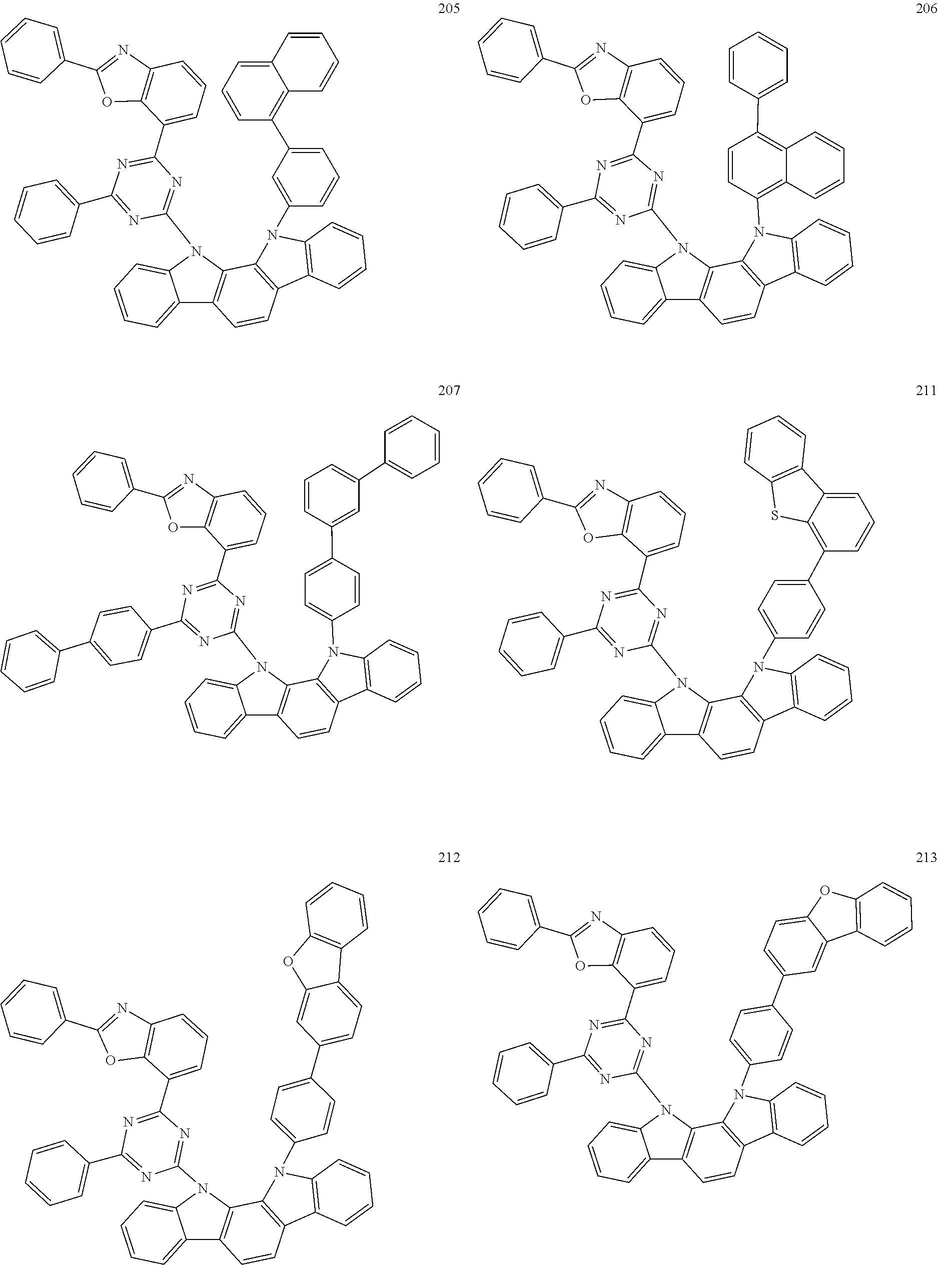

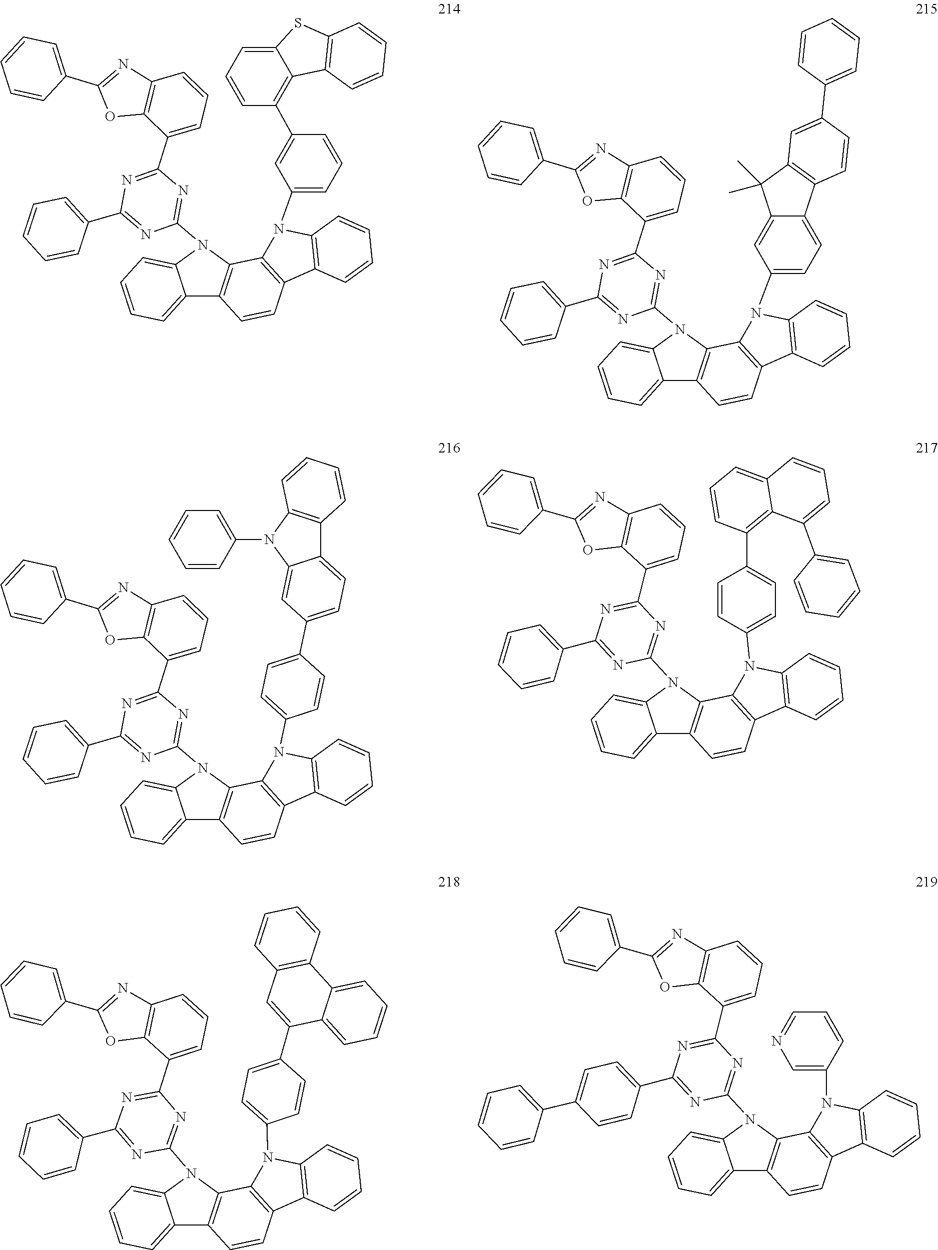

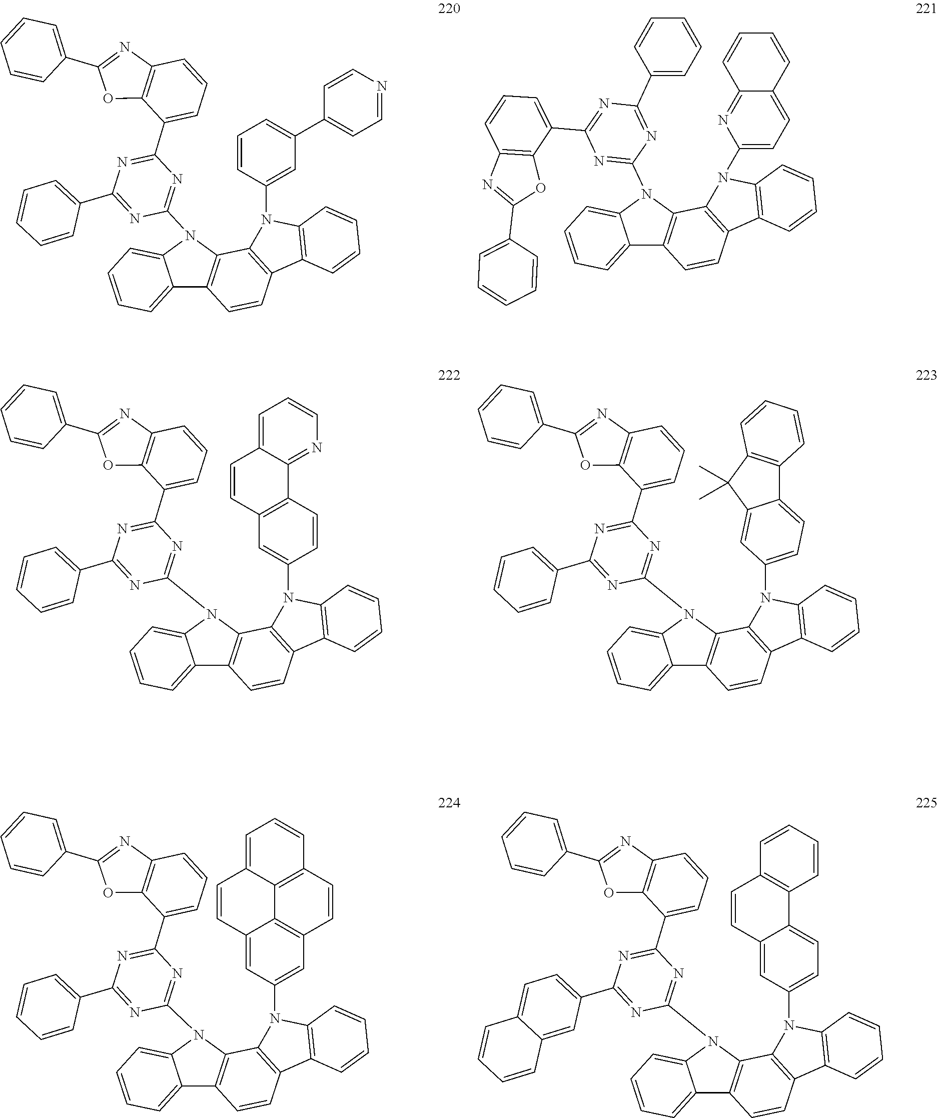

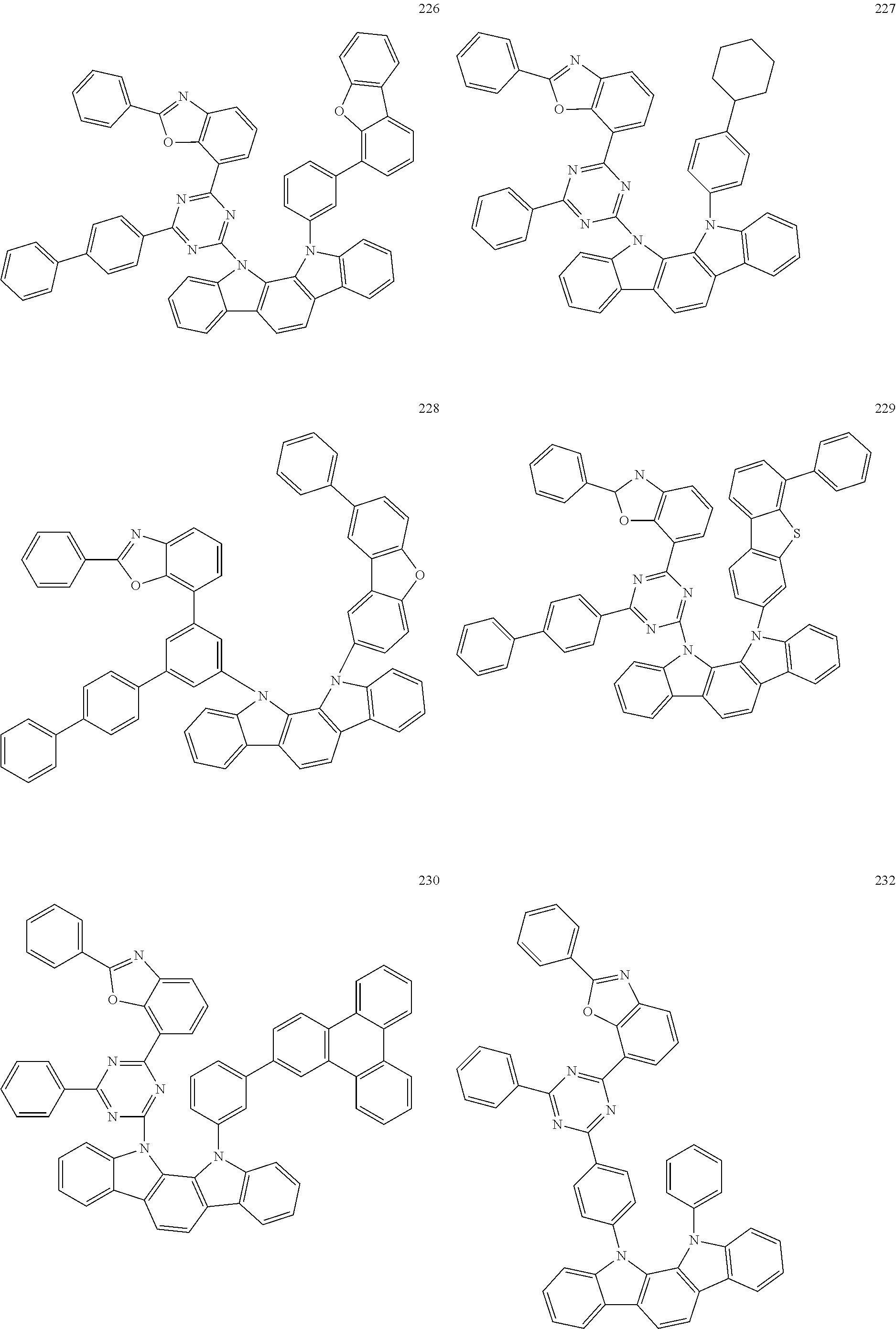

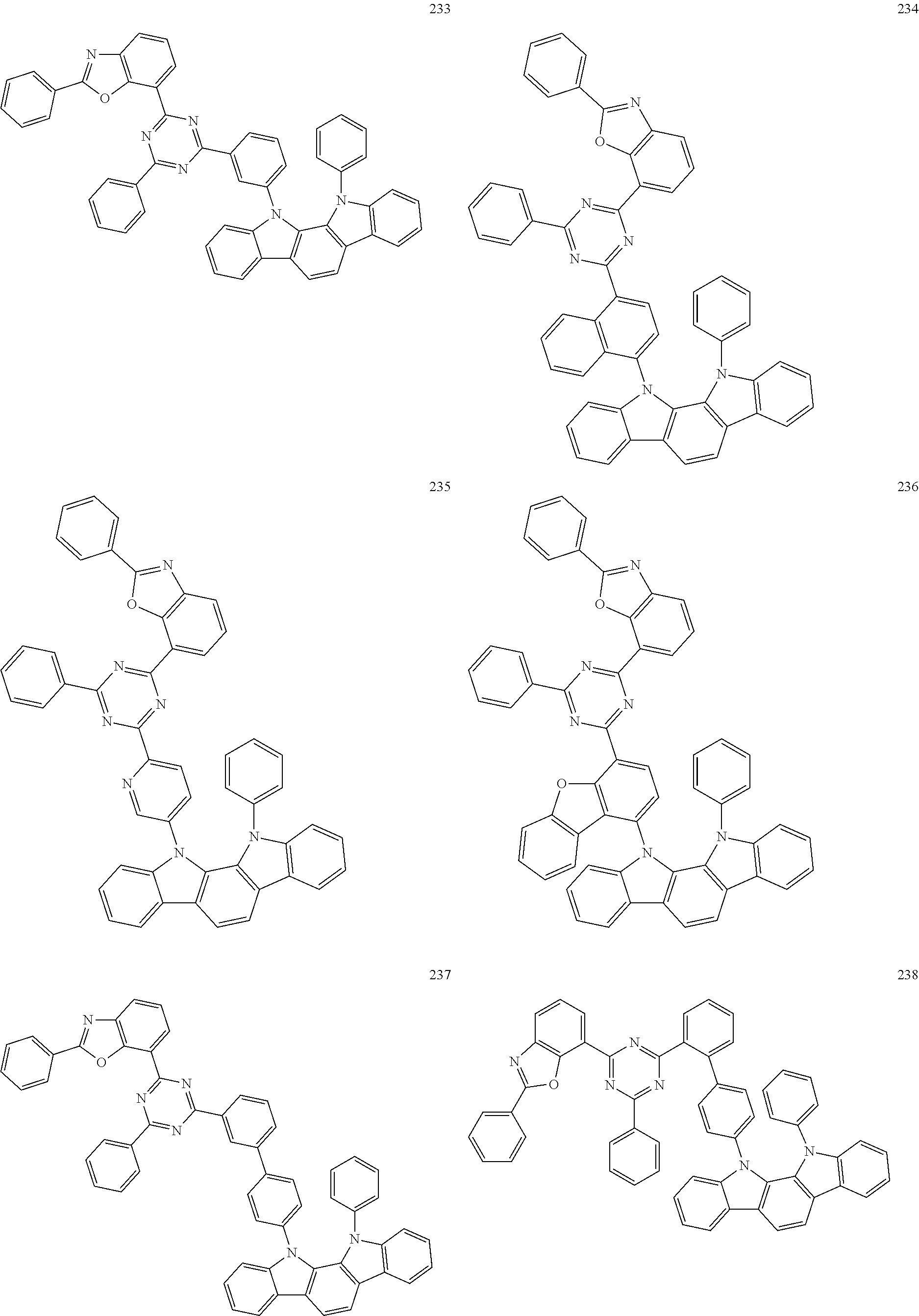

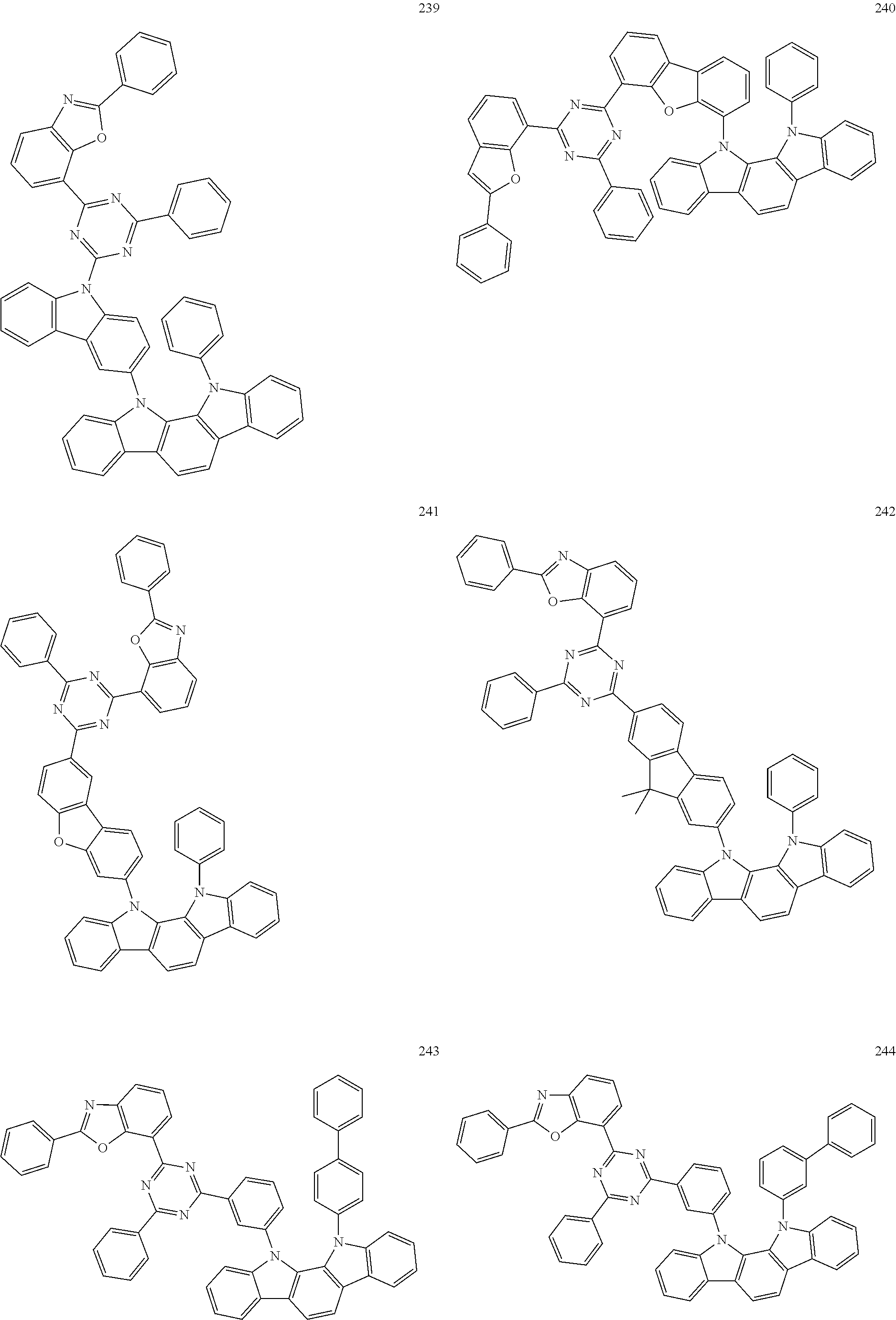

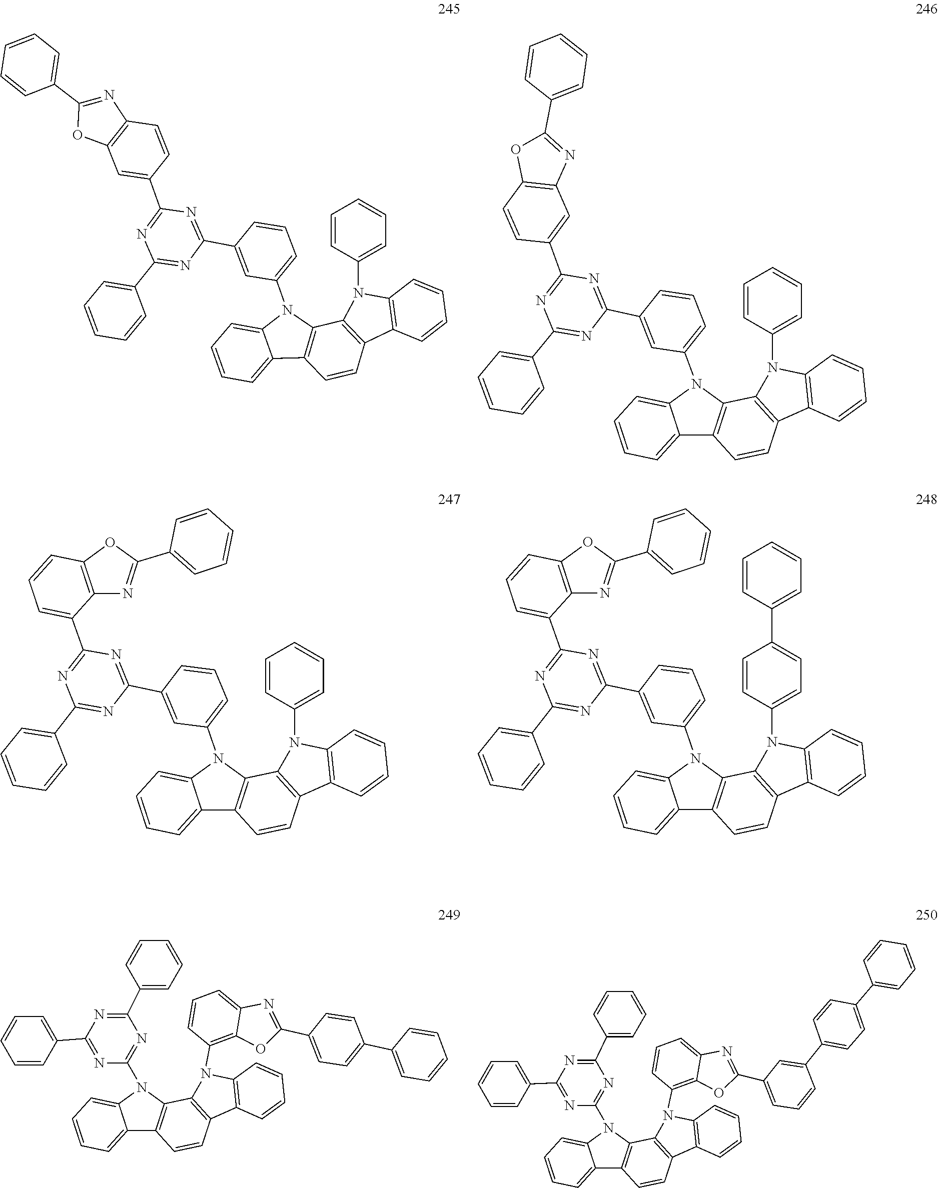

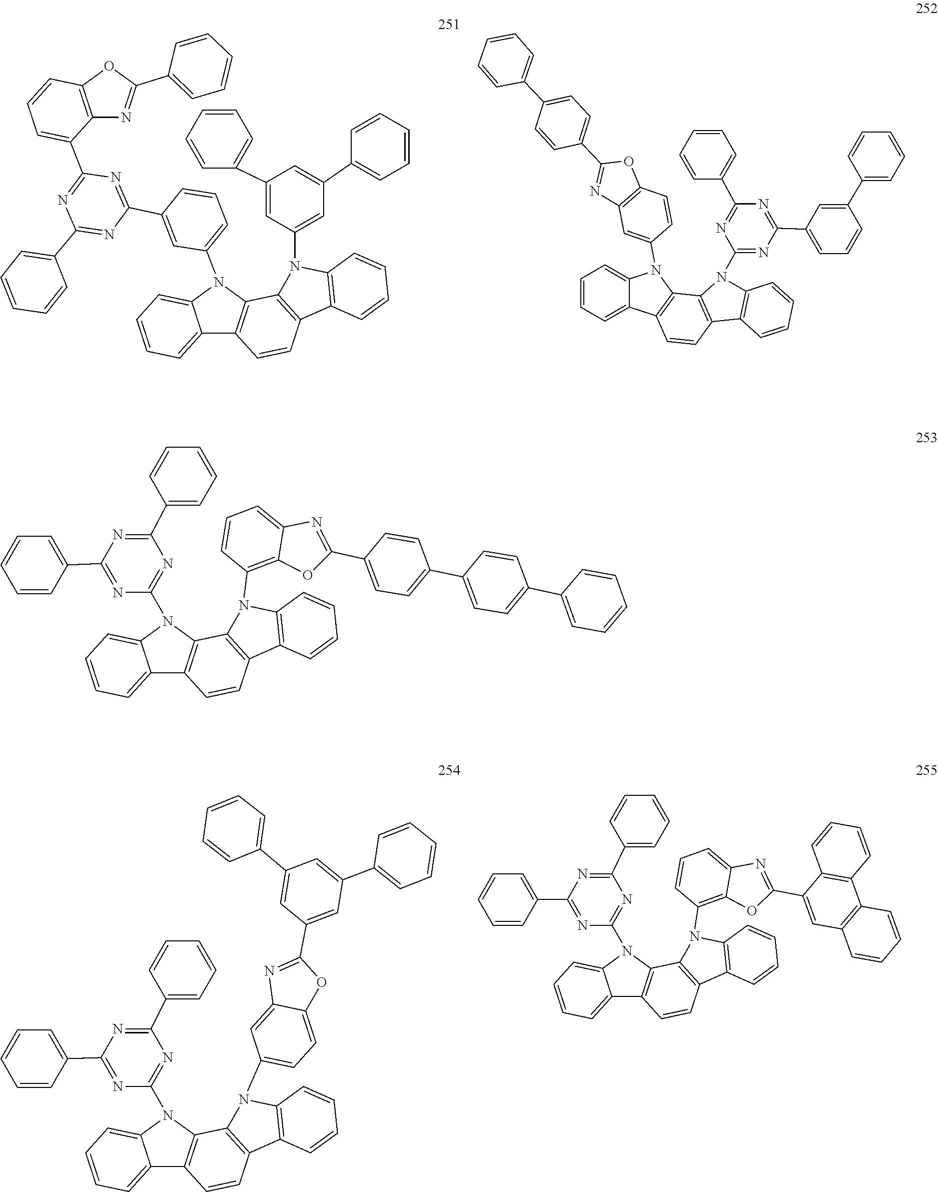

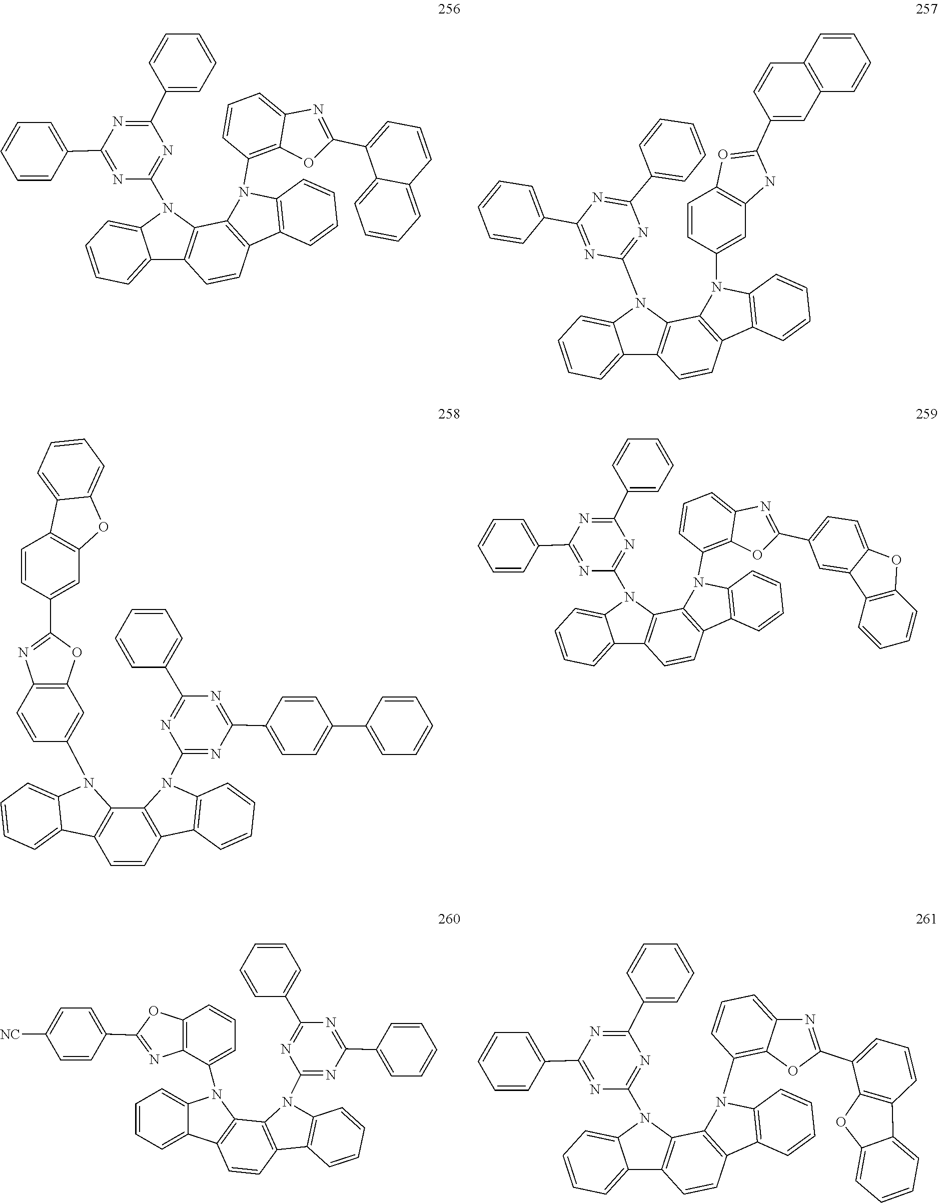

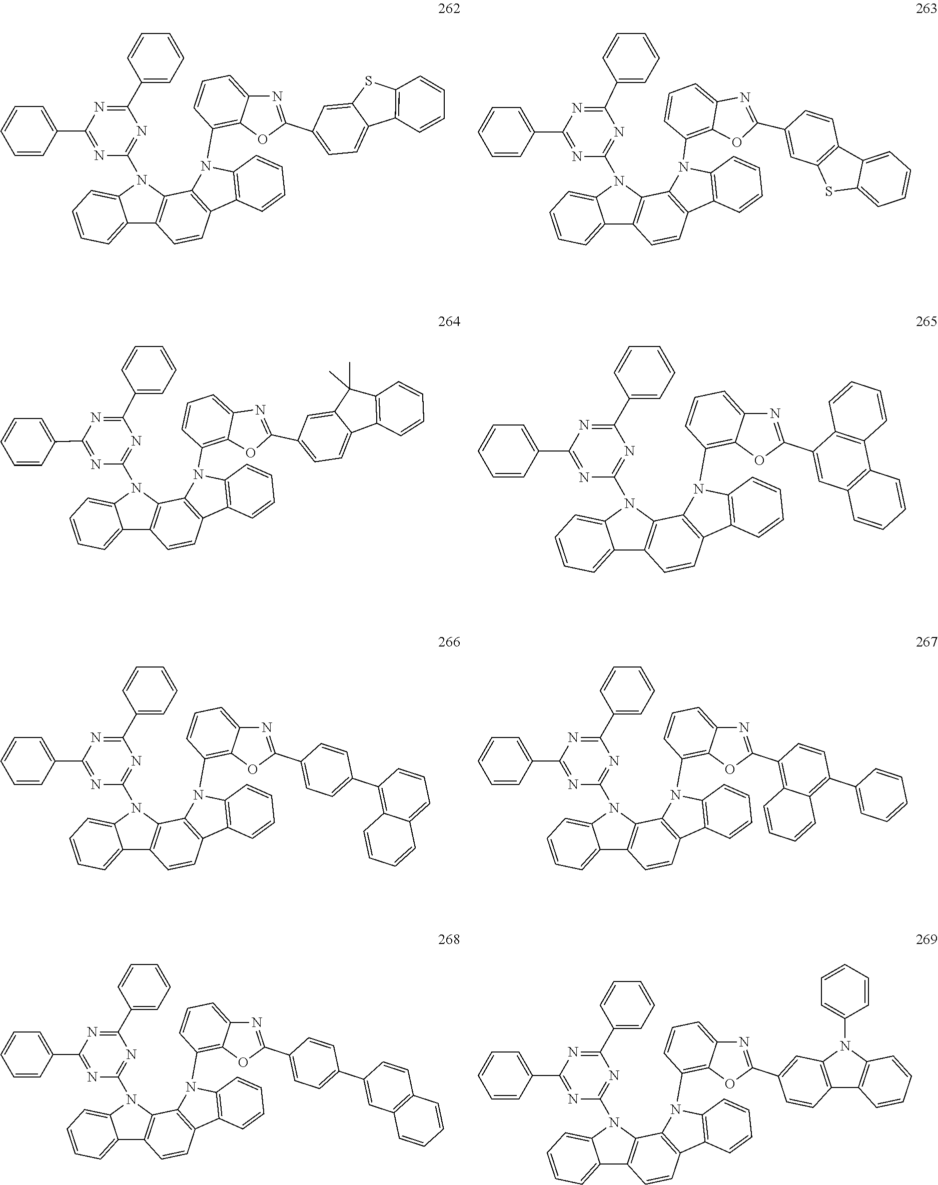

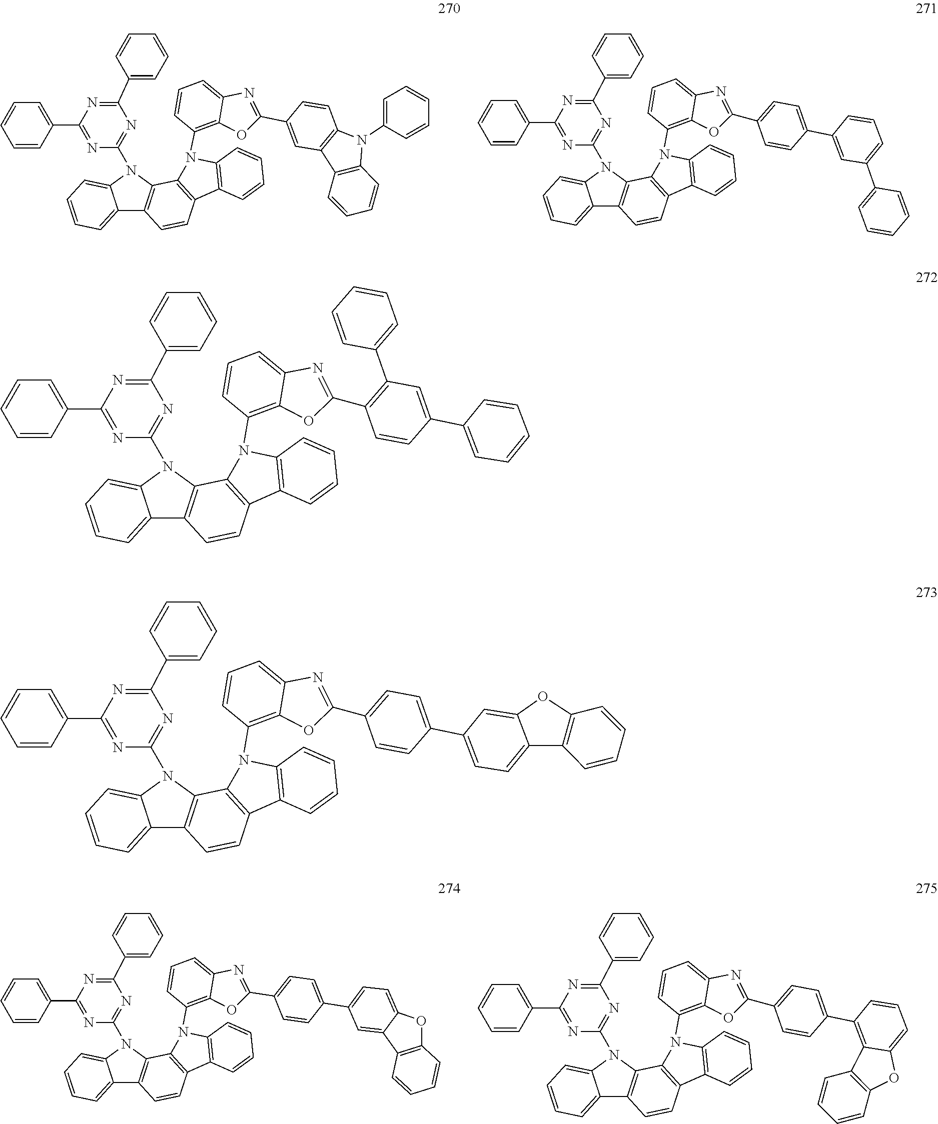

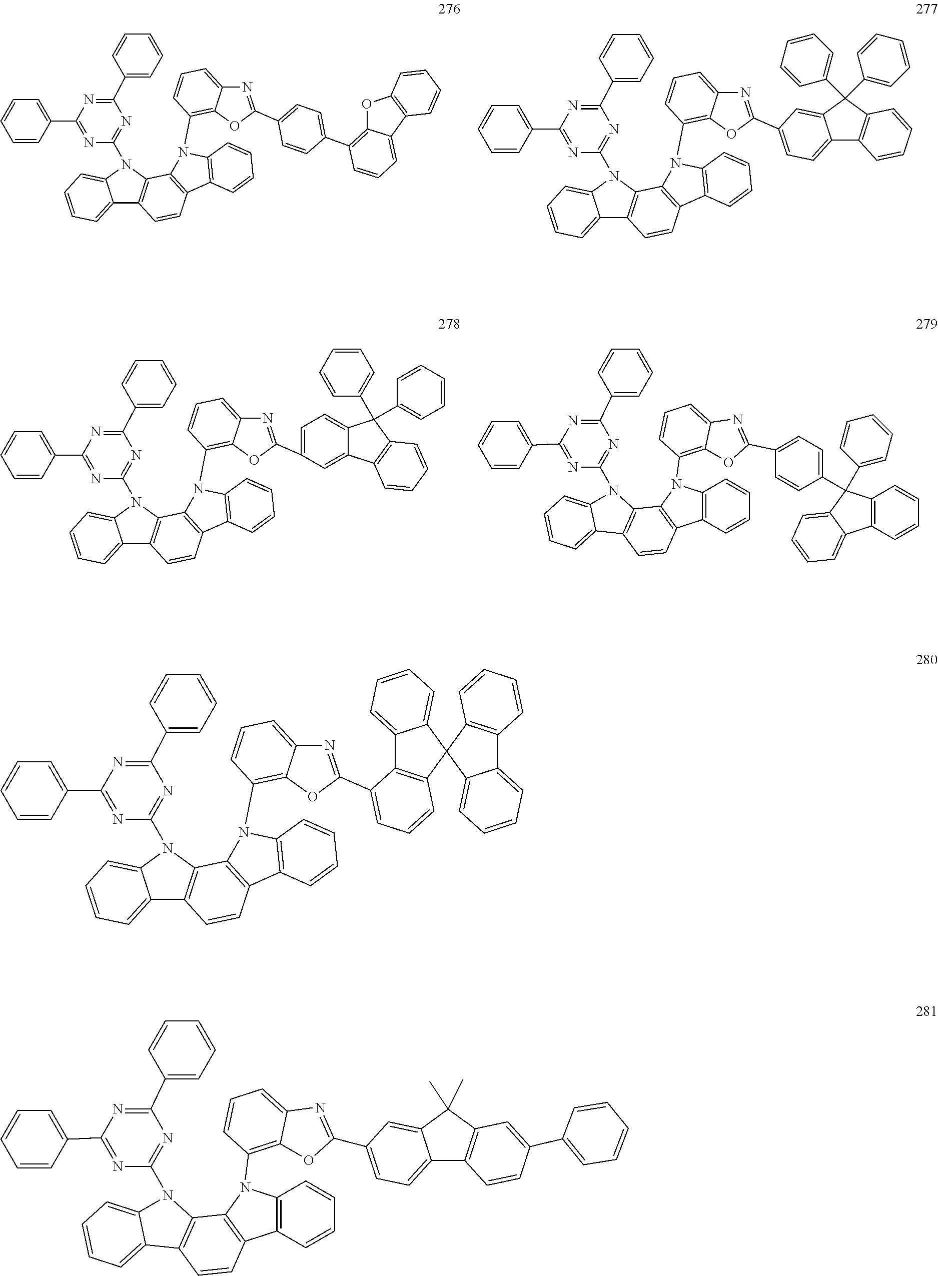

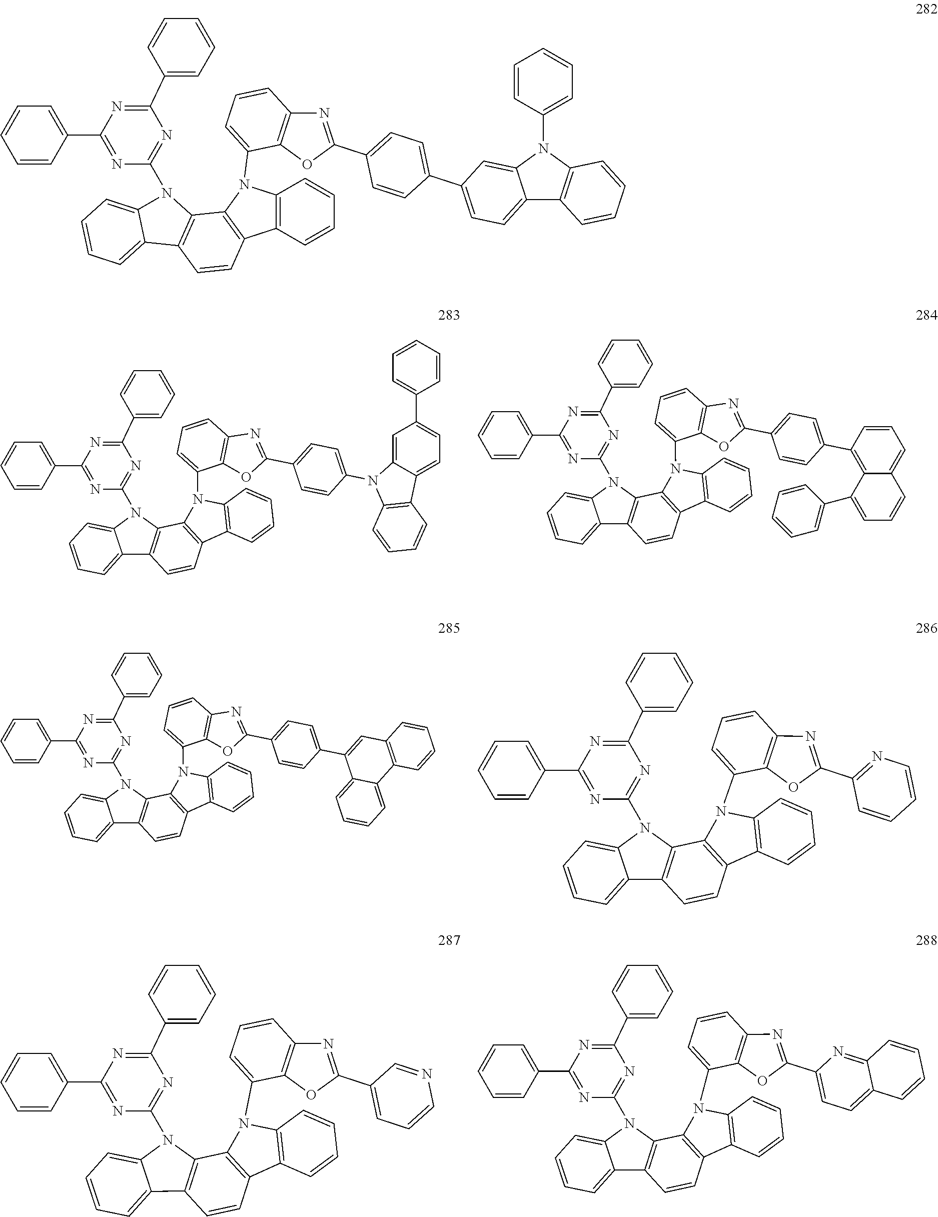

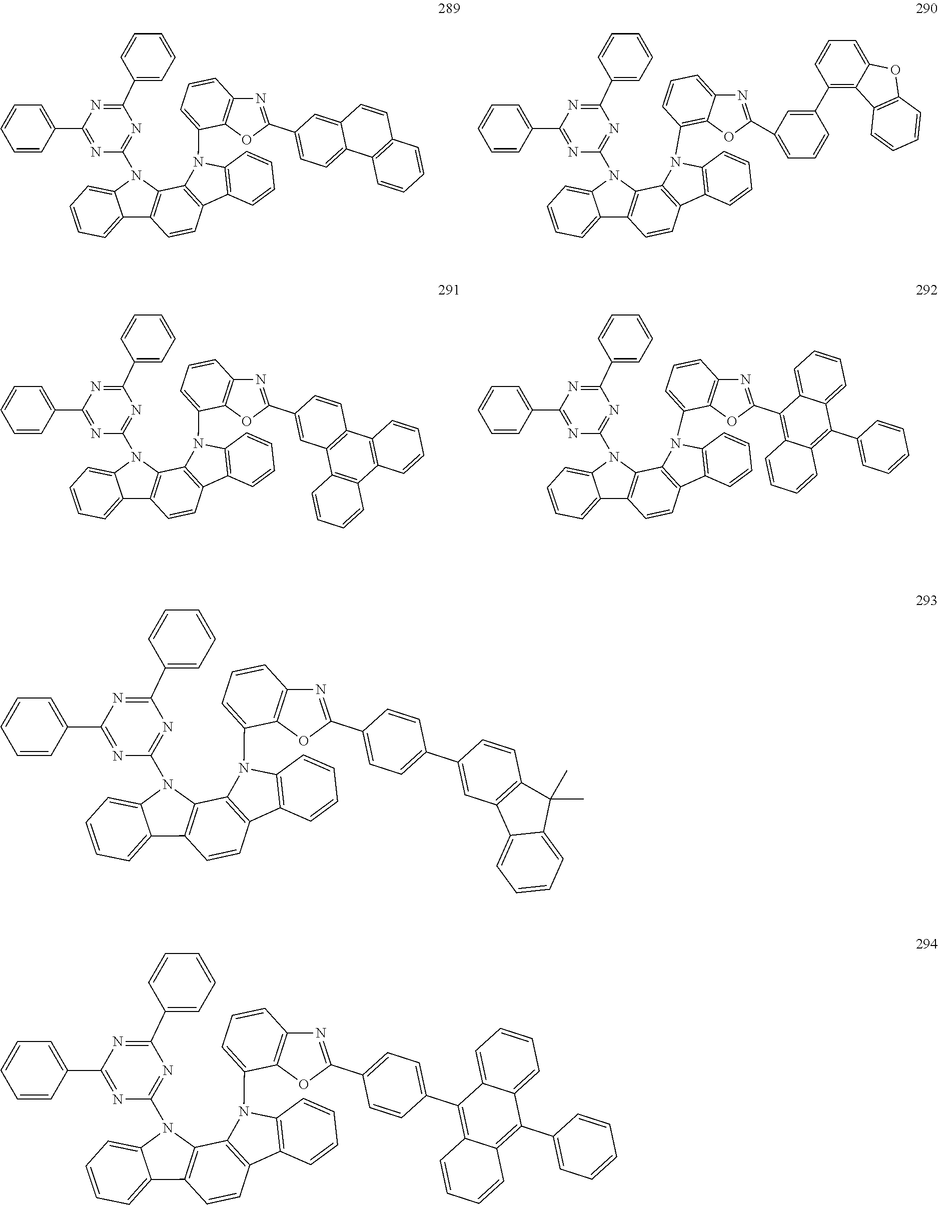

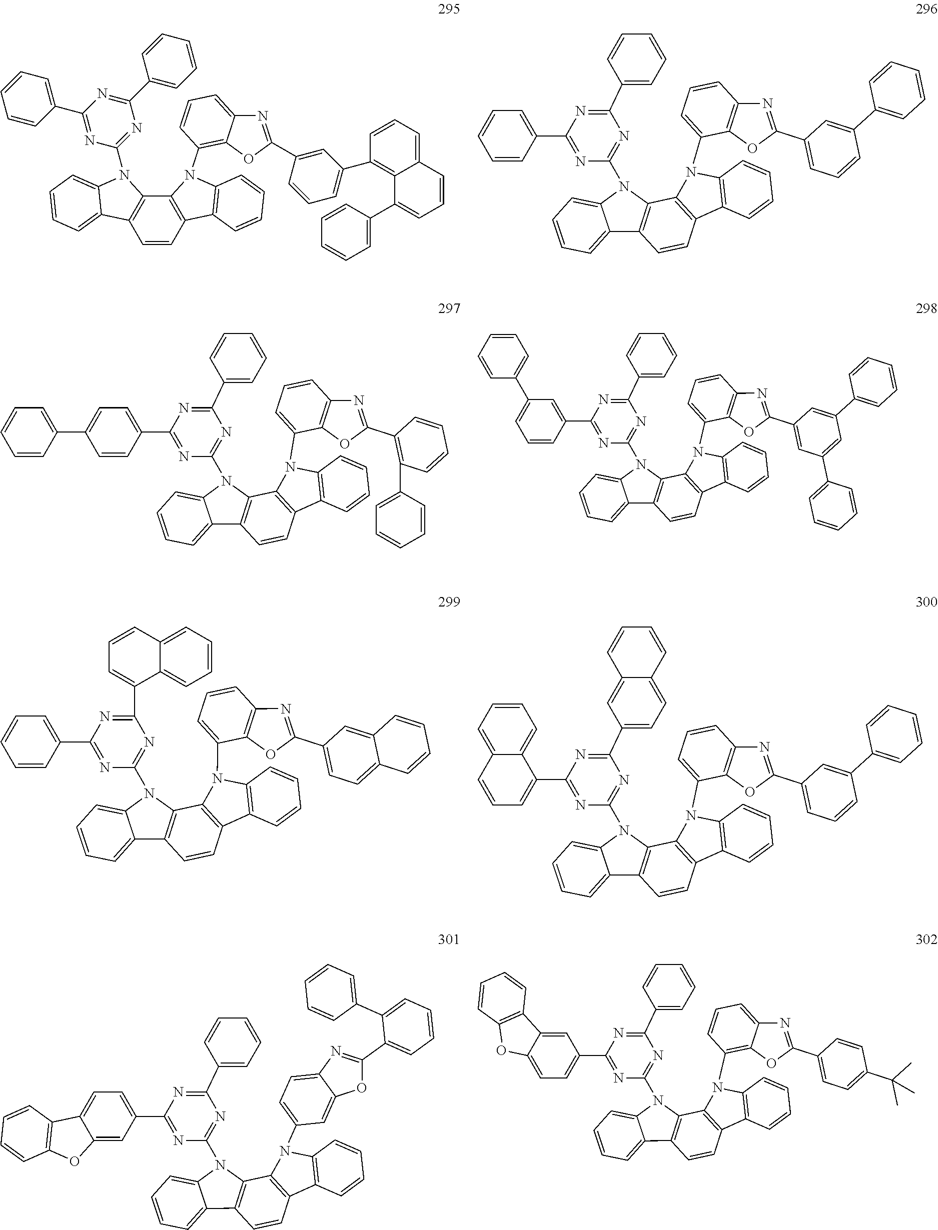

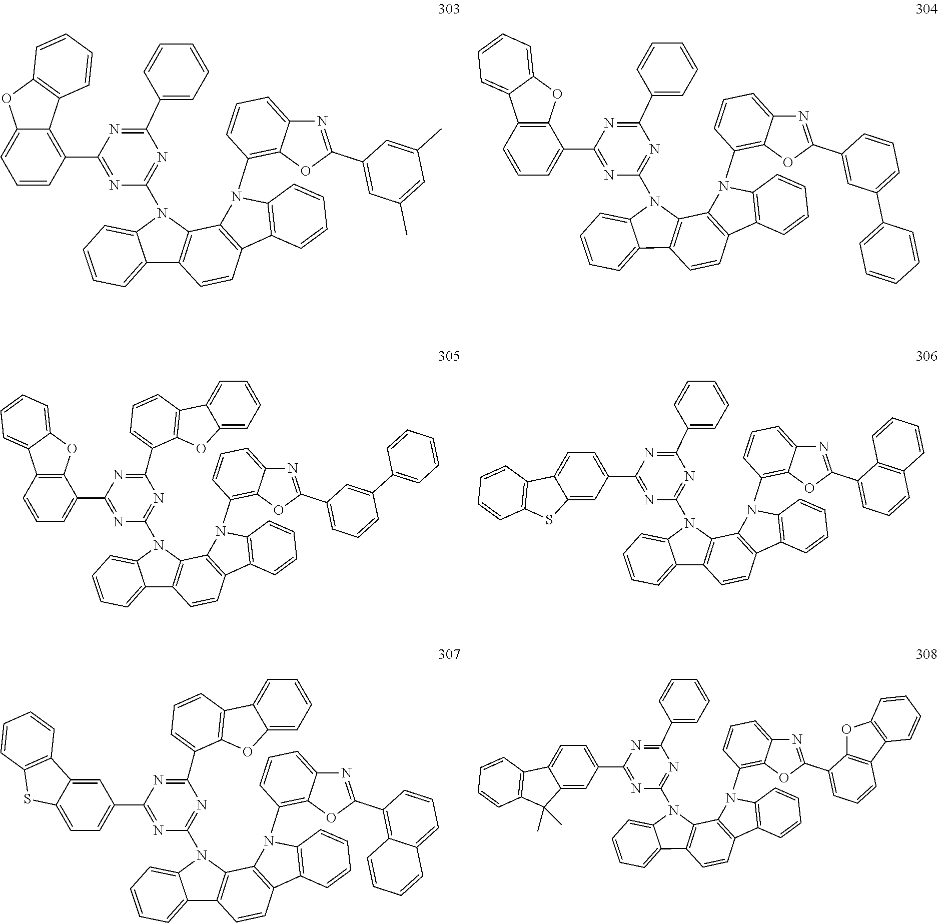

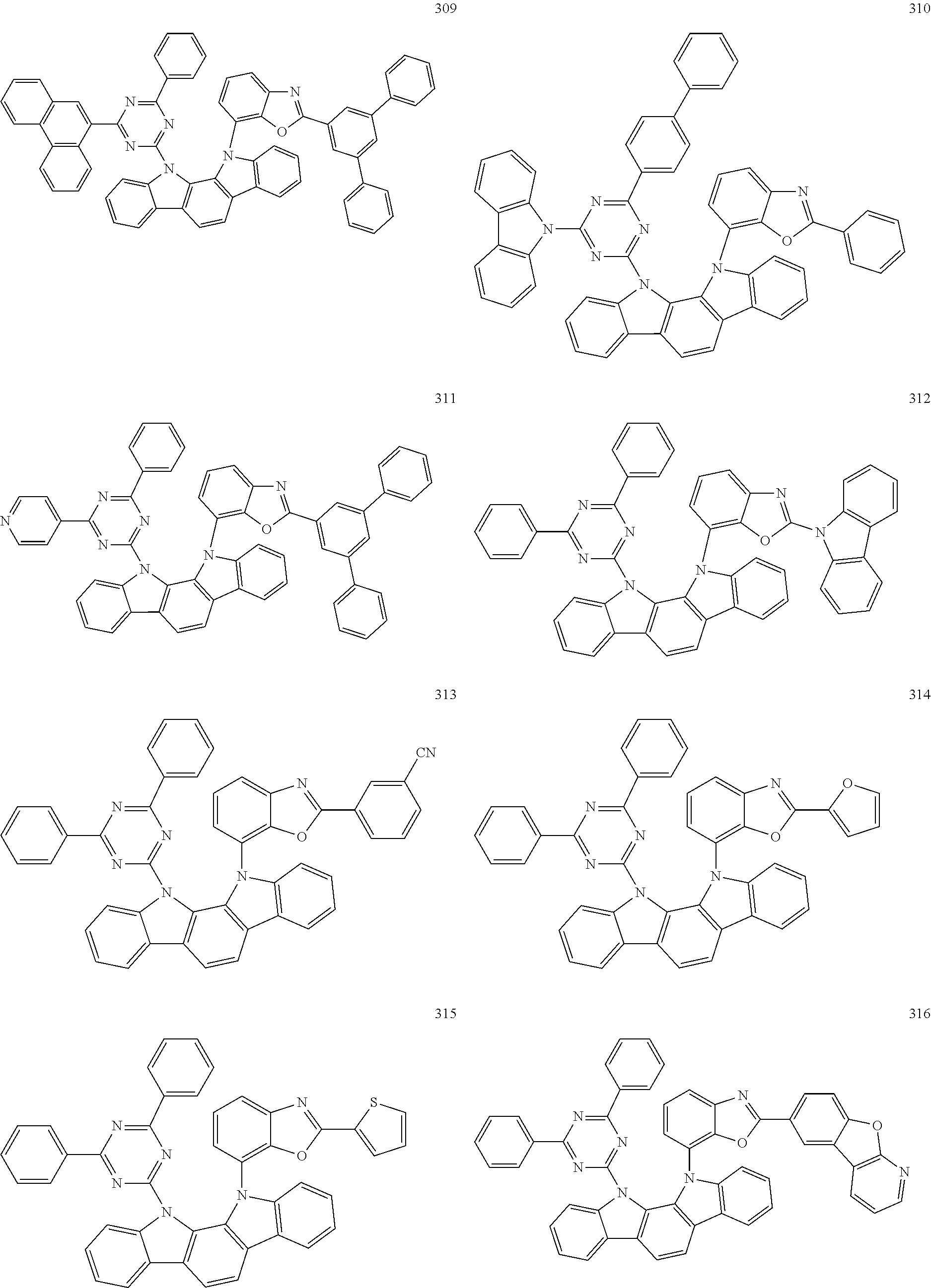

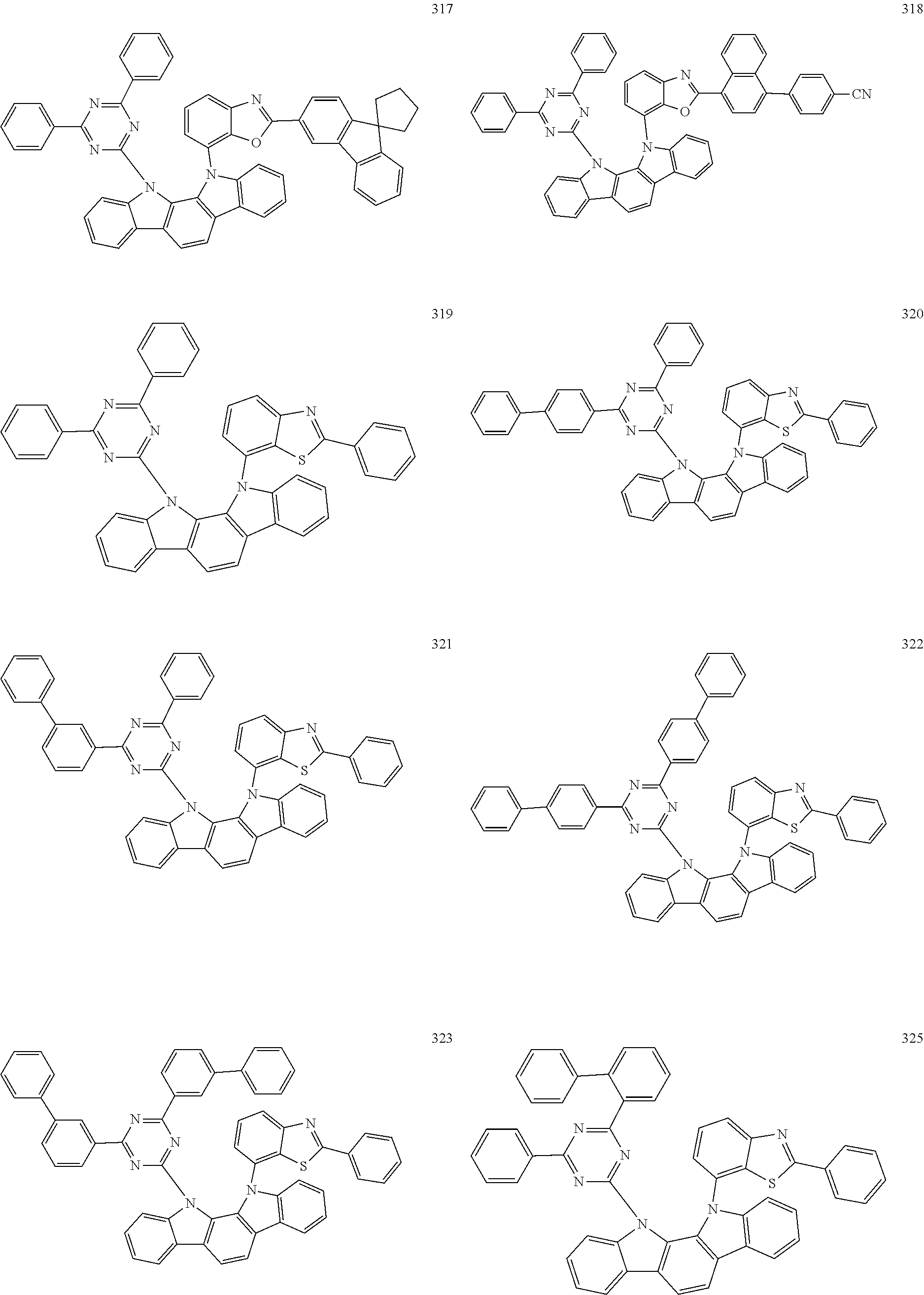

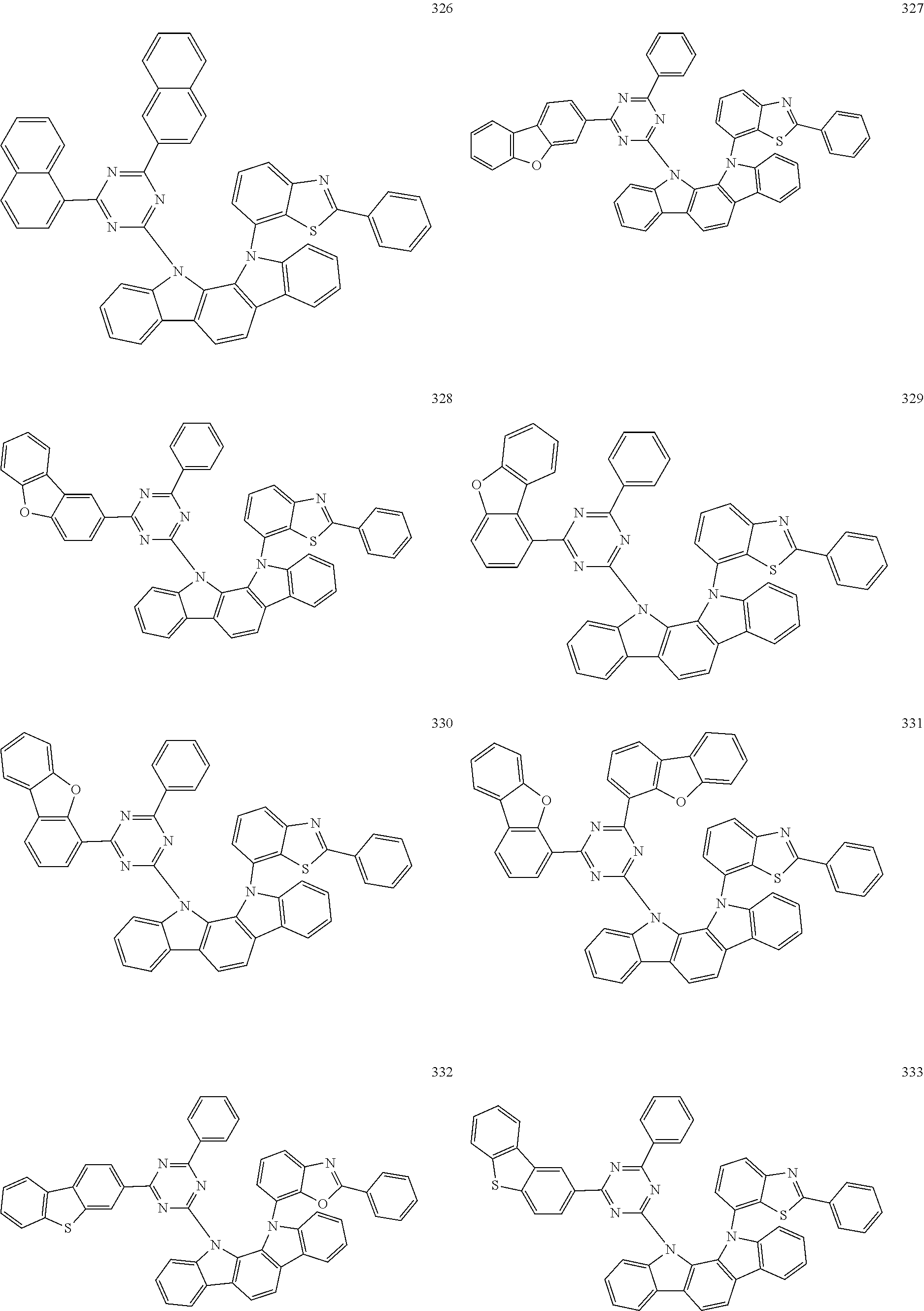

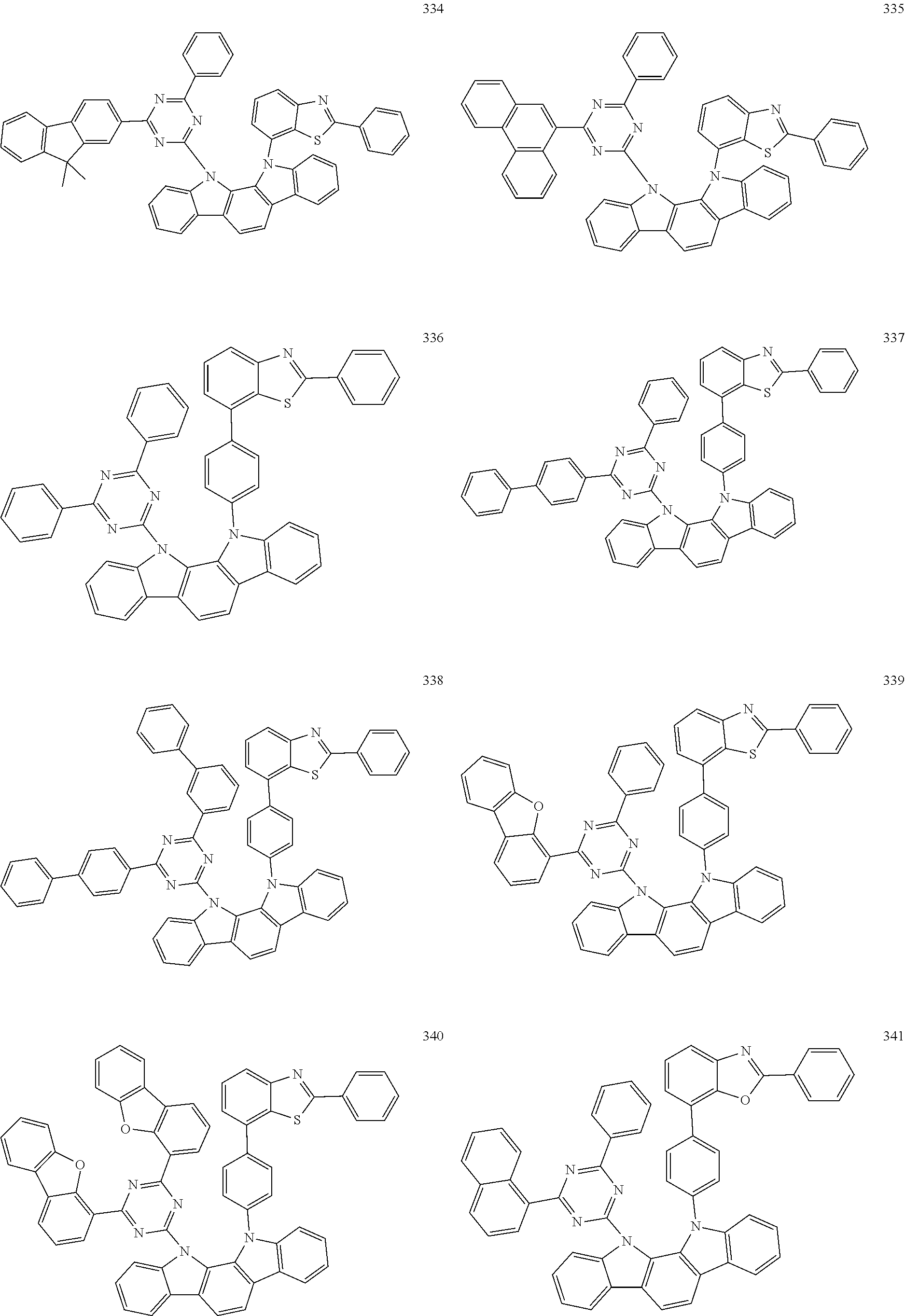

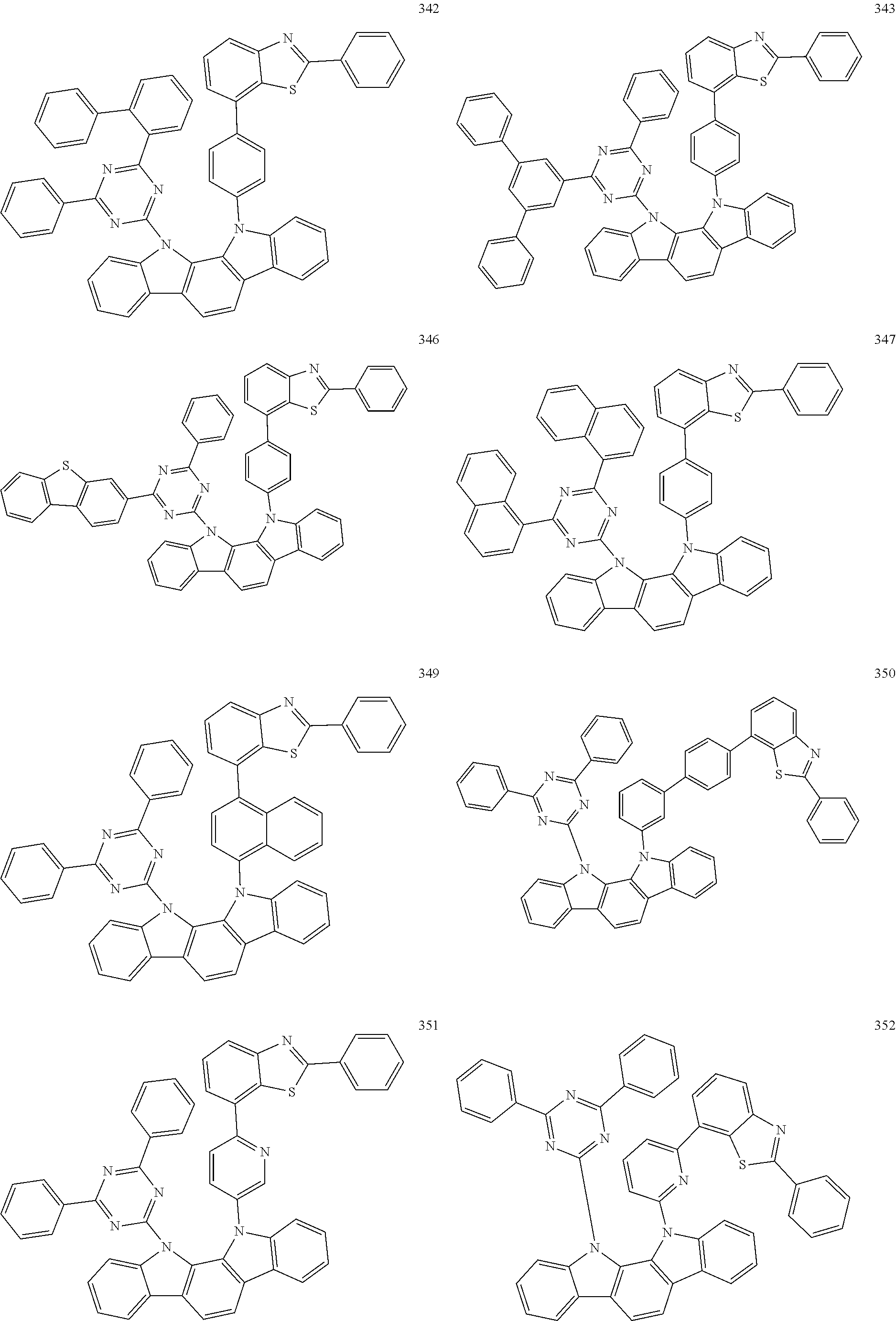

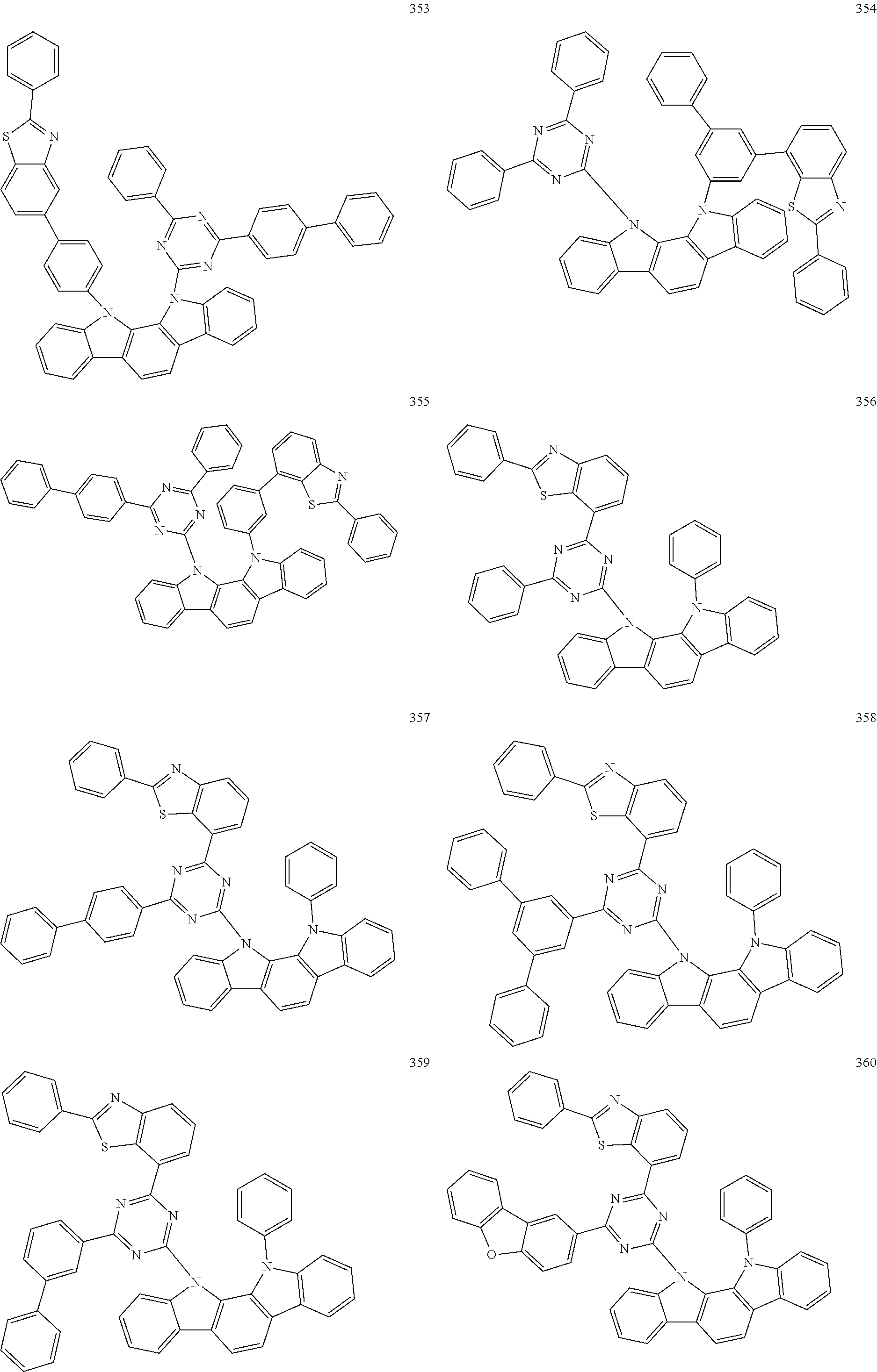

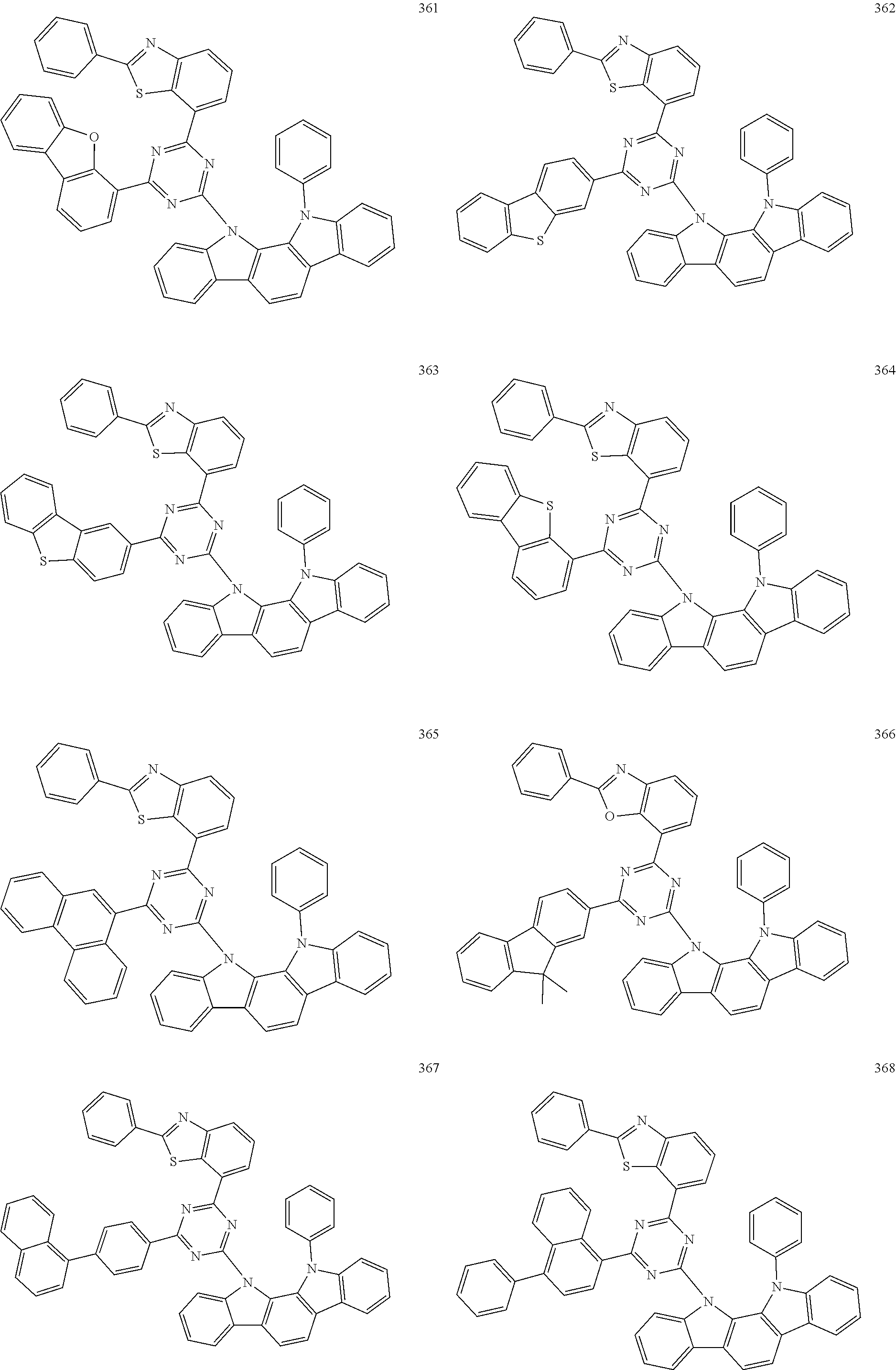

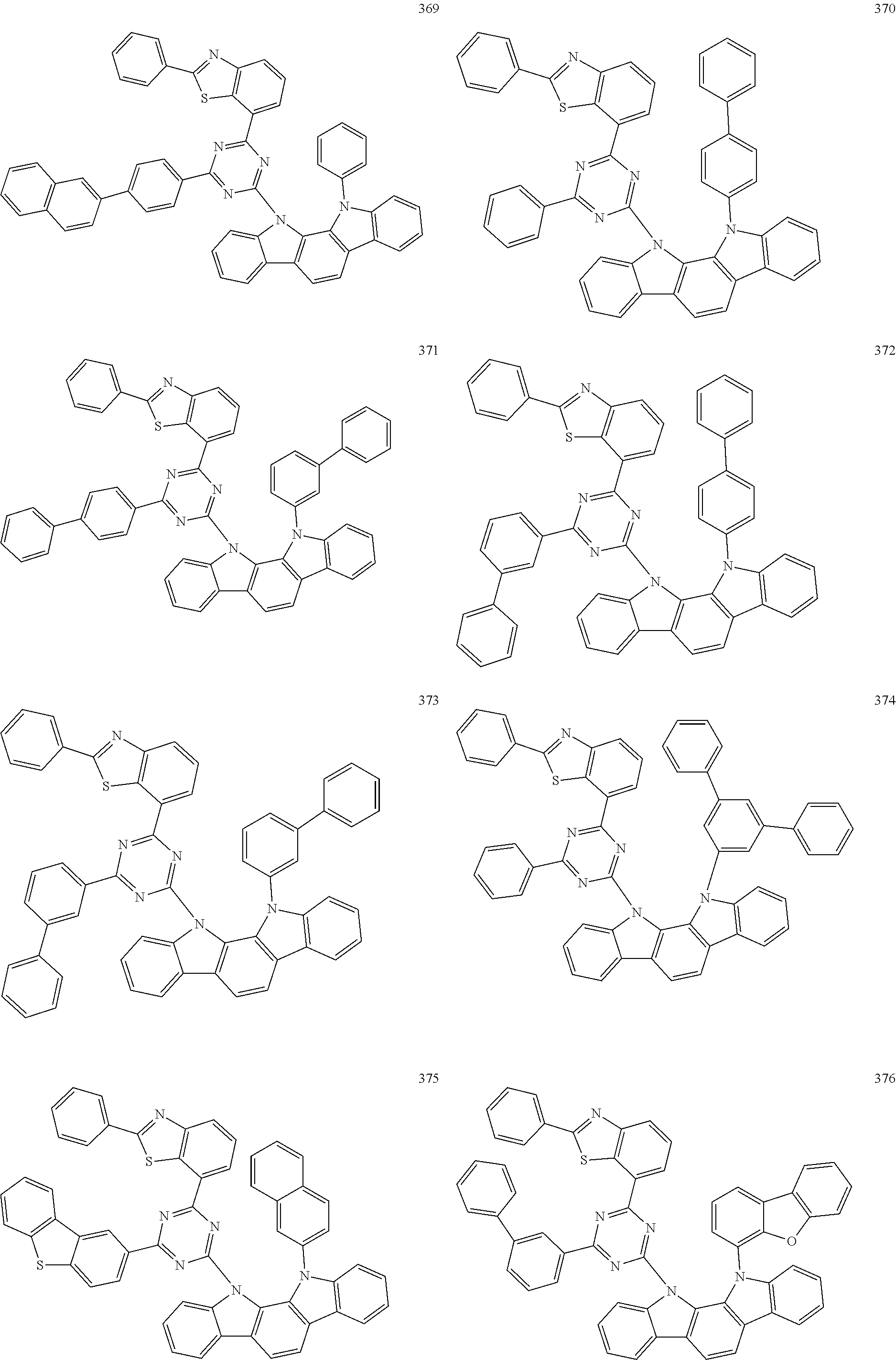

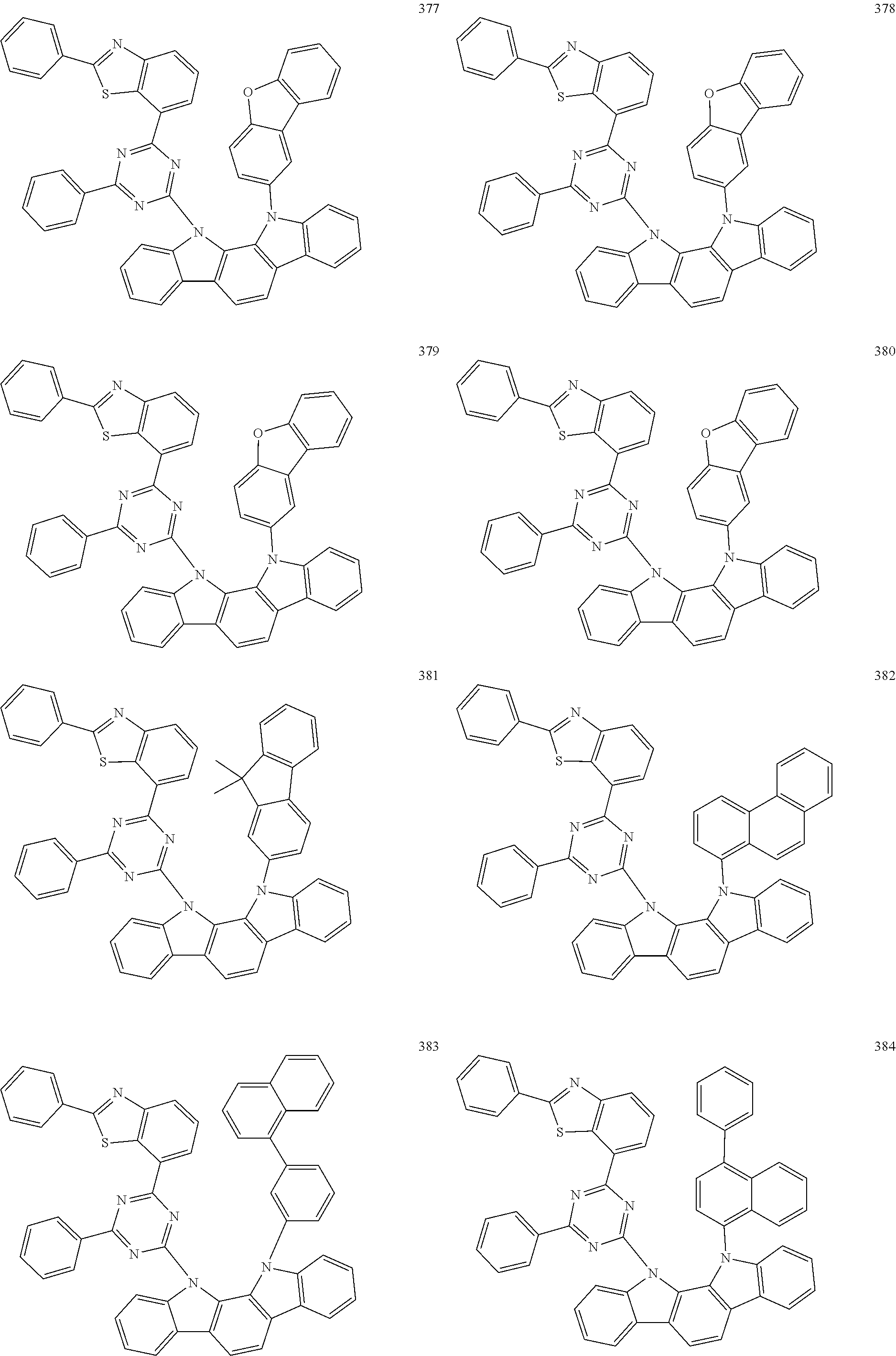

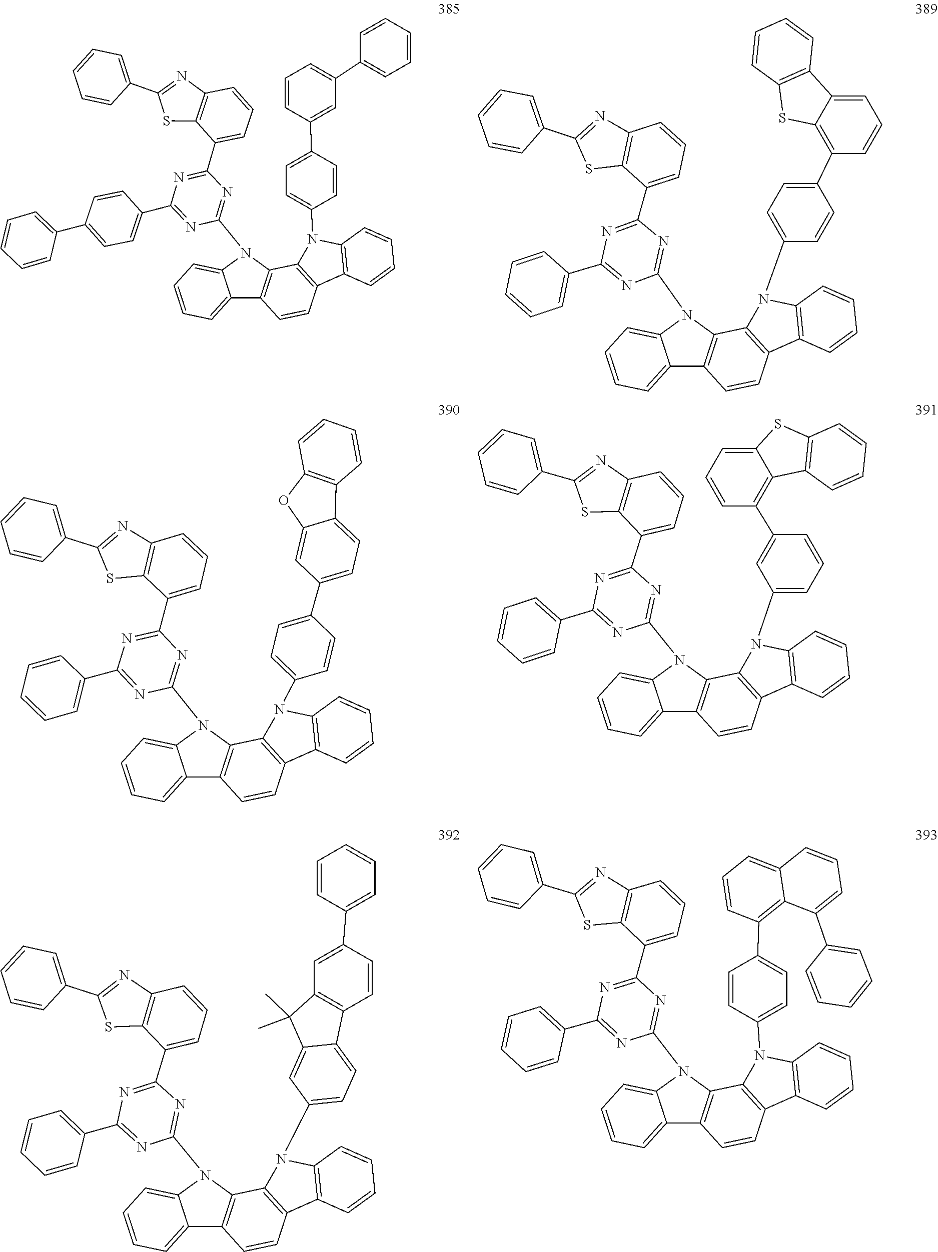

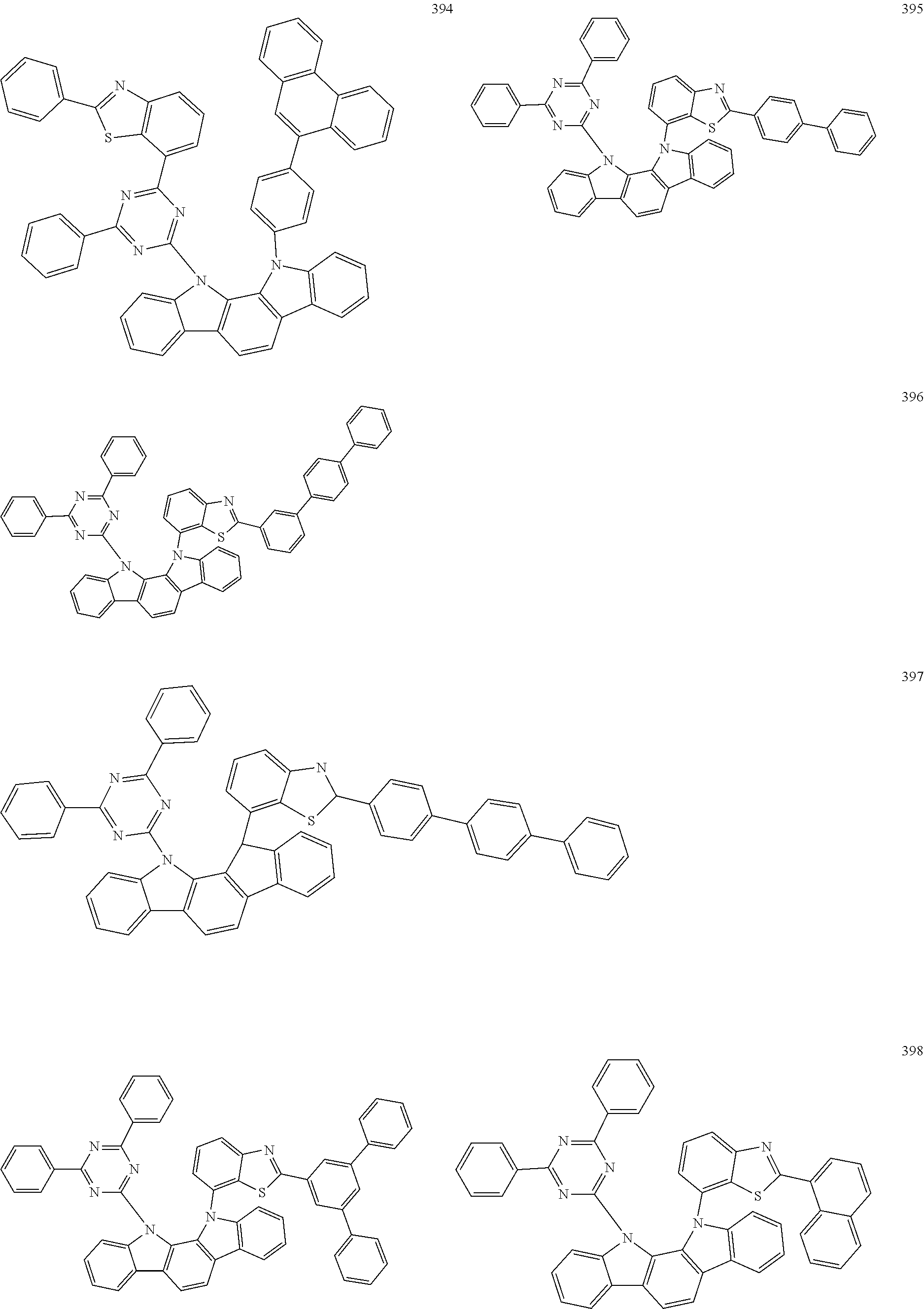

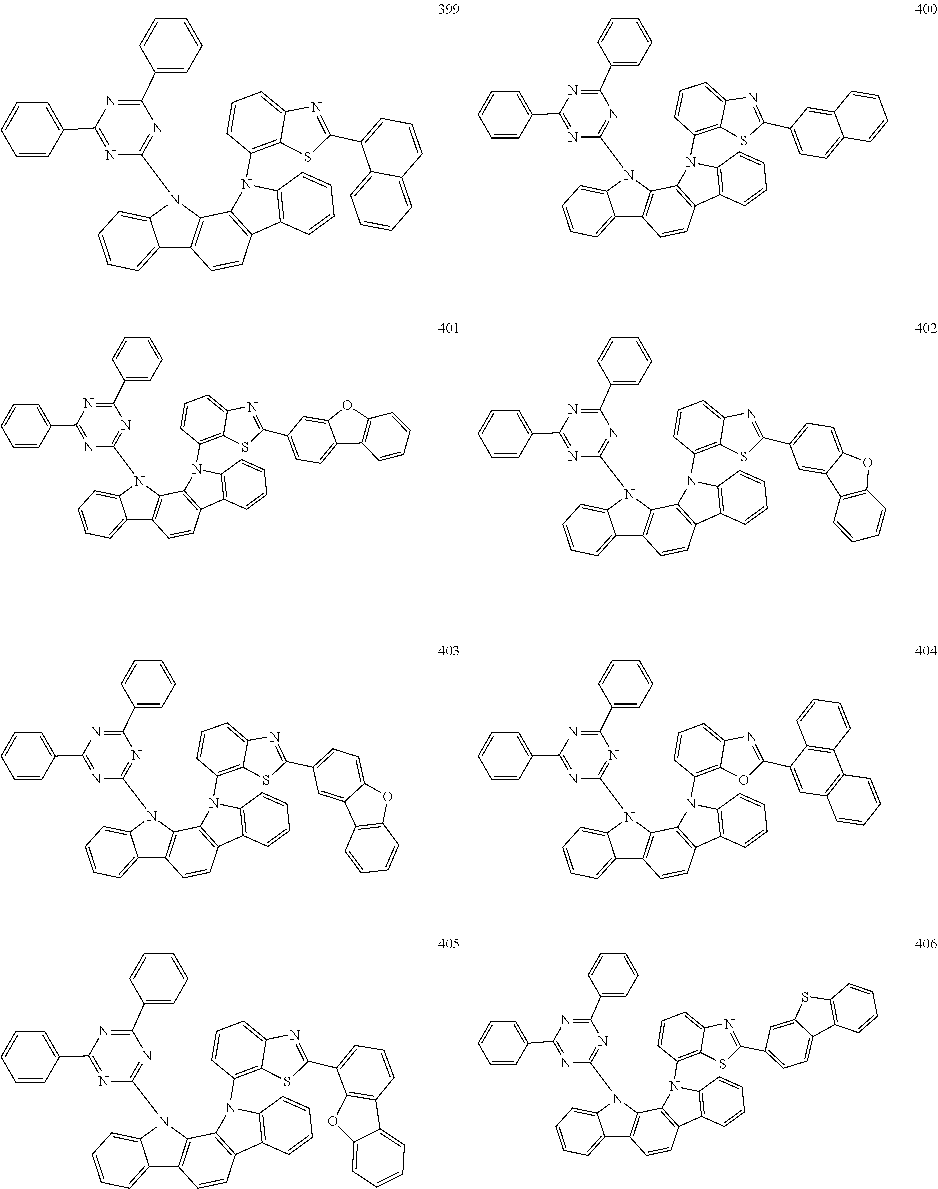

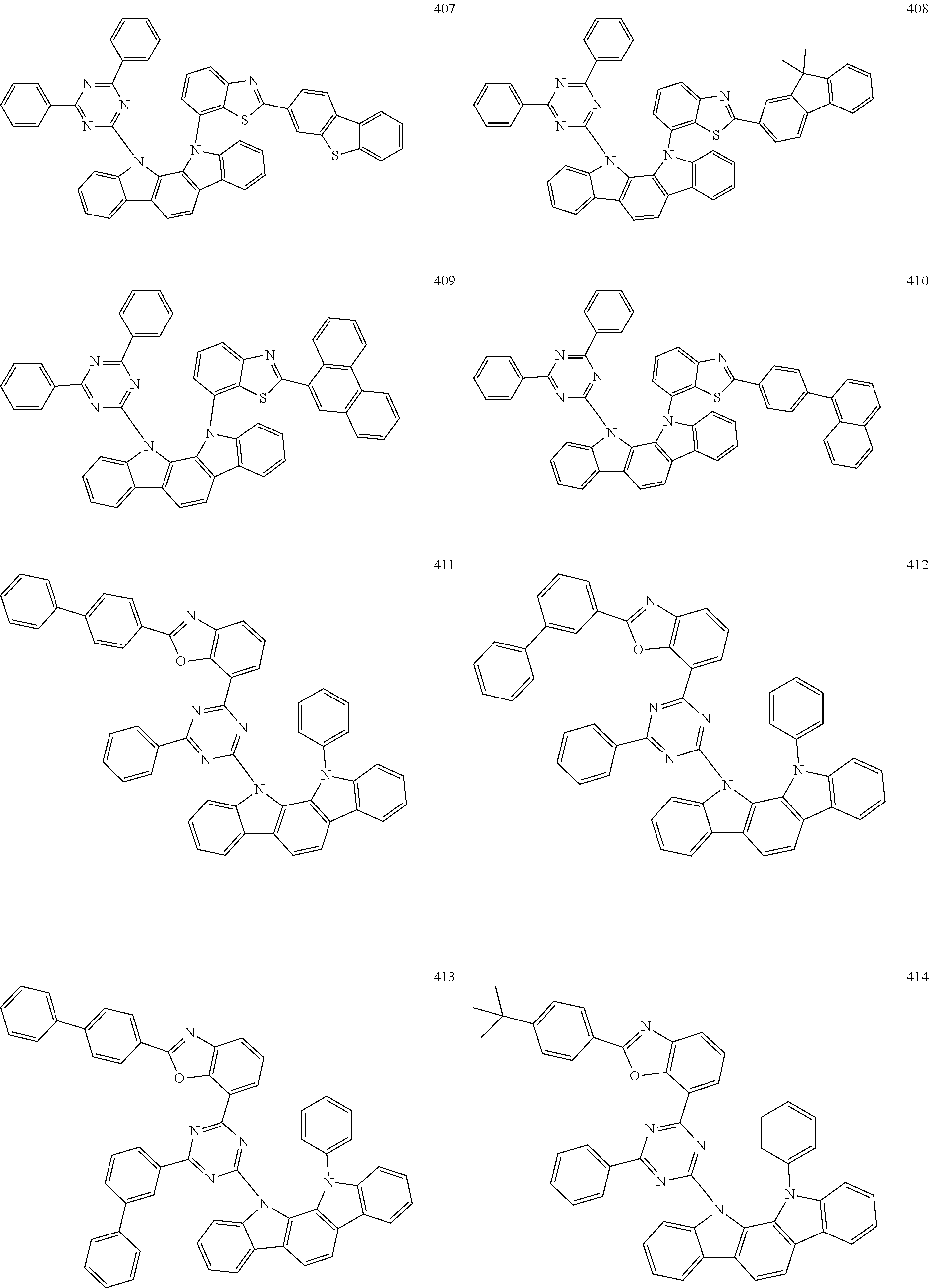

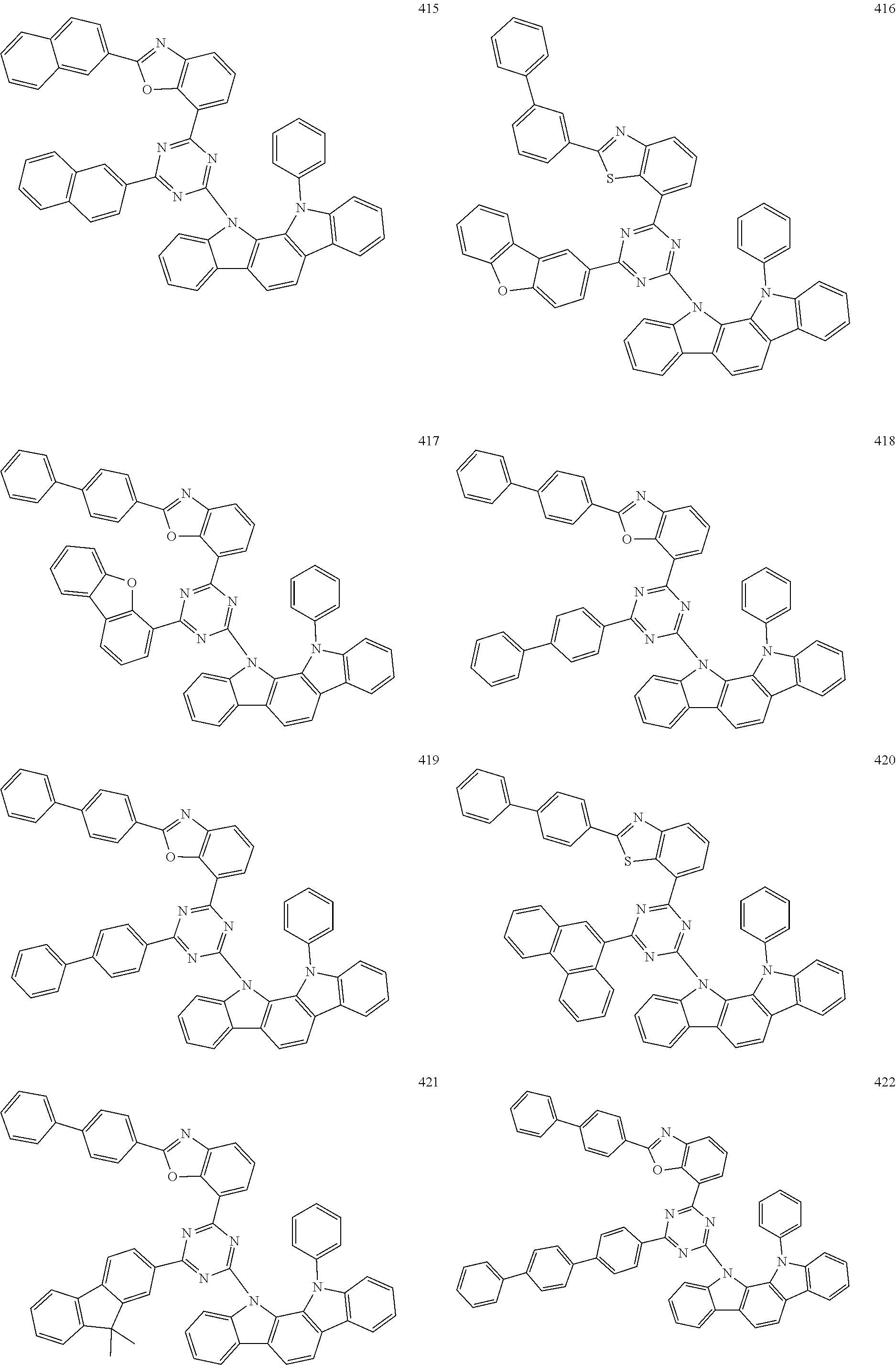

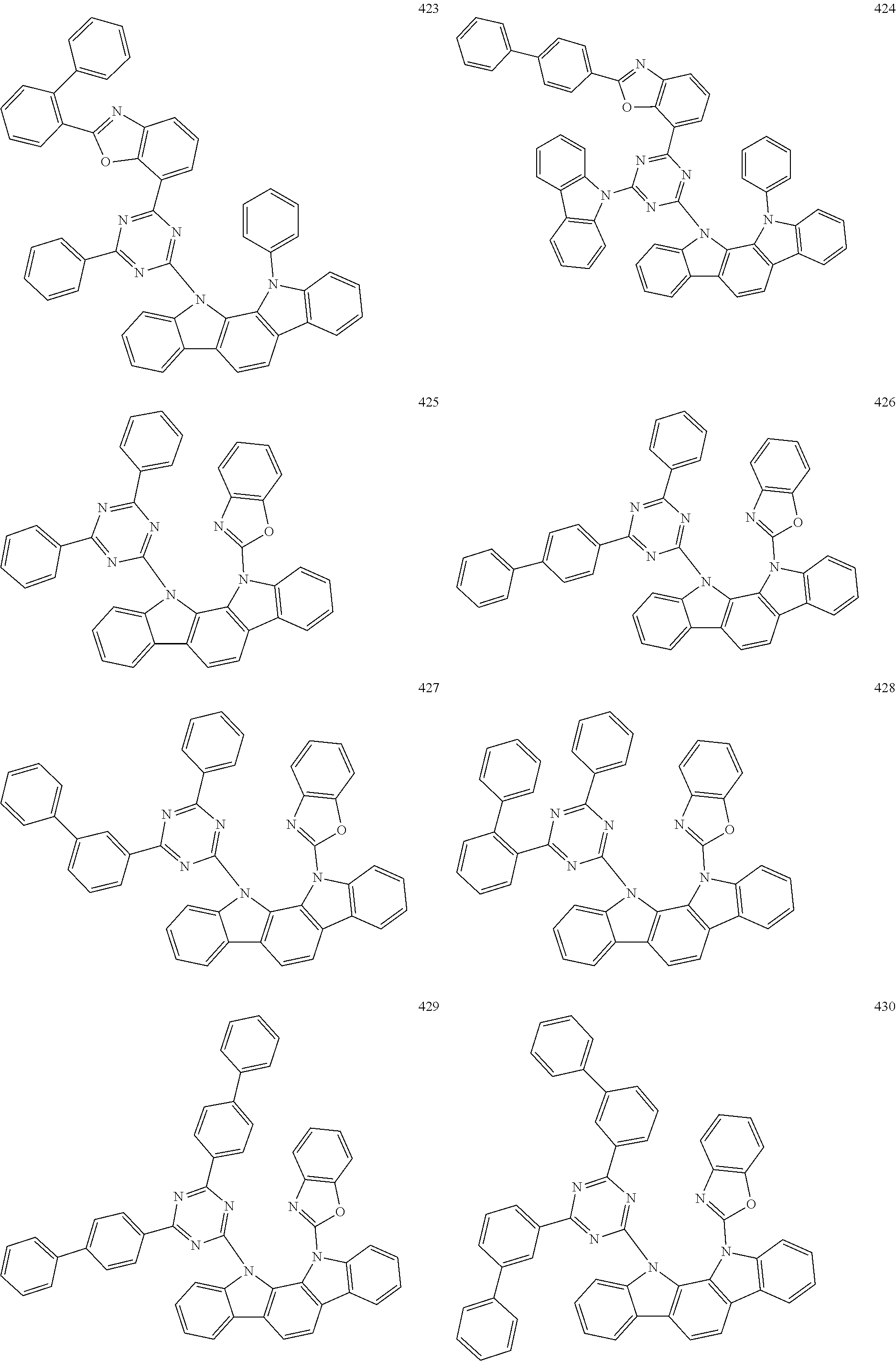

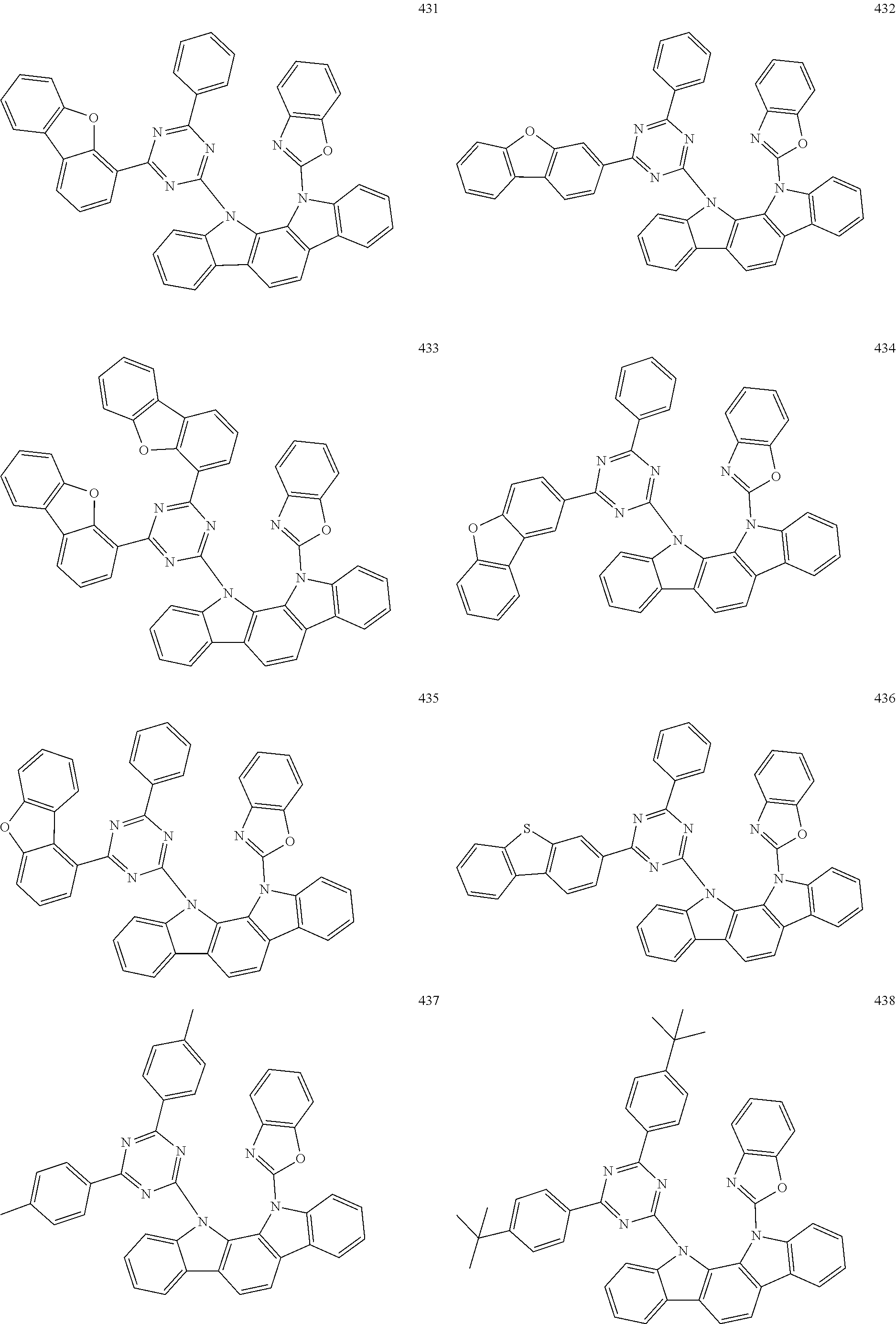

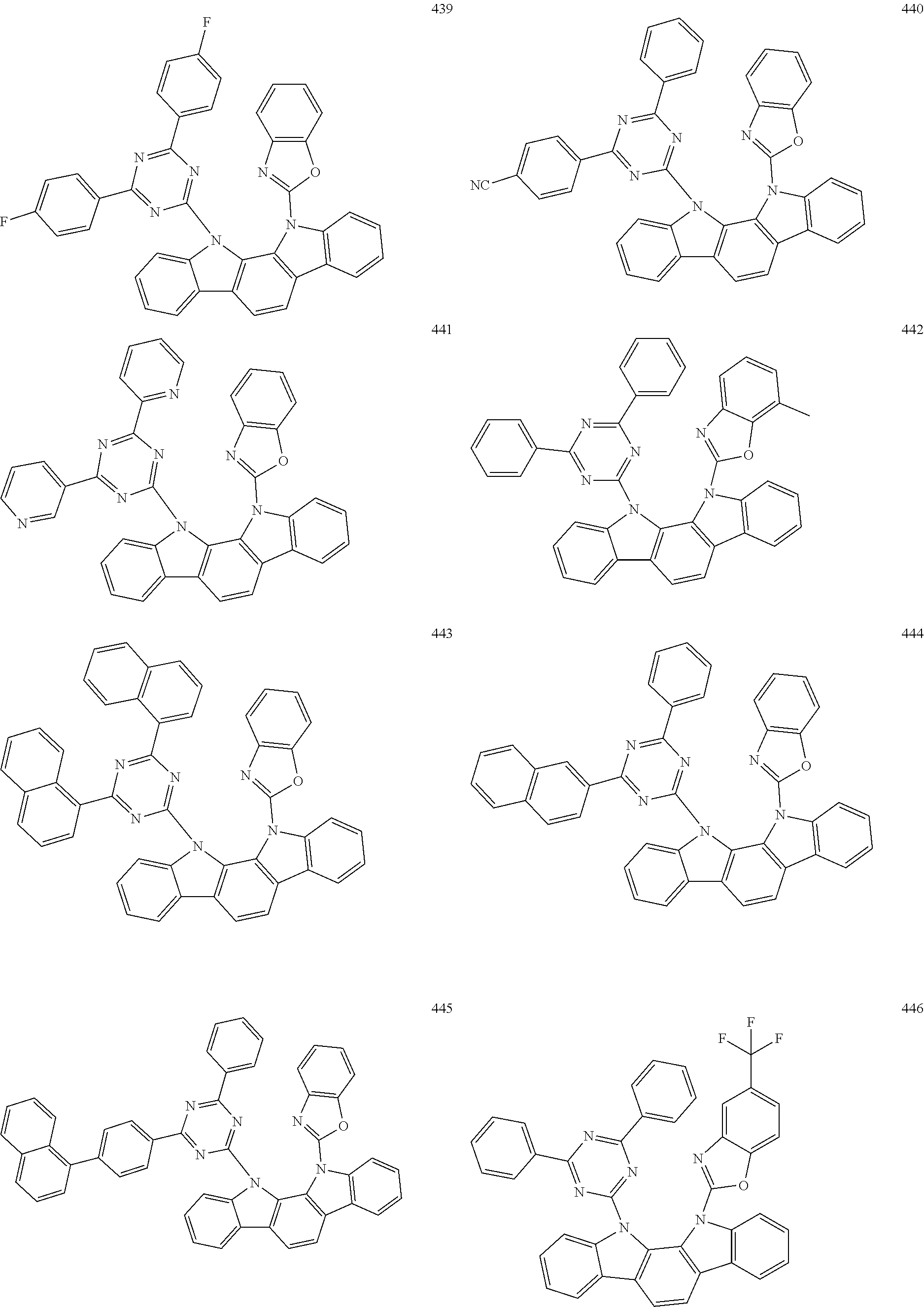

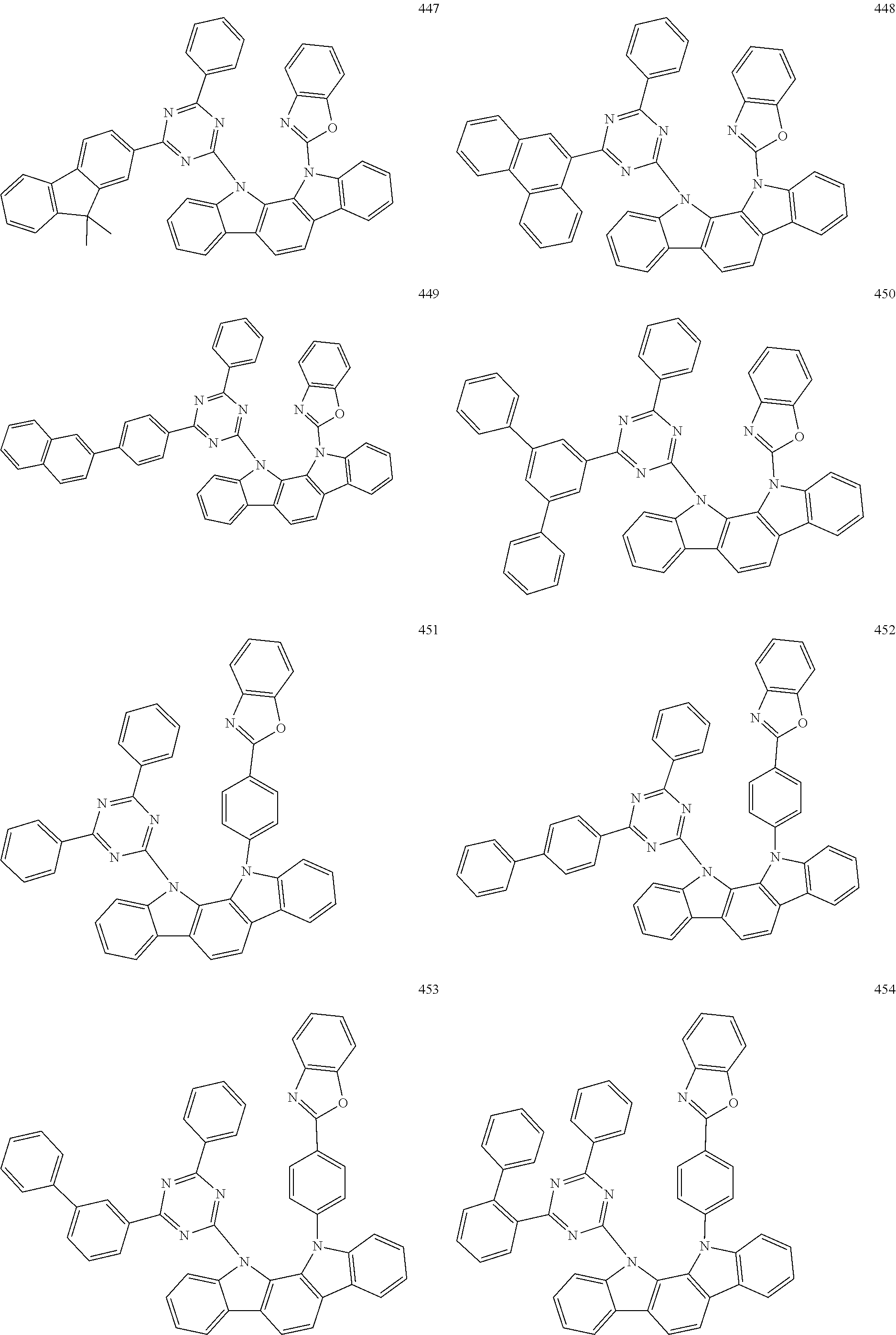

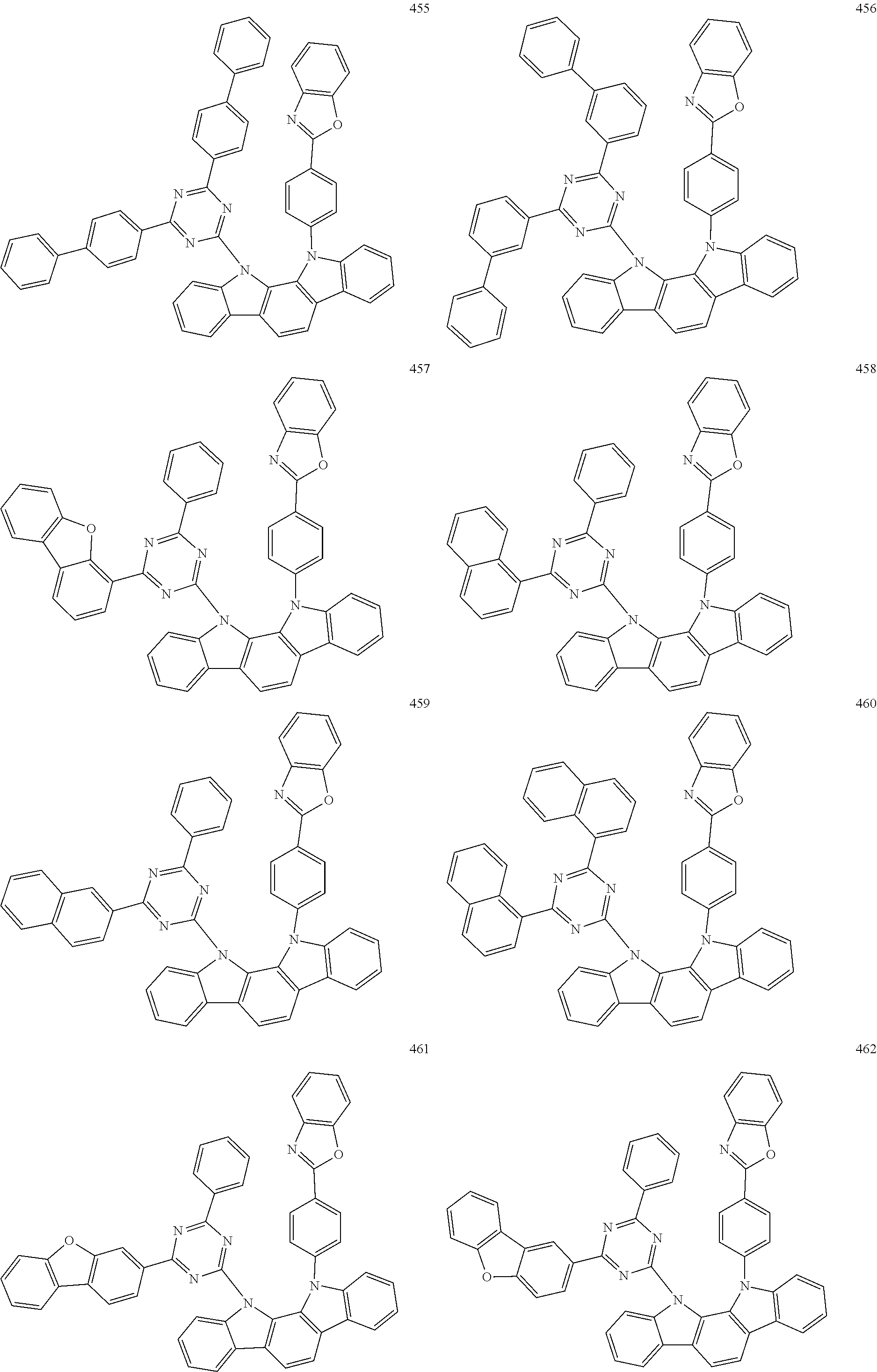

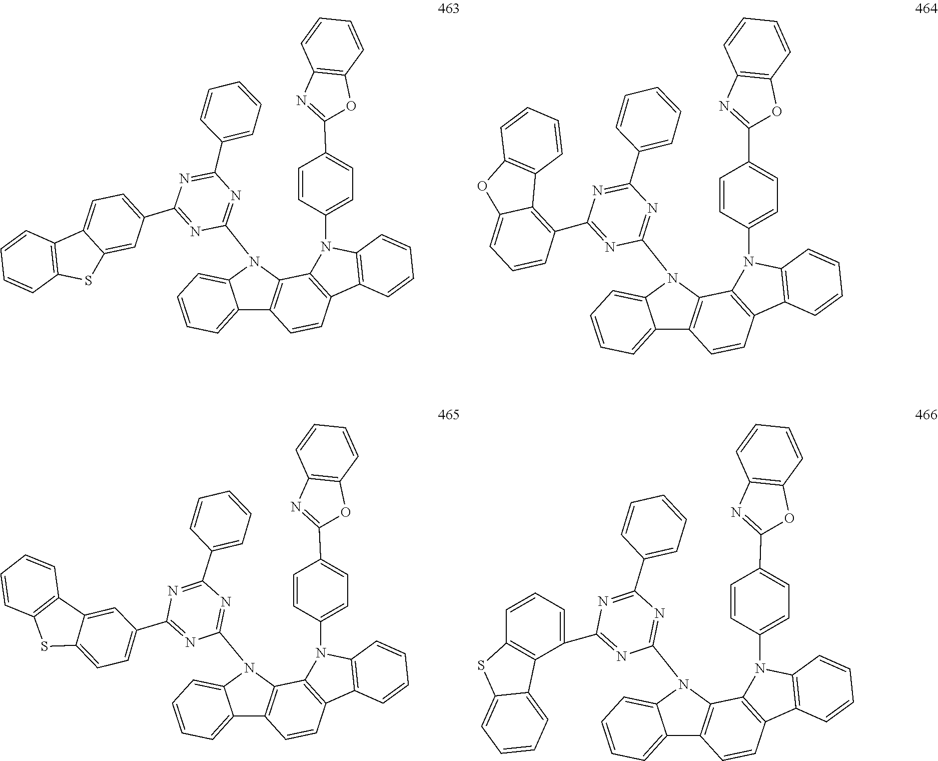 [SMILES: c1ccc(-c2nc(-c3ccc4c(c3)sc3ccccc34)nc(-n3c4ccccc4c4ccc5c6ccccc6n(-c6ccc(-c7nc8ccccc8o7)cc6)c5c43)n2)cc1 ; c1ccc(-c2nc(-c3cccc4oc5ccccc5c34)nc(-n3c4ccccc4c4ccc5c6ccccc6n(-c6ccc(-c7nc8ccccc8o7)cc6)c5c43)n2)cc1 ; c1ccc(-c2nc(-c3ccc4sc5ccccc5c4c3)nc(-n3c4ccccc4c4ccc5c6ccccc6n(-c6ccc(-c7nc8ccccc8o7)cc6)c5c43)n2)cc1 ; c1ccc(-c2nc(-c3cccc4sc5ccccc5c34)nc(-n3c4ccccc4c4ccc5c6ccccc6n(-c6ccc(-c7nc8ccccc8o7)cc6)c5c43)n2)cc1]

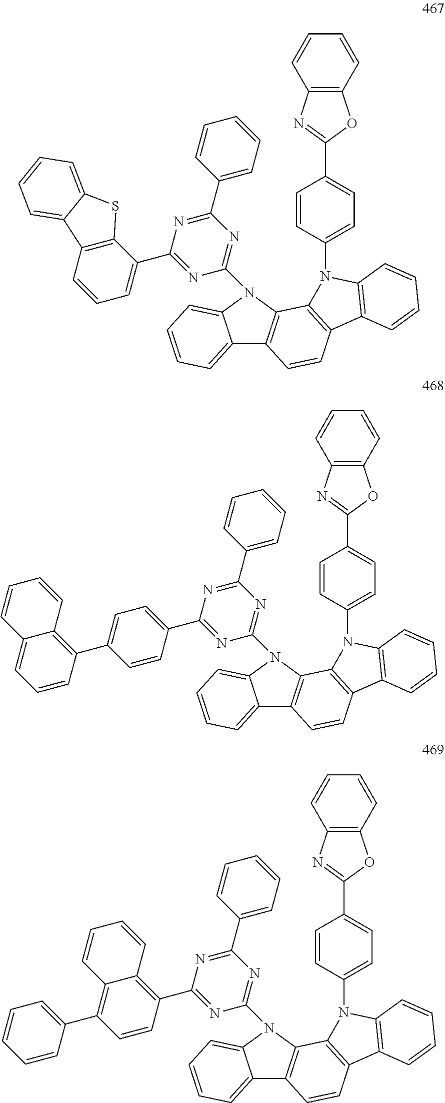 [SMILES: c1ccc(-c2nc(-c3cccc4c3sc3ccccc34)nc(-n3c4ccccc4c4ccc5c6ccccc6n(-c6ccc(-c7nc8ccccc8o7)cc6)c5c43)n2)cc1 ; c1ccc(-c2nc(-c3ccc(-c4cccc5ccccc45)cc3)nc(-n3c4ccccc4c4ccc5c6ccccc6n(-c6ccc(-c7nc8ccccc8o7)cc6)c5c43)n2)cc1 ; c1ccc(-c2nc(-c3ccc(-c4ccccc4)c4ccccc34)nc(-n3c4ccccc4c4ccc5c6ccccc6n(-c6ccc(-c7nc8ccccc8o7)cc6)c5c43)n2)cc1]

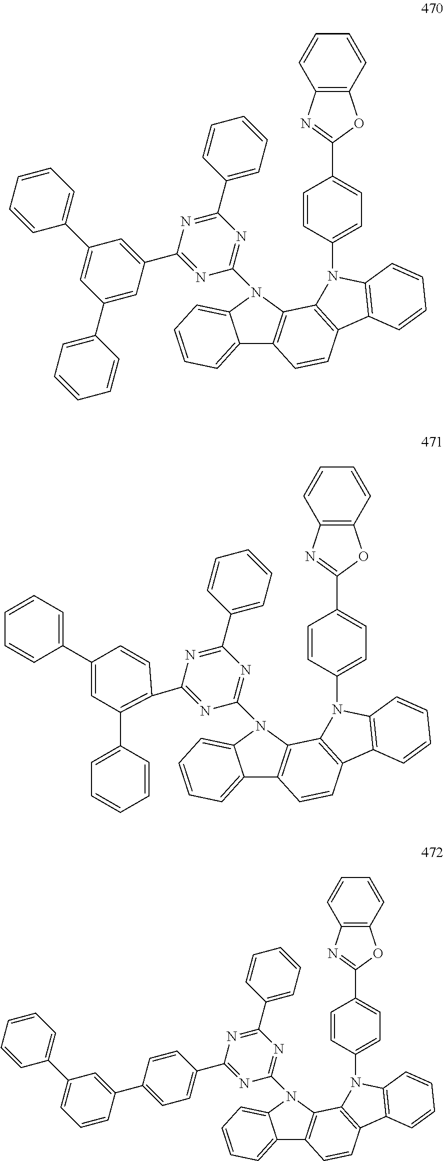 [SMILES: c1ccc(-c2cc(-c3ccccc3)cc(-c3nc(-c4ccccc4)nc(-n4c5ccccc5c5ccc6c7ccccc7n(-c7ccc(-c8nc9ccccc9o8)cc7)c6c54)n3)c2)cc1 ; c1ccc(-c2ccc(-c3nc(-c4ccccc4)nc(-n4c5ccccc5c5ccc6c7ccccc7n(-c7ccc(-c8nc9ccccc9o8)cc7)c6c54)n3)c(-c3ccccc3)c2)cc1 ; c1ccc(-c2cccc(-c3ccc(-c4nc(-c5ccccc5)nc(-n5c6ccccc6c6ccc7c8ccccc8n(-c8ccc(-c9nc%10ccccc%10o9)cc8)c7c65)n4)cc3)c2)cc1]

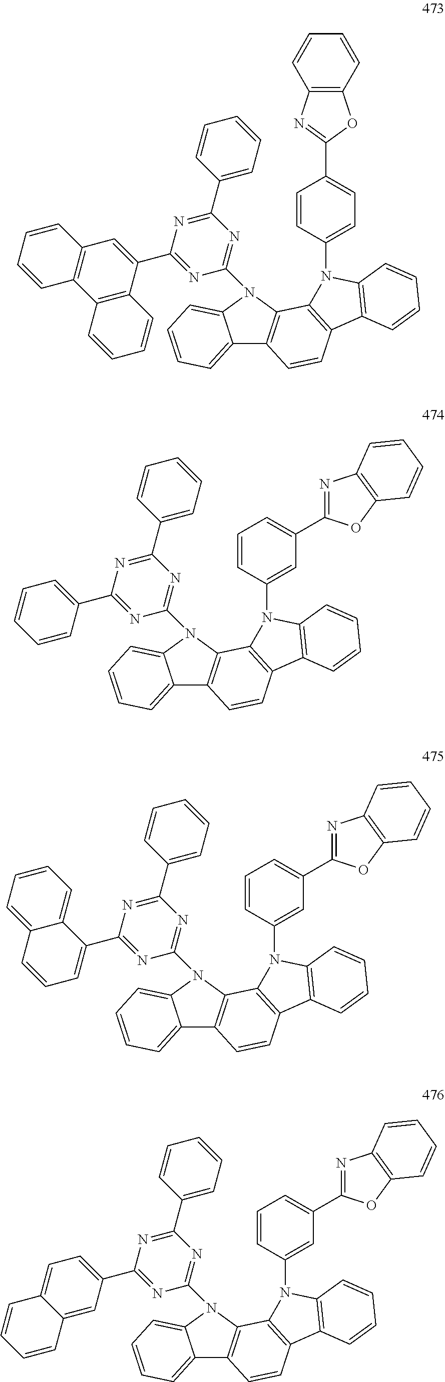 [SMILES: c1ccc(-c2nc(-c3cc4ccccc4c4ccccc34)nc(-n3c4ccccc4c4ccc5c6ccccc6n(-c6ccc(-c7nc8ccccc8o7)cc6)c5c43)n2)cc1 ; c1ccc(-c2nc(-c3ccccc3)nc(-n3c4ccccc4c4ccc5c6ccccc6n(-c6cccc(-c7nc8ccccc8o7)c6)c5c43)n2)cc1 ; c1ccc(-c2nc(-c3cccc4ccccc34)nc(-n3c4ccccc4c4ccc5c6ccccc6n(-c6cccc(-c7nc8ccccc8o7)c6)c5c43)n2)cc1 ; c1ccc(-c2nc(-c3ccc4ccccc4c3)nc(-n3c4ccccc4c4ccc5c6ccccc6n(-c6cccc(-c7nc8ccccc8o7)c6)c5c43)n2)cc1]

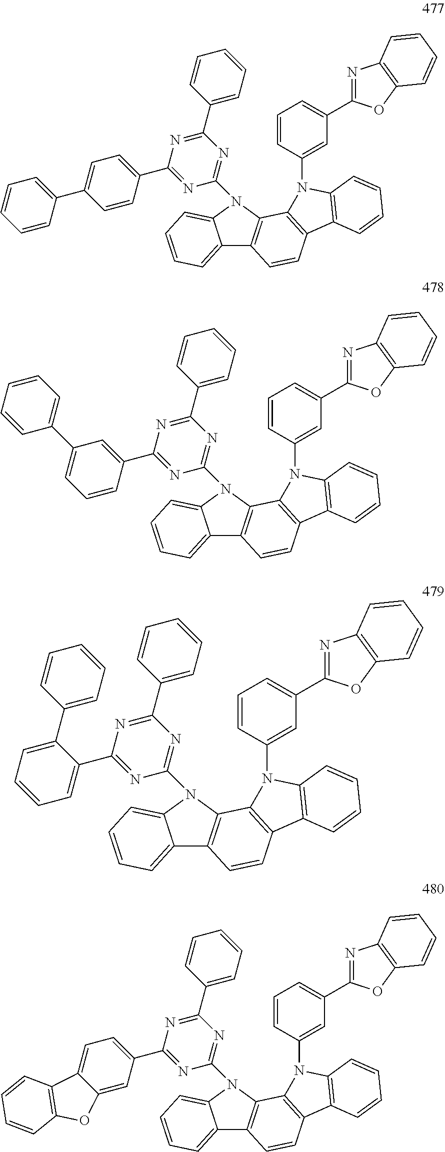 [SMILES: c1ccc(-c2ccc(-c3nc(-c4ccccc4)nc(-n4c5ccccc5c5ccc6c7ccccc7n(-c7cccc(-c8nc9ccccc9o8)c7)c6c54)n3)cc2)cc1 ; c1ccc(-c2cccc(-c3nc(-c4ccccc4)nc(-n4c5ccccc5c5ccc6c7ccccc7n(-c7cccc(-c8nc9ccccc9o8)c7)c6c54)n3)c2)cc1 ; c1ccc(-c2nc(-c3ccccc3-c3ccccc3)nc(-n3c4ccccc4c4ccc5c6ccccc6n(-c6cccc(-c7nc8ccccc8o7)c6)c5c43)n2)cc1 ; c1ccc(-c2nc(-c3ccc4c(c3)oc3ccccc34)nc(-n3c4ccccc4c4ccc5c6ccccc6n(-c6cccc(-c7nc8ccccc8o7)c6)c5c43)n2)cc1]

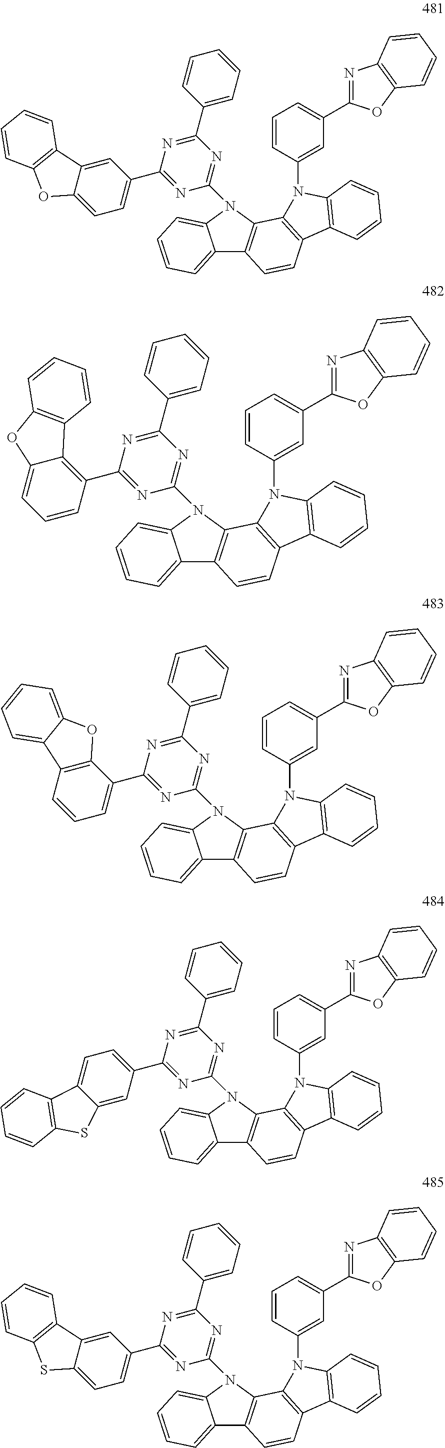

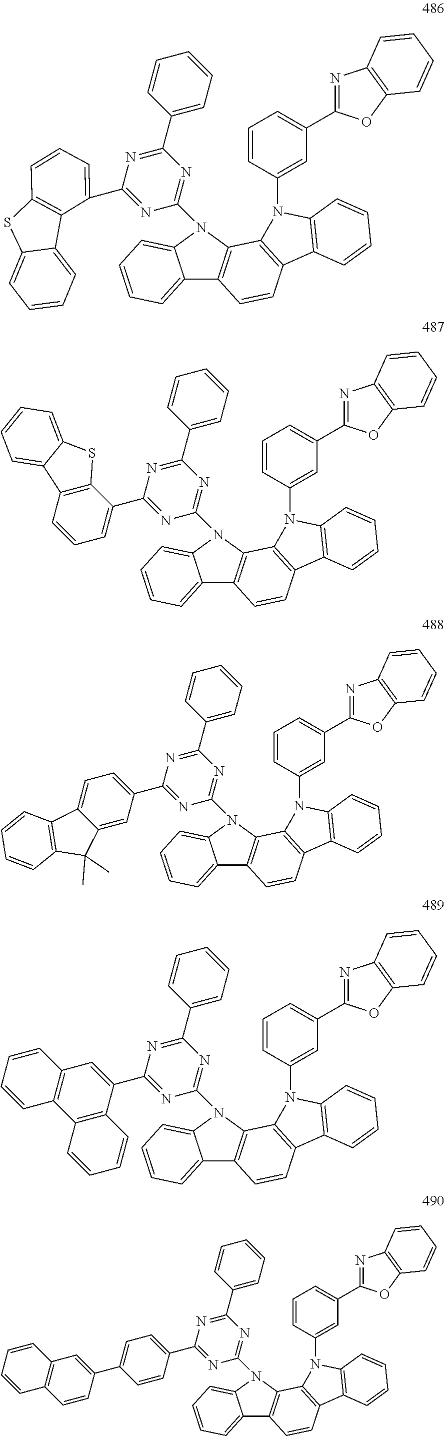

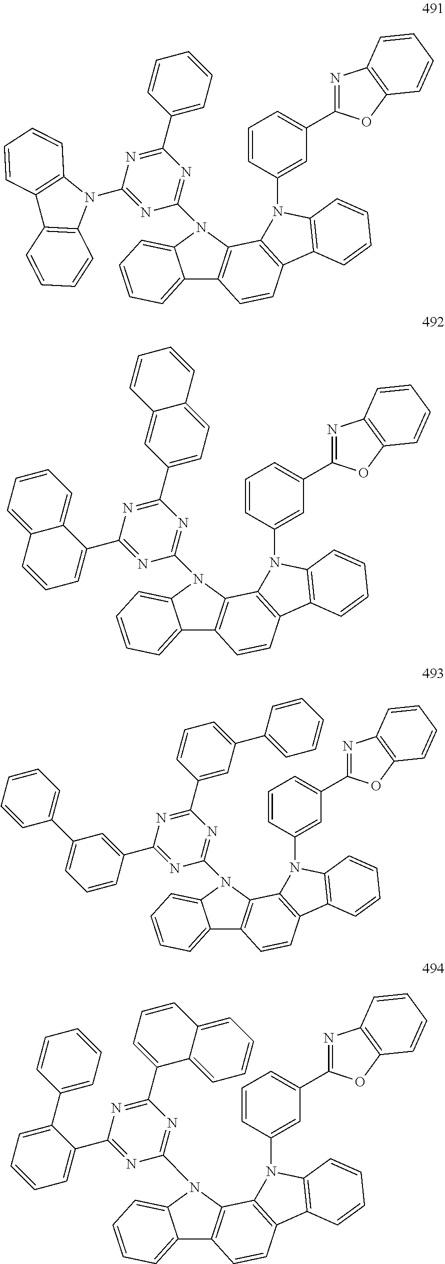

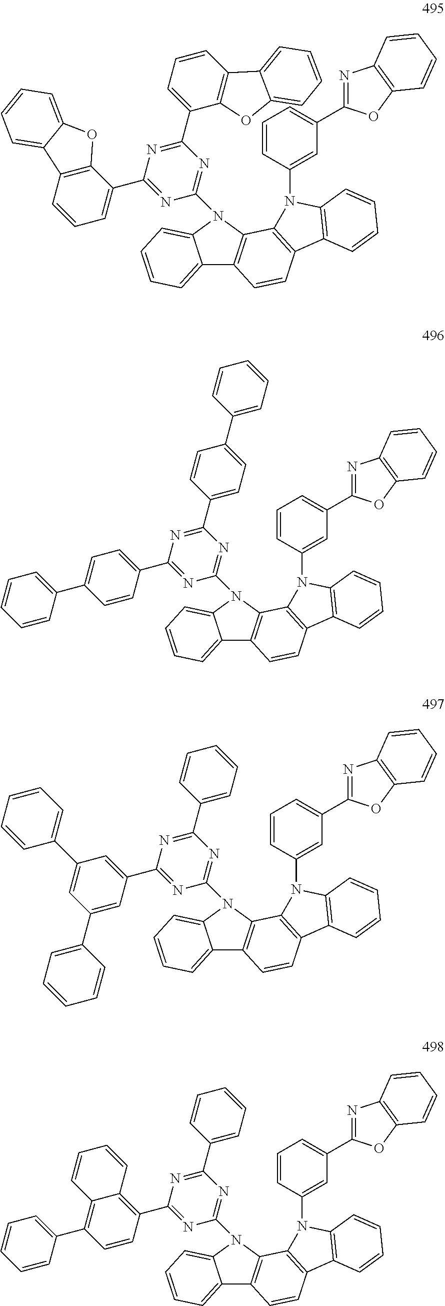 [SMILES: c1cc(-c2nc3ccccc3o2)cc(-n2c3ccccc3c3ccc4c5ccccc5n(-c5nc(-c6cccc7c6oc6ccccc67)nc(-c6cccc7c6oc6ccccc67)n5)c4c32)c1 ; c1ccc(-c2ccc(-c3nc(-c4ccc(-c5ccccc5)cc4)nc(-n4c5ccccc5c5ccc6c7ccccc7n(-c7cccc(-c8nc9ccccc9o8)c7)c6c54)n3)cc2)cc1 ; c1ccc(-c2cc(-c3ccccc3)cc(-c3nc(-c4ccccc4)nc(-n4c5ccccc5c5ccc6c7ccccc7n(-c7cccc(-c8nc9ccccc9o8)c7)c6c54)n3)c2)cc1 ; c1ccc(-c2nc(-c3ccc(-c4ccccc4)c4ccccc34)nc(-n3c4ccccc4c4ccc5c6ccccc6n(-c6cccc(-c7nc8ccccc8o7)c6)c5c43)n2)cc1]

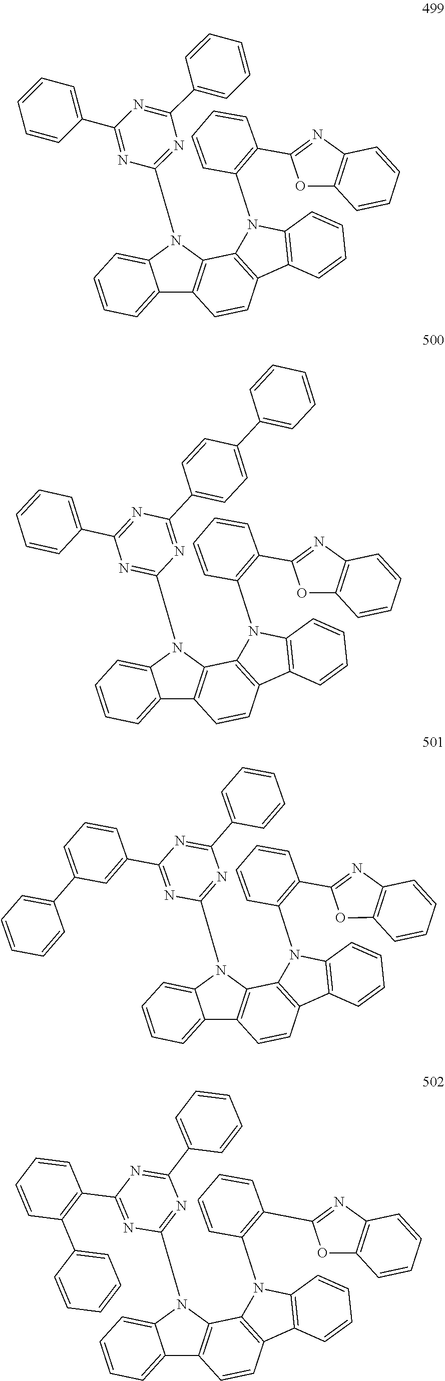 [SMILES: c1ccc(-c2nc(-c3ccccc3)nc(-n3c4ccccc4c4ccc5c6ccccc6n(-c6ccccc6-c6nc7ccccc7o6)c5c43)n2)cc1 ; c1ccc(-c2ccc(-c3nc(-c4ccccc4)nc(-n4c5ccccc5c5ccc6c7ccccc7n(-c7ccccc7-c7nc8ccccc8o7)c6c54)n3)cc2)cc1 ; c1ccc(-c2cccc(-c3nc(-c4ccccc4)nc(-n4c5ccccc5c5ccc6c7ccccc7n(-c7ccccc7-c7nc8ccccc8o7)c6c54)n3)c2)cc1 ; c1ccc(-c2nc(-c3ccccc3-c3ccccc3)nc(-n3c4ccccc4c4ccc5c6ccccc6n(-c6ccccc6-c6nc7ccccc7o6)c5c43)n2)cc1]

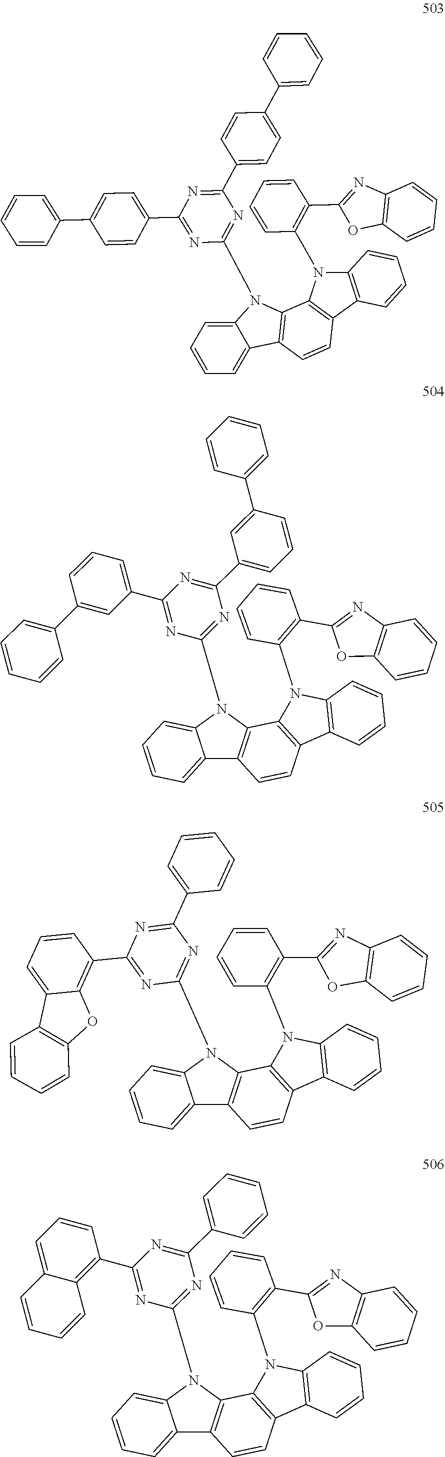

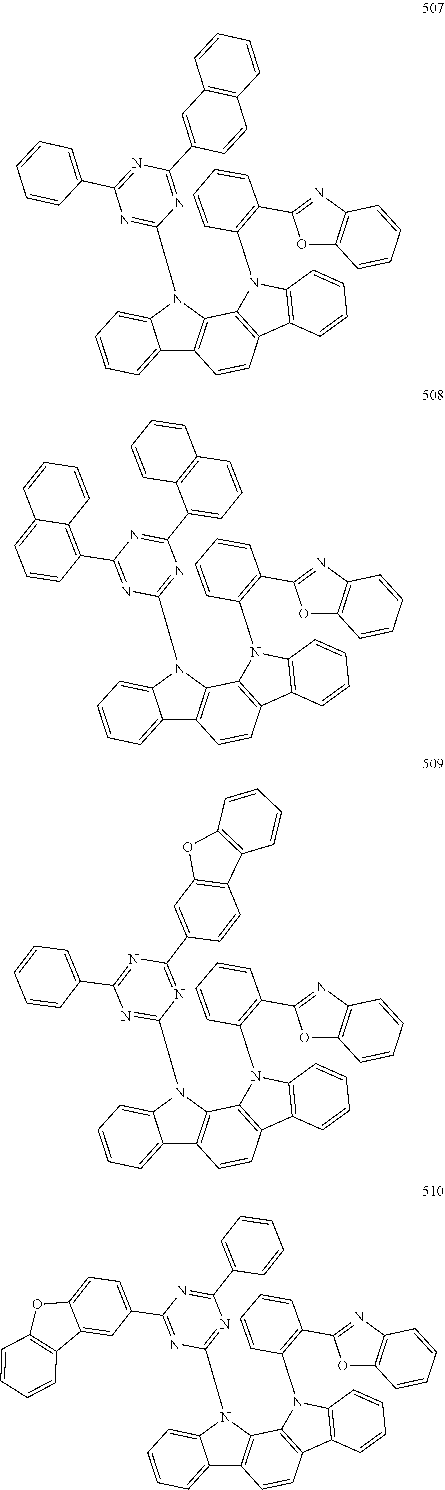 [SMILES: c1ccc(-c2nc(-c3ccc4ccccc4c3)nc(-n3c4ccccc4c4ccc5c6ccccc6n(-c6ccccc6-c6nc7ccccc7o6)c5c43)n2)cc1 ; c1ccc(-n2c3ccccc3c3ccc4c5ccccc5n(-c5nc(-c6cccc7ccccc67)nc(-c6cccc7ccccc67)n5)c4c32)c(-c2nc3ccccc3o2)c1 ; c1ccc(-c2nc(-c3ccc4c(c3)oc3ccccc34)nc(-n3c4ccccc4c4ccc5c6ccccc6n(-c6ccccc6-c6nc7ccccc7o6)c5c43)n2)cc1 ; c1ccc(-c2nc(-c3ccc4oc5ccccc5c4c3)nc(-n3c4ccccc4c4ccc5c6ccccc6n(-c6ccccc6-c6nc7ccccc7o6)c5c43)n2)cc1]

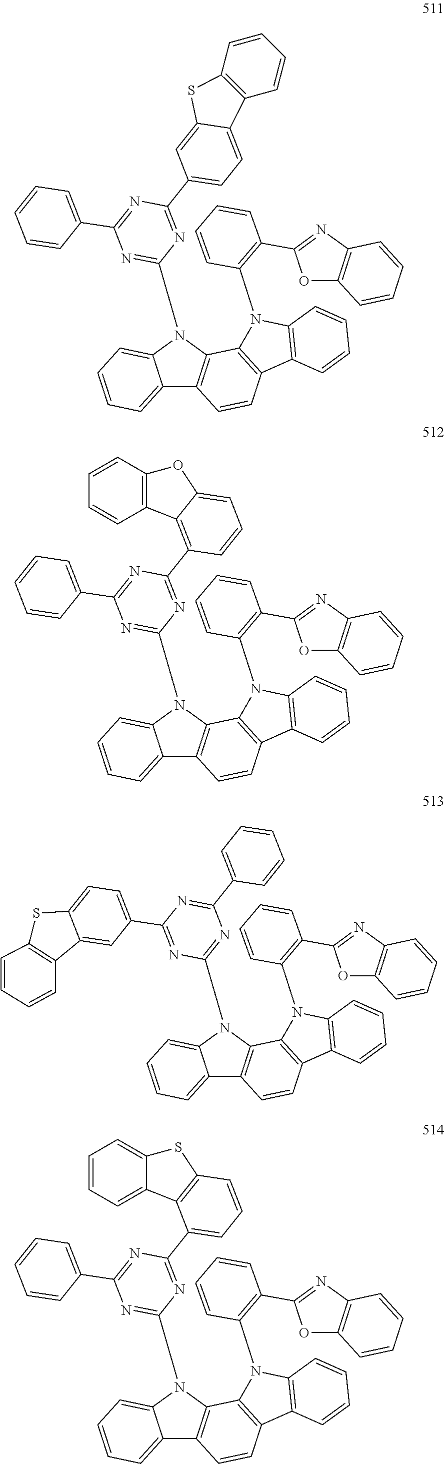 [SMILES: c1ccc(-c2nc(-c3ccc4c(c3)sc3ccccc34)nc(-n3c4ccccc4c4ccc5c6ccccc6n(-c6ccccc6-c6nc7ccccc7o6)c5c43)n2)cc1 ; c1ccc(-c2nc(-c3cccc4oc5ccccc5c34)nc(-n3c4ccccc4c4ccc5c6ccccc6n(-c6ccccc6-c6nc7ccccc7o6)c5c43)n2)cc1 ; c1ccc(-c2nc(-c3ccc4sc5ccccc5c4c3)nc(-n3c4ccccc4c4ccc5c6ccccc6n(-c6ccccc6-c6nc7ccccc7o6)c5c43)n2)cc1 ; c1ccc(-c2nc(-c3cccc4sc5ccccc5c34)nc(-n3c4ccccc4c4ccc5c6ccccc6n(-c6ccccc6-c6nc7ccccc7o6)c5c43)n2)cc1]

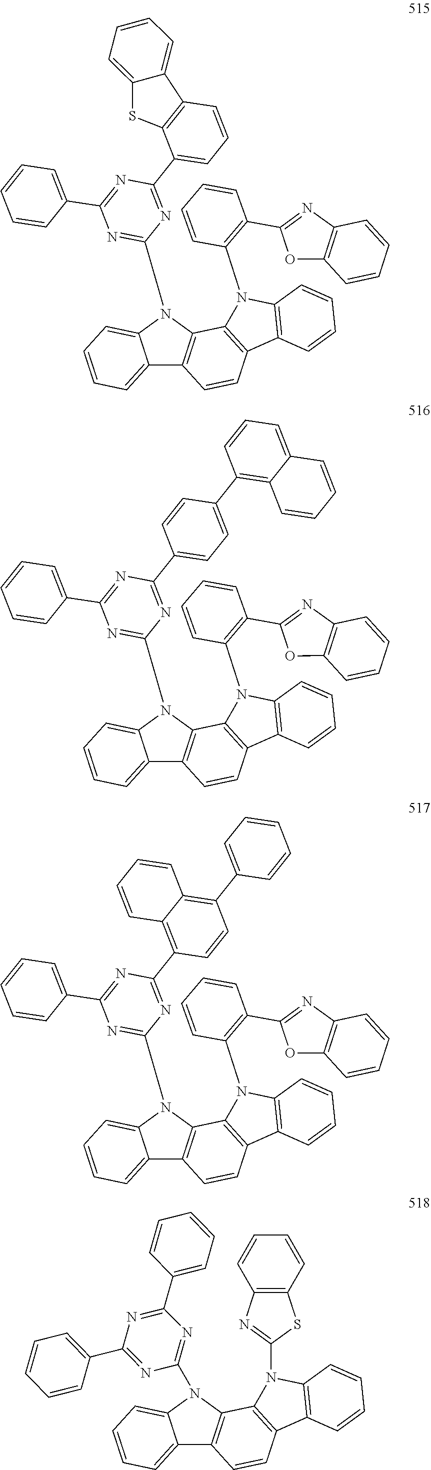

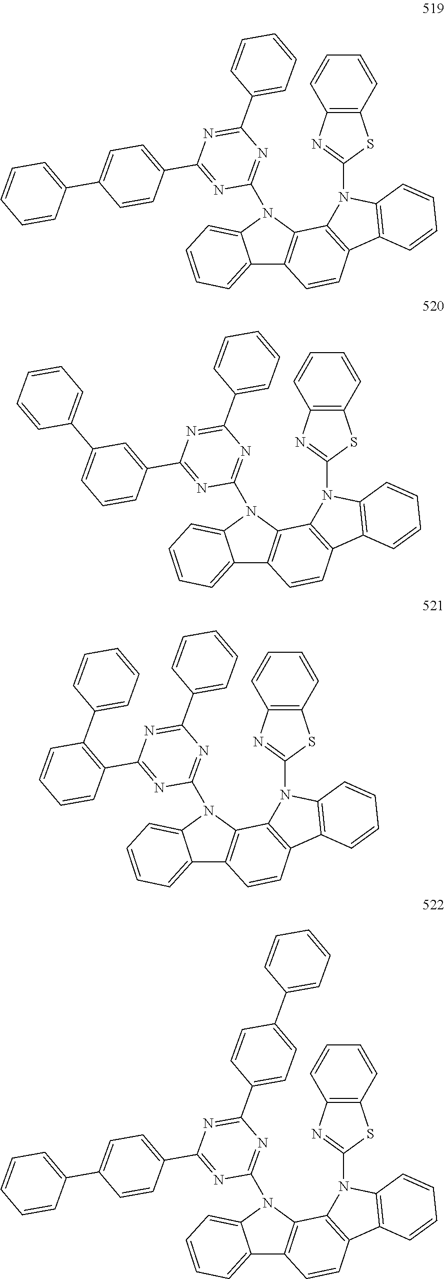

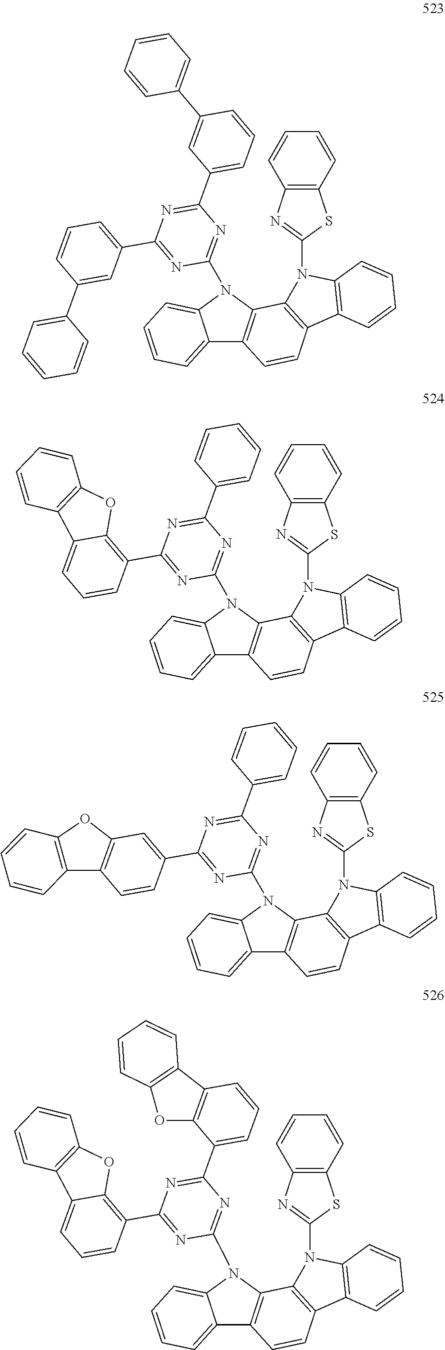

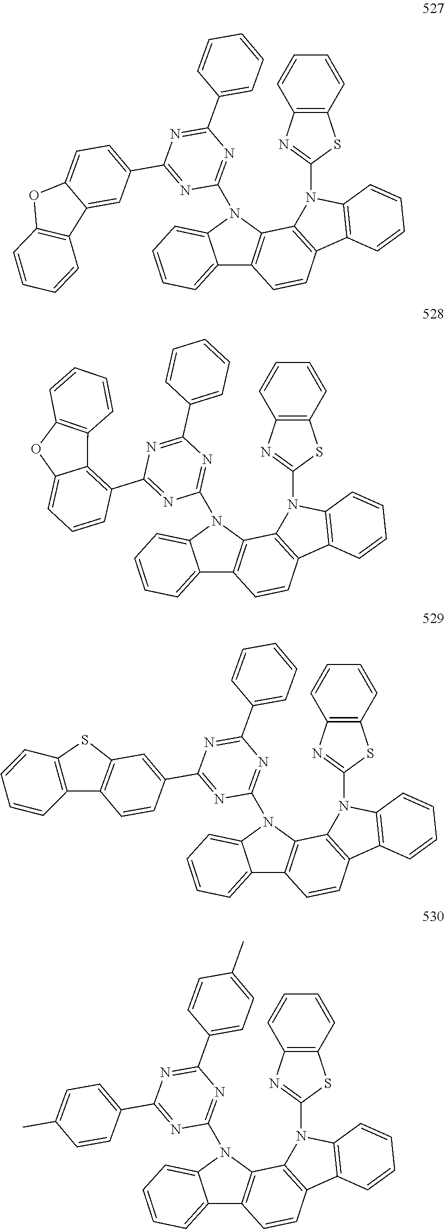

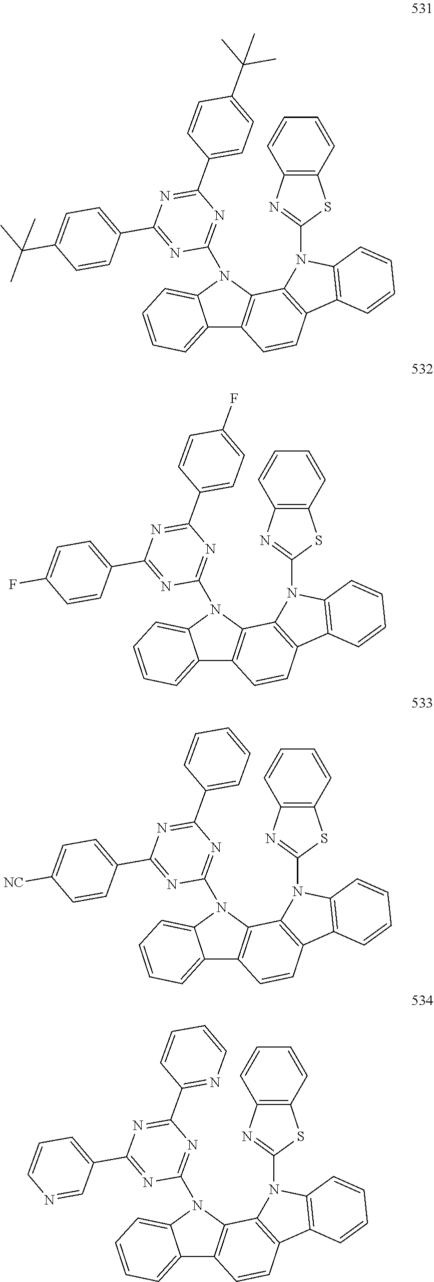 [SMILES: CC(C)(C)c1ccc(-c2nc(-c3ccc(C(C)(C)C)cc3)nc(-n3c4ccccc4c4ccc5c6ccccc6n(-c6nc7ccccc7s6)c5c43)n2)cc1 ; Fc1ccc(-c2nc(-c3ccc(F)cc3)nc(-n3c4ccccc4c4ccc5c6ccccc6n(-c6nc7ccccc7s6)c5c43)n2)cc1 ; N#Cc1ccc(-c2nc(-c3ccccc3)nc(-n3c4ccccc4c4ccc5c6ccccc6n(-c6nc7ccccc7s6)c5c43)n2)cc1 ; c1ccc(-c2nc(-c3cccnc3)nc(-n3c4ccccc4c4ccc5c6ccccc6n(-c6nc7ccccc7s6)c5c43)n2)nc1]

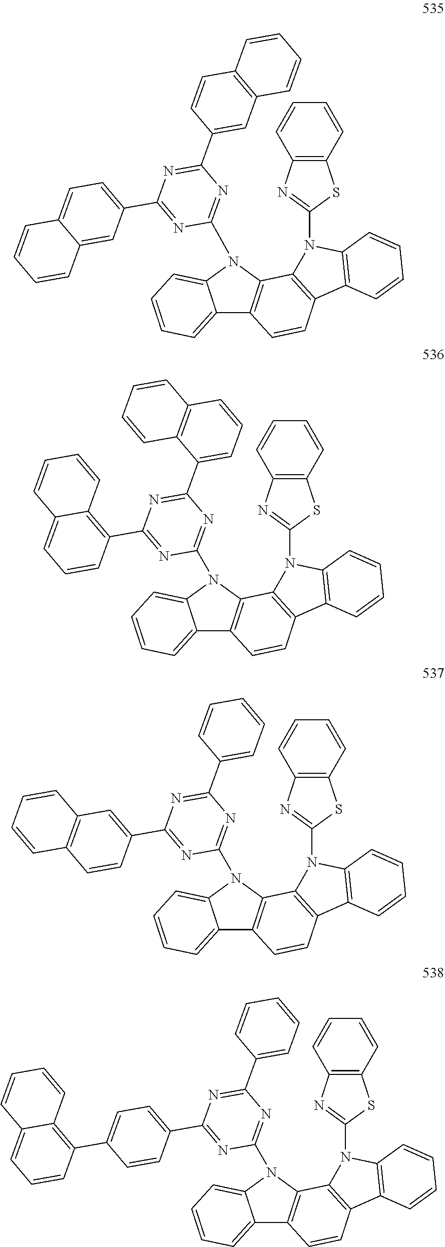

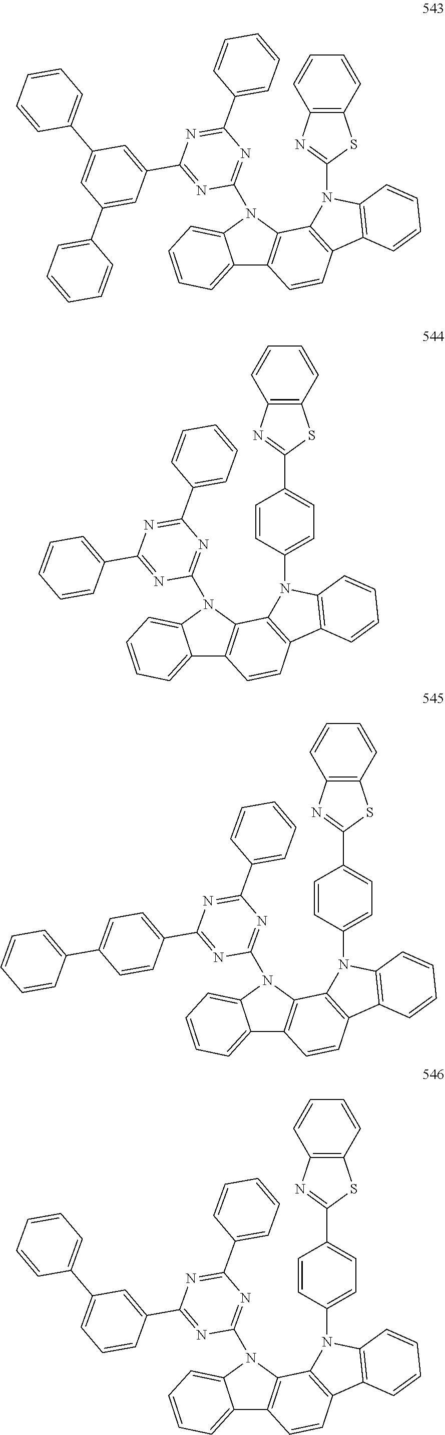

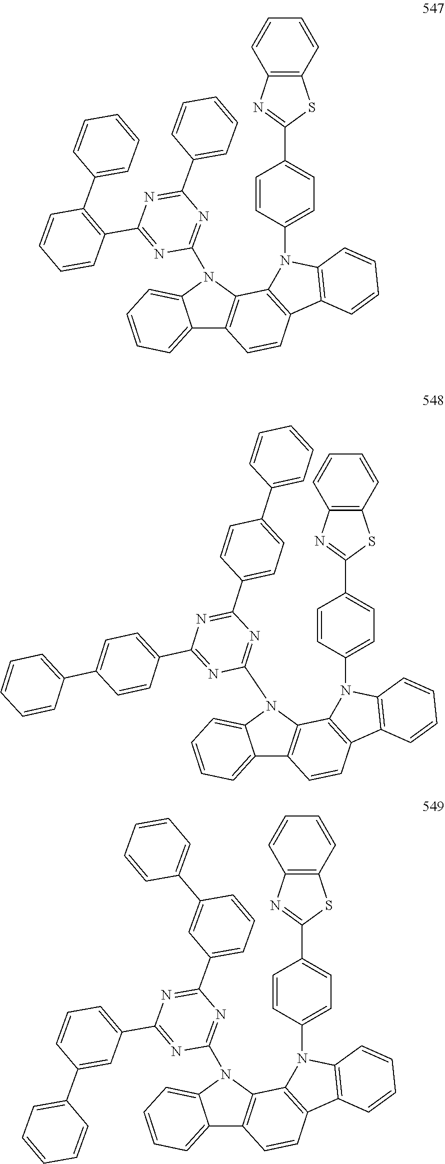

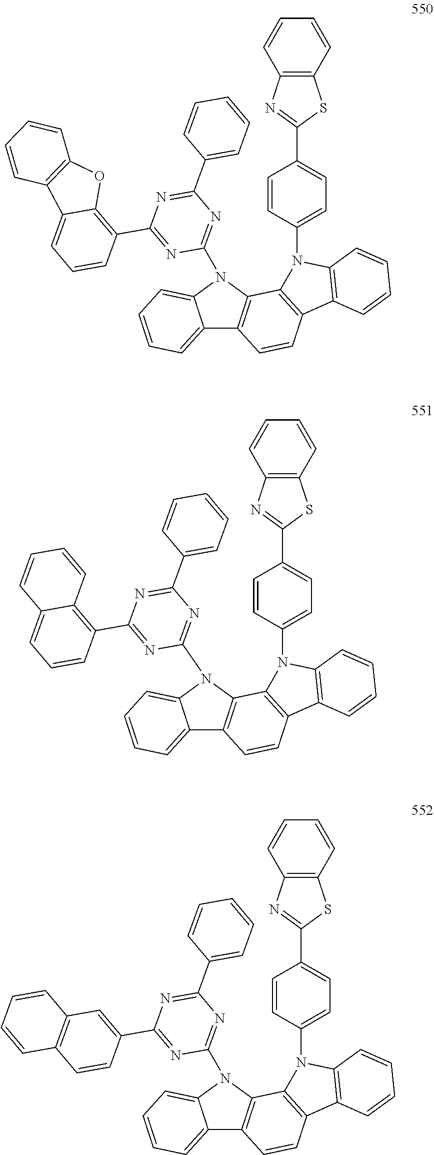 [SMILES: c1ccc(-c2nc(-c3cccc4c3oc3ccccc34)nc(-n3c4ccccc4c4ccc5c6ccccc6n(-c6ccc(-c7nc8ccccc8s7)cc6)c5c43)n2)cc1 ; c1ccc(-c2nc(-c3cccc4ccccc34)nc(-n3c4ccccc4c4ccc5c6ccccc6n(-c6ccc(-c7nc8ccccc8s7)cc6)c5c43)n2)cc1 ; c1ccc(-c2nc(-c3ccc4ccccc4c3)nc(-n3c4ccccc4c4ccc5c6ccccc6n(-c6ccc(-c7nc8ccccc8s7)cc6)c5c43)n2)cc1]

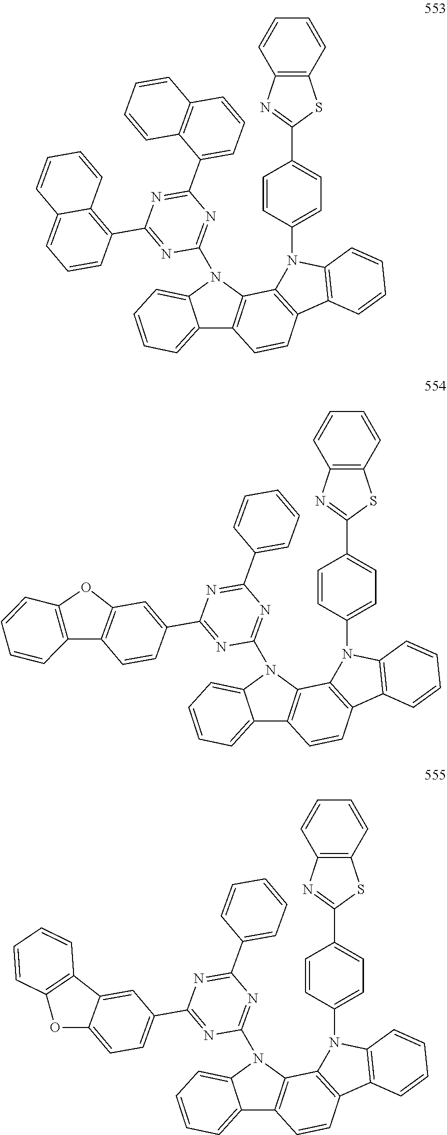 [SMILES: c1ccc2c(-c3nc(-c4cccc5ccccc45)nc(-n4c5ccccc5c5ccc6c7ccccc7n(-c7ccc(-c8nc9ccccc9s8)cc7)c6c54)n3)cccc2c1 ; c1ccc(-c2nc(-c3ccc4c(c3)oc3ccccc34)nc(-n3c4ccccc4c4ccc5c6ccccc6n(-c6ccc(-c7nc8ccccc8s7)cc6)c5c43)n2)cc1 ; c1ccc(-c2nc(-c3ccc4oc5ccccc5c4c3)nc(-n3c4ccccc4c4ccc5c6ccccc6n(-c6ccc(-c7nc8ccccc8s7)cc6)c5c43)n2)cc1]

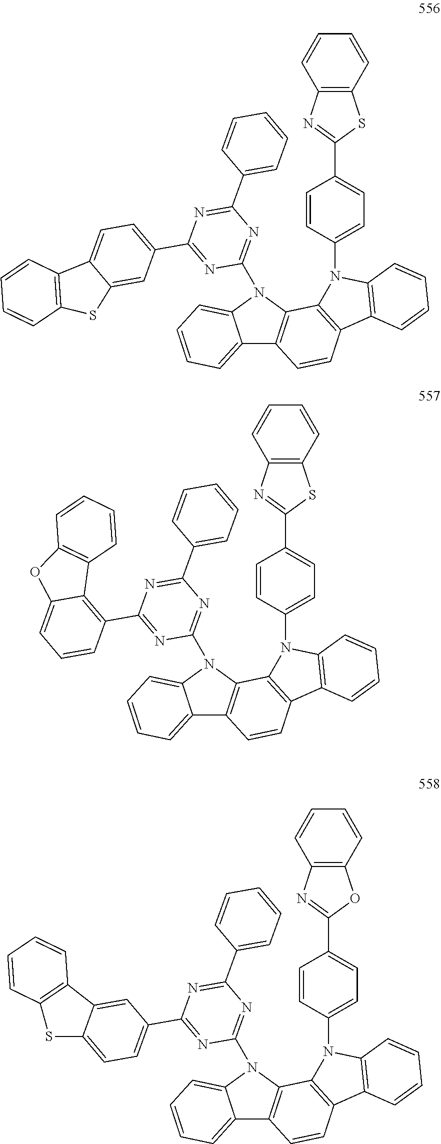

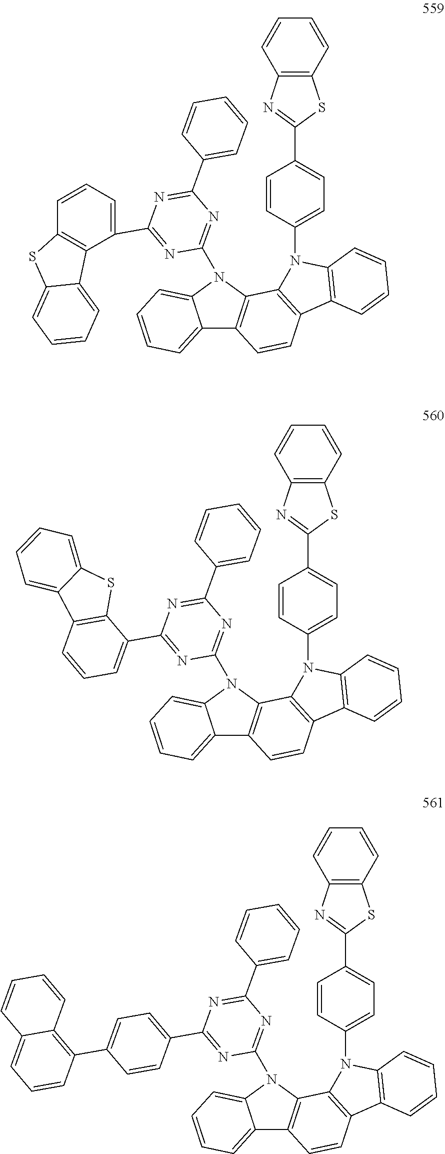 [SMILES: c1ccc(-c2nc(-c3cccc4sc5ccccc5c34)nc(-n3c4ccccc4c4ccc5c6ccccc6n(-c6ccc(-c7nc8ccccc8s7)cc6)c5c43)n2)cc1 ; c1ccc(-c2nc(-c3cccc4c3sc3ccccc34)nc(-n3c4ccccc4c4ccc5c6ccccc6n(-c6ccc(-c7nc8ccccc8s7)cc6)c5c43)n2)cc1 ; c1ccc(-c2nc(-c3ccc(-c4cccc5ccccc45)cc3)nc(-n3c4ccccc4c4ccc5c6ccccc6n(-c6ccc(-c7nc8ccccc8s7)cc6)c5c43)n2)cc1]

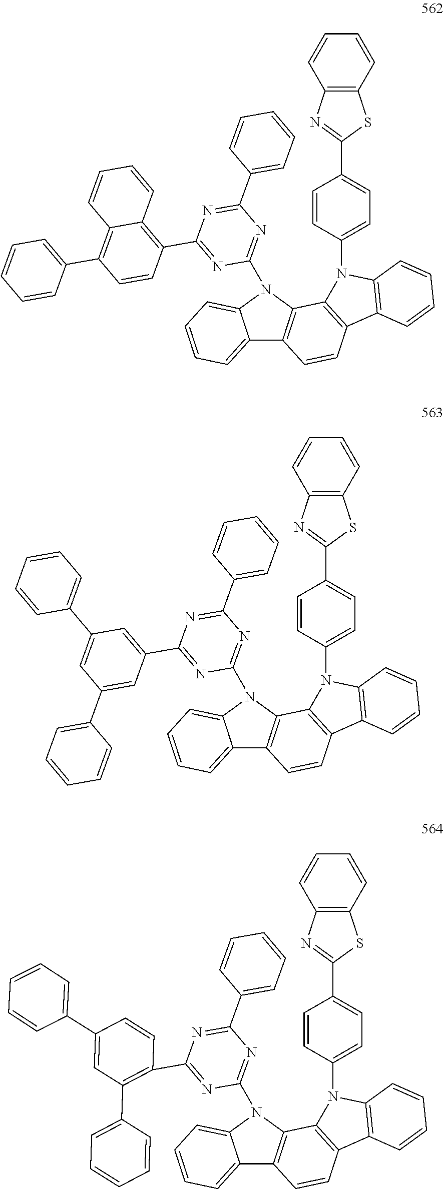 [SMILES: c1ccc(-c2nc(-c3ccc(-c4ccccc4)c4ccccc34)nc(-n3c4ccccc4c4ccc5c6ccccc6n(-c6ccc(-c7nc8ccccc8s7)cc6)c5c43)n2)cc1 ; c1ccc(-c2cc(-c3ccccc3)cc(-c3nc(-c4ccccc4)nc(-n4c5ccccc5c5ccc6c7ccccc7n(-c7ccc(-c8nc9ccccc9s8)cc7)c6c54)n3)c2)cc1 ; c1ccc(-c2ccc(-c3nc(-c4ccccc4)nc(-n4c5ccccc5c5ccc6c7ccccc7n(-c7ccc(-c8nc9ccccc9s8)cc7)c6c54)n3)c(-c3ccccc3)c2)cc1]

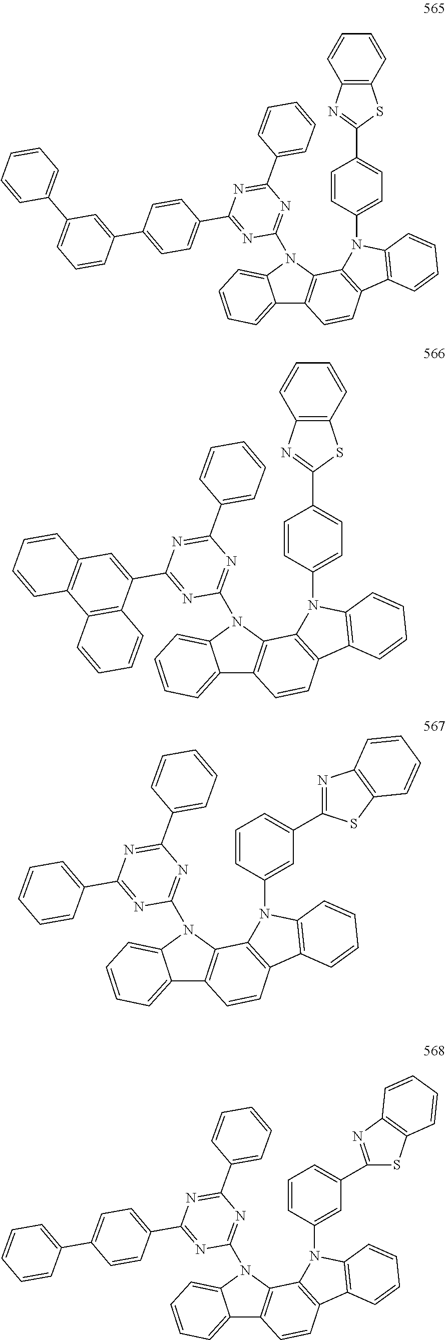

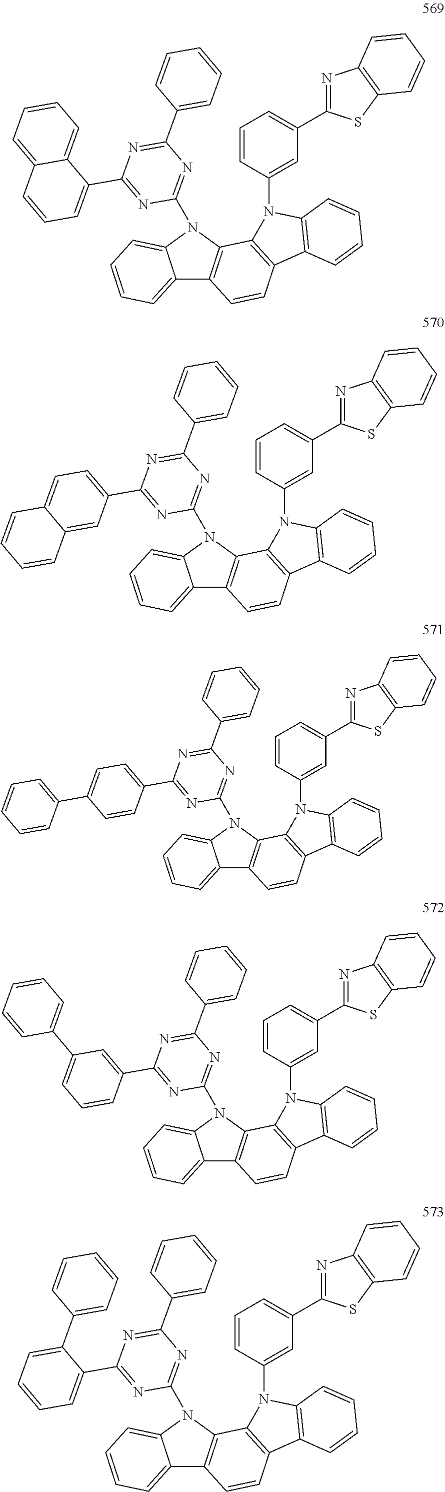

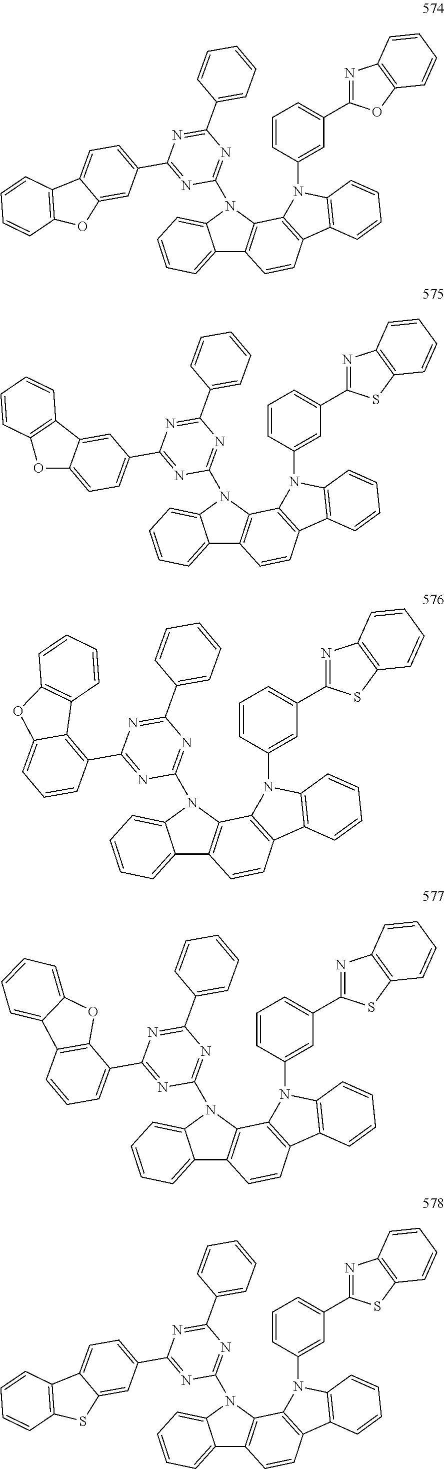

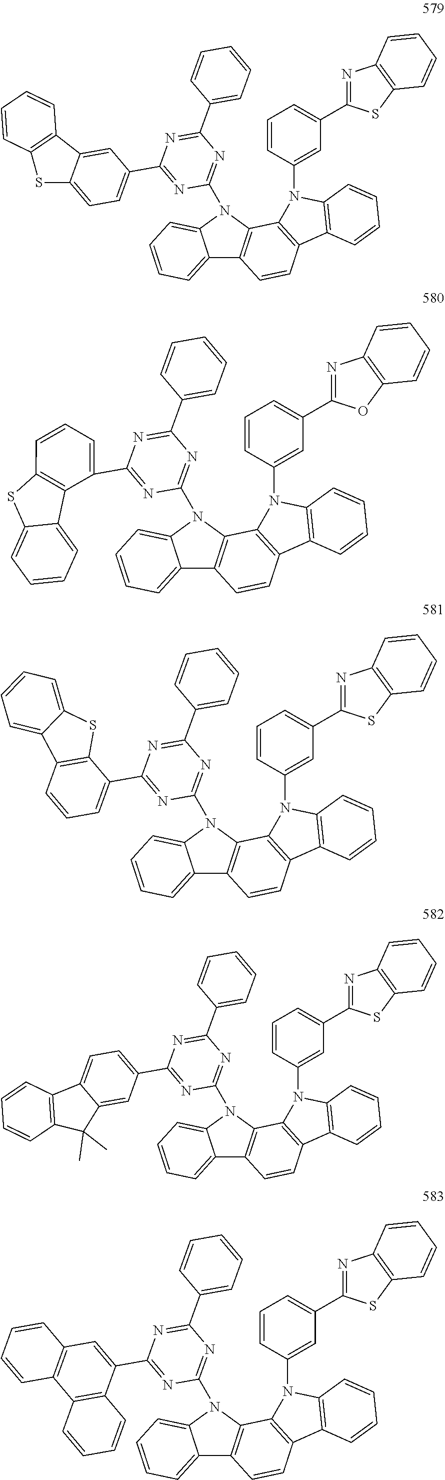

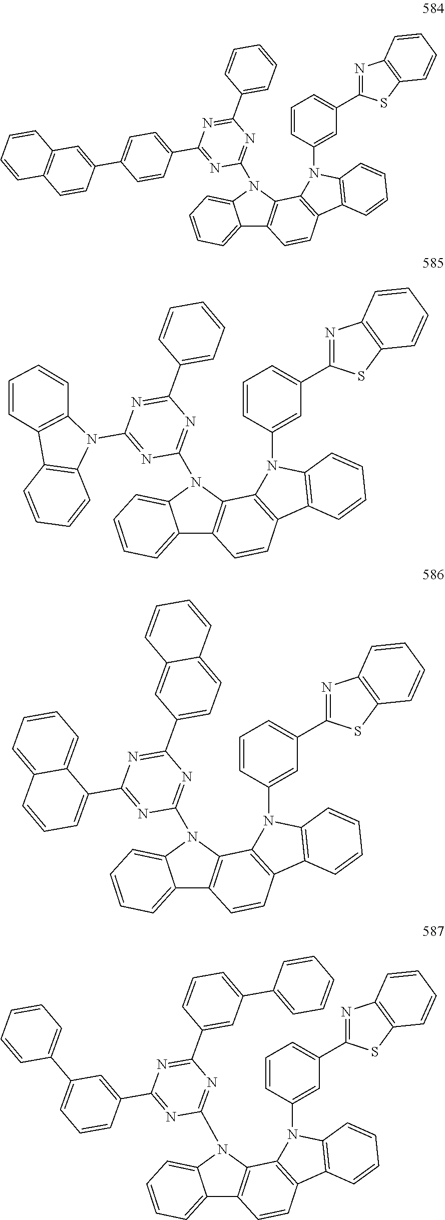 [SMILES: c1ccc(-c2nc(-c3ccc(-c4ccc5ccccc5c4)cc3)nc(-n3c4ccccc4c4ccc5c6ccccc6n(-c6cccc(-c7nc8ccccc8s7)c6)c5c43)n2)cc1 ; c1ccc(-c2nc(-n3c4ccccc4c4ccccc43)nc(-n3c4ccccc4c4ccc5c6ccccc6n(-c6cccc(-c7nc8ccccc8s7)c6)c5c43)n2)cc1 ; c1cc(-c2nc3ccccc3s2)cc(-n2c3ccccc3c3ccc4c5ccccc5n(-c5nc(-c6ccc7ccccc7c6)nc(-c6cccc7ccccc67)n5)c4c32)c1 ; c1ccc(-c2cccc(-c3nc(-c4cccc(-c5ccccc5)c4)nc(-n4c5ccccc5c5ccc6c7ccccc7n(-c7cccc(-c8nc9ccccc9s8)c7)c6c54)n3)c2)cc1]

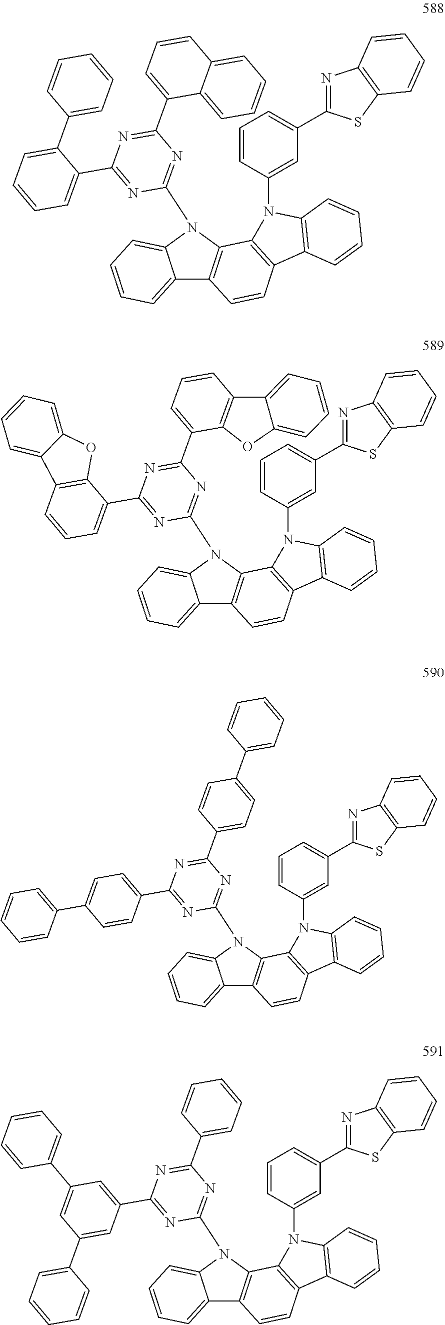 [SMILES: c1ccc(-c2ccccc2-c2nc(-c3cccc4ccccc34)nc(-n3c4ccccc4c4ccc5c6ccccc6n(-c6cccc(-c7nc8ccccc8s7)c6)c5c43)n2)cc1 ; c1cc(-c2nc3ccccc3s2)cc(-n2c3ccccc3c3ccc4c5ccccc5n(-c5nc(-c6cccc7c6oc6ccccc67)nc(-c6cccc7c6oc6ccccc67)n5)c4c32)c1 ; c1ccc(-c2ccc(-c3nc(-c4ccc(-c5ccccc5)cc4)nc(-n4c5ccccc5c5ccc6c7ccccc7n(-c7cccc(-c8nc9ccccc9s8)c7)c6c54)n3)cc2)cc1 ; c1ccc(-c2cc(-c3ccccc3)cc(-c3nc(-c4ccccc4)nc(-n4c5ccccc5c5ccc6c7ccccc7n(-c7cccc(-c8nc9ccccc9s8)c7)c6c54)n3)c2)cc1]

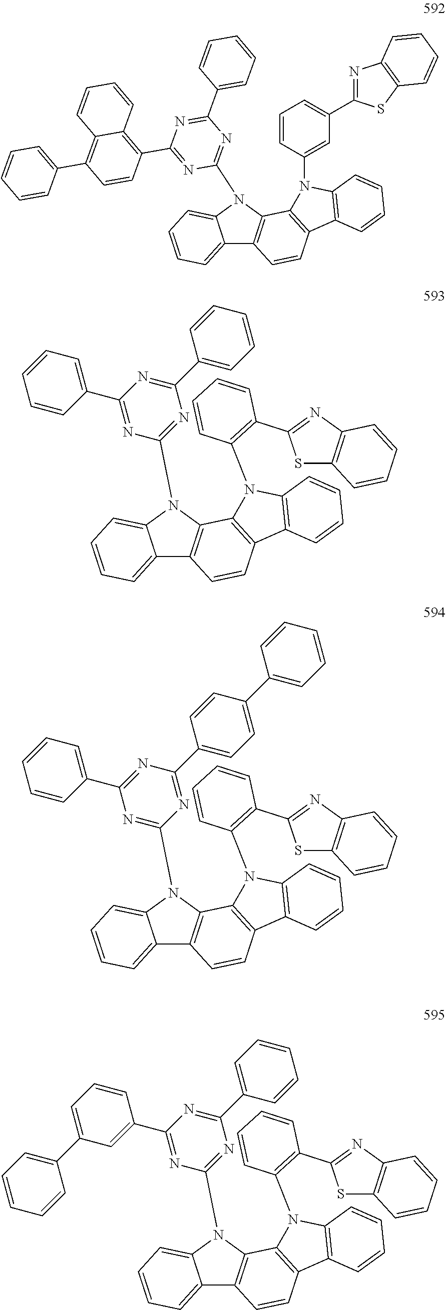

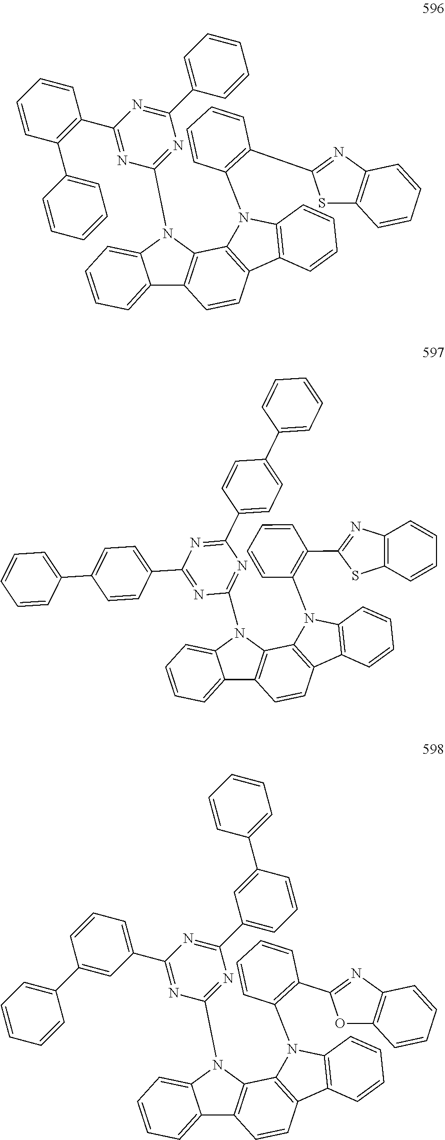 [SMILES: c1ccc(-c2nc(-c3ccccc3-c3ccccc3)nc(-n3c4ccccc4c4ccc5c6ccccc6n(-c6ccccc6-c6nc7ccccc7s6)c5c43)n2)cc1 ; c1ccc(-c2ccc(-c3nc(-c4ccc(-c5ccccc5)cc4)nc(-n4c5ccccc5c5ccc6c7ccccc7n(-c7ccccc7-c7nc8ccccc8s7)c6c54)n3)cc2)cc1 ; c1ccc(-c2cccc(-c3nc(-c4cccc(-c5ccccc5)c4)nc(-n4c5ccccc5c5ccc6c7ccccc7n(-c7ccccc7-c7nc8ccccc8o7)c6c54)n3)c2)cc1]

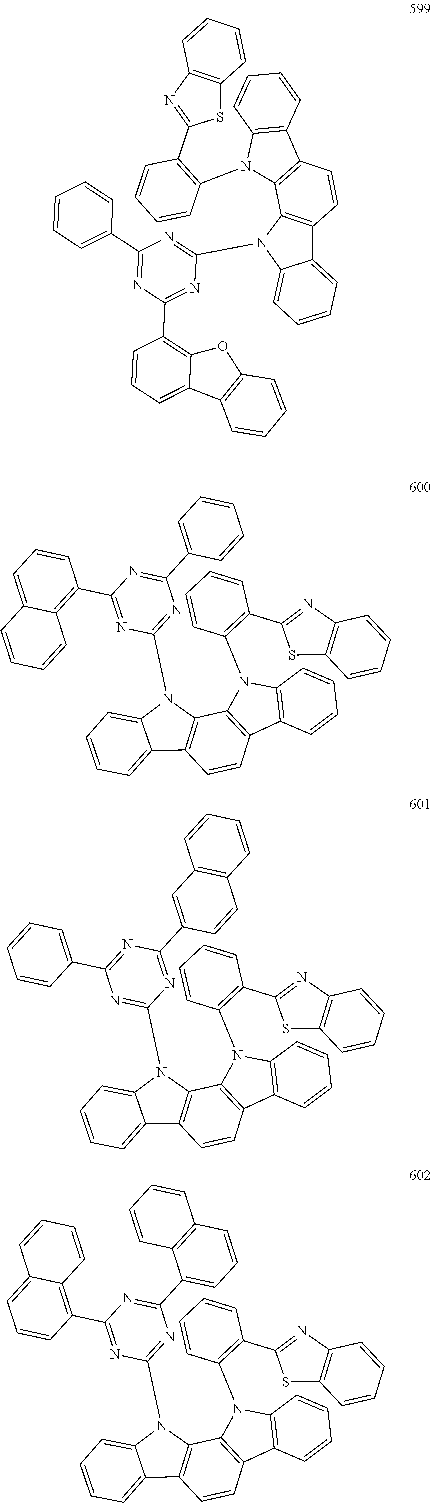

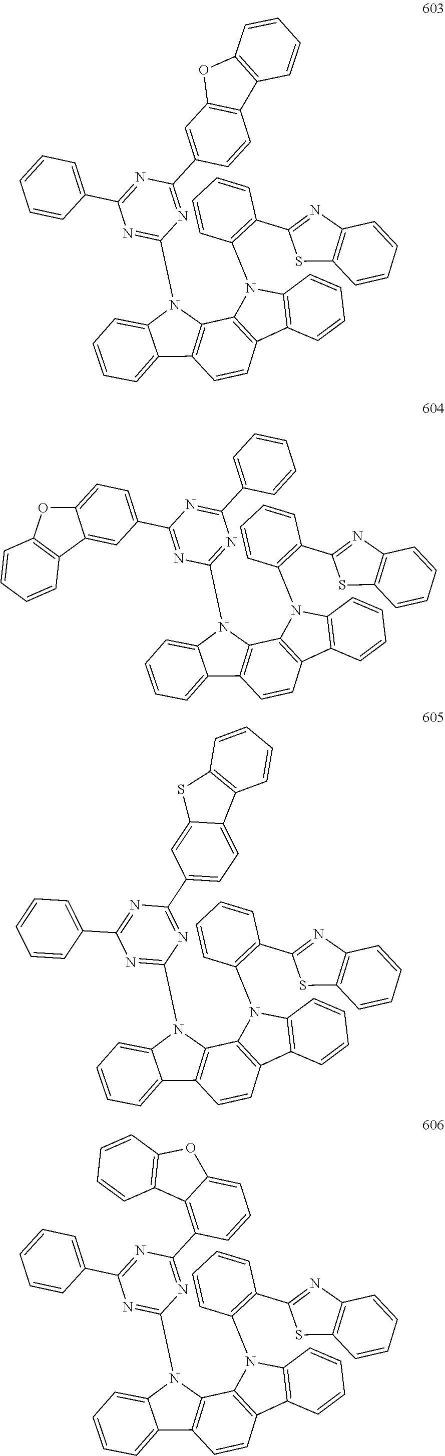

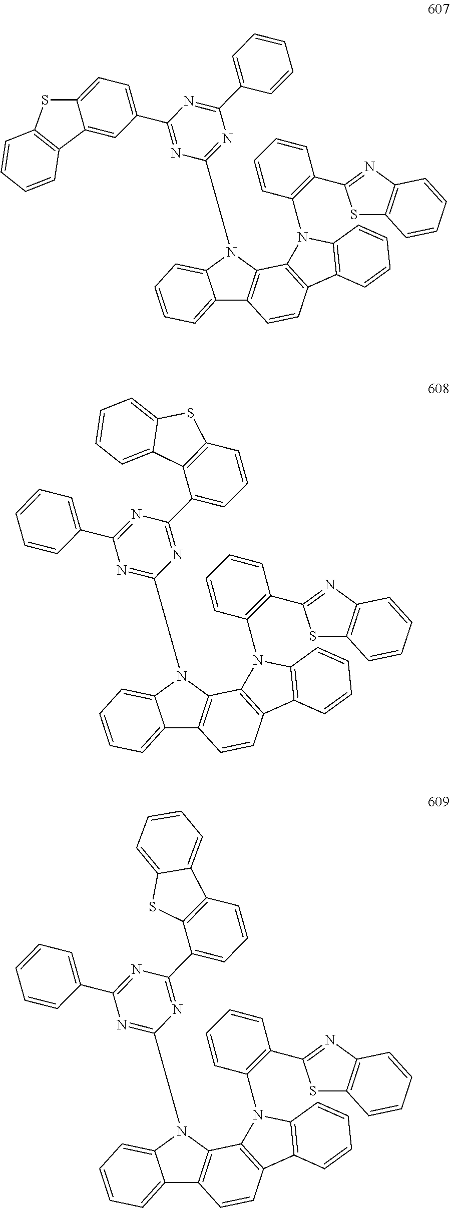 [SMILES: c1ccc(-c2nc(-c3ccc4sc5ccccc5c4c3)nc(-n3c4ccccc4c4ccc5c6ccccc6n(-c6ccccc6-c6nc7ccccc7s6)c5c43)n2)cc1 ; c1ccc(-c2nc(-c3cccc4sc5ccccc5c34)nc(-n3c4ccccc4c4ccc5c6ccccc6n(-c6ccccc6-c6nc7ccccc7s6)c5c43)n2)cc1 ; c1ccc(-c2nc(-c3cccc4c3sc3ccccc34)nc(-n3c4ccccc4c4ccc5c6ccccc6n(-c6ccccc6-c6nc7ccccc7s6)c5c43)n2)cc1]

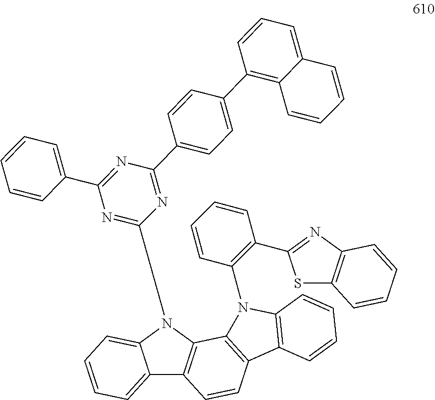 [SMILES: c1ccc(-c2nc(-c3ccc(-c4cccc5ccccc45)cc3)nc(-n3c4ccccc4c4ccc5c6ccccc6n(-c6ccccc6-c6nc7ccccc7s6)c5c43)n2)cc1]

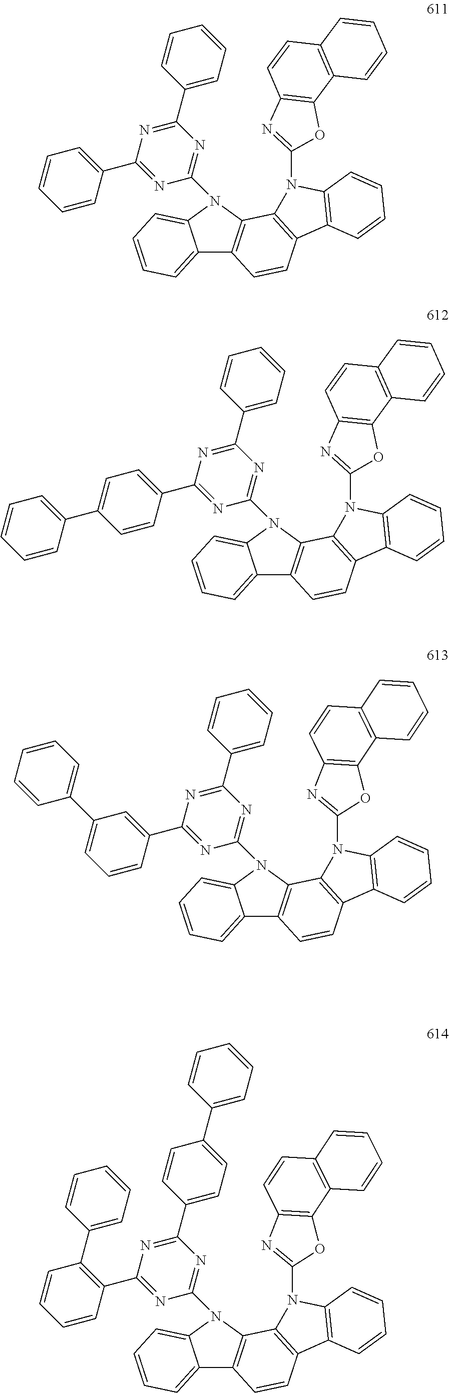 [SMILES: c1ccc(-c2nc(-c3ccccc3)nc(-n3c4ccccc4c4ccc5c6ccccc6n(-c6nc7ccc8ccccc8c7o6)c5c43)n2)cc1 ; c1ccc(-c2ccc(-c3nc(-c4ccccc4)nc(-n4c5ccccc5c5ccc6c7ccccc7n(-c7nc8ccc9ccccc9c8o7)c6c54)n3)cc2)cc1 ; c1ccc(-c2cccc(-c3nc(-c4ccccc4)nc(-n4c5ccccc5c5ccc6c7ccccc7n(-c7nc8ccc9ccccc9c8o7)c6c54)n3)c2)cc1 ; c1ccc(-c2ccc(-c3nc(-c4ccccc4-c4ccccc4)nc(-n4c5ccccc5c5ccc6c7ccccc7n(-c7nc8ccc9ccccc9c8o7)c6c54)n3)cc2)cc1]

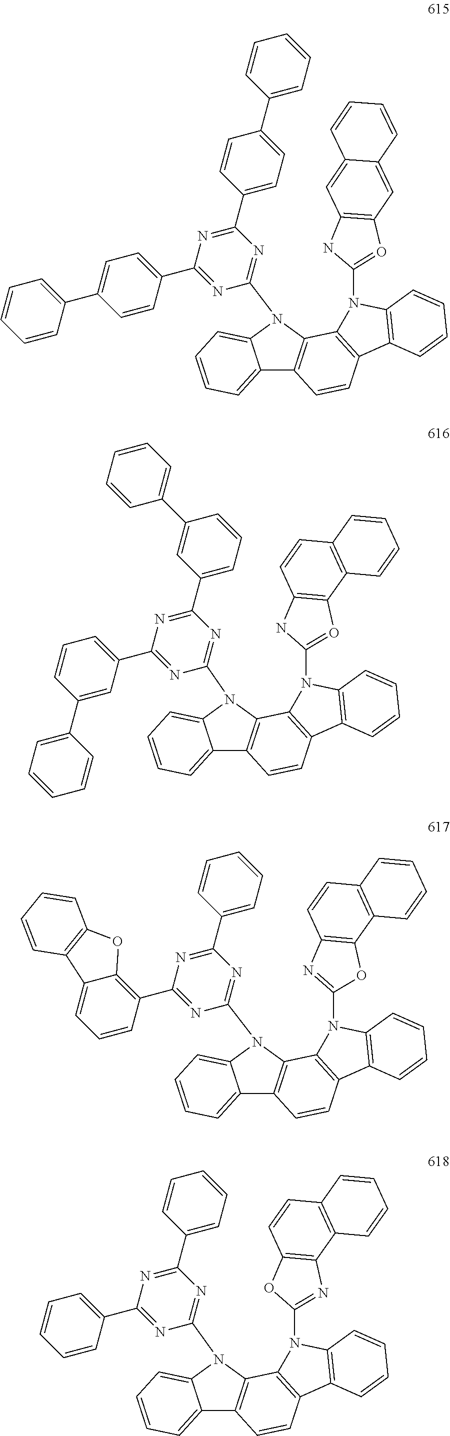

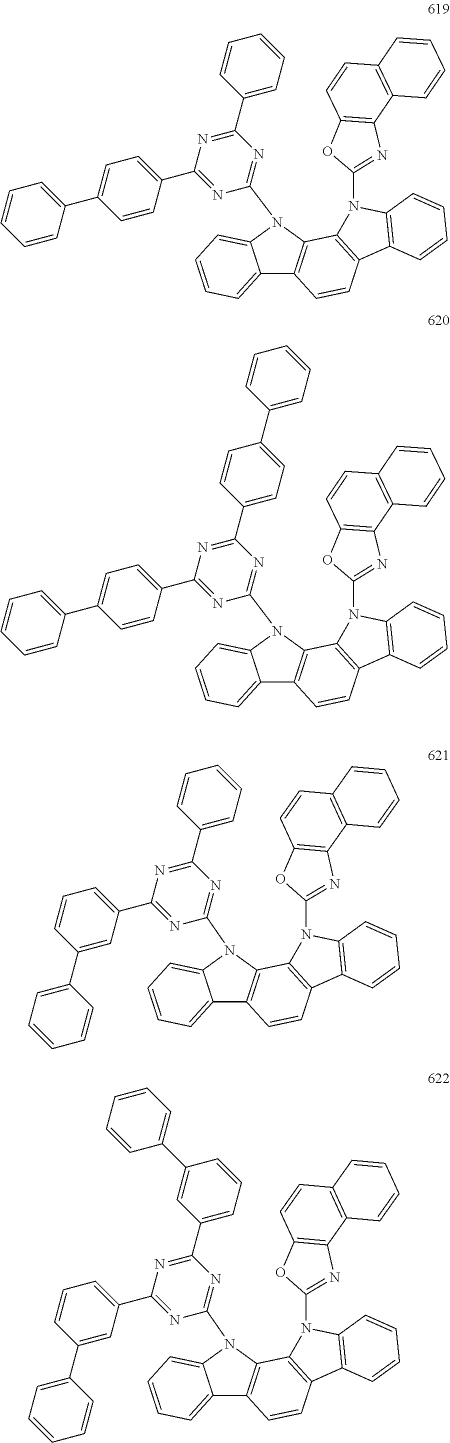 [SMILES: c1ccc(-c2ccc(-c3nc(-c4ccccc4)nc(-n4c5ccccc5c5ccc6c7ccccc7n(-c7nc8c(ccc9ccccc98)o7)c6c54)n3)cc2)cc1 ; c1ccc(-c2ccc(-c3nc(-c4ccc(-c5ccccc5)cc4)nc(-n4c5ccccc5c5ccc6c7ccccc7n(-c7nc8c(ccc9ccccc98)o7)c6c54)n3)cc2)cc1 ; c1ccc(-c2cccc(-c3nc(-c4ccccc4)nc(-n4c5ccccc5c5ccc6c7ccccc7n(-c7nc8c(ccc9ccccc98)o7)c6c54)n3)c2)cc1 ; c1ccc(-c2cccc(-c3nc(-c4cccc(-c5ccccc5)c4)nc(-n4c5ccccc5c5ccc6c7ccccc7n(-c7nc8c(ccc9ccccc98)o7)c6c54)n3)c2)cc1]

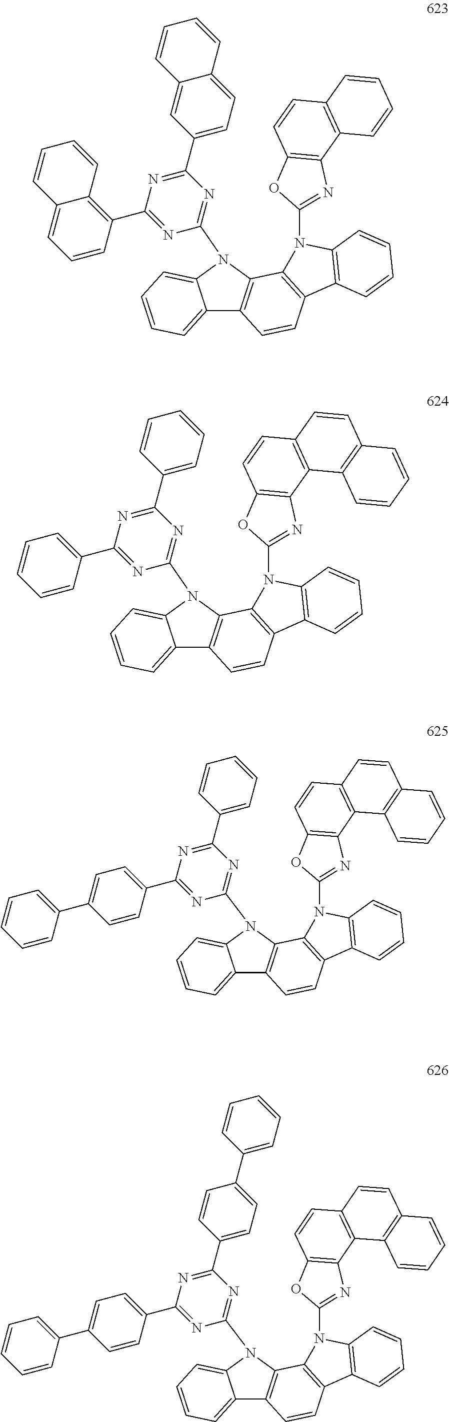 [SMILES: c1ccc2cc(-c3nc(-c4cccc5ccccc45)nc(-n4c5ccccc5c5ccc6c7ccccc7n(-c7nc8c(ccc9ccccc98)o7)c6c54)n3)ccc2c1 ; c1ccc(-c2nc(-c3ccccc3)nc(-n3c4ccccc4c4ccc5c6ccccc6n(-c6nc7c(ccc8ccc9ccccc9c87)o6)c5c43)n2)cc1 ; c1ccc(-c2ccc(-c3nc(-c4ccccc4)nc(-n4c5ccccc5c5ccc6c7ccccc7n(-c7nc8c(ccc9ccc%10ccccc%10c98)o7)c6c54)n3)cc2)cc1 ; c1ccc(-c2ccc(-c3nc(-c4ccc(-c5ccccc5)cc4)nc(-n4c5ccccc5c5ccc6c7ccccc7n(-c7nc8c(ccc9ccc%10ccccc%10c98)o7)c6c54)n3)cc2)cc1]

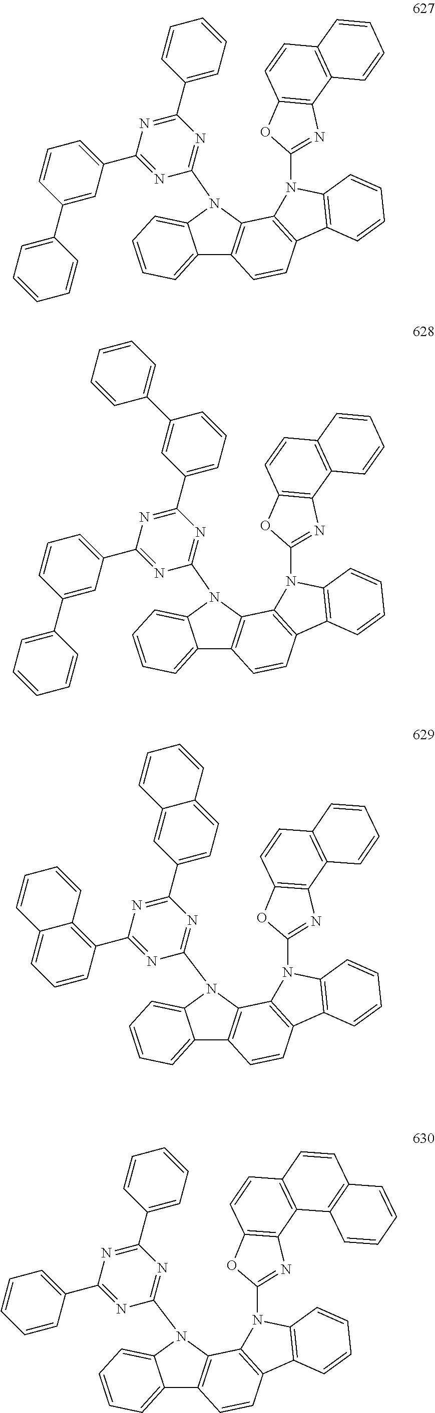 [SMILES: c1ccc(-c2cccc(-c3nc(-c4ccccc4)nc(-n4c5ccccc5c5ccc6c7ccccc7n(-c7nc8c(ccc9ccccc98)o7)c6c54)n3)c2)cc1 ; c1ccc(-c2cccc(-c3nc(-c4cccc(-c5ccccc5)c4)nc(-n4c5ccccc5c5ccc6c7ccccc7n(-c7nc8c(ccc9ccccc98)o7)c6c54)n3)c2)cc1 ; c1ccc2cc(-c3nc(-c4cccc5ccccc45)nc(-n4c5ccccc5c5ccc6c7ccccc7n(-c7nc8c(ccc9ccccc98)o7)c6c54)n3)ccc2c1 ; c1ccc(-c2nc(-c3ccccc3)nc(-n3c4ccccc4c4ccc5c6ccccc6n(-c6nc7c(ccc8ccc9ccccc9c87)o6)c5c43)n2)cc1]

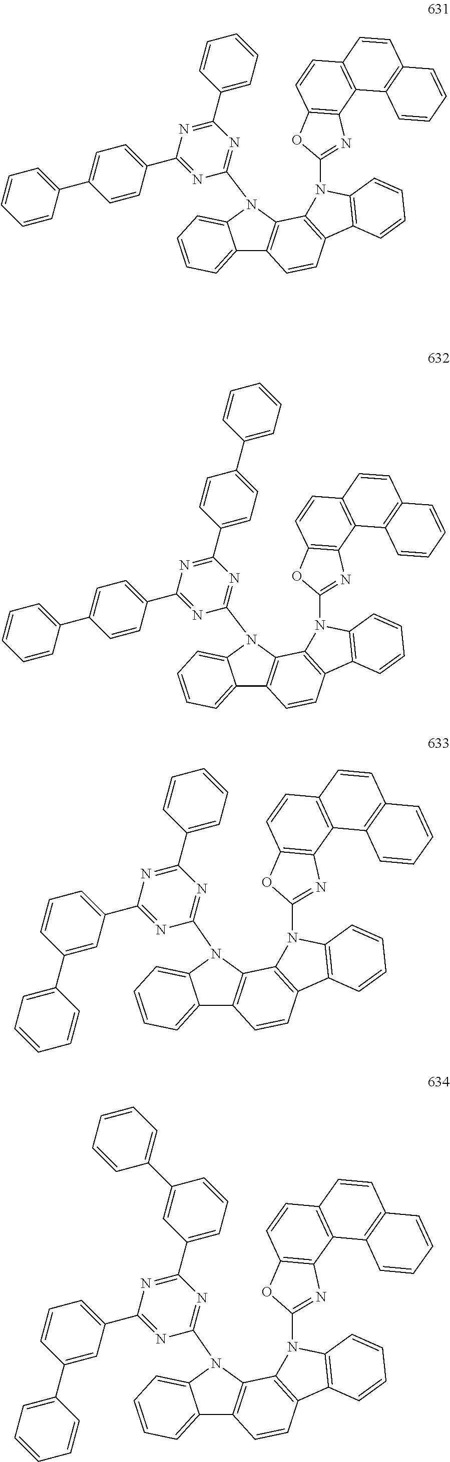 [SMILES: c1ccc(-c2ccc(-c3nc(-c4ccccc4)nc(-n4c5ccccc5c5ccc6c7ccccc7n(-c7nc8c(ccc9ccc%10ccccc%10c98)o7)c6c54)n3)cc2)cc1 ; c1ccc(-c2ccc(-c3nc(-c4ccc(-c5ccccc5)cc4)nc(-n4c5ccccc5c5ccc6c7ccccc7n(-c7nc8c(ccc9ccc%10ccccc%10c98)o7)c6c54)n3)cc2)cc1 ; c1ccc(-c2cccc(-c3nc(-c4ccccc4)nc(-n4c5ccccc5c5ccc6c7ccccc7n(-c7nc8c(ccc9ccc%10ccccc%10c98)o7)c6c54)n3)c2)cc1 ; c1ccc(-c2cccc(-c3nc(-c4cccc(-c5ccccc5)c4)nc(-n4c5ccccc5c5ccc6c7ccccc7n(-c7nc8c(ccc9ccc%10ccccc%10c98)o7)c6c54)n3)c2)cc1]

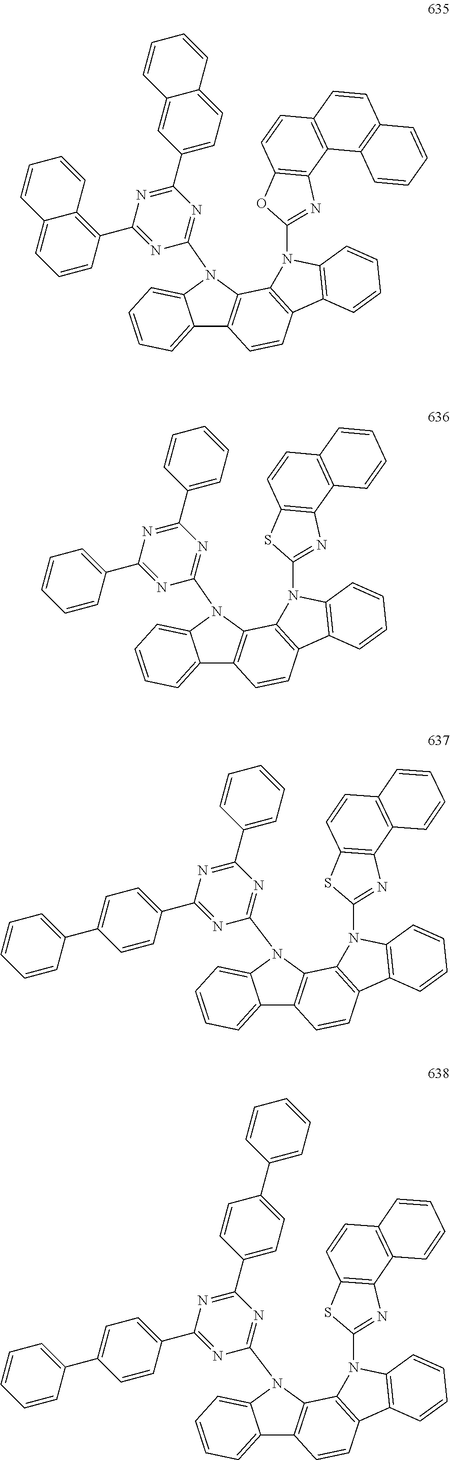 [SMILES: c1ccc2cc(-c3nc(-c4cccc5ccccc45)nc(-n4c5ccccc5c5ccc6c7ccccc7n(-c7nc8c(ccc9ccc%10ccccc%10c98)o7)c6c54)n3)ccc2c1 ; c1ccc(-c2nc(-c3ccccc3)nc(-n3c4ccccc4c4ccc5c6ccccc6n(-c6nc7c(ccc8ccccc87)s6)c5c43)n2)cc1 ; c1ccc(-c2ccc(-c3nc(-c4ccccc4)nc(-n4c5ccccc5c5ccc6c7ccccc7n(-c7nc8c(ccc9ccccc98)s7)c6c54)n3)cc2)cc1 ; c1ccc(-c2ccc(-c3nc(-c4ccc(-c5ccccc5)cc4)nc(-n4c5ccccc5c5ccc6c7ccccc7n(-c7nc8c(ccc9ccccc98)s7)c6c54)n3)cc2)cc1]

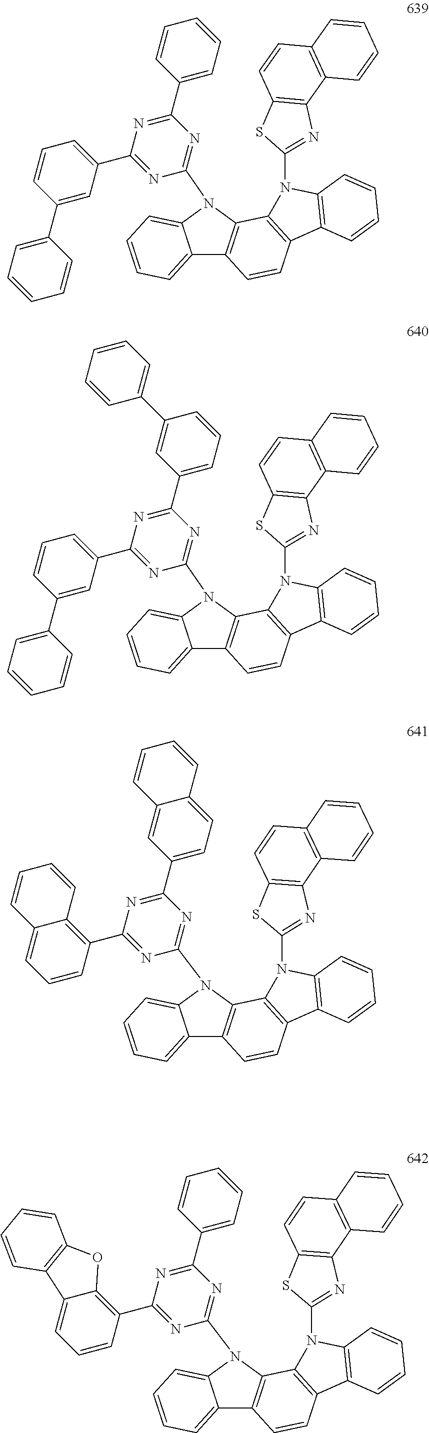 [SMILES: c1ccc(-c2cccc(-c3nc(-c4ccccc4)nc(-n4c5ccccc5c5ccc6c7ccccc7n(-c7nc8c(ccc9ccccc98)s7)c6c54)n3)c2)cc1 ; c1ccc(-c2cccc(-c3nc(-c4cccc(-c5ccccc5)c4)nc(-n4c5ccccc5c5ccc6c7ccccc7n(-c7nc8c(ccc9ccccc98)s7)c6c54)n3)c2)cc1 ; c1ccc2cc(-c3nc(-c4cccc5ccccc45)nc(-n4c5ccccc5c5ccc6c7ccccc7n(-c7nc8c(ccc9ccccc98)s7)c6c54)n3)ccc2c1 ; c1ccc(-c2nc(-c3cccc4c3oc3ccccc34)nc(-n3c4ccccc4c4ccc5c6ccccc6n(-c6nc7c(ccc8ccccc87)s6)c5c43)n2)cc1]

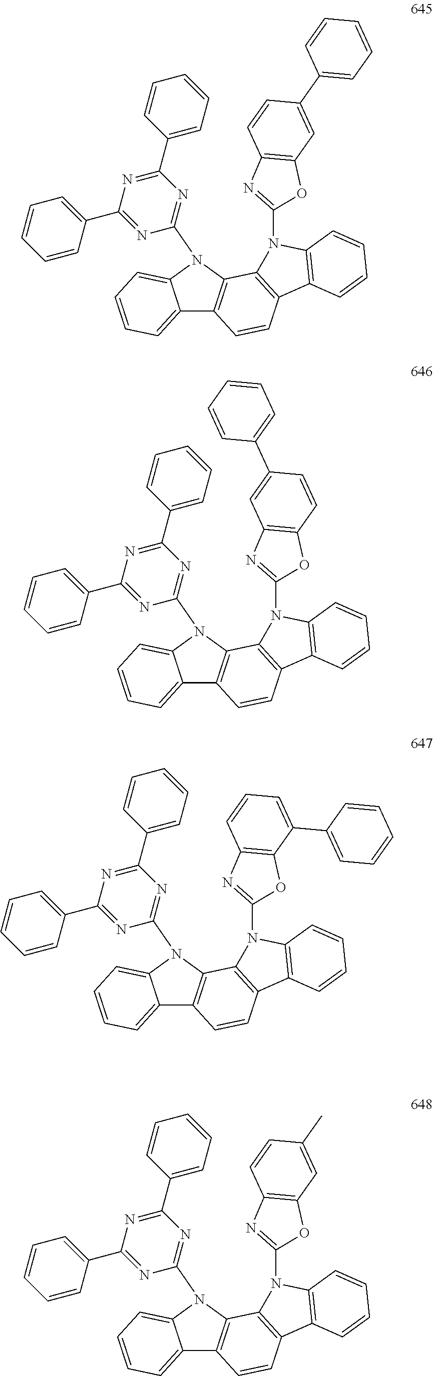

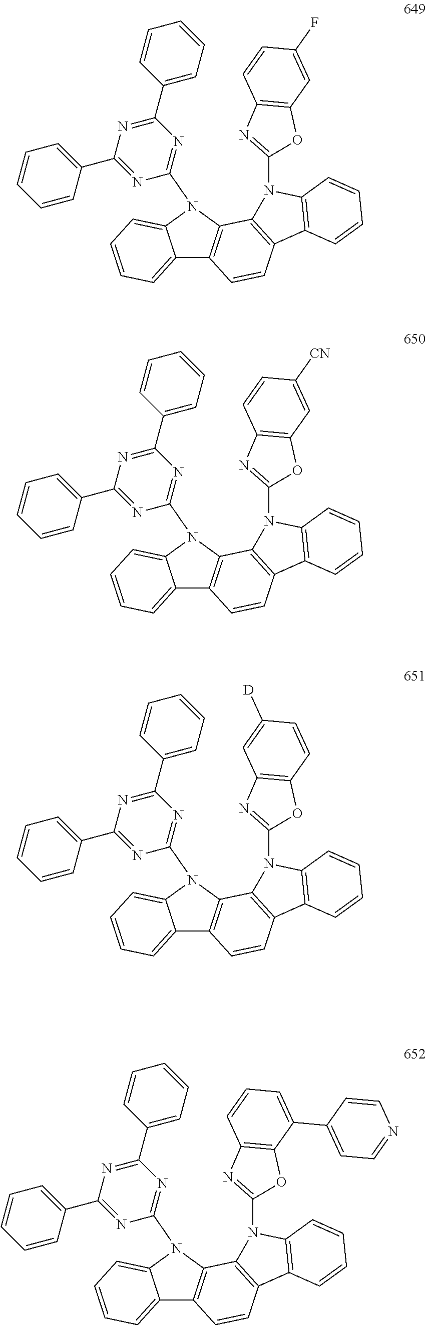 [SMILES: Fc1ccc2nc(-n3c4ccccc4c4ccc5c6ccccc6n(-c6nc(-c7ccccc7)nc(-c7ccccc7)n6)c5c43)oc2c1 ; N#Cc1ccc2nc(-n3c4ccccc4c4ccc5c6ccccc6n(-c6nc(-c7ccccc7)nc(-c7ccccc7)n6)c5c43)oc2c1 ; [2H]c1ccc2oc(-n3c4ccccc4c4ccc5c6ccccc6n(-c6nc(-c7ccccc7)nc(-c7ccccc7)n6)c5c43)nc2c1 ; c1ccc(-c2nc(-c3ccccc3)nc(-n3c4ccccc4c4ccc5c6ccccc6n(-c6nc7cccc(-c8ccncc8)c7o6)c5c43)n2)cc1]

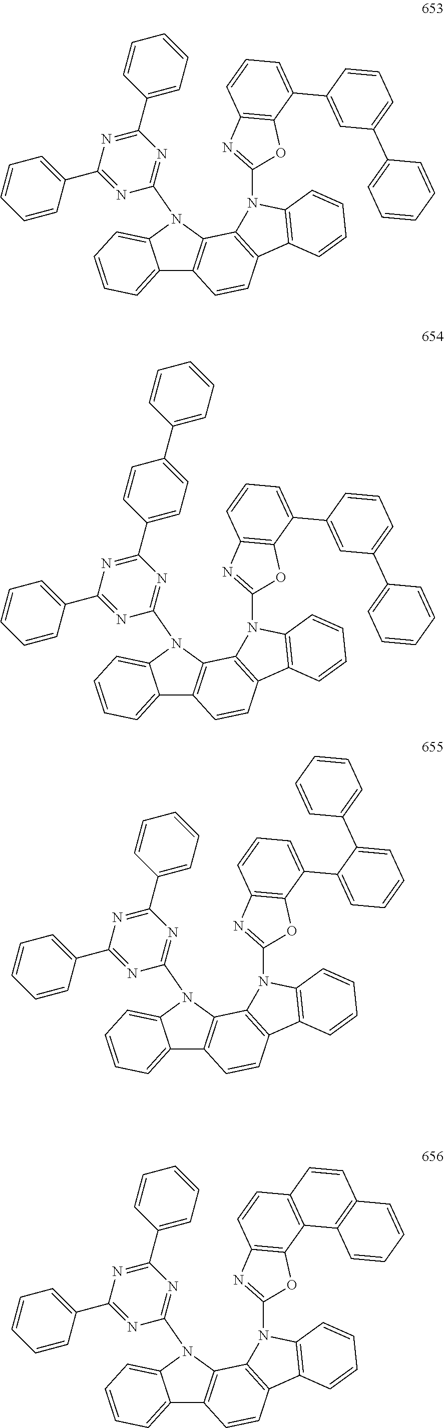 [SMILES: c1ccc(-c2cccc(-c3cccc4nc(-n5c6ccccc6c6ccc7c8ccccc8n(-c8nc(-c9ccccc9)nc(-c9ccccc9)n8)c7c65)oc34)c2)cc1 ; c1ccc(-c2ccc(-c3nc(-c4ccccc4)nc(-n4c5ccccc5c5ccc6c7ccccc7n(-c7nc8cccc(-c9cccc(-c%10ccccc%10)c9)c8o7)c6c54)n3)cc2)cc1 ; c1ccc(-c2nc(-c3ccccc3)nc(-n3c4ccccc4c4ccc5c6ccccc6n(-c6nc7cccc(-c8ccccc8-c8ccccc8)c7o6)c5c43)n2)cc1 ; c1ccc(-c2nc(-c3ccccc3)nc(-n3c4ccccc4c4ccc5c6ccccc6n(-c6nc7ccc8ccc9ccccc9c8c7o6)c5c43)n2)cc1]

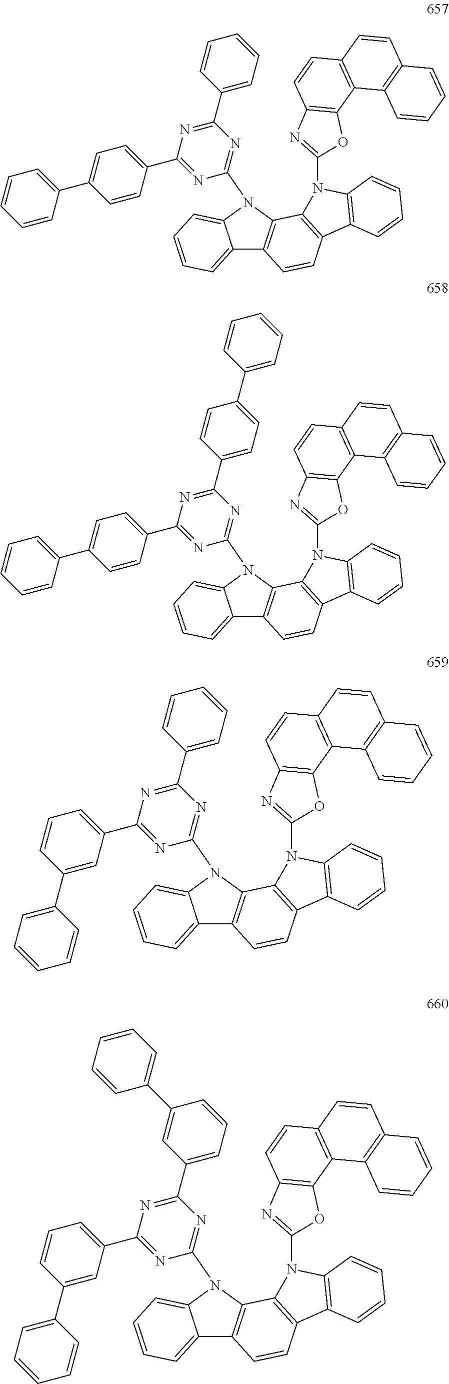 [SMILES: c1ccc(-c2ccc(-c3nc(-c4ccccc4)nc(-n4c5ccccc5c5ccc6c7ccccc7n(-c7nc8ccc9ccc%10ccccc%10c9c8o7)c6c54)n3)cc2)cc1 ; c1ccc(-c2ccc(-c3nc(-c4ccc(-c5ccccc5)cc4)nc(-n4c5ccccc5c5ccc6c7ccccc7n(-c7nc8ccc9ccc%10ccccc%10c9c8o7)c6c54)n3)cc2)cc1 ; c1ccc(-c2cccc(-c3nc(-c4ccccc4)nc(-n4c5ccccc5c5ccc6c7ccccc7n(-c7nc8ccc9ccc%10ccccc%10c9c8o7)c6c54)n3)c2)cc1 ; c1ccc(-c2cccc(-c3nc(-c4cccc(-c5ccccc5)c4)nc(-n4c5ccccc5c5ccc6c7ccccc7n(-c7nc8ccc9ccc%10ccccc%10c9c8o7)c6c54)n3)c2)cc1]

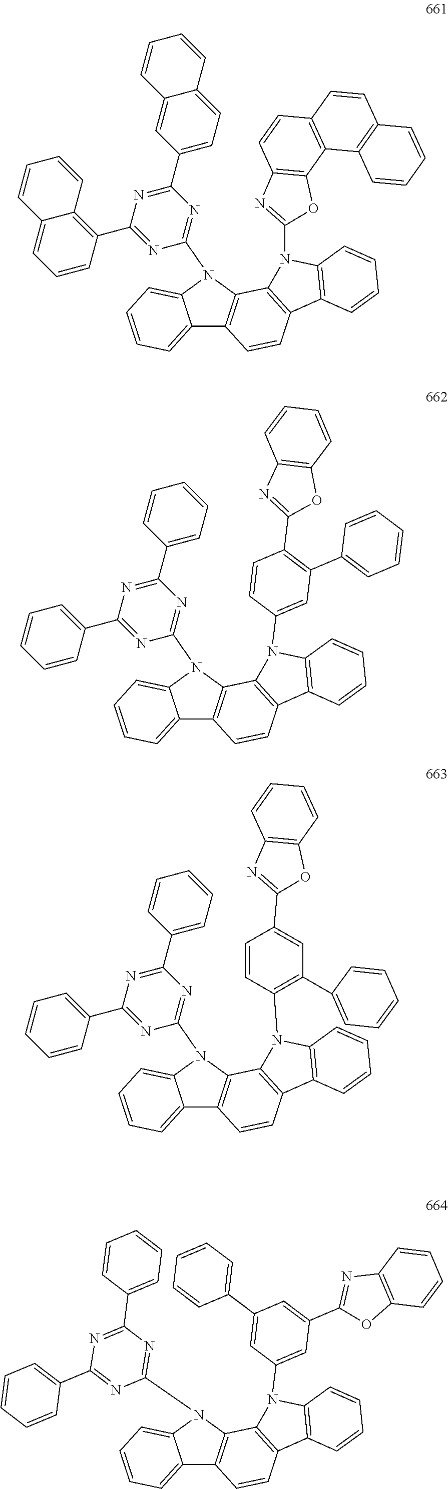 [SMILES: c1ccc2cc(-c3nc(-c4cccc5ccccc45)nc(-n4c5ccccc5c5ccc6c7ccccc7n(-c7nc8ccc9ccc%10ccccc%10c9c8o7)c6c54)n3)ccc2c1 ; c1ccc(-c2nc(-c3ccccc3)nc(-n3c4ccccc4c4ccc5c6ccccc6n(-c6ccc(-c7nc8ccccc8o7)c(-c7ccccc7)c6)c5c43)n2)cc1 ; c1ccc(-c2nc(-c3ccccc3)nc(-n3c4ccccc4c4ccc5c6ccccc6n(-c6ccc(-c7nc8ccccc8o7)cc6-c6ccccc6)c5c43)n2)cc1 ; c1ccc(-c2cc(-c3nc4ccccc4o3)cc(-n3c4ccccc4c4ccc5c6ccccc6n(-c6nc(-c7ccccc7)nc(-c7ccccc7)n6)c5c43)c2)cc1]

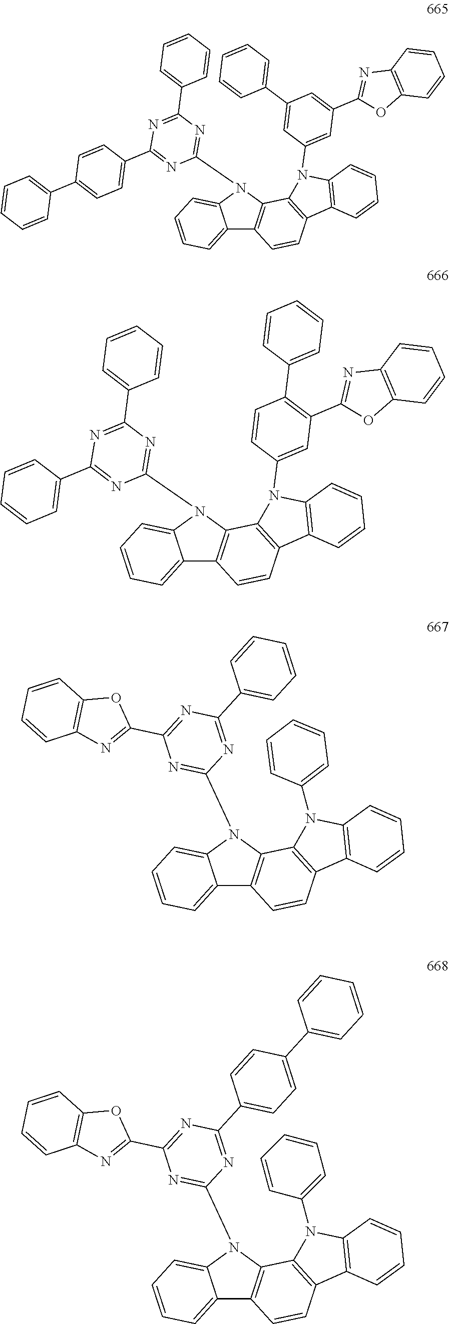 [SMILES: c1ccc(-c2ccc(-c3nc(-c4ccccc4)nc(-n4c5ccccc5c5ccc6c7ccccc7n(-c7cc(-c8ccccc8)cc(-c8nc9ccccc9o8)c7)c6c54)n3)cc2)cc1 ; c1ccc(-c2nc(-c3ccccc3)nc(-n3c4ccccc4c4ccc5c6ccccc6n(-c6ccc(-c7ccccc7)c(-c7nc8ccccc8o7)c6)c5c43)n2)cc1 ; c1ccc(-c2nc(-c3nc4ccccc4o3)nc(-n3c4ccccc4c4ccc5c6ccccc6n(-c6ccccc6)c5c43)n2)cc1 ; c1ccc(-c2ccc(-c3nc(-c4nc5ccccc5o4)nc(-n4c5ccccc5c5ccc6c7ccccc7n(-c7ccccc7)c6c54)n3)cc2)cc1]

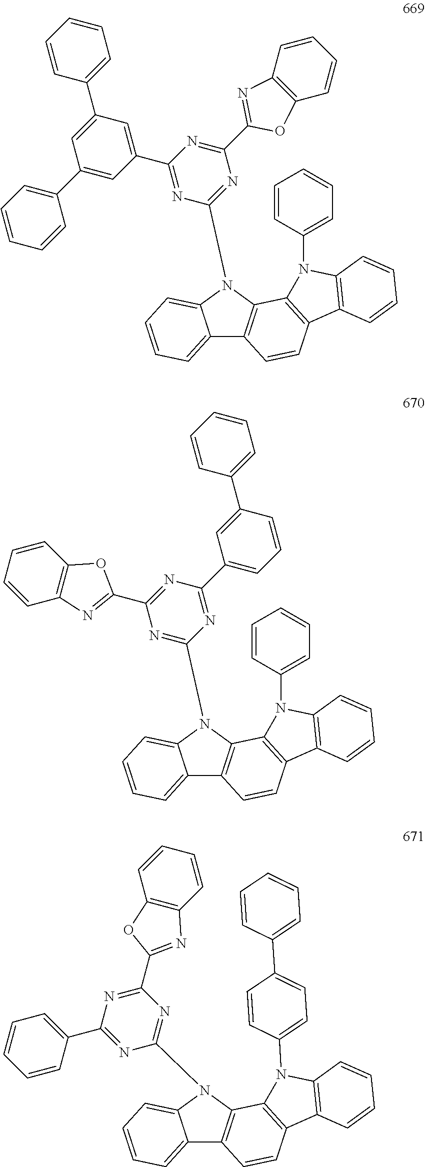

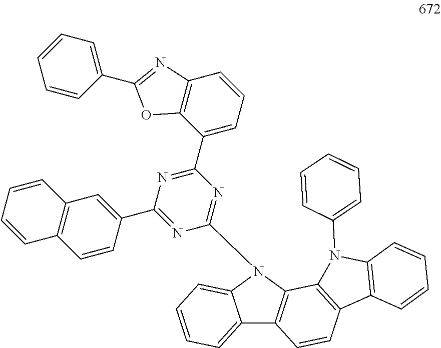 [SMILES: c1ccc(-c2nc3cccc(-c4nc(-c5ccc6ccccc6c5)nc(-n5c6ccccc6c6ccc7c8ccccc8n(-c8ccccc8)c7c65)n4)c3o2)cc1]

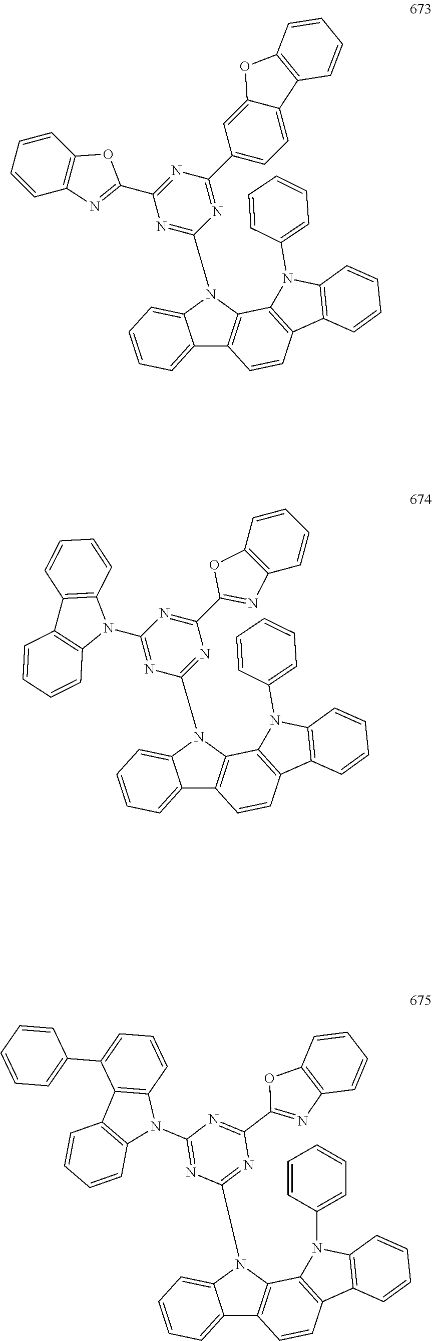 [SMILES: c1ccc(-n2c3ccccc3c3ccc4c5ccccc5n(-c5nc(-c6ccc7c(c6)oc6ccccc67)nc(-c6nc7ccccc7o6)n5)c4c32)cc1 ; c1ccc(-n2c3ccccc3c3ccc4c5ccccc5n(-c5nc(-c6nc7ccccc7o6)nc(-n6c7ccccc7c7ccccc76)n5)c4c32)cc1 ; c1ccc(-c2cccc3c2c2ccccc2n3-c2nc(-c3nc4ccccc4o3)nc(-n3c4ccccc4c4ccc5c6ccccc6n(-c6ccccc6)c5c43)n2)cc1]

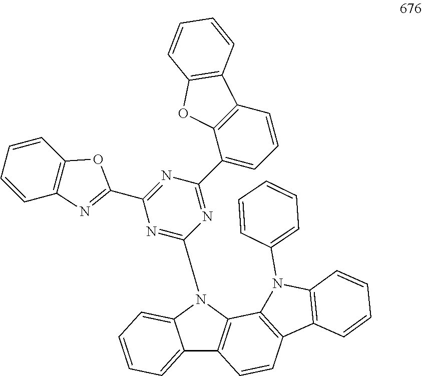 [SMILES: c1ccc(-n2c3ccccc3c3ccc4c5ccccc5n(-c5nc(-c6nc7ccccc7o6)nc(-c6cccc7c6oc6ccccc67)n5)c4c32)cc1]

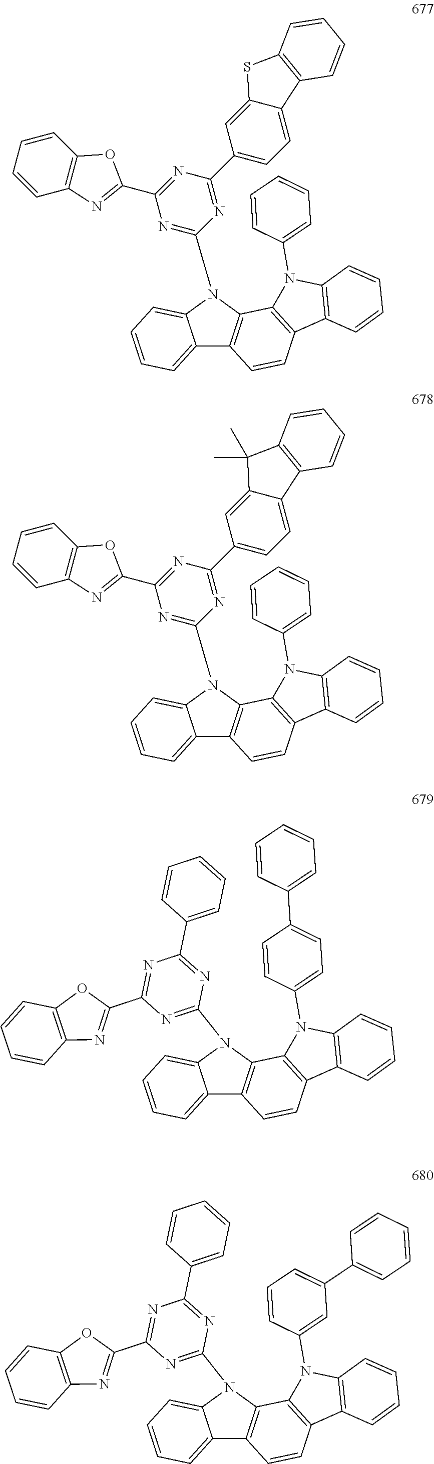 [SMILES: c1ccc(-n2c3ccccc3c3ccc4c5ccccc5n(-c5nc(-c6ccc7c(c6)sc6ccccc67)nc(-c6nc7ccccc7o6)n5)c4c32)cc1 ; CC1(C)c2ccccc2-c2ccc(-c3nc(-c4nc5ccccc5o4)nc(-n4c5ccccc5c5ccc6c7ccccc7n(-c7ccccc7)c6c54)n3)cc21 ; c1ccc(-c2ccc(-n3c4ccccc4c4ccc5c6ccccc6n(-c6nc(-c7ccccc7)nc(-c7nc8ccccc8o7)n6)c5c43)cc2)cc1 ; c1ccc(-c2cccc(-n3c4ccccc4c4ccc5c6ccccc6n(-c6nc(-c7ccccc7)nc(-c7nc8ccccc8o7)n6)c5c43)c2)cc1]

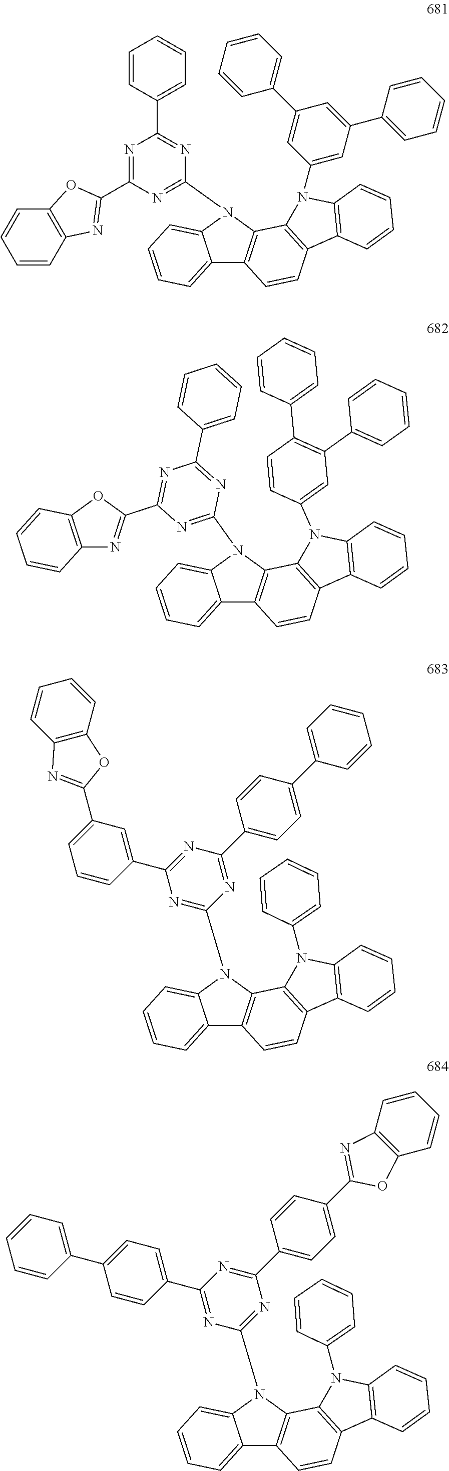 [SMILES: c1ccc(-c2cc(-c3ccccc3)cc(-n3c4ccccc4c4ccc5c6ccccc6n(-c6nc(-c7ccccc7)nc(-c7nc8ccccc8o7)n6)c5c43)c2)cc1 ; c1ccc(-c2nc(-c3nc4ccccc4o3)nc(-n3c4ccccc4c4ccc5c6ccccc6n(-c6ccc(-c7ccccc7)c(-c7ccccc7)c6)c5c43)n2)cc1 ; c1ccc(-c2ccc(-c3nc(-c4cccc(-c5nc6ccccc6o5)c4)nc(-n4c5ccccc5c5ccc6c7ccccc7n(-c7ccccc7)c6c54)n3)cc2)cc1 ; c1ccc(-c2ccc(-c3nc(-c4ccc(-c5nc6ccccc6o5)cc4)nc(-n4c5ccccc5c5ccc6c7ccccc7n(-c7ccccc7)c6c54)n3)cc2)cc1]

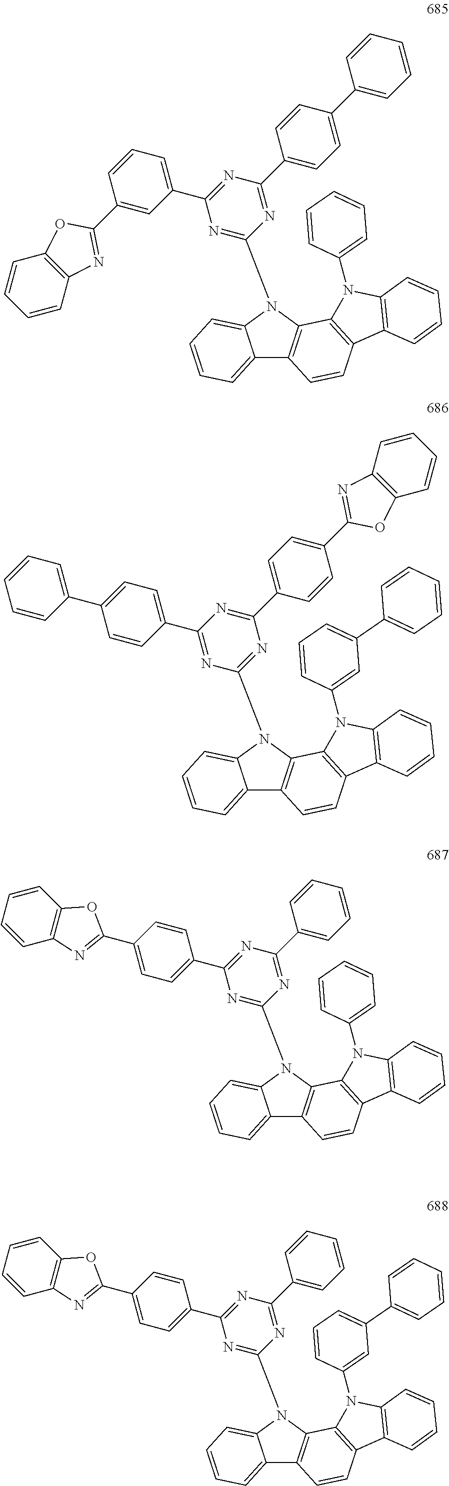 [SMILES: c1ccc(-c2ccc(-c3nc(-c4cccc(-c5nc6ccccc6o5)c4)nc(-n4c5ccccc5c5ccc6c7ccccc7n(-c7ccccc7)c6c54)n3)cc2)cc1 ; c1ccc(-c2ccc(-c3nc(-c4ccc(-c5nc6ccccc6o5)cc4)nc(-n4c5ccccc5c5ccc6c7ccccc7n(-c7cccc(-c8ccccc8)c7)c6c54)n3)cc2)cc1 ; c1ccc(-c2nc(-c3ccc(-c4nc5ccccc5o4)cc3)nc(-n3c4ccccc4c4ccc5c6ccccc6n(-c6ccccc6)c5c43)n2)cc1 ; c1ccc(-c2cccc(-n3c4ccccc4c4ccc5c6ccccc6n(-c6nc(-c7ccccc7)nc(-c7ccc(-c8nc9ccccc9o8)cc7)n6)c5c43)c2)cc1]

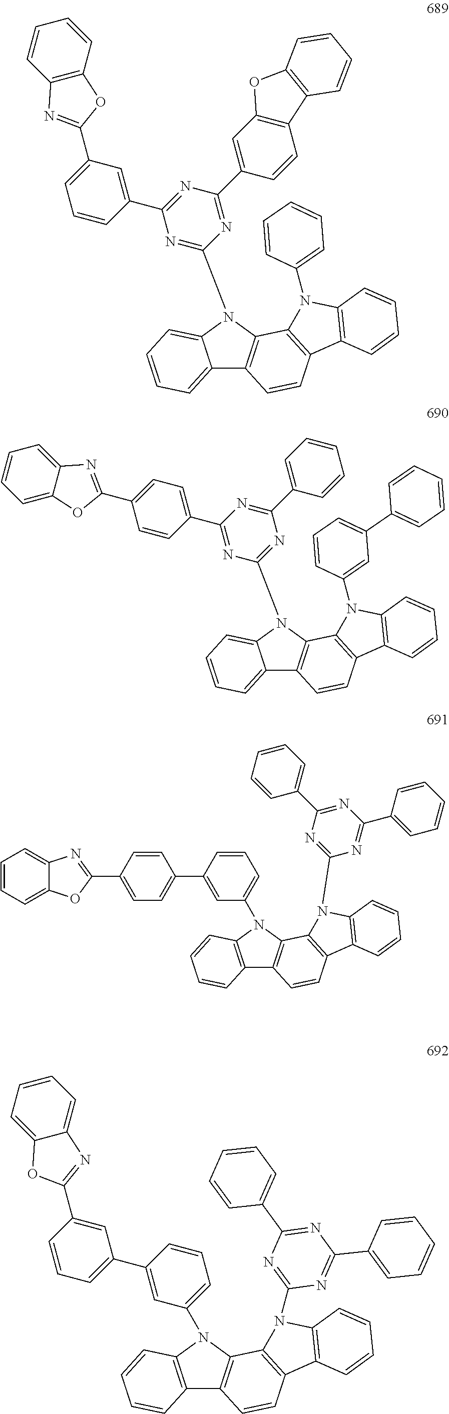 [SMILES: c1ccc(-n2c3ccccc3c3ccc4c5ccccc5n(-c5nc(-c6cccc(-c7nc8ccccc8o7)c6)nc(-c6ccc7c(c6)oc6ccccc67)n5)c4c32)cc1 ; c1ccc(-c2cccc(-n3c4ccccc4c4ccc5c6ccccc6n(-c6nc(-c7ccccc7)nc(-c7ccc(-c8nc9ccccc9o8)cc7)n6)c5c43)c2)cc1 ; c1ccc(-c2nc(-c3ccccc3)nc(-n3c4ccccc4c4ccc5c6ccccc6n(-c6cccc(-c7ccc(-c8nc9ccccc9o8)cc7)c6)c5c43)n2)cc1 ; c1ccc(-c2nc(-c3ccccc3)nc(-n3c4ccccc4c4ccc5c6ccccc6n(-c6cccc(-c7cccc(-c8nc9ccccc9o8)c7)c6)c5c43)n2)cc1]

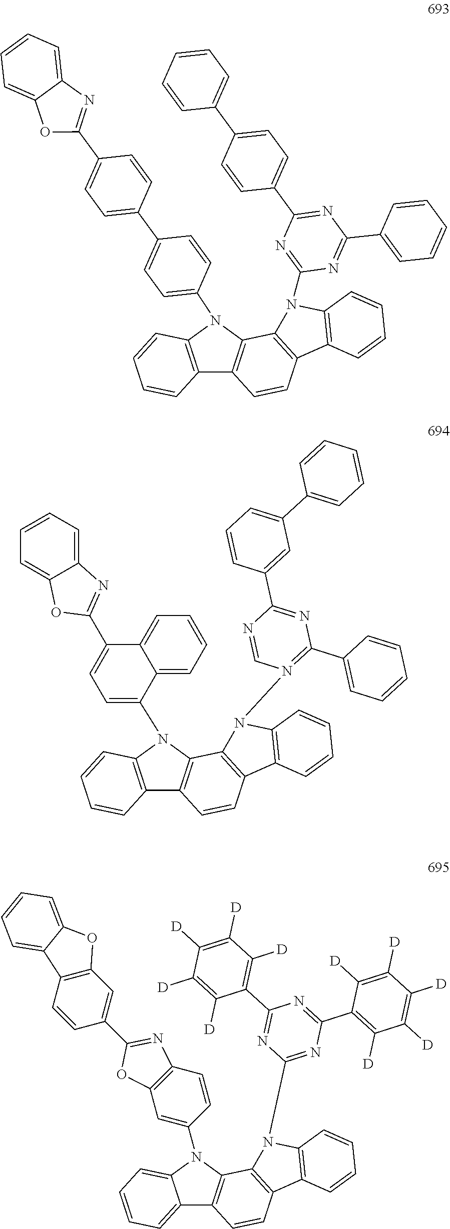

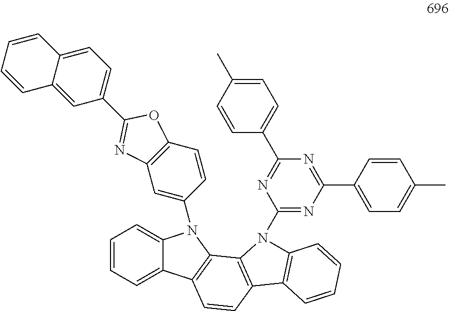 [SMILES: Cc1ccc(-c2nc(-c3ccc(C)cc3)nc(-n3c4ccccc4c4ccc5c6ccccc6n(-c6ccc7oc(-c8ccc9ccccc9c8)nc7c6)c5c43)n2)cc1]

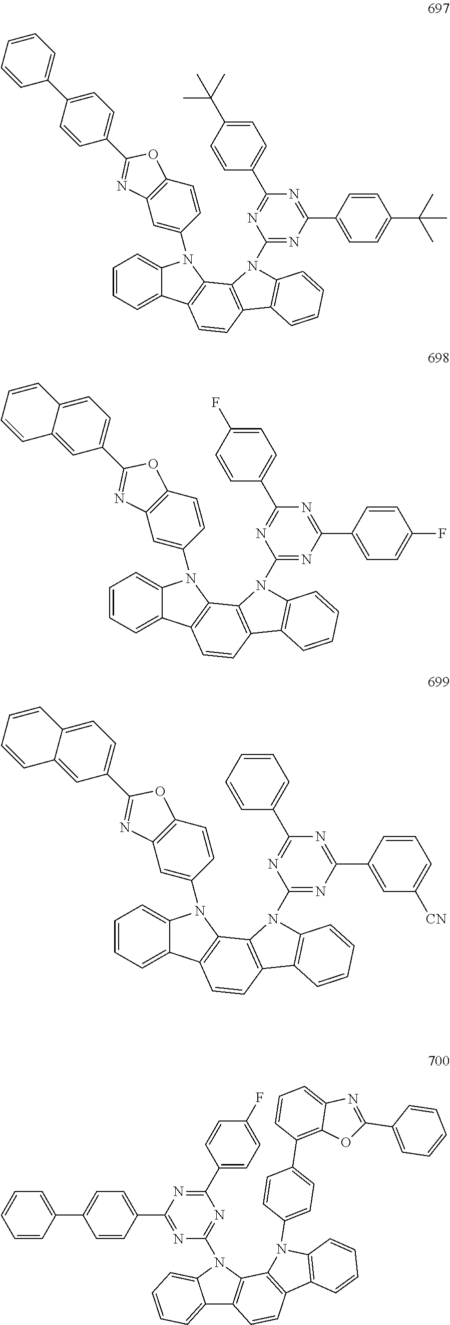 [SMILES: CC(C)(C)c1ccc(-c2nc(-c3ccc(C(C)(C)C)cc3)nc(-n3c4ccccc4c4ccc5c6ccccc6n(-c6ccc7oc(-c8ccc(-c9ccccc9)cc8)nc7c6)c5c43)n2)cc1 ; Fc1ccc(-c2nc(-c3ccc(F)cc3)nc(-n3c4ccccc4c4ccc5c6ccccc6n(-c6ccc7oc(-c8ccc9ccccc9c8)nc7c6)c5c43)n2)cc1 ; N#Cc1cccc(-c2nc(-c3ccccc3)nc(-n3c4ccccc4c4ccc5c6ccccc6n(-c6ccc7oc(-c8ccc9ccccc9c8)nc7c6)c5c43)n2)c1 ; Fc1ccc(-c2nc(-c3ccc(-c4ccccc4)cc3)nc(-n3c4ccccc4c4ccc5c6ccccc6n(-c6ccc(-c7cccc8nc(-c9ccccc9)oc78)cc6)c5c43)n2)cc1]

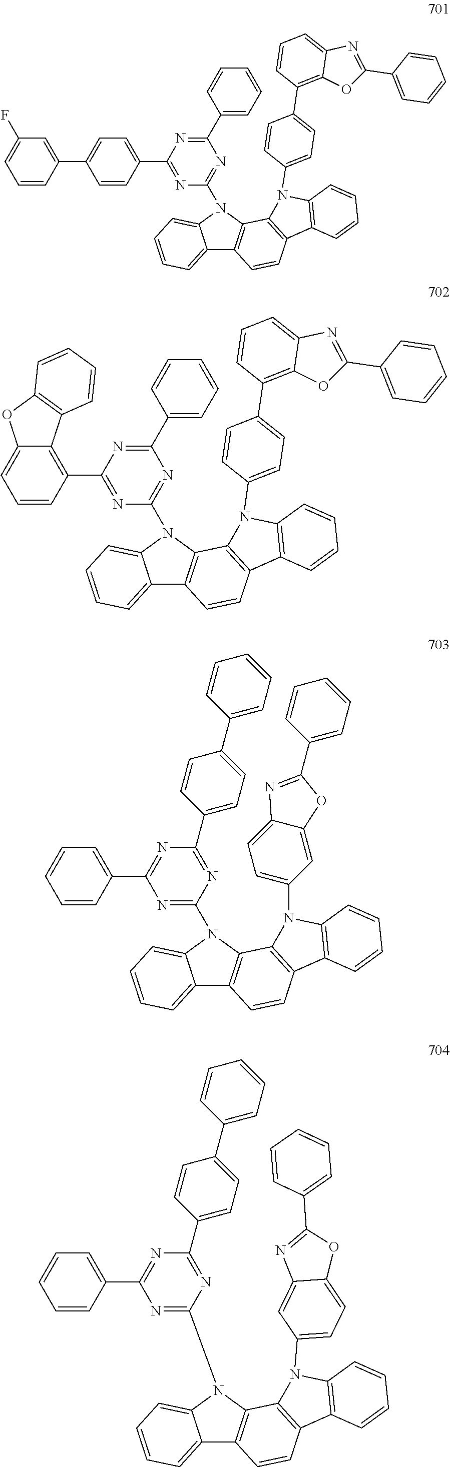 [SMILES: Fc1cccc(-c2ccc(-c3nc(-c4ccccc4)nc(-n4c5ccccc5c5ccc6c7ccccc7n(-c7ccc(-c8cccc9nc(-c%10ccccc%10)oc89)cc7)c6c54)n3)cc2)c1 ; c1ccc(-c2nc(-c3cccc4oc5ccccc5c34)nc(-n3c4ccccc4c4ccc5c6ccccc6n(-c6ccc(-c7cccc8nc(-c9ccccc9)oc78)cc6)c5c43)n2)cc1 ; c1ccc(-c2ccc(-c3nc(-c4ccccc4)nc(-n4c5ccccc5c5ccc6c7ccccc7n(-c7ccc8nc(-c9ccccc9)oc8c7)c6c54)n3)cc2)cc1 ; c1ccc(-c2ccc(-c3nc(-c4ccccc4)nc(-n4c5ccccc5c5ccc6c7ccccc7n(-c7ccc8oc(-c9ccccc9)nc8c7)c6c54)n3)cc2)cc1]

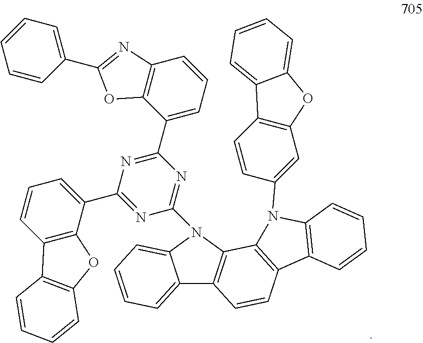 [SMILES: c1ccc(-c2nc3cccc(-c4nc(-c5cccc6c5oc5ccccc56)nc(-n5c6ccccc6c6ccc7c8ccccc8n(-c8ccc9c(c8)oc8ccccc89)c7c65)n4)c3o2)cc1]

In the present disclosure, the second compound may be selected from compounds shown in the following structures:

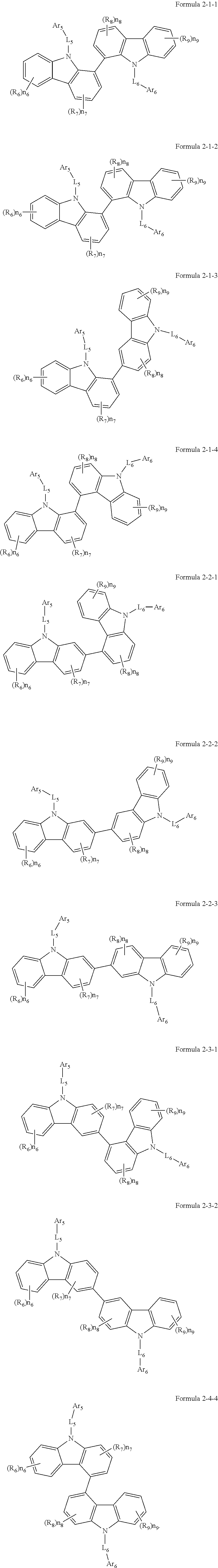

In one embodiment of the present disclosure, in the second compound, each R₆, R₇, R₈, and R₉ are respectively and independently selected from hydrogen, deuterium, a halogen group, cyano, aryl with 6 to 18 carbon atoms, heteroaryl with 5 to 12 carbon atoms, alkyl with 1 to 5 carbon atoms, haloalkyl with 1 to 5 carbon atoms, and cycloalkyl with 3 to 6 carbon atoms.

Specifically, each R₆, R₇, R₈, and R₉ are respectively and independently selected from hydrogen, phenyl, naphthyl, biphenyl, dibenzothienyl, fluorenyl, phenanthryl, and terphenyl.

In one embodiment of the present disclosure, in the second compound, each R₆, R₇, R₈, and R₉ are respectively and independently selected from hydrogen or a group consisting of the following groups:

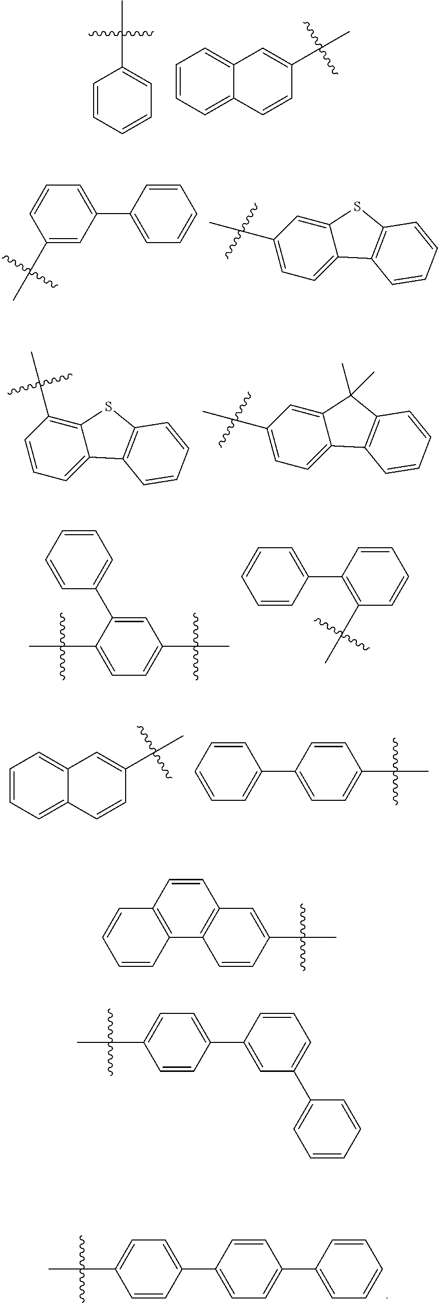

In one specific embodiment of the present disclosure, each R₆, R₇, R₈, and R₉ are respectively and independently selected from hydrogen or phenyl.

In one embodiment of the present disclosure, in the second compound, the L₅ and L₆ are respectively and independently selected from a single bond, substituted or unsubstituted arylene with 6 to 12 carbon atoms, and substituted or unsubstituted heteroarylene with 3 to 20 carbon atoms;

optionally, in the second compound, L₅ and L₆ are respectively and independently selected from a single bond, substituted or unsubstituted arylene with 6 to 12 carbon atoms, and substituted or unsubstituted heteroarylene with 3 to 12 carbon atoms; and

optionally, substituents in the L₅ and L₆ are respectively and independently selected from deuterium, a halogen group, cyano, alkyl with 1 to 5 carbon atoms, or phenyl.

In one embodiment of the present disclosure, in the second compound, the L₅ and L₆ are respectively and independently selected from a single bond, substituted or unsubstituted phenylene, substituted or unsubstituted naphthylene, substituted or unsubstituted biphenylene, and substituted or unsubstituted carbazolylene; and

specifically, substituents in the L₅ and L₆ are each independently selected from deuterium, fluorine, cyano, methyl, ethyl, n-propyl, isopropyl, tert-butyl or phenyl.

In one embodiment of the present disclosure, in the second compound, the L₅ and L₆ are the same or different, and are respectively and independently selected from a single bond or a substituted or unsubstituted group P, and the unsubstituted group P is selected from a group consisting of the following groups:

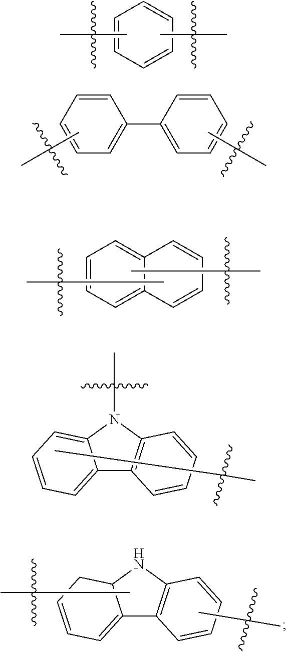

wherein

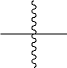

represents a chemical bond; the substituted group P has one or more substituents, and the substituents are each independently selected from deuterium, cyano, fluorine, methyl, ethyl, n-propyl, isopropyl, tert-butyl, or phenyl; and when the number of the substituents in the group P is greater than 1, the substituents are the same or different.

Optionally, L₅ and L₆ are respectively and independently selected from a single bond or a group consisting of the following groups:

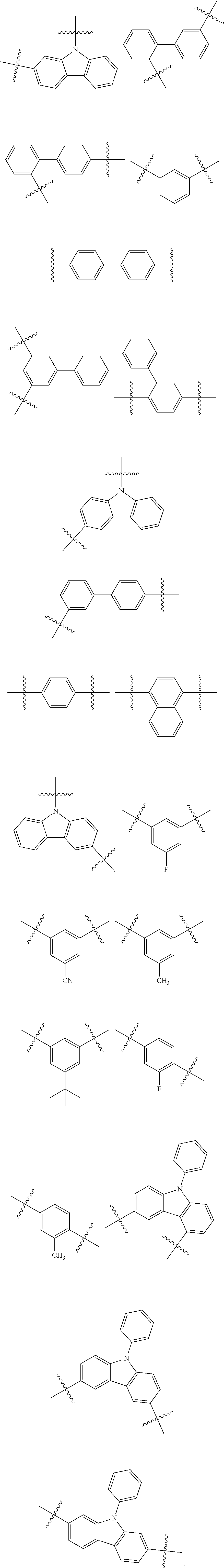

In one embodiment of the present disclosure, in the second compound, the Ar₅ and Ar₆ are respectively and independently selected from substituted or unsubstituted aryl with 6 to 25 carbon atoms, and substituted or unsubstituted heteroaryl with 5 to 12 carbon atoms; and

optionally, substituents in the Ar₅ and Ar₆ are respectively and independently selected from deuterium, a halogen group, alkyl with 1 to 5 carbon atoms, and aryl with 6 to 12 carbon atoms.

Optionally, in Ar₅ and Ar₆, any two adjacent substituents form a saturated or unsaturated ring with 5 to 13 carbon atoms. For example, in Ar₅ and Ar₆, any two adjacent substituents form a fluorene ring.

Specifically, the substituents in the Ar₅ and Ar₆ are each independently selected from deuterium, fluorine, cyano, a halogen group, methyl, ethyl, n-propyl, isopropyl, tert-butyl, phenyl, naphthyl, or biphenyl.

In one embodiment of the present disclosure, in the second compound, the Ar₅ and Ar₆ are respectively and independently selected from substituted or unsubstituted phenyl, substituted or unsubstituted naphthyl, substituted or unsubstituted biphenyl, substituted or unsubstituted terphenyl, substituted or unsubstituted fluorenyl, substituted or unsubstituted phenanthryl, substituted or unsubstituted pyridyl, substituted or unsubstituted dibenzofuranyl, substituted or unsubstituted dibenzothienyl, substituted or unsubstituted carbazolyl, and substituted or unsubstituted triphenylene.

Optionally, the Ar₅ and Ar₆ are respectively and independently selected from substituted or unsubstituted phenyl, substituted or unsubstituted naphthyl, substituted or unsubstituted biphenyl, substituted or unsubstituted terphenyl, substituted or unsubstituted fluorenyl, substituted or unsubstituted phenanthryl, substituted or unsubstituted pyridyl, substituted or unsubstituted dibenzofuranyl, and substituted or unsubstituted dibenzothienyl.

In one embodiment of the present disclosure, in the second compound, the Ar₅ and Ar₆ are the same or different, and are respectively and independently selected from a substituted or unsubstituted group Q, and the unsubstituted group Q is selected from a group consisting of the following groups:

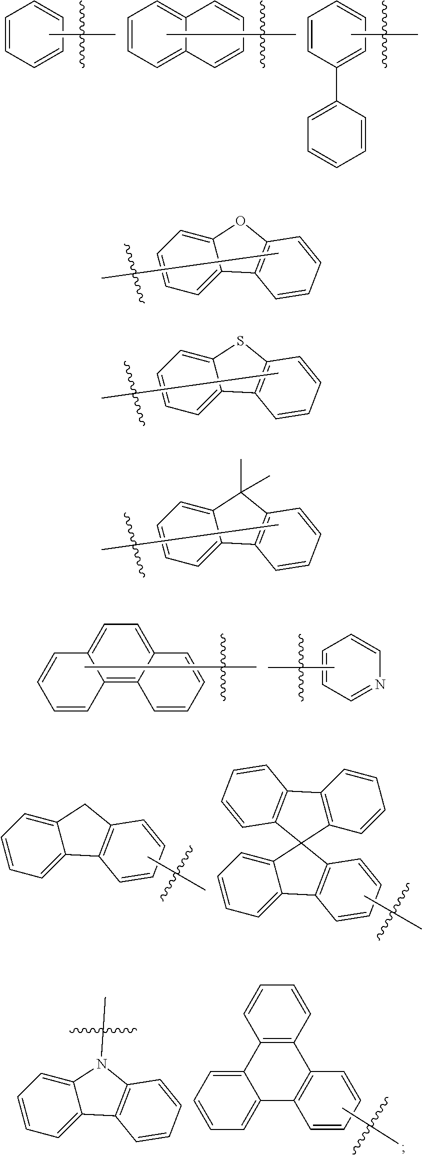

wherein

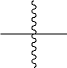

represents a chemical bond; the substituted group Q has one or more substituents, and the substituents are each independently selected from deuterium, cyano, fluorine, methyl, ethyl, n-propyl, isopropyl, tert-butyl, phenyl, naphthyl, or biphenyl; and when the number of the substituents in the group Q is greater than 1, the substituents are the same or different.

Optionally, Ar₅ and Ar₆ are respectively and independently selected from a group consisting of the following groups:

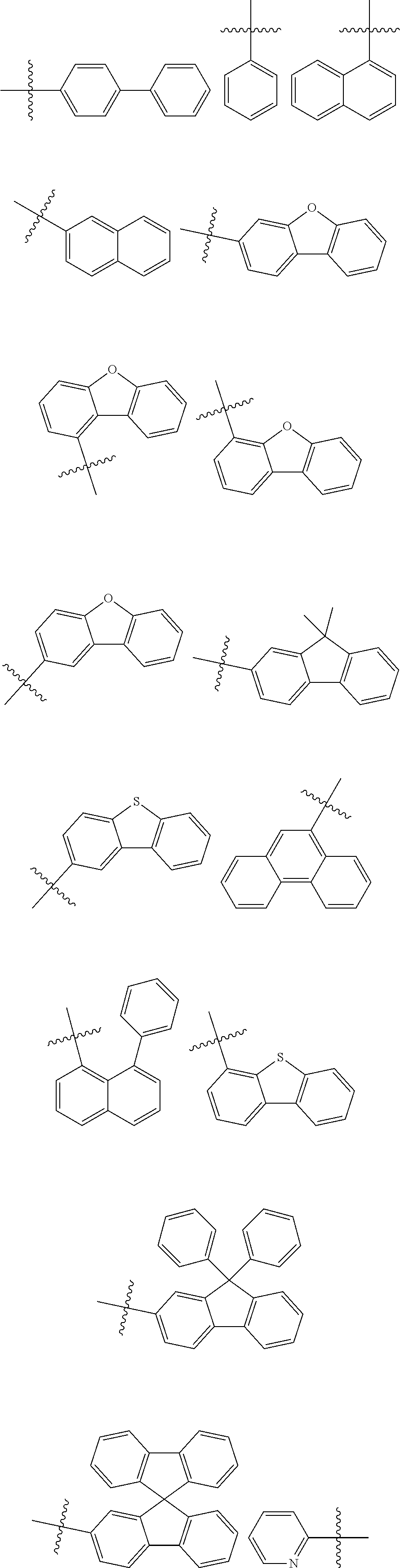

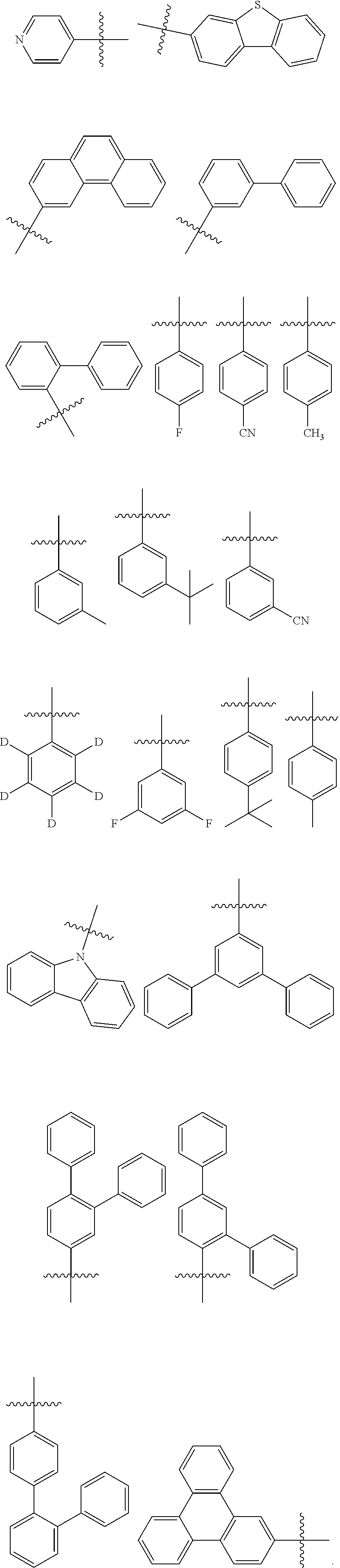

Optionally, the second compound is selected from a group consisting of the following compounds:

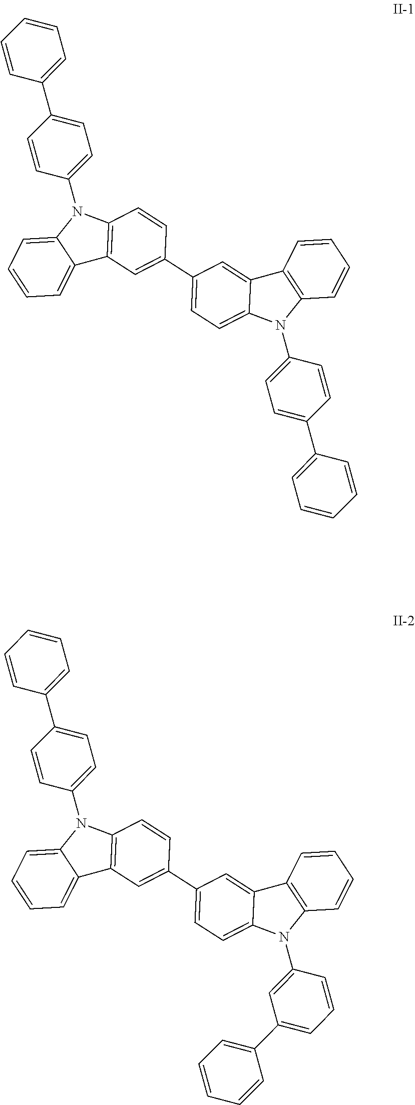 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

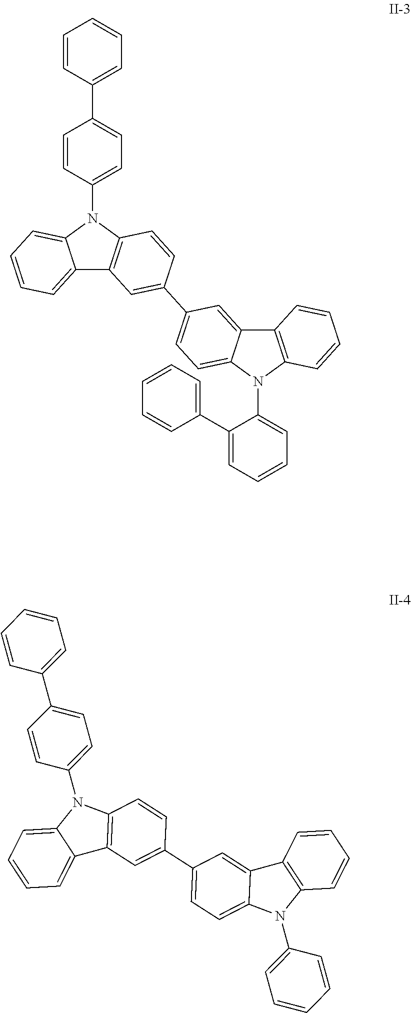 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccccc5)ccc43)cc2)cc1]

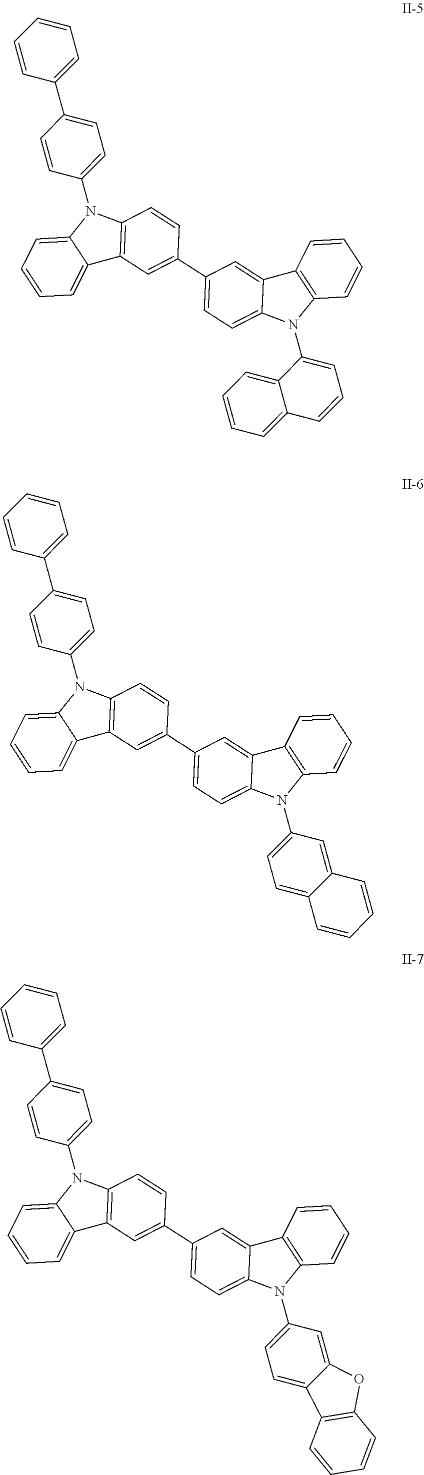 [SMILES: c1ccc(-c2ccc(-n3c4ccccc4c4cc(-c5ccc6c(c5)c5ccccc5n6-c5cccc6ccccc56)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2ccc(-n3c4ccccc4c4cc(-c5ccc6c(c5)c5ccccc5n6-c5ccc6c(c5)oc5ccccc56)ccc43)cc2)cc1]

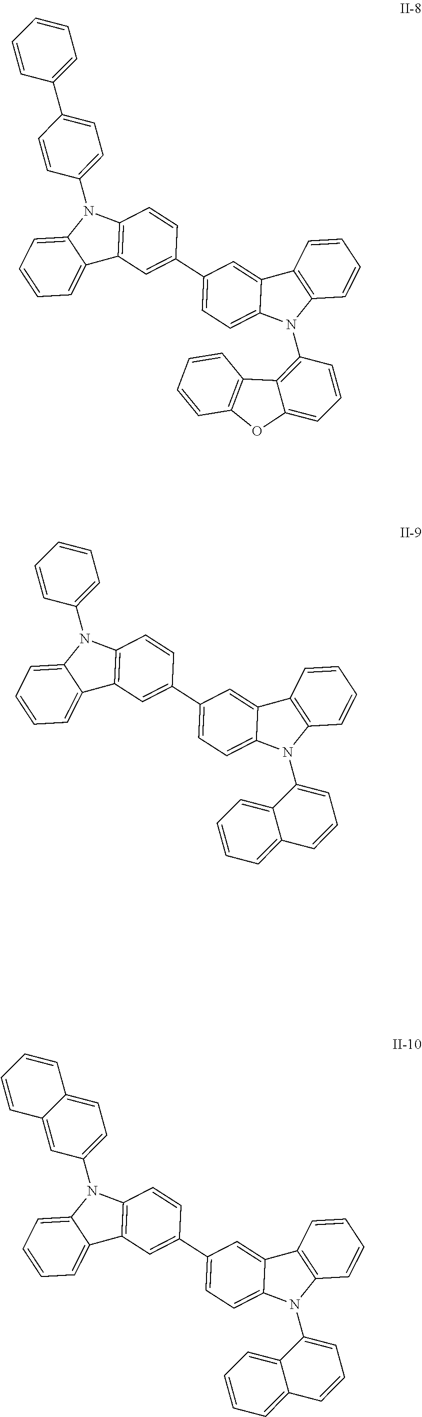 [SMILES: c1ccc(-c2ccc(-n3c4ccccc4c4cc(-c5ccc6c(c5)c5ccccc5n6-c5cccc6oc7ccccc7c56)ccc43)cc2)cc1 ; c1ccc(-n2c3ccccc3c3cc(-c4ccc5c(c4)c4ccccc4n5-c4cccc5ccccc45)ccc32)cc1 ; c1ccc2cc(-n3c4ccccc4c4cc(-c5ccc6c(c5)c5ccccc5n6-c5cccc6ccccc56)ccc43)ccc2c1]

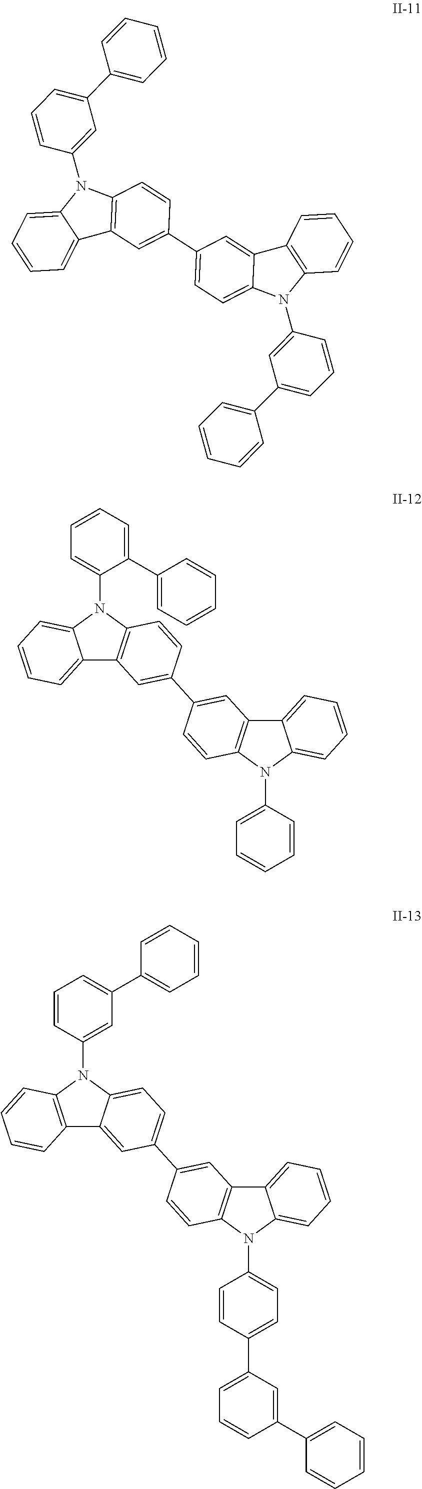 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccccc2-n2c3ccccc3c3cc(-c4ccc5c(c4)c4ccccc4n5-c4ccccc4)ccc32)cc1 ; c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1]

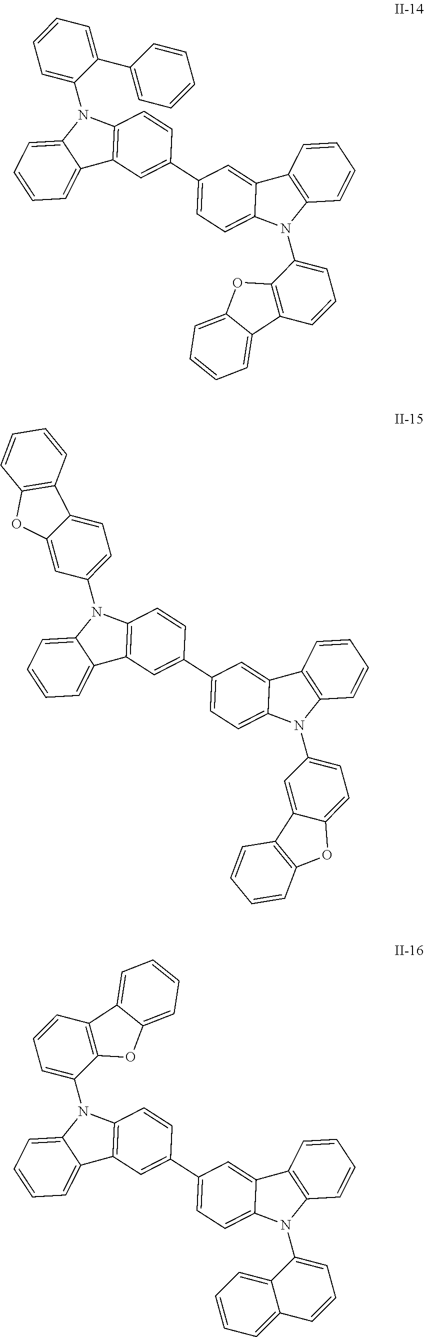 [SMILES: c1ccc(-c2ccccc2-n2c3ccccc3c3cc(-c4ccc5c(c4)c4ccccc4n5-c4cccc5c4oc4ccccc45)ccc32)cc1 ; c1ccc2c(c1)oc1cc(-n3c4ccccc4c4cc(-c5ccc6c(c5)c5ccccc5n6-c5ccc6oc7ccccc7c6c5)ccc43)ccc12 ; c1ccc2c(-n3c4ccccc4c4cc(-c5ccc6c(c5)c5ccccc5n6-c5cccc6c5oc5ccccc56)ccc43)cccc2c1]

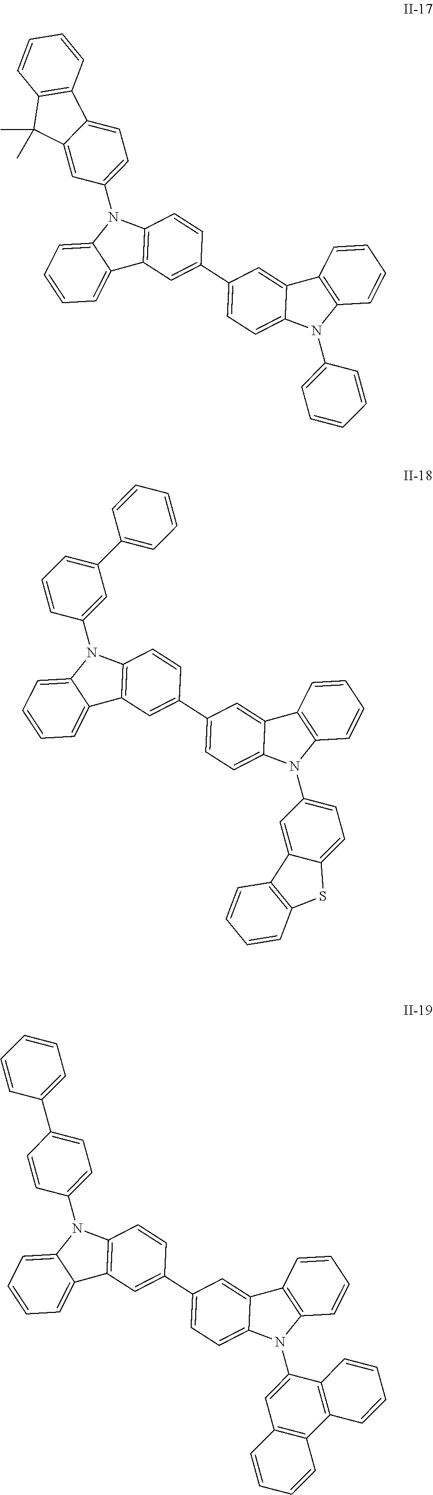 [SMILES: CC1(C)c2ccccc2-c2ccc(-n3c4ccccc4c4cc(-c5ccc6c(c5)c5ccccc5n6-c5ccccc5)ccc43)cc21 ; c1ccc(-c2cccc(-n3c4ccccc4c4cc(-c5ccc6c(c5)c5ccccc5n6-c5ccc6sc7ccccc7c6c5)ccc43)c2)cc1 ; c1ccc(-c2ccc(-n3c4ccccc4c4cc(-c5ccc6c(c5)c5ccccc5n6-c5cc6ccccc6c6ccccc56)ccc43)cc2)cc1]

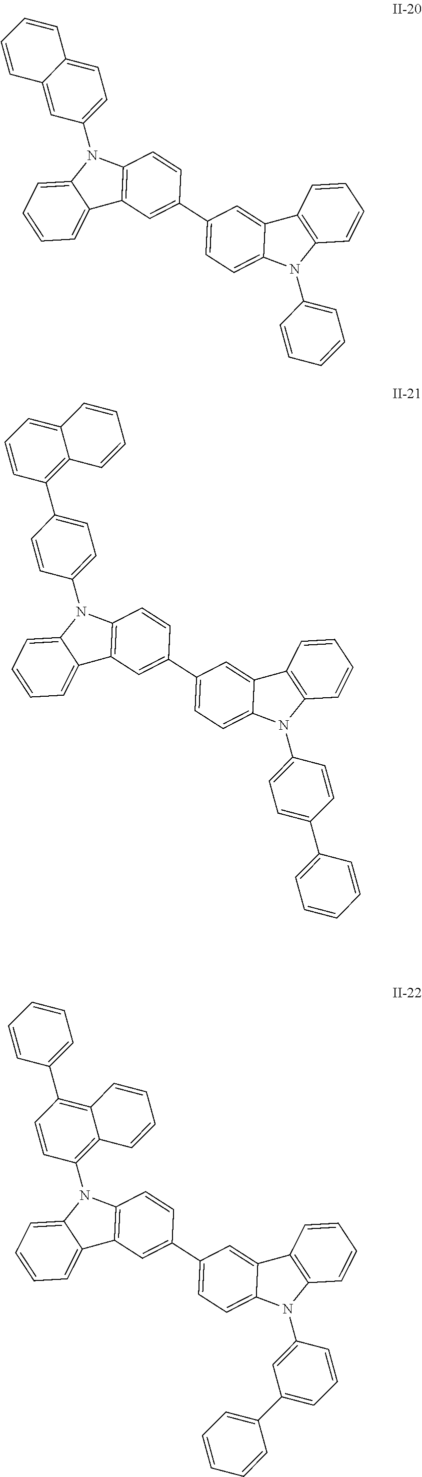 [SMILES: c1ccc(-n2c3ccccc3c3cc(-c4ccc5c(c4)c4ccccc4n5-c4ccc5ccccc5c4)ccc32)cc1 ; c1ccc(-c2ccc(-n3c4ccccc4c4cc(-c5ccc6c(c5)c5ccccc5n6-c5ccc(-c6cccc7ccccc67)cc5)ccc43)cc2)cc1 ; c1ccc(-c2cccc(-n3c4ccccc4c4cc(-c5ccc6c(c5)c5ccccc5n6-c5ccc(-c6ccccc6)c6ccccc56)ccc43)c2)cc1]

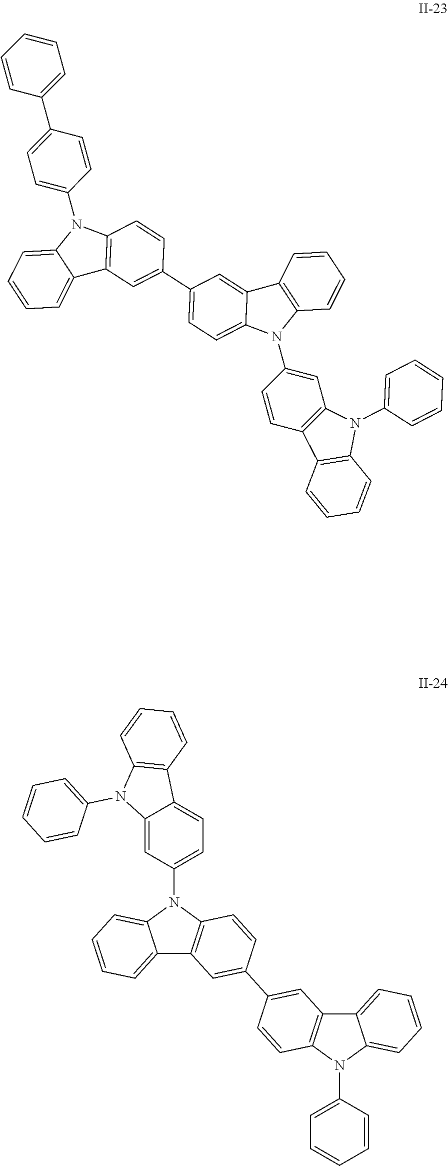 [SMILES: c1ccc(-c2ccc(-n3c4ccccc4c4cc(-c5ccc6c(c5)c5ccccc5n6-c5ccc6c7ccccc7n(-c7ccccc7)c6c5)ccc43)cc2)cc1 ; c1ccc(-n2c3ccccc3c3cc(-c4ccc5c(c4)c4ccccc4n5-c4ccc5c6ccccc6n(-c6ccccc6)c5c4)ccc32)cc1]

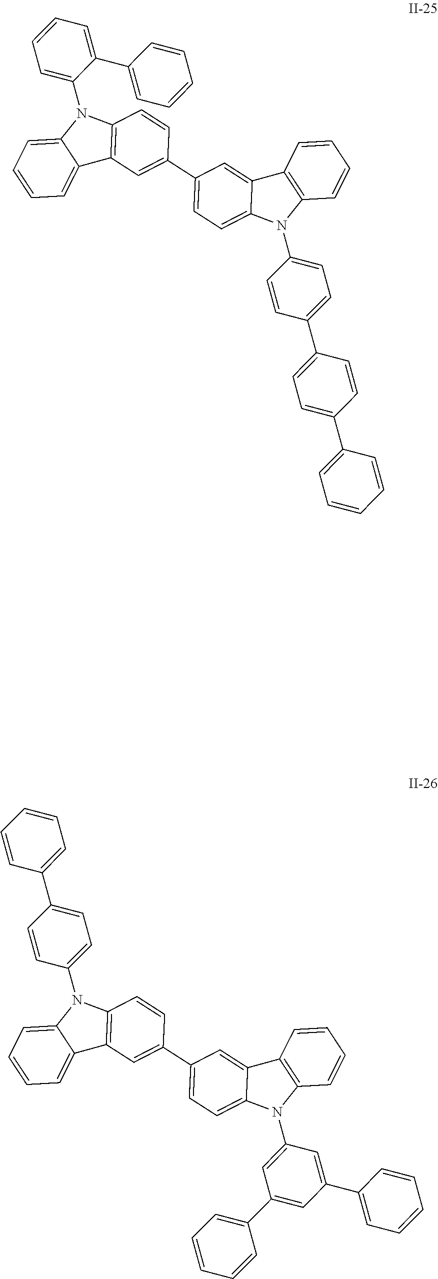 [SMILES: c1ccc(-c2ccc(-c3ccc(-n4c5ccccc5c5cc(-c6ccc7c(c6)c6ccccc6n7-c6ccccc6-c6ccccc6)ccc54)cc3)cc2)cc1 ; c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1]

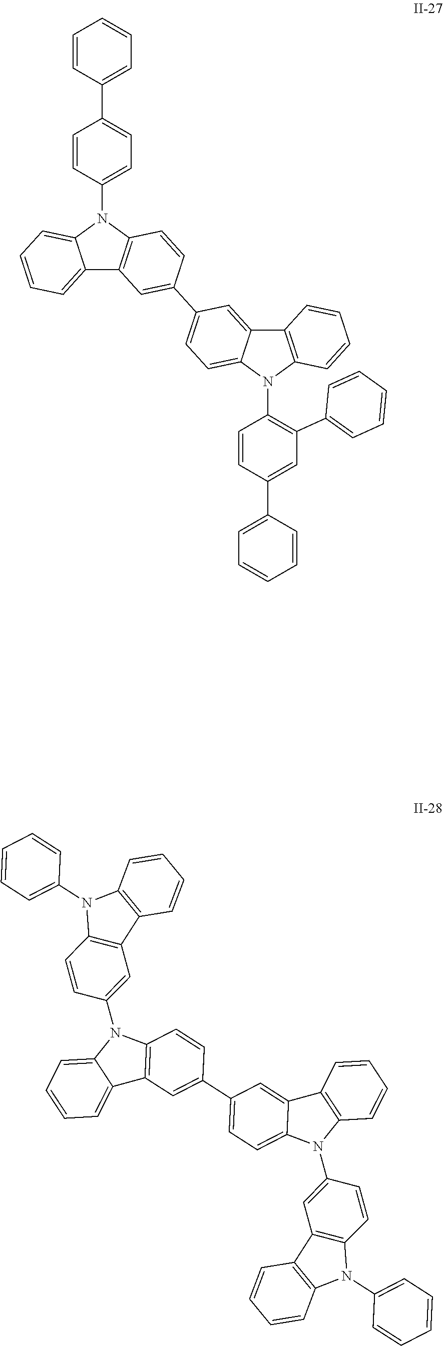 [SMILES: c1ccc(-c2ccc(-n3c4ccccc4c4cc(-c5ccc6c(c5)c5ccccc5n6-c5ccc(-c6ccccc6)cc5-c5ccccc5)ccc43)cc2)cc1 ; c1ccc(-n2c3ccccc3c3cc(-n4c5ccccc5c5cc(-c6ccc7c(c6)c6ccccc6n7-c6ccc7c(c6)c6ccccc6n7-c6ccccc6)ccc54)ccc32)cc1]

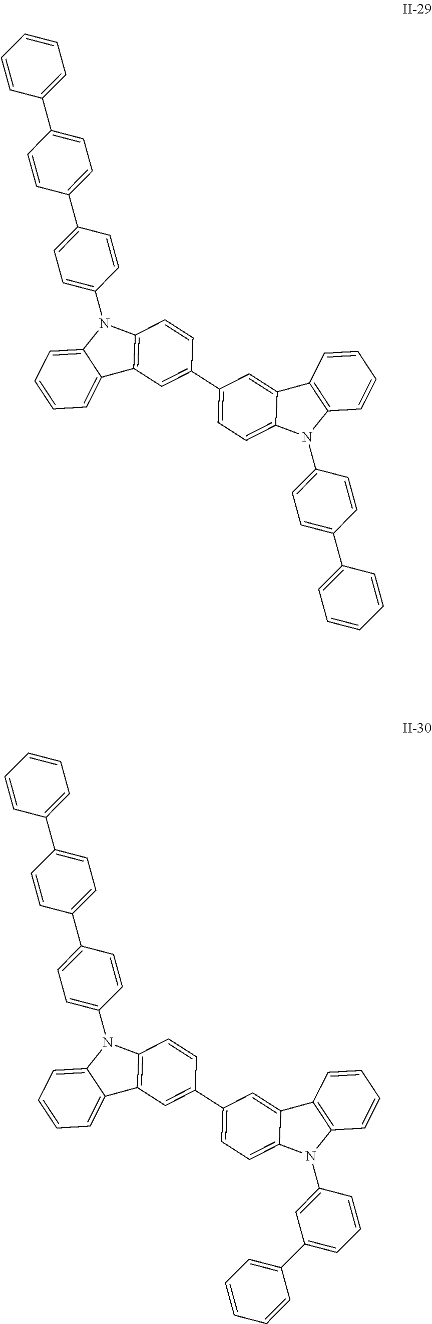 [SMILES: c1ccc(-c2ccc(-c3ccc(-n4c5ccccc5c5cc(-c6ccc7c(c6)c6ccccc6n7-c6ccc(-c7ccccc7)cc6)ccc54)cc3)cc2)cc1 ; c1ccc(-c2ccc(-c3ccc(-n4c5ccccc5c5cc(-c6ccc7c(c6)c6ccccc6n7-c6cccc(-c7ccccc7)c6)ccc54)cc3)cc2)cc1]

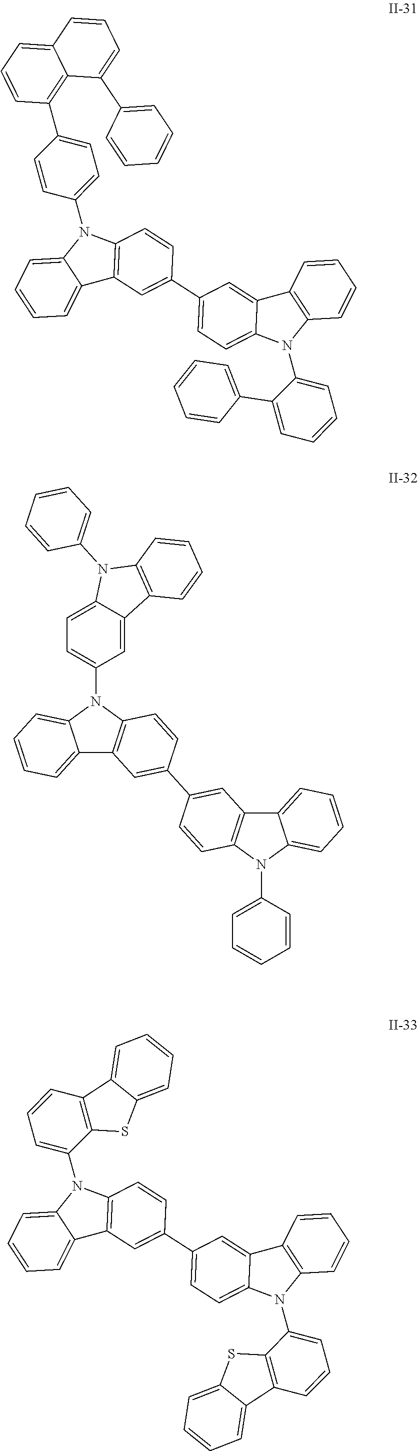 [SMILES: c1ccc(-c2ccccc2-n2c3ccccc3c3cc(-c4ccc5c(c4)c4ccccc4n5-c4ccc(-c5cccc6cccc(-c7ccccc7)c56)cc4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1 ; c1ccc2c(c1)sc1c(-n3c4ccccc4c4cc(-c5ccc6c(c5)c5ccccc5n6-c5cccc6c5sc5ccccc56)ccc43)cccc12]

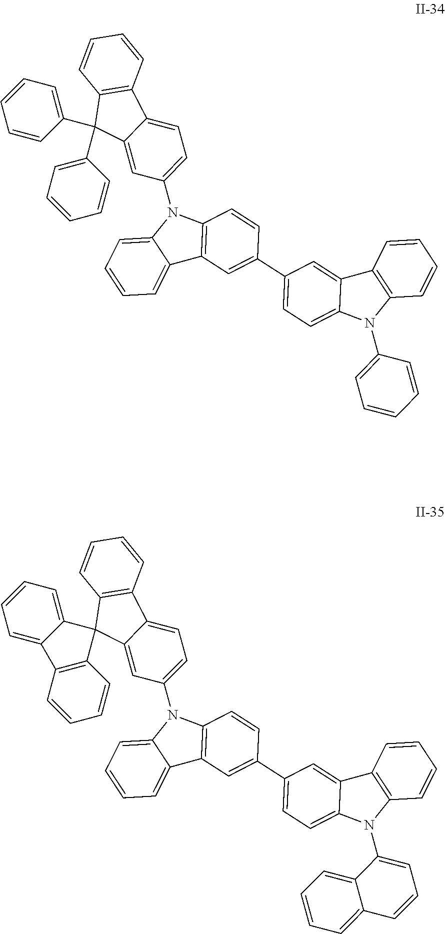 [SMILES: c1ccc(-n2c3ccccc3c3cc(-c4ccc5c(c4)c4ccccc4n5-c4ccc5c(c4)C(c4ccccc4)(c4ccccc4)c4ccccc4-5)ccc32)cc1 ; c1ccc2c(c1)-c1ccccc1C21c2ccccc2-c2ccc(-n3c4ccccc4c4cc(-c5ccc6c(c5)c5ccccc5n6-c5cccc6ccccc56)ccc43)cc21]

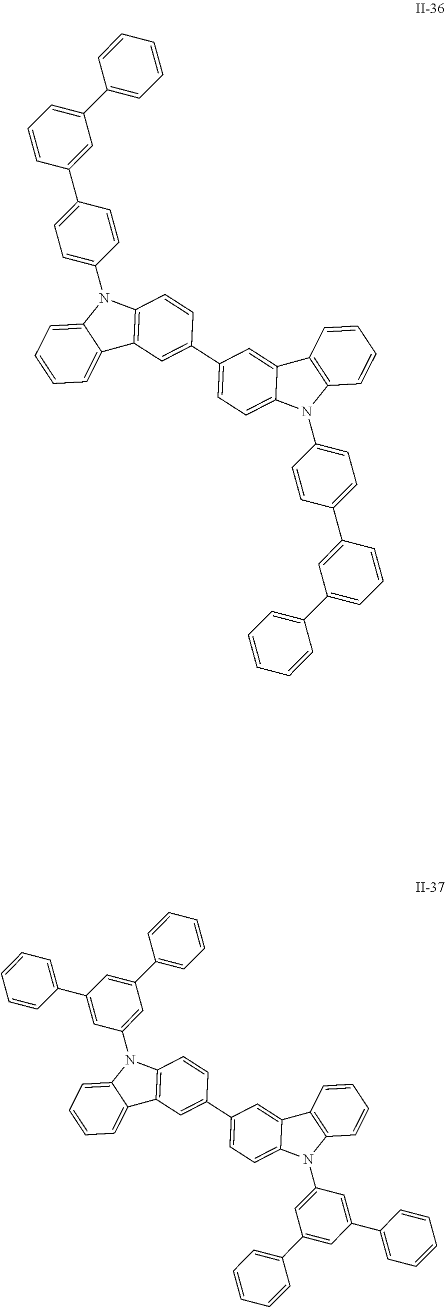 [SMILES: c1ccc(-c2cccc(-c3ccc(-n4c5ccccc5c5cc(-c6ccc7c(c6)c6ccccc6n7-c6ccc(-c7cccc(-c8ccccc8)c7)cc6)ccc54)cc3)c2)cc1 ; c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1]

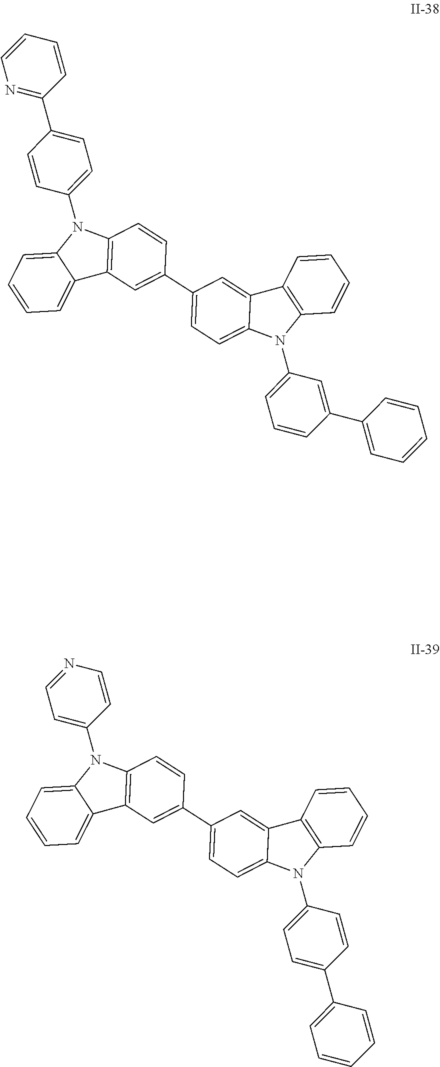 [SMILES: c1ccc(-c2cccc(-n3c4ccccc4c4cc(-c5ccc6c(c5)c5ccccc5n6-c5ccc(-c6ccccn6)cc5)ccc43)c2)cc1 ; c1ccc(-c2ccc(-n3c4ccccc4c4cc(-c5ccc6c(c5)c5ccccc5n6-c5ccncc5)ccc43)cc2)cc1]

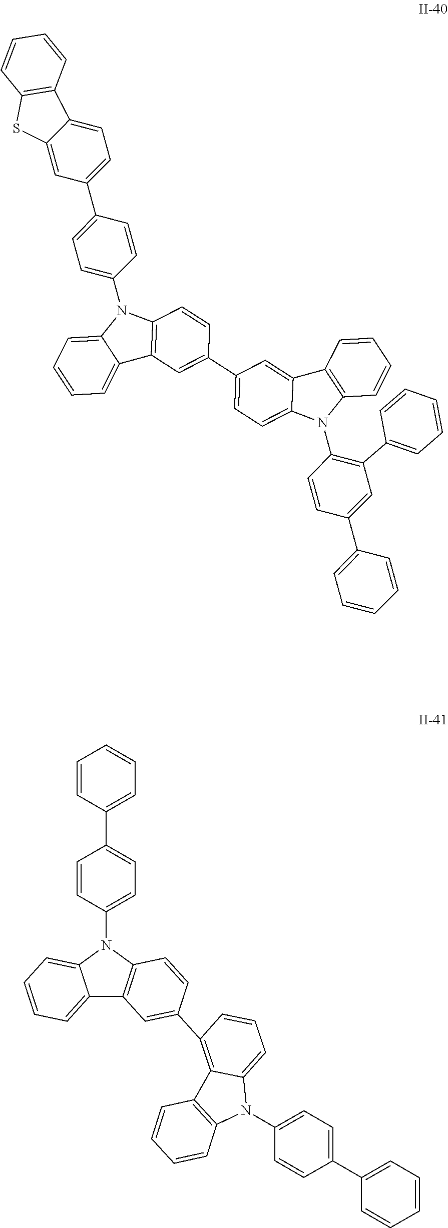 [SMILES: c1ccc(-c2ccc(-n3c4ccccc4c4cc(-c5ccc6c(c5)c5ccccc5n6-c5ccc(-c6ccc7c(c6)sc6ccccc67)cc5)ccc43)c(-c3ccccc3)c2)cc1 ; c1ccc(-c2ccc(-n3c4ccccc4c4cc(-c5cccc6c5c5ccccc5n6-c5ccc(-c6ccccc6)cc5)ccc43)cc2)cc1]

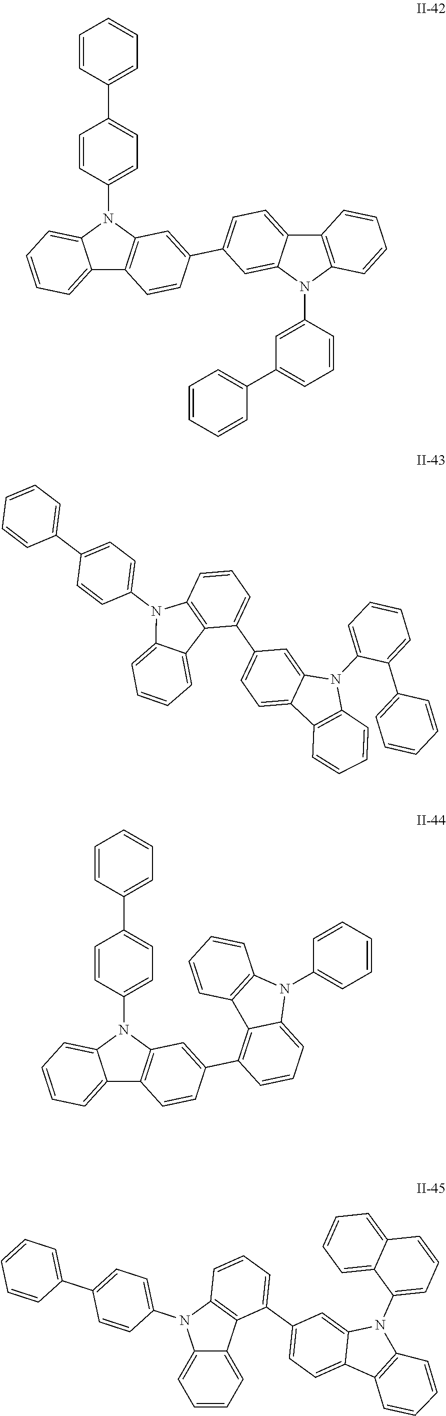 [SMILES: c1ccc(-c2ccc(-n3c4ccccc4c4ccc(-c5ccc6c7ccccc7n(-c7cccc(-c8ccccc8)c7)c6c5)cc43)cc2)cc1 ; c1ccc(-c2ccc(-n3c4ccccc4c4c(-c5ccc6c7ccccc7n(-c7ccccc7-c7ccccc7)c6c5)cccc43)cc2)cc1 ; c1ccc(-c2ccc(-n3c4ccccc4c4ccc(-c5cccc6c5c5ccccc5n6-c5ccccc5)cc43)cc2)cc1 ; c1ccc(-c2ccc(-n3c4ccccc4c4c(-c5ccc6c7ccccc7n(-c7cccc8ccccc78)c6c5)cccc43)cc2)cc1]

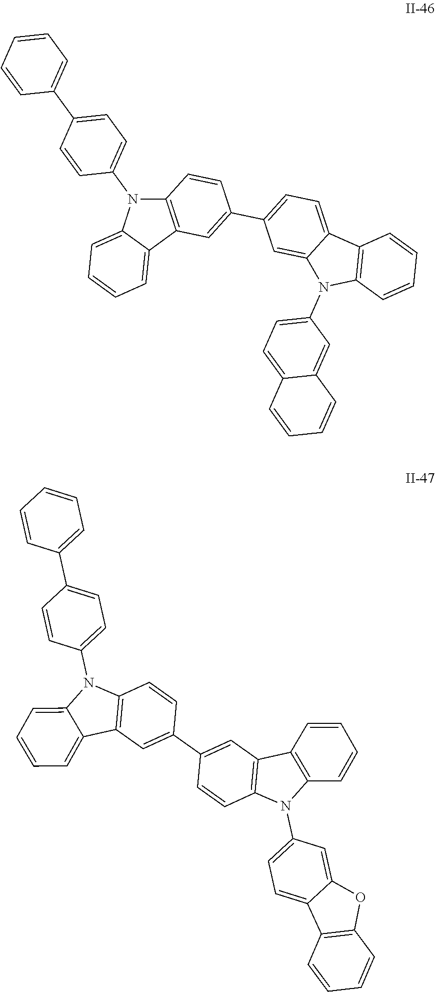 [SMILES: c1ccc(-c2ccc(-n3c4ccccc4c4cc(-c5ccc6c7ccccc7n(-c7ccc8ccccc8c7)c6c5)ccc43)cc2)cc1 ; c1ccc(-c2ccc(-n3c4ccccc4c4cc(-c5ccc6c(c5)c5ccccc5n6-c5ccc6c(c5)oc5ccccc56)ccc43)cc2)cc1]

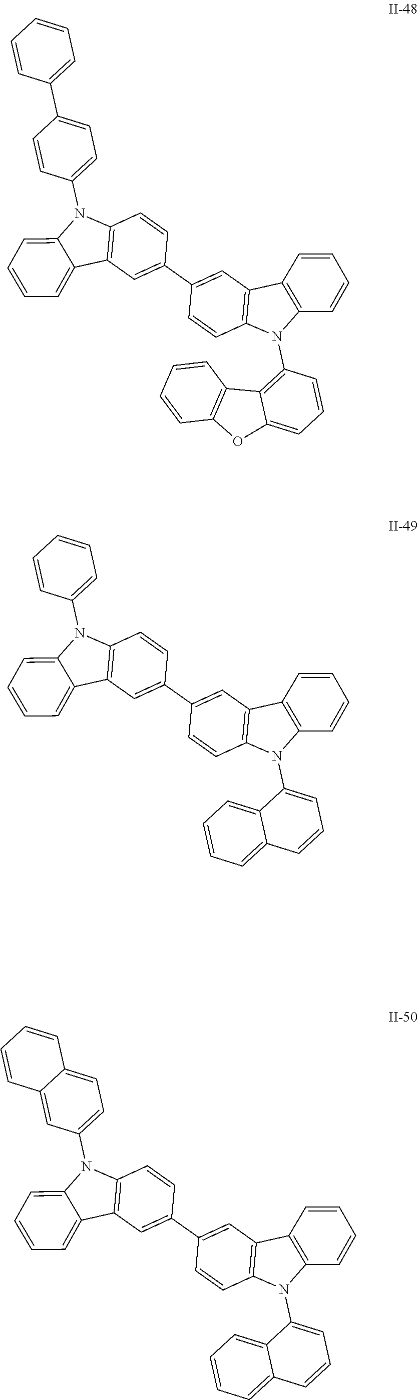 [SMILES: c1ccc(-c2ccc(-n3c4ccccc4c4cc(-c5ccc6c(c5)c5ccccc5n6-c5cccc6oc7ccccc7c56)ccc43)cc2)cc1 ; c1ccc(-n2c3ccccc3c3cc(-c4ccc5c(c4)c4ccccc4n5-c4cccc5ccccc45)ccc32)cc1 ; c1ccc2cc(-n3c4ccccc4c4cc(-c5ccc6c(c5)c5ccccc5n6-c5cccc6ccccc56)ccc43)ccc2c1]

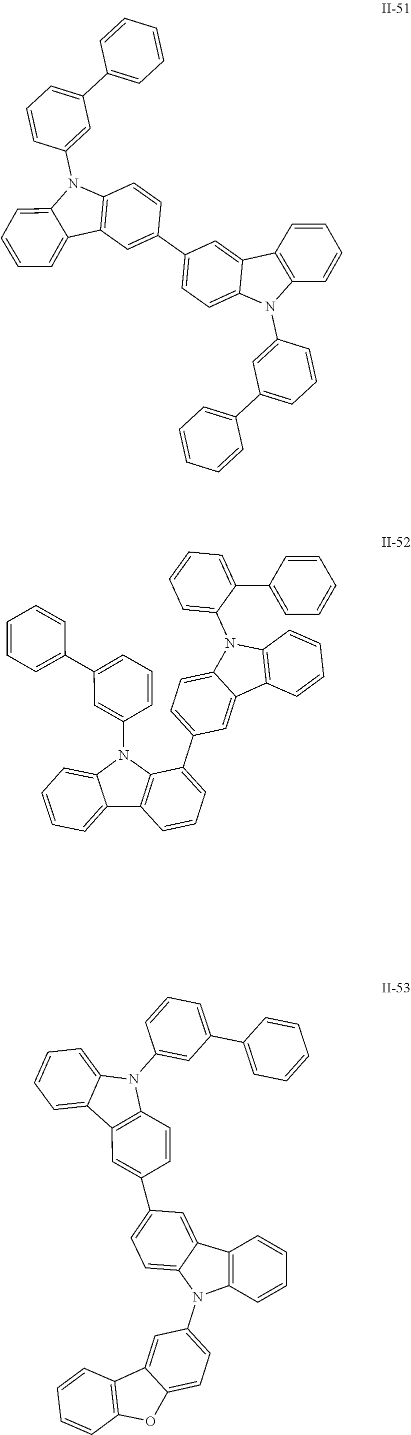 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cccc(-c5ccc6c(c5)c5ccccc5n6-c5ccccc5-c5ccccc5)c43)c2)cc1 ; c1ccc(-c2cccc(-n3c4ccccc4c4cc(-c5ccc6c(c5)c5ccccc5n6-c5ccc6oc7ccccc7c6c5)ccc43)c2)cc1]

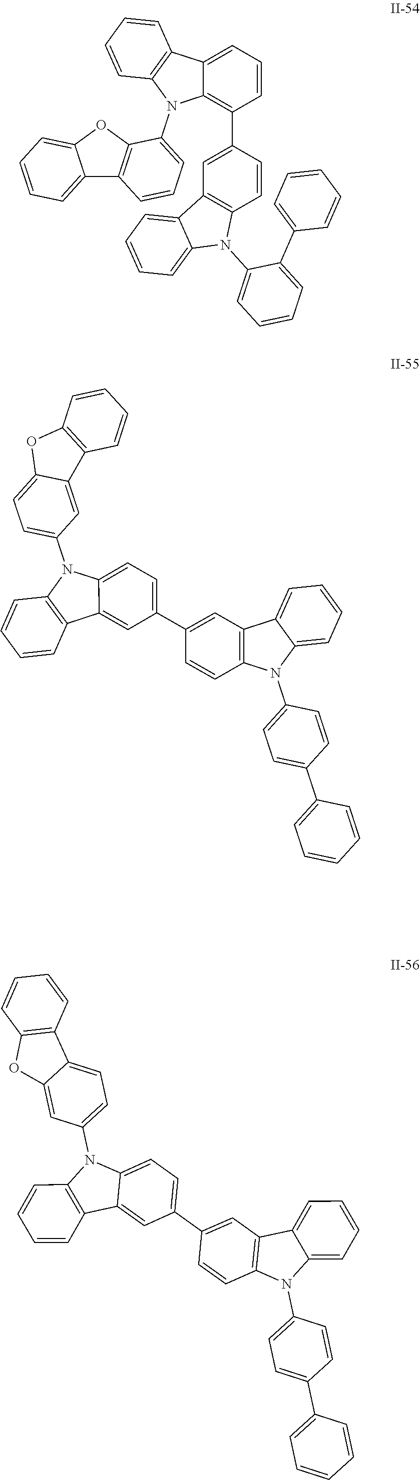 [SMILES: c1ccc(-c2ccccc2-n2c3ccccc3c3cc(-c4cccc5c6ccccc6n(-c6cccc7c6oc6ccccc67)c45)ccc32)cc1 ; c1ccc(-c2ccc(-n3c4ccccc4c4cc(-c5ccc6c(c5)c5ccccc5n6-c5ccc6oc7ccccc7c6c5)ccc43)cc2)cc1 ; c1ccc(-c2ccc(-n3c4ccccc4c4cc(-c5ccc6c(c5)c5ccccc5n6-c5ccc6c(c5)oc5ccccc56)ccc43)cc2)cc1]

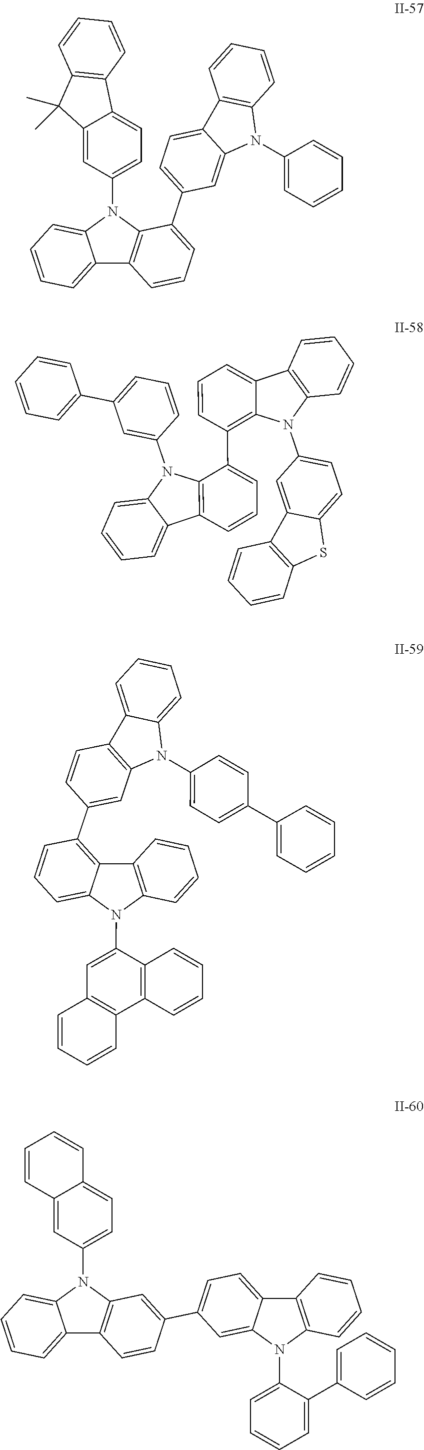 [SMILES: CC1(C)c2ccccc2-c2ccc(-n3c4ccccc4c4cccc(-c5ccc6c7ccccc7n(-c7ccccc7)c6c5)c43)cc21 ; c1ccc(-c2cccc(-n3c4ccccc4c4cccc(-c5cccc6c7ccccc7n(-c7ccc8sc9ccccc9c8c7)c56)c43)c2)cc1 ; c1ccc(-c2ccc(-n3c4ccccc4c4ccc(-c5cccc6c5c5ccccc5n6-c5cc6ccccc6c6ccccc56)cc43)cc2)cc1 ; c1ccc(-c2ccccc2-n2c3ccccc3c3ccc(-c4ccc5c6ccccc6n(-c6ccc7ccccc7c6)c5c4)cc32)cc1]

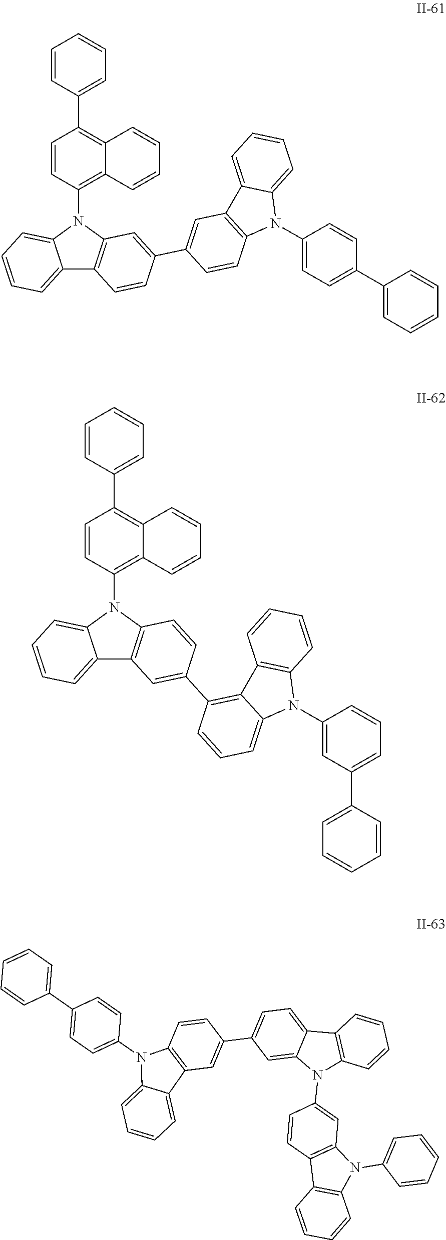 [SMILES: c1ccc(-c2ccc(-n3c4ccccc4c4cc(-c5ccc6c7ccccc7n(-c7ccc(-c8ccccc8)c8ccccc78)c6c5)ccc43)cc2)cc1 ; c1ccc(-c2cccc(-n3c4ccccc4c4c(-c5ccc6c(c5)c5ccccc5n6-c5ccc(-c6ccccc6)c6ccccc56)cccc43)c2)cc1 ; c1ccc(-c2ccc(-n3c4ccccc4c4cc(-c5ccc6c7ccccc7n(-c7ccc8c9ccccc9n(-c9ccccc9)c8c7)c6c5)ccc43)cc2)cc1]

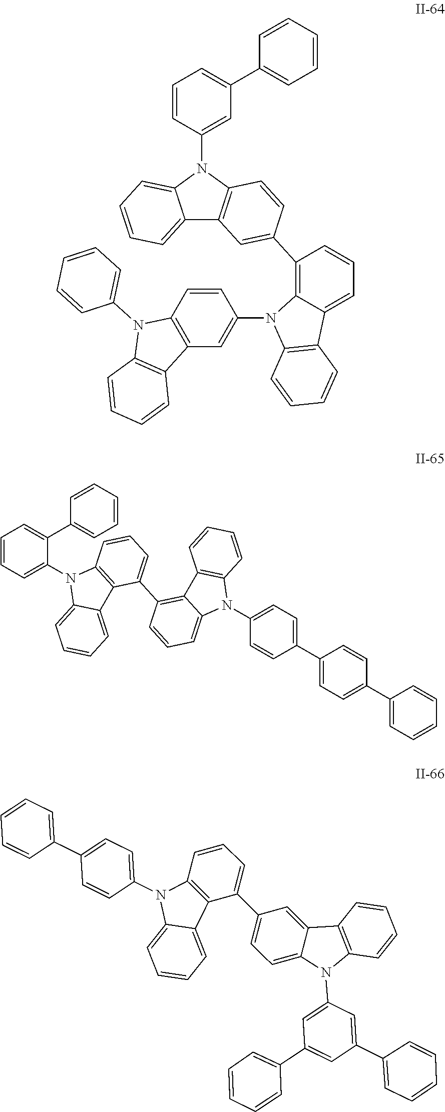 [SMILES: c1ccc(-c2cccc(-n3c4ccccc4c4cc(-c5cccc6c7ccccc7n(-c7ccc8c(c7)c7ccccc7n8-c7ccccc7)c56)ccc43)c2)cc1 ; c1ccc(-c2ccc(-c3ccc(-n4c5ccccc5c5c(-c6cccc7c6c6ccccc6n7-c6ccccc6-c6ccccc6)cccc54)cc3)cc2)cc1 ; c1ccc(-c2ccc(-n3c4ccccc4c4c(-c5ccc6c(c5)c5ccccc5n6-c5cc(-c6ccccc6)cc(-c6ccccc6)c5)cccc43)cc2)cc1]

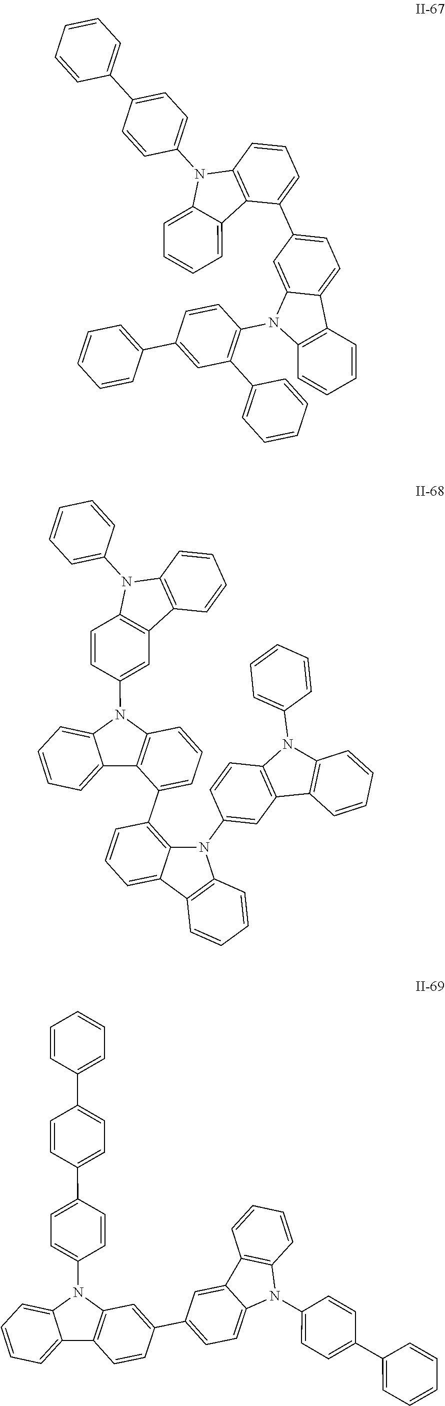 [SMILES: c1ccc(-c2ccc(-n3c4ccccc4c4c(-c5ccc6c7ccccc7n(-c7ccc(-c8ccccc8)cc7-c7ccccc7)c6c5)cccc43)cc2)cc1 ; c1ccc(-n2c3ccccc3c3cc(-n4c5ccccc5c5c(-c6cccc7c8ccccc8n(-c8ccc9c(c8)c8ccccc8n9-c8ccccc8)c67)cccc54)ccc32)cc1 ; c1ccc(-c2ccc(-c3ccc(-n4c5ccccc5c5ccc(-c6ccc7c(c6)c6ccccc6n7-c6ccc(-c7ccccc7)cc6)cc54)cc3)cc2)cc1]

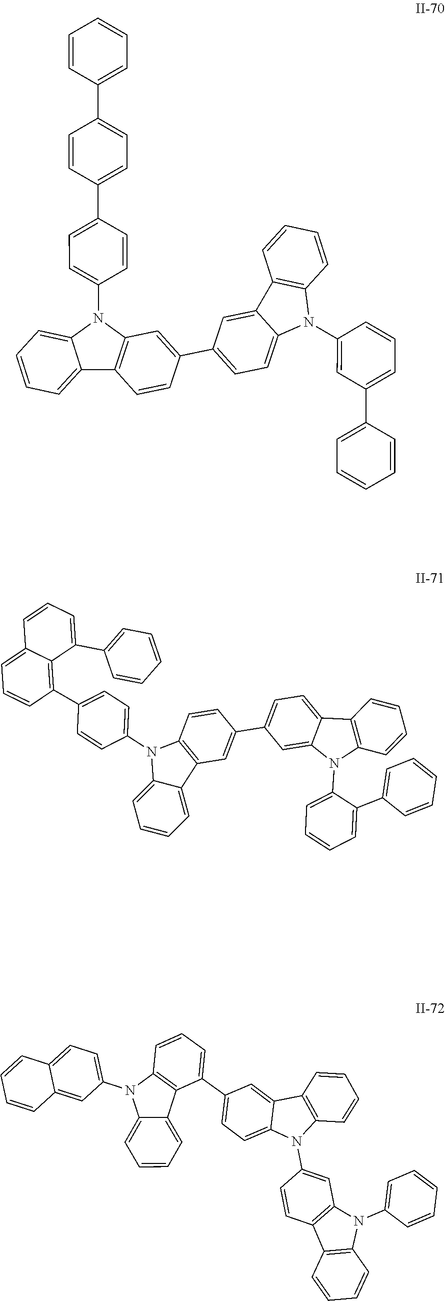 [SMILES: c1ccc(-c2ccc(-c3ccc(-n4c5ccccc5c5ccc(-c6ccc7c(c6)c6ccccc6n7-c6cccc(-c7ccccc7)c6)cc54)cc3)cc2)cc1 ; c1ccc(-c2ccccc2-n2c3ccccc3c3ccc(-c4ccc5c(c4)c4ccccc4n5-c4ccc(-c5cccc6cccc(-c7ccccc7)c56)cc4)cc32)cc1 ; c1ccc(-n2c3ccccc3c3ccc(-n4c5ccccc5c5cc(-c6cccc7c6c6ccccc6n7-c6ccc7ccccc7c6)ccc54)cc32)cc1]

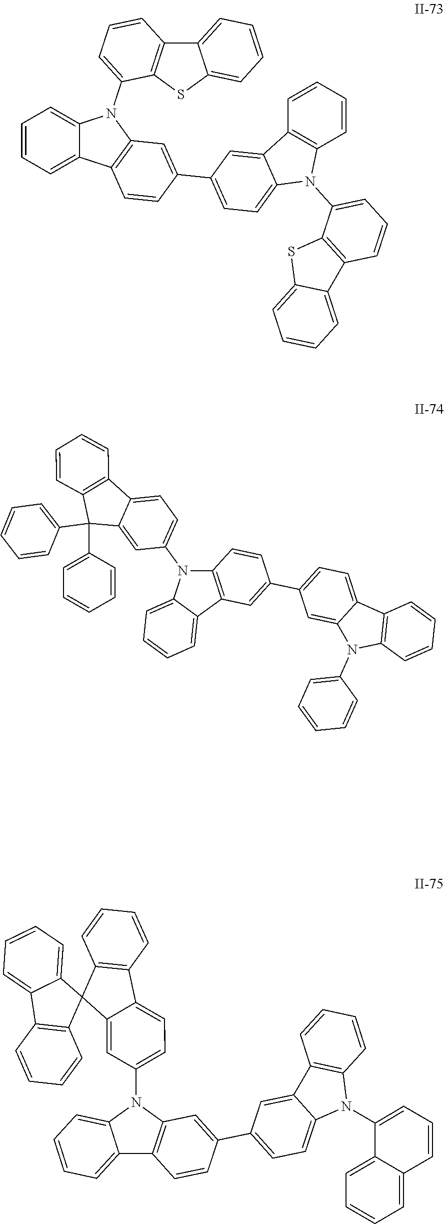 [SMILES: c1ccc2c(c1)sc1c(-n3c4ccccc4c4cc(-c5ccc6c7ccccc7n(-c7cccc8c7sc7ccccc78)c6c5)ccc43)cccc12 ; c1ccc(-n2c3ccccc3c3ccc(-c4ccc5c(c4)c4ccccc4n5-c4ccc5c(c4)C(c4ccccc4)(c4ccccc4)c4ccccc4-5)cc32)cc1 ; c1ccc2c(c1)-c1ccccc1C21c2ccccc2-c2ccc(-n3c4ccccc4c4ccc(-c5ccc6c(c5)c5ccccc5n6-c5cccc6ccccc56)cc43)cc21]

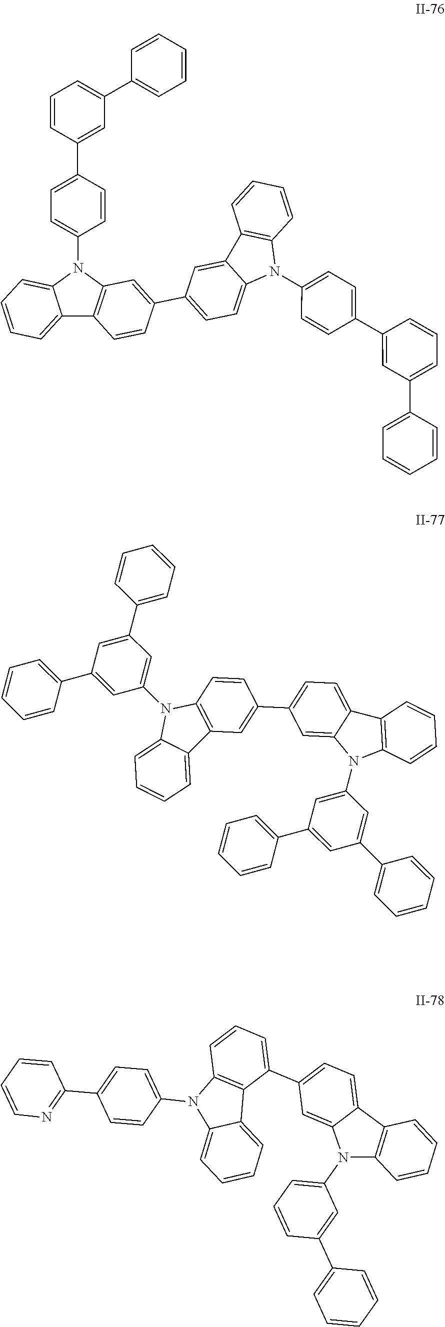 [SMILES: c1ccc(-c2cccc(-c3ccc(-n4c5ccccc5c5cc(-c6ccc7c8ccccc8n(-c8ccc(-c9cccc(-c%10ccccc%10)c9)cc8)c7c6)ccc54)cc3)c2)cc1 ; c1ccc(-c2cc(-c3ccccc3)cc(-n3c4ccccc4c4cc(-c5ccc6c7ccccc7n(-c7cc(-c8ccccc8)cc(-c8ccccc8)c7)c6c5)ccc43)c2)cc1 ; c1ccc(-c2cccc(-n3c4ccccc4c4ccc(-c5cccc6c5c5ccccc5n6-c5ccc(-c6ccccn6)cc5)cc43)c2)cc1]

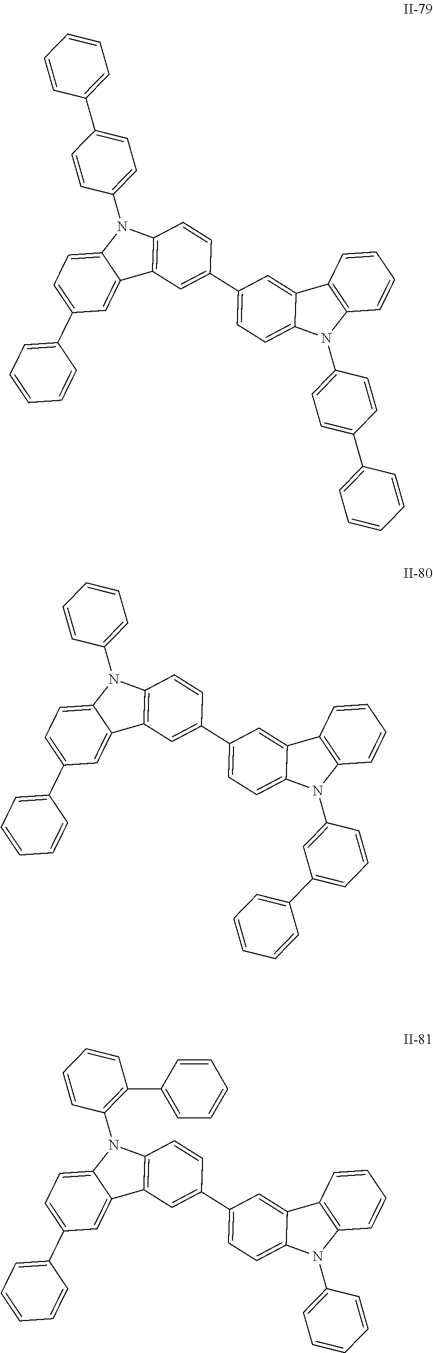 [SMILES: c1ccc(-c2ccc(-n3c4ccccc4c4cc(-c5ccc6c(c5)c5cc(-c7ccccc7)ccc5n6-c5ccc(-c6ccccc6)cc5)ccc43)cc2)cc1 ; c1ccc(-c2cccc(-n3c4ccccc4c4cc(-c5ccc6c(c5)c5cc(-c7ccccc7)ccc5n6-c5ccccc5)ccc43)c2)cc1 ; c1ccc(-c2ccc3c(c2)c2cc(-c4ccc5c(c4)c4ccccc4n5-c4ccccc4)ccc2n3-c2ccccc2-c2ccccc2)cc1]

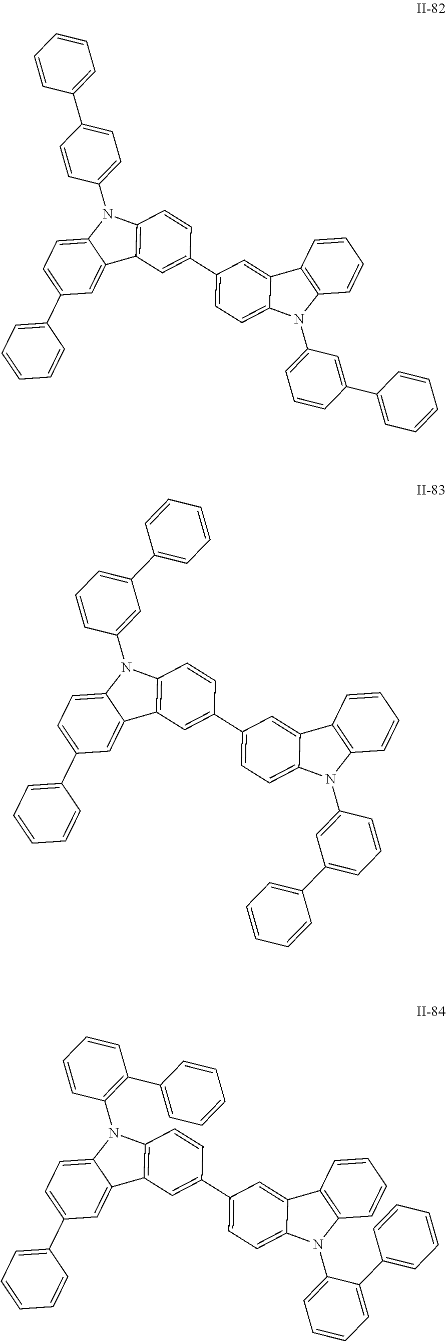 [SMILES: c1ccc(-c2ccc(-n3c4ccc(-c5ccccc5)cc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5ccc6c(c5)c5cc(-c7ccccc7)ccc5n6-c5cccc(-c6ccccc6)c5)ccc43)c2)cc1 ; c1ccc(-c2ccc3c(c2)c2cc(-c4ccc5c(c4)c4ccccc4n5-c4ccccc4-c4ccccc4)ccc2n3-c2ccccc2-c2ccccc2)cc1]

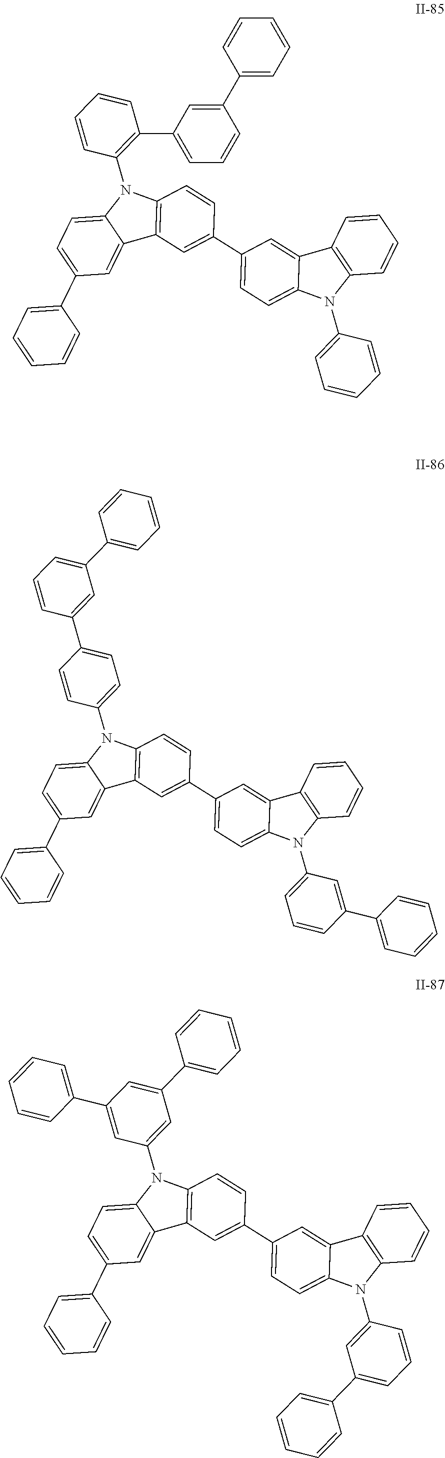 [SMILES: c1ccc(-c2cccc(-c3ccccc3-n3c4ccc(-c5ccccc5)cc4c4cc(-c5ccc6c(c5)c5ccccc5n6-c5ccccc5)ccc43)c2)cc1 ; c1ccc(-c2cccc(-c3ccc(-n4c5ccc(-c6ccccc6)cc5c5cc(-c6ccc7c(c6)c6ccccc6n7-c6cccc(-c7ccccc7)c6)ccc54)cc3)c2)cc1 ; c1ccc(-c2cccc(-n3c4ccccc4c4cc(-c5ccc6c(c5)c5cc(-c7ccccc7)ccc5n6-c5cc(-c6ccccc6)cc(-c6ccccc6)c5)ccc43)c2)cc1]

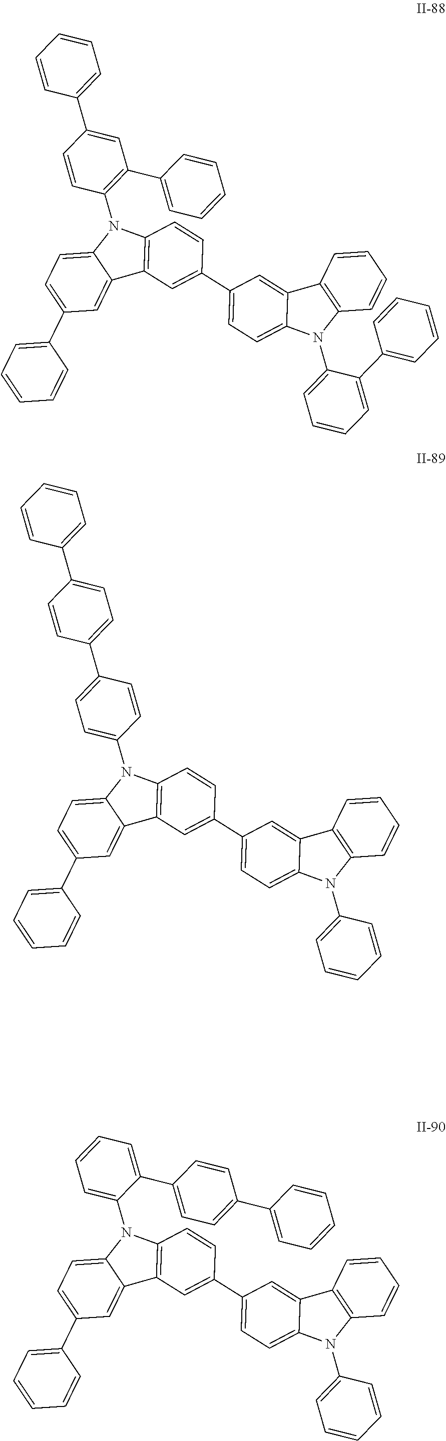 [SMILES: c1ccc(-c2ccc(-n3c4ccc(-c5ccccc5)cc4c4cc(-c5ccc6c(c5)c5ccccc5n6-c5ccccc5-c5ccccc5)ccc43)c(-c3ccccc3)c2)cc1 ; c1ccc(-c2ccc(-c3ccc(-n4c5ccc(-c6ccccc6)cc5c5cc(-c6ccc7c(c6)c6ccccc6n7-c6ccccc6)ccc54)cc3)cc2)cc1 ; c1ccc(-c2ccc(-c3ccccc3-n3c4ccc(-c5ccccc5)cc4c4cc(-c5ccc6c(c5)c5ccccc5n6-c5ccccc5)ccc43)cc2)cc1]

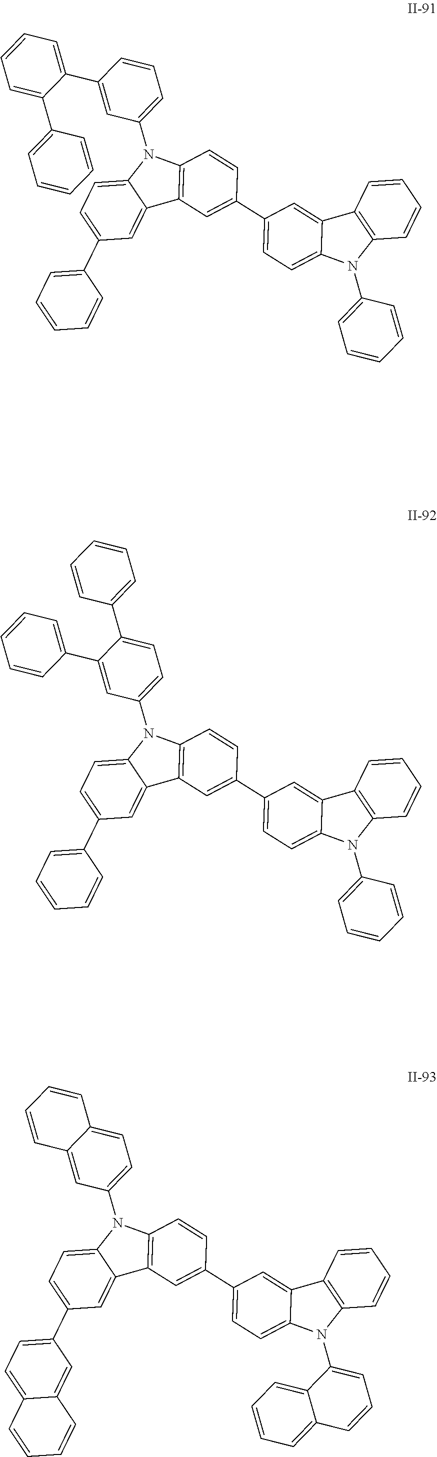 [SMILES: c1ccc(-c2ccc3c(c2)c2cc(-c4ccc5c(c4)c4ccccc4n5-c4ccccc4)ccc2n3-c2cccc(-c3ccccc3-c3ccccc3)c2)cc1 ; c1ccc(-c2ccc3c(c2)c2cc(-c4ccc5c(c4)c4ccccc4n5-c4ccccc4)ccc2n3-c2ccc(-c3ccccc3)c(-c3ccccc3)c2)cc1 ; c1ccc2cc(-c3ccc4c(c3)c3cc(-c5ccc6c(c5)c5ccccc5n6-c5cccc6ccccc56)ccc3n4-c3ccc4ccccc4c3)ccc2c1]

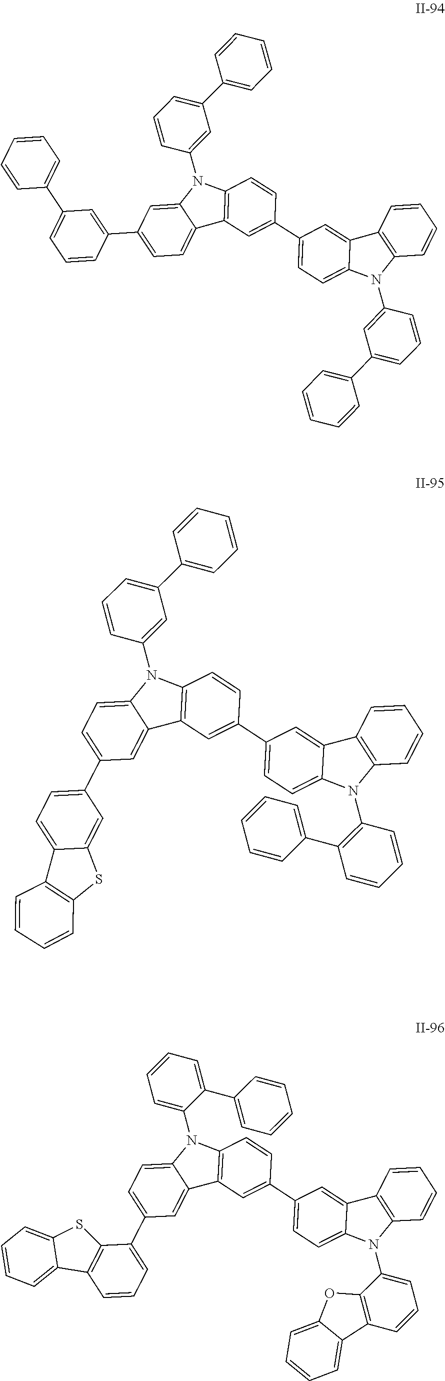 [SMILES: c1ccc(-c2cccc(-c3ccc4c5cc(-c6ccc7c(c6)c6ccccc6n7-c6cccc(-c7ccccc7)c6)ccc5n(-c5cccc(-c6ccccc6)c5)c4c3)c2)cc1 ; c1ccc(-c2cccc(-n3c4ccc(-c5ccc6c(c5)sc5ccccc56)cc4c4cc(-c5ccc6c(c5)c5ccccc5n6-c5ccccc5-c5ccccc5)ccc43)c2)cc1 ; c1ccc(-c2ccccc2-n2c3ccc(-c4ccc5c(c4)c4ccccc4n5-c4cccc5c4oc4ccccc45)cc3c3cc(-c4cccc5c4sc4ccccc45)ccc32)cc1]

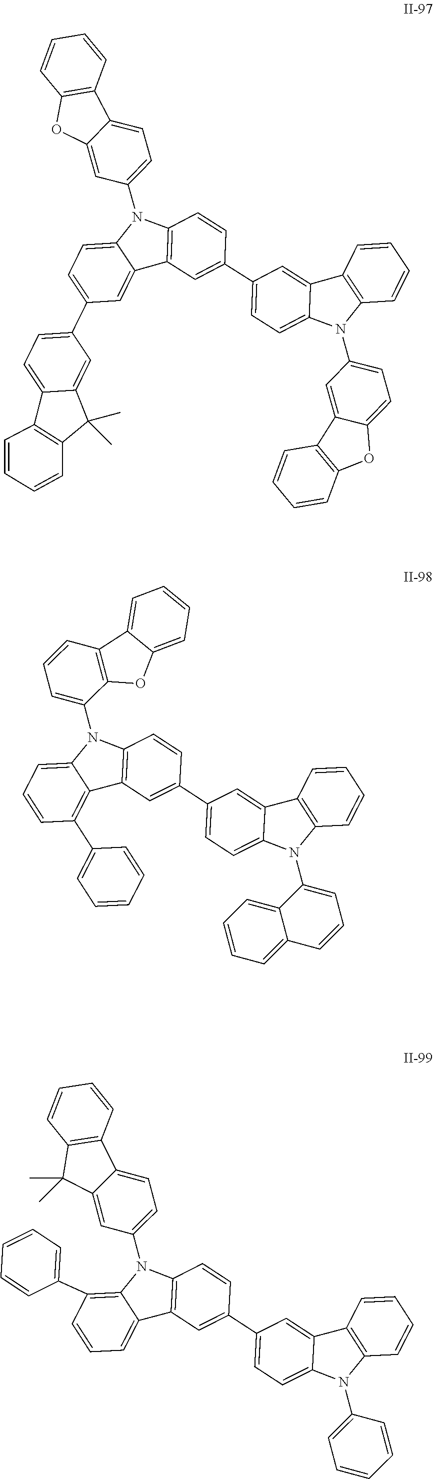 [SMILES: CC1(C)c2ccccc2-c2ccc(-c3ccc4c(c3)c3cc(-c5ccc6c(c5)c5ccccc5n6-c5ccc6oc7ccccc7c6c5)ccc3n4-c3ccc4c(c3)oc3ccccc34)cc21 ; c1ccc(-c2cccc3c2c2cc(-c4ccc5c(c4)c4ccccc4n5-c4cccc5ccccc45)ccc2n3-c2cccc3c2oc2ccccc23)cc1 ; CC1(C)c2ccccc2-c2ccc(-n3c4ccc(-c5ccc6c(c5)c5ccccc5n6-c5ccccc5)cc4c4cccc(-c5ccccc5)c43)cc21]

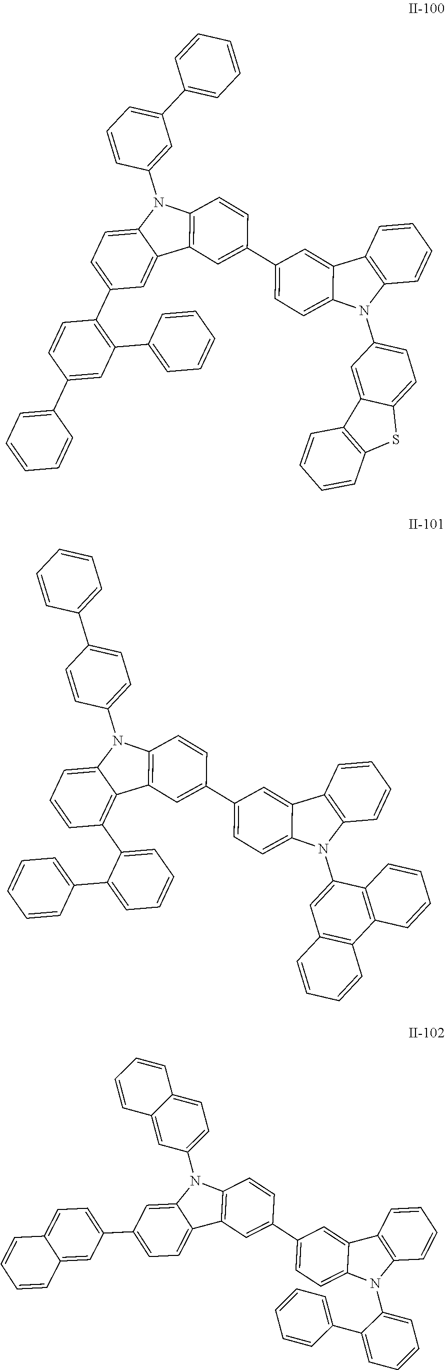 [SMILES: c1ccc(-c2cccc(-n3c4ccc(-c5ccc6c(c5)c5ccccc5n6-c5ccc6sc7ccccc7c6c5)cc4c4cc(-c5ccc(-c6ccccc6)cc5-c5ccccc5)ccc43)c2)cc1 ; c1ccc(-c2ccc(-n3c4ccc(-c5ccc6c(c5)c5ccccc5n6-c5cc6ccccc6c6ccccc56)cc4c4c(-c5ccccc5-c5ccccc5)cccc43)cc2)cc1 ; c1ccc(-c2ccccc2-n2c3ccccc3c3cc(-c4ccc5c(c4)c4ccc(-c6ccc7ccccc7c6)cc4n5-c4ccc5ccccc5c4)ccc32)cc1]

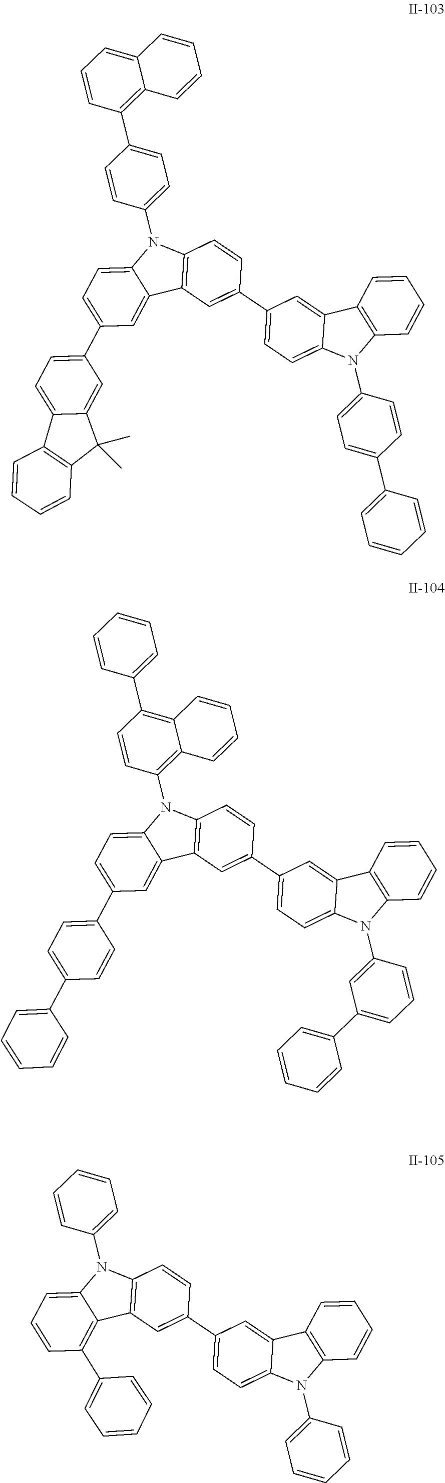 [SMILES: CC1(C)c2ccccc2-c2ccc(-c3ccc4c(c3)c3cc(-c5ccc6c(c5)c5ccccc5n6-c5ccc(-c6ccccc6)cc5)ccc3n4-c3ccc(-c4cccc5ccccc45)cc3)cc21 ; c1ccc(-c2ccc(-c3ccc4c(c3)c3cc(-c5ccc6c(c5)c5ccccc5n6-c5cccc(-c6ccccc6)c5)ccc3n4-c3ccc(-c4ccccc4)c4ccccc34)cc2)cc1 ; c1ccc(-c2cccc3c2c2cc(-c4ccc5c(c4)c4ccccc4n5-c4ccccc4)ccc2n3-c2ccccc2)cc1]

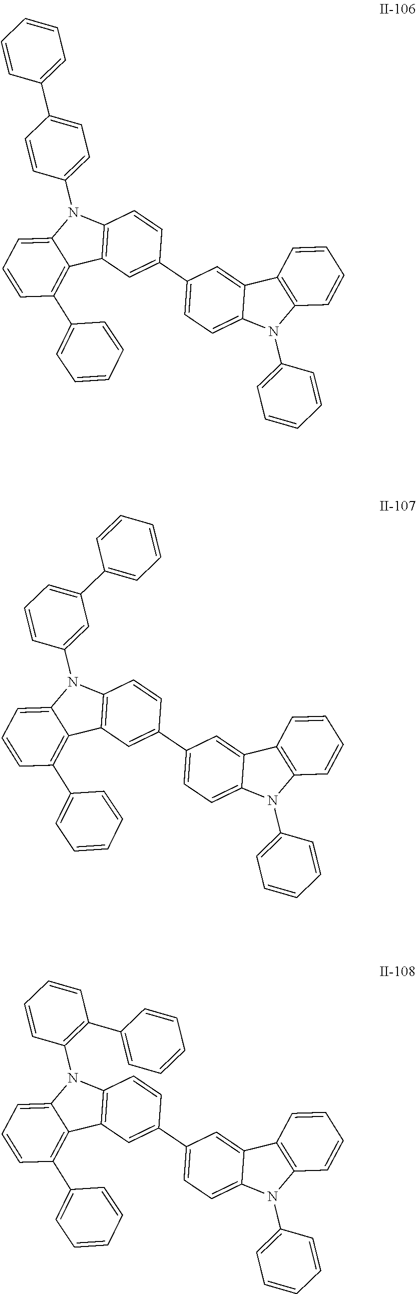 [SMILES: c1ccc(-c2ccc(-n3c4ccc(-c5ccc6c(c5)c5ccccc5n6-c5ccccc5)cc4c4c(-c5ccccc5)cccc43)cc2)cc1 ; c1ccc(-c2cccc(-n3c4ccc(-c5ccc6c(c5)c5ccccc5n6-c5ccccc5)cc4c4c(-c5ccccc5)cccc43)c2)cc1 ; c1ccc(-c2ccccc2-n2c3ccc(-c4ccc5c(c4)c4ccccc4n5-c4ccccc4)cc3c3c(-c4ccccc4)cccc32)cc1]

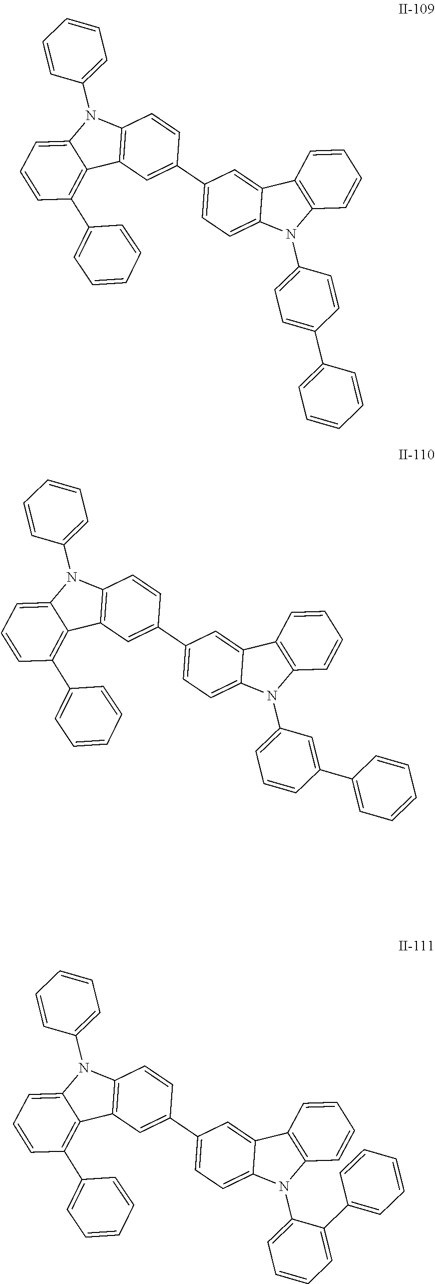 [SMILES: c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2cccc(-n3c4ccccc4c4cc(-c5ccc6c(c5)c5c(-c7ccccc7)cccc5n6-c5ccccc5)ccc43)c2)cc1 ; c1ccc(-c2ccccc2-n2c3ccccc3c3cc(-c4ccc5c(c4)c4c(-c6ccccc6)cccc4n5-c4ccccc4)ccc32)cc1]

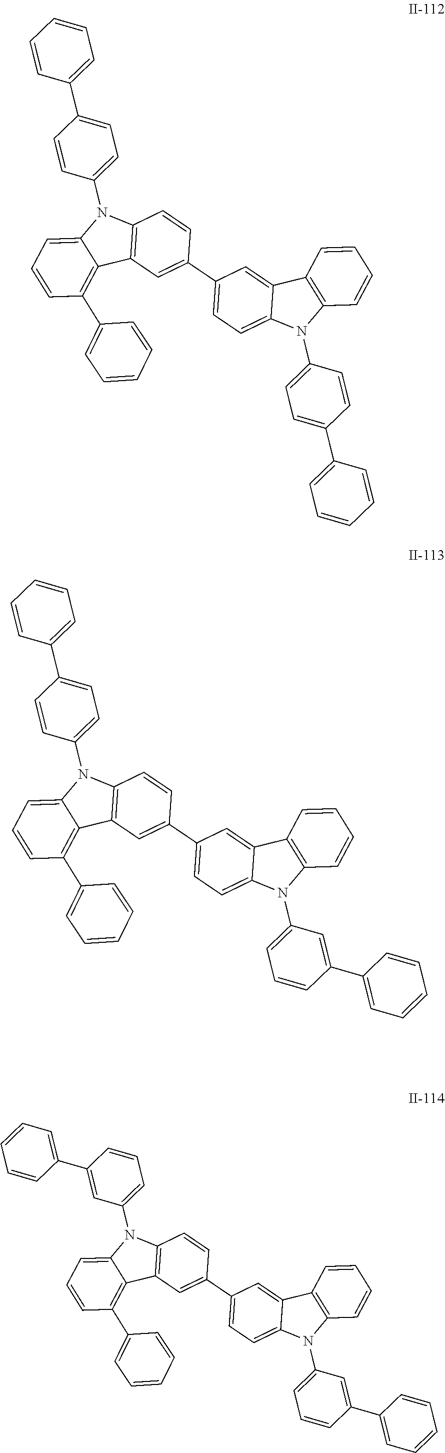 [SMILES: c1ccc(-c2ccc(-n3c4ccccc4c4cc(-c5ccc6c(c5)c5c(-c7ccccc7)cccc5n6-c5ccc(-c6ccccc6)cc5)ccc43)cc2)cc1 ; c1ccc(-c2ccc(-n3c4ccc(-c5ccc6c(c5)c5ccccc5n6-c5cccc(-c6ccccc6)c5)cc4c4c(-c5ccccc5)cccc43)cc2)cc1 ; c1ccc(-c2cccc(-n3c4ccccc4c4cc(-c5ccc6c(c5)c5c(-c7ccccc7)cccc5n6-c5cccc(-c6ccccc6)c5)ccc43)c2)cc1]

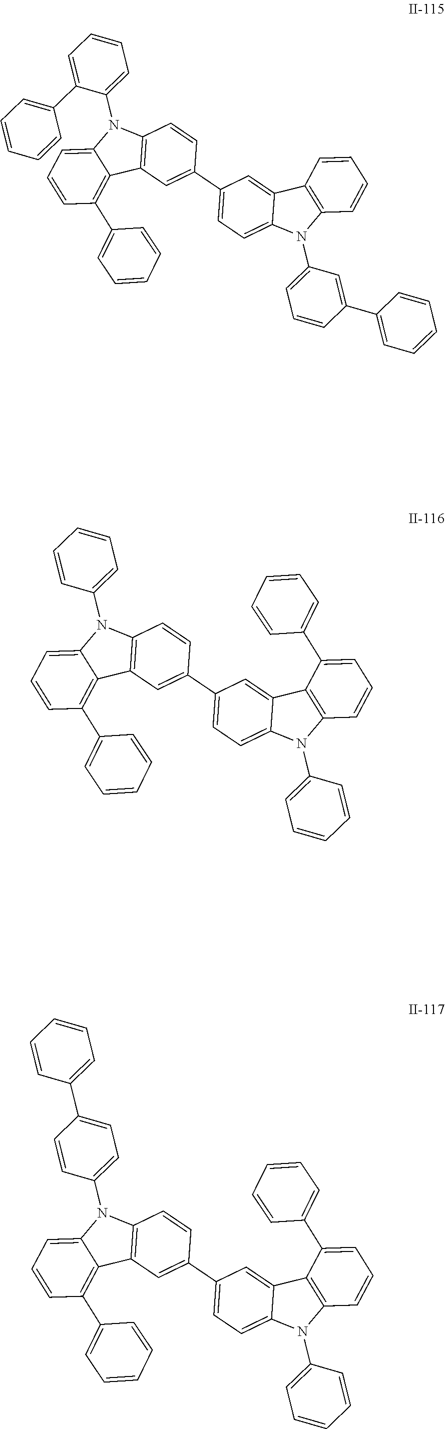 [SMILES: c1ccc(-c2cccc(-n3c4ccccc4c4cc(-c5ccc6c(c5)c5c(-c7ccccc7)cccc5n6-c5ccccc5-c5ccccc5)ccc43)c2)cc1 ; c1ccc(-c2cccc3c2c2cc(-c4ccc5c(c4)c4c(-c6ccccc6)cccc4n5-c4ccccc4)ccc2n3-c2ccccc2)cc1 ; c1ccc(-c2ccc(-n3c4ccc(-c5ccc6c(c5)c5c(-c7ccccc7)cccc5n6-c5ccccc5)cc4c4c(-c5ccccc5)cccc43)cc2)cc1]

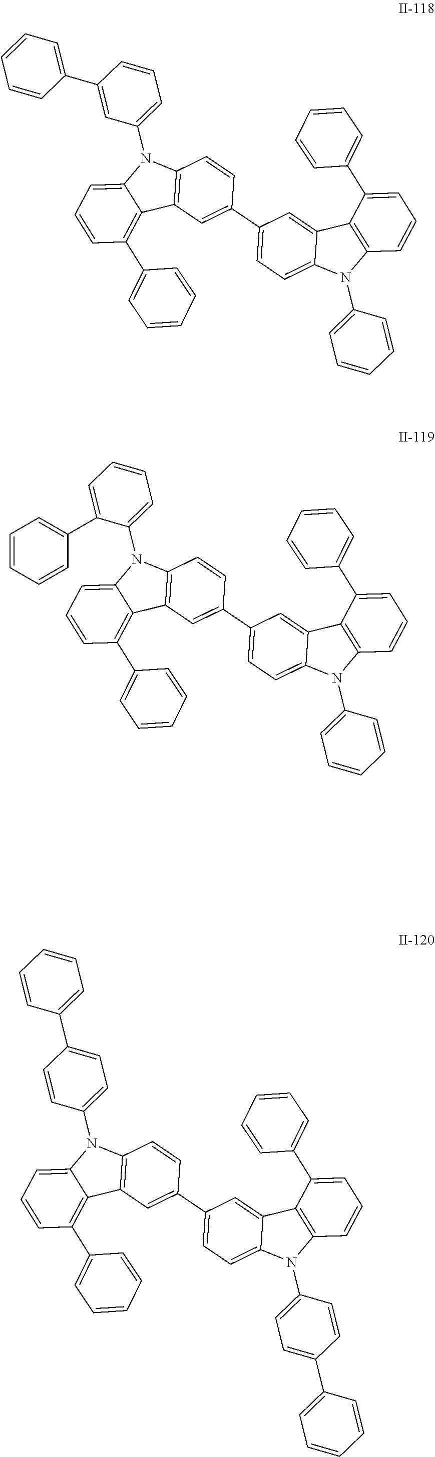 [SMILES: c1ccc(-c2cccc(-n3c4ccc(-c5ccc6c(c5)c5c(-c7ccccc7)cccc5n6-c5ccccc5)cc4c4c(-c5ccccc5)cccc43)c2)cc1 ; c1ccc(-c2ccccc2-n2c3ccc(-c4ccc5c(c4)c4c(-c6ccccc6)cccc4n5-c4ccccc4)cc3c3c(-c4ccccc4)cccc32)cc1 ; c1ccc(-c2ccc(-n3c4ccc(-c5ccc6c(c5)c5c(-c7ccccc7)cccc5n6-c5ccc(-c6ccccc6)cc5)cc4c4c(-c5ccccc5)cccc43)cc2)cc1]

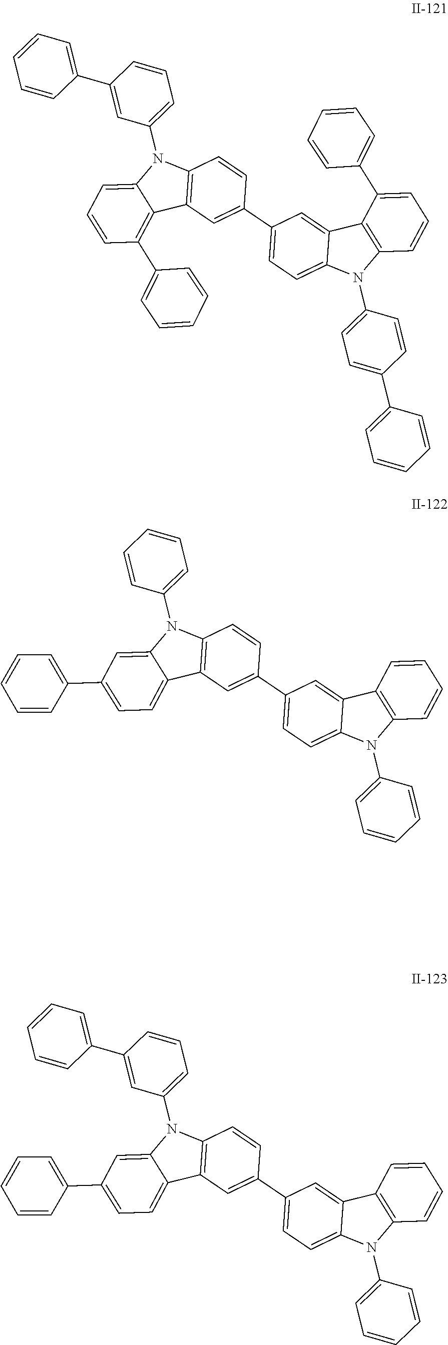 [SMILES: c1ccc(-c2ccc(-n3c4ccc(-c5ccc6c(c5)c5c(-c7ccccc7)cccc5n6-c5cccc(-c6ccccc6)c5)cc4c4c(-c5ccccc5)cccc43)cc2)cc1 ; c1ccc(-c2ccc3c4cc(-c5ccc6c(c5)c5ccccc5n6-c5ccccc5)ccc4n(-c4ccccc4)c3c2)cc1 ; c1ccc(-c2cccc(-n3c4ccc(-c5ccc6c(c5)c5ccccc5n6-c5ccccc5)cc4c4ccc(-c5ccccc5)cc43)c2)cc1]

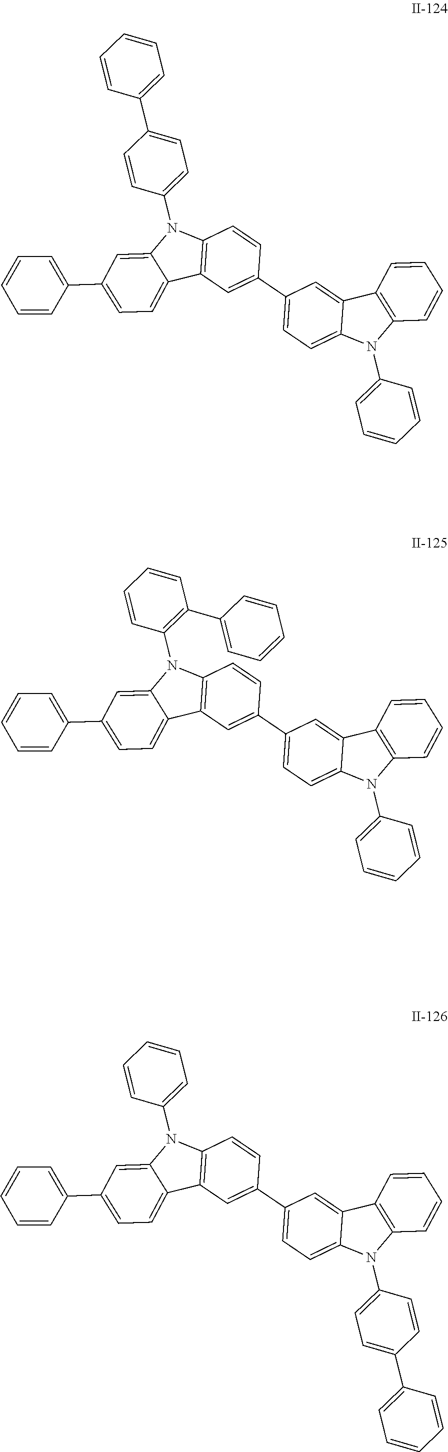 [SMILES: c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc3c4cc(-c5ccc6c(c5)c5ccccc5n6-c5ccccc5)ccc4n(-c4ccccc4-c4ccccc4)c3c2)cc1 ; c1ccc(-c2ccc(-n3c4ccccc4c4cc(-c5ccc6c(c5)c5ccc(-c7ccccc7)cc5n6-c5ccccc5)ccc43)cc2)cc1]

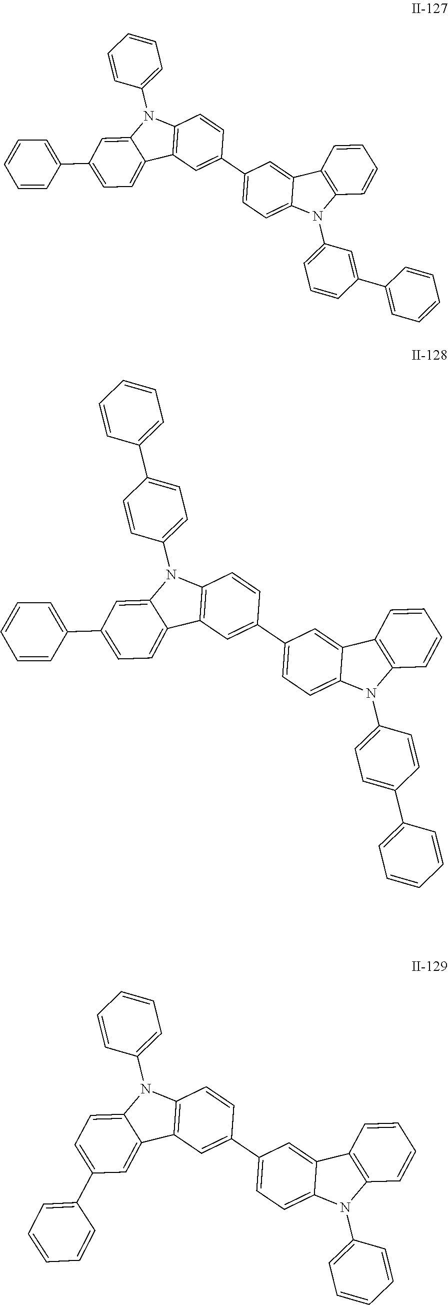 [SMILES: c1ccc(-c2cccc(-n3c4ccccc4c4cc(-c5ccc6c(c5)c5ccc(-c7ccccc7)cc5n6-c5ccccc5)ccc43)c2)cc1 ; c1ccc(-c2ccc(-n3c4ccccc4c4cc(-c5ccc6c(c5)c5ccc(-c7ccccc7)cc5n6-c5ccc(-c6ccccc6)cc5)ccc43)cc2)cc1 ; c1ccc(-c2ccc3c(c2)c2cc(-c4ccc5c(c4)c4ccccc4n5-c4ccccc4)ccc2n3-c2ccccc2)cc1]

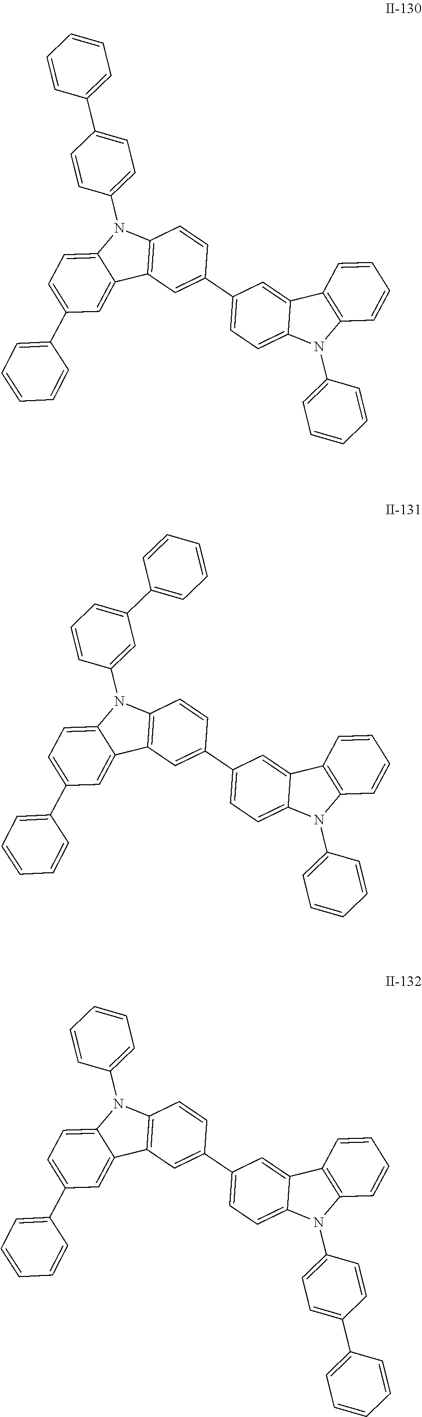 [SMILES: c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2cccc(-n3c4ccc(-c5ccccc5)cc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5cc(-c7ccccc7)ccc5n6-c5ccccc5)ccc43)cc2)cc1]

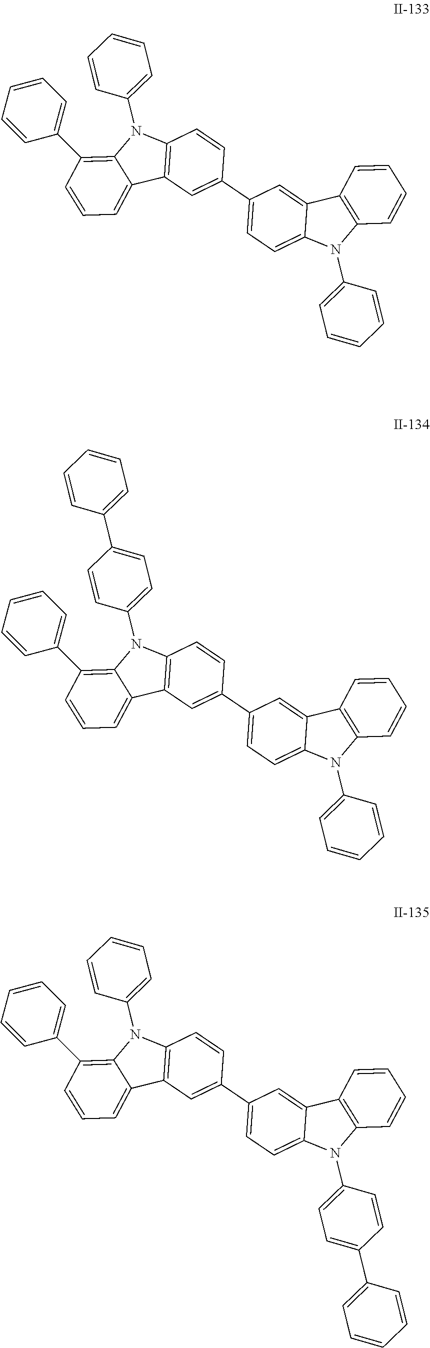 [SMILES: c1ccc(-c2cccc3c4cc(-c5ccc6c(c5)c5ccccc5n6-c5ccccc5)ccc4n(-c4ccccc4)c23)cc1 ; c1ccc(-c2ccc(-n3c4ccc(-c5ccc6c(c5)c5ccccc5n6-c5ccccc5)cc4c4cccc(-c5ccccc5)c43)cc2)cc1 ; c1ccc(-c2ccc(-n3c4ccccc4c4cc(-c5ccc6c(c5)c5cccc(-c7ccccc7)c5n6-c5ccccc5)ccc43)cc2)cc1]

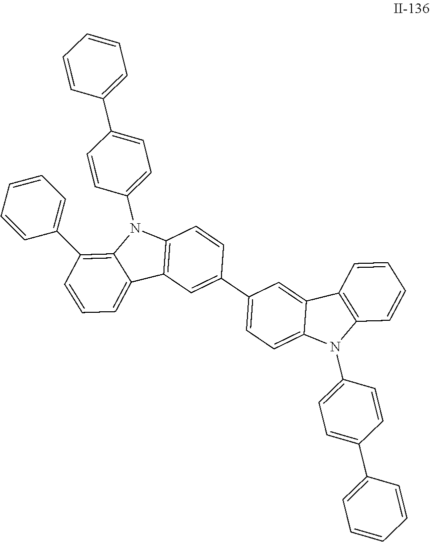 [SMILES: c1ccc(-c2ccc(-n3c4ccccc4c4cc(-c5ccc6c(c5)c5cccc(-c7ccccc7)c5n6-c5ccc(-c6ccccc6)cc5)ccc43)cc2)cc1]

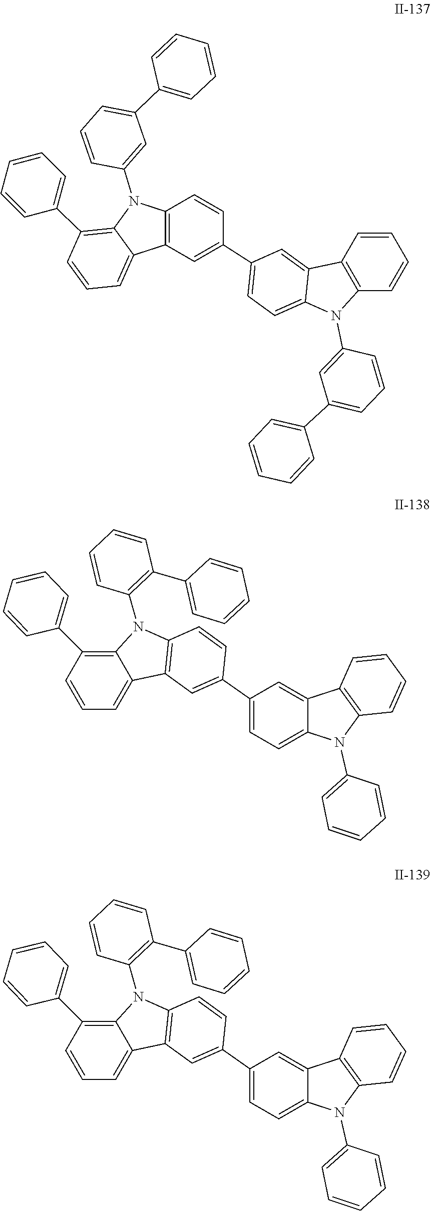 [SMILES: c1ccc(-c2cccc(-n3c4ccccc4c4cc(-c5ccc6c(c5)c5cccc(-c7ccccc7)c5n6-c5cccc(-c6ccccc6)c5)ccc43)c2)cc1 ; c1ccc(-c2ccccc2-n2c3ccc(-c4ccc5c(c4)c4ccccc4n5-c4ccccc4)cc3c3cccc(-c4ccccc4)c32)cc1 ; c1ccc(-c2ccccc2-n2c3ccc(-c4ccc5c(c4)c4ccccc4n5-c4ccccc4)cc3c3cccc(-c4ccccc4)c32)cc1]

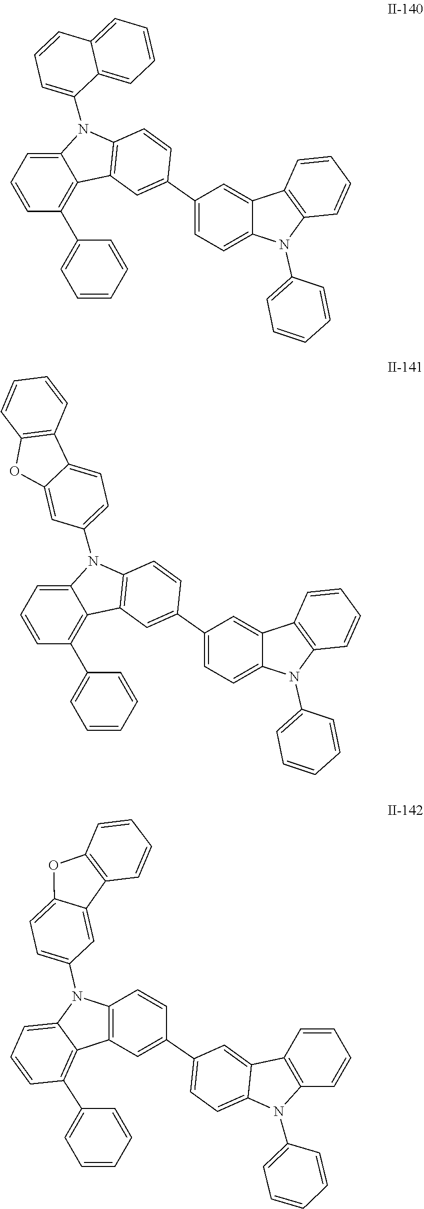 [SMILES: c1ccc(-c2cccc3c2c2cc(-c4ccc5c(c4)c4ccccc4n5-c4ccccc4)ccc2n3-c2cccc3ccccc23)cc1 ; c1ccc(-c2cccc3c2c2cc(-c4ccc5c(c4)c4ccccc4n5-c4ccccc4)ccc2n3-c2ccc3c(c2)oc2ccccc23)cc1 ; c1ccc(-c2cccc3c2c2cc(-c4ccc5c(c4)c4ccccc4n5-c4ccccc4)ccc2n3-c2ccc3oc4ccccc4c3c2)cc1]

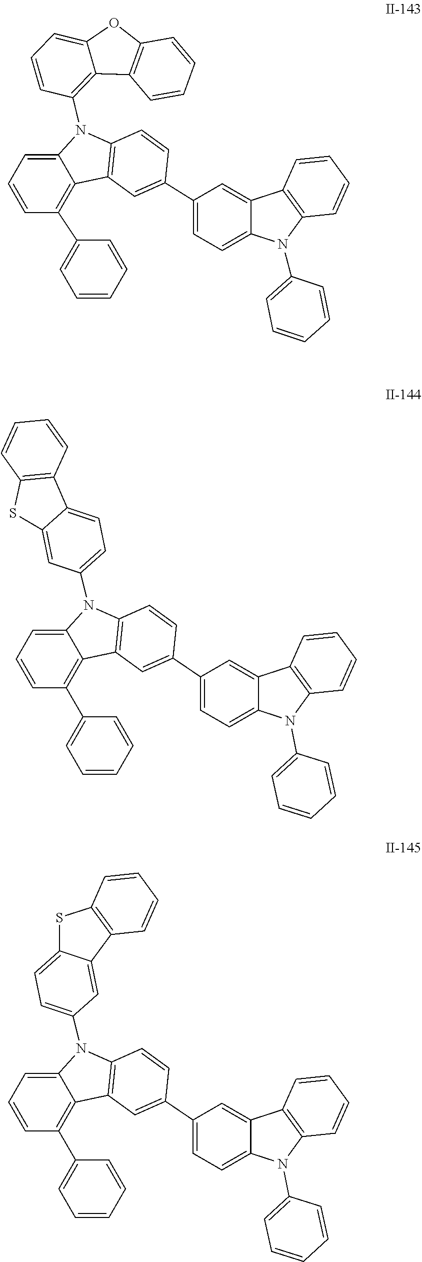 [SMILES: c1ccc(-c2cccc3c2c2cc(-c4ccc5c(c4)c4ccccc4n5-c4ccccc4)ccc2n3-c2cccc3oc4ccccc4c23)cc1 ; c1ccc(-c2cccc3c2c2cc(-c4ccc5c(c4)c4ccccc4n5-c4ccccc4)ccc2n3-c2ccc3c(c2)sc2ccccc23)cc1 ; c1ccc(-c2cccc3c2c2cc(-c4ccc5c(c4)c4ccccc4n5-c4ccccc4)ccc2n3-c2ccc3sc4ccccc4c3c2)cc1]

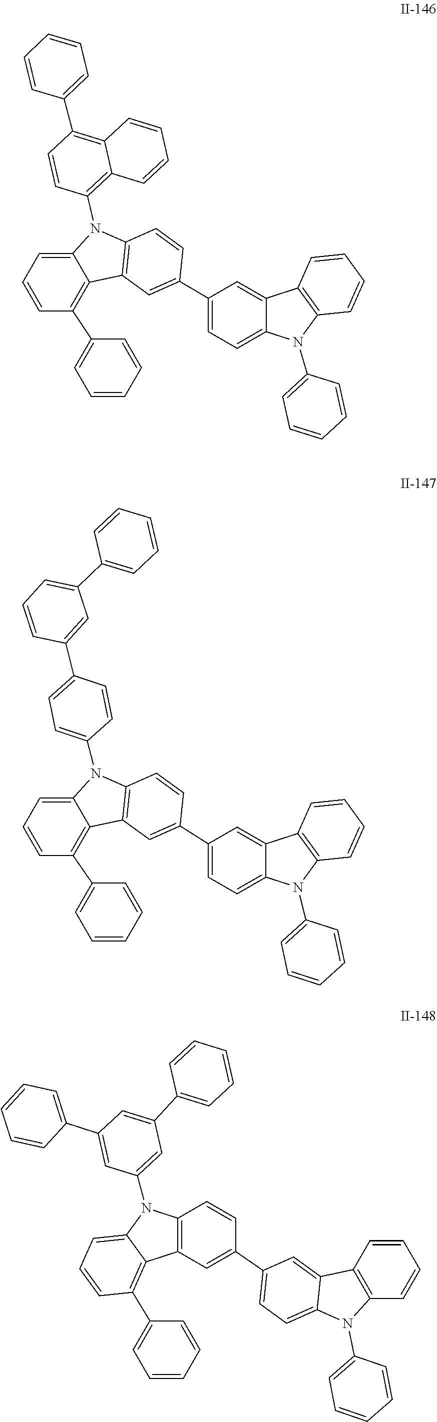 [SMILES: c1ccc(-c2ccc(-n3c4ccc(-c5ccc6c(c5)c5ccccc5n6-c5ccccc5)cc4c4c(-c5ccccc5)cccc43)c3ccccc23)cc1 ; c1ccc(-c2cccc(-c3ccc(-n4c5ccc(-c6ccc7c(c6)c6ccccc6n7-c6ccccc6)cc5c5c(-c6ccccc6)cccc54)cc3)c2)cc1 ; c1ccc(-c2cc(-c3ccccc3)cc(-n3c4ccc(-c5ccc6c(c5)c5ccccc5n6-c5ccccc5)cc4c4c(-c5ccccc5)cccc43)c2)cc1]

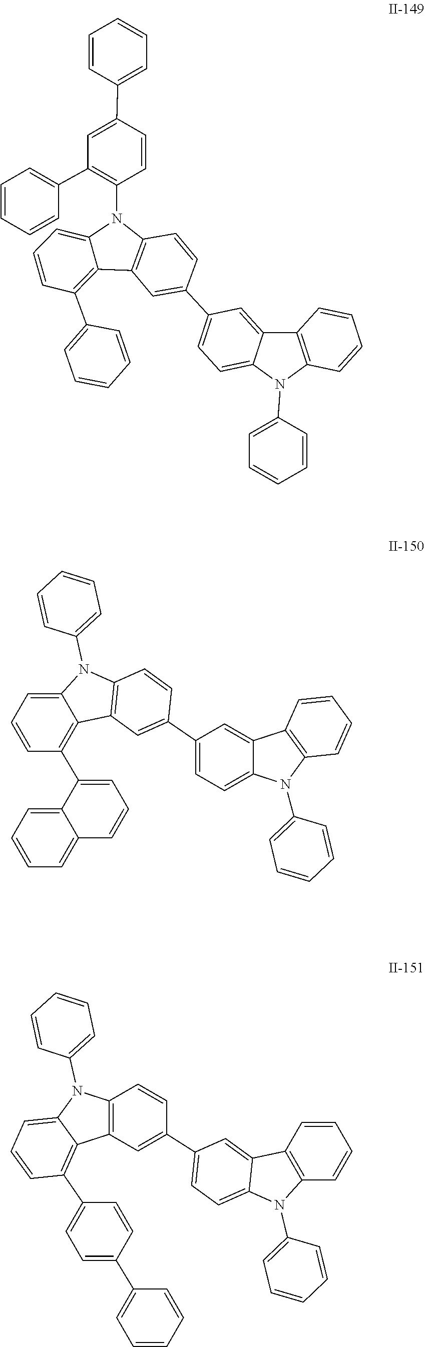 [SMILES: c1ccc(-c2ccc(-n3c4ccc(-c5ccc6c(c5)c5ccccc5n6-c5ccccc5)cc4c4c(-c5ccccc5)cccc43)c(-c3ccccc3)c2)cc1 ; c1ccc(-n2c3ccccc3c3cc(-c4ccc5c(c4)c4c(-c6cccc7ccccc67)cccc4n5-c4ccccc4)ccc32)cc1 ; c1ccc(-c2ccc(-c3cccc4c3c3cc(-c5ccc6c(c5)c5ccccc5n6-c5ccccc5)ccc3n4-c3ccccc3)cc2)cc1]

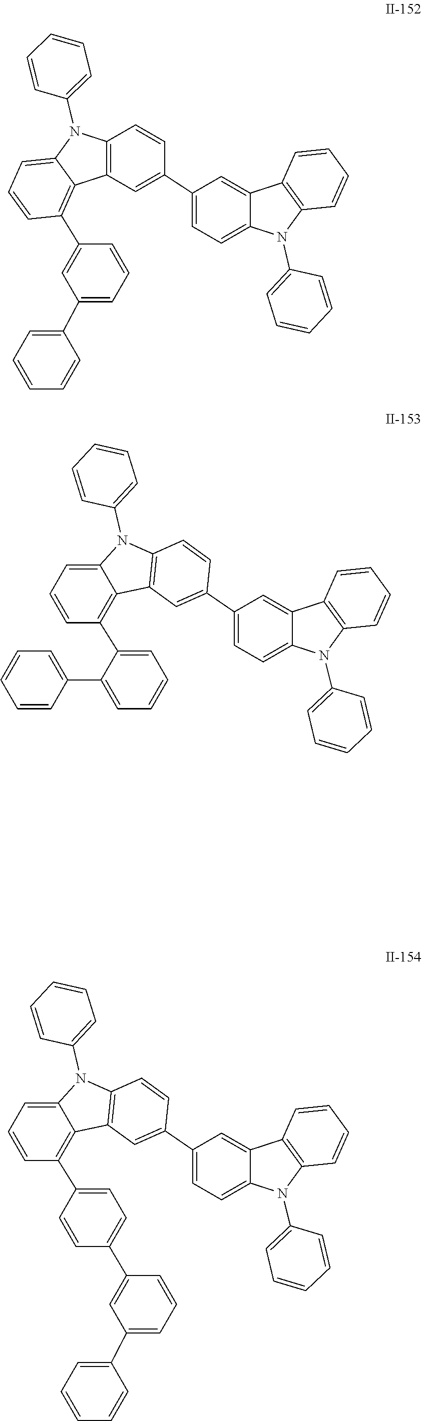 [SMILES: c1ccc(-c2cccc(-c3cccc4c3c3cc(-c5ccc6c(c5)c5ccccc5n6-c5ccccc5)ccc3n4-c3ccccc3)c2)cc1 ; c1ccc(-c2ccccc2-c2cccc3c2c2cc(-c4ccc5c(c4)c4ccccc4n5-c4ccccc4)ccc2n3-c2ccccc2)cc1 ; c1ccc(-c2cccc(-c3ccc(-c4cccc5c4c4cc(-c6ccc7c(c6)c6ccccc6n7-c6ccccc6)ccc4n5-c4ccccc4)cc3)c2)cc1]

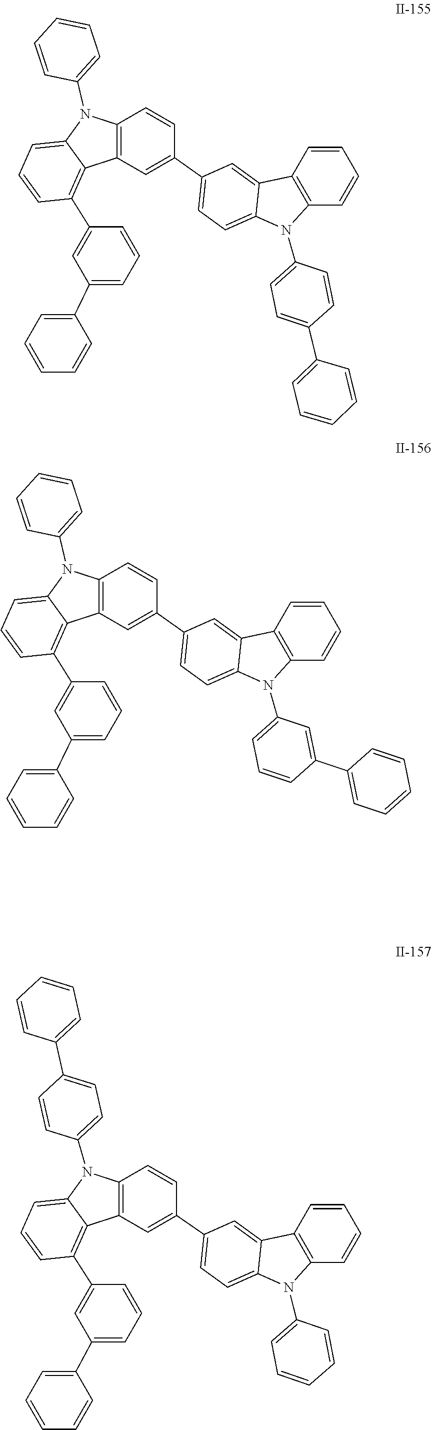 [SMILES: c1ccc(-c2ccc(-n3c4ccccc4c4cc(-c5ccc6c(c5)c5c(-c7cccc(-c8ccccc8)c7)cccc5n6-c5ccccc5)ccc43)cc2)cc1 ; c1ccc(-c2cccc(-c3cccc4c3c3cc(-c5ccc6c(c5)c5ccccc5n6-c5cccc(-c6ccccc6)c5)ccc3n4-c3ccccc3)c2)cc1 ; c1ccc(-c2ccc(-n3c4ccc(-c5ccc6c(c5)c5ccccc5n6-c5ccccc5)cc4c4c(-c5cccc(-c6ccccc6)c5)cccc43)cc2)cc1]

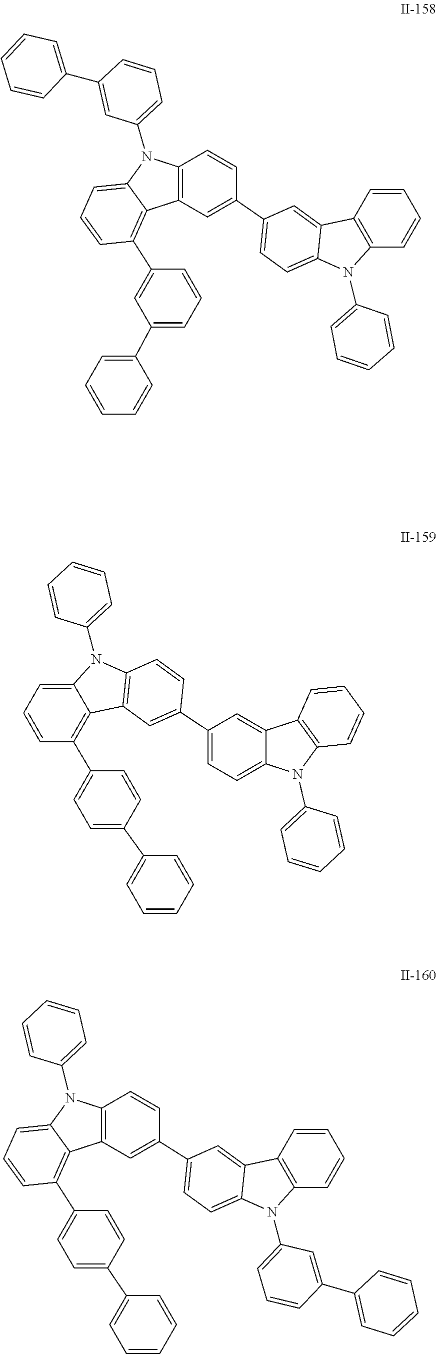 [SMILES: c1ccc(-c2cccc(-c3cccc4c3c3cc(-c5ccc6c(c5)c5ccccc5n6-c5ccccc5)ccc3n4-c3cccc(-c4ccccc4)c3)c2)cc1 ; c1ccc(-c2ccc(-c3cccc4c3c3cc(-c5ccc6c(c5)c5ccccc5n6-c5ccccc5)ccc3n4-c3ccccc3)cc2)cc1 ; c1ccc(-c2ccc(-c3cccc4c3c3cc(-c5ccc6c(c5)c5ccccc5n6-c5cccc(-c6ccccc6)c5)ccc3n4-c3ccccc3)cc2)cc1]

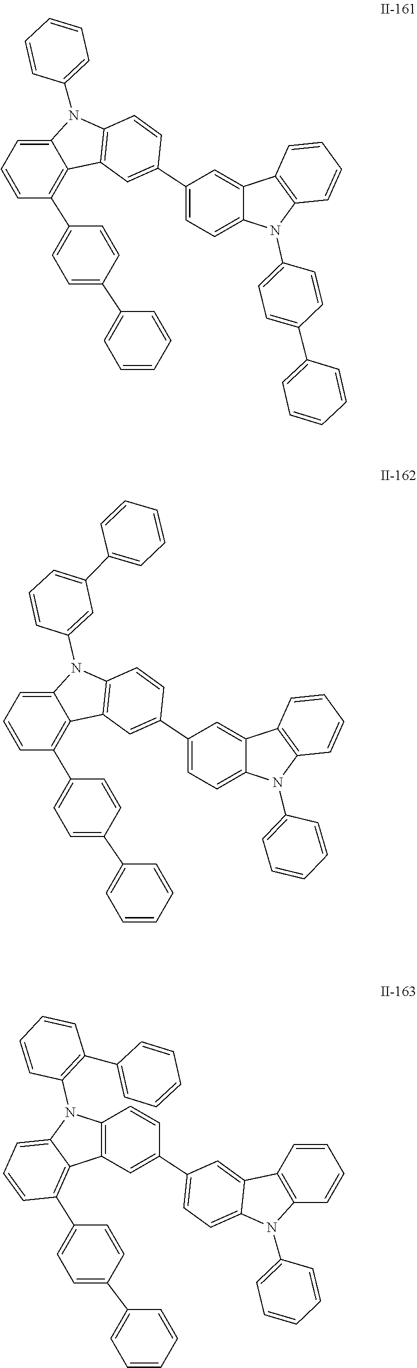 [SMILES: c1ccc(-c2ccc(-c3cccc4c3c3cc(-c5ccc6c(c5)c5ccccc5n6-c5ccc(-c6ccccc6)cc5)ccc3n4-c3ccccc3)cc2)cc1 ; c1ccc(-c2ccc(-c3cccc4c3c3cc(-c5ccc6c(c5)c5ccccc5n6-c5ccccc5)ccc3n4-c3cccc(-c4ccccc4)c3)cc2)cc1 ; c1ccc(-c2ccc(-c3cccc4c3c3cc(-c5ccc6c(c5)c5ccccc5n6-c5ccccc5)ccc3n4-c3ccccc3-c3ccccc3)cc2)cc1]

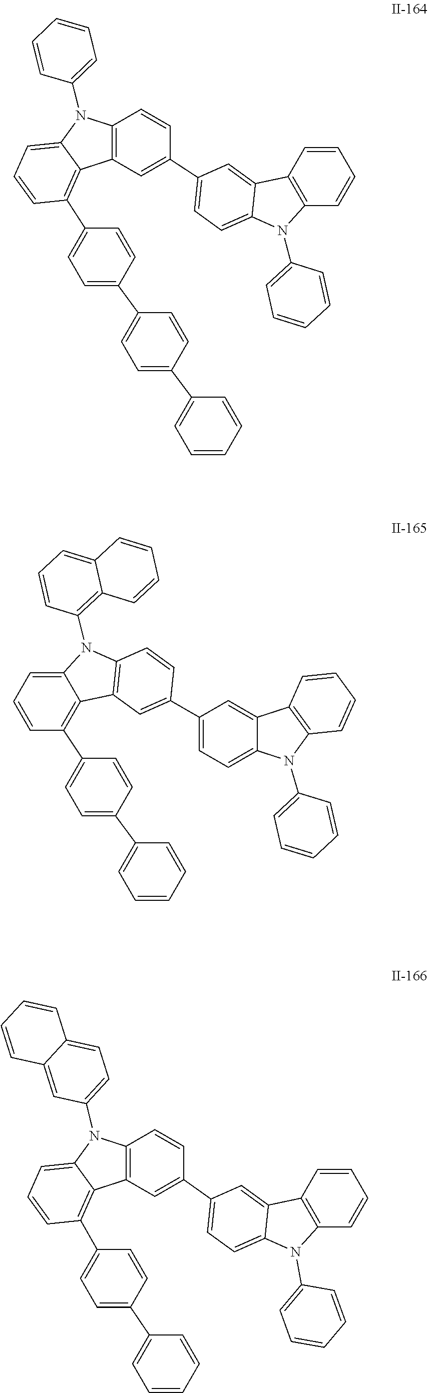 [SMILES: c1ccc(-c2ccc(-c3ccc(-c4cccc5c4c4cc(-c6ccc7c(c6)c6ccccc6n7-c6ccccc6)ccc4n5-c4ccccc4)cc3)cc2)cc1 ; c1ccc(-c2ccc(-c3cccc4c3c3cc(-c5ccc6c(c5)c5ccccc5n6-c5ccccc5)ccc3n4-c3cccc4ccccc34)cc2)cc1 ; c1ccc(-c2ccc(-c3cccc4c3c3cc(-c5ccc6c(c5)c5ccccc5n6-c5ccccc5)ccc3n4-c3ccc4ccccc4c3)cc2)cc1]

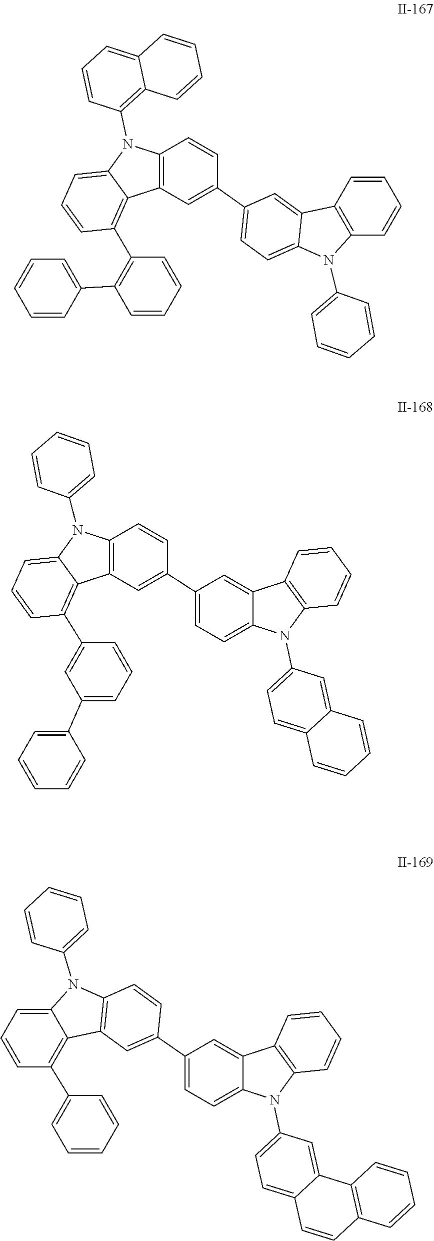 [SMILES: c1ccc(-c2ccccc2-c2cccc3c2c2cc(-c4ccc5c(c4)c4ccccc4n5-c4ccccc4)ccc2n3-c2cccc3ccccc23)cc1 ; c1ccc(-c2cccc(-c3cccc4c3c3cc(-c5ccc6c(c5)c5ccccc5n6-c5ccc6ccccc6c5)ccc3n4-c3ccccc3)c2)cc1 ; c1ccc(-c2cccc3c2c2cc(-c4ccc5c(c4)c4ccccc4n5-c4ccc5ccc6ccccc6c5c4)ccc2n3-c2ccccc2)cc1]

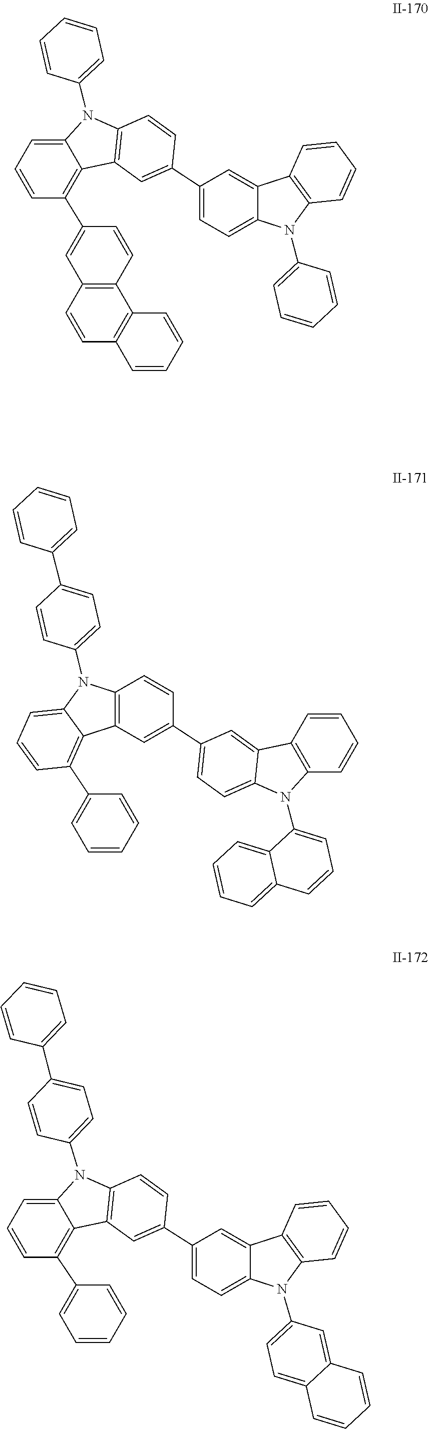 [SMILES: c1ccc(-n2c3ccccc3c3cc(-c4ccc5c(c4)c4c(-c6ccc7c(ccc8ccccc87)c6)cccc4n5-c4ccccc4)ccc32)cc1 ; c1ccc(-c2ccc(-n3c4ccc(-c5ccc6c(c5)c5ccccc5n6-c5cccc6ccccc56)cc4c4c(-c5ccccc5)cccc43)cc2)cc1 ; c1ccc(-c2ccc(-n3c4ccc(-c5ccc6c(c5)c5ccccc5n6-c5ccc6ccccc6c5)cc4c4c(-c5ccccc5)cccc43)cc2)cc1]

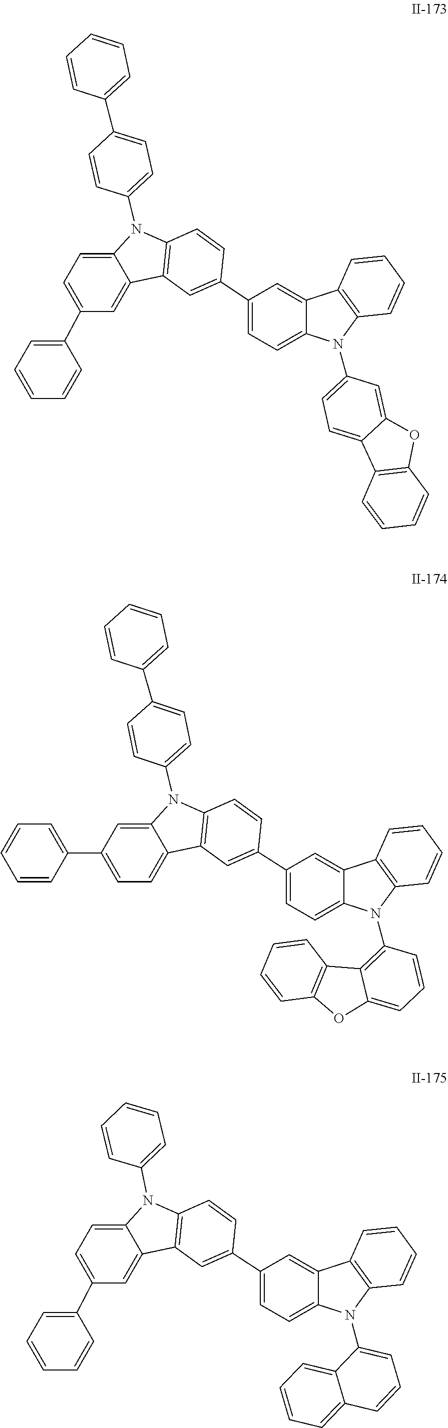

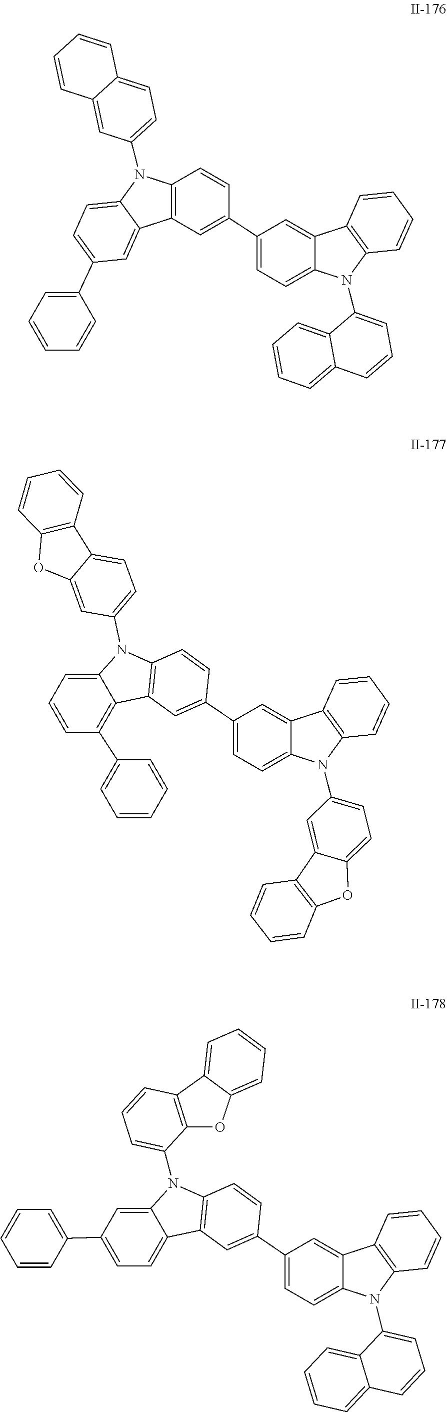 [SMILES: c1ccc(-c2ccc3c(c2)c2cc(-c4ccc5c(c4)c4ccccc4n5-c4cccc5ccccc45)ccc2n3-c2ccc3ccccc3c2)cc1 ; c1ccc(-c2cccc3c2c2cc(-c4ccc5c(c4)c4ccccc4n5-c4ccc5oc6ccccc6c5c4)ccc2n3-c2ccc3c(c2)oc2ccccc23)cc1 ; c1ccc(-c2ccc3c4cc(-c5ccc6c(c5)c5ccccc5n6-c5cccc6ccccc56)ccc4n(-c4cccc5c4oc4ccccc45)c3c2)cc1]

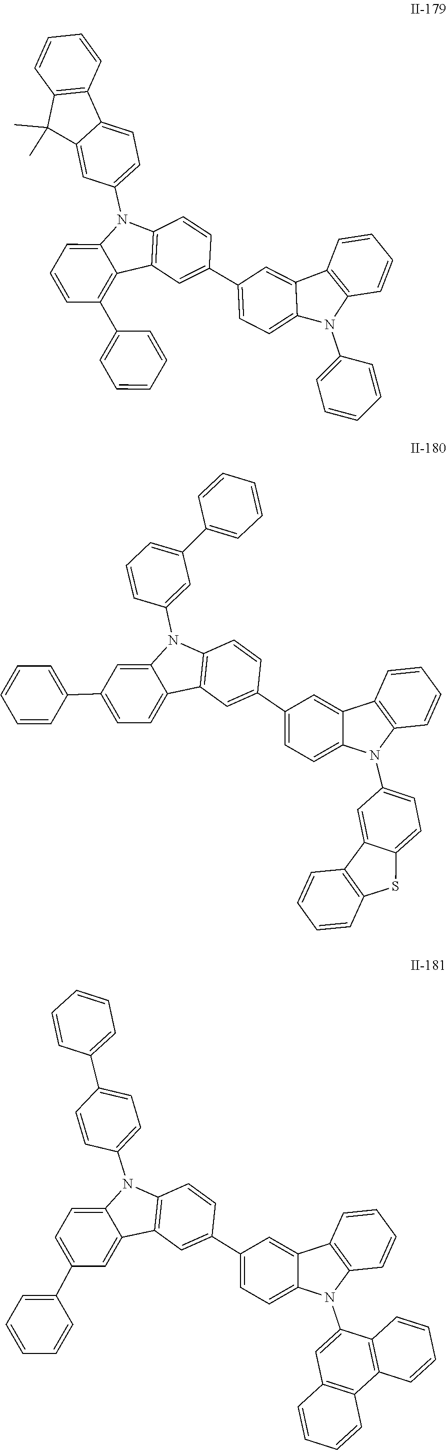 [SMILES: CC1(C)c2ccccc2-c2ccc(-n3c4ccc(-c5ccc6c(c5)c5ccccc5n6-c5ccccc5)cc4c4c(-c5ccccc5)cccc43)cc21 ; c1ccc(-c2cccc(-n3c4ccc(-c5ccc6c(c5)c5ccccc5n6-c5ccc6sc7ccccc7c6c5)cc4c4ccc(-c5ccccc5)cc43)c2)cc1 ; c1ccc(-c2ccc(-n3c4ccc(-c5ccccc5)cc4c4cc(-c5ccc6c(c5)c5ccccc5n6-c5cc6ccccc6c6ccccc56)ccc43)cc2)cc1]

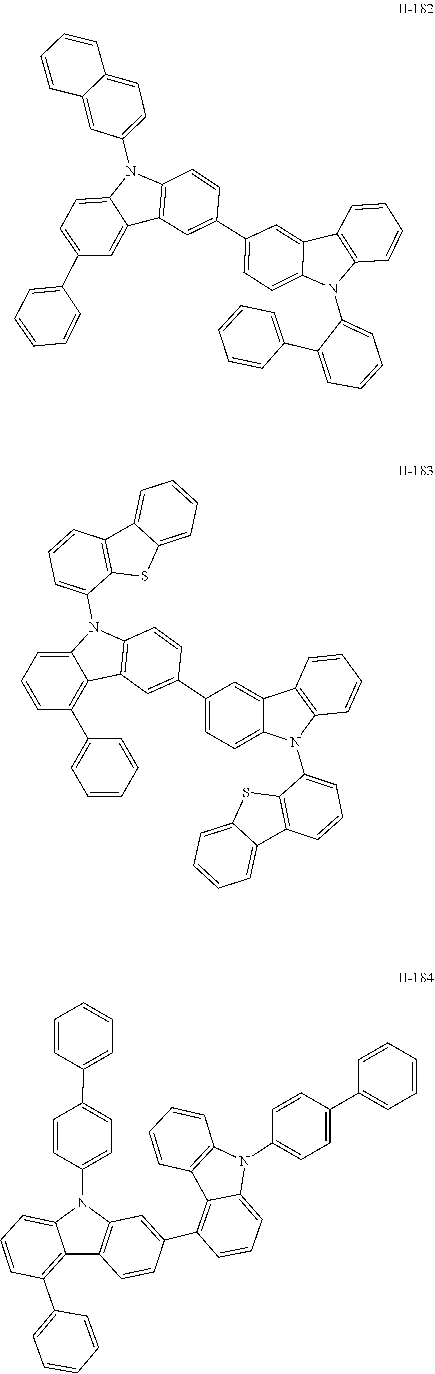 [SMILES: c1ccc(-c2ccc3c(c2)c2cc(-c4ccc5c(c4)c4ccccc4n5-c4ccccc4-c4ccccc4)ccc2n3-c2ccc3ccccc3c2)cc1 ; c1ccc(-c2cccc3c2c2cc(-c4ccc5c(c4)c4ccccc4n5-c4cccc5c4sc4ccccc45)ccc2n3-c2cccc3c2sc2ccccc23)cc1 ; c1ccc(-c2ccc(-n3c4ccccc4c4c(-c5ccc6c7c(-c8ccccc8)cccc7n(-c7ccc(-c8ccccc8)cc7)c6c5)cccc43)cc2)cc1]

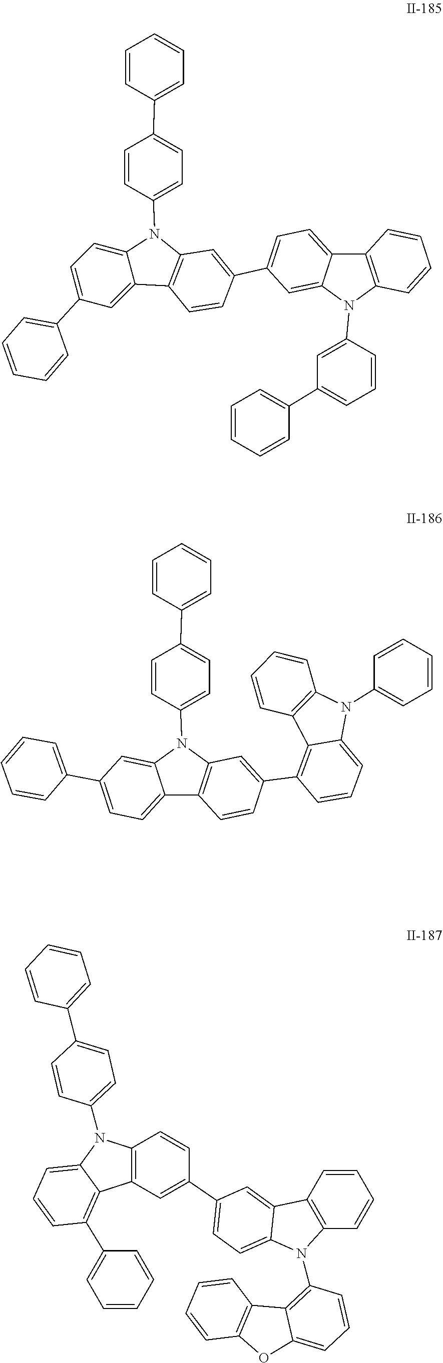 [SMILES: c1ccc(-c2ccc(-n3c4ccc(-c5ccccc5)cc4c4ccc(-c5ccc6c7ccccc7n(-c7cccc(-c8ccccc8)c7)c6c5)cc43)cc2)cc1 ; c1ccc(-c2ccc(-n3c4cc(-c5ccccc5)ccc4c4ccc(-c5cccc6c5c5ccccc5n6-c5ccccc5)cc43)cc2)cc1 ; c1ccc(-c2ccc(-n3c4ccc(-c5ccc6c(c5)c5ccccc5n6-c5cccc6oc7ccccc7c56)cc4c4c(-c5ccccc5)cccc43)cc2)cc1]

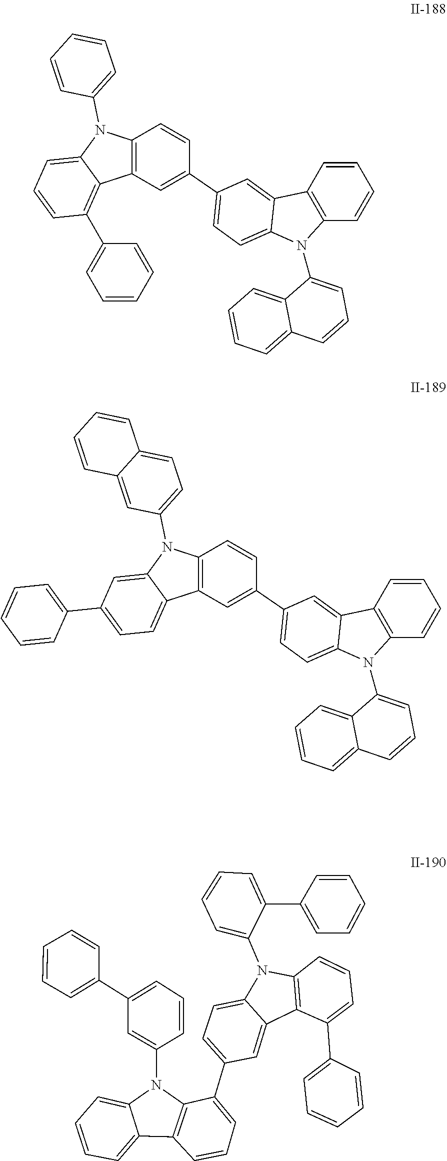 [SMILES: c1ccc(-c2cccc3c2c2cc(-c4ccc5c(c4)c4ccccc4n5-c4cccc5ccccc45)ccc2n3-c2ccccc2)cc1 ; c1ccc(-c2ccc3c4cc(-c5ccc6c(c5)c5ccccc5n6-c5cccc6ccccc56)ccc4n(-c4ccc5ccccc5c4)c3c2)cc1 ; c1ccc(-c2cccc(-n3c4ccccc4c4cccc(-c5ccc6c(c5)c5c(-c7ccccc7)cccc5n6-c5ccccc5-c5ccccc5)c43)c2)cc1]

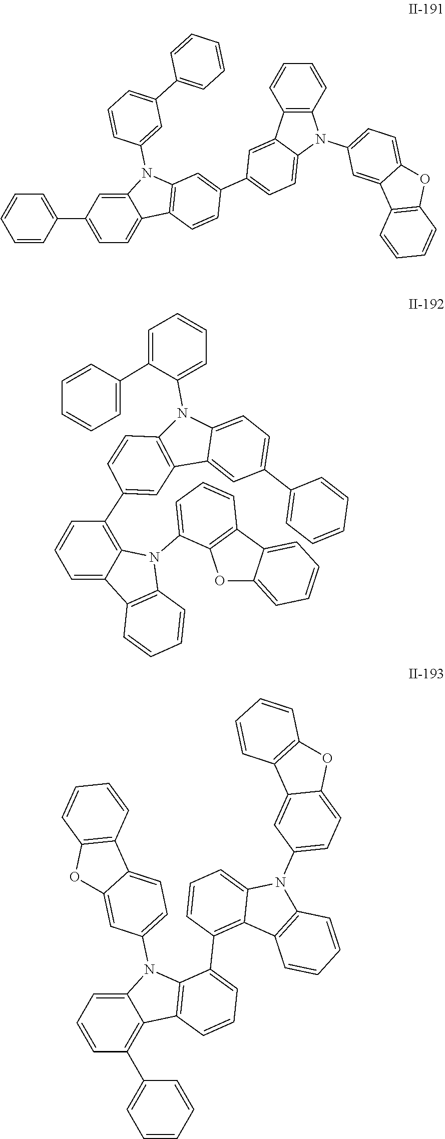 [SMILES: c1ccc(-c2cccc(-n3c4cc(-c5ccccc5)ccc4c4ccc(-c5ccc6c(c5)c5ccccc5n6-c5ccc6oc7ccccc7c6c5)cc43)c2)cc1 ; c1ccc(-c2ccc3c(c2)c2cc(-c4cccc5c6ccccc6n(-c6cccc7c6oc6ccccc67)c45)ccc2n3-c2ccccc2-c2ccccc2)cc1 ; c1ccc(-c2cccc3c2c2cccc(-c4cccc5c4c4ccccc4n5-c4ccc5oc6ccccc6c5c4)c2n3-c2ccc3c(c2)oc2ccccc23)cc1]

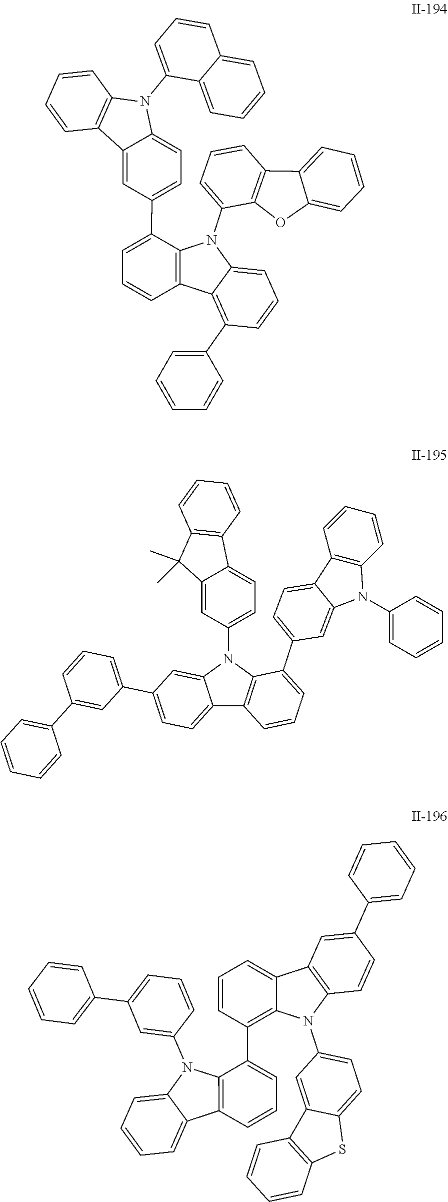 [SMILES: c1ccc(-c2cccc3c2c2cccc(-c4ccc5c(c4)c4ccccc4n5-c4cccc5ccccc45)c2n3-c2cccc3c2oc2ccccc23)cc1 ; CC1(C)c2ccccc2-c2ccc(-n3c4cc(-c5cccc(-c6ccccc6)c5)ccc4c4cccc(-c5ccc6c7ccccc7n(-c7ccccc7)c6c5)c43)cc21 ; c1ccc(-c2cccc(-n3c4ccccc4c4cccc(-c5cccc6c7cc(-c8ccccc8)ccc7n(-c7ccc8sc9ccccc9c8c7)c56)c43)c2)cc1]

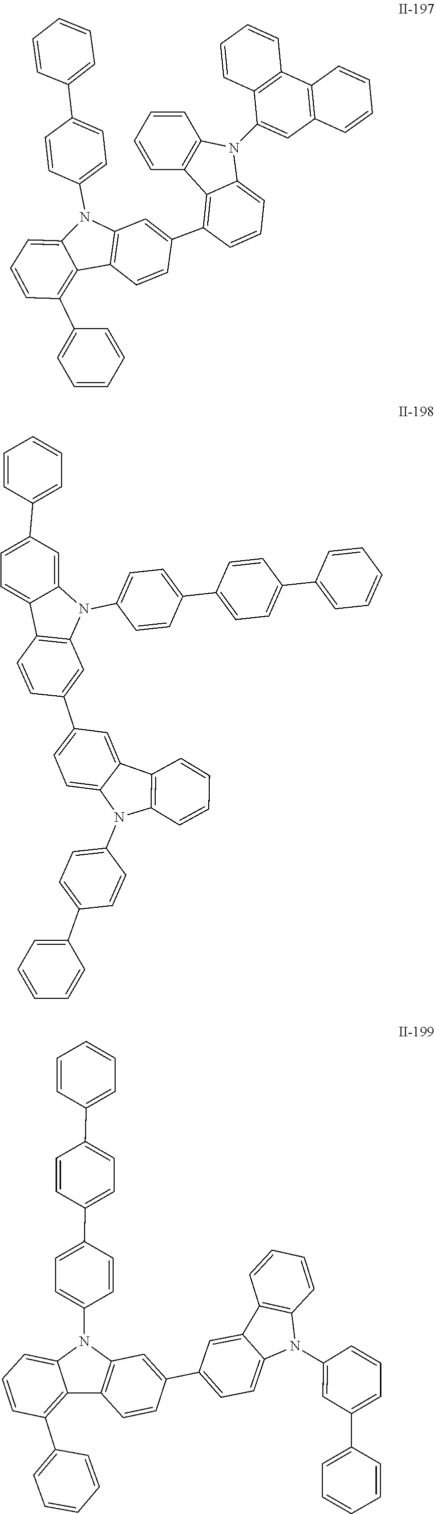 [SMILES: c1ccc(-c2ccc(-n3c4cc(-c5cccc6c5c5ccccc5n6-c5cc6ccccc6c6ccccc56)ccc4c4c(-c5ccccc5)cccc43)cc2)cc1 ; c1ccc(-c2ccc(-c3ccc(-n4c5cc(-c6ccccc6)ccc5c5ccc(-c6ccc7c(c6)c6ccccc6n7-c6ccc(-c7ccccc7)cc6)cc54)cc3)cc2)cc1 ; c1ccc(-c2ccc(-c3ccc(-n4c5cc(-c6ccc7c(c6)c6ccccc6n7-c6cccc(-c7ccccc7)c6)ccc5c5c(-c6ccccc6)cccc54)cc3)cc2)cc1]

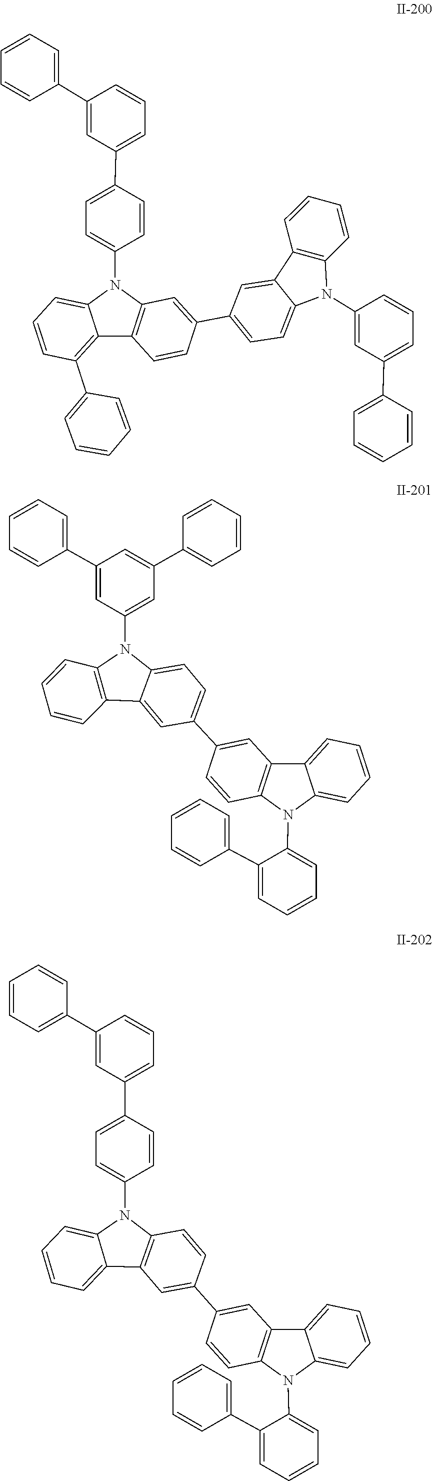 [SMILES: c1ccc(-c2cccc(-c3ccc(-n4c5cc(-c6ccc7c(c6)c6ccccc6n7-c6cccc(-c7ccccc7)c6)ccc5c5c(-c6ccccc6)cccc54)cc3)c2)cc1 ; c1ccc(-c2cc(-c3ccccc3)cc(-n3c4ccccc4c4cc(-c5ccc6c(c5)c5ccccc5n6-c5ccccc5-c5ccccc5)ccc43)c2)cc1 ; c1ccc(-c2cccc(-c3ccc(-n4c5ccccc5c5cc(-c6ccc7c(c6)c6ccccc6n7-c6ccccc6-c6ccccc6)ccc54)cc3)c2)cc1]

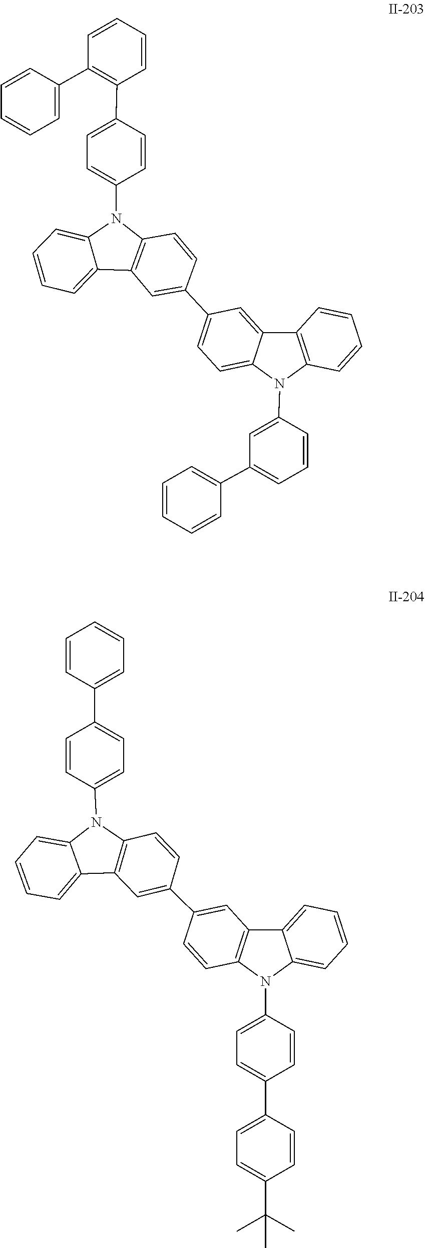 [SMILES: c1ccc(-c2cccc(-n3c4ccccc4c4cc(-c5ccc6c(c5)c5ccccc5n6-c5ccc(-c6ccccc6-c6ccccc6)cc5)ccc43)c2)cc1 ; CC(C)(C)c1ccc(-c2ccc(-n3c4ccccc4c4cc(-c5ccc6c(c5)c5ccccc5n6-c5ccc(-c6ccccc6)cc5)ccc43)cc2)cc1]

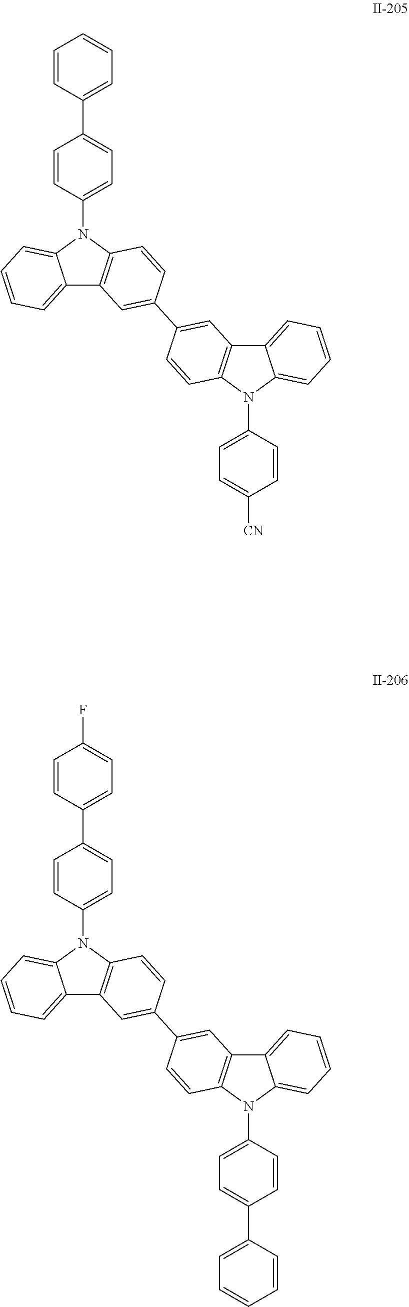 [SMILES: N#Cc1ccc(-n2c3ccccc3c3cc(-c4ccc5c(c4)c4ccccc4n5-c4ccc(-c5ccccc5)cc4)ccc32)cc1 ; Fc1ccc(-c2ccc(-n3c4ccccc4c4cc(-c5ccc6c(c5)c5ccccc5n6-c5ccc(-c6ccccc6)cc5)ccc43)cc2)cc1]

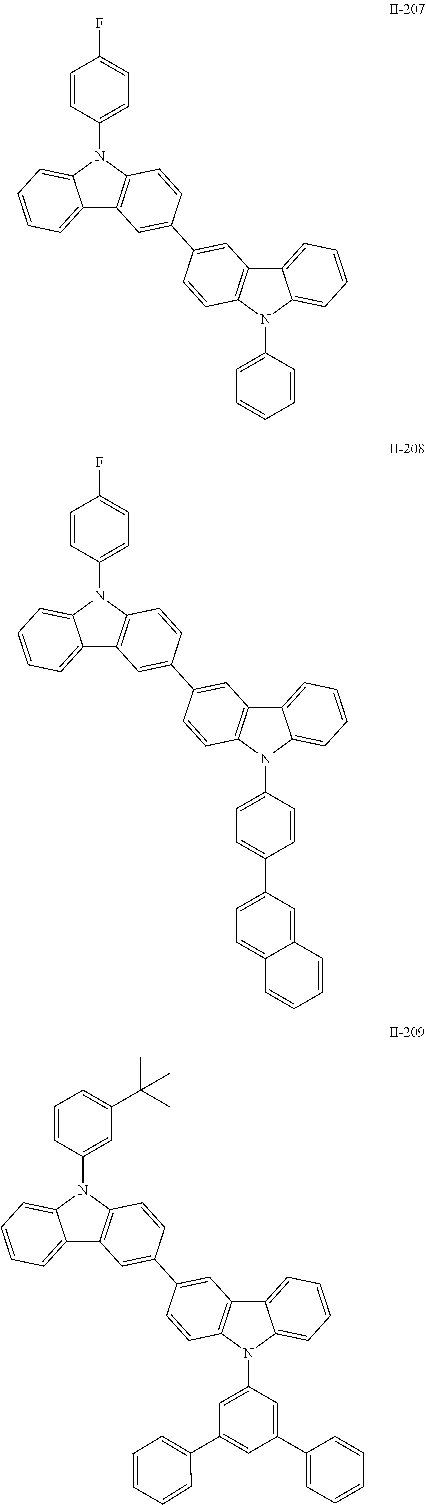 [SMILES: Fc1ccc(-n2c3ccccc3c3cc(-c4ccc5c(c4)c4ccccc4n5-c4ccccc4)ccc32)cc1 ; Fc1ccc(-n2c3ccccc3c3cc(-c4ccc5c(c4)c4ccccc4n5-c4ccc(-c5ccc6ccccc6c5)cc4)ccc32)cc1 ; CC(C)(C)c1cccc(-n2c3ccccc3c3cc(-c4ccc5c(c4)c4ccccc4n5-c4cc(-c5ccccc5)cc(-c5ccccc5)c4)ccc32)c1]

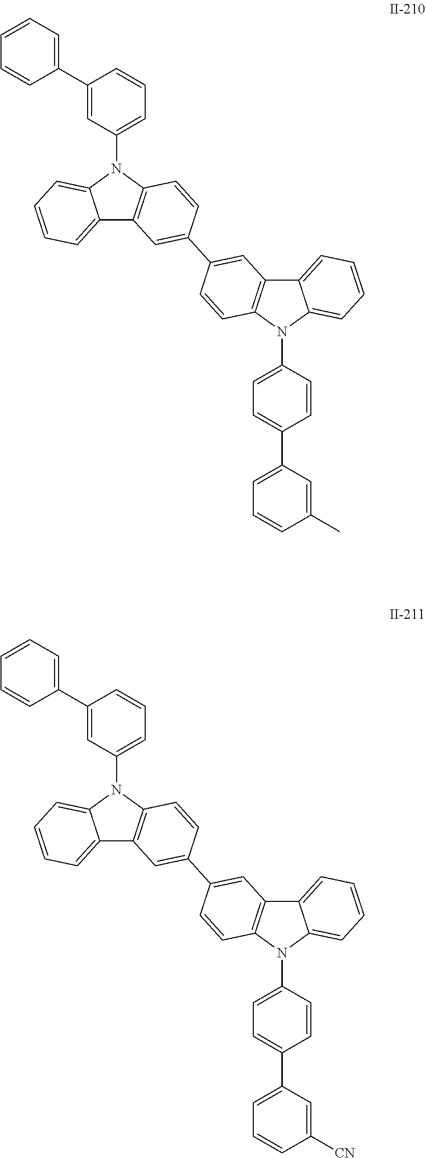 [SMILES: Cc1cccc(-c2ccc(-n3c4ccccc4c4cc(-c5ccc6c(c5)c5ccccc5n6-c5cccc(-c6ccccc6)c5)ccc43)cc2)c1 ; N#Cc1cccc(-c2ccc(-n3c4ccccc4c4cc(-c5ccc6c(c5)c5ccccc5n6-c5cccc(-c6ccccc6)c5)ccc43)cc2)c1]

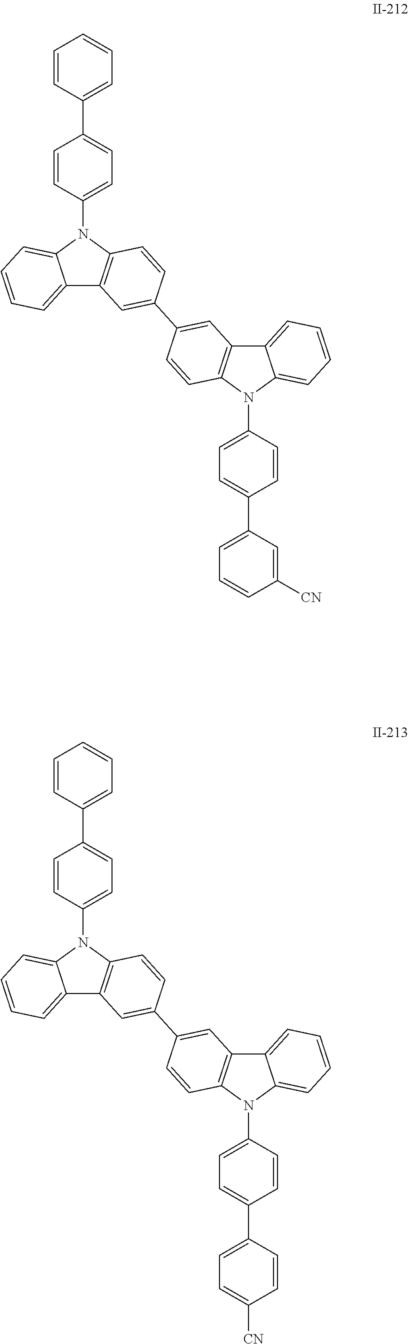 [SMILES: N#Cc1cccc(-c2ccc(-n3c4ccccc4c4cc(-c5ccc6c(c5)c5ccccc5n6-c5ccc(-c6ccccc6)cc5)ccc43)cc2)c1 ; N#Cc1ccc(-c2ccc(-n3c4ccccc4c4cc(-c5ccc6c(c5)c5ccccc5n6-c5ccc(-c6ccccc6)cc5)ccc43)cc2)cc1]

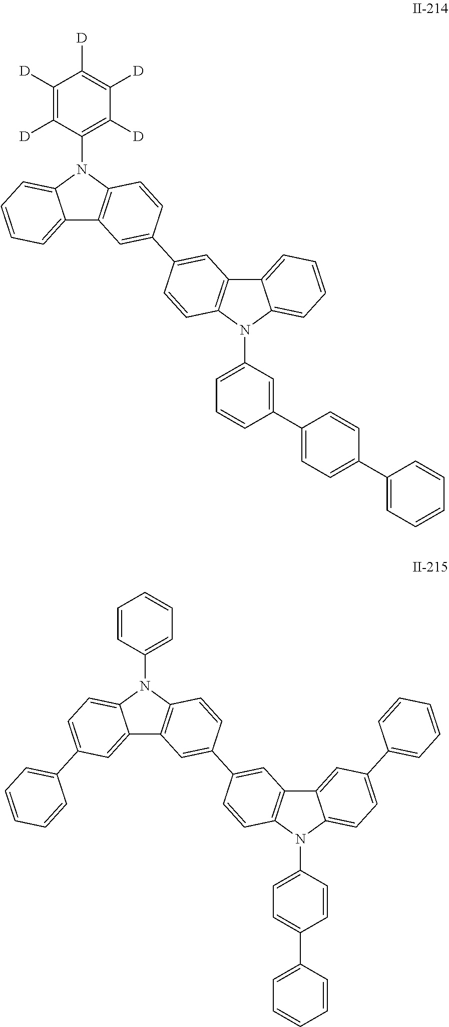 [SMILES: [2H]c1c([2H])c([2H])c(-n2c3ccccc3c3cc(-c4ccc5c(c4)c4ccccc4n5-c4cccc(-c5ccc(-c6ccccc6)cc5)c4)ccc32)c([2H])c1[2H] ; c1ccc(-c2ccc(-n3c4ccc(-c5ccccc5)cc4c4cc(-c5ccc6c(c5)c5cc(-c7ccccc7)ccc5n6-c5ccccc5)ccc43)cc2)cc1]

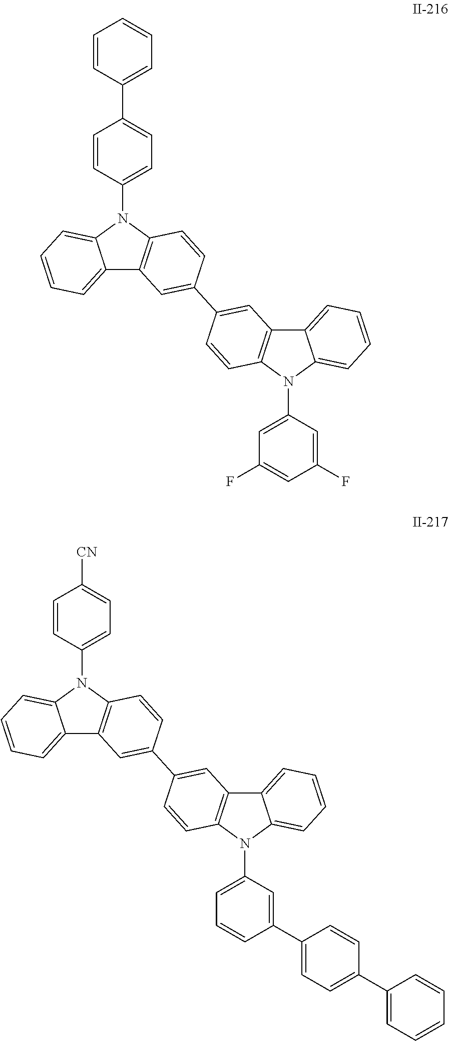 [SMILES: Fc1cc(F)cc(-n2c3ccccc3c3cc(-c4ccc5c(c4)c4ccccc4n5-c4ccc(-c5ccccc5)cc4)ccc32)c1 ; N#Cc1ccc(-n2c3ccccc3c3cc(-c4ccc5c(c4)c4ccccc4n5-c4cccc(-c5ccc(-c6ccccc6)cc5)c4)ccc32)cc1]

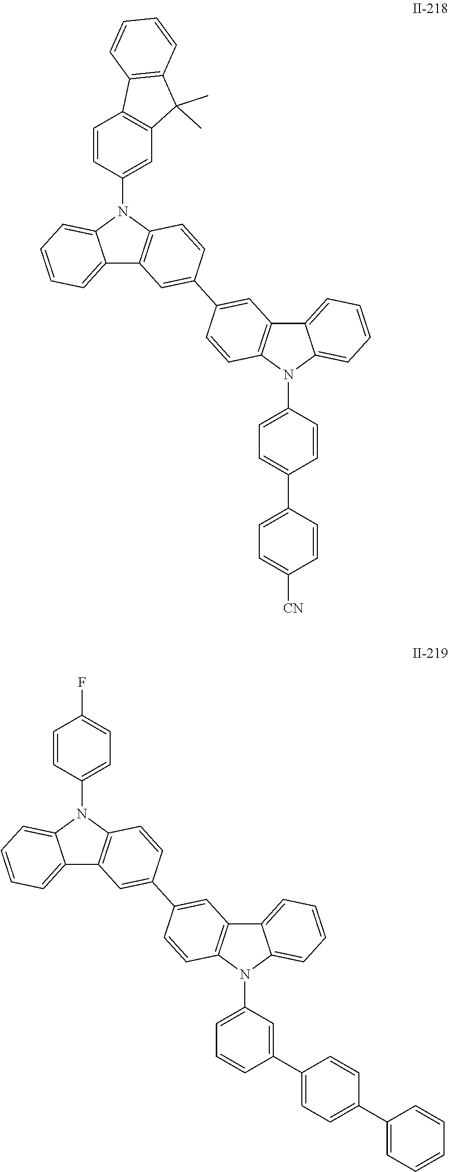 [SMILES: CC1(C)c2ccccc2-c2ccc(-n3c4ccccc4c4cc(-c5ccc6c(c5)c5ccccc5n6-c5ccc(-c6ccc(C#N)cc6)cc5)ccc43)cc21 ; Fc1ccc(-n2c3ccccc3c3cc(-c4ccc5c(c4)c4ccccc4n5-c4cccc(-c5ccc(-c6ccccc6)cc5)c4)ccc32)cc1]

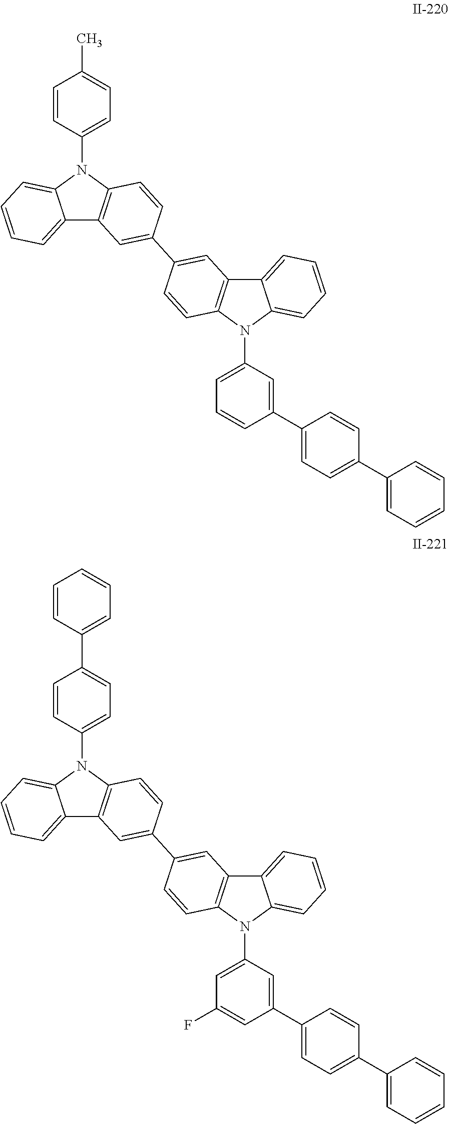 [SMILES: Cc1ccc(-n2c3ccccc3c3cc(-c4ccc5c(c4)c4ccccc4n5-c4cccc(-c5ccc(-c6ccccc6)cc5)c4)ccc32)cc1 ; Fc1cc(-c2ccc(-c3ccccc3)cc2)cc(-n2c3ccccc3c3cc(-c4ccc5c(c4)c4ccccc4n5-c4ccc(-c5ccccc5)cc4)ccc32)c1]

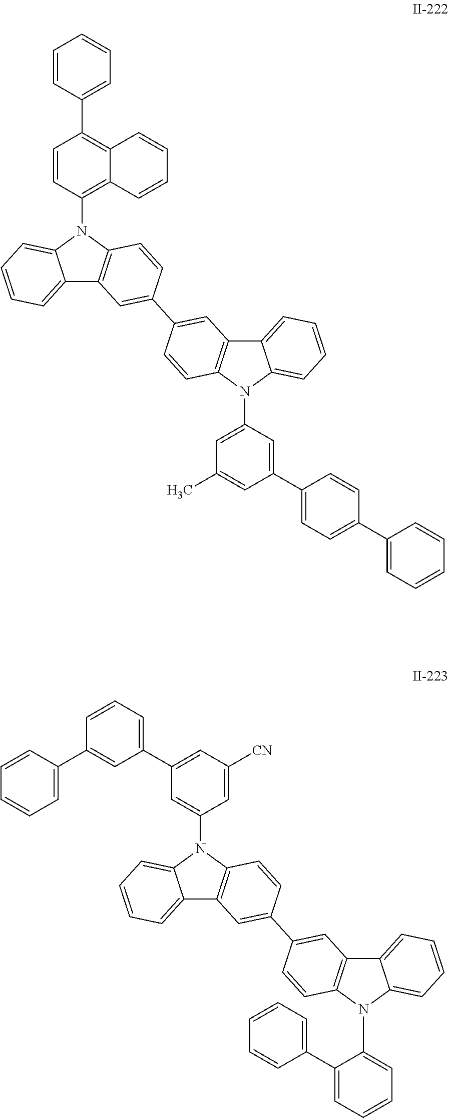 [SMILES: Cc1cc(-c2ccc(-c3ccccc3)cc2)cc(-n2c3ccccc3c3cc(-c4ccc5c(c4)c4ccccc4n5-c4ccc(-c5ccccc5)c5ccccc45)ccc32)c1 ; N#Cc1cc(-c2cccc(-c3ccccc3)c2)cc(-n2c3ccccc3c3cc(-c4ccc5c(c4)c4ccccc4n5-c4ccccc4-c4ccccc4)ccc32)c1]

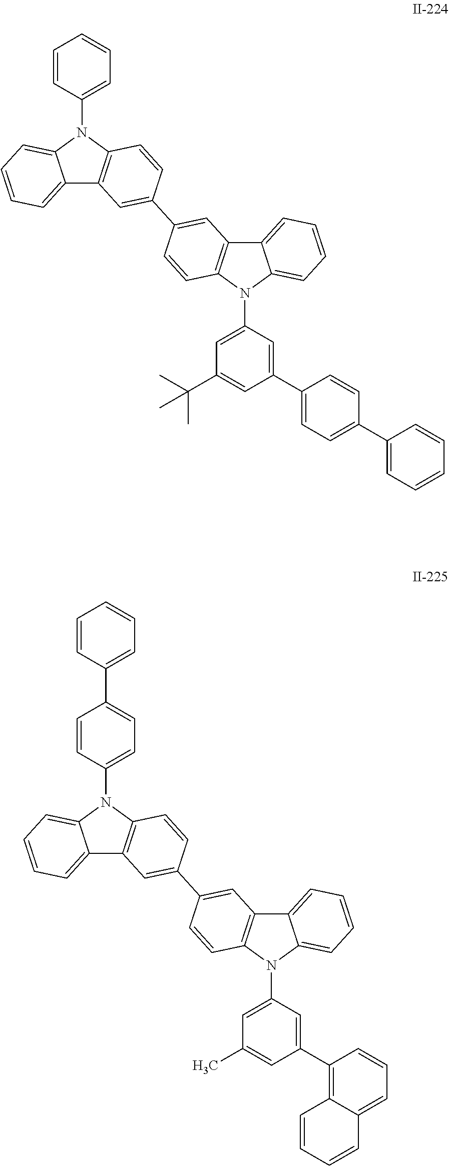 [SMILES: CC(C)(C)c1cc(-c2ccc(-c3ccccc3)cc2)cc(-n2c3ccccc3c3cc(-c4ccc5c(c4)c4ccccc4n5-c4ccccc4)ccc32)c1 ; Cc1cc(-c2cccc3ccccc23)cc(-n2c3ccccc3c3cc(-c4ccc5c(c4)c4ccccc4n5-c4ccc(-c5ccccc5)cc4)ccc32)c1]

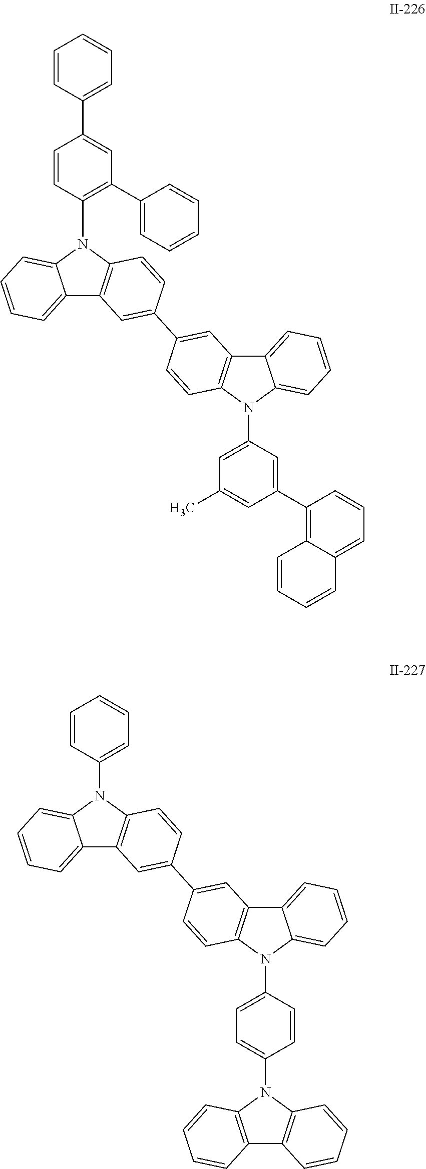 [SMILES: Cc1cc(-c2cccc3ccccc23)cc(-n2c3ccccc3c3cc(-c4ccc5c(c4)c4ccccc4n5-c4ccc(-c5ccccc5)cc4-c4ccccc4)ccc32)c1 ; c1ccc(-n2c3ccccc3c3cc(-c4ccc5c(c4)c4ccccc4n5-c4ccc(-n5c6ccccc6c6ccccc65)cc4)ccc32)cc1]

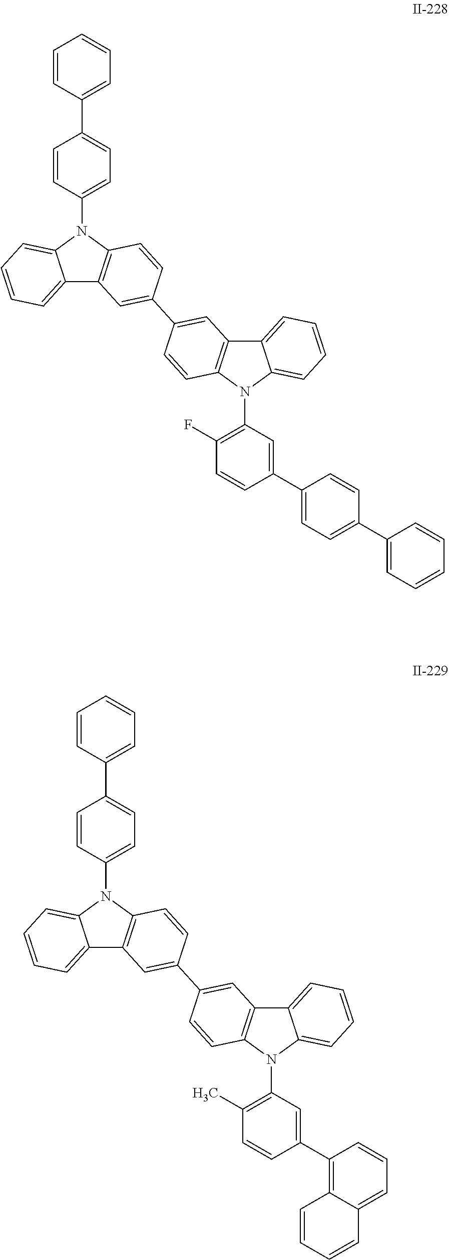 [SMILES: Fc1ccc(-c2ccc(-c3ccccc3)cc2)cc1-n1c2ccccc2c2cc(-c3ccc4c(c3)c3ccccc3n4-c3ccc(-c4ccccc4)cc3)ccc21 ; Cc1ccc(-c2cccc3ccccc23)cc1-n1c2ccccc2c2cc(-c3ccc4c(c3)c3ccccc3n4-c3ccc(-c4ccccc4)cc3)ccc21]

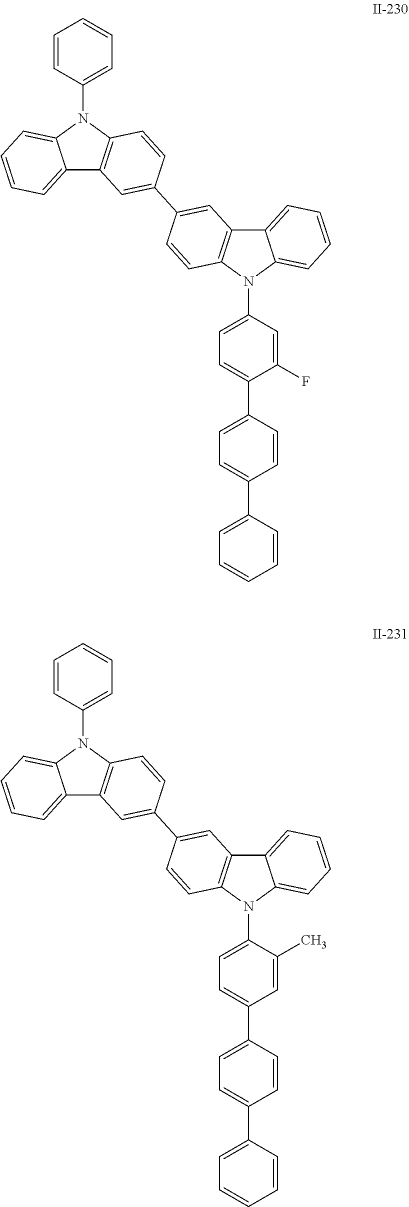 [SMILES: Fc1cc(-n2c3ccccc3c3cc(-c4ccc5c(c4)c4ccccc4n5-c4ccccc4)ccc32)ccc1-c1ccc(-c2ccccc2)cc1 ; Cc1cc(-c2ccc(-c3ccccc3)cc2)ccc1-n1c2ccccc2c2cc(-c3ccc4c(c3)c3ccccc3n4-c3ccccc3)ccc21]

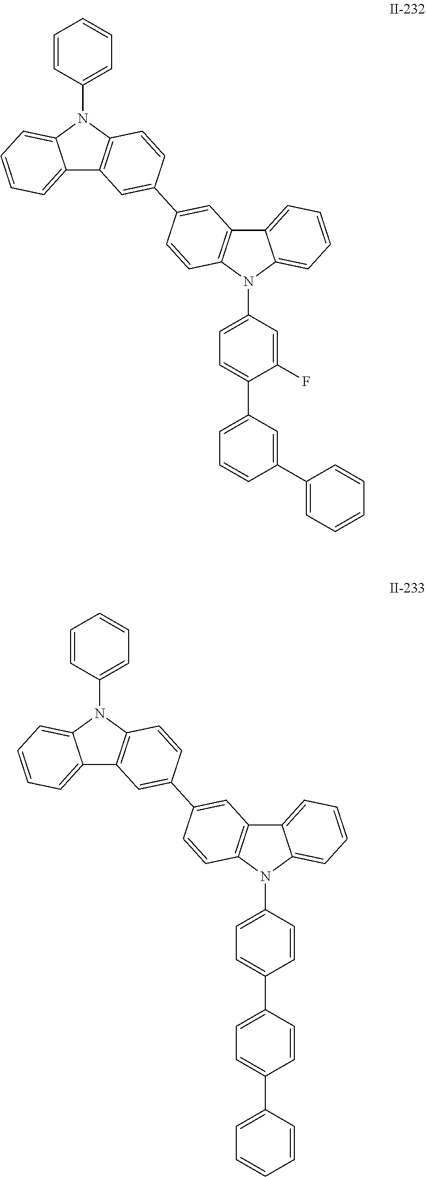 [SMILES: Fc1cc(-n2c3ccccc3c3cc(-c4ccc5c(c4)c4ccccc4n5-c4ccccc4)ccc32)ccc1-c1cccc(-c2ccccc2)c1 ; c1ccc(-c2ccc(-c3ccc(-n4c5ccccc5c5cc(-c6ccc7c(c6)c6ccccc6n7-c6ccccc6)ccc54)cc3)cc2)cc1]

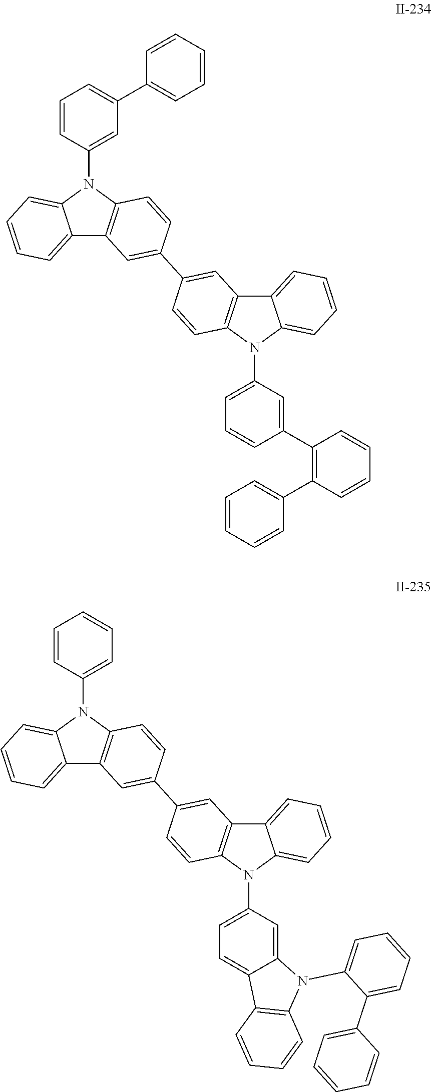 [SMILES: c1ccc(-c2cccc(-n3c4ccccc4c4cc(-c5ccc6c(c5)c5ccccc5n6-c5cccc(-c6ccccc6-c6ccccc6)c5)ccc43)c2)cc1 ; c1ccc(-c2ccccc2-n2c3ccccc3c3ccc(-n4c5ccccc5c5cc(-c6ccc7c(c6)c6ccccc6n7-c6ccccc6)ccc54)cc32)cc1]

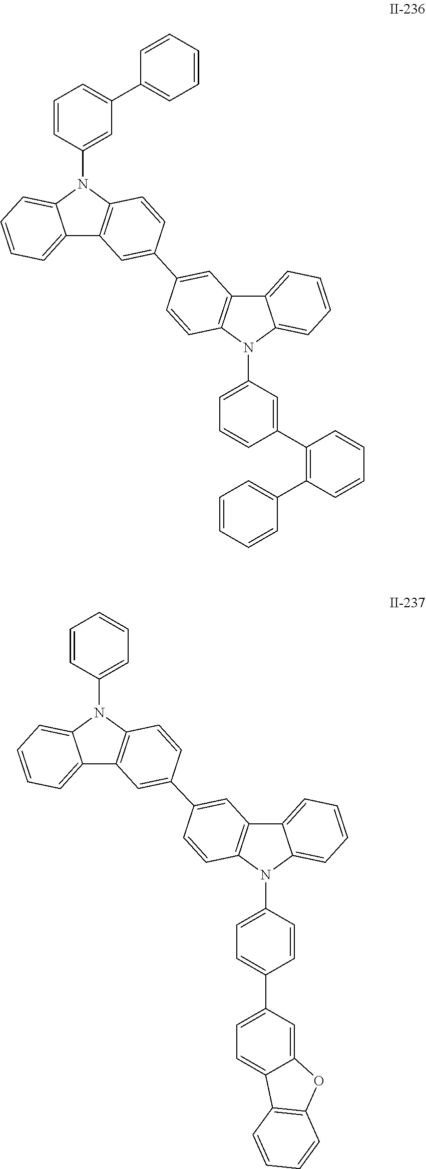 [SMILES: c1ccc(-c2cccc(-n3c4ccccc4c4cc(-c5ccc6c(c5)c5ccccc5n6-c5cccc(-c6ccccc6-c6ccccc6)c5)ccc43)c2)cc1 ; c1ccc(-n2c3ccccc3c3cc(-c4ccc5c(c4)c4ccccc4n5-c4ccc(-c5ccc6c(c5)oc5ccccc56)cc4)ccc32)cc1]

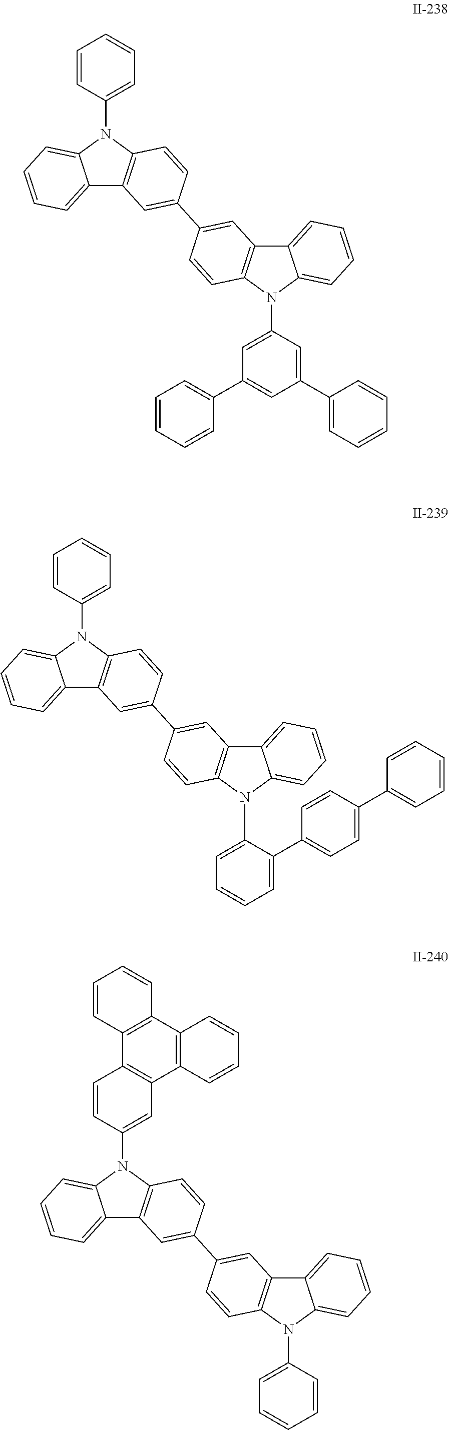 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3-n3c4ccccc4c4cc(-c5ccc6c(c5)c5ccccc5n6-c5ccccc5)ccc43)cc2)cc1 ; c1ccc(-n2c3ccccc3c3cc(-c4ccc5c(c4)c4ccccc4n5-c4ccc5c6ccccc6c6ccccc6c5c4)ccc32)cc1]

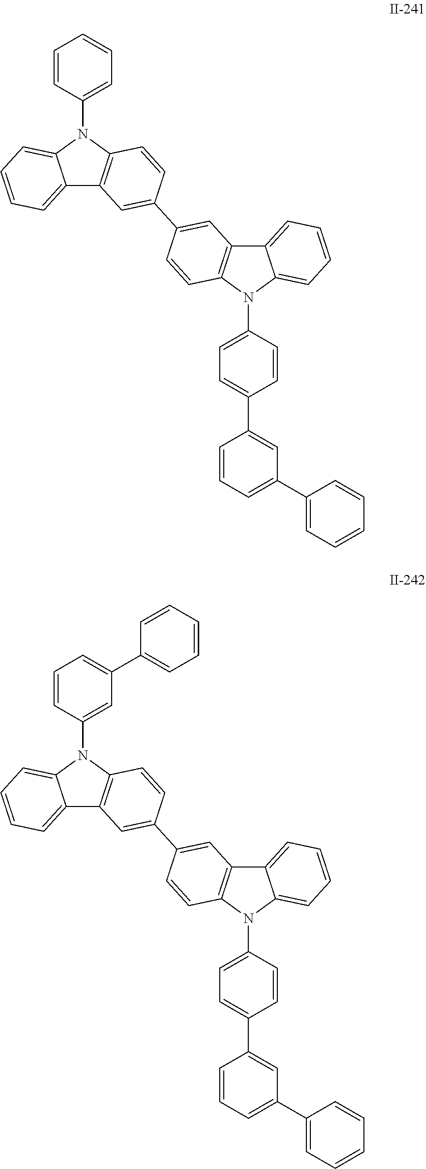 [SMILES: c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1]

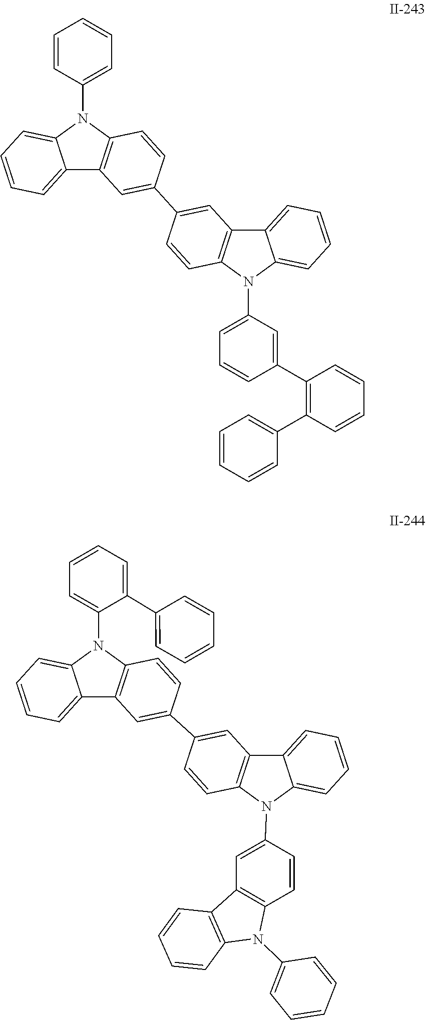 [SMILES: c1ccc(-c2ccccc2-c2cccc(-n3c4ccccc4c4cc(-c5ccc6c(c5)c5ccccc5n6-c5ccccc5)ccc43)c2)cc1 ; c1ccc(-c2ccccc2-n2c3ccccc3c3cc(-c4ccc5c(c4)c4ccccc4n5-c4ccc5c(c4)c4ccccc4n5-c4ccccc4)ccc32)cc1]

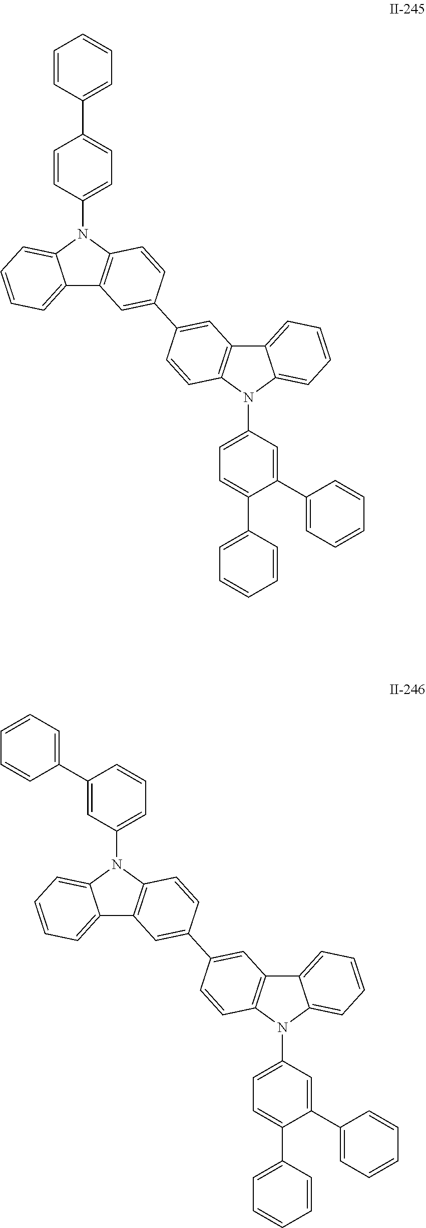 [SMILES: c1ccc(-c2ccc(-n3c4ccccc4c4cc(-c5ccc6c(c5)c5ccccc5n6-c5ccc(-c6ccccc6)c(-c6ccccc6)c5)ccc43)cc2)cc1 ; c1ccc(-c2cccc(-n3c4ccccc4c4cc(-c5ccc6c(c5)c5ccccc5n6-c5ccc(-c6ccccc6)c(-c6ccccc6)c5)ccc43)c2)cc1]

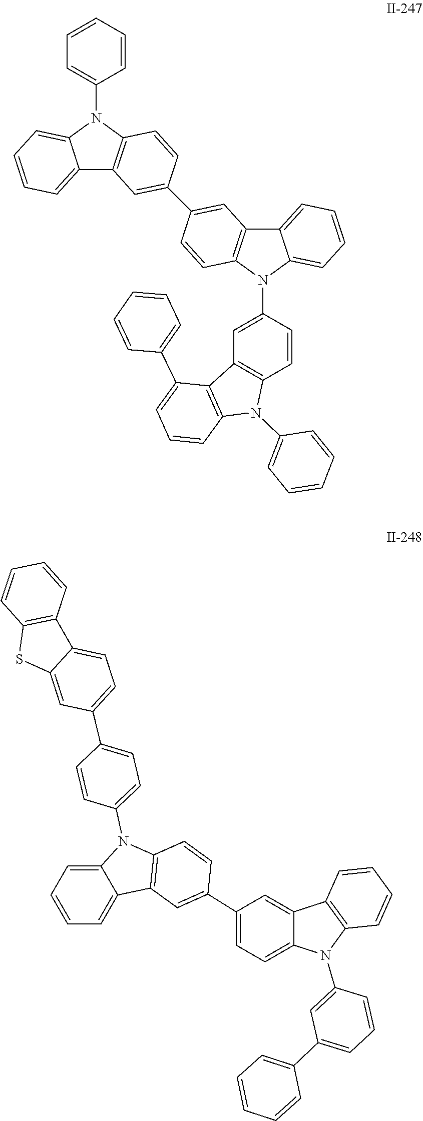 [SMILES: c1ccc(-c2cccc3c2c2cc(-n4c5ccccc5c5cc(-c6ccc7c(c6)c6ccccc6n7-c6ccccc6)ccc54)ccc2n3-c2ccccc2)cc1 ; c1ccc(-c2cccc(-n3c4ccccc4c4cc(-c5ccc6c(c5)c5ccccc5n6-c5ccc(-c6ccc7c(c6)sc6ccccc67)cc5)ccc43)c2)cc1]

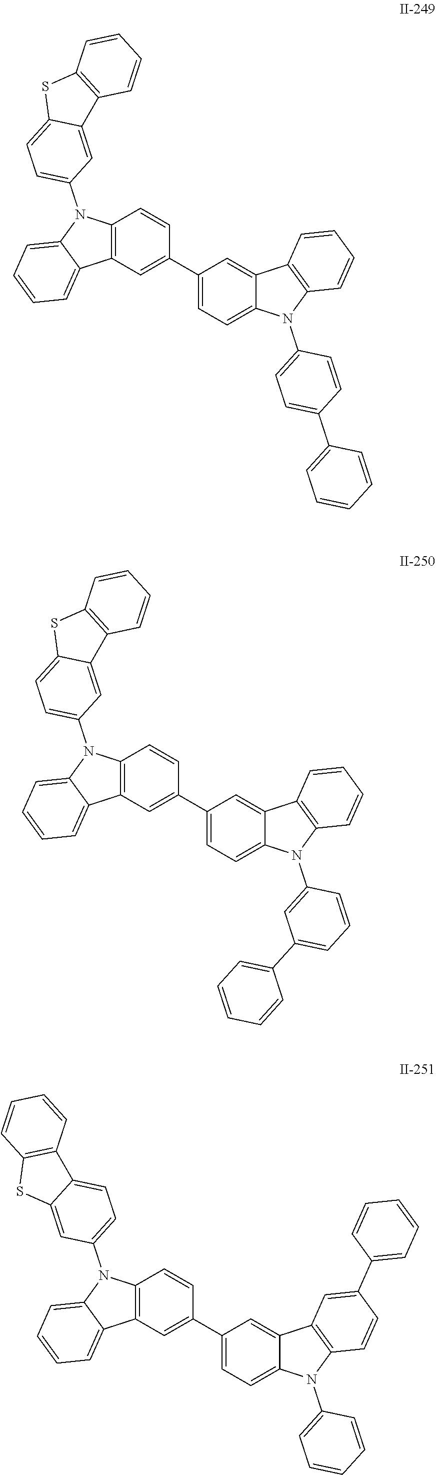 [SMILES: c1ccc(-c2ccc(-n3c4ccccc4c4cc(-c5ccc6c(c5)c5ccccc5n6-c5ccc6sc7ccccc7c6c5)ccc43)cc2)cc1 ; c1ccc(-c2cccc(-n3c4ccccc4c4cc(-c5ccc6c(c5)c5ccccc5n6-c5ccc6sc7ccccc7c6c5)ccc43)c2)cc1 ; c1ccc(-c2ccc3c(c2)c2cc(-c4ccc5c(c4)c4ccccc4n5-c4ccc5c(c4)sc4ccccc45)ccc2n3-c2ccccc2)cc1]

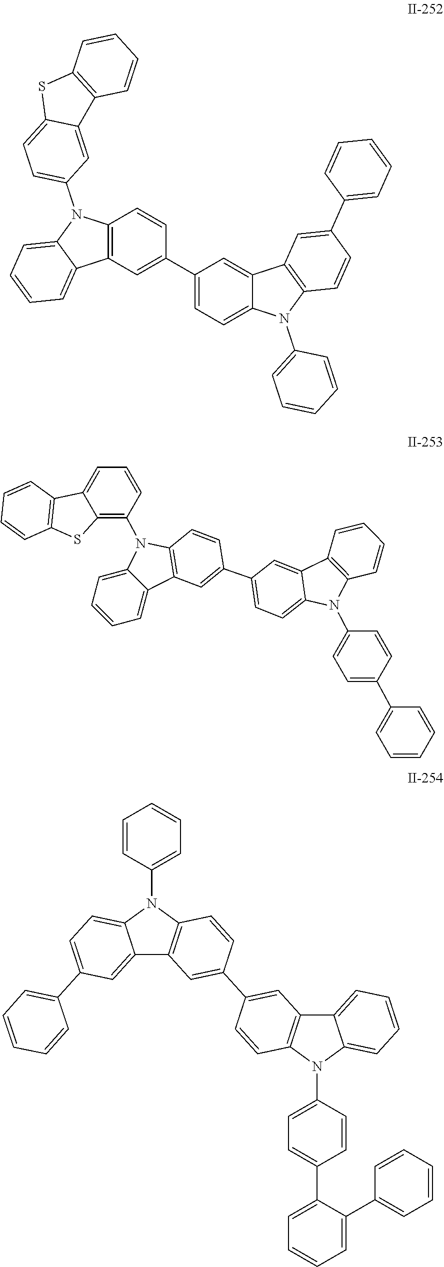 [SMILES: c1ccc(-c2ccc3c(c2)c2cc(-c4ccc5c(c4)c4ccccc4n5-c4ccc5sc6ccccc6c5c4)ccc2n3-c2ccccc2)cc1 ; c1ccc(-c2ccc(-n3c4ccccc4c4cc(-c5ccc6c(c5)c5ccccc5n6-c5cccc6c5sc5ccccc56)ccc43)cc2)cc1 ; c1ccc(-c2ccc3c(c2)c2cc(-c4ccc5c(c4)c4ccccc4n5-c4ccc(-c5ccccc5-c5ccccc5)cc4)ccc2n3-c2ccccc2)cc1]

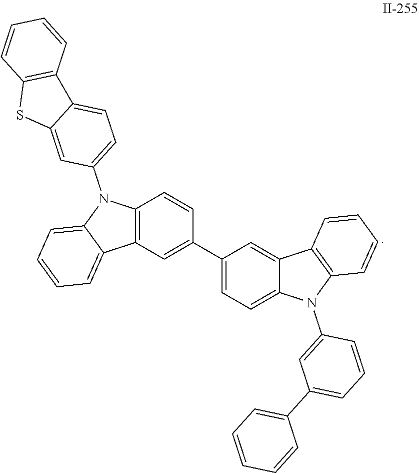 [SMILES: c1ccc(-c2cccc(-n3c4ccccc4c4cc(-c5ccc6c(c5)c5ccccc5n6-c5ccc6c(c5)sc5ccccc56)ccc43)c2)cc1]

Optionally, the composition is a mixture of the first compound and the second compound. For example, the mixture may be formed by uniformly mixing the first compound and the second compound by mechanical stirring.

The relative content of the two types of compounds in the composition is not specifically limited in the present disclosure, and may be selected according to the specific applications of an organic electroluminescent device. In general, based on the total weight of the composition, the mass percentage of the first compound may be 1% to 99% and the mass percentage of the second compound may be 1% to 99%. For example, in the composition, a mass ratio of the first compound to the second compound may be 1:99, 20:80, 30:70, 40:60, 45:65, 50:50, 55:45, 60:40, 70:30, 80:20, 99:1, and the like.

In one embodiment of the present disclosure, the composition consists of the first compound and the second compound, wherein based on the total weight of the composition, the mass percentage of the first compound is 20% to 80% and the mass percentage of the second compound is 20% to 80%.

In one preferred embodiment, in the composition, based on the total weight of the composition, the mass percentage of the first compound is 30% to 60% and the mass percentage of the second compound is 40% to 70%, in this case, when the composition is applied to an organic electroluminescent device, the device can have both high luminous efficiency and long service life, and is especially suitable as an electronic display device. Preferably, based on the total weight of the composition, the mass percentage of the first compound is 40% to 60% and the mass percentage of the second compound is 40% to 60%. More preferably, the mass percentage of the first compound is 40% to 50% and the mass percentage of the second compound is 50% to 60%.

The present disclosure also provides use of the composition as a host material of an organic electroluminescent layer of an organic electroluminescent device.

In one embodiment of the present disclosure, the composition is used as a host material of a green phosphorescent organic electroluminescent device.

The present disclosure also provides an electronic component for realizing photoelectric conversion. The electronic component comprises an anode and a cathode which is arranged oppositely to the anode, and at least one functional layer between the anode and the cathode, and the functional layer comprises the composition of the present disclosure.

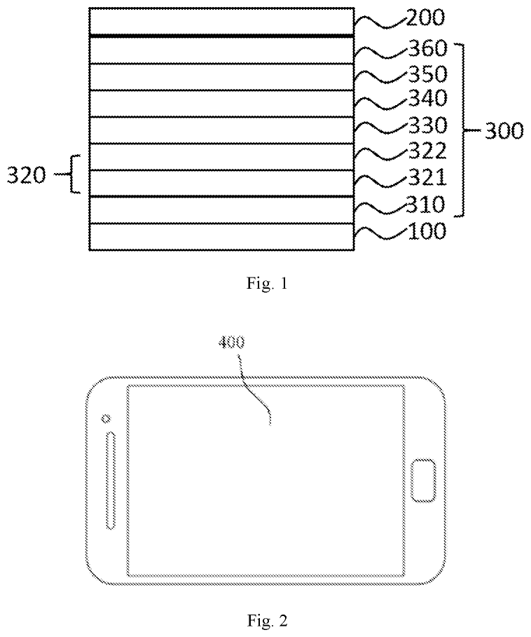

In one specific embodiment of the present disclosure, the electronic component is an organic electroluminescent device. As shown in FIG. 1, the organic electroluminescent device of the present disclosure comprises an anode 100, a cathode 200 and at least one functional layer 300 between an anode layer and a cathode layer, and the functional layer 300 comprises a hole injection layer 310, a hole transport layer 320, an organic electroluminescent layer 330, a hole blocking layer 340, an electron transport layer 350 and an electron injection layer 360; the hole transport layer 320 comprises a first hole transport layer 321 and a second hole transport layer 322; and the hole injection layer 310, the hole transport layer 320, the organic electroluminescent layer 330, the hole blocking layer 340, the electron transport layer 350, and the electron injection layer 360 may be sequentially formed on the anode 100, the organic electroluminescent layer 330 may comprise the composition of the first aspect of the present disclosure, and the composition includes the first compound, preferably containing at least one of the compounds 1 to 705, and the second compound, preferably containing at least one of the compounds II-1 to II-255.

In the present disclosure, the first compound has a bipolar characteristic in which electron characteristics are relatively strong, while the second compound has a bipolar characteristic in which hole characteristics are relatively strong, so the first compound and the second compound can be used together to increase charge mobility and stability, significantly improving luminous efficiency and service life characteristics.

The present disclosure also provides an electronic component which is a green organic electroluminescent device, including an anode and a cathode which is arranged oppositely to the anode, and at least one functional layer between the anode and the cathode, and the functional layer comprises the composition of the present disclosure.

In one embodiment of the present disclosure, the organic electroluminescent layer of the organic electroluminescent device comprises the composition of the present disclosure, and the composition is used in a host of the organic electroluminescent layer of the organic electroluminescent device.

In one embodiment of the present disclosure, the organic electroluminescent layer further comprises a dopant, and the dopant can be, for example, a phosphorescent dopant, such as a green phosphorescent dopant. A small amount of the dopant is mixed with a host compound to cause light emission, and the dopant may typically be a substance that emits light by multiple excitations to or beyond a triplet state, such as a metal complex. The dopant may be, for example, an inorganic, organic, or organic/inorganic compound, and one or more species may be used.

Examples of the dopant may be a phosphorescent dopant, and examples of the phosphorescent dopant may be organometallic compounds including Ir, Pt, Os, Ti, Zr, Hf, Eu, Tb, Tm, Fe, Co, Ni, Ru, Rh, Pd, or their combination. For example, the phosphorescent dopant may be Ir(ppy)₃, Ir(pbi)₂(acac), Ir(nbi)₂(acac), Ir(fbi)₂(acac), Ir(tbi)₂(acac), Ir(pybi)₂(acac), Ir(3mppy)₃, Ir(npy)₂acac, Ir(mppy)₃, Ir(ppy)₂(acac), or fac-Ir(ppy)₃, but is not limited to this.

Optionally, the anode 100 comprises an anode material, which is preferably a material with a large work function that facilitates hole injection into the functional layer. Specific examples of the anode material include metals such as nickel, platinum, vanadium, chromium, copper, zinc, and gold or their alloys; metal oxides such as zinc oxide, indium oxide, indium tin oxide (ITO), and indium zinc oxide (IZO); combined metals and oxides such as ZnO:Al or SnO₂:Sb; or conducting polymers such as poly(3-methylthiophene), poly[3,4-(ethylene-1,2-dioxy)thiophene] (PEDT), polypyrrole, and polyaniline, but are not limited to thereto. A transparent electrode comprising indium tin oxide (ITO) as the anode is preferably included.

Optionally, the hole transport layer 320 may comprise one or more hole transport materials, and the hole transport materials may be selected from a carbazole polymer, carbazole-linked triarylamine compounds, or other types of compounds, which are not specially limited in the present disclosure. The hole transport layer 320 may comprise a first hole transport layer 321 and a second hole transport layer 322; and the first hole transport layer 321 is adjacent to the second hole transport layer 322, and which is closer to the anode than the second hole transport layer 322. For example, in one embodiment of the present disclosure, the first hole transport layer 321 is composed of a compound NPB, and the second hole transport layer 322 is composed of a compound PAPB.

Optionally, the organic electroluminescent layer 330 may be composed of a single light-emitting material and may also comprise a host material and a guest material. Alternatively, the organic electroluminescent layer 330 is composed of the host material and the guest material, and holes and electrons which are injected into the organic electroluminescent layer 330 may be recombined in the organic electroluminescent layer 330 to form excitons, the excitons transfer energy to the host material, and the host material transfers energy to the guest material, thus enabling the guest material to emit light.

In one embodiment of the present disclosure, the host material of the organic electroluminescent layer 330 is composed of the composition G-X-Y provided by the present disclosure. In the present disclosure, GH-N is an electron-type host material and GH-P is a hole-type host material. The composition G-X-Y provided by the present disclosure comprises a first compound and a second compound, the first compound is GH-N, which has a bipolar characteristic in which electron characteristics are relatively strong, while the second compound is GH-P, which has a bipolar characteristic in which hole characteristics are relatively strong, thus, the first compound and the second compound can be used together to increase charge mobility and stability, thus significantly improving luminous efficiency and service life characteristics. Specifically, the first compound includes a nitrogen-containing six-membered ring having high electron transport characteristics to stably and efficiently transport electrons, thus reducing the driving voltage, improving the current efficiency, and realizing long service life characteristics of the device; the second compound has a carbazole or amine structure having a high HOMO energy, which efficiently injects and transports holes, thus contributing to improving device characteristics; and through the composition including the first compound and the second compound, the adjustment of the electron and hole characteristics within the device stack is ultimately achieved to achieve an optimal balance.

The guest material of the organic electroluminescent layer 330 may be a compound having a condensed aryl ring or its derivative, a compound having a heteroaryl ring or its derivative, an aromatic amine derivative, or other materials, which is not specially limited in the present disclosure. In one example of the present disclosure, the guest material of the organic electroluminescent layer 330 may be Ir(mppy)₃.

The electron transport layer 350 may be of a single-layer structure or a multi-layer structure and may comprise one or more electron transport materials, and the electron transport materials are selected from a benzimidazole derivative, an oxadiazole derivative, a quinoxaline derivative, or other electron transport materials, which is not specially limited in the present disclosure. For example, in one embodiment of the present disclosure, the electron transport layer 350 may be composed of ET-06 and LiQ.

Optionally, a hole blocking layer 340 is arranged between the organic electroluminescent layer 330 and the electron transport layer 350. The hole blocking layer may comprise one or more hole blocking materials, which are not specially limited in the present disclosure.

Optionally, the cathode 200 comprises a cathode material, which is a material having a small work function that facilitates electron injection into the functional layer. Specific examples of the cathode material include metals such as magnesium, calcium, sodium, potassium, titanium, indium, yttrium, lithium, gadolinium, aluminum, silver, tin, and lead or their alloys; or multilayer materials such as LiF/Al, Liq/Al, LiO₂/Al, LiF/Ca, LiF/Al, and BaF₂/Ca, but are not limited to this. A metal electrode comprising silver and magnesium as the cathode is preferably included.

Optionally, a hole injection layer 310 may also be arranged between the anode 100 and the hole transport layer 320 to enhance the ability to inject holes into the hole transport layer 320. The hole injection layer 310 can be made of a benzidine derivative, a starburst arylamine compound, a phthalocyanine derivative or other materials, which is not specially limited in the present disclosure. In one embodiment of the present disclosure, the hole injection layer 310 may be composed of F4-TCNQ.

Optionally, an electron injection layer 360 may also be arranged between the cathode 200 and the electron transport layer 350 to enhance the ability to inject electrons into the electron transport layer 350. The electron injection layer 360 may comprise an inorganic material such as an alkali metal sulfide and an alkali metal halide, or may include a complex of an alkali metal and an organic substance. In one embodiment of the present disclosure, the electron injection layer 360 may comprise ytterbium (Yb).

The present disclosure also provides an electronic device, comprising the electronic component described in the present disclosure.

For example, as shown in FIG. 2, the electronic device provided by the present disclosure is an electronic device 400 including any one of the organic electroluminescent devices described in the above embodiments of the organic electroluminescent device. The electronic device may be a display device, a lighting device, an optical communication device, or other types of electronic devices, and may include, for example, but is not limited to, a computer screen, a mobile phone screen, a television, electronic paper, an emergency lighting lamp, an optical module, and the like. Since the electronic device 400 has the above-described organic electroluminescent device, the electronic device 400 has the same beneficial effects, which is not repeated here.

The present disclosure will be described in detail below with reference to examples, but the following description is intended to explain the present disclosure and is not intended to limit the scope of the present disclosure in any way.

### SYNTHESIS EXAMPLES

Those skilled in the art will recognize that the chemical reactions described in the present disclosure can be used to suitably prepare a number of other compounds of the present disclosure, and other methods for preparing the compounds of the present disclosure are deemed to be within the scope of the present disclosure. For example, the synthesis of those non-exemplified compounds in accordance with the present disclosure can be successfully accomplished by those skilled in the art by modifying methods, for example, by appropriately protecting interfering groups, by utilizing other known reagents other than those described in the present disclosure, or by making some routine modification of reaction conditions. In addition, the compounds disclosed in the present disclosure are synthesized.

Preparation of First Compound

### Preparation Example 1: Synthesis of Compound 67

(1) Synthesis of Reactant B-1

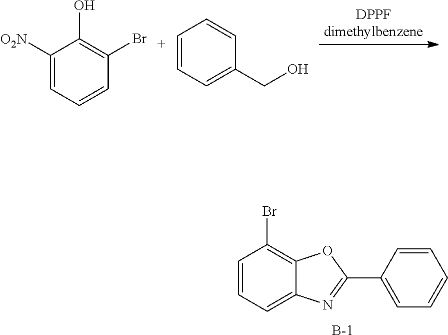

Nitrogen (0.100 L/min) was introduced into a three-necked flask equipped with a mechanical stirrer, a thermometer, and an Allihn condenser for replacement for 15 min, 2-bromo-6-nitrophenol (50.0 g, 229.3 mmol), benzyl alcohol (29.76 g, 275.2 mmol), 1,1′-bis(diphenylphosphino)ferrocene (3.71 g, 6.8 mmol) and xylene (500 mL) were successively added into the three-necked flask, stirring and heating were started, after the temperature was raised to 125 to 135° C., a reaction was carried out under reflux for 36 h, after the reaction was completed, stirring and heating were stopped, and the reaction was started to be treated when the temperature was cooled to room temperature, the reaction solution was started to be treated; the resulting reaction solution was extracted with toluene and water, the organic phases were combined, and an organic layer was dried over anhydrous magnesium sulfate, filtered, and concentrated; and a crude product was purified by silica gel column chromatography using a dichloromethane/n-heptane system to obtain a compound reactant B-1 (40.23 g, 64%) as a solid.

(2) Synthesis of Intermediate Sub 1-I-A1

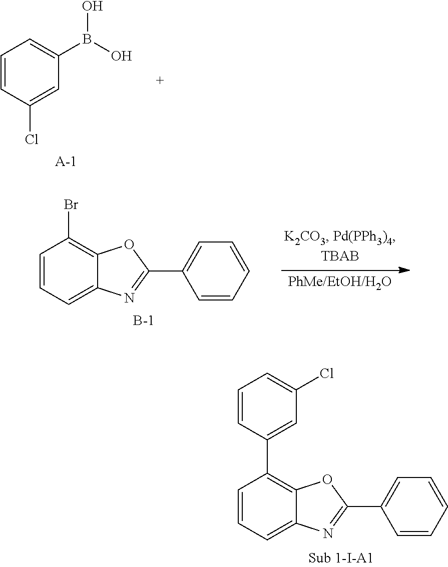

Nitrogen (0.100 L/min) was introduced into a three-necked flask equipped with a mechanical stirrer, a thermometer, and an Allihn condenser for replacement for 15 min, and B-1 (50.0 g, 182.40 mmol), m-chlorophenylboronic acid (31.37 g, 200.64 mmol) (A-1), potassium carbonate (55.5 g, 401.3 mmol), tetrakis(triphenylphosphine)palladium (4.2 g, 3.6 mmol), tetrabutylammonium bromide (1.2 g, 3.6 mmol) and a mixed solvent of toluene (400 mL), ethanol (200 mL) and water (100 mL) were added into the three-necked flask. Stirring and heating were started, after the temperature was raised to 75 to 80° C., a reaction was carried out under reflux for 8 h, and after the reaction was completed, the reaction solution was cooled to room temperature. An organic phase was extracted with toluene and water and then separated, washed with water to be neutral, dried over anhydrous magnesium sulfate, and filtered, and the obtained filtrate was concentrated by distillation under reduced pressure; and a crude product was purified by silica gel column chromatography using a dichloromethane/n-heptane system to obtain a compound intermediate sub1-I-A1 (39.6 g, 71%) as a solid.

(3) Synthesis of Intermediate Sub A-1

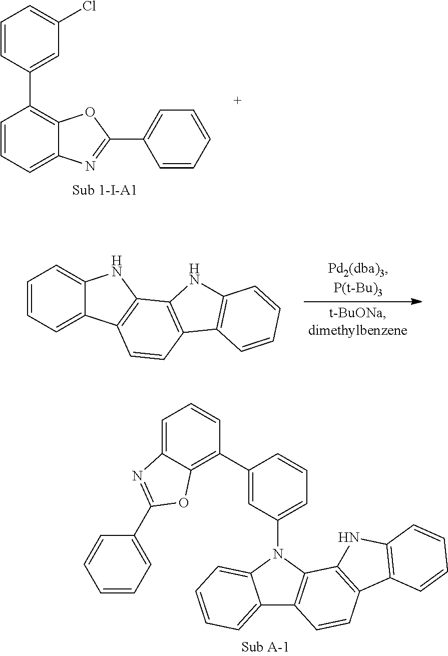 [SMILES: Clc1cccc(-c2cccc3nc(-c4ccccc4)oc23)c1 ; c1ccc2c(c1)[nH]c1c2ccc2c3ccccc3[nH]c21 ; c1ccc(-c2nc3cccc(-c4cccc(-n5c6ccccc6c6ccc7c8ccccc8[nH]c7c65)c4)c3o2)cc1]

Nitrogen (0.100 L/min) was introduced into a three-necked flask equipped with a mechanical stirrer, a thermometer, and an Allihn condenser for replacement for 15 min, and the intermediate sub 1-I-A1 (35.0 g, 114.5 mmol), indolo[2,3-A]carbazole (35.3 g, 137.6 mmol), Pd₂(dba)₃ (2.1 g, 2.3 mmol), tri-tert-butylphosphine (0.92 g, 4.6 mmol), sodium tert-butoxide (27.5 g, 286.2 mmol), and xylene (500 mL) were added into the three-necked flask. Stirring and heating were started, after the temperature was raised to 135 to 145° C., a reaction was carried out under reflux for 10 h, and after the reaction was completed, the reaction solution was cooled to room temperature. After the reaction solution was washed with water, the organic phase was separated, the organic phase was dried over anhydrous magnesium sulfate, and filtered, the obtained filtrate was distilled under reduced pressure to remove a solvent, and a crude product was recrystallized by using a dichloromethane/ethanol system to obtain an intermediate sub A-1 (45.1 g, 75%) as a white solid.

Referring to the synthesis method for the intermediate sub A-1, intermediates sub A-X shown in Table 1 below were synthesized (X is 2 to 6, 8, 10 to 11 or 15 to 18). Intermediates sub A-2 to sub A-6, sub A-8 and sub A-10 shown in Table 1 below were synthesized with reference to the reactions in (2) and (3) of the intermediate sub A-1 by using a reactant A-X (X is 1 to 5) instead of the reactant A-1, and a reactant B-X (X is 1 to 2, 4, or 6) instead of the reactant B-1, while intermediates sub A-11, and sub A-15 to sub A-18 shown in Table 1 were synthesized with reference to the reaction in (3) of the intermediate sub A-1 by using a reactant B-X (X is 7 or 11 to 14) instead of the reactant B-1.

TABLE 1

| Reactant (A-X) | Reactant (B-X) | Intermediate (sub A-X) | Yield % |
|---|---|---|---|
| 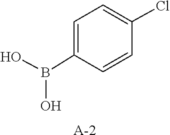 | 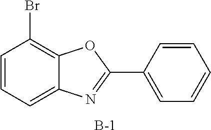 | 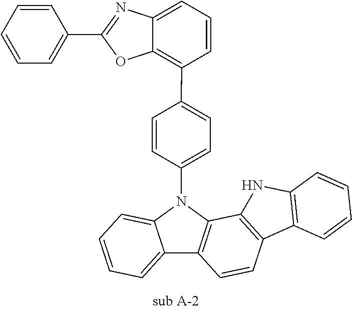 [SMILES: c1ccc(-c2nc3cccc(-c4ccc(-n5c6ccccc6c6ccc7c8ccccc8[nH]c7c65)cc4)c3o2)cc1] | 69 |
| 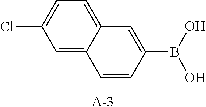 | 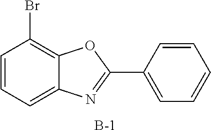 | 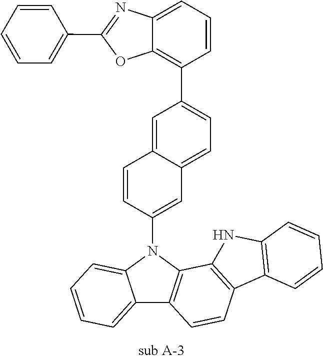 [SMILES: c1ccc(-c2nc3cccc(-c4ccc5cc(-n6c7ccccc7c7ccc8c9ccccc9[nH]c8c76)ccc5c4)c3o2)cc1] | 57 |
| 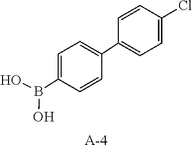 [SMILES: OB(O)c1ccc(-c2ccc(Cl)cc2)cc1 ; "A-4"] | 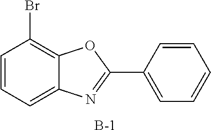 | 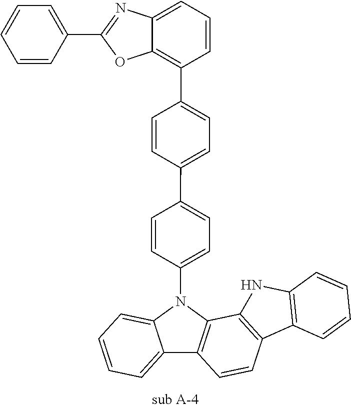 [SMILES: c1ccc(-c2nc3cccc(-c4ccc(-c5ccc(-n6c7ccccc7c7ccc8c9ccccc9[nH]c8c76)cc5)cc4)c3o2)cc1] | 71 |
| 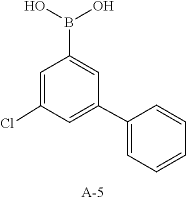 [SMILES: OB(O)c1cc(Cl)cc(-c2ccccc2)c1 ; "A-5"] | 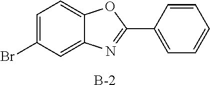 | 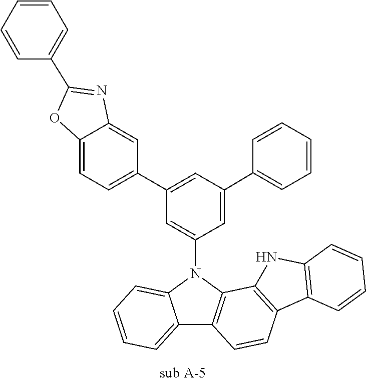 [SMILES: c1ccc(-c2cc(-c3ccc4oc(-c5ccccc5)nc4c3)cc(-n3c4ccccc4c4ccc5c6ccccc6[nH]c5c43)c2)cc1] | 65 |
| 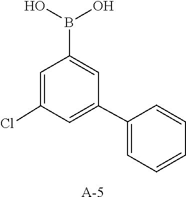 [SMILES: OB(O)c1cc(Cl)cc(-c2ccccc2)c1 ; "A-5"] | 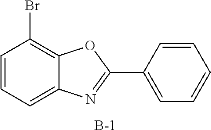 | 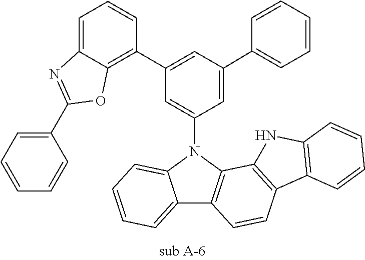 [SMILES: c1ccc(-c2cc(-c3cccc4nc(-c5ccccc5)oc34)cc(-n3c4ccccc4c4ccc5c6ccccc6[nH]c5c43)c2)cc1] | 66 |
| 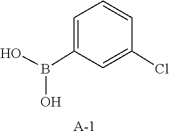 | 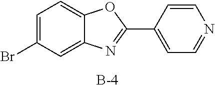 | 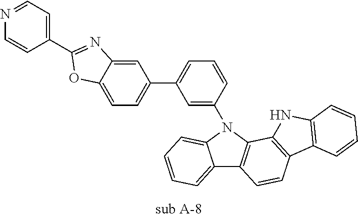 [SMILES: c1cc(-c2ccc3oc(-c4ccncc4)nc3c2)cc(-n2c3ccccc3c3ccc4c5ccccc5[nH]c4c32)c1] | 60 |
| 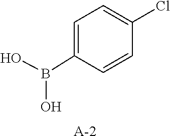 | 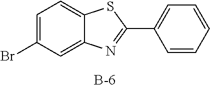 | 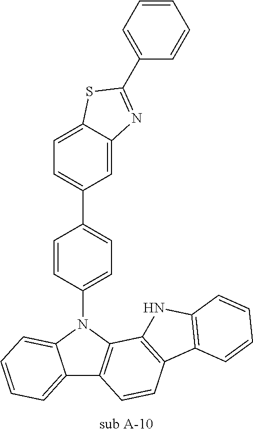 [SMILES: c1ccc(-c2nc3cc(-c4ccc(-n5c6ccccc6c6ccc7c8ccccc8[nH]c7c65)cc4)ccc3s2)cc1] | 56 |
| — | 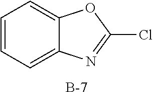 | 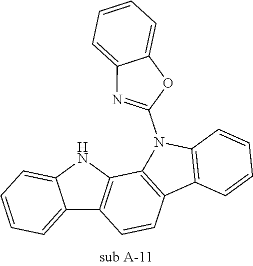 [SMILES: c1ccc2oc(-n3c4ccccc4c4ccc5c6ccccc6[nH]c5c43)nc2c1] | 67 |
| — | 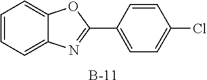 | 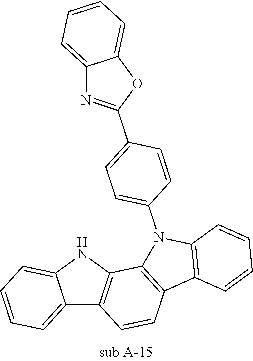 [SMILES: c1ccc2oc(-c3ccc(-n4c5ccccc5c5ccc6c7ccccc7[nH]c6c54)cc3)nc2c1] | 72 |
| — | 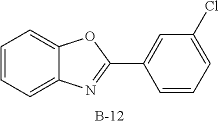 | 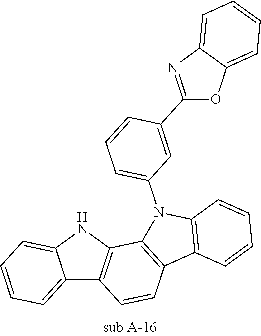 [SMILES: c1cc(-c2nc3ccccc3o2)cc(-n2c3ccccc3c3ccc4c5ccccc5[nH]c4c32)c1] | 68 |
| — | 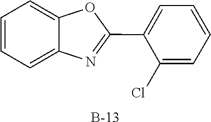 | 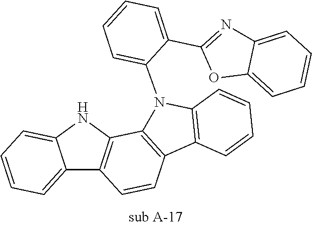 [SMILES: c1ccc(-n2c3ccccc3c3ccc4c5ccccc5[nH]c4c32)c(-c2nc3ccccc3o2)c1] | 60 |
| — | 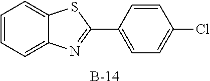 | 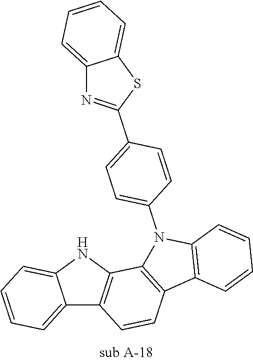 [SMILES: c1ccc2sc(-c3ccc(-n4c5ccccc5c5ccc6c7ccccc7[nH]c6c54)cc3)nc2c1] | 59 |

(4) Synthesis of Compound 67

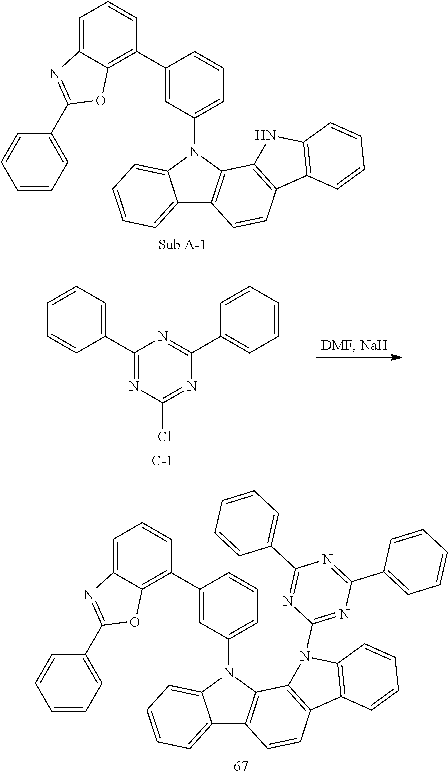

Nitrogen (0.100 L/min) was introduced into a three-necked flask equipped with a mechanical stirrer, a thermometer, and an Allihn condenser for replacement for 15 min, the intermediate sub A-1 (20.0 g, 38.0 mmol), 2-chloro-4,6-diphenyl-1,3,5-triazine (35.3 g, 137.6 mmol) (a reactant C-1), and DMF (200 mL) were added into the three-necked flask, the temperature was cooled to 0° C., after NaH (1.0 g, 41.8 mmol) was added into the reaction solution, the system was changed from white to yellow, and after the temperature of the system was naturally raised to room temperature, solid was precipitated and the reaction was completed. The reaction solution was washed with water, and filtered to obtain a solid product, the solid product was rinsed with a small amount of ethanol, and a crude product was recrystallized by using toluene to obtain a compound 67 (13.2 g, 46%). Mass spectrum: m/z=757.26 [M+H]⁺.

Referring to the synthesis method for the compound 67, compounds shown in Table 2 below were synthesized, where intermediates sub A-X (X is 1 to 6, 8, 10 to 11, or 15 to 18) were used instead of the intermediate sub A-1, and a reactant C-X (X is 1 to 7, 9 to 10, or 12 to 14) was used instead of the reactant C-1 to synthesize the compounds shown in Table 2 below.

TABLE 2

| Preparation | | |
|---|---|---|
| example | Intermediate (sub A-X) | Reactant (C-X) |
| 2 | 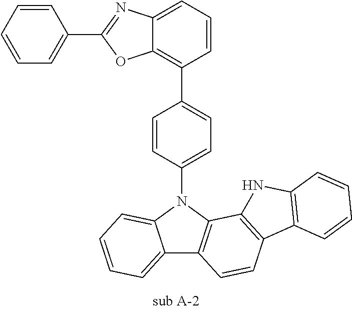 [SMILES: c1ccc(-c2nc3cccc(-c4ccc(-n5c6ccccc6c6ccc7c8ccccc8[nH]c7c65)cc4)c3o2)cc1] | 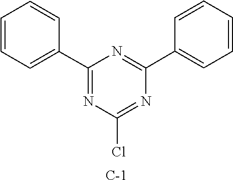 |
| 3 | 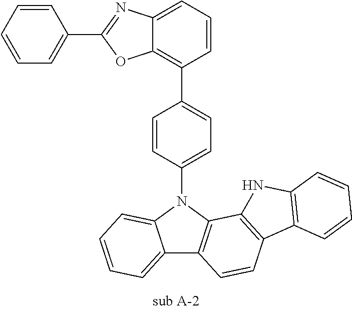 [SMILES: c1ccc(-c2nc3cccc(-c4ccc(-n5c6ccccc6c6ccc7c8ccccc8[nH]c7c65)cc4)c3o2)cc1] | 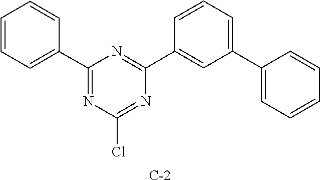 |
| 4 | 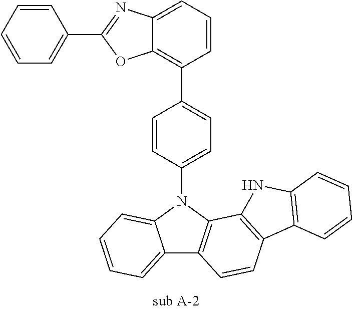 [SMILES: c1ccc(-c2nc3cccc(-c4ccc(-n5c6ccccc6c6ccc7c8ccccc8[nH]c7c65)cc4)c3o2)cc1] | 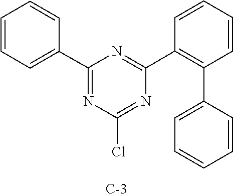 |
| 5 | 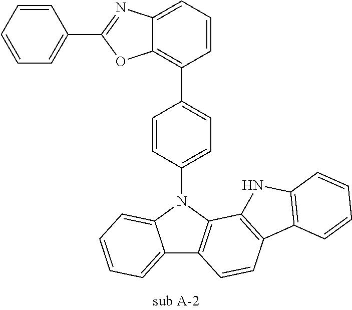 [SMILES: c1ccc(-c2nc3cccc(-c4ccc(-n5c6ccccc6c6ccc7c8ccccc8[nH]c7c65)cc4)c3o2)cc1] | 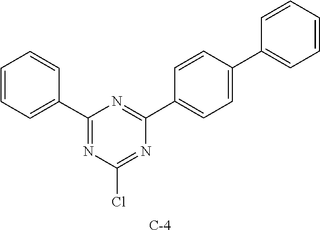 |
| 6 | 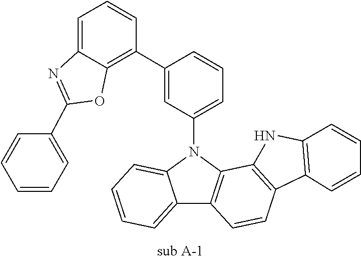 [SMILES: c1ccc(-c2nc3cccc(-c4cccc(-n5c6ccccc6c6ccc7c8ccccc8[nH]c7c65)c4)c3o2)cc1] | 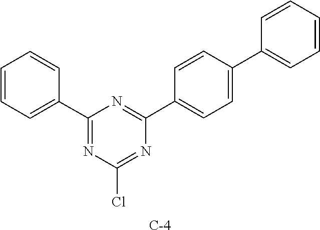 |
| 7 | 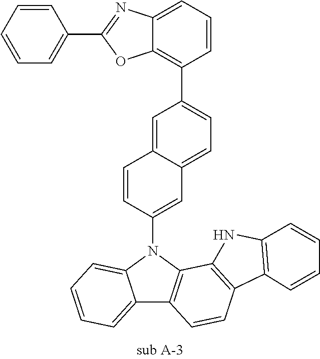 [SMILES: c1ccc(-c2nc3cccc(-c4ccc5cc(-n6c7ccccc7c7ccc8c9ccccc9[nH]c8c76)ccc5c4)c3o2)cc1] | 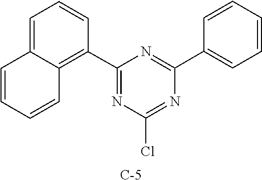 |
| 8 | 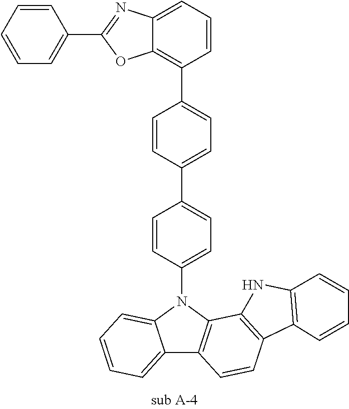 [SMILES: c1ccc(-c2nc3cccc(-c4ccc(-c5ccc(-n6c7ccccc7c7ccc8c9ccccc9[nH]c8c76)cc5)cc4)c3o2)cc1] | 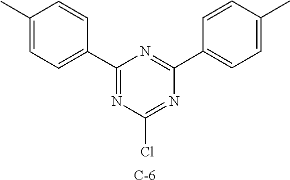 |
| 9 | 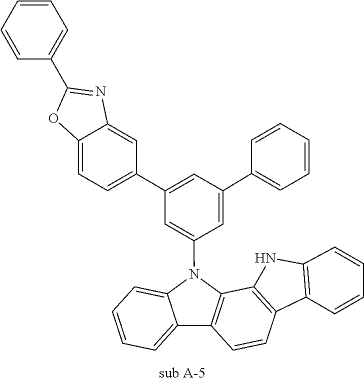 [SMILES: c1ccc(-c2cc(-c3ccc4oc(-c5ccccc5)nc4c3)cc(-n3c4ccccc4c4ccc5c6ccccc6[nH]c5c43)c2)cc1] | 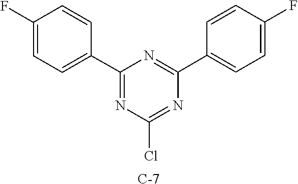 |
| 10 | 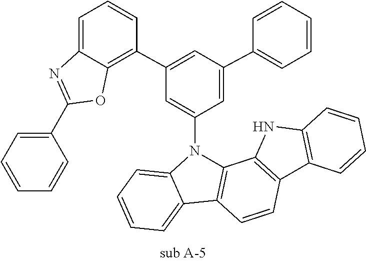 [SMILES: c1ccc(-c2cc(-c3cccc4nc(-c5ccccc5)oc34)cc(-n3c4ccccc4c4ccc5c6ccccc6[nH]c5c43)c2)cc1] | 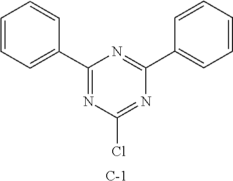 |
| 11 | 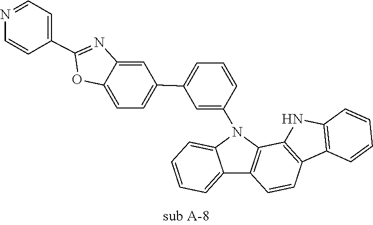 [SMILES: c1cc(-c2ccc3oc(-c4ccncc4)nc3c2)cc(-n2c3ccccc3c3ccc4c5ccccc5[nH]c4c32)c1] | 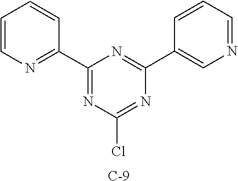 |
| 12 | 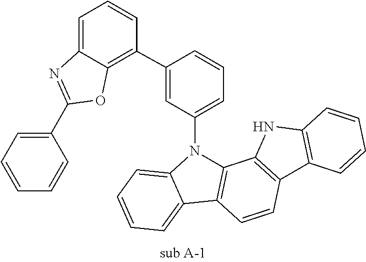 [SMILES: c1ccc(-c2nc3cccc(-c4cccc(-n5c6ccccc6c6ccc7c8ccccc8[nH]c7c65)c4)c3o2)cc1] | 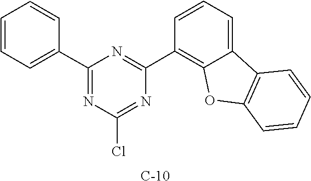 |
| 13 | 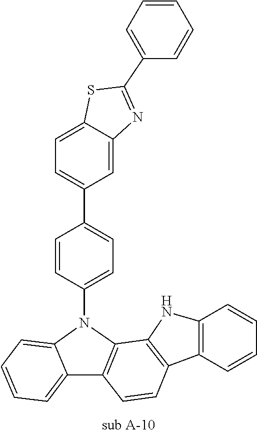 [SMILES: c1ccc(-c2nc3cc(-c4ccc(-n5c6ccccc6c6ccc7c8ccccc8[nH]c7c65)cc4)ccc3s2)cc1] | 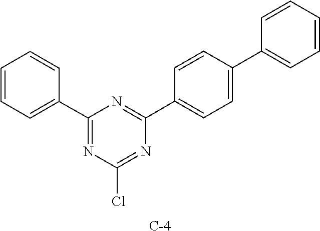 |
| 14 | 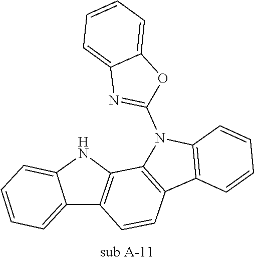 [SMILES: c1ccc2oc(-n3c4ccccc4c4ccc5c6ccccc6[nH]c5c43)nc2c1] | 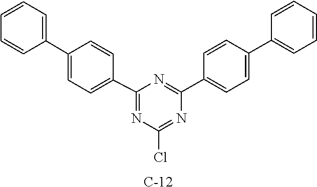 |
| 15 | 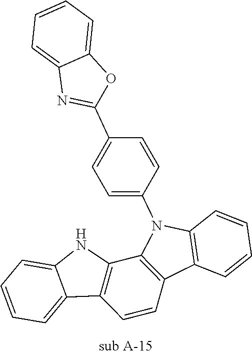 [SMILES: c1ccc2oc(-c3ccc(-n4c5ccccc5c5ccc6c7ccccc7[nH]c6c54)cc3)nc2c1] | 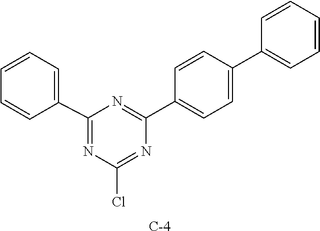 |
| 16 | 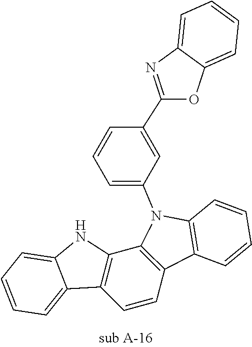 [SMILES: c1cc(-c2nc3ccccc3o2)cc(-n2c3ccccc3c3ccc4c5ccccc5[nH]c4c32)c1] | 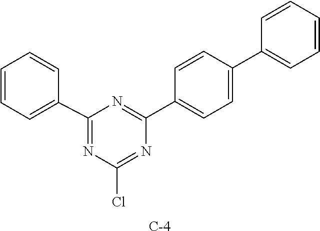 |
| 17 | 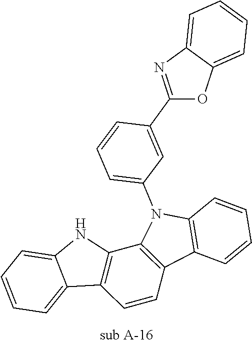 [SMILES: c1cc(-c2nc3ccccc3o2)cc(-n2c3ccccc3c3ccc4c5ccccc5[nH]c4c32)c1] | 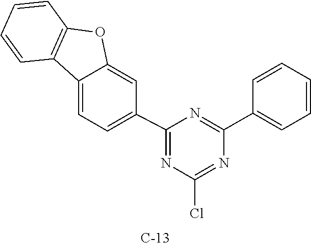 |
| 18 | 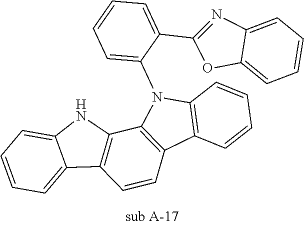 [SMILES: c1ccc(-n2c3ccccc3c3ccc4c5ccccc5[nH]c4c32)c(-c2nc3ccccc3o2)c1] | 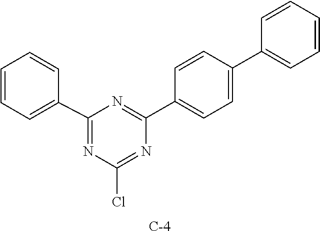 |
| 19 | 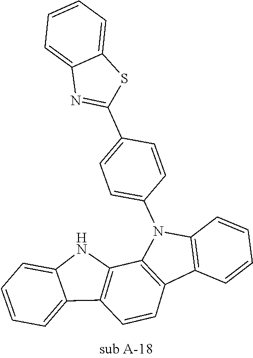 [SMILES: c1ccc2sc(-c3ccc(-n4c5ccccc5c5ccc6c7ccccc7[nH]c6c54)cc3)nc2c1] | 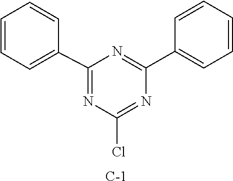 |
| 20 | 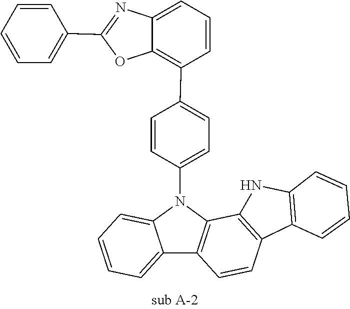 [SMILES: c1ccc(-c2nc3cccc(-c4ccc(-n5c6ccccc6c6ccc7c8ccccc8[nH]c7c65)cc4)c3o2)cc1] | 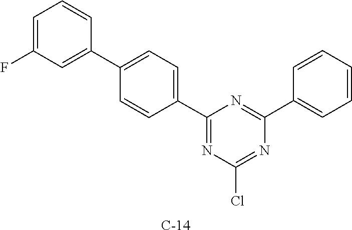 |

| Preparation | | | Mass |
|---|---|---|---|
| example | Compound | Yield | spectrum |
| 2 | 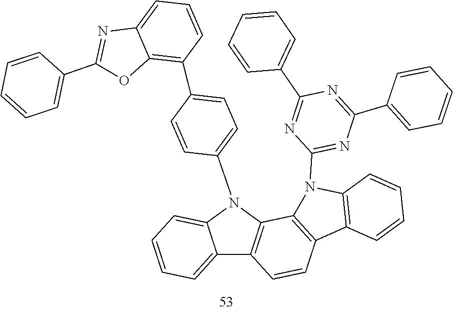 [SMILES: c1ccc(-c2nc(-c3ccccc3)nc(-n3c4ccccc4c4ccc5c6ccccc6n(-c6ccc(-c7cccc8nc(-c9ccccc9)oc78)cc6)c5c43)n2)cc1] | 81 | 757.26 |
| 3 | 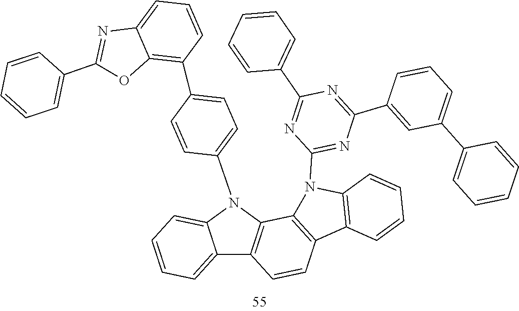 [SMILES: c1ccc(-c2cccc(-c3nc(-c4ccccc4)nc(-n4c5ccccc5c5ccc6c7ccccc7n(-c7ccc(-c8cccc9nc(-c%10ccccc%10)oc89)cc7)c6c54)n3)c2)cc1] | 75 | 833.30 |
| 4 | 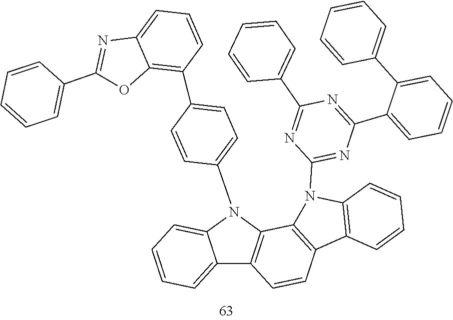 [SMILES: c1ccc(-c2nc(-c3ccccc3-c3ccccc3)nc(-n3c4ccccc4c4ccc5c6ccccc6n(-c6ccc(-c7cccc8nc(-c9ccccc9)oc78)cc6)c5c43)n2)cc1] | 65 | 833.30 |
| 5 | 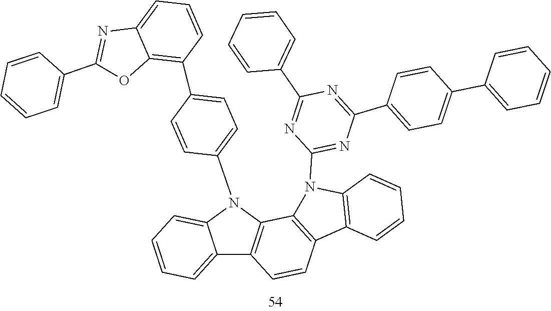 [SMILES: c1ccc(-c2ccc(-c3nc(-c4ccccc4)nc(-n4c5ccccc5c5ccc6c7ccccc7n(-c7ccc(-c8cccc9nc(-c%10ccccc%10)oc89)cc7)c6c54)n3)cc2)cc1] | 74 | 833.30 |
| 6 | 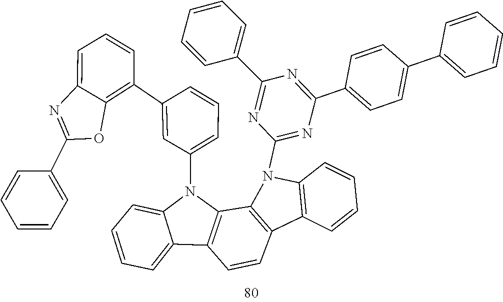 [SMILES: c1ccc(-c2ccc(-c3nc(-c4ccccc4)nc(-n4c5ccccc5c5ccc6c7ccccc7n(-c7cccc(-c8cccc9nc(-c%10ccccc%10)oc89)c7)c6c54)n3)cc2)cc1] | 85 | 833.30 |
| 7 | 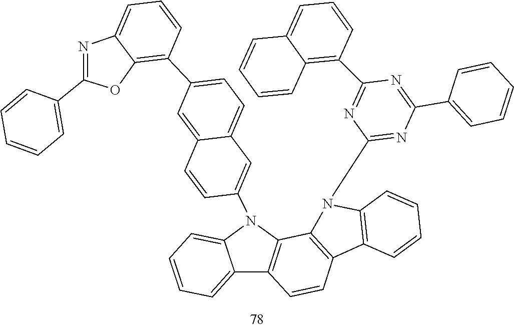 [SMILES: c1ccc(-c2nc(-c3cccc4ccccc34)nc(-n3c4ccccc4c4ccc5c6ccccc6n(-c6ccc7cc(-c8cccc9nc(-c%10ccccc%10)oc89)ccc7c6)c5c43)n2)cc1] | 71 | 857.30 |
| 8 | 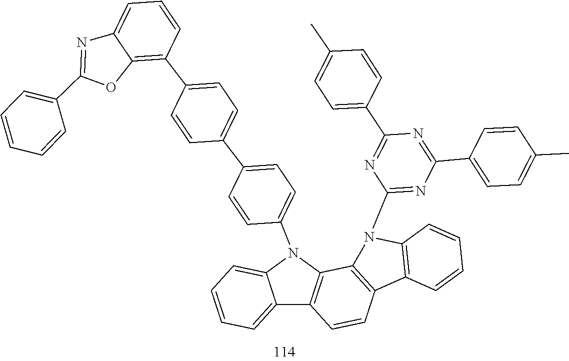 [SMILES: Cc1ccc(-c2nc(-c3ccc(C)cc3)nc(-n3c4ccccc4c4ccc5c6ccccc6n(-c6ccc(-c7ccc(-c8cccc9nc(-c%10ccccc%10)oc89)cc7)cc6)c5c43)n2)cc1] | 65 | 861.33 |
| 9 | 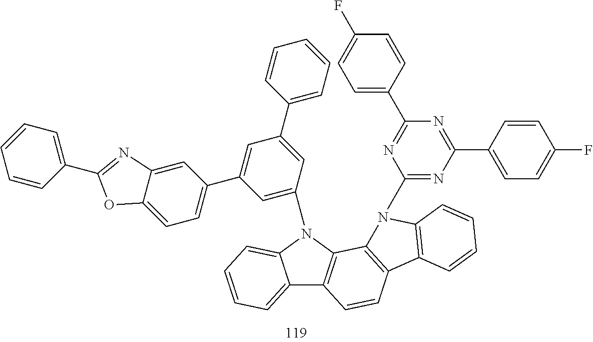 [SMILES: Fc1ccc(-c2nc(-c3ccc(F)cc3)nc(-n3c4ccccc4c4ccc5c6ccccc6n(-c6cc(-c7ccccc7)cc(-c7ccc8oc(-c9ccccc9)nc8c7)c6)c5c43)n2)cc1] | 62 | 869.28 |
| 10 | 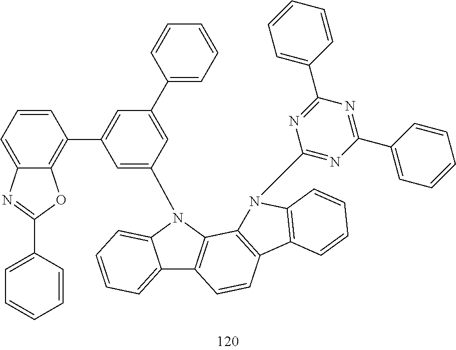 [SMILES: c1ccc(-c2cc(-c3cccc4nc(-c5ccccc5)oc34)cc(-n3c4ccccc4c4ccc5c6ccccc6n(-c6nc(-c7ccccc7)nc(-c7ccccc7)n6)c5c43)c2)cc1] | 64 | 833.30 |
| 11 | 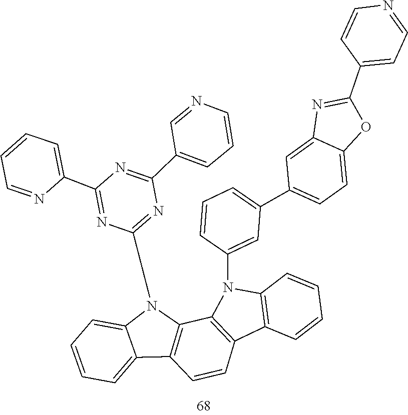 [SMILES: c1ccc(-c2nc(-c3cccnc3)nc(-n3c4ccccc4c4ccc5c6ccccc6n(-c6cccc(-c7ccc8oc(-c9ccncc9)nc8c7)c6)c5c43)n2)nc1] | 58 | 760.25 |
| 12 | 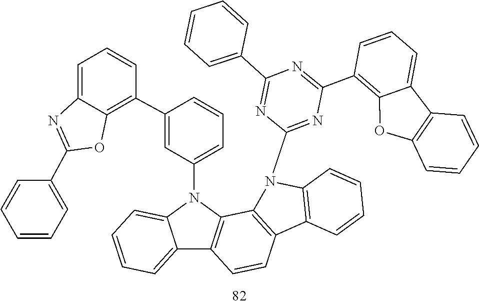 [SMILES: c1ccc(-c2nc(-c3cccc4c3oc3ccccc34)nc(-n3c4ccccc4c4ccc5c6ccccc6n(-c6cccc(-c7cccc8nc(-c9ccccc9)oc78)c6)c5c43)n2)cc1] | 59 | 847.27 |
| 13 | 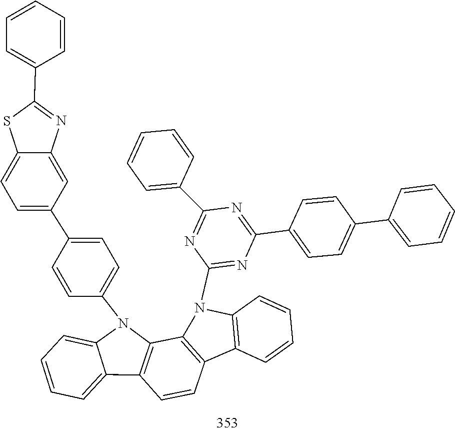 [SMILES: c1ccc(-c2ccc(-c3nc(-c4ccccc4)nc(-n4c5ccccc5c5ccc6c7ccccc7n(-c7ccc(-c8ccc9sc(-c%10ccccc%10)nc9c8)cc7)c6c54)n3)cc2)cc1] | 58 | 849.27 |
| 14 | 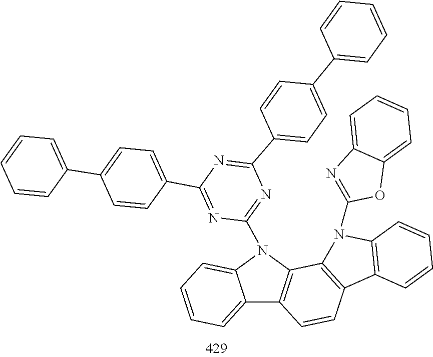 [SMILES: c1ccc(-c2ccc(-c3nc(-c4ccc(-c5ccccc5)cc4)nc(-n4c5ccccc5c5ccc6c7ccccc7n(-c7nc8ccccc8o7)c6c54)n3)cc2)cc1] | 85 | 757.26 |
| 15 | 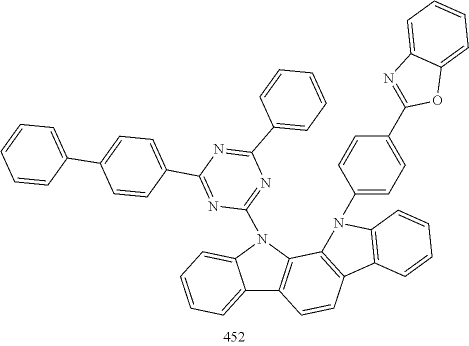 [SMILES: c1ccc(-c2ccc(-c3nc(-c4ccccc4)nc(-n4c5ccccc5c5ccc6c7ccccc7n(-c7ccc(-c8nc9ccccc9o8)cc7)c6c54)n3)cc2)cc1] | 73 | 757.26 |
| 16 | 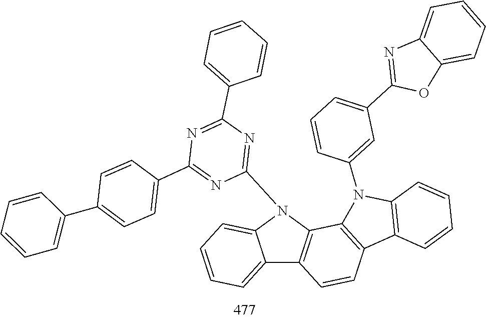 [SMILES: c1ccc(-c2ccc(-c3nc(-c4ccccc4)nc(-n4c5ccccc5c5ccc6c7ccccc7n(-c7cccc(-c8nc9ccccc9o8)c7)c6c54)n3)cc2)cc1] | 63 | 757.26 |
| 17 | 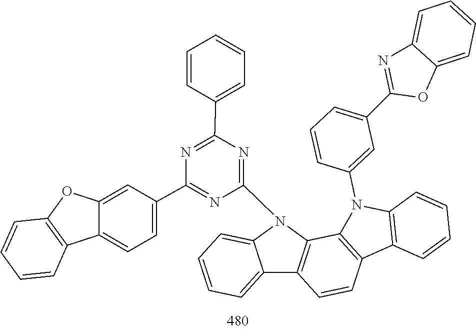 [SMILES: c1ccc(-c2nc(-c3ccc4c(c3)oc3ccccc34)nc(-n3c4ccccc4c4ccc5c6ccccc6n(-c6cccc(-c7nc8ccccc8o7)c6)c5c43)n2)cc1] | 70 | 771.25 |
| 18 | 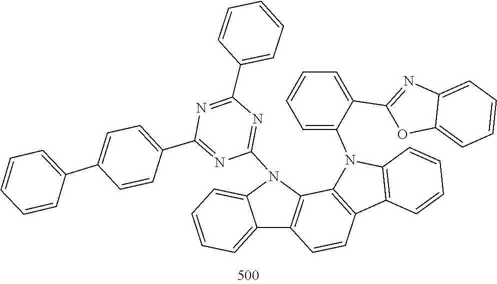 [SMILES: c1ccc(-c2ccc(-c3nc(-c4ccccc4)nc(-n4c5ccccc5c5ccc6c7ccccc7n(-c7ccccc7-c7nc8ccccc8o7)c6c54)n3)cc2)cc1] | 57 | 757.26 |
| 19 | 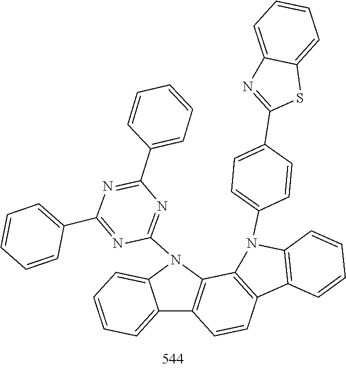 [SMILES: c1ccc(-c2nc(-c3ccccc3)nc(-n3c4ccccc4c4ccc5c6ccccc6n(-c6ccc(-c7nc8ccccc8s7)cc6)c5c43)n2)cc1] | 68 | 697.21 |
| 20 | 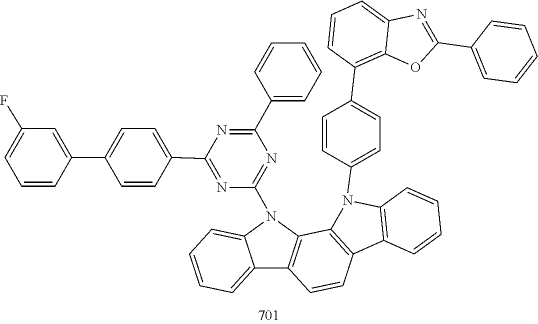 [SMILES: Fc1cccc(-c2ccc(-c3nc(-c4ccccc4)nc(-n4c5ccccc5c5ccc6c7ccccc7n(-c7ccc(-c8cccc9nc(-c%10ccccc%10)oc89)cc7)c6c54)n3)cc2)c1] | 56 | 851.29 |

### Preparation Example 21: Synthesis of Compound 257

(1) Synthesis of Intermediate Sub 1-I-A11

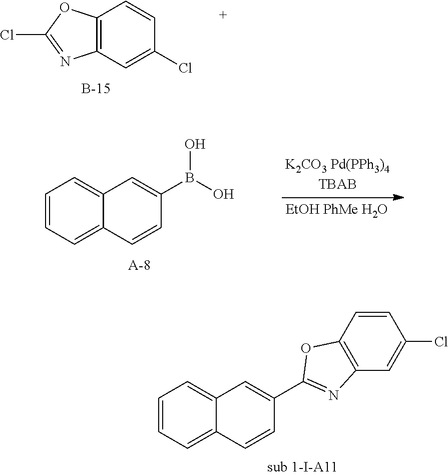

Nitrogen (0.100 L/min) was introduced into a three-necked flask equipped with a mechanical stirrer, a thermometer, and an Allihn condenser for replacement for 15 min, and 2,5-dichlorobenzoxazole (35.0 g, 186.1 mmol) (a reactant B-15), 2-naphthaleneboronic acid (32.0, 186.1 mmol) (a reactant A-8), potassium carbonate (64.3 g, 465.4 mmol), tetrakis(triphenylphosphine)palladium (4.3 g, 3.7 mmol), tetrabutylammonium bromide (1.2 g, 3.72 mmol) and a mixed solvent of toluene (280 mL), ethanol (70 mL) and water (70 mL) were added into the three-necked flask. Stirring and heating were started, after the temperature was raised to 75 to 80° C., a reaction was carried out under reflux for 15 h, and after the reaction was completed, the reaction solution was cooled to room temperature. An organic phase was extracted with toluene and water and then separated, washed with water to be neutral, dried over anhydrous magnesium sulfate, and filtered, and the obtained filtrate was concentrated by distillation under reduced pressure; and a crude product was purified by silica gel column chromatography using a dichloromethane/n-heptane system to obtain a compound intermediate sub1-I-A11 (31.7 g, 61%) as a solid.

Referring to the synthesis method for the intermediate sub1-I-A11, intermediates shown in Table 3 below were synthesized, where a reactant B-X (X is 15, 16, or 17) was used instead of the reactant B-15, and a reactant A-X (X is 9, 10, 11, or 14) was used instead of the reactant A-8 to synthesize intermediates sub1-I-AX (X is 12, 13, 14, or 17) shown in Table 3 below.

TABLE 3

| Reactant (B-X) | Reactant (A-X) | Intermediate (sub 1-I-AX) | Yield % |
|---|---|---|---|
| 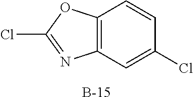 | 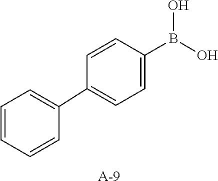 [SMILES: OB(O)c1ccc(-c2ccccc2)cc1 ; "A-9"] | 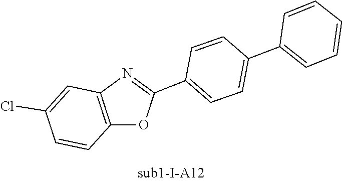 [SMILES: Clc1ccc2oc(-c3ccc(-c4ccccc4)cc3)nc2c1] | 69 |
| 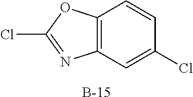 | 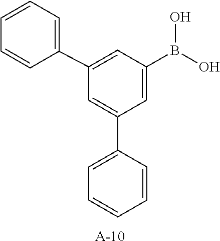 | 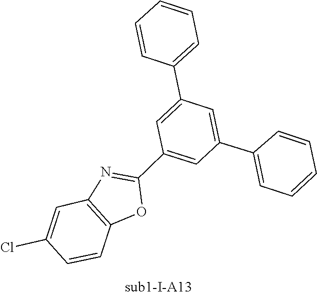 [SMILES: Clc1ccc2oc(-c3cc(-c4ccccc4)cc(-c4ccccc4)c3)nc2c1] | 56 |
| 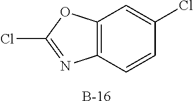 | 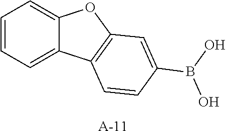 | 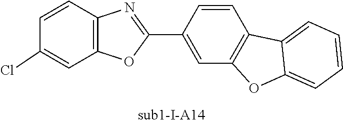 [SMILES: Clc1ccc2nc(-c3ccc4c(c3)oc3ccccc34)oc2c1] | 54 |
| 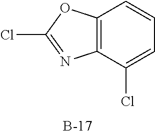 | 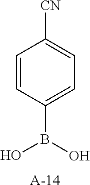 | 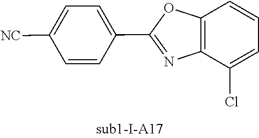 [SMILES: N#Cc1ccc(-c2nc3c(Cl)cccc3o2)cc1] | 54 |

(2) Synthesis of Compound 257

Referring to the synthesis method for the compound 67, compounds shown in Table 4 below were synthesized, where intermediates sub1-I-AX (X is 11, 12, 13, 14, or 17) were used instead of the intermediate sub1-I-A1, and a reactant C-X (X is 1, 2, 4, or 14 to 18) was used instead of the reactant C-1 to synthesize the compounds shown in Table 4 below.

TABLE 4

| Preparation | Intermediate | |
|---|---|---|
| example | (sub1-I-AX) | Reactant (C-X) |
| 21 | 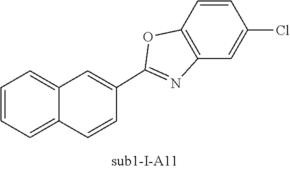 [SMILES: Clc1ccc2oc(-c3ccc4ccccc4c3)nc2c1] | 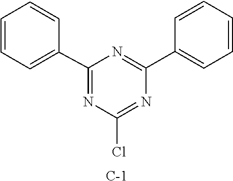 |
| 22 | 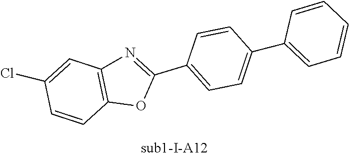 [SMILES: Clc1ccc2oc(-c3ccc(-c4ccccc4)cc3)nc2c1] | 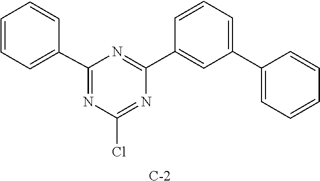 |
| 23 | 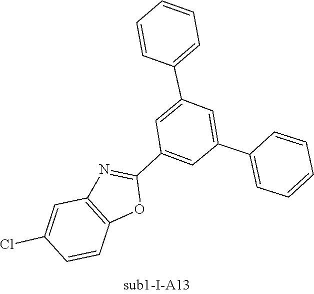 [SMILES: Clc1ccc2oc(-c3cc(-c4ccccc4)cc(-c4ccccc4)c3)nc2c1] | 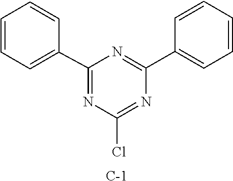 |
| 24 | 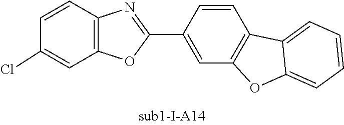 [SMILES: Clc1ccc2nc(-c3ccc4c(c3)oc3ccccc34)oc2c1] | 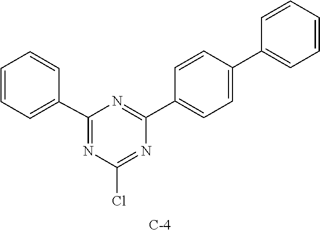 |
| 25 | 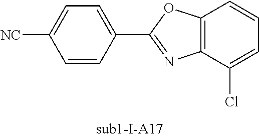 [SMILES: N#Cc1ccc(-c2nc3c(Cl)cccc3o2)cc1] | 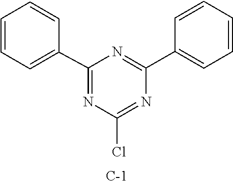 |
| 26 | 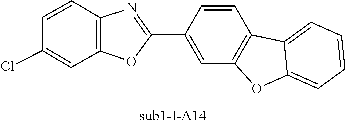 [SMILES: Clc1ccc2nc(-c3ccc4c(c3)oc3ccccc34)oc2c1] | 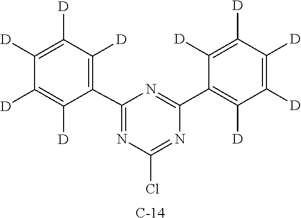 |
| 27 | 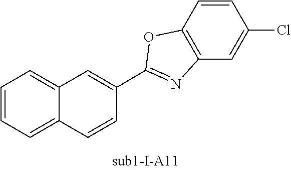 [SMILES: Clc1ccc2oc(-c3ccc4ccccc4c3)nc2c1] | 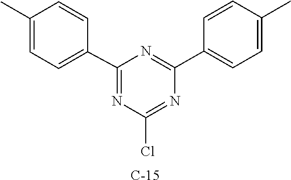 |
| 28 | 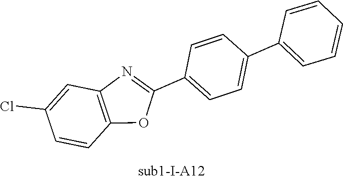 [SMILES: Clc1ccc2oc(-c3ccc(-c4ccccc4)cc3)nc2c1] | 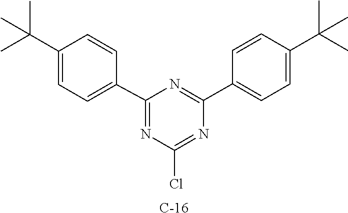 |
| 29 | 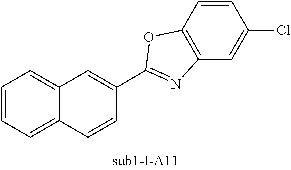 [SMILES: Clc1ccc2oc(-c3ccc4ccccc4c3)nc2c1] | 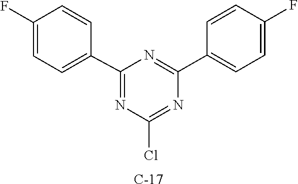 |
| 30 | 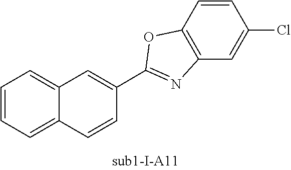 [SMILES: Clc1ccc2oc(-c3ccc4ccccc4c3)nc2c1] | 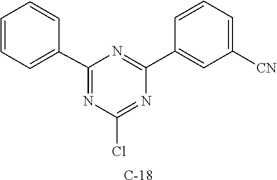 |

| Preparation | | Yield | Mass |
|---|---|---|---|
| example | Compound | % | spectrum |
| 21 | 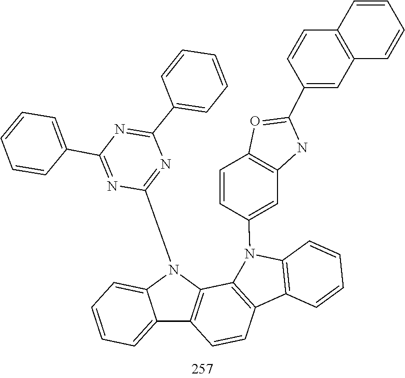 | 51 | 731.25 |
| 22 | 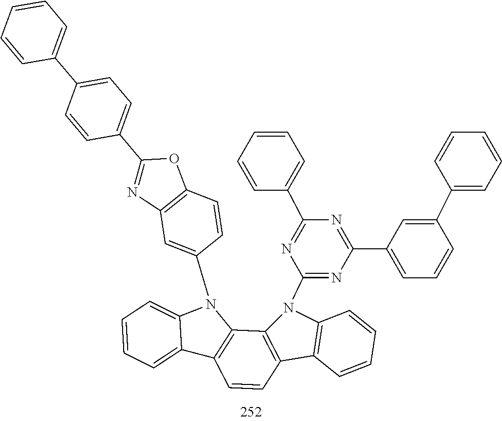 [SMILES: c1ccc(-c2ccc(-c3nc4cc(-n5c6ccccc6c6ccc7c8ccccc8n(-c8nc(-c9ccccc9)nc(-c9cccc(-c%10ccccc%10)c9)n8)c7c65)ccc4o3)cc2)cc1] | 55 | 833.30 |
| 23 | 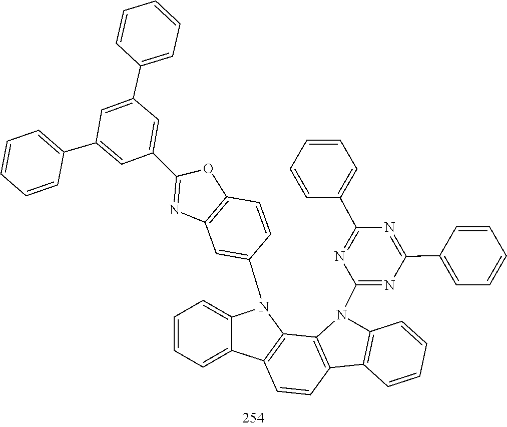 [SMILES: c1ccc(-c2cc(-c3ccccc3)cc(-c3nc4cc(-n5c6ccccc6c6ccc7c8ccccc8n(-c8nc(-c9ccccc9)nc(-c9ccccc9)n8)c7c65)ccc4o3)c2)cc1] | 57 | 833.30 |
| 24 | 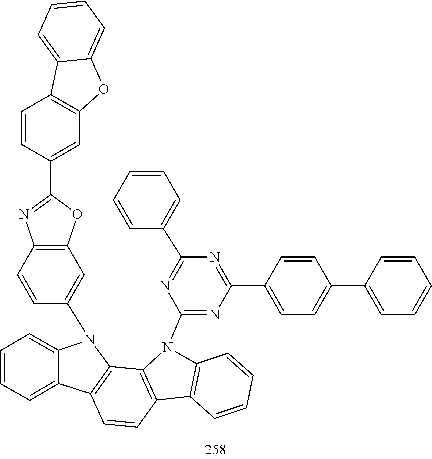 [SMILES: c1ccc(-c2ccc(-c3nc(-c4ccccc4)nc(-n4c5ccccc5c5ccc6c7ccccc7n(-c7ccc8nc(-c9ccc%10c(c9)oc9ccccc9%10)oc8c7)c6c54)n3)cc2)cc1] | 46 | 847.27 |
| 25 | 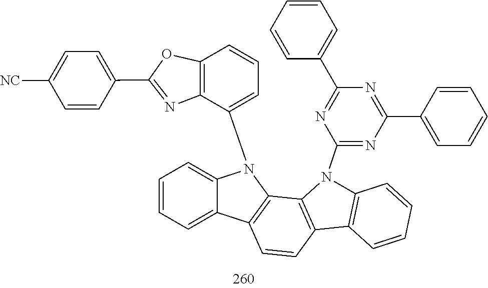 [SMILES: N#Cc1ccc(-c2nc3c(-n4c5ccccc5c5ccc6c7ccccc7n(-c7nc(-c8ccccc8)nc(-c8ccccc8)n7)c6c54)cccc3o2)cc1] | 64 | 706.23 |
| 26 | 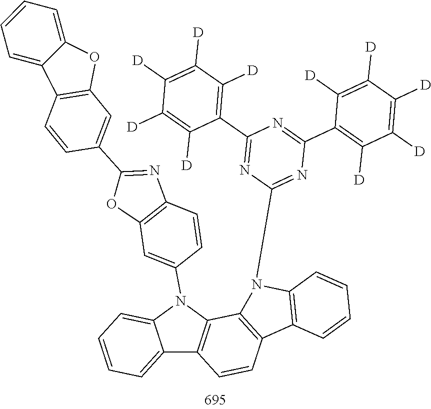 [SMILES: [2H]c1c([2H])c([2H])c(-c2nc(-c3c([2H])c([2H])c([2H])c([2H])c3[2H])nc(-n3c4ccccc4c4ccc5c6ccccc6n(-c6ccc7nc(-c8ccc9c(c8)oc8ccccc89)oc7c6)c5c43)n2)c([2H])c1[2H]] | 51 | 781.31 |
| 27 | 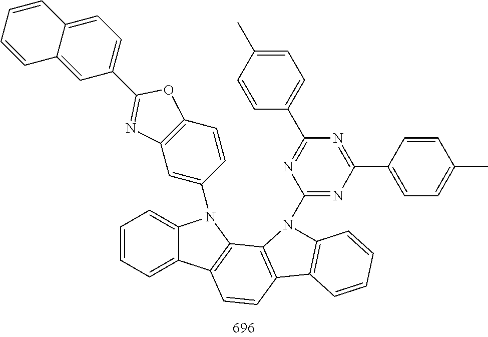 [SMILES: Cc1ccc(-c2nc(-c3ccc(C)cc3)nc(-n3c4ccccc4c4ccc5c6ccccc6n(-c6ccc7oc(-c8ccc9ccccc9c8)nc7c6)c5c43)n2)cc1] | 42 | 759.29 |
| 28 | 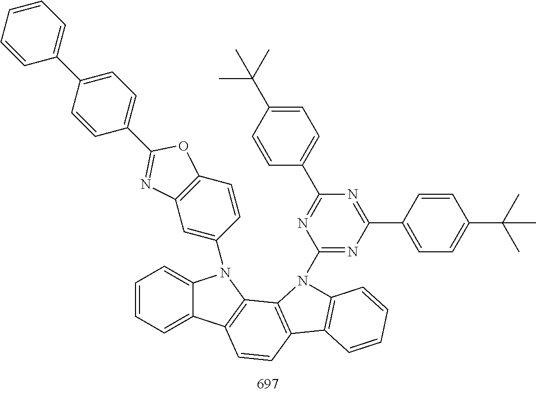 [SMILES: CC(C)(C)c1ccc(-c2nc(-c3ccc(C(C)(C)C)cc3)nc(-n3c4ccccc4c4ccc5c6ccccc6n(-c6ccc7oc(-c8ccc(-c9ccccc9)cc8)nc7c6)c5c43)n2)cc1] | 60 | 869.40 |
| 29 | 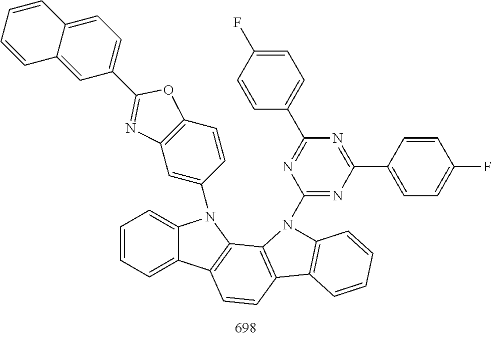 [SMILES: Fc1ccc(-c2nc(-c3ccc(F)cc3)nc(-n3c4ccccc4c4ccc5c6ccccc6n(-c6ccc7oc(-c8ccc9ccccc9c8)nc7c6)c5c43)n2)cc1] | 46 | 767.24 |
| 30 | 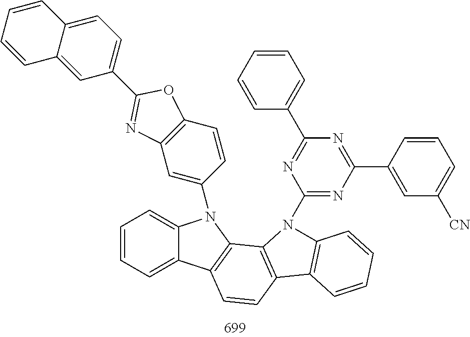 [SMILES: N#Cc1cccc(-c2nc(-c3ccccc3)nc(-n3c4ccccc4c4ccc5c6ccccc6n(-c6ccc7oc(-c8ccc9ccccc9c8)nc7c6)c5c43)n2)c1] | 57 | 756.25 |

### Preparation Example 31 Synthesis of Compound 121

(1) Synthesis of Intermediate Sub A-19

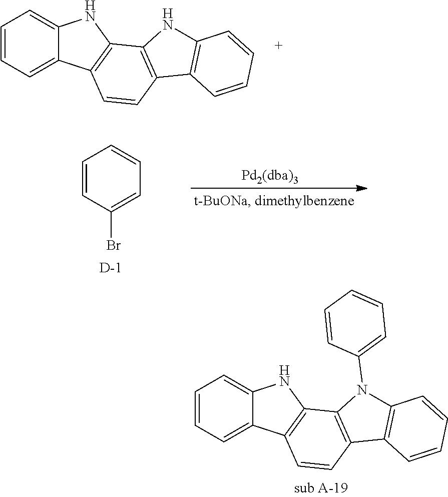

Nitrogen (0.100 L/min) was introduced into a three-necked flask equipped with a mechanical stirrer, a thermometer, and an Allihn condenser for replacement for 15 min, and indolo[2,3-A]carbazole (50.0 g, 195.1 mmol), bromobenzene (27.5 g, 175.5 mmol) (a reactant D-1), Pd₂(dba)₃ (3.5 g, 3.9 mmol), tri-tert-butylphosphine (1.6 g, 7.8 mmol), sodium tert-butoxide (41.2 g, 429.2 mmol), and xylene (500 mL) were added into the three-necked flask. Stirring and heating were started, after the temperature was raised to 135 to 145° C., a reaction was carried out under reflux for 10 h, and after the reaction was completed, the reaction solution was cooled to room temperature. The reaction solution was extracted with toluene and water, an organic phase was dried over anhydrous magnesium sulfate, and filtered, the obtained filtrate was concentrated by distillation under reduced pressure, and a crude product was purified by silica gel column chromatography using a dichloromethane/n-heptane system to obtain an intermediate sub A-19 (47.3 g, 73%) as a solid.

Referring to the synthesis method for the intermediate sub A-19, intermediates shown in Table 5 below were synthesized, where a reactant D-X (X is 2 to 6 or 8) was used instead of the reactant D-1 to synthesize intermediates sub A-X (X is 20 to 24 or 26) shown in Table 5 below.

TABLE 5

| Reactant (D-X) | Intermediate (sub A-X) | Yield % |
|---|---|---|
| 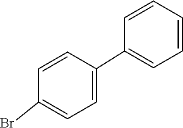 [SMILES: Brc1ccc(-c2ccccc2)cc1] D-2 | 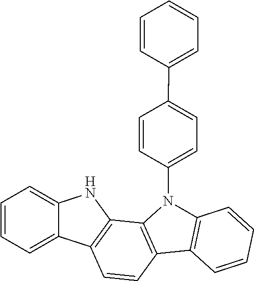 [SMILES: c1ccc(-c2ccc(-n3c4ccccc4c4ccc5c6ccccc6[nH]c5c43)cc2)cc1] | 66 |
| | sub A-20 | |
| 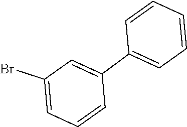 [SMILES: Brc1cccc(-c2ccccc2)c1] D-3 | 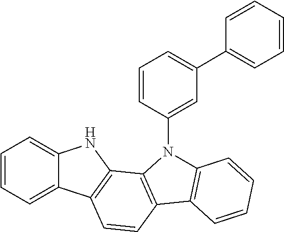 [SMILES: c1ccc(-c2cccc(-n3c4ccccc4c4ccc5c6ccccc6[nH]c5c43)c2)cc1] | 64 |
| | sub A-21 | |
| 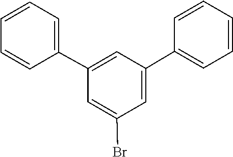 [SMILES: Brc1cc(-c2ccccc2)cc(-c2ccccc2)c1] D-4 | 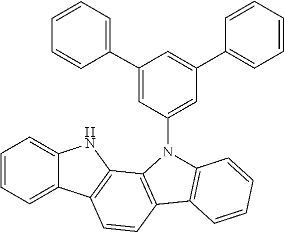 [SMILES: c1ccc(-c2cc(-c3ccccc3)cc(-n3c4ccccc4c4ccc5c6ccccc6[nH]c5c43)c2)cc1] | 60 |
| | sub A-22 | |
| 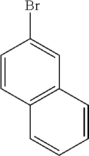 [SMILES: Brc1ccc2ccccc2c1] D-5 | 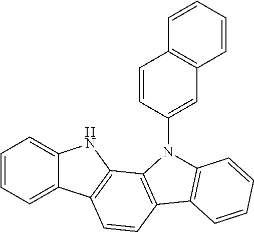 [SMILES: c1ccc2cc(-n3c4ccccc4c4ccc5c6ccccc6[nH]c5c43)ccc2c1] | 62 |
| | sub A-23 | |
| 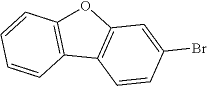 [SMILES: Brc1ccc2c(c1)oc1ccccc12] D-6 | 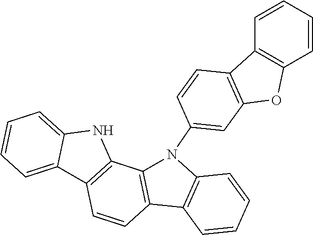 [SMILES: c1ccc2c(c1)[nH]c1c2ccc2c3ccccc3n(-c3ccc4c(c3)oc3ccccc34)c21] | 52 |
| | sub A-24 | |
| 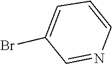 D-8 | 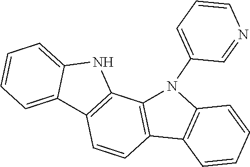 [SMILES: c1cncc(-n2c3ccccc3c3ccc4c5ccccc5[nH]c4c32)c1] | 73 |
| | sub A-26 | |

(2) Synthesis of Intermediate Sub B-1

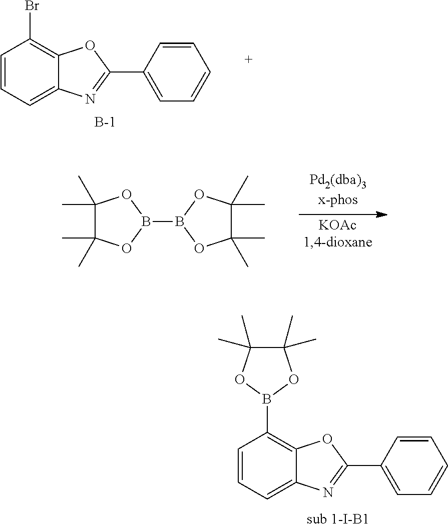

Nitrogen (0.100 L/min) was introduced into a three-necked flask equipped with a mechanical stirrer, a thermometer, and an Allihn condenser for replacement for 15 min, and the reactant B-1 (55.0 g, 200.6 mmol), bis(pinacolato)diboron (76.4 g, 300.9 mmol), 1,4-dioxane (600 mL), potassium acetate (49.2 g, 501.6 mmol), x-phos (1.9 g, 4.0 mmol), and Pd₂(dba)₃ (1.8 g, 2.0 mmol) were successively added into the three-necked flask, the mixture was raised to 95 to 105° C., and subjected to a reaction under reflux for 14 h, and after the reaction was completed, the reaction solution was cooled to room temperature. The reaction solution was extracted with toluene and water, an organic phase was dried over anhydrous magnesium sulfate, and filtered, the obtained filtrate was concentrated by distillation under reduced pressure, and the obtained product was pulped with ethanol, and filtered to obtain an intermediate sub 1-I-B1 (54.1 g, 84%).

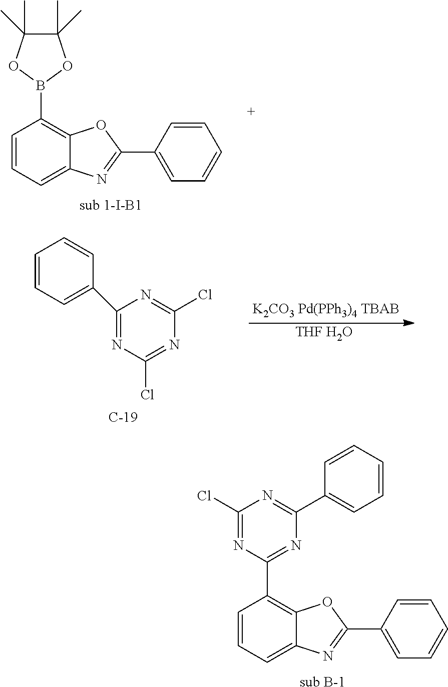

Nitrogen (0.100 L/min) was introduced into a three-necked flask equipped with a mechanical stirrer, a thermometer, and an Allihn condenser for replacement for 15 min, and the intermediate sub 1-I-B1 (45.5 g, 141.5 mmol), 2,4-dichloro-6-phenyl-1,3,5-triazine (40.0 g, 176.9 mmol) (a reactant C-19), tetrakis(triphenylphosphine)palladium (2.0 g, 1.7 mmol), potassium carbonate (61.1 g, 442.3 mmol), tetrabutylammonium bromide (1.1 g, 3.5 mmol), tetrahydrofuran (320 mL) and deionized water (80 mL) were successively added into the three-necked flask; and stirring and heating were started, after the temperature was raised to 60 to 70° C., a reaction was carried out under reflux for 10 h, and after the reaction was completed, the reaction solution was cooled to room temperature. The reaction solution was extracted with toluene and water, the organic phases were combined, dried over anhydrous magnesium sulfate, filtered, and concentrated, and a crude product was purified by silica gel column chromatography using a dichloromethane/n-heptane system to obtain an intermediate sub B-1 (38.1 g, yield: 56%) as a solid.

Referring to the synthesis method for the intermediate sub B-1, intermediates shown in Table 6 below were synthesized, where a reactant C-X (X is 20, 22, 23 or 24) was used instead of the reactant C-19 to synthesize intermediates sub B-X (X is 2, 4, 5 or 6) shown in Table 6 below.

TABLE 6

| Reactant (C-X) | Intermediate (sub B-X) | Yield % |
|---|---|---|
| 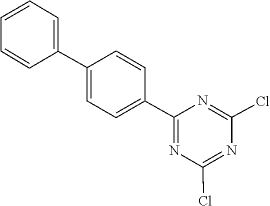 [SMILES: Clc1nc(Cl)nc(-c2ccc(-c3ccccc3)cc2)n1] C-20 | 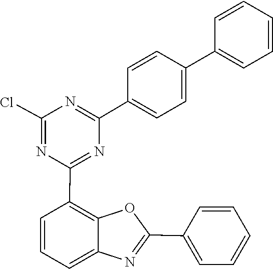 [SMILES: Clc1nc(-c2ccc(-c3ccccc3)cc2)nc(-c2cccc3nc(-c4ccccc4)oc23)n1] | 62 |
| | sub B-2 | |
| | | 57 |
| 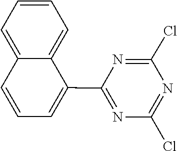 [SMILES: Clc1nc(Cl)nc(-c2cccc3ccccc23)n1] C-22 | 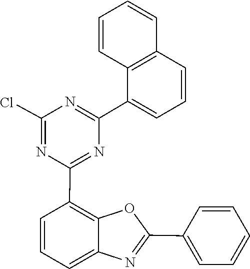 [SMILES: Clc1nc(-c2cccc3ccccc23)nc(-c2cccc3nc(-c4ccccc4)oc23)n1] | |
| | sub B-4 | 60 |
| 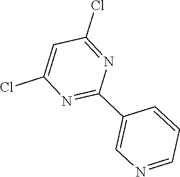 [SMILES: Clc1cc(Cl)nc(-c2cccnc2)n1] C-23 | 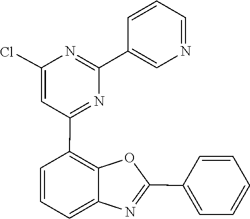 [SMILES: Clc1cc(-c2cccc3nc(-c4ccccc4)oc23)nc(-c2cccnc2)n1] | |
| | sub B-5 | 67 |
| 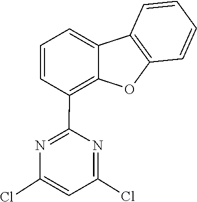 [SMILES: Clc1cc(Cl)nc(-c2cccc3c2oc2ccccc23)n1] C-24 | 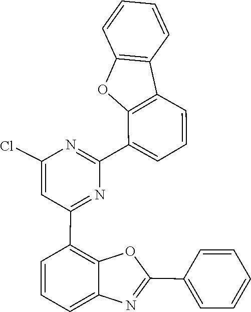 [SMILES: Clc1cc(-c2cccc3nc(-c4ccccc4)oc23)nc(-c2cccc3c2oc2ccccc23)n1] | |
| | sub B-6 | |

(3) Synthesis of Compound 121

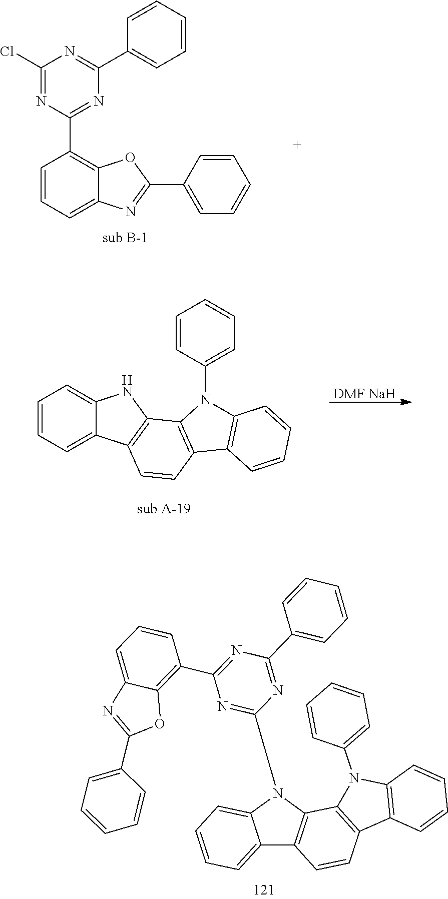

Nitrogen (0.100 L/min) was introduced into a three-necked flask equipped with a mechanical stirrer, a thermometer, and an Allihn condenser for replacement for 15 min, the intermediate sub A-19 (20.0 g, 60.2 mmol), the intermediate sub B-1 (27.7 g, 72.2 mmol), and DMF (200 mL) were added into the three-necked flask, the temperature was cooled to 0° C., after NaH (1.6 g, 66.2 mmol) was added into the reaction solution, the system was changed from white to yellow, after the temperature was naturally raised to room temperature, solid was precipitated and the reaction was completed. The reaction solution was washed with water and filtered to obtain a solid product, the solid product was rinsed with a small amount of ethanol, and a crude product was recrystallized by using toluene to obtain a compound 121 (23.3 g, 57%). Mass spectrum: m/z=681.23 [M+H]⁺.

Compounds shown in Table 7 below were synthesized with reference to the synthesis method for the compound 121, where intermediates sub A-X (X is 19, 22 to 24, or 26) were used instead of the intermediate sub A-19, and intermediates sub B-X (X is 2 or 4 to 6) were used instead of the intermediate sub B-1 to synthesize the compounds shown in Table 7 below.

TABLE 7

| Preparation | Intermediate | Intermediate | | Yield | Mass |
|---|---|---|---|---|---|
| example | (sub A-X) | (sub B-X) | Compound | % | spectrum |
| 32 | 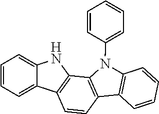 [SMILES: c1ccc(-n2c3ccccc3c3ccc4c5ccccc5[nH]c4c32)cc1] sub A-19 | 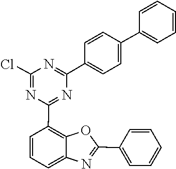 [SMILES: Clc1nc(-c2ccc(-c3ccccc3)cc2)nc(-c2cccc3nc(-c4ccccc4)oc23)n1] sub B-2 | 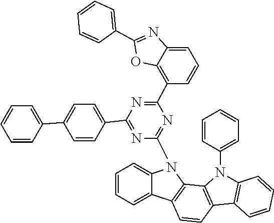 [SMILES: c1ccc(-c2ccc(-c3nc(-c4cccc5nc(-c6ccccc6)oc45)nc(-n4c5ccccc5c5ccc6c7ccccc7n(-c7ccccc7)c6c54)n3)cc2)cc1] | 68 | 757.26 |
| | | | 122 | | |
| 33 | 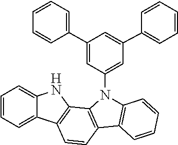 [SMILES: c1ccc(-c2cc(-c3ccccc3)cc(-n3c4ccccc4c4ccc5c6ccccc6[nH]c5c43)c2)cc1] sub A-22 | 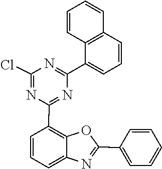 [SMILES: Clc1nc(-c2cccc3ccccc23)nc(-c2cccc3nc(-c4ccccc4)oc23)n1] sub B-4 | 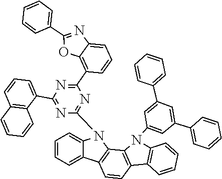 [SMILES: c1ccc(-c2cc(-c3ccccc3)cc(-n3c4ccccc4c4ccc5c6ccccc6n(-c6nc(-c7cccc8ccccc78)nc(-c7cccc8nc(-c9ccccc9)oc78)n6)c5c43)c2)cc1] 188 | 57 | 883.31 |
| 34 | 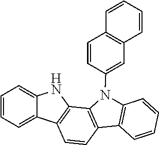 [SMILES: c1ccc2cc(-n3c4ccccc4c4ccc5c6ccccc6[nH]c5c43)ccc2c1] sub A-23 | 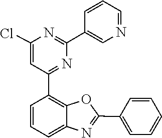 [SMILES: Clc1cc(-c2cccc3nc(-c4ccccc4)oc23)nc(-c2cccnc2)n1] sub B-5 | 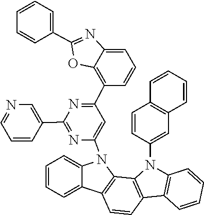 [SMILES: c1ccc(-c2nc3cccc(-c4cc(-n5c6ccccc6c6ccc7c8ccccc8n(-c8ccc9ccccc9c8)c7c65)nc(-c5cccnc5)n4)c3o2)cc1] | 58 | 731.25 |
| | | | 194 | | |
| 35 | 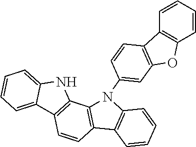 [SMILES: c1ccc2c(c1)[nH]c1c2ccc2c3ccccc3n(-c3ccc4c(c3)oc3ccccc34)c21] sub A-24 | 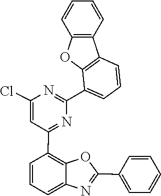 [SMILES: Clc1cc(-c2cccc3nc(-c4ccccc4)oc23)nc(-c2cccc3c2oc2ccccc23)n1] sub B-6 | 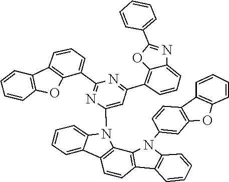 [SMILES: c1ccc(-c2nc3cccc(-c4cc(-n5c6ccccc6c6ccc7c8ccccc8n(-c8ccc9c(c8)oc8ccccc89)c7c65)nc(-c5cccc6c5oc5ccccc56)n4)c3o2)cc1] 199 | 42 | 861.246 |
| 36 | 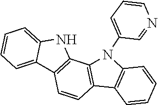 [SMILES: c1cncc(-n2c3ccccc3c3ccc4c5ccccc5[nH]c4c32)c1] sub A-26 | 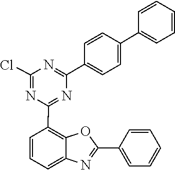 [SMILES: Clc1nc(-c2ccc(-c3ccccc3)cc2)nc(-c2cccc3nc(-c4ccccc4)oc23)n1] sub B-2 | 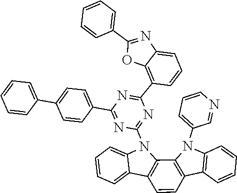 [SMILES: c1ccc(-c2ccc(-c3nc(-c4cccc5nc(-c6ccccc6)oc45)nc(-n4c5ccccc5c5ccc6c7ccccc7n(-c7cccnc7)c6c54)n3)cc2)cc1] | 63 | 758.26 |
| | | | 219 | | |

### Preparation Example 37 Synthesis of Compound 667

(1) Synthesis of Intermediate Sub B-7

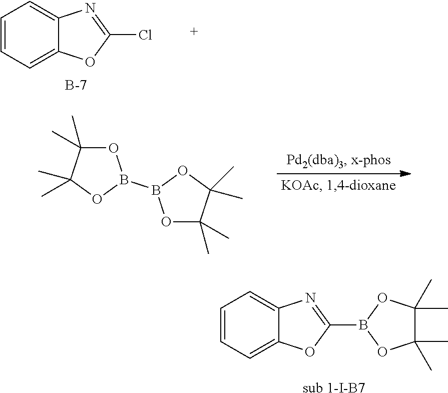

Nitrogen (0.100 L/min) was introduced into a three-necked flask equipped with a mechanical stirrer, a thermometer, and an Allihn condenser for replacement for 15 min, and a reactant B-7 (30.0 g, 195.3 mmol), bis(pinacolato)diboron (74.4 g, 293.0 mmol), 1,4-dioxane (600 mL), potassium acetate (38.3 g, 390.70 mmol), x-phos (1.8 g, 3.9 mmol), and Pd₂(dba)₃ (1.7 g, 1.9 mmol) were successively added into the three-necked flask, the mixture was heated to 95 to 105° C. and subjected to a reaction under reflux for 14 h, and after the reaction was completed, the reaction solution was cooled to room temperature. The reaction solution was extracted with toluene and water, an organic phase was dried over anhydrous magnesium sulfate, and filtered, the obtained filtrate was concentrated by distillation under reduced pressure, and the obtained product was pulped with ethanol, and filtered to obtain an intermediate sub 1-I-B7 (29.2 g, 61%).

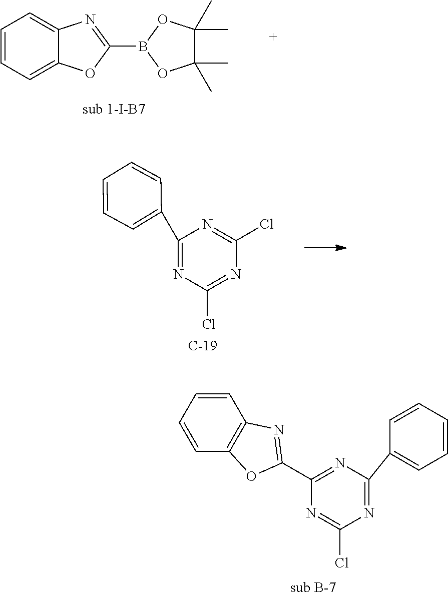

Nitrogen (0.100 L/min) was introduced into a three-necked flask equipped with a mechanical stirrer, a thermometer, and an Allihn condenser for replacement for 15 min, and the intermediate sub 1-I-B7 (25.0 g, 102.0 mmol), 2,4-dichloro-6-phenyl-1,3,5-triazine (23.0 g, 102.0 mmol) (a reactant C-19), tetrakis(triphenylphosphine)palladium (2.3 g, 2.0 mmol), potassium carbonate (28.2 g, 204.0 mmol), tetrabutylammonium bromide (0.6 g, 2.0 mmol), tetrahydrofuran (100 mL) and deionized water (25 mL) were successively added into the three-necked flask; and stirring and heating were started, after the temperature was raised to 60 to 70° C., a reaction was carried out under reflux for 10 h, and after the reaction was completed, the reaction solution was cooled to room temperature. The reaction solution was extracted with toluene and water, the organic phases were combined, dried over anhydrous magnesium sulfate, filtered, and concentrated, and a crude product was purified by silica gel column chromatography using a dichloromethane/n-heptane system to obtain an intermediate sub B-7 (17.3 g, yield: 55%) as a solid.

Referring to the synthesis method for the intermediate sub B-7, intermediates shown in Table 8 below were synthesized, where a reactant C-X (X is 20) was used instead of the reactant C-19, and a reactant B-X (X is 7 or 11) was used instead of the reactant B-7 to synthesize intermediates sub B-X (X is 8 or 9) shown in Table 8 below.

TABLE 8

| Reactant | | | Yield |
|---|---|---|---|
| (C-X) | Reactant (B-X) | Intermediate (sub B-X) | % |
| 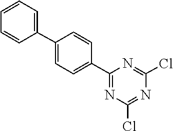 | 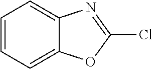 B-7 | 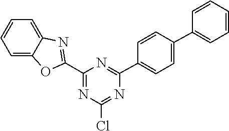 [SMILES: Clc1nc(-c2ccc(-c3ccccc3)cc2)nc(-c2nc3ccccc3o2)n1] | 58 |
| C-20 | | Sub B-8 | |
| 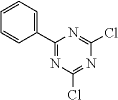 C-19 | 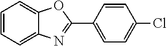 [SMILES: Clc1ccc(-c2nc3ccccc3o2)cc1] B-11 | 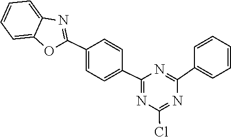 [SMILES: Clc1nc(-c2ccccc2)nc(-c2ccc(-c3nc4ccccc4o3)cc2)n1] | 51 |
| | | Sub B-9 | |

(2) Synthesis of Compound 667

Compounds shown in Table 9 below were synthesized with reference to the synthesis method for the compound 121, where intermediates sub A-X (X is 19 to 21) were used instead of the intermediate sub A-19, and intermediates sub B-X (X is 7 to 8) were used instead of the intermediate sub B-1 to synthesize the compounds shown in Table 9 below.

TABLE 9

| Preparation | Intermediate | Intermediate | | Yield | Mass |
|---|---|---|---|---|---|
| example | (sub A-X) | (sub B-X) | Compound | % | spectrum |
| 37 | 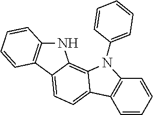 [SMILES: c1ccc(-n2c3ccccc3c3ccc4c5ccccc5[nH]c4c32)cc1] sub A-19 | 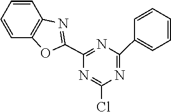 [SMILES: Clc1nc(-c2ccccc2)nc(-c2nc3ccccc3o2)n1] sub B-7 | 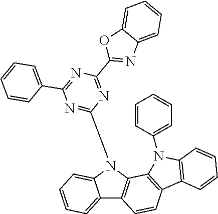 [SMILES: c1ccc(-c2nc(-c3nc4ccccc4o3)nc(-n3c4ccccc4c4ccc5c6ccccc6n(-c6ccccc6)c5c43)n2)cc1] | 51 | 605.20 |
| | | | 667 | | |
| 38 | 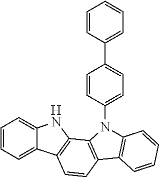 [SMILES: c1ccc(-c2ccc(-n3c4ccccc4c4ccc5c6ccccc6[nH]c5c43)cc2)cc1] sub A-20 | 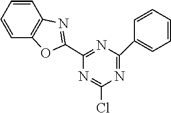 [SMILES: Clc1nc(-c2ccccc2)nc(-c2nc3ccccc3o2)n1] sub B-7 | 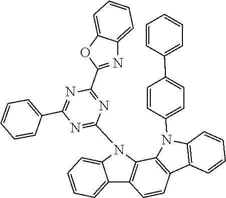 [SMILES: c1ccc(-c2ccc(-n3c4ccccc4c4ccc5c6ccccc6n(-c6nc(-c7ccccc7)nc(-c7nc8ccccc8o7)n6)c5c43)cc2)cc1] | 52 | 757.27 |
| | | | 671 | | |
| 39 | 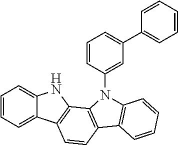 [SMILES: c1ccc(-c2cccc(-n3c4ccccc4c4ccc5c6ccccc6[nH]c5c43)c2)cc1] sub A-21 | 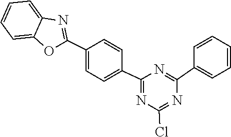 [SMILES: Clc1nc(-c2ccccc2)nc(-c2ccc(-c3nc4ccccc4o3)cc2)n1] Sub B-9 | 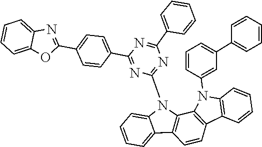 [SMILES: c1ccc(-c2cccc(-n3c4ccccc4c4ccc5c6ccccc6n(-c6nc(-c7ccccc7)nc(-c7ccc(-c8nc9ccccc9o8)cc7)n6)c5c43)c2)cc1] 690 | 63 | 757.26 |

### Preparation Example 40 Synthesis of Compound 665

(1) Synthesis of Intermediate Sub A-29

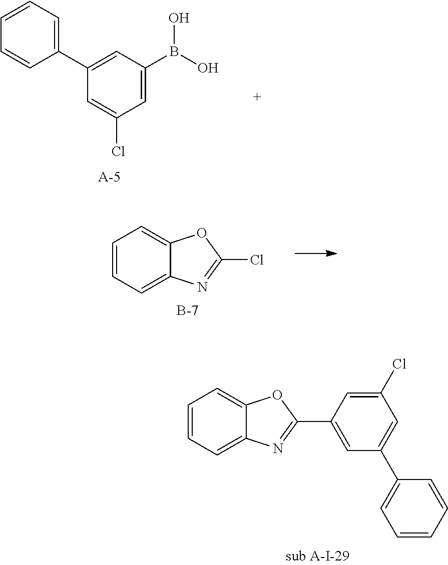

Nitrogen (0.100 L/min) was introduced into a three-necked flask equipped with a mechanical stirrer, a thermometer, and an Allihn condenser for replacement for 15 min, and (5-chloro-3-biphenyl)boronic acid (45.0 g, 193.5 mmol) (a reactant A-5), 2-chlorobenzoxazole (29.7 g, 193.5 mmol) (a reactant B-7), tetrakis(triphenylphosphine)palladium (4.4 g, 3.8 mmol), potassium carbonate (53.5 g, 387.1 mmol), tetrabutylammonium bromide (1.2 g, 3.8 mmol), tetrahydrofuran (180 mL) and deionized water (45 mL) were sequentially added into the three-necked flask; stirring and heating were started, after the temperature was raised to 66° C., a reaction was carried out under reflux for 15 h, and after the reaction was completed, the reaction solution was cooled to room temperature. The reaction solution was extracted with toluene and water, the organic phases were combined, dried over anhydrous magnesium sulfate, filtered, and concentrated, and a crude product was purified by silica gel column chromatography using a dichloromethane/n-heptane system to obtain an intermediate sub A-I-29 (32.5 g, yield: 55%) as a solid.

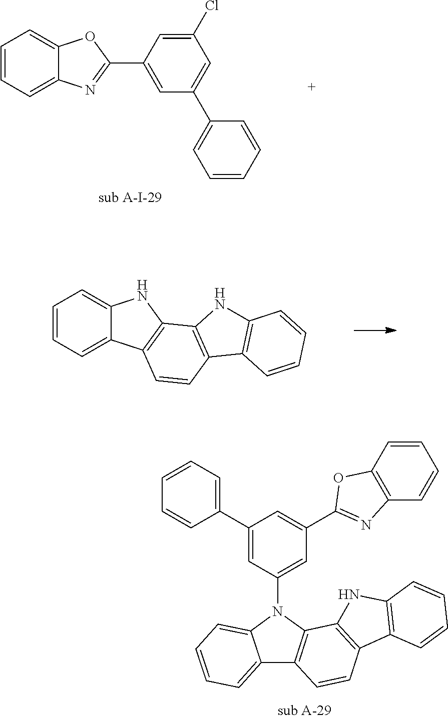 [SMILES: Clc1cc(-c2ccccc2)cc(-c2nc3ccccc3o2)c1 ; c1ccc2c(c1)[nH]c1c2ccc2c3ccccc3[nH]c21 ; c1ccc(-c2cc(-c3nc4ccccc4o3)cc(-n3c4ccccc4c4ccc5c6ccccc6[nH]c5c43)c2)cc1]

Nitrogen (0.100 L/min) was introduced into a three-necked flask equipped with a mechanical stirrer, a thermometer, and an Allihn condenser for replacement for 15 min, and the intermediate sub A-I-29 (20.0 g, 65.4 mmol), indolo[2,3-A]carbazole (20.1 g, 78.5 mmol), Pd₂(dba)₃ (0.6 g, 0.6 mmol), tri-tert-butylphosphine (0.3 g, 1.3 mmol), sodium tert-butoxide (12.5 g, 130.8 mmol), and xylene (200 mL) was added into the three-necked flask. Stirring and heating were started, after the temperature was raised to 140° C., a reaction was carried out under reflux for 5 h, and after the reaction was completed, the reaction solution was cooled to room temperature. After the reaction solution was washed with water, the organic phase was separated, the organic phase was dried over anhydrous magnesium sulfate, and filtered, the obtained filtrate was distilled under reduced pressure to remove a solvent, and a crude product was recrystallized by using a dichloromethane/ethanol system to obtain an intermediate sub A-29 (20.9 g, 61%) as a white solid.

Referring to the synthesis method for the intermediate sub A-I-29, intermediates shown in Table 10 below were synthesized, where a reactant A-X (12 or 15) was used instead of the reactant A-5 to synthesize intermediates sub A-I-X (X is 30 or 33) shown in Table 10 below.

TABLE 10

| | | Intermediate | | Yield |
|---|---|---|---|---|
| Reactant (A-X) | Reactant (B-X) | (sub A-I-X) | sub A-X | % |
| 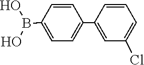 [SMILES: OB(O)c1ccc(-c2cccc(Cl)c2)cc1] A-12 | 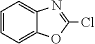 B-7 | 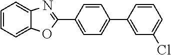 [SMILES: Clc1cccc(-c2ccc(-c3nc4ccccc4o3)cc2)c1] sub A-I-30 | 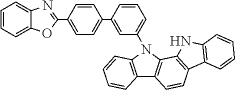 [SMILES: c1cc(-c2ccc(-c3nc4ccccc4o3)cc2)cc(-n2c3ccccc3c3ccc4c5ccccc5[nH]c4c32)c1] | 48 |
| | | | sub A-30 | |
| 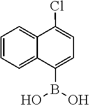 [SMILES: OB(O)c1ccc(Cl)c2ccccc12] A-15 | 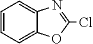 B-7 | 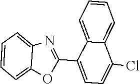 [SMILES: Clc1ccc(-c2nc3ccccc3o2)c2ccccc12] sub A-I-33 | 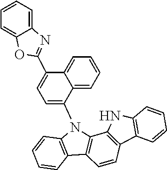 [SMILES: c1ccc2oc(-c3ccc(-n4c5ccccc5c5ccc6c7ccccc7[nH]c6c54)c4ccccc34)nc2c1] | 40 |
| | | | sub A-33 | |

(2) Synthesis of Compound 665

Referring to the synthesis method for the compound 67, compounds shown in Table 11 below were synthesized, where intermediates sub A-X (X is 29 to 30 or 33) were used instead of the intermediate sub A-1 and a reactant C-X (X is 1, 2, or 4) was used instead of the reactant C-1 to synthesize the compounds shown in Table 11 below.

TABLE 11

| Preparation | | | | | Mass |
|---|---|---|---|---|---|
| example | Intermediate (sub A-X) | Reactant (C-X) | Compound | Yield | spectrum |
| 41 | 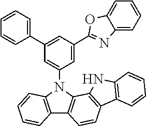 [SMILES: c1ccc(-c2cc(-c3nc4ccccc4o3)cc(-n3c4ccccc4c4ccc5c6ccccc6[nH]c5c43)c2)cc1] sub A-29 | 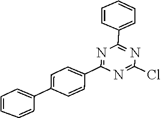 [SMILES: Clc1nc(-c2ccccc2)nc(-c2ccc(-c3ccccc3)cc2)n1] C-4 | 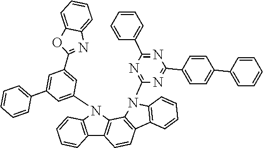 [SMILES: c1ccc(-c2ccc(-c3nc(-c4ccccc4)nc(-n4c5ccccc5c5ccc6c7ccccc7n(-c7cc(-c8ccccc8)cc(-c8nc9ccccc9o8)c7)c6c54)n3)cc2)cc1] | 75 | 833.30 |
| | | | 665 | | |
| 42 | 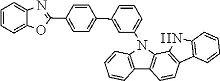 [SMILES: c1cc(-c2ccc(-c3nc4ccccc4o3)cc2)cc(-n2c3ccccc3c3ccc4c5ccccc5[nH]c4c32)c1] sub A-30 | 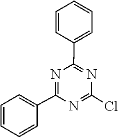 [SMILES: Clc1nc(-c2ccccc2)nc(-c2ccccc2)n1] C-l | 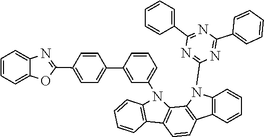 [SMILES: c1ccc(-c2nc(-c3ccccc3)nc(-n3c4ccccc4c4ccc5c6ccccc6n(-c6cccc(-c7ccc(-c8nc9ccccc9o8)cc7)c6)c5c43)n2)cc1] 691 | 65 | 757.26 |
| 43 | 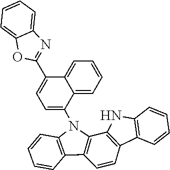 [SMILES: c1ccc2oc(-c3ccc(-n4c5ccccc5c5ccc6c7ccccc7[nH]c6c54)c4ccccc34)nc2c1] sub A-33 | 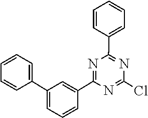 [SMILES: Clc1nc(-c2ccccc2)nc(-c2cccc(-c3ccccc3)c2)n1] C-2 | 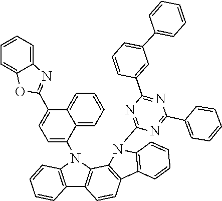 [SMILES: c1ccc(-c2cccc(-c3nc(-c4ccccc4)nc(-n4c5ccccc5c5ccc6c7ccccc7n(-c7ccc(-c8nc9ccccc9o8)c8ccccc78)c6c54)n3)c2)cc1] | 71 | 807.28 |
| | | | 694 | | |

NMR Data for Some Compounds are Shown in Table 12 Below

TABLE 12

| Compound | NMR data |
|---|---|
| Compound | ¹H NMR (400 MHz, dichloromethare-D₂): δ 8.56-8.62 (d, 2H), δ 8.32-8.37 (m, |
| 53 | 4H), δ 8.13-8.18 (m, 4H), δ 8.02-8.08 (d, 4H), δ 7.85-7.89 (t, 2H), δ 7.72-7.78 |
| | (m, 3H), δ 7.51-7.57 (t, 1H), δ 7.44-7.50 (m, 7H), 7.36-7.43 (m, 2H), δ 7.21-7.26 |
| | (t, 2H), δ 7.00-7.04 (d, 1H). |
| Compound | ¹H NMR (400 MHz, dichloromethare-D₂): δ 8.56-8.62 (d, 2H), δ 8.32-8.37 (m, |
| 67 | 4H), δ 8.13-8.18 (m, 4H), δ 8.02-8.08 (d, 4H), δ 7.85-7.89 (t, 2H), δ 7.72-7.78 |
| | (m, 3H), δ 7.51-7.57 (t, 1H), δ 7.44-7.50 (m, 7H), 7.36-7.43 (m, 2H), δ 7.21-7.26 |
| | (t, 2H), δ 7.00-7.04 (d, 1H). |
| Compound | ¹H NMR (400 MHz, dichloromethare-D₂): δ 8.55 (d, 3H), δ 8.32-8.29 (m, 2H), δ |
| 80 | 8.15-8.08 (m, 2H), δ 7.97-7.70 (m, 8H), δ 7.60-6.35 (m, 11H), δ 7.28-6.75 (m, |
| | 10H). |
| Compound | ¹H NMR (400 MHz, dichloromethare-D₂): δ 8.50-8.45 (m, 1H), δ 8.33-8.25 (m, |
| 54 | 8H), δ 8.17-8.09 (m, 2H), δ 7.68 (d, 2H), δ 7.62-7.50 (m, 6H), δ 7.46-7.33 (m, |
| | 11H), δ 7.23-7.16 (m, 5H), δ 7.08 (t, 1H) |
| Compound | ¹H NMR (400 MHz, dichloromethare-D₂): δ 8.96 (d, 1H), δ 8.45-8.21 (m, 9H), δ |
| 429 | 7.72-7.37 (m, 18H), δ 7.25-7.23 (m, 1H), δ 7.13-7.10 (m, 1H), δ 6.93-6.87 (m, |
| | 2H). |
| Compound | ¹H NMR (400 MHz, dichloromethare-D₂): δ 8.52-8.60 (d, 1H), δ 8.26-8.49 (m, |
| 480 | 4H), δ 8.09-8.23 (m, 4H), δ 7.99-8.07 (d, 1H), δ 7.89-7.95 (s, 1H), δ 7.51-7.82 |
| | (m, 6H), δ 7.31-7.50 (m, 10H), δ 7.71-7.24 (m, 3H). |
| Compound | ¹H NMR (400 MHz, dichloromethare-D₂) δ 8.52 (d, 1H), δ 8.36-8.40 (m, 4H), δ |
| 452 | 8.27-8.34 (m, 4H), δ 7.96 (d, 2H), δ 7.33-7.56 (m, 15H), δ 7.17-7.30 (m, 6H). |

### Preparation Example 44: Preparation of Second Compound

Synthesis of Compound II-1

(1) Synthesis of Intermediate c I-1

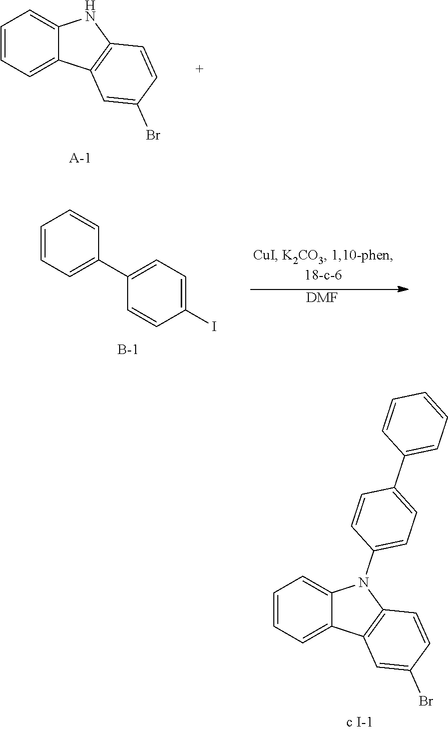

Nitrogen (0.100 L/min) was introduced into a three-necked flask equipped with a mechanical stirrer, a thermometer, and an Allihn condenser for replacement for 15 min, and 3-bromocarbazole (50.0 g, 203.1 mmol) (a reactant A-1), 4-iodobiphenyl (58.0 g, 207.2 mmol) (a reactant B-1), cuprous iodide (CuI) (7.7 g, 40.6 mmol), potassium carbonate (K₂CO₃) (61.7 g, 446.9 mmol), 18-crown-6 (5.4 g, 20.3 mmol), and dried DMF (500 mL) were added into the three-necked flask. Stirring and heating were started, after the temperature was raised to 145 to 155° C., a reaction was carried out under reflux for 18 h, and after the reaction was completed, the reaction solution was cooled to room temperature. The reaction solution was extracted, an organic phase was dried over anhydrous magnesium sulfate, and filtered, the obtained filtrate was concentrated by distillation under reduced pressure, and a crude product was purified by silica gel column chromatography using a dichloromethane/n-heptane system to obtain an intermediate c I-1 (42.8 g, 53%) as a solid.

Referring to the synthesis method for the intermediate c I-1, intermediates shown in Table 13 below were synthesized, where a reactant A-X (X is 1, 4 or 5) was used instead of the reactant A-1, and a reactant B-M (M is 1 to 7, 9, 12 to 17 or 20 to 22) was used instead of the reactant B-1 to synthesize intermediates c I-Z (Z is 2 to 7, 9 or 12 to 22) as shown in Table 13 below.

TABLE 13

| | | | Yield |
|---|---|---|---|
| Reactants A-X | Reactants B-M | Intermediate c I-Z | % |
| 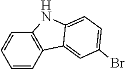 [SMILES: Brc1ccc2[nH]c3ccccc3c2c1] A-1 | 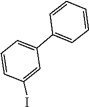 [SMILES: Ic1cccc(-c2ccccc2)c1] B-2 | 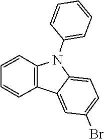 [SMILES: Brc1ccc2c(c1)c1ccccc1n2-c1ccccc1] | 61 |
| | | c I-2 | |
| 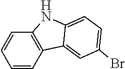 [SMILES: Brc1ccc2[nH]c3ccccc3c2c1] A-1 | 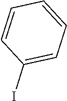 B-3 | 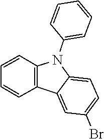 [SMILES: Brc1ccc2c(c1)c1ccccc1n2-c1ccccc1] | 68 |
| | | c I-3 | |
| 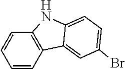 [SMILES: Brc1ccc2[nH]c3ccccc3c2c1] A-1 | 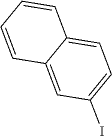 [SMILES: Ic1ccc2ccccc2c1] B-4 | 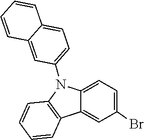 [SMILES: Brc1ccc2c(c1)c1ccccc1n2-c1ccc2ccccc2c1] c I-4 | 67 |
| 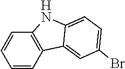 [SMILES: Brc1ccc2[nH]c3ccccc3c2c1] A-1 | 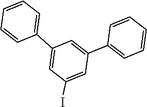 [SMILES: Ic1cc(-c2ccccc2)cc(-c2ccccc2)c1] B-5 | 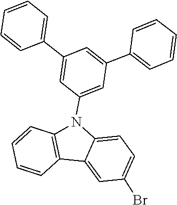 [SMILES: Brc1ccc2c(c1)c1ccccc1n2-c1cc(-c2ccccc2)cc(-c2ccccc2)c1] | 69 |
| | | c I-5 | |
| 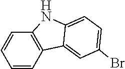 [SMILES: Brc1ccc2[nH]c3ccccc3c2c1] A-1 | 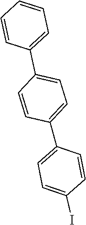 [SMILES: Ic1ccc(-c2ccc(-c3ccccc3)cc2)cc1] B-6 | 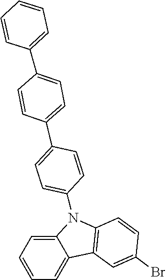 [SMILES: Brc1ccc2c(c1)c1ccccc1n2-c1ccc(-c2ccc(-c3ccccc3)cc2)cc1] | 68 |
| | | c I-6 | |
| 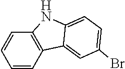 [SMILES: Brc1ccc2[nH]c3ccccc3c2c1] A-1 | 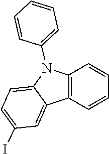 [SMILES: Ic1ccc2c(c1)c1ccccc1n2-c1ccccc1] B-7 | 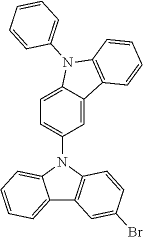 | 52 |
| | | c I-7 | |
| 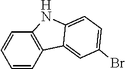 [SMILES: Brc1ccc2[nH]c3ccccc3c2c1] A-1 | 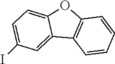 [SMILES: Ic1ccc2oc3ccccc3c2c1] B-9 | 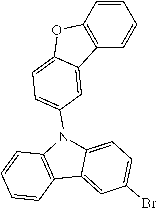 [SMILES: Brc1ccc2c(c1)c1ccccc1n2-c1ccc2oc3ccccc3c2c1] | 54 |
| | | c I-9 | |
| 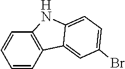 [SMILES: Brc1ccc2[nH]c3ccccc3c2c1] A-1 | 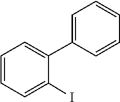 [SMILES: Ic1ccccc1-c1ccccc1] B-12 | 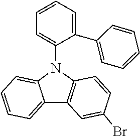 [SMILES: Brc1ccc2c(c1)c1ccccc1n2-c1ccccc1-c1ccccc1] | 55 |
| | | c I-12 | |
| 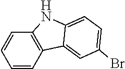 [SMILES: Brc1ccc2[nH]c3ccccc3c2c1] A-1 | 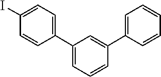 [SMILES: Ic1ccc(-c2cccc(-c3ccccc3)c2)cc1] B-13 | 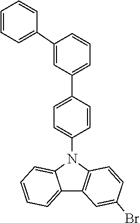 [SMILES: Brc1ccc2c(c1)c1ccccc1n2-c1ccc(-c2cccc(-c3ccccc3)c2)cc1] | 58 |
| | | c I-13 | |
| 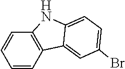 [SMILES: Brc1ccc2[nH]c3ccccc3c2c1] A-1 | 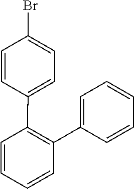 [SMILES: Brc1ccc(-c2ccccc2-c2ccccc2)cc1] B-14 | 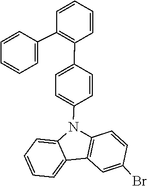 [SMILES: Brc1ccc2c(c1)c1ccccc1n2-c1ccc(-c2ccccc2-c2ccccc2)cc1] c I-14 | 55 |
| 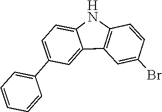 [SMILES: Brc1ccc2[nH]c3ccc(-c4ccccc4)cc3c2c1] A-4 | 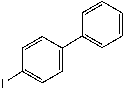 [SMILES: Ic1ccc(-c2ccccc2)cc1] B-1 | 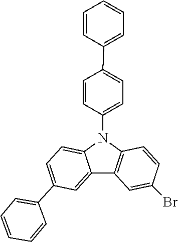 [SMILES: Brc1ccc2c(c1)c1cc(-c3ccccc3)ccc1n2-c1ccc(-c2ccccc2)cc1] | 57 |
| | | c I-15 | |
| 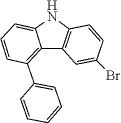 [SMILES: Brc1ccc2[nH]c3cccc(-c4ccccc4)c3c2c1] A-5 | 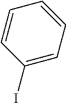 B-3 | 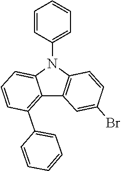 [SMILES: Brc1ccc2c(c1)c1c(-c3ccccc3)cccc1n2-c1ccccc1] | 61 |
| | | c I-16 | |
| 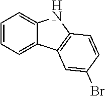 [SMILES: Brc1ccc2[nH]c3ccccc3c2c1] A-1 | 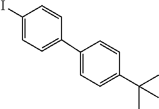 [SMILES: CC(C)(C)c1ccc(-c2ccc(I)cc2)cc1] B-15 | 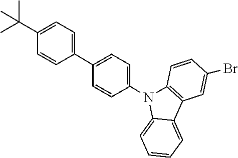 [SMILES: CC(C)(C)c1ccc(-c2ccc(-n3c4ccccc4c4cc(Br)ccc43)cc2)cc1] | 52 |
| | | C I-17 | |
| 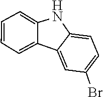 [SMILES: Brc1ccc2[nH]c3ccccc3c2c1] A-1 | 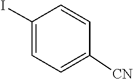 B-16 | 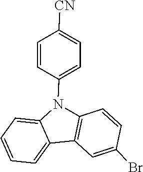 [SMILES: N#Cc1ccc(-n2c3ccccc3c3cc(Br)ccc32)cc1] | 56 |
| | | C I-18 | |
| 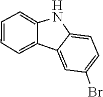 [SMILES: Brc1ccc2[nH]c3ccccc3c2c1] A-1 | 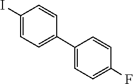 [SMILES: Fc1ccc(-c2ccc(I)cc2)cc1] B-17 | 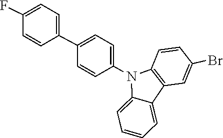 [SMILES: Fc1ccc(-c2ccc(-n3c4ccccc4c4cc(Br)ccc43)cc2)cc1] | 50 |
| | | C I-19 | |
| 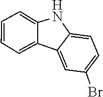 [SMILES: Brc1ccc2[nH]c3ccccc3c2c1] A-1 | 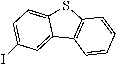 [SMILES: Ic1ccc2sc3ccccc3c2c1] B-20 | 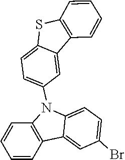 [SMILES: Brc1ccc2c(c1)c1ccccc1n2-c1ccc2sc3ccccc3c2c1] | 57 |
| | | c I-20 | |
| 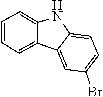 [SMILES: Brc1ccc2[nH]c3ccccc3c2c1] A-1 | 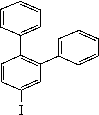 [SMILES: Ic1ccc(-c2ccccc2)c(-c2ccccc2)c1] B-21 | 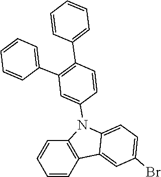 [SMILES: Brc1ccc2c(c1)c1ccccc1n2-c1ccc(-c2ccccc2)c(-c2ccccc2)c1] | 62 |
| | | c I-21 | |
| 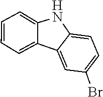 [SMILES: Brc1ccc2[nH]c3ccccc3c2c1] A-1 | 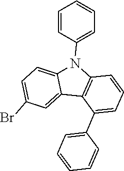 [SMILES: Brc1ccc2c(c1)c1c(-c3ccccc3)cccc1n2-c1ccccc1] B-22 | 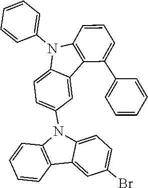 [SMILES: Brc1ccc2c(c1)c1ccccc1n2-c1ccc2c(c1)c1c(-c3ccccc3)cccc1n2-c1ccccc1] | 45 |
| | | c I-22 | |

(2) Synthesis of Intermediate c II-1

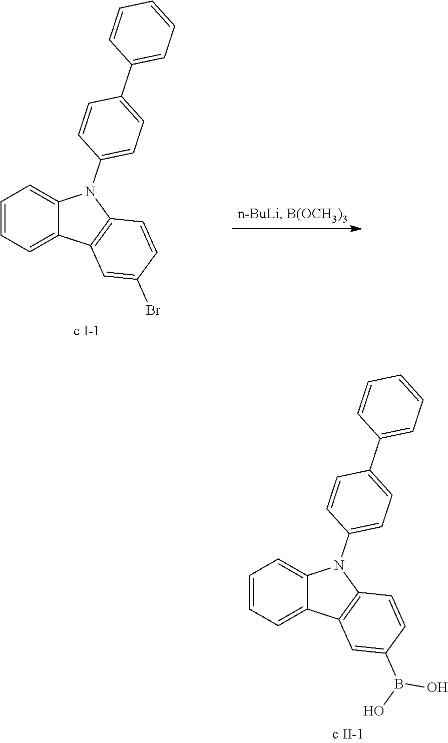 [SMILES: Brc1ccc2c(c1)c1ccccc1n2-c1ccc(-c2ccccc2)cc1 ; OB(O)c1ccc2c(c1)c1ccccc1n2-c1ccc(-c2ccccc2)cc1]

Nitrogen (0.100 L/min) was introduced into a three-necked flask equipped with a mechanical stirrer, a thermometer, and a constant pressure dropping funnel for replacement for 15 min, the intermediate c I-1 (30.0 g, 75.3 mmol) and tetrahydrofuran (300 mL) were added into the three-necked flask, the temperature was cooled to −80° C. to −90° C. with liquid nitrogen, a solution of n-butyllithium (5.3 g, 82.8 mmol) in tetrahydrofuran was added dropwise to the mixture, after dropwise addition was complete, the reaction solution was kept temperature and stirred for 1 h, and the temperature was maintained at −80° C. to −90° C., then trimethyl borate (9.4 g, 90.4 mmol) was added dropwise to the reaction solution, after dropwise addition was complete, heat preservation was performed for 1 h, the system was raised to room temperature, and a reaction was carried out under stirring for 24 h; an aqueous solution of hydrochloric acid was added into the reaction solution, stirring was performed for 0.5 h, the reaction solution was extracted with dichloromethane and water, and then separated, an organic phase was washed with water to be neutral, dried over anhydrous magnesium sulfate, and filtered, and the obtained filtrate was distilled under reduced pressure to remove a solvent; and purification was performed by pulping with n-heptane to obtain an intermediate c II-1 (15.0 g, 55%) as a white solid.

Referring to the synthesis method for the intermediate c II-1, intermediates shown in Table 14 below were synthesized, where intermediates c I-Y (Y is 2 to 7, 9, 12-14 or 17 to 20) were used instead of the intermediate c I-1 to synthesize intermediates c II-X (X is 2 to 7, 9, 12 to 14 or 17 to 20) shown in Table 14 below.

TABLE 14

| | | Yield |
|---|---|---|
| Intermediate c I-Y | Intermediate c II-X | % |
| 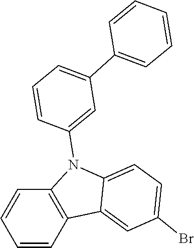 [SMILES: Brc1ccc2c(c1)c1ccccc1n2-c1cccc(-c2ccccc2)c1] c I-2 | 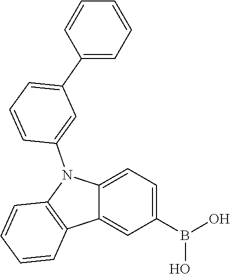 [SMILES: OB(O)c1ccc2c(c1)c1ccccc1n2-c1cccc(-c2ccccc2)c1] | 52 |
| | c II-2 | |
| 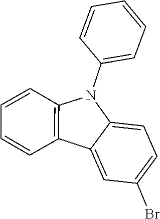 [SMILES: Brc1ccc2c(c1)c1ccccc1n2-c1ccccc1] c I-3 | 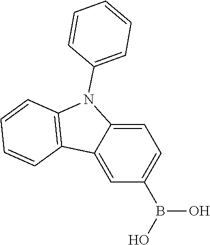 [SMILES: OB(O)c1ccc2c(c1)c1ccccc1n2-c1ccccc1] | 57 |
| | c II-3 | |
| 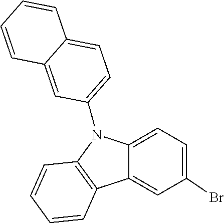 [SMILES: Brc1ccc2c(c1)c1ccccc1n2-c1ccc2ccccc2c1] c I-4 | 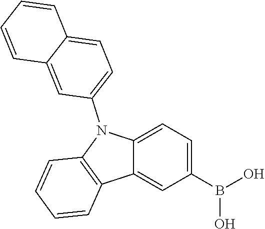 [SMILES: OB(O)c1ccc2c(c1)c1ccccc1n2-c1ccc2ccccc2c1] c II-4 | 53 |
| 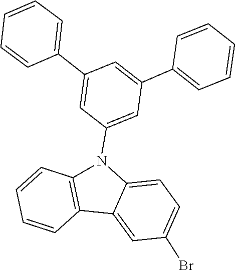 [SMILES: Brc1ccc2c(c1)c1ccccc1n2-c1cc(-c2ccccc2)cc(-c2ccccc2)c1] c I-5 | 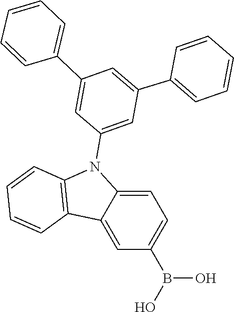 [SMILES: OB(O)c1ccc2c(c1)c1ccccc1n2-c1cc(-c2ccccc2)cc(-c2ccccc2)c1] | 52 |
| | c II-5 | |
| 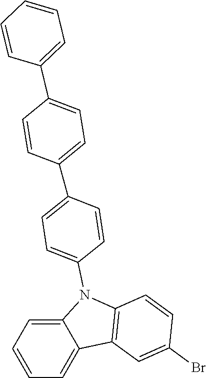 [SMILES: Brc1ccc2c(c1)c1ccccc1n2-c1ccc(-c2ccc(-c3ccccc3)cc2)cc1] c I-6 | 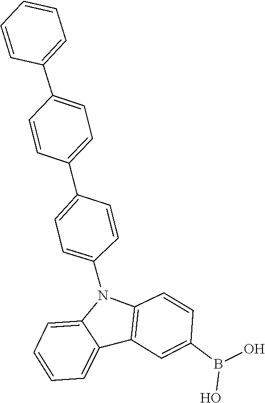 [SMILES: OB(O)c1ccc2c(c1)c1ccccc1n2-c1ccc(-c2ccc(-c3ccccc3)cc2)cc1] | 55 |
| | c II-6 | |
| 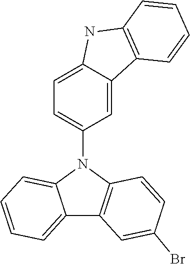 c I-7 | 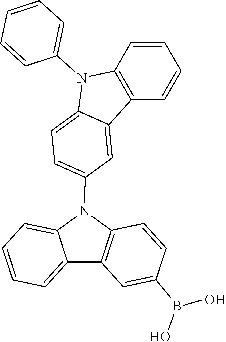 | 48 |
| | c II-7 | |
| 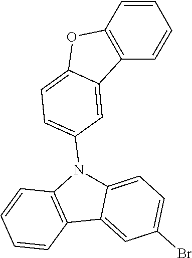 [SMILES: Brc1ccc2c(c1)c1ccccc1n2-c1ccc2oc3ccccc3c2c1] c I-9 | 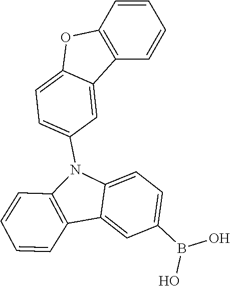 [SMILES: OB(O)c1ccc2c(c1)c1ccccc1n2-c1ccc2oc3ccccc3c2c1] | 47 |
| | c II-9 | |
| 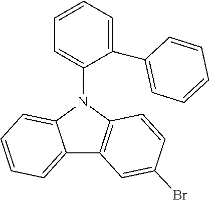 [SMILES: Brc1ccc2c(c1)c1ccccc1n2-c1ccccc1-c1ccccc1] c I-12 | 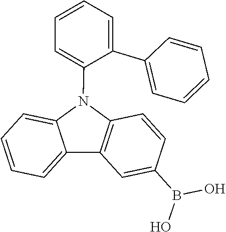 [SMILES: OB(O)c1ccc2c(c1)c1ccccc1n2-c1ccccc1-c1ccccc1] | 49 |
| | c II-12 | |
| 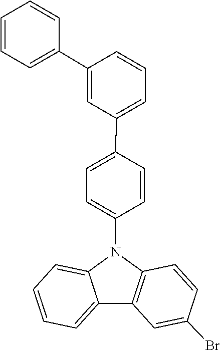 [SMILES: Brc1ccc2c(c1)c1ccccc1n2-c1ccc(-c2cccc(-c3ccccc3)c2)cc1] c I-13 | 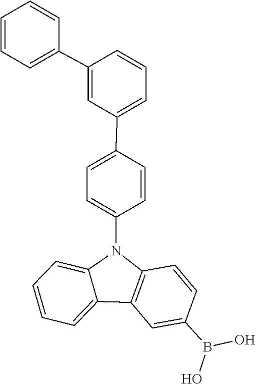 [SMILES: OB(O)c1ccc2c(c1)c1ccccc1n2-c1ccc(-c2cccc(-c3ccccc3)c2)cc1] | 47 |
| | c II-13 | |
| 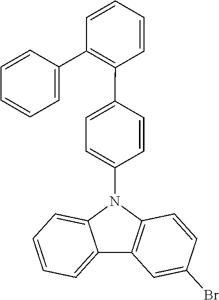 [SMILES: Brc1ccc2c(c1)c1ccccc1n2-c1ccc(-c2ccccc2-c2ccccc2)cc1] c I-14 | 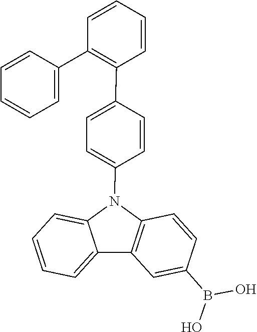 [SMILES: OB(O)c1ccc2c(c1)c1ccccc1n2-c1ccc(-c2ccccc2-c2ccccc2)cc1] | 41 |
| | c II-14 | |
| 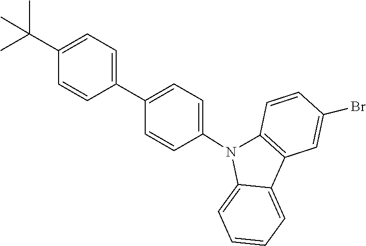 [SMILES: CC(C)(C)c1ccc(-c2ccc(-n3c4ccccc4c4cc(Br)ccc43)cc2)cc1] C I-17 | 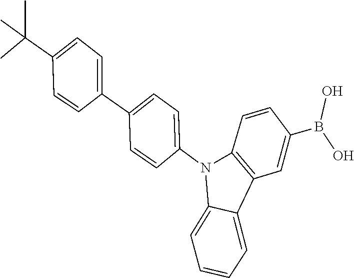 [SMILES: CC(C)(C)c1ccc(-c2ccc(-n3c4ccccc4c4cc(B(O)O)ccc43)cc2)cc1] | 52 |
| | C-II-17 | |
| 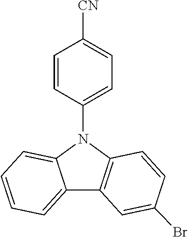 [SMILES: N#Cc1ccc(-n2c3ccccc3c3cc(Br)ccc32)cc1] C I-18 | 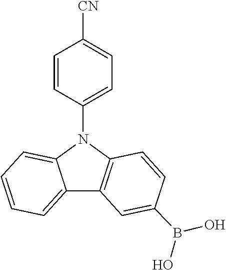 [SMILES: N#Cc1ccc(-n2c3ccccc3c3cc(B(O)O)ccc32)cc1] | 45 |
| | C-II-18 | |
| 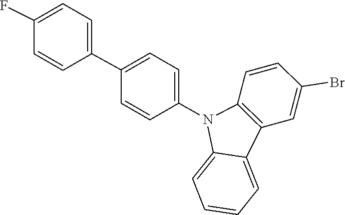 [SMILES: Fc1ccc(-c2ccc(-n3c4ccccc4c4cc(Br)ccc43)cc2)cc1] C I-19 | 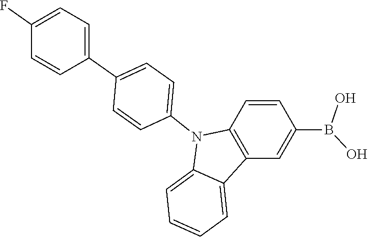 [SMILES: OB(O)c1ccc2c(c1)c1ccccc1n2-c1ccc(-c2ccc(F)cc2)cc1] | 51 |
| | C-II-19 | |
| 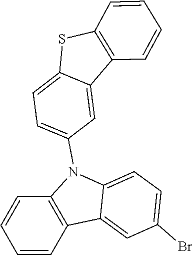 [SMILES: Brc1ccc2c(c1)c1ccccc1n2-c1ccc2sc3ccccc3c2c1] c I-20 | 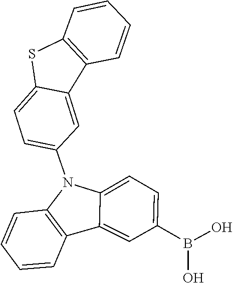 [SMILES: OB(O)c1ccc2c(c1)c1ccccc1n2-c1ccc2sc3ccccc3c2c1] | 55 |
| | c -II-20 | |

(3) Synthesis of Compound II-1

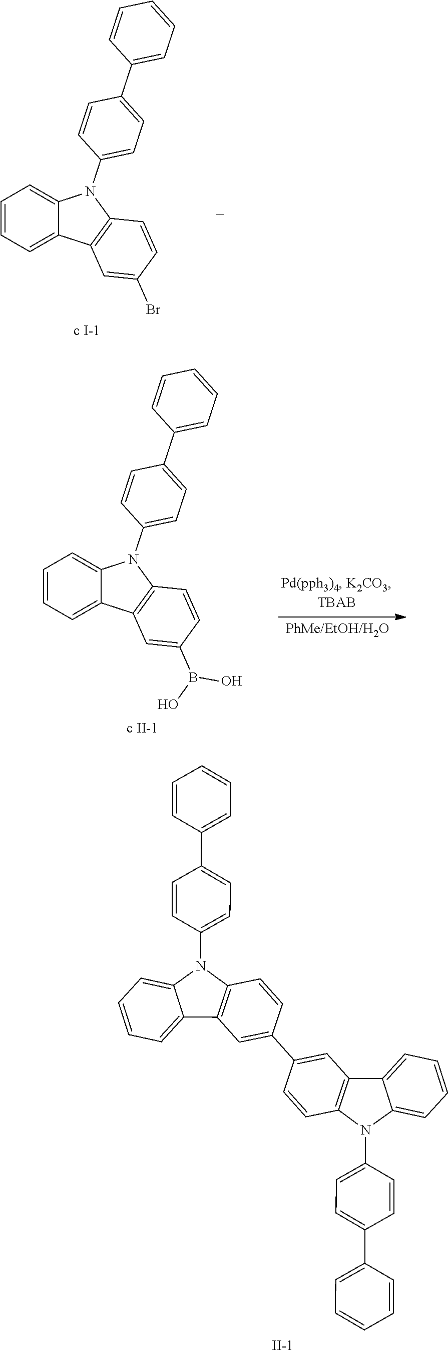 [SMILES: Brc1ccc2c(c1)c1ccccc1n2-c1ccc(-c2ccccc2)cc1 ; OB(O)c1ccc2c(c1)c1ccccc1n2-c1ccc(-c2ccccc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; "II-1"]

Nitrogen (0.100 L/min) was introduced into a three-necked flask equipped with a mechanical stirrer, a thermometer, and an Allihn condenser for replacement for 15 min, and the intermediate c I-1 (10.0 g, 25.1 mmol), the intermediate c II-1 (10.0 g, 27.6 mmol), potassium carbonate (8.6 g, 62.7 mmol), tetrakis(triphenylphosphine)palladium (1.4 g, 1.2 mmol), and tetrabutylammonium bromide (1.6 g, 5.0 mmol) were added into the three-necked flask and a mixed solvent of toluene (100 mL), ethanol (50 mL) and water (25 mL) was added into the three-necked flask. Stirring and heating were started, after the temperature was raised to 75 to 80° C., a reaction was carried out under reflux for 18 h, and after the reaction was completed, the reaction solution was cooled to room temperature. The organic phase was obtained by extraction and separation of the reaction solution, the organic phase washed with water to be neutral, dried over anhydrous magnesium sulfate, and filtered, and the obtained filtrate was concentrated by distillation under reduced pressure; and a crude product was purified by silica gel column chromatography using a dichloromethane/n-heptane system to obtain a compound II-1 (9.9 g, 62%) as a solid, mass spectrum: m/z=637.26 [M+H]⁺.

Compounds shown in Table 15 below were synthesized with reference to the synthesis method for the compound II-1, where intermediates c I-X (X is 1 to 2, 4 to 7, 9, 14 to 16, or 21 to 22) were used instead of the intermediate c I-1 and intermediates c II-X (X is 1 to 4, 12 to 13, or 17 to 20) were used instead of the intermediate c II-1 to synthesize the compounds shown in Table 15 below.

TABLE 15

| | | | | | Mass |
|---|---|---|---|---|---|
| Preparation | | | | Yield | spectrum |
| example | Intermediate c I-X | Intermediate c II-X | Compound X | (%) | [M + H]⁺ |
| 45 | 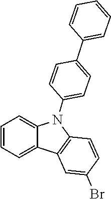 [SMILES: Brc1ccc2c(c1)c1ccccc1n2-c1ccc(-c2ccccc2)cc1] c I-1 | 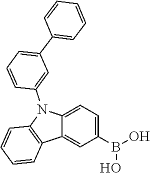 [SMILES: OB(O)c1ccc2c(c1)c1ccccc1n2-c1cccc(-c2ccccc2)c1] c II-2 | 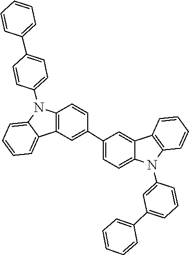 [SMILES: c1ccc(-c2ccc(-n3c4ccccc4c4cc(-c5ccc6c(c5)c5ccccc5n6-c5cccc(-c6ccccc6)c5)ccc43)cc2)cc1] | 67 | 637.26 |
| | | | II-2 | | |
| 46 | 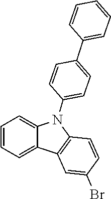 [SMILES: Brc1ccc2c(c1)c1ccccc1n2-c1ccc(-c2ccccc2)cc1] | 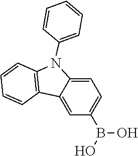 [SMILES: OB(O)c1ccc2c(c1)c1ccccc1n2-c1ccccc1] c II-3 | 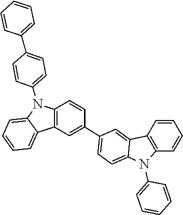 [SMILES: c1ccc(-c2ccc(-n3c4ccccc4c4cc(-c5ccc6c(c5)c5ccccc5n6-c5ccccc5)ccc43)cc2)cc1] | 66 | 561.23 |
| | c I-1 | | II-4 | | |
| 47 | 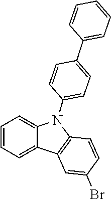 [SMILES: Brc1ccc2c(c1)c1ccccc1n2-c1ccc(-c2ccccc2)cc1] c I-1 | 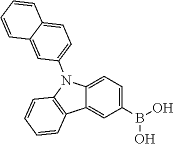 [SMILES: OB(O)c1ccc2c(c1)c1ccccc1n2-c1ccc2ccccc2c1] c II-4 | 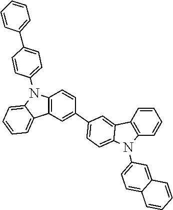 [SMILES: c1ccc(-c2ccc(-n3c4ccccc4c4cc(-c5ccc6c(c5)c5ccccc5n6-c5ccc6ccccc6c5)ccc43)cc2)cc1] II-6 | 61 | 611.25 |
| 48 | 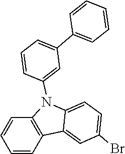 [SMILES: Brc1ccc2c(c1)c1ccccc1n2-c1cccc(-c2ccccc2)c1] c I-2 | 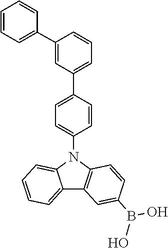 [SMILES: OB(O)c1ccc2c(c1)c1ccccc1n2-c1ccc(-c2cccc(-c3ccccc3)c2)cc1] c II-13 | 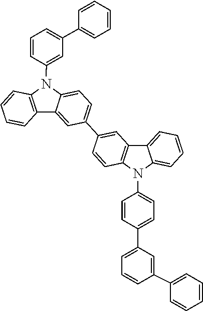 [SMILES: c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1] | 62 | 713.29 |
| | | | II-13 | | |
| 49 | 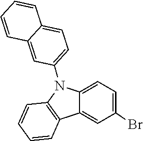 [SMILES: Brc1ccc2c(c1)c1ccccc1n2-c1ccc2ccccc2c1] c I-4 | 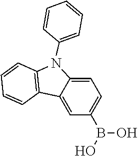 [SMILES: OB(O)c1ccc2c(c1)c1ccccc1n2-c1ccccc1] c II-3 | 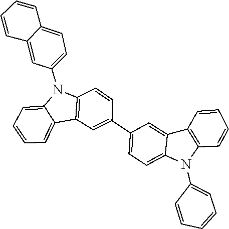 [SMILES: c1ccc(-n2c3ccccc3c3cc(-c4ccc5c(c4)c4ccccc4n5-c4ccc5ccccc5c4)ccc32)cc1] | 65 | 535.21 |
| | | | II-20 | | |
| 50 | 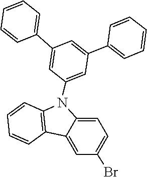 [SMILES: Brc1ccc2c(c1)c1ccccc1n2-c1cc(-c2ccccc2)cc(-c2ccccc2)c1] c I-5 | 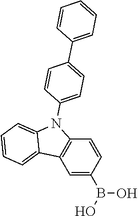 [SMILES: OB(O)c1ccc2c(c1)c1ccccc1n2-c1ccc(-c2ccccc2)cc1] c II-1 | 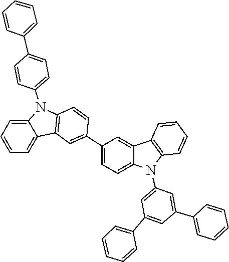 [SMILES: c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1] | 68 | 713.29 |
| | | | II-26 | | |
| 51 | 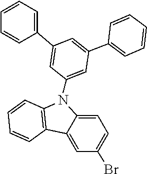 [SMILES: Brc1ccc2c(c1)c1ccccc1n2-c1cc(-c2ccccc2)cc(-c2ccccc2)c1] c I-5 | 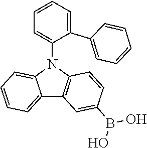 [SMILES: OB(O)c1ccc2c(c1)c1ccccc1n2-c1ccccc1-c1ccccc1] c II-12 | 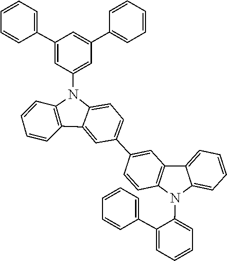 [SMILES: c1ccc(-c2cc(-c3ccccc3)cc(-n3c4ccccc4c4cc(-c5ccc6c(c5)c5ccccc5n6-c5ccccc5-c5ccccc5)ccc43)c2)cc1] | 58 | 713.29 |
| | | | II-201 | | |
| 52 | 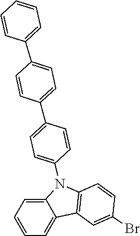 [SMILES: Brc1ccc2c(c1)c1ccccc1n2-c1ccc(-c2ccc(-c3ccccc3)cc2)cc1] c I-6 | 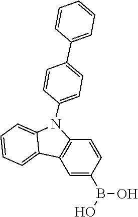 [SMILES: OB(O)c1ccc2c(c1)c1ccccc1n2-c1ccc(-c2ccccc2)cc1] c II-1 | 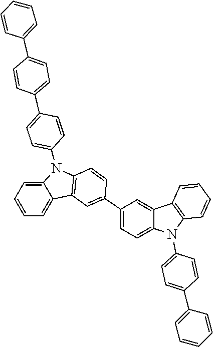 [SMILES: c1ccc(-c2ccc(-c3ccc(-n4c5ccccc5c5cc(-c6ccc7c(c6)c6ccccc6n7-c6ccc(-c7ccccc7)cc6)ccc54)cc3)cc2)cc1] | 70 | 713.29 |
| | | | II-29 | | |
| 53 | 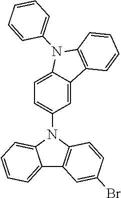 c I-7 | 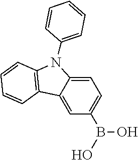 [SMILES: OB(O)c1ccc2c(c1)c1ccccc1n2-c1ccccc1] c II-3 | 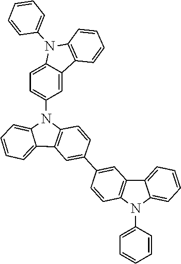 [SMILES: c1ccc(-n2c3ccccc3c3cc(-c4ccc5c(c4)c4ccccc4n5-c4ccc5c(c4)c4ccccc4n5-c4ccccc4)ccc32)cc1] | 58 | 650.25 |
| | | | II-32 | | |
| 54 | 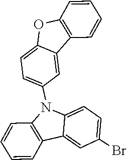 [SMILES: Brc1ccc2c(c1)c1ccccc1n2-c1ccc2oc3ccccc3c2c1] c I-9 | 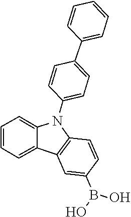 [SMILES: OB(O)c1ccc2c(c1)c1ccccc1n2-c1ccc(-c2ccccc2)cc1] c II-1 | 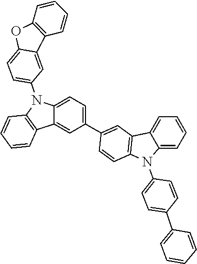 [SMILES: c1ccc(-c2ccc(-n3c4ccccc4c4cc(-c5ccc6c(c5)c5ccccc5n6-c5ccc6oc7ccccc7c6c5)ccc43)cc2)cc1] | 61 | 651.24 |
| | | | II-55 | | |
| 55 | 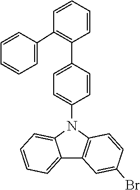 [SMILES: Brc1ccc2c(c1)c1ccccc1n2-c1ccc(-c2ccccc2-c2ccccc2)cc1] c I-14 | 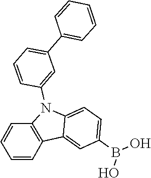 [SMILES: OB(O)c1ccc2c(c1)c1ccccc1n2-c1cccc(-c2ccccc2)c1] c II-2 | 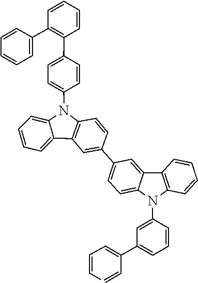 [SMILES: C=C/C(=C\C=C/C)c1cccc(-n2c3ccccc3c3cc(-c4ccc5c(c4)c4ccccc4n5-c4ccc(-c5ccccc5-c5ccccc5)cc4)ccc32)c1] | 62 | 713.29 |
| | | | II-203 | | |
| 56 | 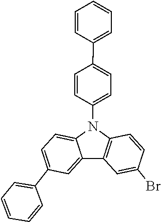 [SMILES: Brc1ccc2c(c1)c1cc(-c3ccccc3)ccc1n2-c1ccc(-c2ccccc2)cc1] c I-15 | 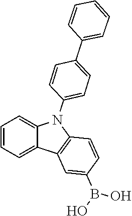 [SMILES: OB(O)c1ccc2c(c1)c1ccccc1n2-c1ccc(-c2ccccc2)cc1] c II-1 | 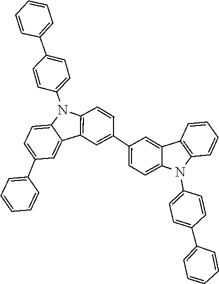 [SMILES: c1ccc(-c2ccc(-n3c4ccccc4c4cc(-c5ccc6c(c5)c5cc(-c7ccccc7)ccc5n6-c5ccc(-c6ccccc6)cc5)ccc43)cc2)cc1] | 58 | 713.29 |
| | | | II-79 | | |
| 57 | 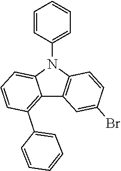 [SMILES: Brc1ccc2c(c1)c1c(-c3ccccc3)cccc1n2-c1ccccc1] c I-16 | 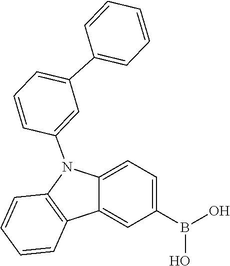 [SMILES: OB(O)c1ccc2c(c1)c1ccccc1n2-c1cccc(-c2ccccc2)c1] | 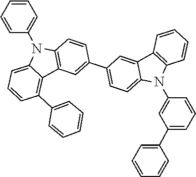 [SMILES: c1ccc(-c2cccc(-n3c4ccccc4c4cc(-c5ccc6c(c5)c5c(-c7ccccc7)cccc5n6-c5ccccc5)ccc43)c2)cc1] II-110 | 60 | 637.26 |
| | | c II-2 | | | |
| 58 | 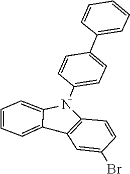 [SMILES: Brc1ccc2c(c1)c1ccccc1n2-c1ccc(-c2ccccc2)cc1] c I-1 | 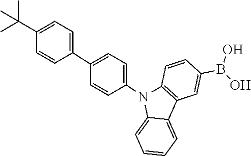 [SMILES: CC(C)(C)c1ccc(-c2ccc(-n3c4ccccc4c4cc(B(O)O)ccc43)cc2)cc1] c II-17 | 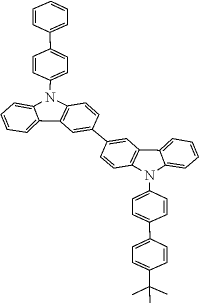 [SMILES: CC(C)(C)c1ccc(-c2ccc(-n3c4ccccc4c4cc(-c5ccc6c(c5)c5ccccc5n6-c5ccc(-c6ccccc6)cc5)ccc43)cc2)cc1] | 54 | 693.32 |
| | | | II-204 | | |
| 59 | 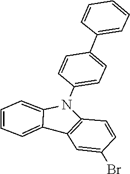 [SMILES: Brc1ccc2c(c1)c1ccccc1n2-c1ccc(-c2ccccc2)cc1] c I-1 | 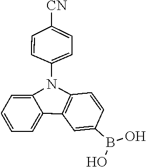 [SMILES: N#Cc1ccc(-n2c3ccccc3c3cc(B(O)O)ccc32)cc1] c II-18 | 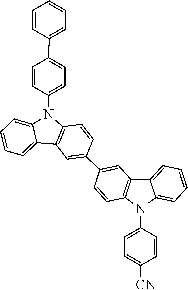 [SMILES: N#Cc1ccc(-n2c3ccccc3c3cc(-c4ccc5c(c4)c4ccccc4n5-c4ccc(-c5ccccc5)cc4)ccc32)cc1] | 61 | 586.22 |
| | | | II-205 | | |
| 60 | 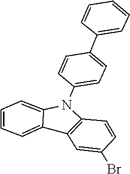 [SMILES: Brc1ccc2c(c1)c1ccccc1n2-c1ccc(-c2ccccc2)cc1] C I-1 | 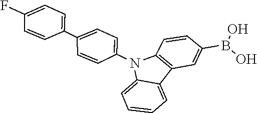 [SMILES: OB(O)c1ccc2c(c1)c1ccccc1n2-c1ccc(-c2ccc(F)cc2)cc1] c II-19 | 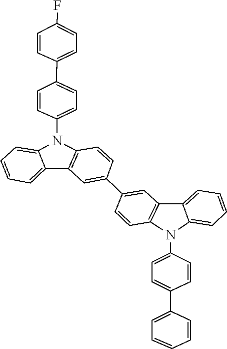 [SMILES: Fc1ccc(-c2ccc(-n3c4ccccc4c4cc(-c5ccc6c(c5)c5ccccc5n6-c5ccc(-c6ccccc6)cc5)ccc43)cc2)cc1] | 50 | 655.24 |
| | | | II-206 | | |
| 61 | 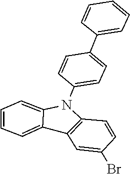 [SMILES: Brc1ccc2c(c1)c1ccccc1n2-c1ccc(-c2ccccc2)cc1] C I-1 | 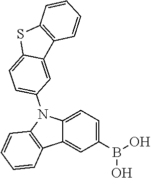 [SMILES: OB(O)c1ccc2c(c1)c1ccccc1n2-c1ccc2sc3ccccc3c2c1] c II-20 | 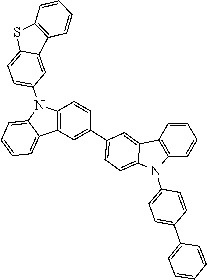 [SMILES: c1ccc(-c2ccc(-n3c4ccccc4c4cc(-c5ccc6c(c5)c5ccccc5n6-c5ccc6sc7ccccc7c6c5)ccc43)cc2)cc1] | 57 | 667.22 |
| | | | II-249 | | |
| 62 | 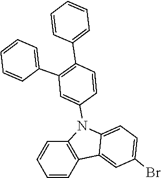 [SMILES: Brc1ccc2c(c1)c1ccccc1n2-c1ccc(-c2ccccc2)c(-c2ccccc2)c1] C I-21 | 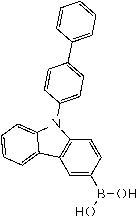 [SMILES: OB(O)c1ccc2c(c1)c1ccccc1n2-c1ccc(-c2ccccc2)cc1] c II-1 | 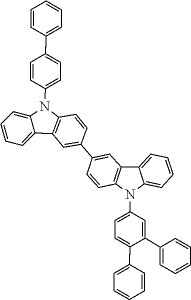 [SMILES: c1ccc(-c2ccc(-n3c4ccccc4c4cc(-c5ccc6c(c5)c5ccccc5n6-c5ccc(-c6ccccc6)c(-c6ccccc6)c5)ccc43)cc2)cc1] | 64 | 713.30 |
| | | | II-245 | | |
| 63 | 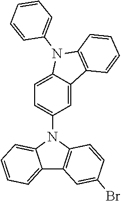 [SMILES: Brc1ccc2c(c1)c1ccccc1n2-c1ccc2c(c1)c1ccccc1n2-c1ccccc1] C I-7 | 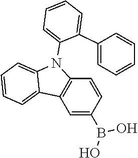 [SMILES: OB(O)c1ccc2c(c1)c1ccccc1n2-c1ccccc1-c1ccccc1] c II-12 | 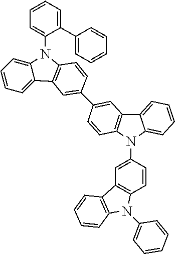 [SMILES: c1ccc(-c2ccccc2-n2c3ccccc3c3cc(-c4ccc5c(c4)c4ccccc4n5-c4ccc5c(c4)c4ccccc4n5-c4ccccc4)ccc32)cc1] | 53 | 726.29 |
| | | | II-244 | | |
| 64 | 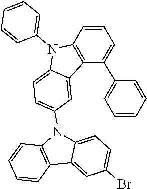 [SMILES: Brc1ccc2c(c1)c1ccccc1n2-c1ccc2c(c1)c1c(-c3ccccc3)cccc1n2-c1ccccc1] C I-22 | 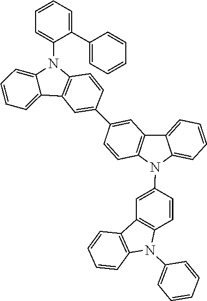 [SMILES: c1ccc(-c2ccccc2-n2c3ccccc3c3cc(-c4ccc5c(c4)c4ccccc4n5-c4ccc5c(c4)c4ccccc4n5-c4ccccc4)ccc32)cc1] | 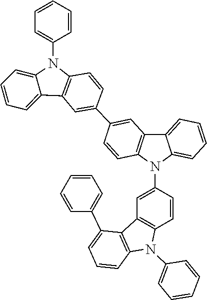 [SMILES: c1ccc(-c2cccc3c2c2cc(-n4c5ccccc5c5cc(-c6ccc7c(c6)c6ccccc6n7-c6ccccc6)ccc54)ccc2n3-c2ccccc2)cc1] | 59 | 726.29 |
| | | c II-3 | II-247 | | |

Manufacture and Performance Evaluation of Organic Electroluminescent Devices

### Example 1

Green Organic Electroluminescent Device

An ITO substrate having a thickness of 1500 Å for an anode 100 was cut into a dimension of 40 mm (length)×40 mm (width)×0.7 mm (thickness) to be prepared into an experimental substrate with a cathode 200, an anode 100 and insulating layer patterns by a photoetching process, and surface treatment was performed with UV ozone and O₂:N₂ plasma to increase the work function of the anode 100 (the experimental substrate), and the surface of the ITO substrate was cleaned by using an organic solvent to clean scum and oil on the surface of the ITO substrate.

A compound F4-TCNQ (a structural formula is shown below) was vacuum evaporated on the experimental substrate to form a hole injection layer 310 (HIL) having a thickness of 100 Å; a compound NPB (a structural formula is shown below) was vacuum evaporated on the hole injection layer 310 to form a first hole transport layer 321 (HTL1) having a thickness of 1050 Å; and PAPB was vacuum evaporated on the first hole transport layer 321 (HTL1) to form a second hole transport layer 322 (HTL2) having a thickness of 380 Å.

A composition GH-1-1 and Ir(mppy)₃ were co-evaporated on the second hole transport layer at a ratio of 100%:10% (an evaporation rate) to form a green organic electroluminescent layer (EML) having a thickness of 400 Å.

ET-06 and LiQ were mixed at a weight ratio of 1:1 and evaporated to form an electron transport layer 350 (ETL) having a thickness of 350 Å, and Yb was then evaporated on the electron transport layer to form an electron injection layer 360 (EIL) having a thickness of 15 Å.

Magnesium (Mg) and silver (Ag) were vacuum evaporated on the electron injection layer at a film thickness ratio of 1:10 to form a cathode 200 having a thickness of 130 Å.

In addition, the above cathode 200 was evaporated with CP-05 having a thickness of 650 Å to form a capping layer (CPL), thus completing the manufacture of an organic electroluminescent device.

The structural formulas of F4-TCNQ, NPB, PAPB, Ir(mppy)₃, ET-06, LiQ, CP-05, a compound A, and a compound B were shown in Table 16 below:

TABLE 16

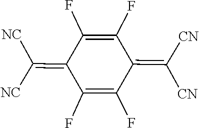 [SMILES: N#CC(C#N)=c1c(F)c(F)c(=C(C#N)C#N)c(F)c1F]

F4-TCNQ

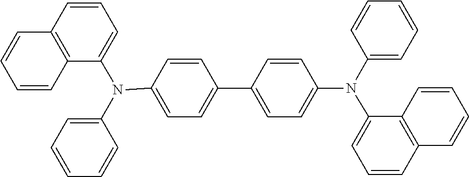 [SMILES: c1ccc(N(c2ccc(-c3ccc(N(c4ccccc4)c4cccc5ccccc45)cc3)cc2)c2cccc3ccccc23)cc1]

NPB

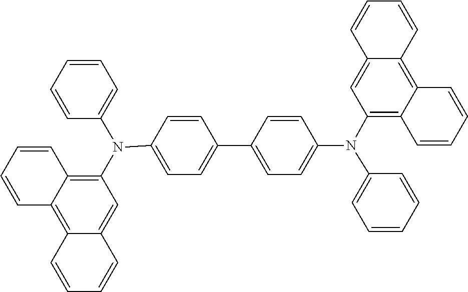 [SMILES: c1ccc(N(c2ccc(-c3ccc(N(c4ccccc4)c4cc5ccccc5c5ccccc45)cc3)cc2)c2cc3ccccc3c3ccccc23)cc1]

PAPB

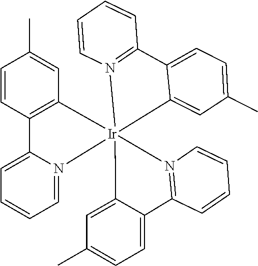

Ir(mppy)₃

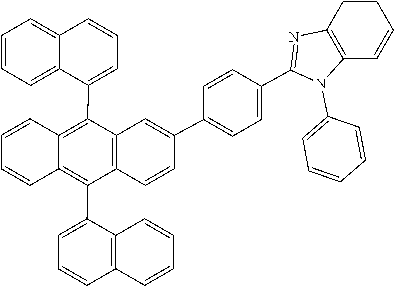 [SMILES: C1=Cc2c(nc(-c3ccc(-c4ccc5c(-c6cccc7ccccc67)c6ccccc6c(-c6cccc7ccccc67)c5c4)cc3)n2-c2ccccc2)CC1]

ET-06

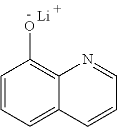

LiQ

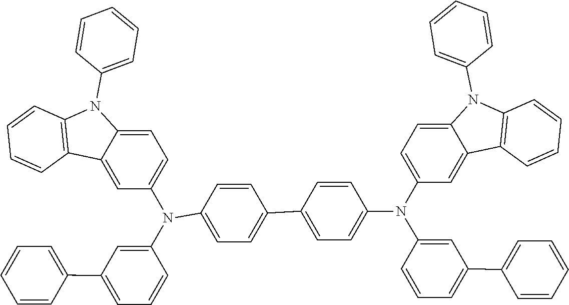 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

CP-05

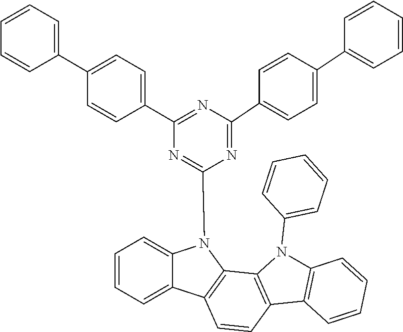 [SMILES: c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1]

Compound A

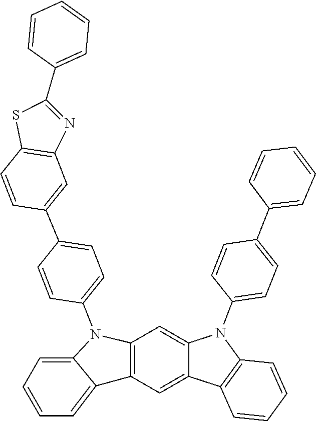 [SMILES: c1ccc(-c2ccc(-n3c4ccccc4c4cc5c6ccccc6n(-c6ccc(-c7ccc8sc(-c9ccccc9)nc8c7)cc6)c5cc43)cc2)cc1]

Compound B

### Examples 2 to 53

An organic electroluminescent device was manufactured by the same method as that in Example 1, except that host material compositions GH-X-Y shown in Table 17 below were respectively used instead of the host material composition GH-1-1 when the organic electroluminescent layer was formed.

### Comparative Examples 1 to 4

An organic electroluminescent device was manufactured by the same method as that in Example 1 except that host material compositions GH-X-Y shown in Table 17 below were used instead of the host material composition GH-1-1 when the organic electroluminescent layer was formed.

In the above Examples and Comparative Examples, the host material compositions GH-X-Y used were obtained by respectively mixing the first compounds in Preparation Examples 1 to 43 and the second compounds in Preparation Examples 44 to 64, and the specific composition was shown in Table 17, where a mass ratio refers to a ratio of the mass percentage of compounds shown in the front column to compounds shown in the latter column in the table. By taking the composition GH-1-1 as an example, in connection with Table 17, it can be seen that GH-1-1 was obtained by mixing a compound 67 and a compound 11-6 in a mass ratio of 40:60; and by taking a host material GH-D1-1 as an example, in connection with Table 17, it can be seen that GH-D1-1 was obtained by mixing a compound A and a compound II-1 in a mass ratio of 40:60.

For the manufactured organic electroluminescent devices, the IVL performance of the devices was tested under a condition of 20 mA/cm², and the T95 device service life was also tested under a condition of 20 mA/cm², the results of which are shown in Table 17.

TABLE 17
Performance test results of green organic electroluminescent device

| | | | | | | | | External | |
|---|---|---|---|---|---|---|---|---|---|
| | | | | | Luminous | Power | Chromaticity | Quantum | |
| | | | | Voltage | efficiency | efficiency | coordinate | Efficiency, | T95 |
| Example | Composition GH-X-Y | | | (V) | (Cd/A) | (Im/W) | CIEx, CIEy | EQE % | (h) |
| Example 1 | GH-1-1 | | | 3.92 | 84.54 | 67.75 | 0.22, 0.71 | 21.14 | 237 |
| | Compound | Compound | 40:60 | | | | | | |
| | 67 | II-6 | | | | | | | |
| Example 2 | GH-2-1 | | | 3.89 | 93.05 | 74.57 | 0.22, 0.71 | 23.26 | 200 |
| | Compound | Compound | 50:50 | | | | | | |
| | 53 | II-6 | | | | | | | |
| Example 3 | GH-3-1 | | | 3.86 | 87.61 | 70.08 | 0.22, 0.71 | 21.90 | 230 |
| | Compound | Compound | 45:55 | | | | | | |
| | 55 | II-1 | | | | | | | |
| Example 4 | GH-4-1 | | | 3.93 | 89.58 | 71.61 | 0.22, 0.71 | 22.40 | 202 |
| | Compound | Compound | 50:50 | | | | | | |
| | 63 | II-2 | | | | | | | |
| Example 5 | GH-5-1 | | | 3.94 | 82.50 | 65.78 | 0.22, 0.71 | 20.63 | 240 |
| | Compound | Compound | 40:60 | | | | | | |
| | 54 | II-1 | | | | | | | |
| Example 6 | GH-5-2 | | | 3.90 | 90.79 | 73.13 | 0.22, 0.71 | 22.70 | 192 |
| | Compound | Compound | 50:50 | | | | | | |
| | 54 | II-2 | | | | | | | |
| Example 7 | GH-5-3 | | | 3.83 | 88.53 | 70.82 | 0.22, 0.71 | 22.13 | 228 |
| | Compound | Compound | 45:55 | | | | | | |
| | 54 | II-110 | | | | | | | |
| Example 8 | GH-6-1 | | | 3.90 | 83.45 | 67.22 | 0.22, 0.71 | 20.86 | 222 |
| | Compound | Compound | 40:60 | | | | | | |
| | 80 | II-1 | | | | | | | |
| Example 9 | GH-7-1 | | | 3.97 | 86.97 | 68.82 | 0.22, 0.71 | 21.97 | 190 |
| | Compound | Compound | 50:50 | | | | | | |
| | 78 | II-13 | | | | | | | |
| Example 10 | GH-8-1 | | | 3.95 | 87.86 | 69.88 | 0.22, 0.71 | 21.74 | 186 |
| | Compound | Compound | 50:50 | | | | | | |
| | 114 | II-201 | | | | | | | |
| Example 11 | GH-9-1 | | | 3.91 | 82.42 | 66.22 | 0.22, 0.71 | 20.61 | 220 |
| | Compound | Compound | 40:60 | | | | | | |
| | 119 | II-29 | | | | | | | |
| Example 12 | GH-10-1 | | | 3.90 | 98.88 | 78.64 | 0.22, 0.71 | 24.72 | 175 |
| | Compound | Compound | 60:40 | | | | | | |
| | 120 | II-1 | | | | | | | |
| Example 13 | GH-11-1 | | | 3.88 | 85.97 | 69.61 | 0.22, 0.71 | 21.49 | 222 |
| | Compound | Compound | 40:60 | | | | | | |
| | 68 | II-6 | | | | | | | |
| Example 15 | GH-12-1 | | | 3.93 | 90.18 | 72.09 | 0.22, 0.71 | 22.55 | 183 |
| | Compound | Compound | 50:50 | | | | | | |
| | 82 | II-32 | | | | | | | |
| Example 16 | GH-13-1 | | | 3.91 | 91.12 | 73.21 | 0.22, 0.71 | 22.78 | 187 |
| | Compound | Compound | 50:50 | | | | | | |
| | 353 | II-55 | | | | | | | |
| Example 17 | GH-14-1 | | | 3.94 | 89.89 | 71.67 | 0.22, 0.71 | 22.47 | 197 |
| | Compound | Compound | 50:50 | | | | | | |
| | 429 | II-6 | | | | | | | |
| Example 18 | GH-15-1 | | | 3.90 | 90.05 | 72.54 | 0.22, 0.71 | 22.51 | 182 |
| | Compound | Compound | 50:50 | | | | | | |
| | 452 | II-6 | | | | | | | |
| Example 19 | GH-16-1 | | | 3.94 | 82.92 | 66.12 | 0.22, 0.71 | 20.73 | 229 |
| | Compound | Compound | 40:60 | | | | | | |
| | 480 | II-6 | | | | | | | |
| Example 20 | GH-17-1 | | | 3.95 | 83.65 | 66.53 | 0.22, 0.71 | 20.91 | 239 |
| | Compound | Compound | 40:60 | | | | | | |
| | 500 | II-6 | | | | | | | |
| Example 21 | GH-18-1 | | | 3.86 | 90.90 | 73.22 | 0.22, 0.71 | 22.73 | 185 |
| | Compound | Compound | 50:50 | | | | | | |
| | 544 | II-4 | | | | | | | |
| Example 22 | GH-19-1 | | | 3.92 | 89.99 | 72.12 | 0.22, 0.71 | 22.50 | 179 |
| | Compound | Compound | 50:50 | | | | | | |
| | 257 | II-6 | | | | | | | |
| Example 23 | GH-20-1 | | | 3.91 | 82.44 | 66.24 | 0.22, 0.71 | 20.73 | 229 |
| | Compound | Compound | 40:60 | | | | | | |
| | 252 | II-1 | | | | | | | |
| Example 24 | GH-21-1 | | | 3.95 | 82.23 | 65.40 | 0.22, 0.71 | 20.56 | 245 |
| | Compound | Compound | 40:60 | | | | | | |
| | 254 | II-2 | | | | | | | |
| Example 25 | GH-22-1 | | | 3.90 | 83.21 | 67.03 | 0.22, 0.71 | 20.8 | 241 |
| | Compound | Compound | 40:60 | | | | | | |
| | 258 | II-55 | | | | | | | |
| Example 26 | GH-23-1 | | | 3.94 | 84.35 | 67.26 | 0.22, 0.71 | 21.09 | 233 |
| | Compound | Compound | 40:60 | | | | | | |
| | 260 | II-6 | | | | | | | |
| Example 27 | GH-24-1 | | | 3.91 | 90.88 | 73.02 | 0.22, 0.71 | 22.72 | 182 |
| | Compound | Compound | 50:50 | | | | | | |
| | 695 | II-6 | | | | | | | |
| Example 29 | GH-25-1 | | | 3.95 | 91.27 | 72.59 | 0.22, 0.71 | 22.82 | 193 |
| | Compound | Compound | 50:50 | | | | | | |
| | 696 | II-6 | | | | | | | |
| Example 30 | GH-26-1 | | | 3.92 | 98.57 | 78.99 | 0.22, 0.71 | 24.64 | 169 |
| | Compound | Compound | 60:40 | | | | | | |
| | 697 | II-29 | | | | | | | |
| Example 31 | GH-27-1 | | | 3.95 | 91.49 | 72.76 | 0.22, 0.71 | 22.87 | 181 |
| | Compound | Compound | 50:50 | | | | | | |
| | 698 | II-6 | | | | | | | |
| Example 32 | GH-28-1 | | | 3.92 | 90.74 | 72.72 | 0.22, 0.71 | 22.69 | 194 |
| | Compound | Compound | 50:50 | | | | | | |
| | 699 | II-6 | | | | | | | |
| Example 33 | GH-29-1 | | | 3.98 | 75.54 | 59.63 | 0.22, 0.71 | 18.89 | 229 |
| | Compound | Compound | 40:60 | | | | | | |
| | 121 | II-4 | | | | | | | |
| Example 34 | GH-30-1 | | | 3.95 | 77.81 | 61.88 | 0.22, 0.71 | 19.45 | 232 |
| | Compound | Compound | 40:60 | | | | | | |
| | 122 | II-6 | | | | | | | |
| Example 35 | GH-31-1 | | | 3.96 | 75.05 | 59.54 | 0.22, 0.71 | 18.76 | 234 |
| | Compound | Compound | 40:60 | | | | | | |
| | 188 | II-203 | | | | | | | |
| Example 36 | GH-32-1 | | | 3.92 | 78.33 | 61.83 | 0.22, 0.71 | 19.58 | 241 |
| | Compound | Compound | 40:60 | | | | | | |
| | 194 | II-6 | | | | | | | |
| Example 37 | GH-33-1 | | | 3.94 | 73.79 | 58.54 | 0.22, 0.71 | 18.45 | 244 |
| | Compound | Compound | 40:60 | | | | | | |
| | 199 | II-13 | | | | | | | |
| Example 38 | GH-34-1 | | | 3.98 | 77.27 | 60.99 | 0.22, 0.71 | 19.32 | 236 |
| | Compound | Compound | 40:60 | | | | | | |
| | 219 | II-6 | | | | | | | |
| Example 39 | GH-35-1 | | | 3.83 | 80.12 | 64.10 | 0.22, 0.71 | 20.30 | 181 |
| | Compound | Compound | 50:50 | | | | | | |
| | 671 | II-4 | | | | | | | |
| Example 40 | GH-36-1 | | | 3.86 | 79.10 | 63.38 | 0.22, 0.71 | 18.93 | 222 |
| | Compound | Compound | 45:55 | | | | | | |
| | 690 | II-6 | | | | | | | |
| Example 41 | GH-37-1 | | | 3.91 | 91.84 | 73.79 | 0.22, 0.71 | 22.96 | 193 |
| | Compound | Compound | 50:50 | | | | | | |
| | 665 | II-2 | | | | | | | |
| Example 42 | GH-38-1 | | | 3.82 | 92.94 | 74.48 | 0.22, 0.71 | 23.24 | 188 |
| | Compound | Compound | 50:50 | | | | | | |
| | 691 | II-6 | | | | | | | |
| Example 43 | GH-39-1 | | | 3.91 | 99.19 | 79.69 | 0.22, 0.71 | 24.80 | 166 |
| | Compound | Compound | 60:40 | | | | | | |
| | 694 | II-6 | | | | | | | |
| Example 44 | GH-39-1 | | | 3.87 | 90.89 | 73.21 | 0.22, 0.71 | 22.72 | 256 |
| | Compound | Compound | 50:50 | | | | | | |
| | 477 | II-6 | | | | | | | |
| Example 45 | GH-40-1 | | | 3.91 | 82.65 | 66.41 | 0.22, 0.71 | 20.66 | 240 |
| | Compound | Compound | 40:60 | | | | | | |
| | 477 | II-6 | | | | | | | |
| Example 46 | GH-41-1 | | | 3.89 | 93.64 | 75.43 | 0.22, 0.71 | 23.41 | 188 |
| | Compound | Compound | 50:50 | | | | | | |
| | 477 | II-6 | | | | | | | |
| Example 47 | GH-42-1 | | | 3.85 | 92.58 | 74.38 | 0.22, 0.71 | 23.15 | 191 |
| | Compound | Compound | 50:50 | | | | | | |
| | 55 | II-204 | | | | | | | |
| Example 48 | GH-43-1 | | | 3.92 | 93.69 | 75.08 | 0.22, 0.71 | 23.15 | 198 |
| | Compound | Compound | 50:50 | | | | | | |
| | 699 | II-205 | | | | | | | |
| Example 49 | GH-44-1 | | | 3.97 | 86.26 | 68.26 | 0.22, 0.71 | 21.57 | 235 |
| | Compound | Compound | 40:60 | | | | | | |
| | 82 | II-206 | | | | | | | |
| Example 50 | GH-45-1 | | | 3.95 | 91.97 | 73.15 | 0.22, 0.71 | 22.99 | 201 |
| | Compound | Compound | 50:50 | | | | | | |
| | 82 | II-249 | | | | | | | |
| Example 51 | GH-46-1 | | | 3.90 | 90.08 | 73.12 | 0.22, 0.71 | 22.55 | 192 |
| | Compound | Compound | 50:50 | | | | | | |
| | 701 | II-245 | | | | | | | |
| Example 52 | GH-46-2 | | | 3.85 | 90.86 | 72.45 | 0.22, 0.71 | 22.72 | 199 |
| | Compound | Compound | 50:50 | | | | | | |
| | 701 | II-244 | | | | | | | |
| Example 53 | GH-47-1 | | | 3.92 | 82.19 | 66.21 | 0.22, 0.71 | 20.55 | 242 |
| | Compound | Compound | 40:60 | | | | | | |
| | 54 | II-247 | | | | | | | |
| Comparative | GH-D1-1 | | | 4.09 | 66.35 | 50.94 | 0.22, 0.71 | 16.59 | 144 |
| Example 1 | Compound | Compound | 40:60 | | | | | | |
| | A | II-1 | | | | | | | |
| Comparative | GH-D1-2 | | | 4.14 | 64.57 | 48.97 | 0.22, 0.71 | 16.14 | 118 |
| Example 2 | Compound | Compound | 60:40 | | | | | | |
| | A | II-2 | | | | | | | |
| Comparative | GH-D2-1 | | | 4.32 | 61.43 | 44.65 | 0.22, 0.71 | 15.36 | 137 |
| Example 3 | Compound | Compound | 50:50 | | | | | | |
| | B | II-6 | | | | | | | |
| Comparative | GH-D2-2 | | | 4.25 | 61.56 | 45.48 | 0.22, 0.71 | 15.39 | 140 |
| Example 4 | Compound | Compound | 45:55 | | | | | | |
| | B | II-201 | | | | | | | |

From the results of Table 17, it can be seen that when the composition of the present disclosure was used as the host material of the organic electroluminescent layer, various properties of the organic electroluminescent devices manufactured in Examples 1 to 53 were improved compared with Comparative Examples 1 to 4. When the composition of the present disclosure was used as the host of the organic electroluminescent layer, compared with the host composition of the organic electroluminescent layer in Comparative Examples 1 to 4, the T95 service life was increased by at least 15.3%, the current efficiency was increased by at least 11.2%, the power efficiency was increased by at least 14.9%, and the external quantum efficiency was increased by at least 11.2% under the condition that the ratio was not much different. It can be seen that the organic electroluminescent device using the composition of the present disclosure as the host material of the organic electroluminescent layer shows higher luminous efficiency and longer service life, and also has lower driving voltage.

From the above data, it can be seen that with the composition of the present disclosure as the host material of the organic electroluminescent layer of the electronic element, the luminous efficiency (Cd/A), the external quantum efficiency (EQE) and the service life (T95) of the electronic element are all significantly improved. In particular, the organic electroluminescent device has superior performance when the mass percentage of the first compound is 40 to 60% and the mass percentage of the second compound is 40 to 60%. Thus, the organic electroluminescent device with high luminous efficiency and long service life can be manufactured by using the composition of the present disclosure in the organic electroluminescent layer.

1. A composition for an organic optoelectronic device, wherein the composition comprises a first compound and a second compound;
based on the total weight of the composition, the mass percentage of the first compound is 1% to 99%, and the mass percentage of the second compound is 1% to 99%;
the first compound is represented by a Formula I: 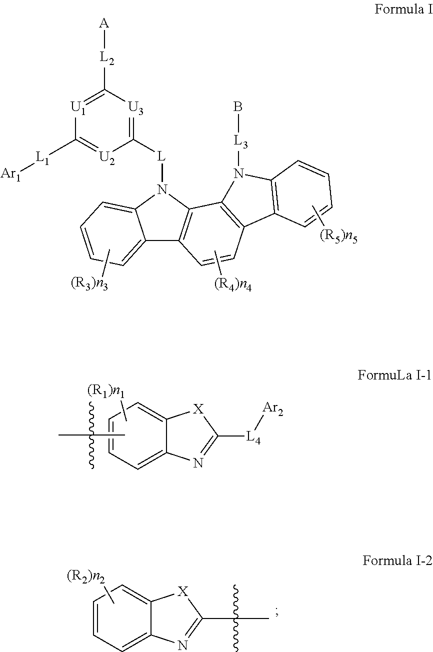
wherein 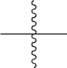
represents a chemical bond, A and B are the same or different, and are respectively and independently selected from substituted or unsubstituted aryl with 6 to 30 carbon atoms, substituted or unsubstituted heteroaryl with 3 to 30 carbon atoms, a Formula I-1 or a Formula I-2, and at least one of A and B is selected from the Formula I-1 or the Formula I-2;
U₁, U₂ and U₃ are the same, and are respectively and independently selected from N;
each R₁, R₂, R₃, R₄, and R₅ are respectively and independently selected from hydrogen, deuterium, a halogen group, cyano, aryl with 6 to 12 carbon atoms, heteroaryl with 5 to 12 carbon atoms, alkyl with 1 to 5 carbon atoms, haloalkyl with 1 to 5 carbon atoms, and cycloalkyl with 3 to 10 carbon atoms;
n₁ represents the number of a substituent R₁, n₁ is selected from 1, 2 or 3, and when n₁ is greater than 1, any two R₁s are the same or different;
n₂ represents the number of a substituent R₂, n₂ is selected from 1, 2, 3 or 4, and when n₂ is greater than 1, any two R₂s are the same or different, and optionally, any two adjacent R₂s form a ring;
n₃ represents the number of a substituent R₃, n₃ is selected from 1, 2, 3 or 4, and when n₃ is greater than 1, any two R₃s are the same or different;
n₄ represents the number of a substituent R₄, n₄ is selected from 1 or 2, and when n₄ is 2, any two R₄s are the same or different;
n₅ represents the number of a substituent R₅, n₅ is selected from 1, 2, 3 or 4, and when n₅ is greater than 1, any two R₅s are the same or different;
X is selected from S or O;
L, L₁, L₂, L₃ and L₄ are the same or different, and are respectively and independently selected from a single bond, substituted or unsubstituted arylene with 6 to 30 carbon atoms, and substituted or unsubstituted heteroarylene with 3 to 30 carbon atoms;
Ar₁ and Ar₂ are the same or different, and are respectively and independently selected from substituted or unsubstituted aryl with 6 to 30 carbon atoms, and substituted or unsubstituted heteroaryl with 3 to 30 carbon atoms;
substituents in the A, B, L, L₁, L₂, L₃, L₄, Ar₁ and Ar₂ are the same or different, and are respectively and independently selected from deuterium, a halogen group, cyano, heteroaryl with 3 to 20 carbon atoms, aryl with 6 to 20 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, or alkoxy with 1 to 10 carbon atoms;
optionally, in Ar₁ and Ar₂, any two adjacent substituents form a ring;
the second compound is represented by a Formula II; 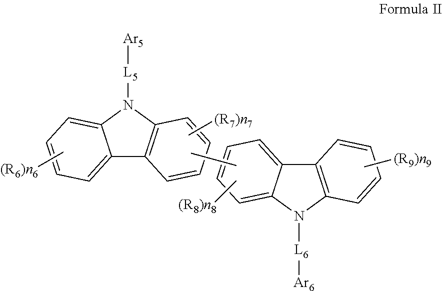
wherein 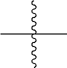
represents a chemical bond,
each R₆, R₇, R₈, and R₉ are respectively and independently selected from hydrogen, deuterium, a halogen group, cyano, aryl with 6 to 25 carbon atoms, heteroaryl with 5 to 25 carbon atoms, alkyl with 1 to 10 carbon atoms, haloalkyl with 1 to 10 carbon atoms, and cycloalkyl with 3 to 10 carbon atoms;
n₆ represents the number of a substituent R₆, n₆ is selected from 1, 2, 3 or 4, and when n₆ is greater than 1, any two R₆s are the same or different;
n₇ represents the number of a substituent R₇, n₇ is selected from 1, 2 or 3, and when n₇ is greater than 1, any two R₇s are the same or different;
n₈ represents the number of a substituent R₈, n₈ is selected from 1, 2 or 3, and when n₈ is greater than 1, any two R₈s are the same or different;
n₉ represents the number of a substituent R₉, n₉ is selected from 1, 2, 3 or 4, and when n₉ is greater than 1, any two R₉s are the same or different;
L₅ and L₆ are the same or different, and are respectively and independently selected from a single bond, substituted or unsubstituted arylene with 6 to 30 carbon atoms, and substituted or unsubstituted heteroarylene with 3 to 30 carbon atoms;
Ar₅ and Ar₆ are the same or different, and are respectively and independently selected from substituted or unsubstituted aryl with 6 to 30 carbon atoms, and substituted or unsubstituted heteroaryl with 3 to 30 carbon atoms;
substituents in L₅, L₆, Ar₅ and Ar₆ are the same or different, and are respectively and independently selected from deuterium, a halogen group, cyano, heteroaryl with 3 to 20 carbon atoms, aryl with 6 to 20 carbon atoms, trialkylsilyl with 3 to 12 carbon atoms, alkyl with 1 to 10 carbon atoms, haloalkyl with 1 to 10 carbon atoms, cycloalkyl with 3 to 10 carbon atoms, heterocycloalkyl with 2 to 10 carbon atoms, or alkoxy with 1 to 10 carbon atoms; and
optionally, in Ar₅ and Ar₆, any two adjacent substituents form a ring.

2. The composition for an organic optoelectronic device of claim 1, wherein in the first compound, the A and B are respectively and independently selected from substituted or unsubstituted aryl with 6 to 25 carbon atoms, substituted or unsubstituted heteroaryl with 5 to 20 carbon atoms, the Formula I-1 or the Formula I-2, and one and only one of A and B is selected from the Formula I-1 or the Formula I-2;
substituents in the A and B are respectively and independently selected from deuterium, a halogen group, cyano, aryl with 6 to 12 carbon atoms, heteroaryl with 5 to 12 carbon atoms, alkyl with 1 to 5 carbon atoms, or cycloalkyl with 3 to 10 carbon atoms.

3. The composition for an organic optoelectronic device of claim 1, wherein in the first compound, the A and B are respectively and independently selected from substituted or unsubstituted phenyl, substituted or unsubstituted naphthyl, substituted or unsubstituted biphenyl, substituted or unsubstituted phenanthryl, substituted or unsubstituted anthryl, substituted or unsubstituted pyridyl, substituted or unsubstituted benzophenanthryl, substituted or unsubstituted spirobifluorenyl, substituted or unsubstituted quinolyl, substituted or unsubstituted isoquinolyl, substituted or unsubstituted dibenzofuranyl, substituted or unsubstituted carbazolyl, substituted or unsubstituted dibenzothienyl, substituted or unsubstituted fluorenyl, substituted or unsubstituted pyrenyl, substituted or unsubstituted phenanthrolinyl, the Formula I-1 or the Formula I-2, and one and only one of A and B is selected from the Formula I-1 or the Formula I-2;
substituents in the A and B are respectively and independently selected from deuterium, fluorine, cyano, methyl, ethyl, n-propyl, isopropyl, tert-butyl, phenyl, naphthyl, biphenyl, pyridyl, carbazolyl, dibenzofuranyl, dibenzothienyl, cyclopentyl, or cyclohexyl.

4. The composition for an organic optoelectronic device of claim 1, wherein in the first compound, the L, L₁, L₂, L₃ and L₄ are the same or different, and are respectively and independently selected from a single bond, substituted or unsubstituted arylene with 6 to 20 carbon atoms, or substituted or unsubstituted heteroarylene with 5 to 20 carbon atoms; and
substituents in the L, L₁, L₂, L₃ and L₄ are respectively and independently selected from deuterium, a halogen group, cyano, aryl with 6 to 12 carbon atoms or alkyl with 1 to 5 carbon atoms.

5. (canceled)

6. The composition for an organic optoelectronic device of claim 1, wherein in the first compound, the L, L₁, L₂, L₃ and L₄ are the same or different, and are respectively and independently selected from a single bond or a substituted or unsubstituted group V, wherein the unsubstituted group V is selected from a group consisting of the following groups: 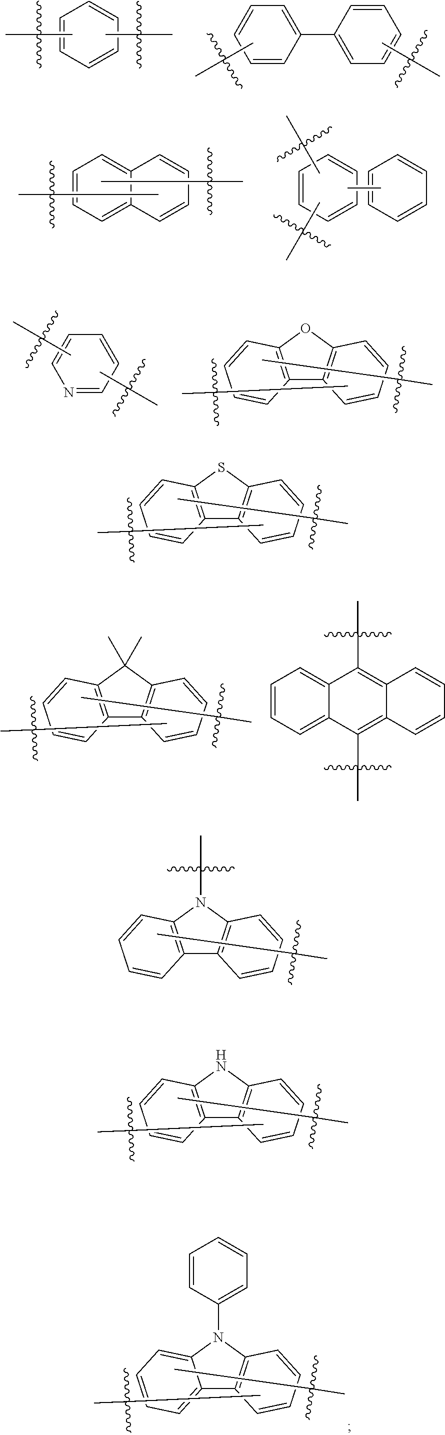
wherein 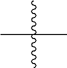
represents a chemical bond; the substituted group V has one or more substituents, and the substituents are each independently selected from deuterium, cyano, fluorine, methyl, ethyl, n-propyl, isopropyl, tert-butyl, or phenyl; and when the number of the substituents in the V is greater than 1, the substituents are the same or different.

7. The composition for an organic optoelectronic device of claim 1, wherein in the first compound, the Ar₁ and Ar₂ are each independently selected from substituted or unsubstituted aryl with 6 to 25 carbon atoms, or substituted or unsubstituted heteroaryl with 4 to 20 carbon atoms;
substituents in the Ar₁ are respectively and independently selected from deuterium, a halogen group, cyano, aryl with 6 to 12 carbon atoms, heteroaryl with 5 to 12 carbon atoms, alkyl with 1 to 5 carbon atoms, or cycloalkyl with 3 to 10 carbon atoms;
substituents in the Ar₂ are respectively and independently selected from deuterium, a halogen group, cyano, aryl with 6 to 12 carbon atoms, heteroaryl with 5 to 12 carbon atoms, alkyl with 1 to 5 carbon atoms, haloalkyl with 1 to 5 carbon atoms, or cycloalkyl with 3 to 10 carbon atoms;
optionally, any two adjacent substituents in the Ar₂ form a saturated or unsaturated ring with 5 to 13 carbon atoms.

8. (canceled)

9. The composition for an organic optoelectronic device of claim 1 wherein in the first compound, the Ar₁ and Ar₂ are each independently selected from a substituted or unsubstituted group W₁, wherein the unsubstituted W₁ is selected from a group consisting of the following groups: 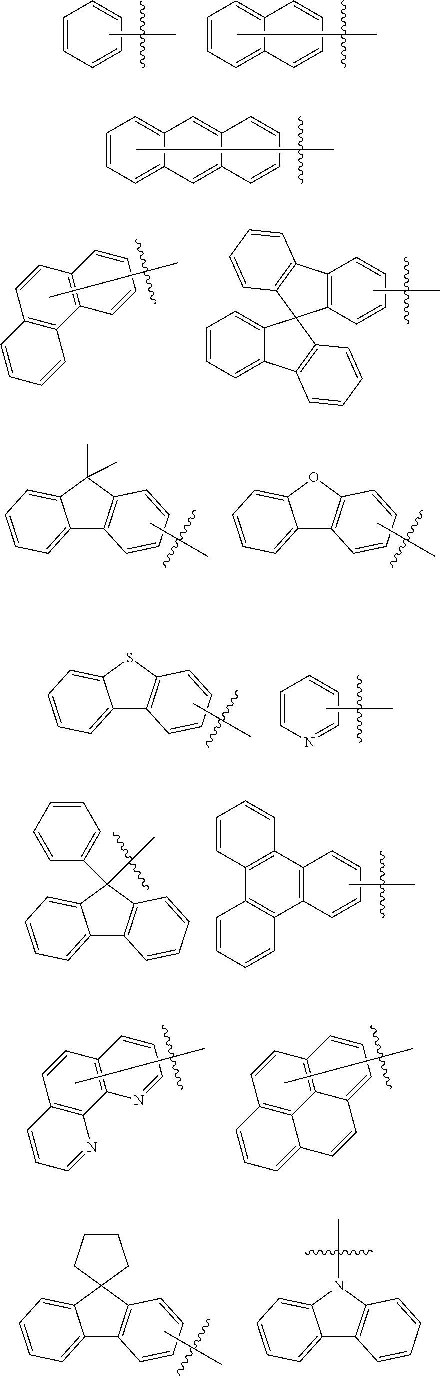 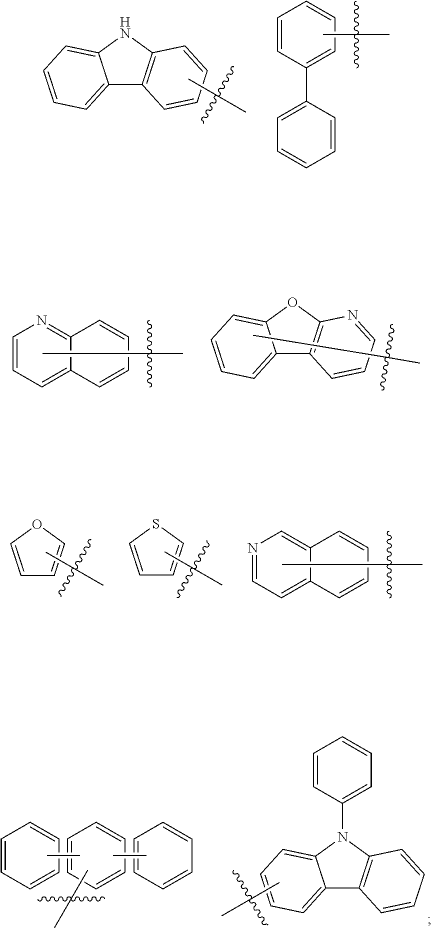
wherein 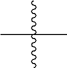
represents a chemical bond; the substituted group W₁ has one or more substituents, and the substituents are each independently selected from deuterium, cyano, fluorine, methyl, ethyl, n-propyl, isopropyl, tert-butyl, phenyl, naphthyl, biphenyl, or carbazolyl; and when the number of the substituents in the W₁ is greater than 1, the substituents are the same or different.

10. The composition for an organic optoelectronic device of claim 1, wherein in the first compound, each R₁, R₂, R₃, R₄, and R₅ are respectively and independently selected from hydrogen, deuterium, fluorine, cyano, methyl, ethyl, n-propyl, isopropyl, tert-butyl, phenyl, pyridyl, trifluoromethyl or biphenyl; or, any two adjacent R₂s form a benzene ring, a naphthalene ring, or a phenanthrene ring.

11. (canceled)

12. The composition for an organic optoelectronic device of claim 1, wherein in the second compound, each R₆, R₇, R₈, and R₉ are respectively and independently selected from hydrogen, deuterium, a halogen group, cyano, aryl with 6 to 18 carbon atoms, heteroaryl with 5 to 12 carbon atoms, alkyl with 1 to 5 carbon atoms, haloalkyl with 1 to 5 carbon atoms, and cycloalkyl with 3 to 6 carbon atoms;
alternatively, each R₆, R₇, R₈, and R₉ are respectively and independently selected from hydrogen, phenyl, naphthyl, biphenyl, dibenzothienyl, fluorenyl, phenanthryl, and terphenyl;
alternatively, each R₆, R₇, R₈, and R₉ are respectively and independently selected from hydrogen or phenyl.

13. The composition for an organic optoelectronic device of claim 1, wherein in the second compound, the L₅ and L₆ are respectively and independently selected from a single bond, substituted or unsubstituted arylene with 6 to 12 carbon atoms, and substituted or unsubstituted heteroarylene with 3 to 20 carbon atoms;
alternatively, the L₅ and L₆ are respectively and independently selected from a single bond, substituted or unsubstituted arylene with 6 to 12 carbon atoms, and substituted or unsubstituted heteroarylene with 3 to 12 carbon atoms;
alternatively, substituents in the L₅ and L₆ are respectively and independently selected from deuterium, a halogen group, cyano, alkyl with 1 to 5 carbon atoms, and phenyl.

14. The composition for an organic optoelectronic device of claim 1, wherein in the second compound, the L₅ and L₆ are respectively and independently selected from a single bond, substituted or unsubstituted phenylene, substituted or unsubstituted naphthylene, substituted or unsubstituted biphenylene, and substituted or unsubstituted carbazolylene;
substituents in the L₅ and L₆ are respectively and independently selected from deuterium, fluorine, cyano, methyl, ethyl, n-propyl, isopropyl, tert-butyl or phenyl;
in the first compound, the L, L₁, L₂, L₃ and L₄ are the same or different, and are respectively and independently selected from a single bond, substituted or unsubstituted phenylene, substituted or unsubstituted naphthylene, substituted or unsubstituted biphenylene, substituted or unsubstituted pyridylene, substituted or unsubstituted dibenzofurylene, substituted or unsubstituted dibenzothienylene, substituted or unsubstituted fluorenylene, substituted or unsubstituted carbazolylene, and substituted or unsubstituted anthrylene;
substituents in the L, L₁, L₂, L₃ and L₄ are respectively and independently selected from deuterium, cyano, fluorine, methyl, ethyl, n-propyl, isopropyl, tert-butyl or phenyl.

15. The composition for an organic optoelectronic device of claim 1, wherein in the second compound, the Ar₅ and Ar₆ are respectively and independently selected from substituted or unsubstituted aryl with 6 to 25 carbon atoms, and substituted or unsubstituted heteroaryl with 5 to 12 carbon atoms;
substituents in the Ar₅ and Ar₆ are respectively and independently selected from deuterium, a halogen group, alkyl with 1 to 5 carbon atoms, and aryl with 6 to 12 carbon atoms;
optionally, in Ar₅ and Ar₆, any two adjacent substituents form a saturated or unsaturated ring with 5 to 13 carbon atoms.

16. The composition for an organic optoelectronic device of claim 1, wherein in the second compound, the Ar₅ and Ar₆ are respectively and independently selected from substituted or unsubstituted phenyl, substituted or unsubstituted naphthyl, substituted or unsubstituted biphenyl, substituted or unsubstituted terphenyl, substituted or unsubstituted fluorenyl, substituted or unsubstituted phenanthryl, substituted or unsubstituted pyridyl, substituted or unsubstituted dibenzofuranyl, substituted or unsubstituted dibenzothienyl, substituted or unsubstituted carbazolyl, and substituted or unsubstituted triphenylene;
alternatively, the Ar₅ and Ar₆ are respectively and independently selected from substituted or unsubstituted phenyl, substituted or unsubstituted naphthyl, substituted or unsubstituted biphenyl, substituted or unsubstituted terphenyl, substituted or unsubstituted fluorenyl, substituted or unsubstituted phenanthryl, substituted or unsubstituted pyridyl, substituted or unsubstituted dibenzofuranyl, and substituted or unsubstituted dibenzothienyl;
alternatively, substituents in the Ar₅ and Ar₆ are respectively and independently selected from deuterium, fluorine, cyano, a halogen group, methyl, ethyl, n-propyl, isopropyl, tert-butyl, phenyl, naphthyl, and biphenyl;
optionally, in Ar₅ and Ar₆, any two adjacent substituents form a saturated or unsaturated ring with 5 to 13 carbon atoms
in the first compound, the Ar₁ and Ar₂ are each independently selected from substituted or unsubstituted phenyl, substituted or unsubstituted biphenyl, substituted or unsubstituted naphthyl, substituted or unsubstituted dibenzofuranyl, substituted or unsubstituted dibenzothienyl, substituted or unsubstituted fluorenyl, substituted or unsubstituted N-phenylcarbazolyl, substituted or unsubstituted carbazolyl, substituted or unsubstituted phenanthryl, substituted or unsubstituted anthryl, substituted or unsubstituted terphenyl, substituted or unsubstituted pyridyl, substituted or unsubstituted pyrenyl, substituted or unsubstituted quinolyl, substituted or unsubstituted isoquinolyl, substituted or unsubstituted phenanthrolinyl, substituted or unsubstituted benzophenanthryl, substituted or unsubstituted furyl, substituted or unsubstituted thienyl or the following group substituted or unsubstituted: 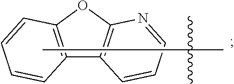
substituents in the Ar₁ and Ar₂ are respectively and independently selected from deuterium, cyano, fluorine, methyl, ethyl, n-propyl, isopropyl, tert-butyl, phenyl, naphthyl, biphenyl, or carbazolyl.

17. (canceled)

18. The composition for an organic optoelectronic device of claim 1, wherein the second compound is selected from a group consisting of the following compounds: 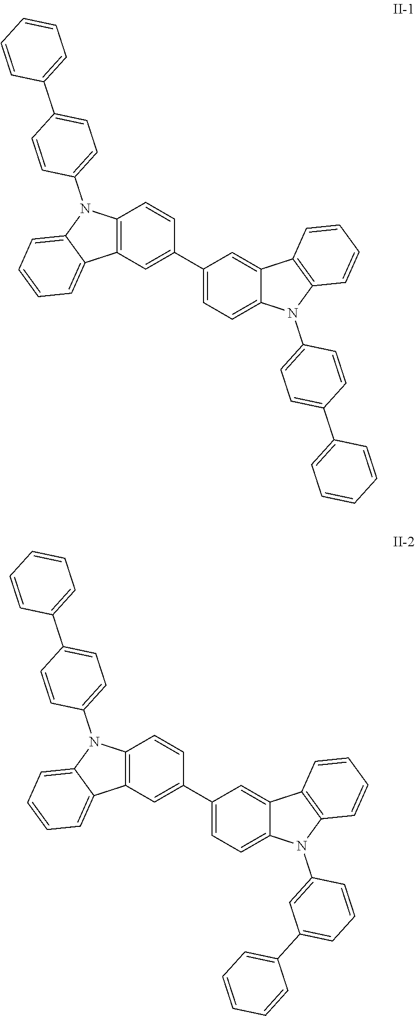 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1] 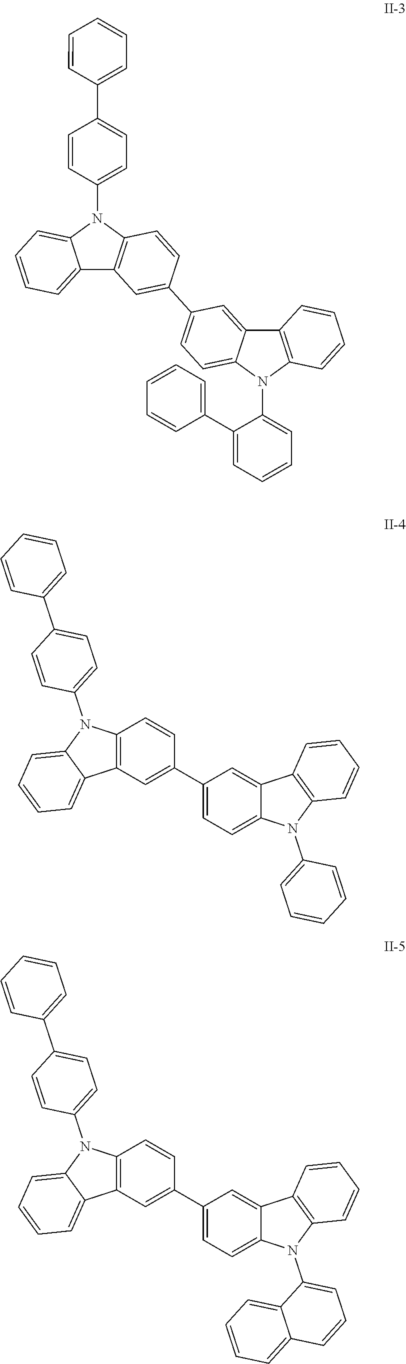 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5cccc6ccccc56)ccc43)cc2)cc1] 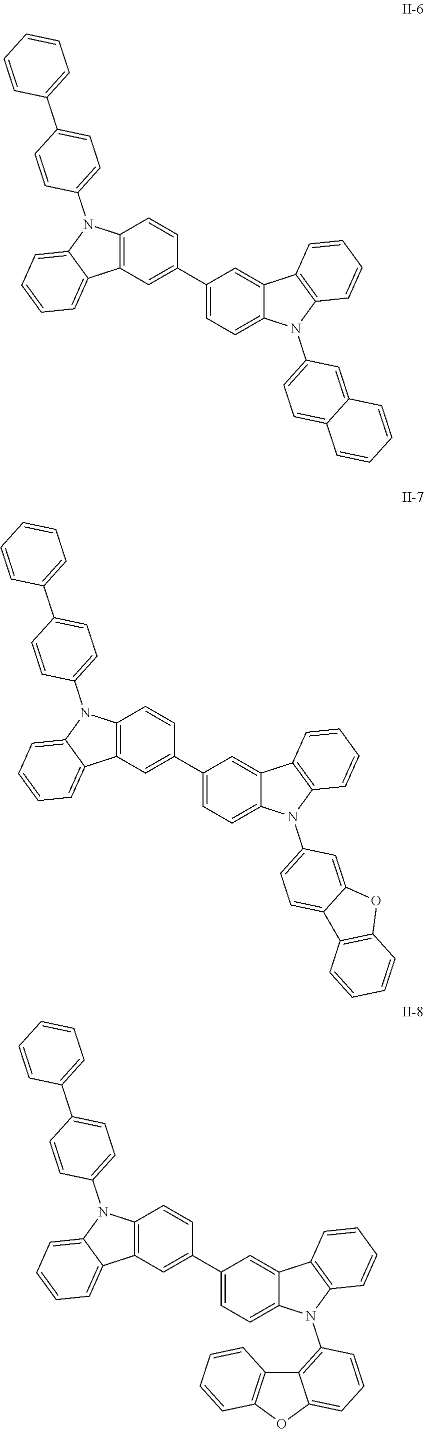 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2ccc(-n3c4ccccc4c4cc(-c5ccc6c(c5)c5ccccc5n6-c5ccc6c(c5)oc5ccccc56)ccc43)cc2)cc1 ; c1ccc(-c2ccc(-n3c4ccccc4c4cc(-c5ccc6c(c5)c5ccccc5n6-c5cccc6oc7ccccc7c56)ccc43)cc2)cc1] 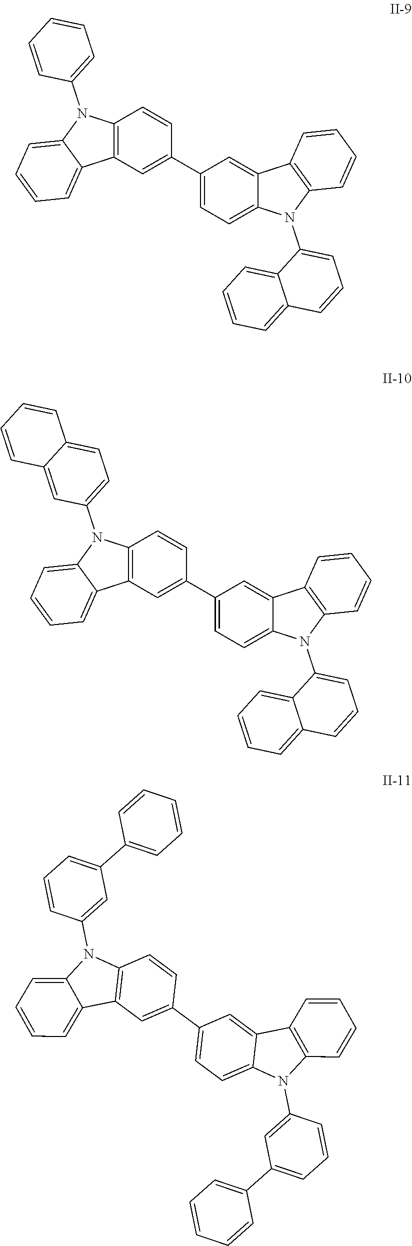 [SMILES: c1ccc(-n2c3ccccc3c3cc(-c4ccc5c(c4)c4ccccc4n5-c4cccc5ccccc45)ccc32)cc1 ; c1ccc2cc(-n3c4ccccc4c4cc(-c5ccc6c(c5)c5ccccc5n6-c5cccc6ccccc56)ccc43)ccc2c1 ; c1ccc(-c2cccc(-n3c4ccccc4c4cc(-c5ccc6c(c5)c5ccccc5n6-c5cccc(-c6ccccc6)c5)ccc43)c2)cc1] 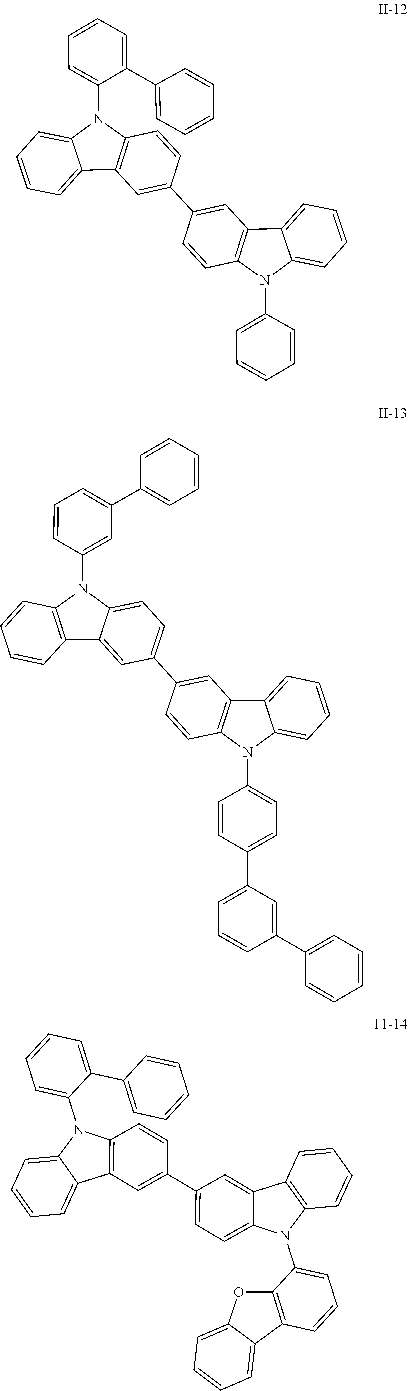 [SMILES: c1ccc(-c2ccccc2-n2c3ccccc3c3cc(-c4ccc5c(c4)c4ccccc4n5-c4ccccc4)ccc32)cc1 ; c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1 ; c1ccc(-c2ccccc2-n2c3ccccc3c3cc(-c4ccc5c(c4)c4ccccc4n5-c4cccc5c4oc4ccccc45)ccc32)cc1] 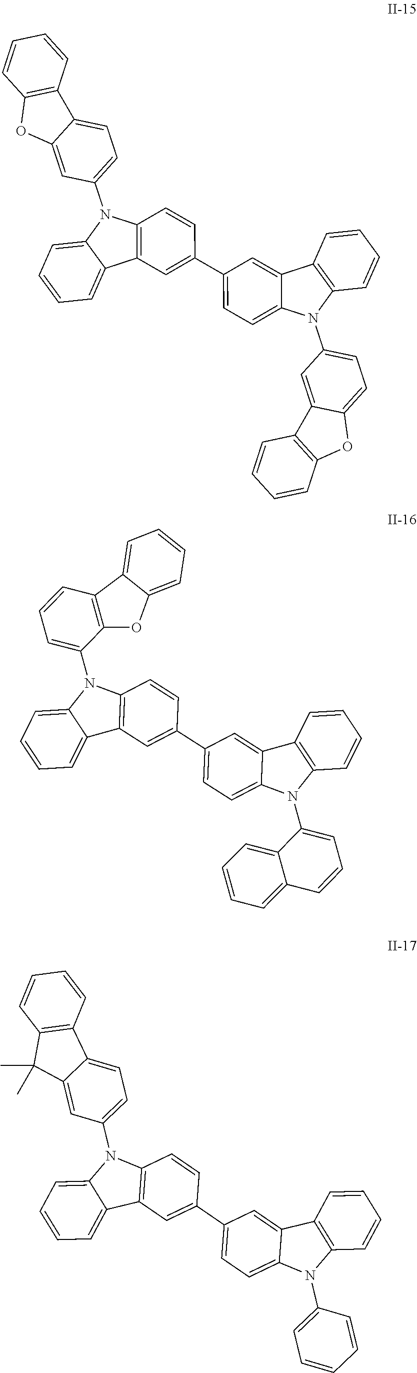 [SMILES: c1ccc2c(c1)oc1cc(-n3c4ccccc4c4cc(-c5ccc6c(c5)c5ccccc5n6-c5ccc6oc7ccccc7c6c5)ccc43)ccc12 ; c1ccc2c(-n3c4ccccc4c4cc(-c5ccc6c(c5)c5ccccc5n6-c5cccc6c5oc5ccccc56)ccc43)cccc2c1 ; CC1(C)c2ccccc2-c2ccc(-n3c4ccccc4c4cc(-c5ccc6c(c5)c5ccccc5n6-c5ccccc5)ccc43)cc21] 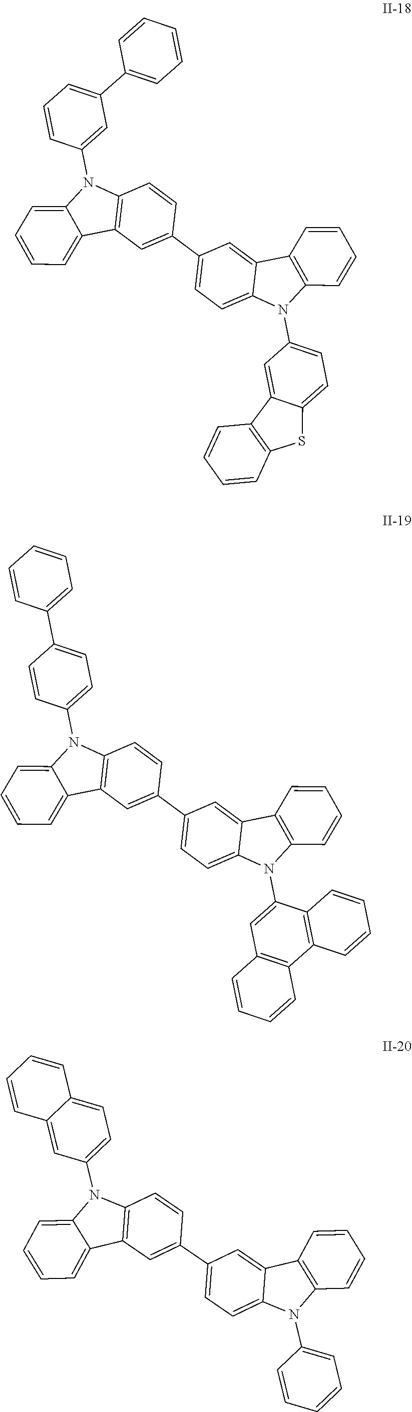 [SMILES: c1ccc(-c2cccc(-n3c4ccccc4c4cc(-c5ccc6c(c5)c5ccccc5n6-c5ccc6sc7ccccc7c6c5)ccc43)c2)cc1 ; c1ccc(-c2ccc(-n3c4ccccc4c4cc(-c5ccc6c(c5)c5ccccc5n6-c5cc6ccccc6c6ccccc56)ccc43)cc2)cc1 ; c1ccc(-n2c3ccccc3c3cc(-c4ccc5c(c4)c4ccccc4n5-c4ccc5ccccc5c4)ccc32)cc1] 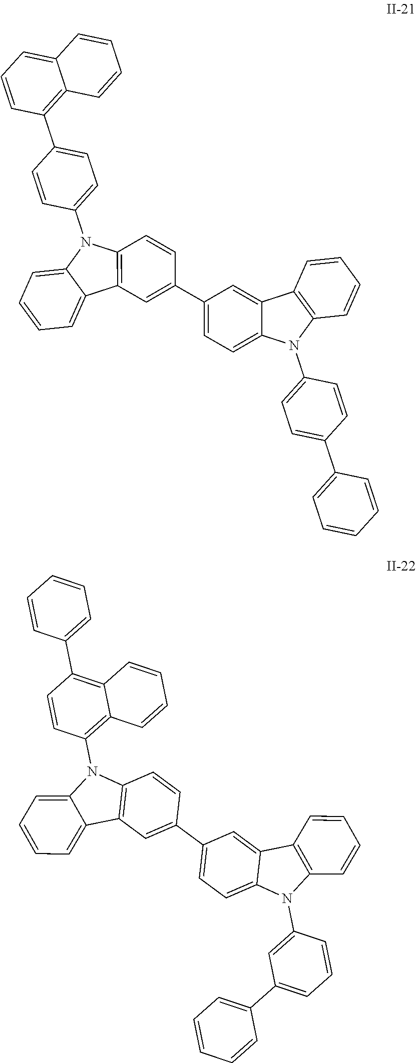 [SMILES: c1ccc(-c2ccc(-n3c4ccccc4c4cc(-c5ccc6c(c5)c5ccccc5n6-c5ccc(-c6cccc7ccccc67)cc5)ccc43)cc2)cc1 ; c1ccc(-c2cccc(-n3c4ccccc4c4cc(-c5ccc6c(c5)c5ccccc5n6-c5ccc(-c6ccccc6)c6ccccc56)ccc43)c2)cc1] 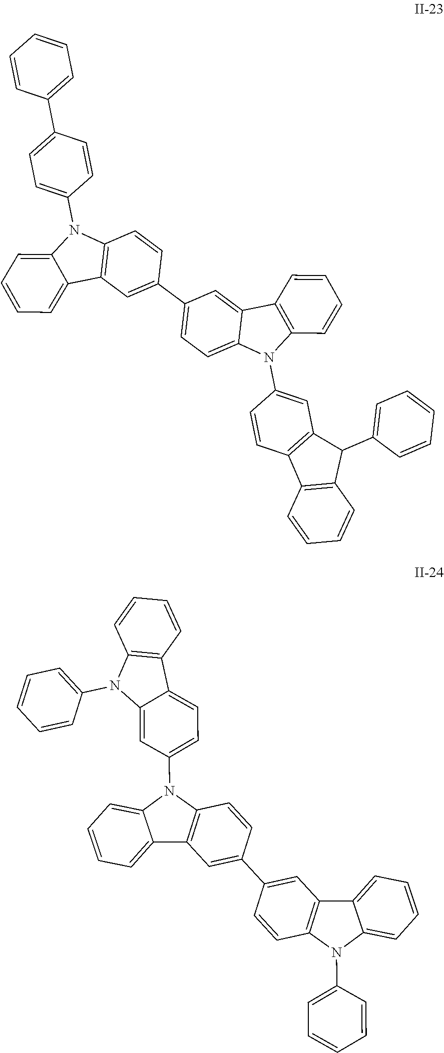 [SMILES: c1ccc(-c2ccc(-n3c4ccccc4c4cc(-c5ccc6c(c5)c5ccccc5n6-c5ccc6c(c5)C(c5ccccc5)c5ccccc5-6)ccc43)cc2)cc1 ; c1ccc(-n2c3ccccc3c3cc(-c4ccc5c(c4)c4ccccc4n5-c4ccc5c6ccccc6n(-c6ccccc6)c5c4)ccc32)cc1] 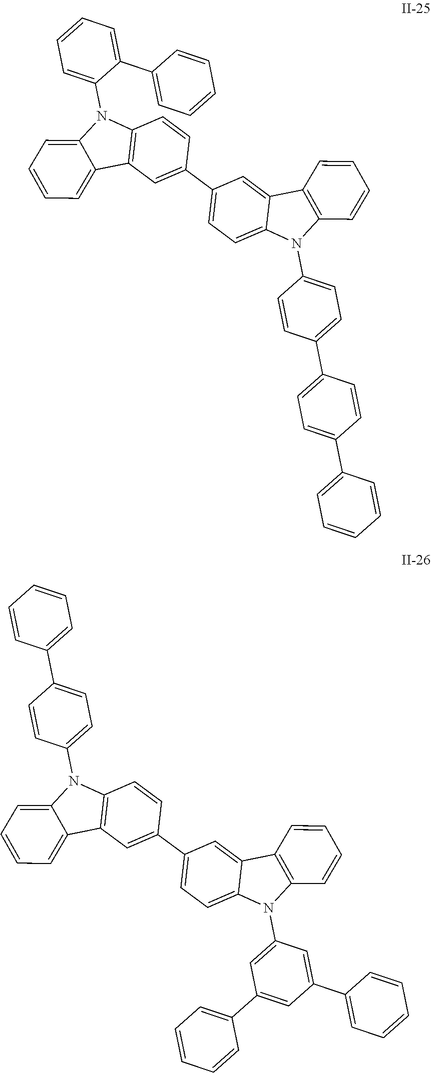 [SMILES: c1ccc(-c2ccc(-c3ccc(-n4c5ccccc5c5cc(-c6ccc7c(c6)c6ccccc6n7-c6ccccc6-c6ccccc6)ccc54)cc3)cc2)cc1 ; c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1] 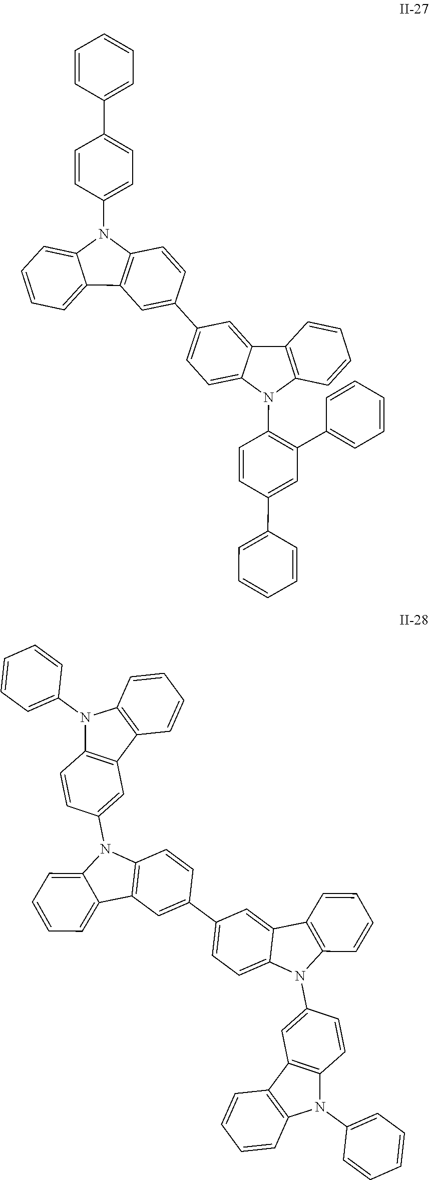 [SMILES: c1ccc(-c2ccc(-n3c4ccccc4c4cc(-c5ccc6c(c5)c5ccccc5n6-c5ccc(-c6ccccc6)cc5-c5ccccc5)ccc43)cc2)cc1 ; c1ccc(-n2c3ccccc3c3cc(-n4c5ccccc5c5cc(-c6ccc7c(c6)c6ccccc6n7-c6ccc7c(c6)c6ccccc6n7-c6ccccc6)ccc54)ccc32)cc1] 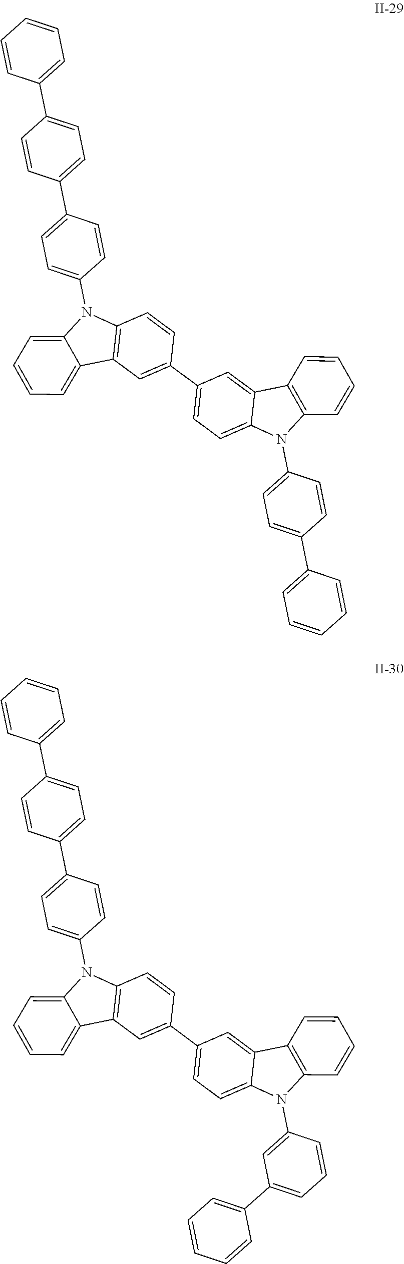 [SMILES: c1ccc(-c2ccc(-c3ccc(-n4c5ccccc5c5cc(-c6ccc7c(c6)c6ccccc6n7-c6ccc(-c7ccccc7)cc6)ccc54)cc3)cc2)cc1 ; c1ccc(-c2ccc(-c3ccc(-n4c5ccccc5c5cc(-c6ccc7c(c6)c6ccccc6n7-c6cccc(-c7ccccc7)c6)ccc54)cc3)cc2)cc1] 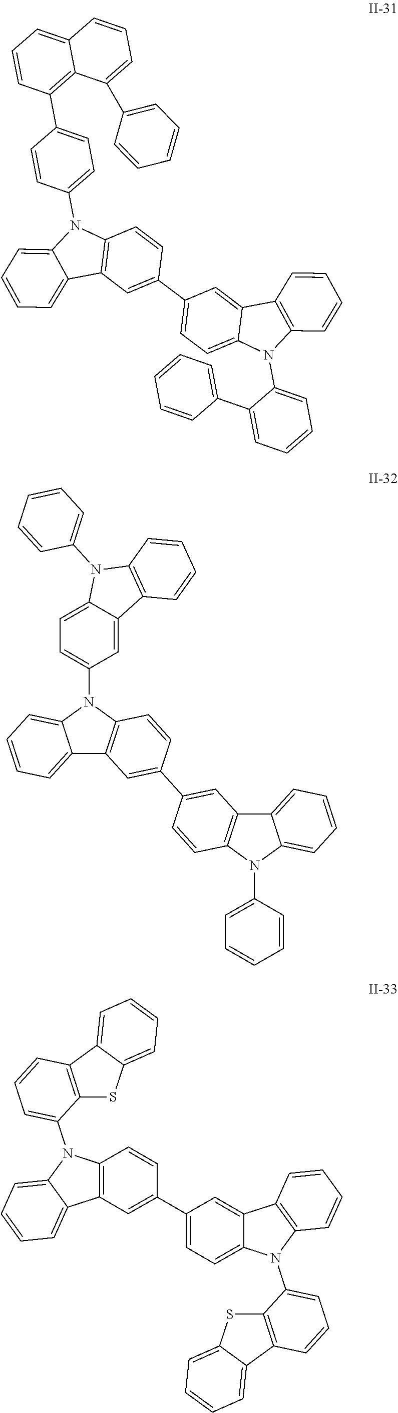 [SMILES: c1ccc(-c2ccccc2-n2c3ccccc3c3cc(-c4ccc5c(c4)c4ccccc4n5-c4ccc(-c5cccc6cccc(-c7ccccc7)c56)cc4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1 ; c1ccc2c(c1)sc1c(-n3c4ccccc4c4cc(-c5ccc6c(c5)c5ccccc5n6-c5cccc6c5sc5ccccc56)ccc43)cccc12] 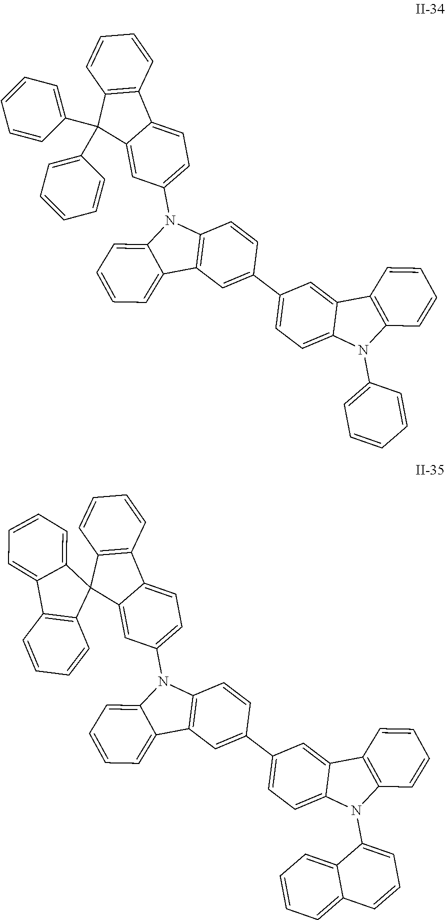 [SMILES: c1ccc(-n2c3ccccc3c3cc(-c4ccc5c(c4)c4ccccc4n5-c4ccc5c(c4)C(c4ccccc4)(c4ccccc4)c4ccccc4-5)ccc32)cc1 ; c1ccc2c(c1)-c1ccccc1C21c2ccccc2-c2ccc(-n3c4ccccc4c4cc(-c5ccc6c(c5)c5ccccc5n6-c5cccc6ccccc56)ccc43)cc21] 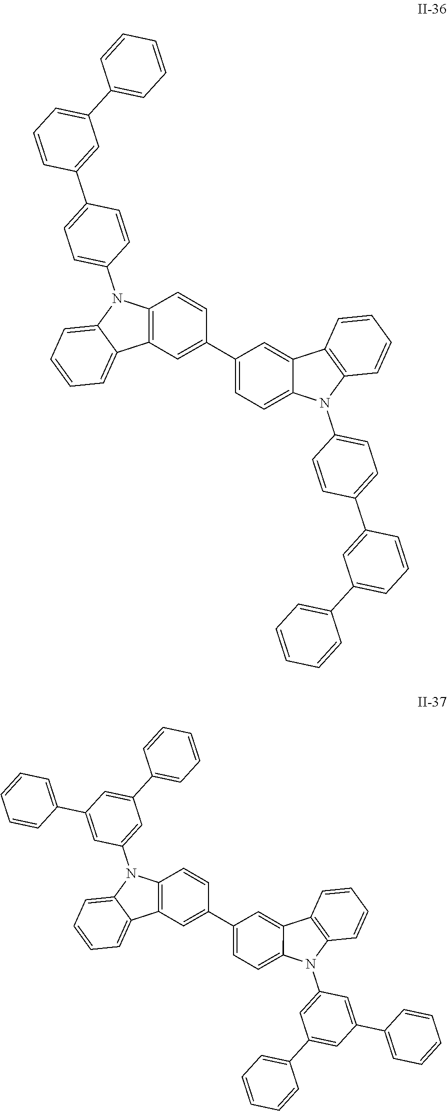 [SMILES: c1ccc(-c2cccc(-c3ccc(-n4c5ccccc5c5cc(-c6ccc7c(c6)c6ccccc6n7-c6ccc(-c7cccc(-c8ccccc8)c7)cc6)ccc54)cc3)c2)cc1 ; c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1] 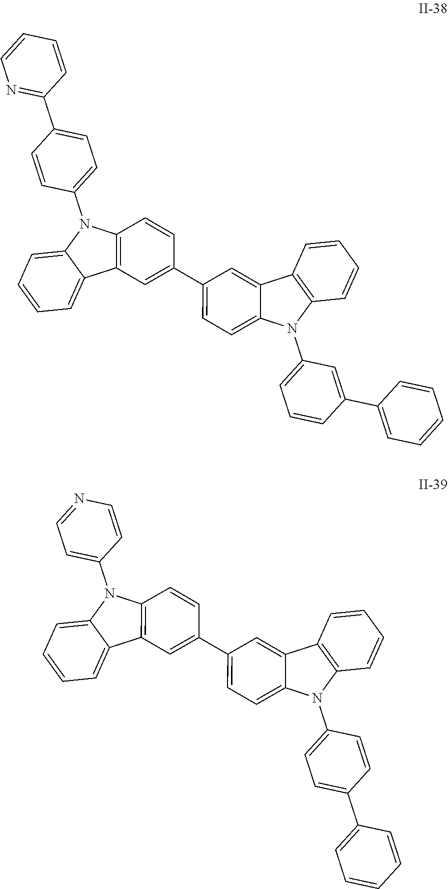 [SMILES: c1ccc(-c2cccc(-n3c4ccccc4c4cc(-c5ccc6c(c5)c5ccccc5n6-c5ccc(-c6ccccn6)cc5)ccc43)c2)cc1 ; c1ccc(-c2ccc(-n3c4ccccc4c4cc(-c5ccc6c(c5)c5ccccc5n6-c5ccncc5)ccc43)cc2)cc1] 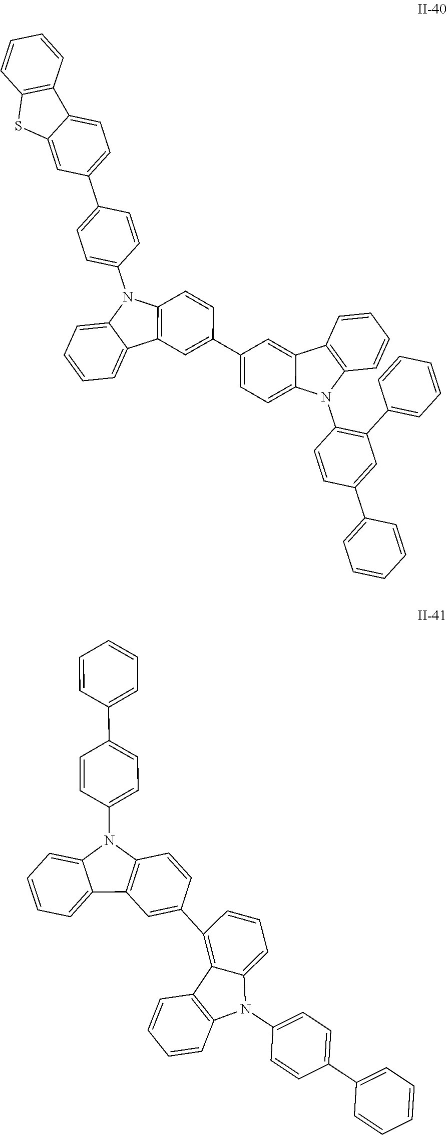 [SMILES: c1ccc(-c2ccc(-n3c4ccccc4c4cc(-c5ccc6c(c5)c5ccccc5n6-c5ccc(-c6ccc7c(c6)sc6ccccc67)cc5)ccc43)c(-c3ccccc3)c2)cc1 ; c1ccc(-c2ccc(-n3c4ccccc4c4cc(-c5cccc6c5c5ccccc5n6-c5ccc(-c6ccccc6)cc5)ccc43)cc2)cc1] 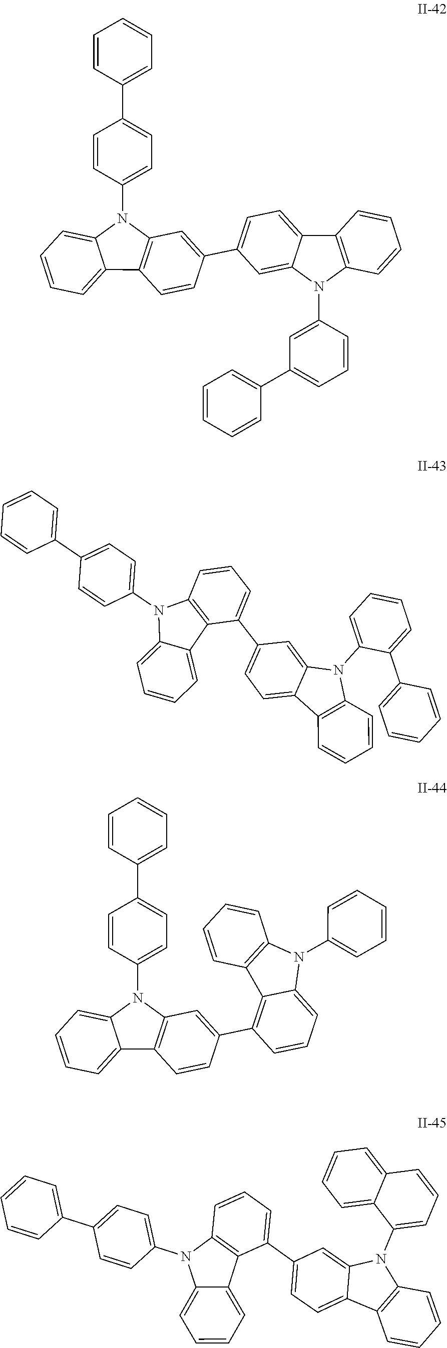 [SMILES: c1ccc(-c2ccc(-n3c4ccccc4c4ccc(-c5ccc6c7ccccc7n(-c7cccc(-c8ccccc8)c7)c6c5)cc43)cc2)cc1 ; c1ccc(-c2ccc(-n3c4ccccc4c4c(-c5ccc6c7ccccc7n(-c7ccccc7-c7ccccc7)c6c5)cccc43)cc2)cc1 ; c1ccc(-c2ccc(-n3c4ccccc4c4ccc(-c5cccc6c5c5ccccc5n6-c5ccccc5)cc43)cc2)cc1 ; c1ccc(-c2ccc(-n3c4ccccc4c4c(-c5ccc6c7ccccc7n(-c7cccc8ccccc78)c6c5)cccc43)cc2)cc1] 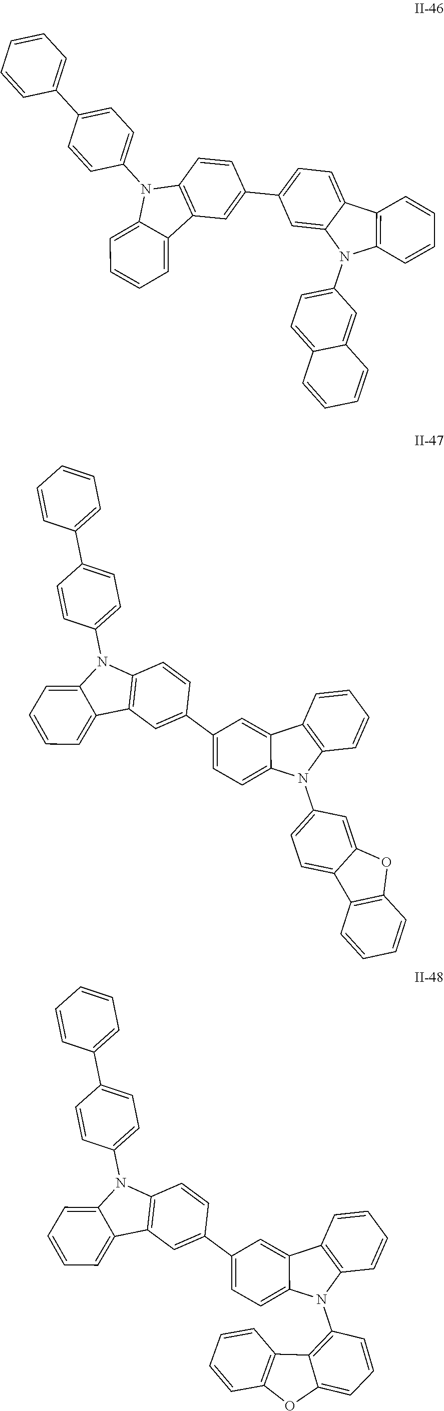 [SMILES: c1ccc(-c2ccc(-n3c4ccccc4c4cc(-c5ccc6c7ccccc7n(-c7ccc8ccccc8c7)c6c5)ccc43)cc2)cc1 ; c1ccc(-c2ccc(-n3c4ccccc4c4cc(-c5ccc6c(c5)c5ccccc5n6-c5ccc6c(c5)oc5ccccc56)ccc43)cc2)cc1 ; c1ccc(-c2ccc(-n3c4ccccc4c4cc(-c5ccc6c(c5)c5ccccc5n6-c5cccc6oc7ccccc7c56)ccc43)cc2)cc1] 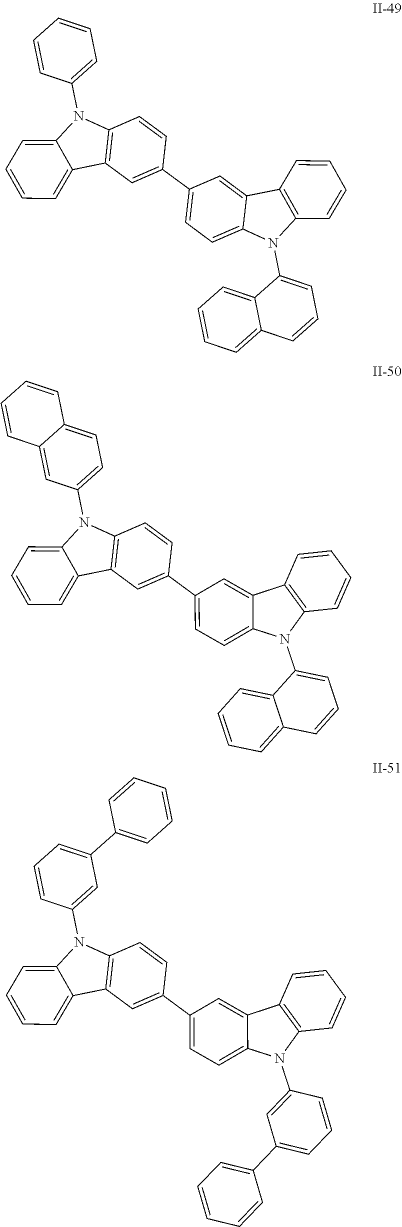 [SMILES: c1ccc(-n2c3ccccc3c3cc(-c4ccc5c(c4)c4ccccc4n5-c4cccc5ccccc45)ccc32)cc1 ; c1ccc2cc(-n3c4ccccc4c4cc(-c5ccc6c(c5)c5ccccc5n6-c5cccc6ccccc56)ccc43)ccc2c1 ; c1ccc(-c2cccc(-n3c4ccccc4c4cc(-c5ccc6c(c5)c5ccccc5n6-c5cccc(-c6ccccc6)c5)ccc43)c2)cc1] 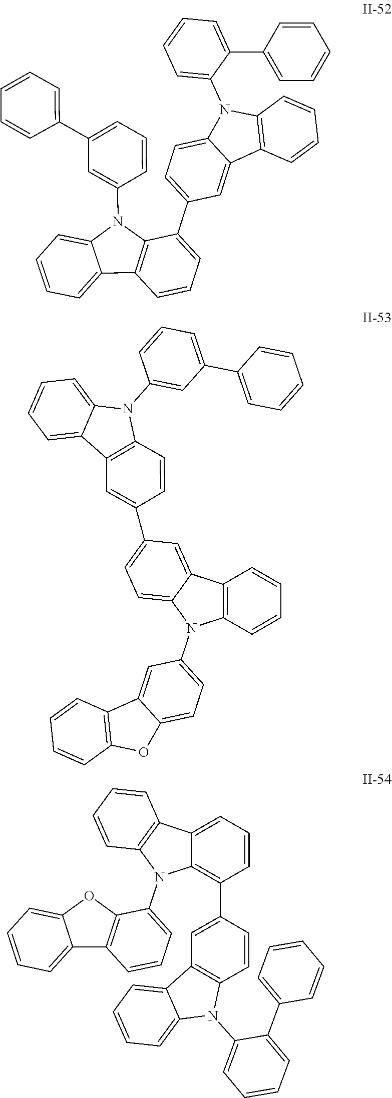 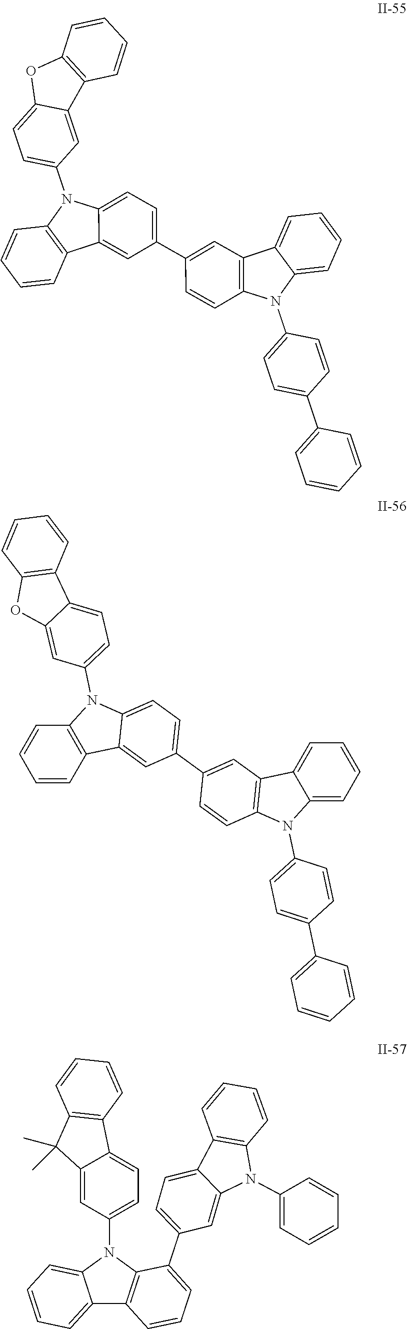 [SMILES: c1ccc(-c2ccc(-n3c4ccccc4c4cc(-c5ccc6c(c5)c5ccccc5n6-c5ccc6oc7ccccc7c6c5)ccc43)cc2)cc1 ; c1ccc(-c2ccc(-n3c4ccccc4c4cc(-c5ccc6c(c5)c5ccccc5n6-c5ccc6c(c5)oc5ccccc56)ccc43)cc2)cc1 ; CC1(C)c2ccccc2-c2ccc(-n3c4ccccc4c4cccc(-c5ccc6c7ccccc7n(-c7ccccc7)c6c5)c43)cc21] 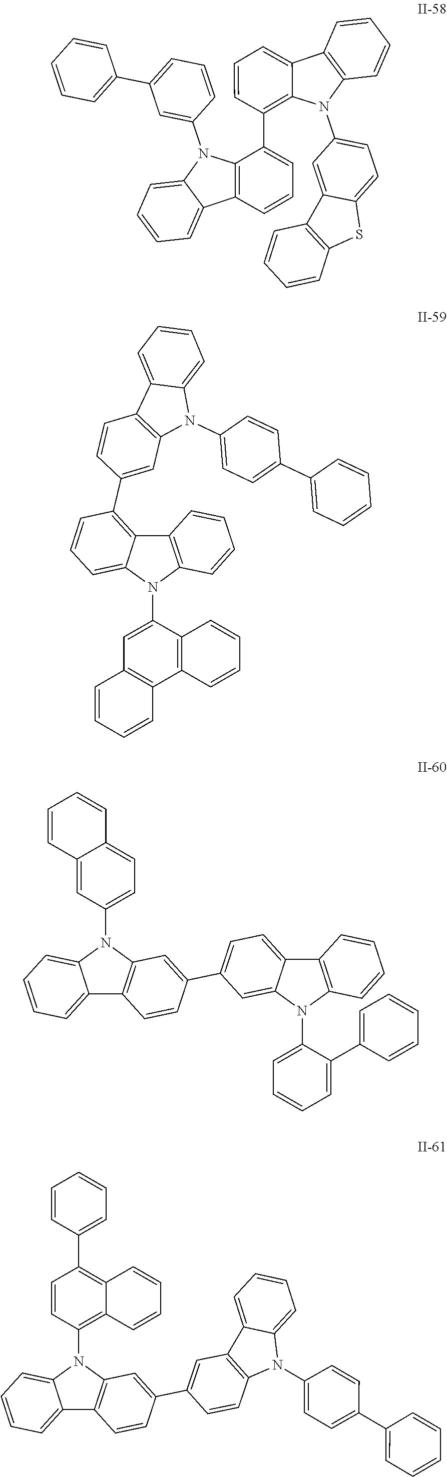 [SMILES: c1ccc(-c2cccc(-n3c4ccccc4c4cccc(-c5cccc6c7ccccc7n(-c7ccc8sc9ccccc9c8c7)c56)c43)c2)cc1 ; c1ccc(-c2ccc(-n3c4ccccc4c4ccc(-c5cccc6c5c5ccccc5n6-c5cc6ccccc6c6ccccc56)cc43)cc2)cc1 ; c1ccc(-c2ccccc2-n2c3ccccc3c3ccc(-c4ccc5c6ccccc6n(-c6ccc7ccccc7c6)c5c4)cc32)cc1 ; c1ccc(-c2ccc(-n3c4ccccc4c4cc(-c5ccc6c7ccccc7n(-c7ccc(-c8ccccc8)c8ccccc78)c6c5)ccc43)cc2)cc1] 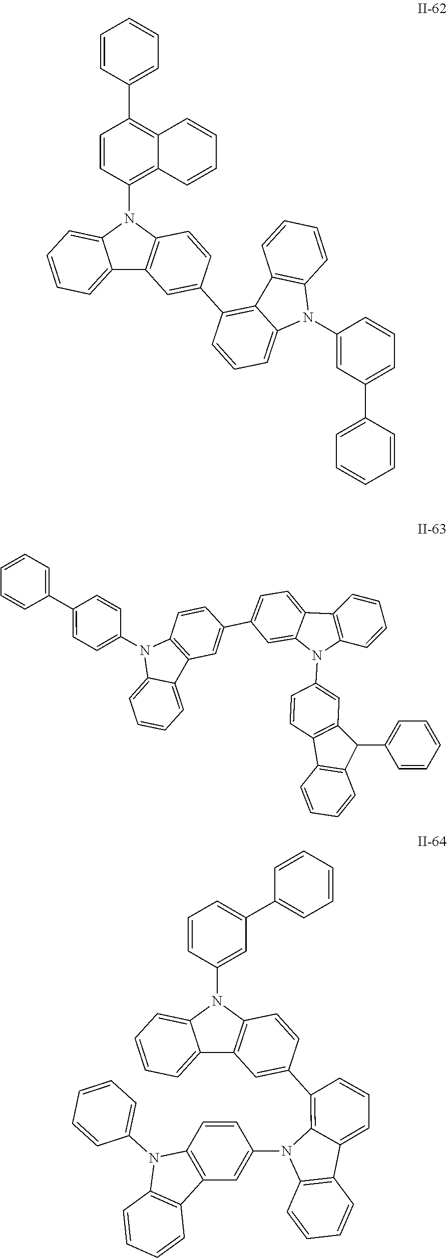 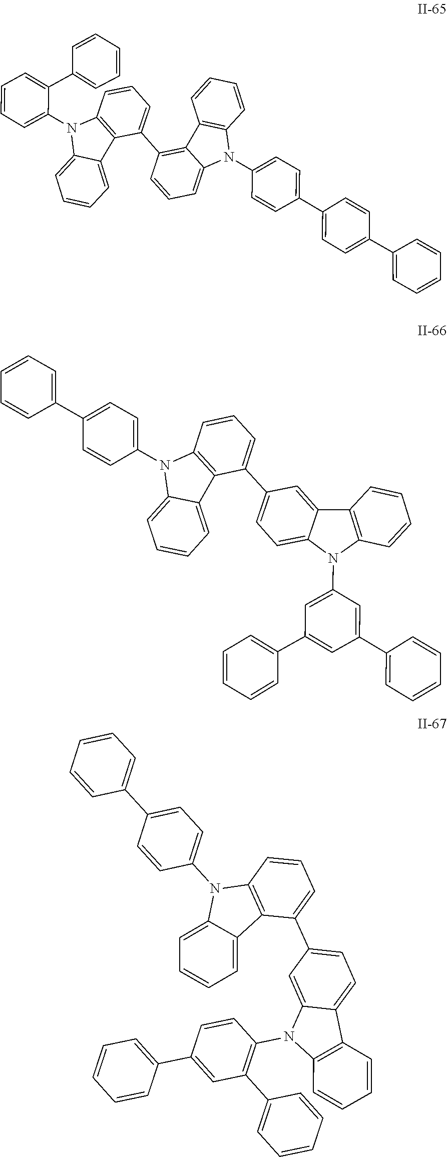 [SMILES: c1ccc(-c2ccc(-c3ccc(-n4c5ccccc5c5c(-c6cccc7c6c6ccccc6n7-c6ccccc6-c6ccccc6)cccc54)cc3)cc2)cc1 ; c1ccc(-c2ccc(-n3c4ccccc4c4c(-c5ccc6c(c5)c5ccccc5n6-c5cc(-c6ccccc6)cc(-c6ccccc6)c5)cccc43)cc2)cc1 ; c1ccc(-c2ccc(-n3c4ccccc4c4c(-c5ccc6c7ccccc7n(-c7ccc(-c8ccccc8)cc7-c7ccccc7)c6c5)cccc43)cc2)cc1] 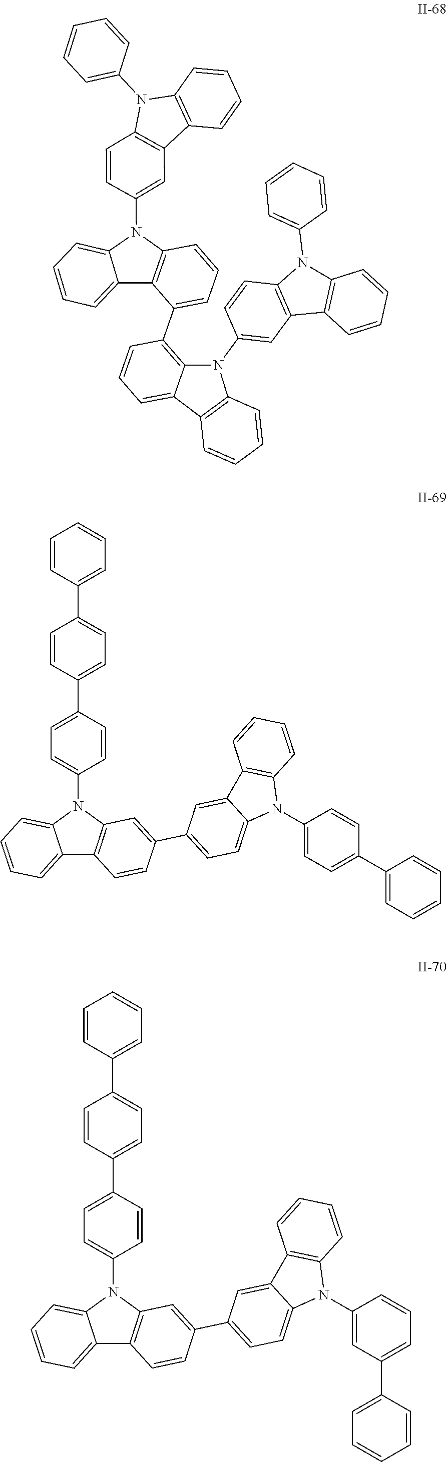 [SMILES: c1ccc(-n2c3ccccc3c3cc(-n4c5ccccc5c5c(-c6cccc7c8ccccc8n(-c8ccc9c(c8)c8ccccc8n9-c8ccccc8)c67)cccc54)ccc32)cc1 ; c1ccc(-c2ccc(-c3ccc(-n4c5ccccc5c5ccc(-c6ccc7c(c6)c6ccccc6n7-c6ccc(-c7ccccc7)cc6)cc54)cc3)cc2)cc1 ; c1ccc(-c2ccc(-c3ccc(-n4c5ccccc5c5ccc(-c6ccc7c(c6)c6ccccc6n7-c6cccc(-c7ccccc7)c6)cc54)cc3)cc2)cc1] 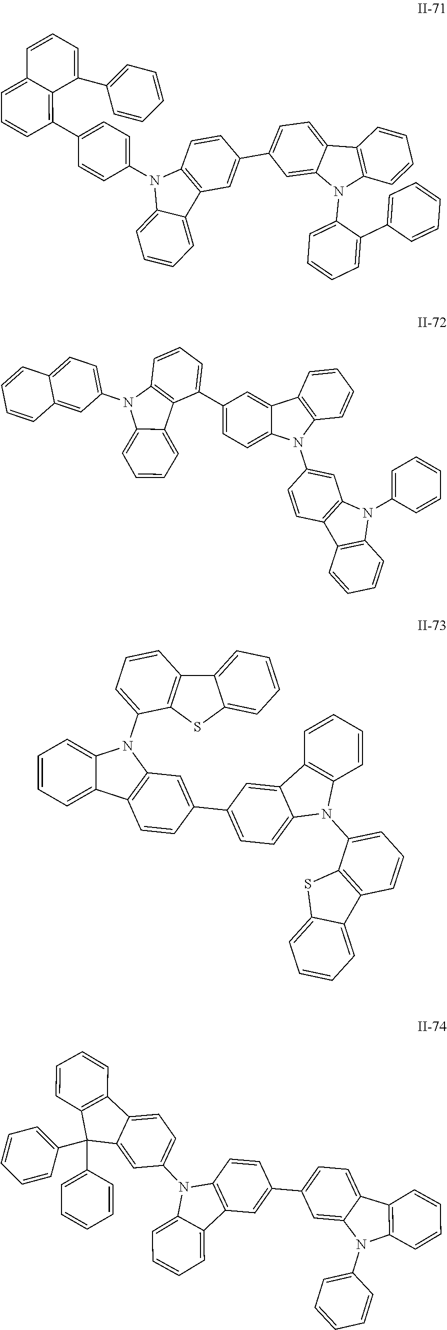 [SMILES: c1ccc(-c2ccccc2-n2c3ccccc3c3ccc(-c4ccc5c(c4)c4ccccc4n5-c4ccc(-c5cccc6cccc(-c7ccccc7)c56)cc4)cc32)cc1 ; c1ccc(-n2c3ccccc3c3ccc(-n4c5ccccc5c5cc(-c6cccc7c6c6ccccc6n7-c6ccc7ccccc7c6)ccc54)cc32)cc1 ; c1ccc2c(c1)sc1c(-n3c4ccccc4c4cc(-c5ccc6c7ccccc7n(-c7cccc8c7sc7ccccc78)c6c5)ccc43)cccc12 ; c1ccc(-n2c3ccccc3c3ccc(-c4ccc5c(c4)c4ccccc4n5-c4ccc5c(c4)C(c4ccccc4)(c4ccccc4)c4ccccc4-5)cc32)cc1] 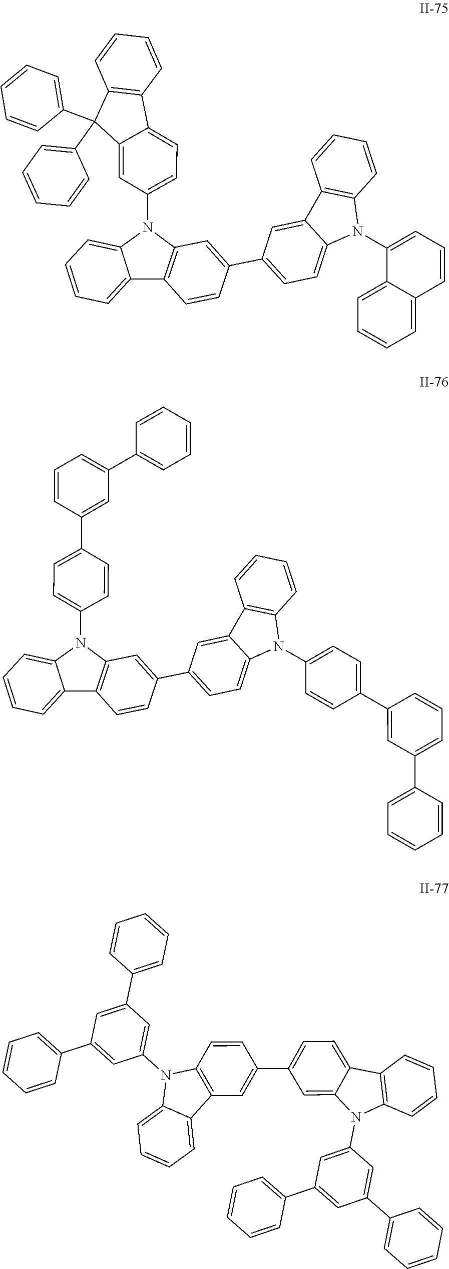 [SMILES: c1ccc(C2(c3ccccc3)c3ccccc3-c3ccc(-n4c5ccccc5c5ccc(-c6ccc7c(c6)c6ccccc6n7-c6cccc7ccccc67)cc54)cc32)cc1 ; c1ccc(-c2cccc(-c3ccc(-n4c5ccccc5c5cc(-c6ccc7c8ccccc8n(-c8ccc(-c9cccc(-c%10ccccc%10)c9)cc8)c7c6)ccc54)cc3)c2)cc1 ; c1ccc(-c2cc(-c3ccccc3)cc(-n3c4ccccc4c4cc(-c5ccc6c7ccccc7n(-c7cc(-c8ccccc8)cc(-c8ccccc8)c7)c6c5)ccc43)c2)cc1] 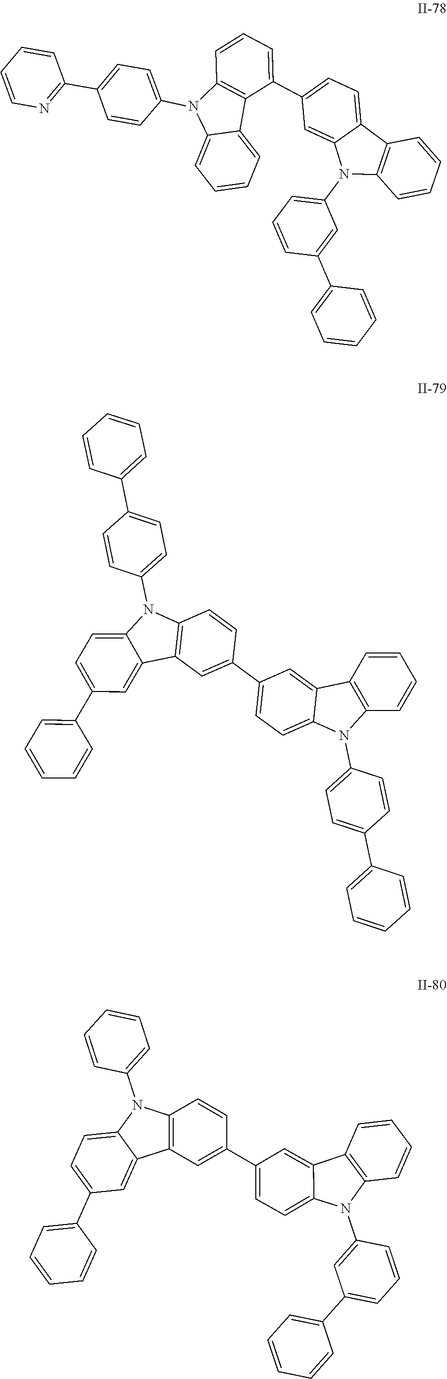 [SMILES: c1ccc(-c2cccc(-n3c4ccccc4c4ccc(-c5cccc6c5c5ccccc5n6-c5ccc(-c6ccccn6)cc5)cc43)c2)cc1 ; c1ccc(-c2ccc(-n3c4ccccc4c4cc(-c5ccc6c(c5)c5cc(-c7ccccc7)ccc5n6-c5ccc(-c6ccccc6)cc5)ccc43)cc2)cc1 ; c1ccc(-c2cccc(-n3c4ccccc4c4cc(-c5ccc6c(c5)c5cc(-c7ccccc7)ccc5n6-c5ccccc5)ccc43)c2)cc1] 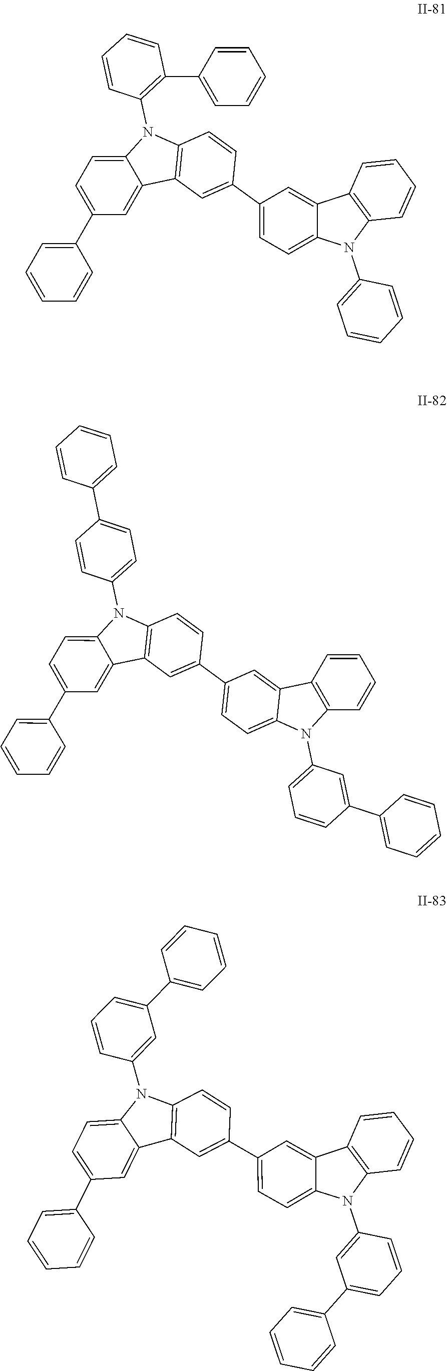 [SMILES: c1ccc(-c2ccc3c(c2)c2cc(-c4ccc5c(c4)c4ccccc4n5-c4ccccc4)ccc2n3-c2ccccc2-c2ccccc2)cc1 ; c1ccc(-c2ccc(-n3c4ccc(-c5ccccc5)cc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5ccc6c(c5)c5cc(-c7ccccc7)ccc5n6-c5cccc(-c6ccccc6)c5)ccc43)c2)cc1] 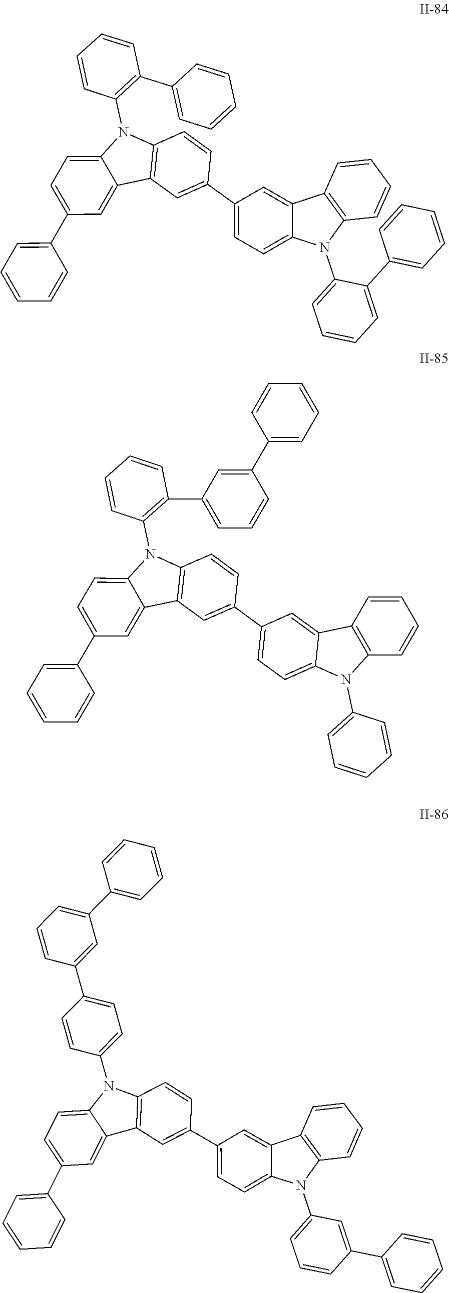 [SMILES: c1ccc(-c2ccc3c(c2)c2cc(-c4ccc5c(c4)c4ccccc4n5-c4ccccc4-c4ccccc4)ccc2n3-c2ccccc2-c2ccccc2)cc1 ; c1ccc(-c2cccc(-c3ccccc3-n3c4ccc(-c5ccccc5)cc4c4cc(-c5ccc6c(c5)c5ccccc5n6-c5ccccc5)ccc43)c2)cc1 ; c1ccc(-c2cccc(-c3ccc(-n4c5ccc(-c6ccccc6)cc5c5cc(-c6ccc7c(c6)c6ccccc6n7-c6cccc(-c7ccccc7)c6)ccc54)cc3)c2)cc1] 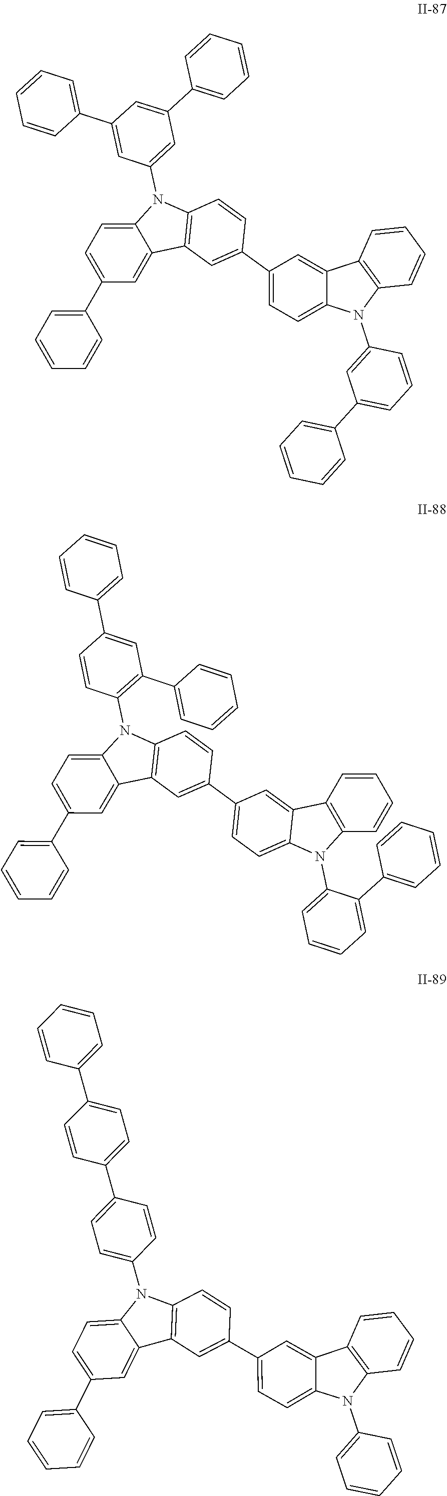 [SMILES: c1ccc(-c2cccc(-n3c4ccccc4c4cc(-c5ccc6c(c5)c5cc(-c7ccccc7)ccc5n6-c5cc(-c6ccccc6)cc(-c6ccccc6)c5)ccc43)c2)cc1 ; c1ccc(-c2ccc(-n3c4ccc(-c5ccccc5)cc4c4cc(-c5ccc6c(c5)c5ccccc5n6-c5ccccc5-c5ccccc5)ccc43)c(-c3ccccc3)c2)cc1 ; c1ccc(-c2ccc(-c3ccc(-n4c5ccc(-c6ccccc6)cc5c5cc(-c6ccc7c(c6)c6ccccc6n7-c6ccccc6)ccc54)cc3)cc2)cc1] 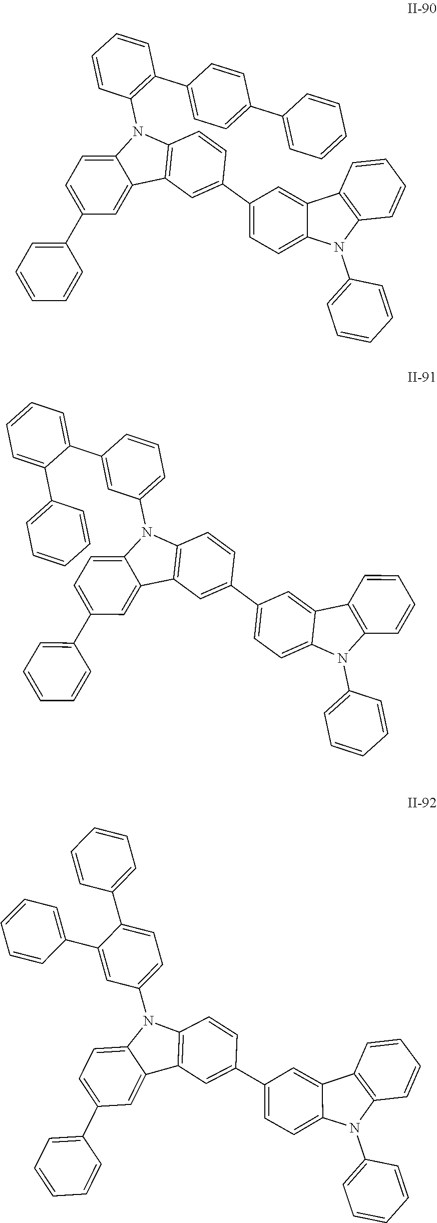 [SMILES: c1ccc(-c2ccc(-c3ccccc3-n3c4ccc(-c5ccccc5)cc4c4cc(-c5ccc6c(c5)c5ccccc5n6-c5ccccc5)ccc43)cc2)cc1 ; c1ccc(-c2ccc3c(c2)c2cc(-c4ccc5c(c4)c4ccccc4n5-c4ccccc4)ccc2n3-c2cccc(-c3ccccc3-c3ccccc3)c2)cc1 ; c1ccc(-c2ccc3c(c2)c2cc(-c4ccc5c(c4)c4ccccc4n5-c4ccccc4)ccc2n3-c2ccc(-c3ccccc3)c(-c3ccccc3)c2)cc1] 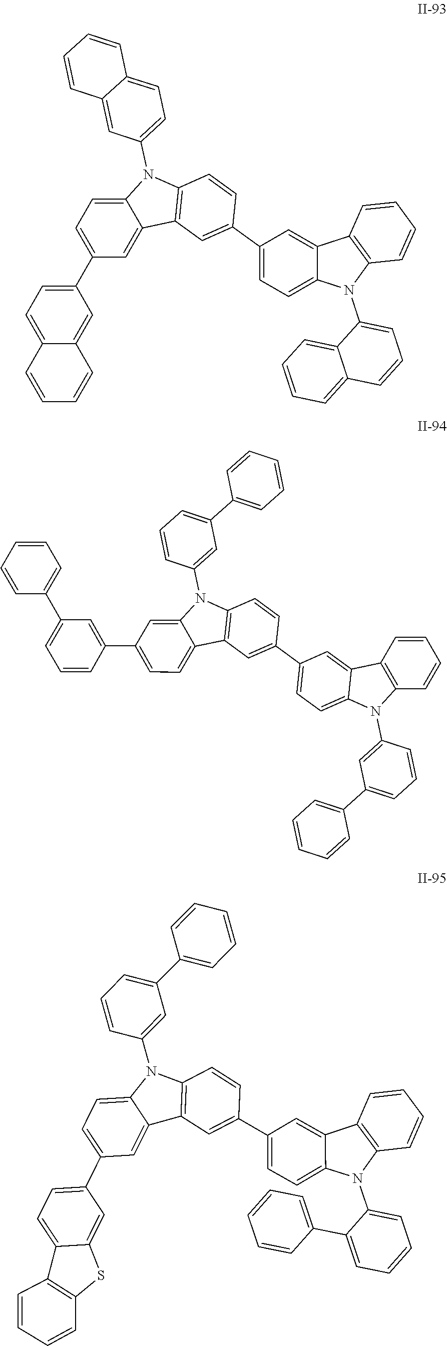 [SMILES: c1ccc2cc(-c3ccc4c(c3)c3cc(-c5ccc6c(c5)c5ccccc5n6-c5cccc6ccccc56)ccc3n4-c3ccc4ccccc4c3)ccc2c1 ; c1ccc(-c2cccc(-c3ccc4c5cc(-c6ccc7c(c6)c6ccccc6n7-c6cccc(-c7ccccc7)c6)ccc5n(-c5cccc(-c6ccccc6)c5)c4c3)c2)cc1 ; c1ccc(-c2cccc(-n3c4ccc(-c5ccc6c(c5)sc5ccccc56)cc4c4cc(-c5ccc6c(c5)c5ccccc5n6-c5ccccc5-c5ccccc5)ccc43)c2)cc1] 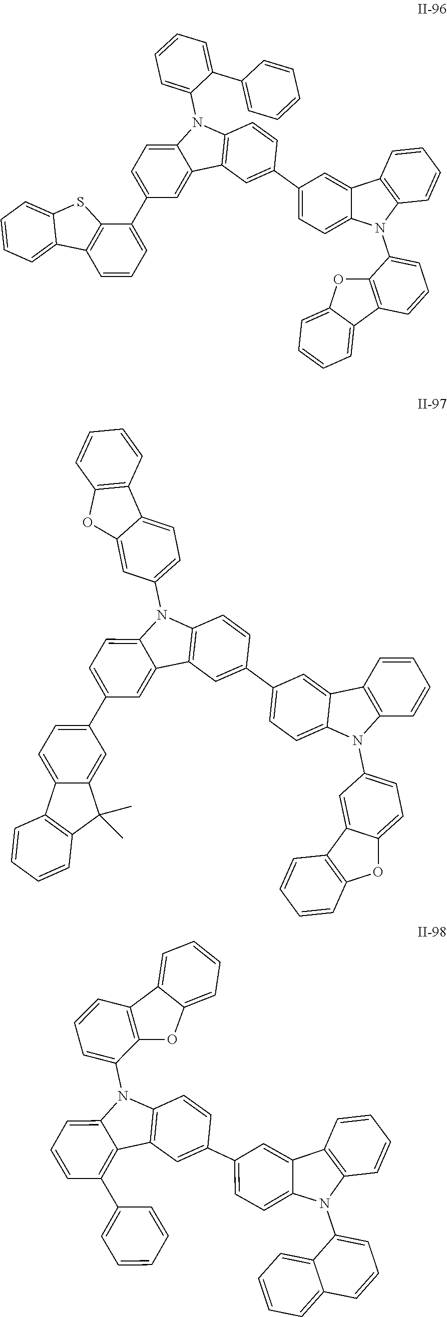 [SMILES: c1ccc(-c2ccccc2-n2c3ccc(-c4ccc5c(c4)c4ccccc4n5-c4cccc5c4oc4ccccc45)cc3c3cc(-c4cccc5c4sc4ccccc45)ccc32)cc1 ; CC1(C)c2ccccc2-c2ccc(-c3ccc4c(c3)c3cc(-c5ccc6c(c5)c5ccccc5n6-c5ccc6oc7ccccc7c6c5)ccc3n4-c3ccc4c(c3)oc3ccccc34)cc21 ; c1ccc(-c2cccc3c2c2cc(-c4ccc5c(c4)c4ccccc4n5-c4cccc5ccccc45)ccc2n3-c2cccc3c2oc2ccccc23)cc1] 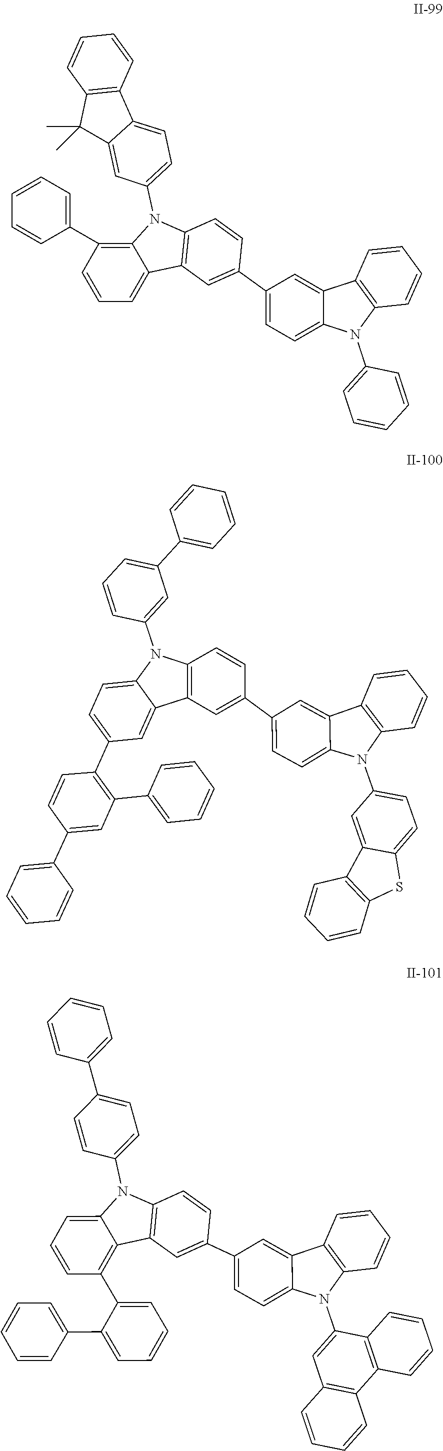 [SMILES: CC1(C)c2ccccc2-c2ccc(-n3c4ccc(-c5ccc6c(c5)c5ccccc5n6-c5ccccc5)cc4c4cccc(-c5ccccc5)c43)cc21 ; c1ccc(-c2cccc(-n3c4ccc(-c5ccc6c(c5)c5ccccc5n6-c5ccc6sc7ccccc7c6c5)cc4c4cc(-c5ccc(-c6ccccc6)cc5-c5ccccc5)ccc43)c2)cc1 ; c1ccc(-c2ccc(-n3c4ccc(-c5ccc6c(c5)c5ccccc5n6-c5cc6ccccc6c6ccccc56)cc4c4c(-c5ccccc5-c5ccccc5)cccc43)cc2)cc1] 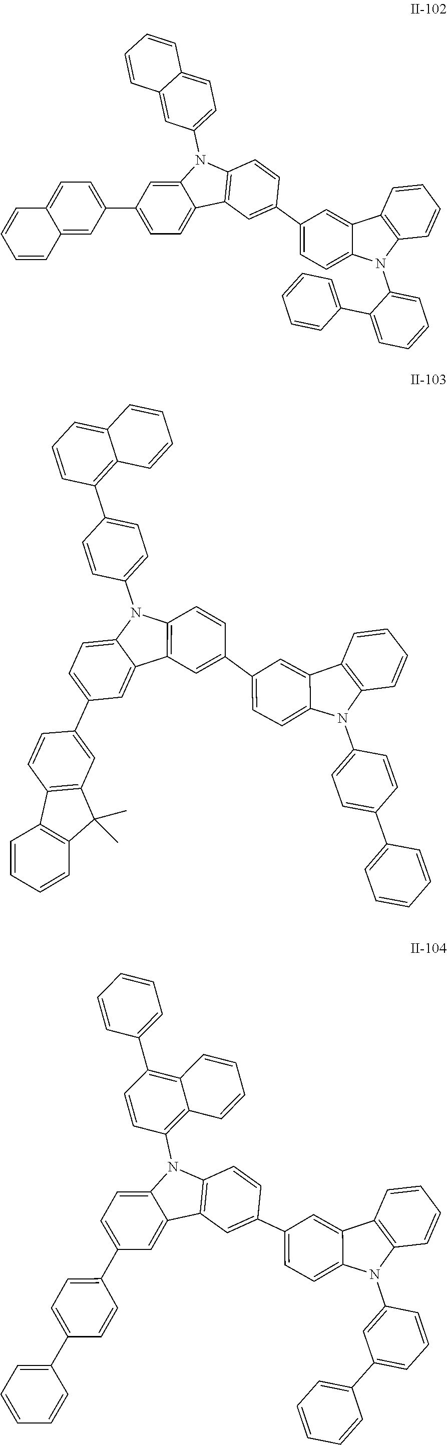 [SMILES: c1ccc(-c2ccccc2-n2c3ccccc3c3cc(-c4ccc5c(c4)c4ccc(-c6ccc7ccccc7c6)cc4n5-c4ccc5ccccc5c4)ccc32)cc1 ; CC1(C)c2ccccc2-c2ccc(-c3ccc4c(c3)c3cc(-c5ccc6c(c5)c5ccccc5n6-c5ccc(-c6ccccc6)cc5)ccc3n4-c3ccc(-c4cccc5ccccc45)cc3)cc21 ; c1ccc(-c2ccc(-c3ccc4c(c3)c3cc(-c5ccc6c(c5)c5ccccc5n6-c5cccc(-c6ccccc6)c5)ccc3n4-c3ccc(-c4ccccc4)c4ccccc34)cc2)cc1] 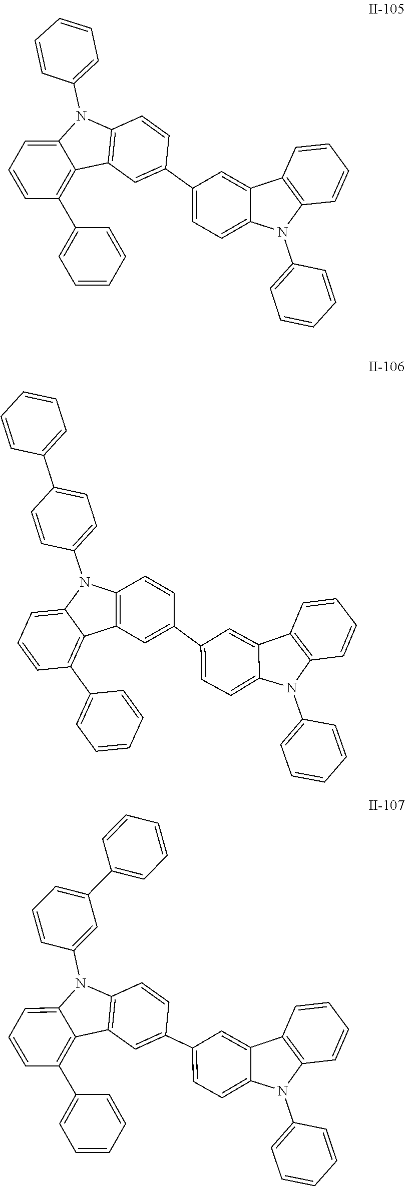 [SMILES: c1ccc(-c2cccc3c2c2cc(-c4ccc5c(c4)c4ccccc4n5-c4ccccc4)ccc2n3-c2ccccc2)cc1 ; c1ccc(-c2ccc(-n3c4ccc(-c5ccc6c(c5)c5ccccc5n6-c5ccccc5)cc4c4c(-c5ccccc5)cccc43)cc2)cc1 ; c1ccc(-c2cccc(-n3c4ccc(-c5ccc6c(c5)c5ccccc5n6-c5ccccc5)cc4c4c(-c5ccccc5)cccc43)c2)cc1] 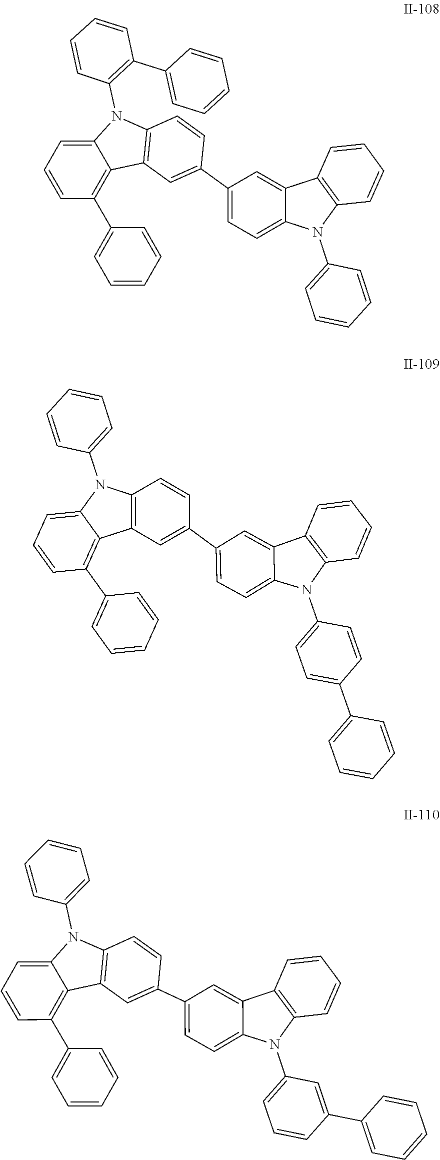 [SMILES: c1ccc(-c2ccccc2-n2c3ccc(-c4ccc5c(c4)c4ccccc4n5-c4ccccc4)cc3c3c(-c4ccccc4)cccc32)cc1 ; c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2cccc(-n3c4ccccc4c4cc(-c5ccc6c(c5)c5c(-c7ccccc7)cccc5n6-c5ccccc5)ccc43)c2)cc1] 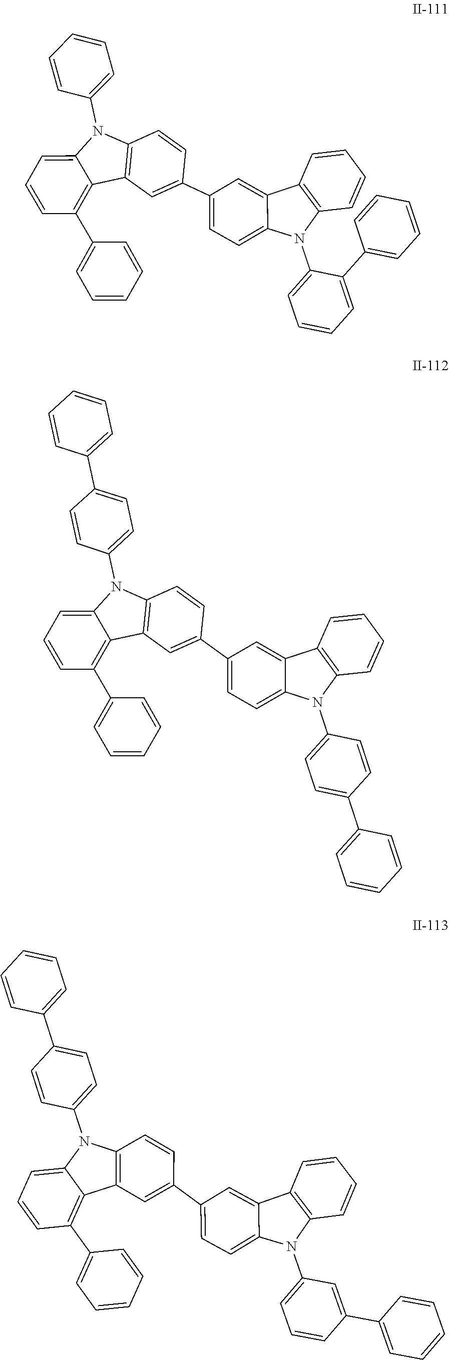 [SMILES: c1ccc(-c2ccccc2-n2c3ccccc3c3cc(-c4ccc5c(c4)c4c(-c6ccccc6)cccc4n5-c4ccccc4)ccc32)cc1 ; c1ccc(-c2ccc(-n3c4ccccc4c4cc(-c5ccc6c(c5)c5c(-c7ccccc7)cccc5n6-c5ccc(-c6ccccc6)cc5)ccc43)cc2)cc1 ; c1ccc(-c2ccc(-n3c4ccc(-c5ccc6c(c5)c5ccccc5n6-c5cccc(-c6ccccc6)c5)cc4c4c(-c5ccccc5)cccc43)cc2)cc1] 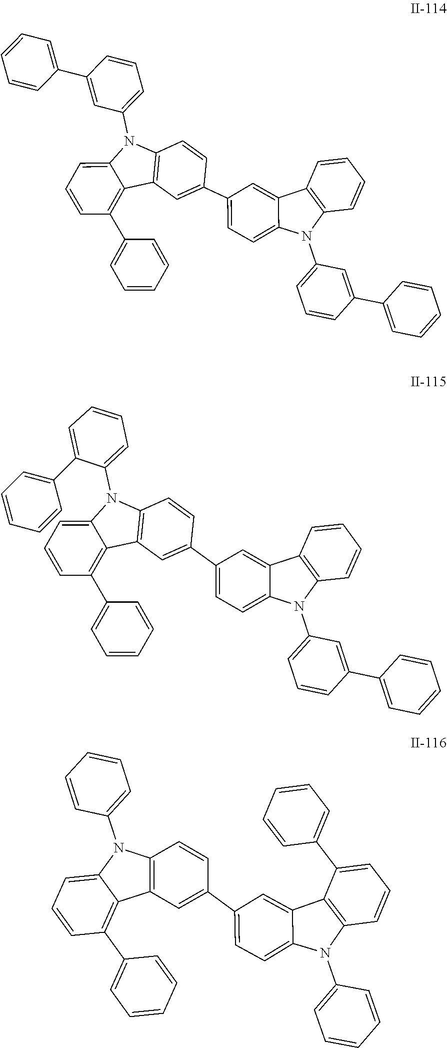 [SMILES: c1ccc(-c2cccc(-n3c4ccccc4c4cc(-c5ccc6c(c5)c5c(-c7ccccc7)cccc5n6-c5cccc(-c6ccccc6)c5)ccc43)c2)cc1 ; c1ccc(-c2cccc(-n3c4ccccc4c4cc(-c5ccc6c(c5)c5c(-c7ccccc7)cccc5n6-c5ccccc5-c5ccccc5)ccc43)c2)cc1 ; c1ccc(-c2cccc3c2c2cc(-c4ccc5c(c4)c4c(-c6ccccc6)cccc4n5-c4ccccc4)ccc2n3-c2ccccc2)cc1] 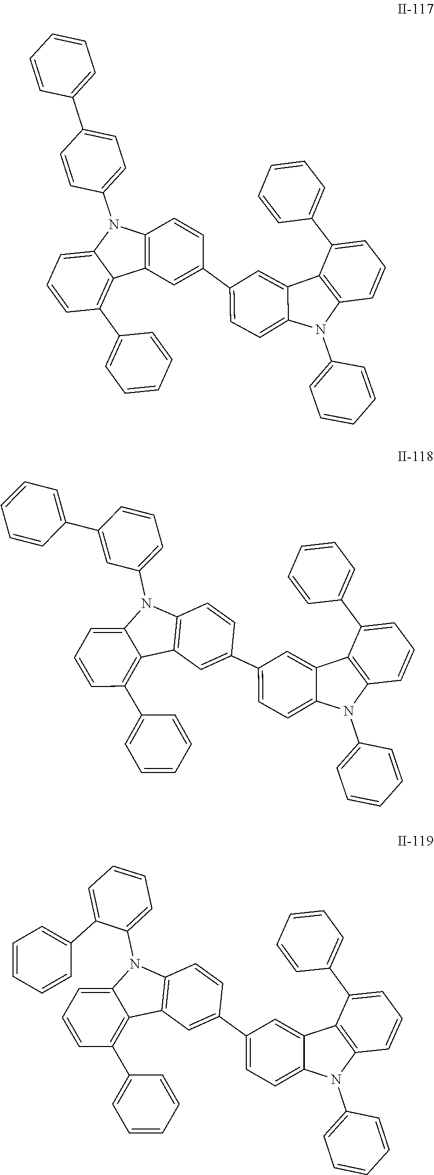 [SMILES: c1ccc(-c2ccc(-n3c4ccc(-c5ccc6c(c5)c5c(-c7ccccc7)cccc5n6-c5ccccc5)cc4c4c(-c5ccccc5)cccc43)cc2)cc1 ; c1ccc(-c2cccc(-n3c4ccc(-c5ccc6c(c5)c5c(-c7ccccc7)cccc5n6-c5ccccc5)cc4c4c(-c5ccccc5)cccc43)c2)cc1 ; c1ccc(-c2ccccc2-n2c3ccc(-c4ccc5c(c4)c4c(-c6ccccc6)cccc4n5-c4ccccc4)cc3c3c(-c4ccccc4)cccc32)cc1] 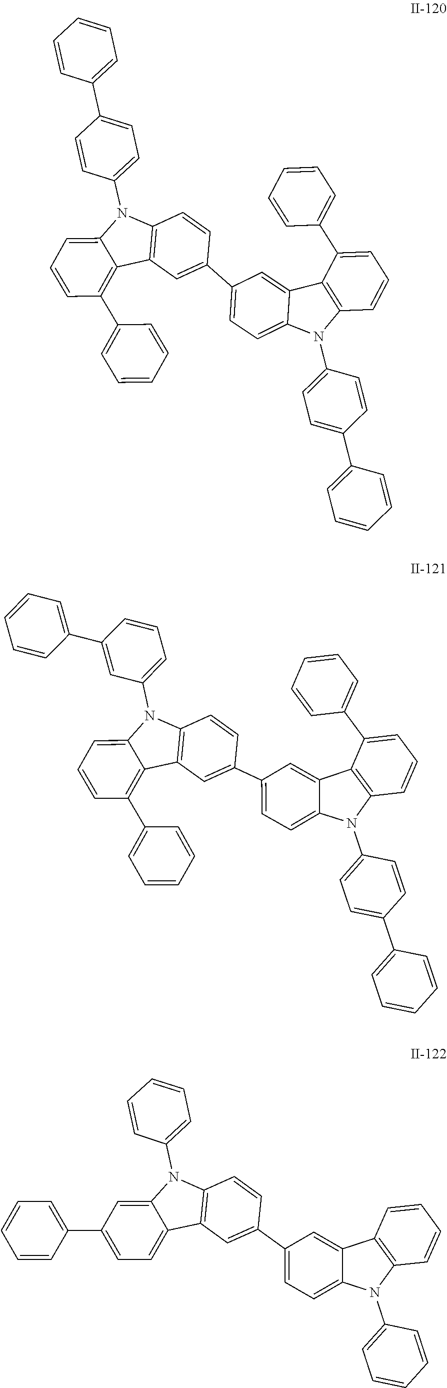 [SMILES: c1ccc(-c2ccc(-n3c4ccc(-c5ccc6c(c5)c5c(-c7ccccc7)cccc5n6-c5ccc(-c6ccccc6)cc5)cc4c4c(-c5ccccc5)cccc43)cc2)cc1 ; c1ccc(-c2ccc(-n3c4ccc(-c5ccc6c(c5)c5c(-c7ccccc7)cccc5n6-c5cccc(-c6ccccc6)c5)cc4c4c(-c5ccccc5)cccc43)cc2)cc1 ; c1ccc(-c2ccc3c4cc(-c5ccc6c(c5)c5ccccc5n6-c5ccccc5)ccc4n(-c4ccccc4)c3c2)cc1] 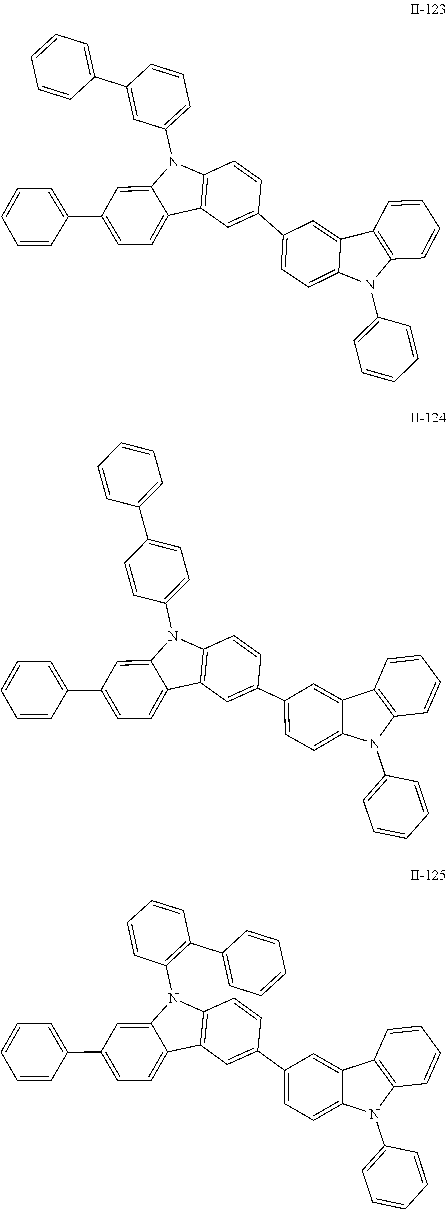 [SMILES: c1ccc(-c2cccc(-n3c4ccc(-c5ccc6c(c5)c5ccccc5n6-c5ccccc5)cc4c4ccc(-c5ccccc5)cc43)c2)cc1 ; c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc3c4cc(-c5ccc6c(c5)c5ccccc5n6-c5ccccc5)ccc4n(-c4ccccc4-c4ccccc4)c3c2)cc1] 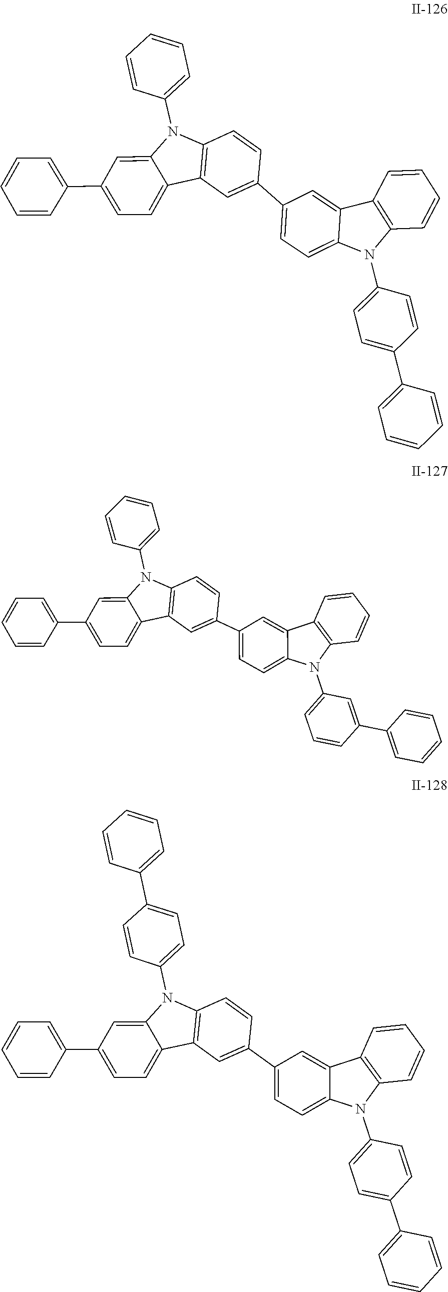 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2cccc(-n3c4ccccc4c4cc(-c5ccc6c(c5)c5ccc(-c7ccccc7)cc5n6-c5ccccc5)ccc43)c2)cc1 ; c1ccc(-c2ccc(-n3c4ccccc4c4cc(-c5ccc6c(c5)c5ccc(-c7ccccc7)cc5n6-c5ccc(-c6ccccc6)cc5)ccc43)cc2)cc1] 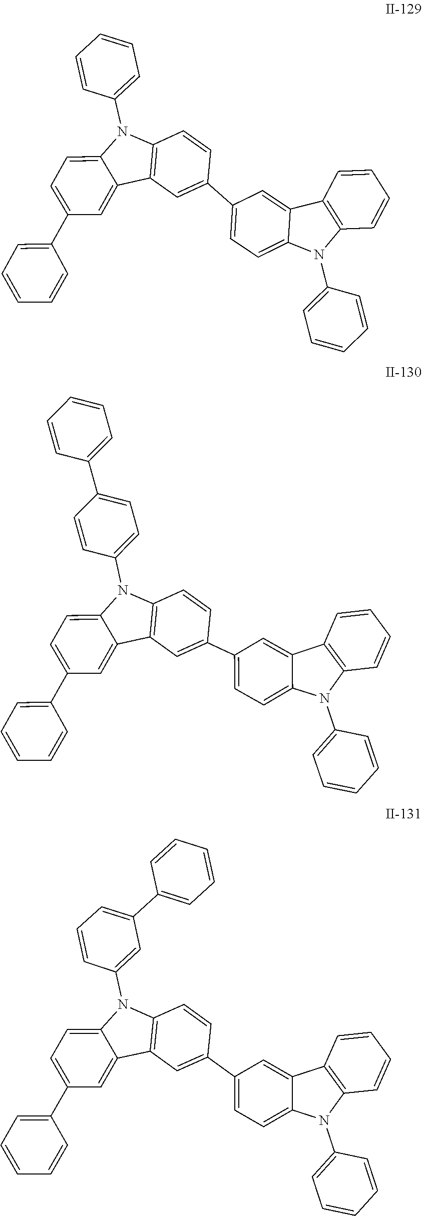 [SMILES: c1ccc(-c2ccc3c(c2)c2cc(-c4ccc5c(c4)c4ccccc4n5-c4ccccc4)ccc2n3-c2ccccc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2cccc(-n3c4ccc(-c5ccccc5)cc4c4cc(-c5ccc6c(c5)c5ccccc5n6-c5ccccc5)ccc43)c2)cc1] 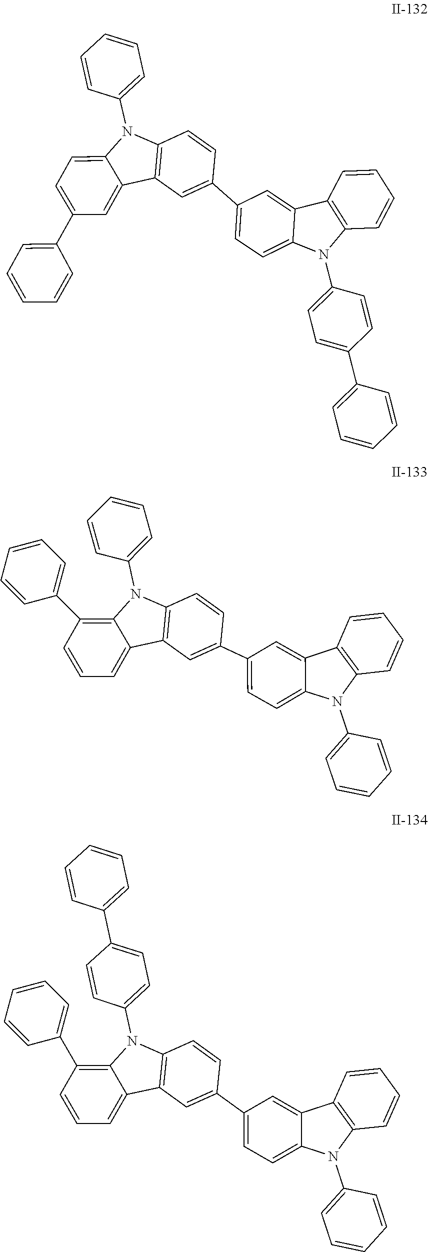 [SMILES: c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2cccc3c4cc(-c5ccc6c(c5)c5ccccc5n6-c5ccccc5)ccc4n(-c4ccccc4)c23)cc1 ; c1ccc(-c2ccc(-n3c4ccc(-c5ccc6c(c5)c5ccccc5n6-c5ccccc5)cc4c4cccc(-c5ccccc5)c43)cc2)cc1] 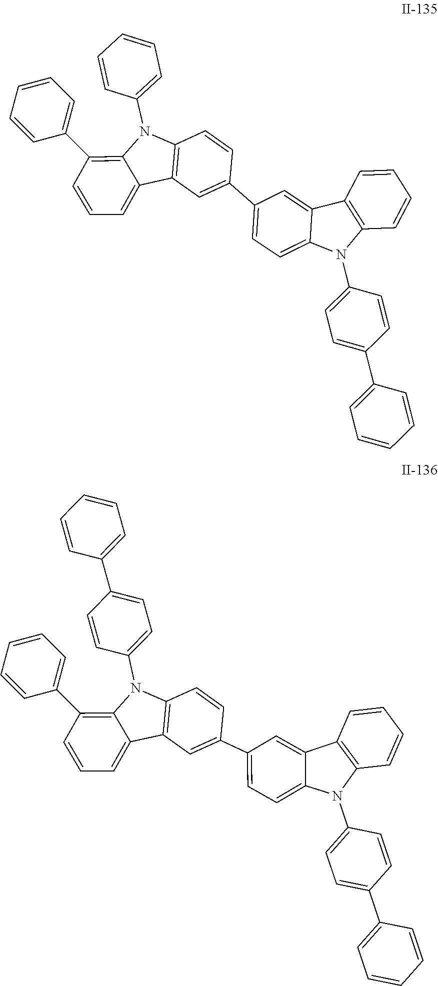 [SMILES: c1ccc(-c2ccc(-n3c4ccccc4c4cc(-c5ccc6c(c5)c5cccc(-c7ccccc7)c5n6-c5ccccc5)ccc43)cc2)cc1 ; c1ccc(-c2ccc(-n3c4ccccc4c4cc(-c5ccc6c(c5)c5cccc(-c7ccccc7)c5n6-c5ccc(-c6ccccc6)cc5)ccc43)cc2)cc1] 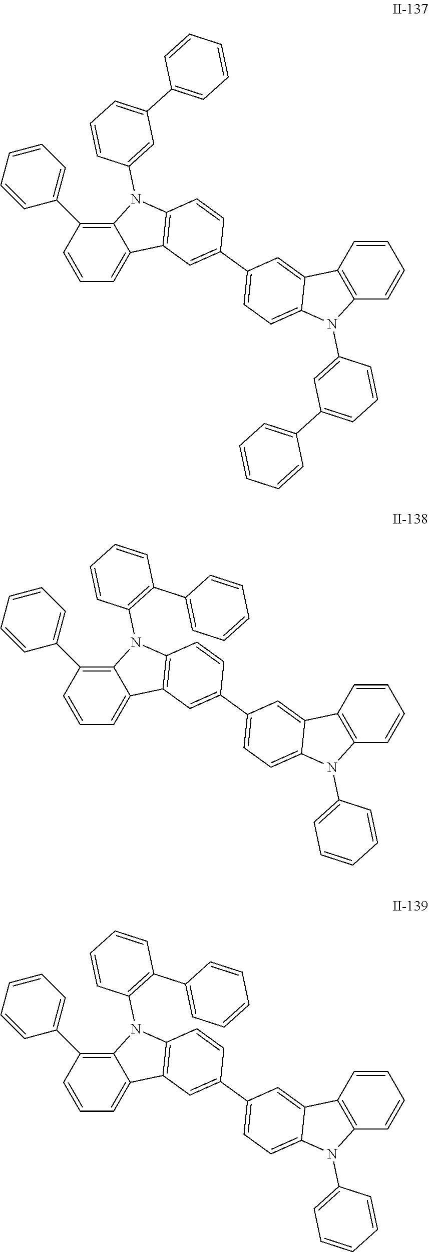 [SMILES: c1ccc(-c2cccc(-n3c4ccccc4c4cc(-c5ccc6c(c5)c5cccc(-c7ccccc7)c5n6-c5cccc(-c6ccccc6)c5)ccc43)c2)cc1 ; c1ccc(-c2ccccc2-n2c3ccc(-c4ccc5c(c4)c4ccccc4n5-c4ccccc4)cc3c3cccc(-c4ccccc4)c32)cc1 ; c1ccc(-c2ccccc2-n2c3ccc(-c4ccc5c(c4)c4ccccc4n5-c4ccccc4)cc3c3cccc(-c4ccccc4)c32)cc1] 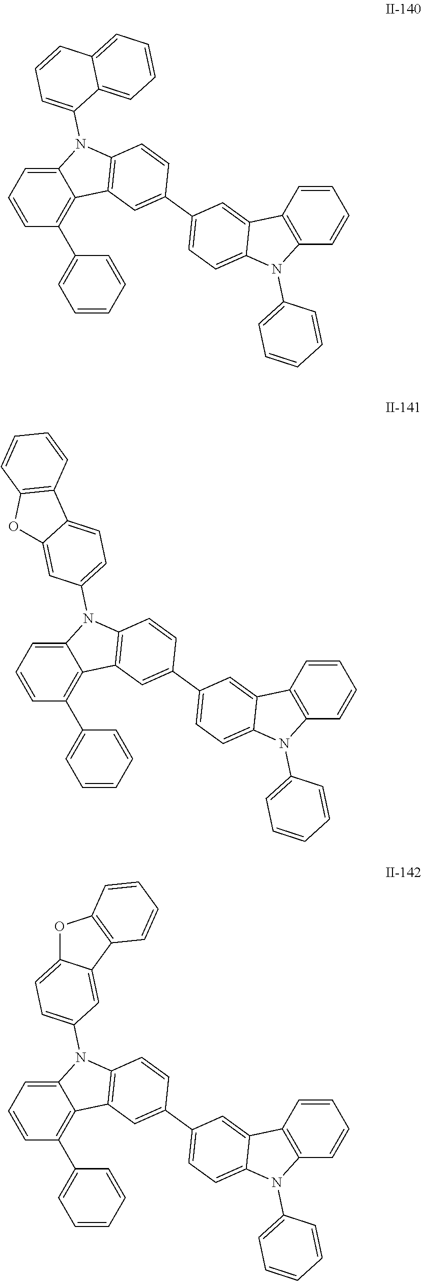 [SMILES: c1ccc(-c2cccc3c2c2cc(-c4ccc5c(c4)c4ccccc4n5-c4ccccc4)ccc2n3-c2cccc3ccccc23)cc1 ; c1ccc(-c2cccc3c2c2cc(-c4ccc5c(c4)c4ccccc4n5-c4ccccc4)ccc2n3-c2ccc3c(c2)oc2ccccc23)cc1 ; c1ccc(-c2cccc3c2c2cc(-c4ccc5c(c4)c4ccccc4n5-c4ccccc4)ccc2n3-c2ccc3oc4ccccc4c3c2)cc1] 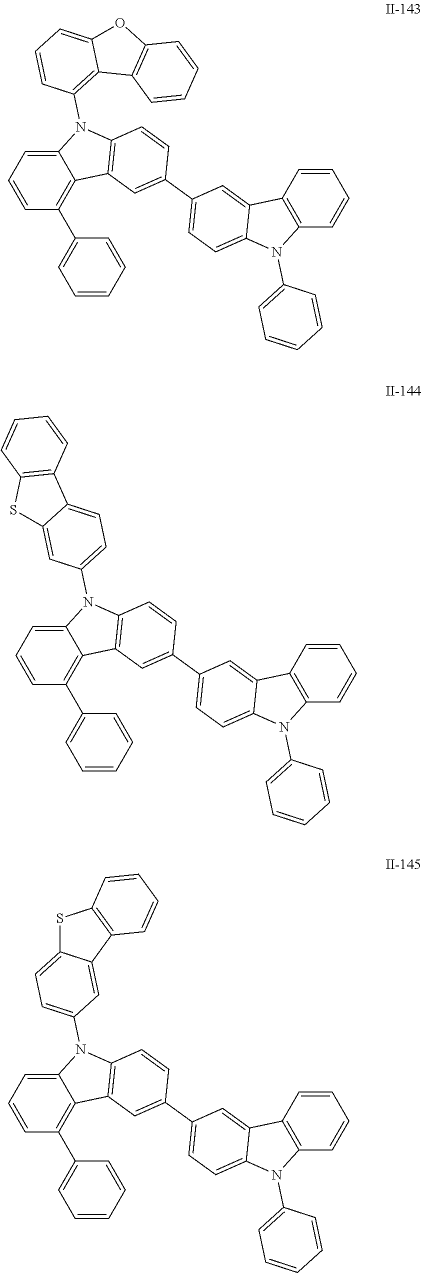 [SMILES: c1ccc(-c2cccc3c2c2cc(-c4ccc5c(c4)c4ccccc4n5-c4ccccc4)ccc2n3-c2cccc3oc4ccccc4c23)cc1 ; c1ccc(-c2cccc3c2c2cc(-c4ccc5c(c4)c4ccccc4n5-c4ccccc4)ccc2n3-c2ccc3c(c2)sc2ccccc23)cc1 ; c1ccc(-c2cccc3c2c2cc(-c4ccc5c(c4)c4ccccc4n5-c4ccccc4)ccc2n3-c2ccc3sc4ccccc4c3c2)cc1] 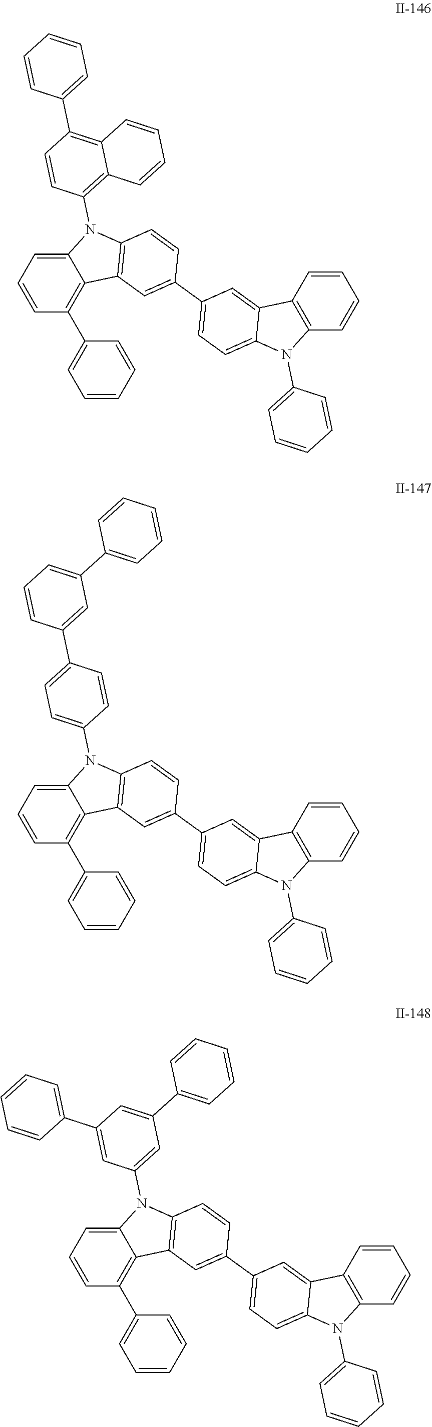 [SMILES: c1ccc(-c2ccc(-n3c4ccc(-c5ccc6c(c5)c5ccccc5n6-c5ccccc5)cc4c4c(-c5ccccc5)cccc43)c3ccccc23)cc1 ; c1ccc(-c2cccc(-c3ccc(-n4c5ccc(-c6ccc7c(c6)c6ccccc6n7-c6ccccc6)cc5c5c(-c6ccccc6)cccc54)cc3)c2)cc1 ; c1ccc(-c2cc(-c3ccccc3)cc(-n3c4ccc(-c5ccc6c(c5)c5ccccc5n6-c5ccccc5)cc4c4c(-c5ccccc5)cccc43)c2)cc1] 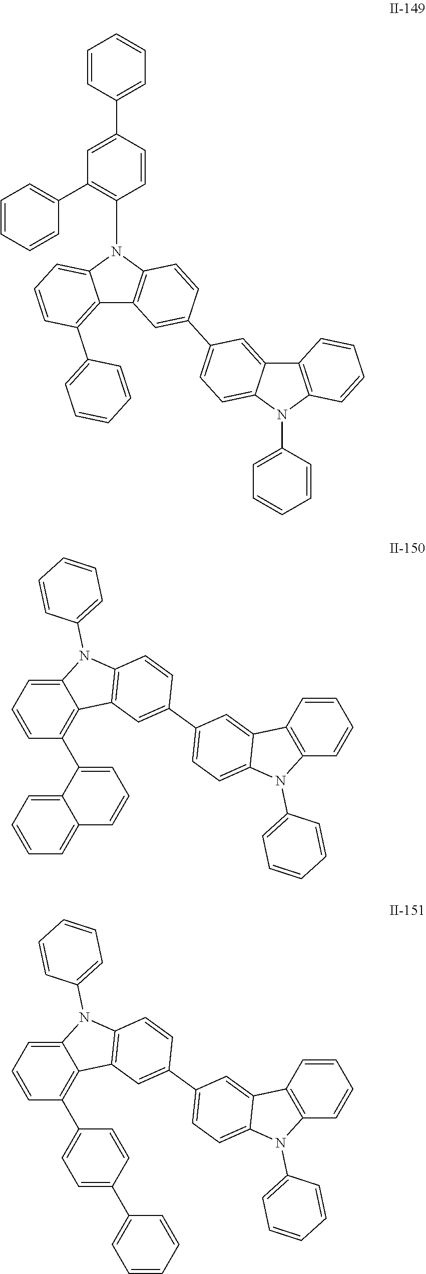 [SMILES: c1ccc(-c2ccc(-n3c4ccc(-c5ccc6c(c5)c5ccccc5n6-c5ccccc5)cc4c4c(-c5ccccc5)cccc43)c(-c3ccccc3)c2)cc1 ; c1ccc(-n2c3ccccc3c3cc(-c4ccc5c(c4)c4c(-c6cccc7ccccc67)cccc4n5-c4ccccc4)ccc32)cc1 ; c1ccc(-c2ccc(-c3cccc4c3c3cc(-c5ccc6c(c5)c5ccccc5n6-c5ccccc5)ccc3n4-c3ccccc3)cc2)cc1] 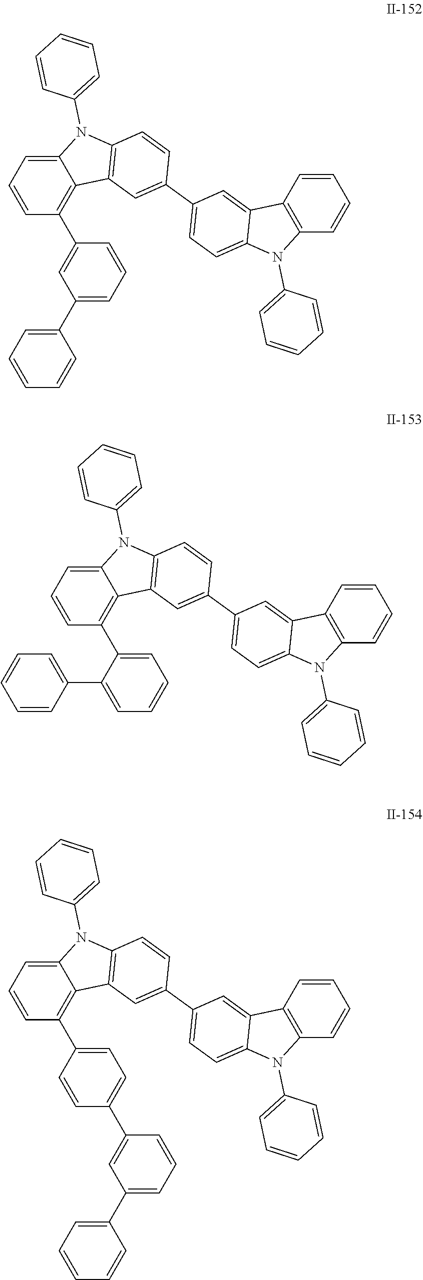 [SMILES: c1ccc(-c2cccc(-c3cccc4c3c3cc(-c5ccc6c(c5)c5ccccc5n6-c5ccccc5)ccc3n4-c3ccccc3)c2)cc1 ; c1ccc(-c2ccccc2-c2cccc3c2c2cc(-c4ccc5c(c4)c4ccccc4n5-c4ccccc4)ccc2n3-c2ccccc2)cc1 ; c1ccc(-c2cccc(-c3ccc(-c4cccc5c4c4cc(-c6ccc7c(c6)c6ccccc6n7-c6ccccc6)ccc4n5-c4ccccc4)cc3)c2)cc1] 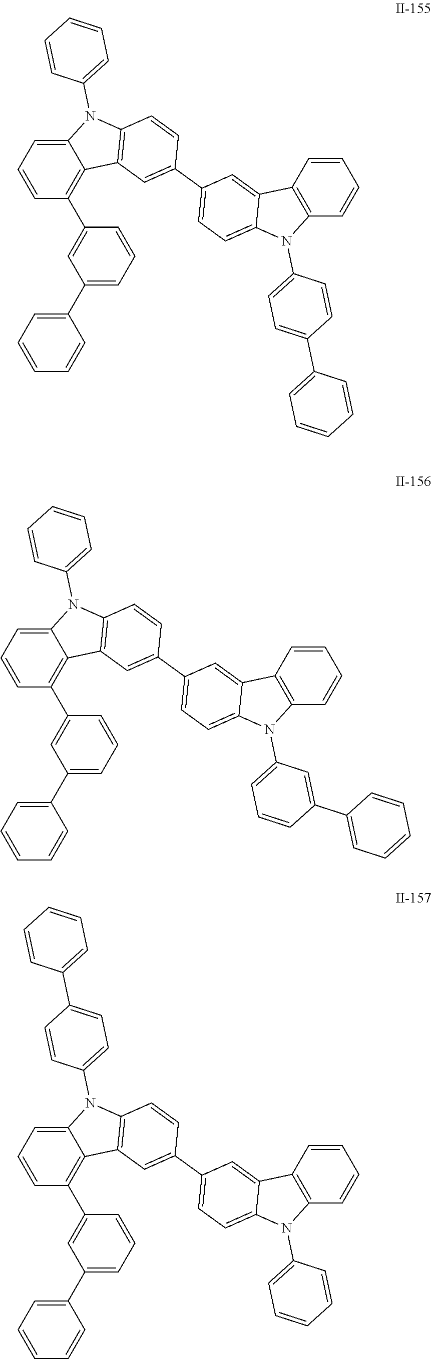 [SMILES: c1ccc(-c2ccc(-n3c4ccccc4c4cc(-c5ccc6c(c5)c5c(-c7cccc(-c8ccccc8)c7)cccc5n6-c5ccccc5)ccc43)cc2)cc1 ; c1ccc(-c2cccc(-c3cccc4c3c3cc(-c5ccc6c(c5)c5ccccc5n6-c5cccc(-c6ccccc6)c5)ccc3n4-c3ccccc3)c2)cc1 ; c1ccc(-c2ccc(-n3c4ccc(-c5ccc6c(c5)c5ccccc5n6-c5ccccc5)cc4c4c(-c5cccc(-c6ccccc6)c5)cccc43)cc2)cc1] 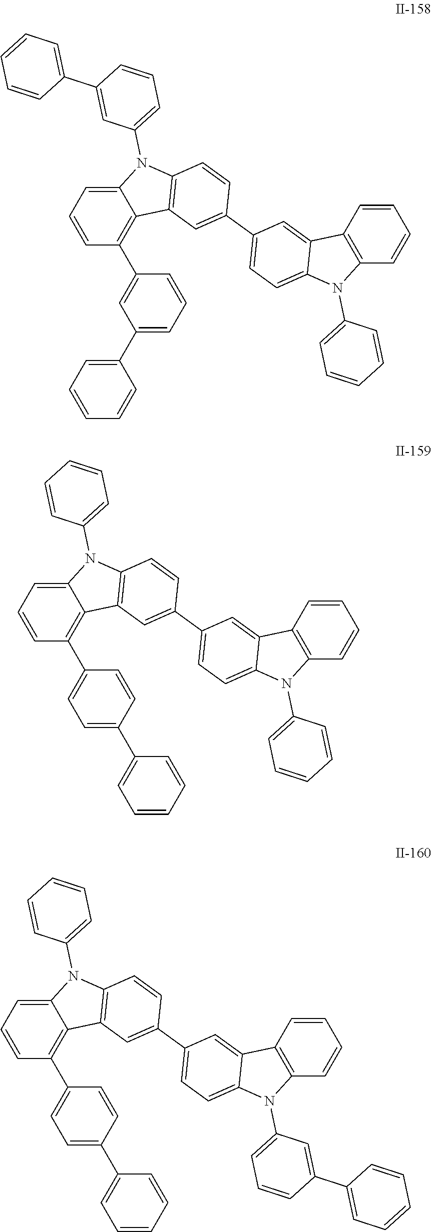 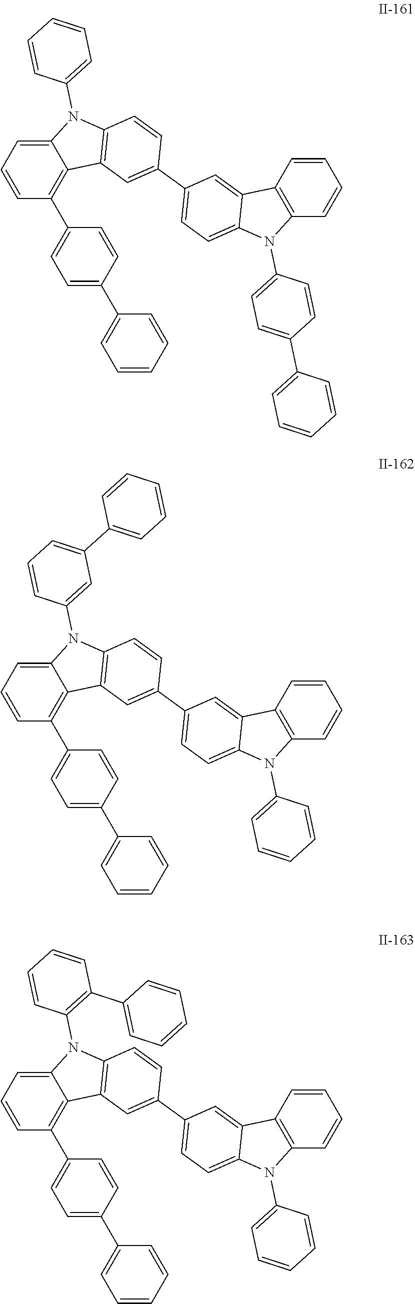 [SMILES: c1ccc(-c2ccc(-c3cccc4c3c3cc(-c5ccc6c(c5)c5ccccc5n6-c5ccc(-c6ccccc6)cc5)ccc3n4-c3ccccc3)cc2)cc1 ; c1ccc(-c2ccc(-c3cccc4c3c3cc(-c5ccc6c(c5)c5ccccc5n6-c5ccccc5)ccc3n4-c3cccc(-c4ccccc4)c3)cc2)cc1 ; c1ccc(-c2ccc(-c3cccc4c3c3cc(-c5ccc6c(c5)c5ccccc5n6-c5ccccc5)ccc3n4-c3ccccc3-c3ccccc3)cc2)cc1] 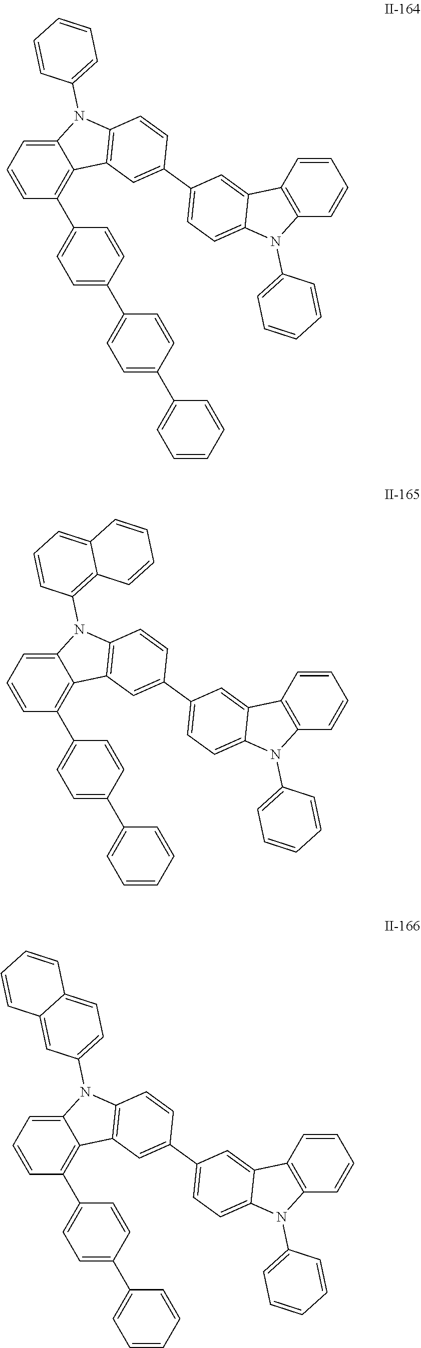 [SMILES: c1ccc(-c2ccc(-c3ccc(-c4cccc5c4c4cc(-c6ccc7c(c6)c6ccccc6n7-c6ccccc6)ccc4n5-c4ccccc4)cc3)cc2)cc1 ; c1ccc(-c2ccc(-c3cccc4c3c3cc(-c5ccc6c(c5)c5ccccc5n6-c5ccccc5)ccc3n4-c3cccc4ccccc34)cc2)cc1 ; c1ccc(-c2ccc(-c3cccc4c3c3cc(-c5ccc6c(c5)c5ccccc5n6-c5ccccc5)ccc3n4-c3ccc4ccccc4c3)cc2)cc1] 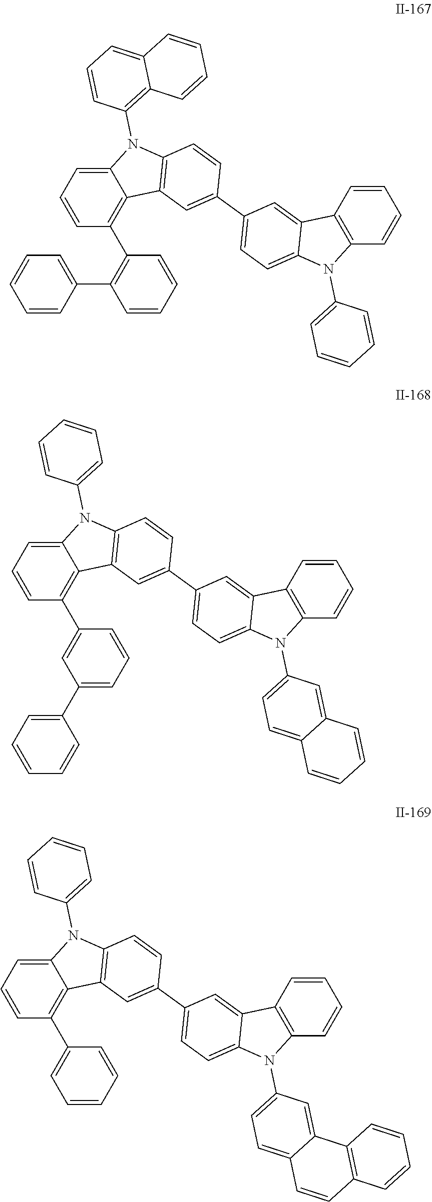 [SMILES: c1ccc(-c2ccccc2-c2cccc3c2c2cc(-c4ccc5c(c4)c4ccccc4n5-c4ccccc4)ccc2n3-c2cccc3ccccc23)cc1 ; c1ccc(-c2cccc(-c3cccc4c3c3cc(-c5ccc6c(c5)c5ccccc5n6-c5ccc6ccccc6c5)ccc3n4-c3ccccc3)c2)cc1 ; c1ccc(-c2cccc3c2c2cc(-c4ccc5c(c4)c4ccccc4n5-c4ccc5ccc6ccccc6c5c4)ccc2n3-c2ccccc2)cc1] 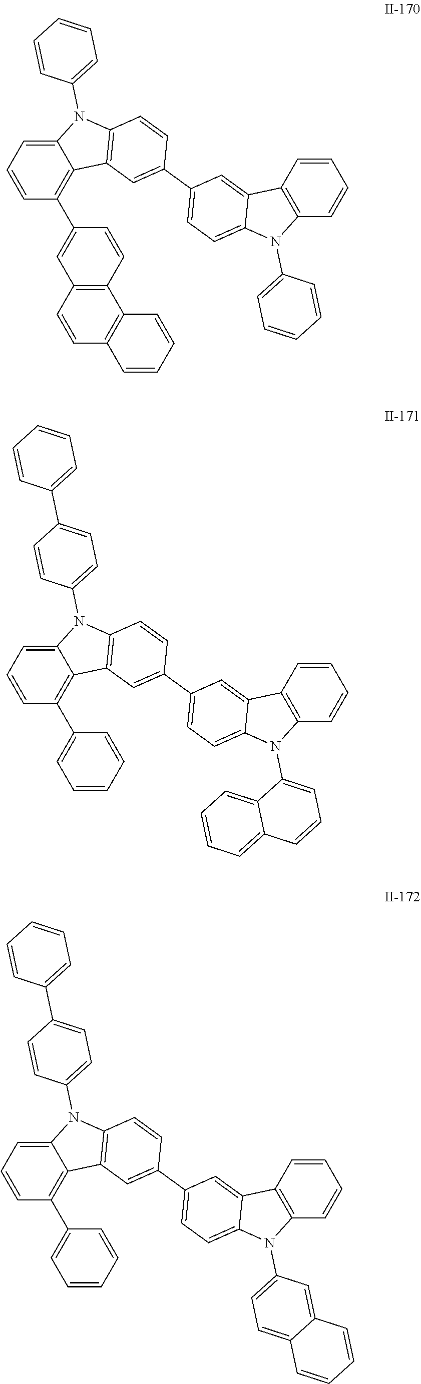 [SMILES: c1ccc(-n2c3ccccc3c3cc(-c4ccc5c(c4)c4c(-c6ccc7c(ccc8ccccc87)c6)cccc4n5-c4ccccc4)ccc32)cc1 ; c1ccc(-c2ccc(-n3c4ccc(-c5ccc6c(c5)c5ccccc5n6-c5cccc6ccccc56)cc4c4c(-c5ccccc5)cccc43)cc2)cc1 ; c1ccc(-c2ccc(-n3c4ccc(-c5ccc6c(c5)c5ccccc5n6-c5ccc6ccccc6c5)cc4c4c(-c5ccccc5)cccc43)cc2)cc1] 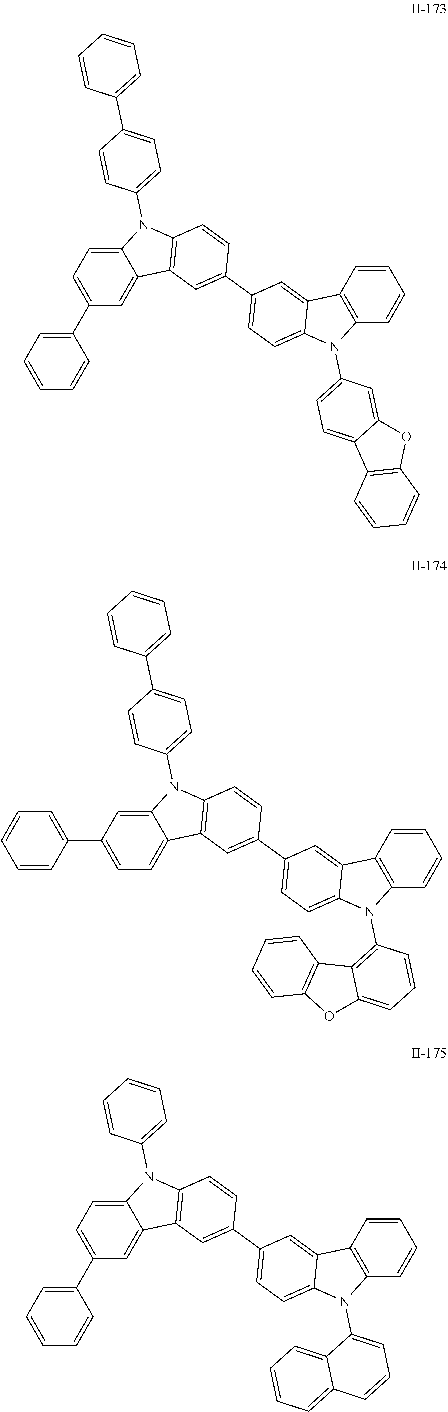 [SMILES: c1ccc(-c2ccc(-n3c4ccc(-c5ccccc5)cc4c4cc(-c5ccc6c(c5)c5ccccc5n6-c5ccc6c(c5)oc5ccccc56)ccc43)cc2)cc1 ; c1ccc(-c2ccc(-n3c4ccc(-c5ccc6c(c5)c5ccccc5n6-c5cccc6oc7ccccc7c56)cc4c4ccc(-c5ccccc5)cc43)cc2)cc1 ; c1ccc(-c2ccc3c(c2)c2cc(-c4ccc5c(c4)c4ccccc4n5-c4cccc5ccccc45)ccc2n3-c2ccccc2)cc1] 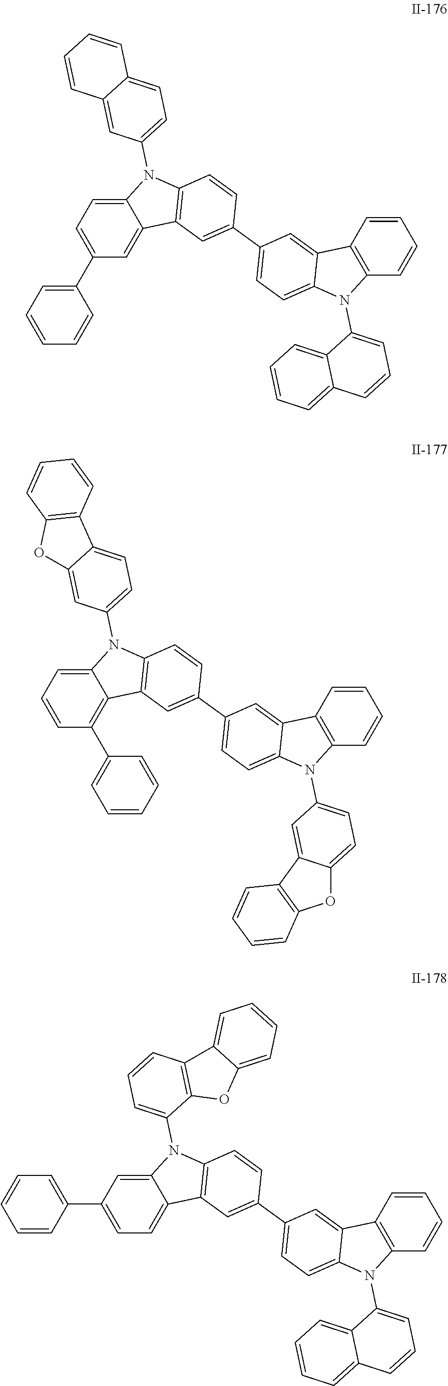 [SMILES: c1ccc(-c2ccc3c(c2)c2cc(-c4ccc5c(c4)c4ccccc4n5-c4cccc5ccccc45)ccc2n3-c2ccc3ccccc3c2)cc1 ; c1ccc(-c2cccc3c2c2cc(-c4ccc5c(c4)c4ccccc4n5-c4ccc5oc6ccccc6c5c4)ccc2n3-c2ccc3c(c2)oc2ccccc23)cc1 ; c1ccc(-c2ccc3c4cc(-c5ccc6c(c5)c5ccccc5n6-c5cccc6ccccc56)ccc4n(-c4cccc5c4oc4ccccc45)c3c2)cc1] 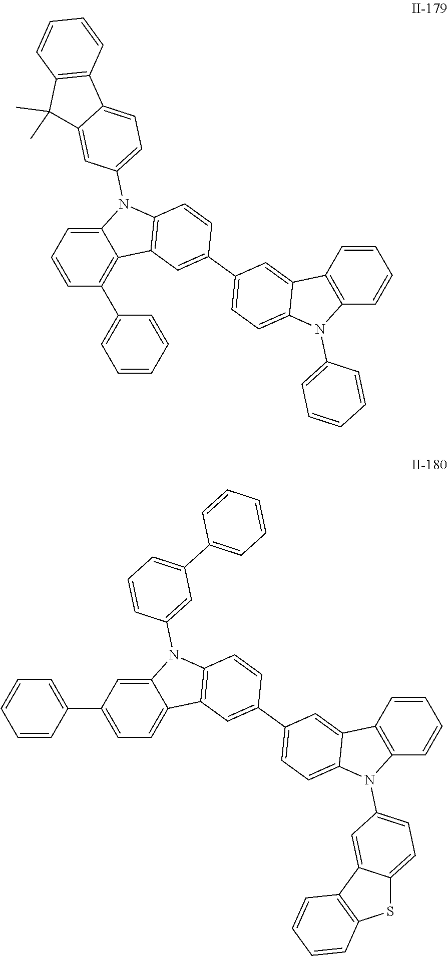 [SMILES: CC1(C)c2ccccc2-c2ccc(-n3c4ccc(-c5ccc6c(c5)c5ccccc5n6-c5ccccc5)cc4c4c(-c5ccccc5)cccc43)cc21 ; c1ccc(-c2cccc(-n3c4ccc(-c5ccc6c(c5)c5ccccc5n6-c5ccc6sc7ccccc7c6c5)cc4c4ccc(-c5ccccc5)cc43)c2)cc1] 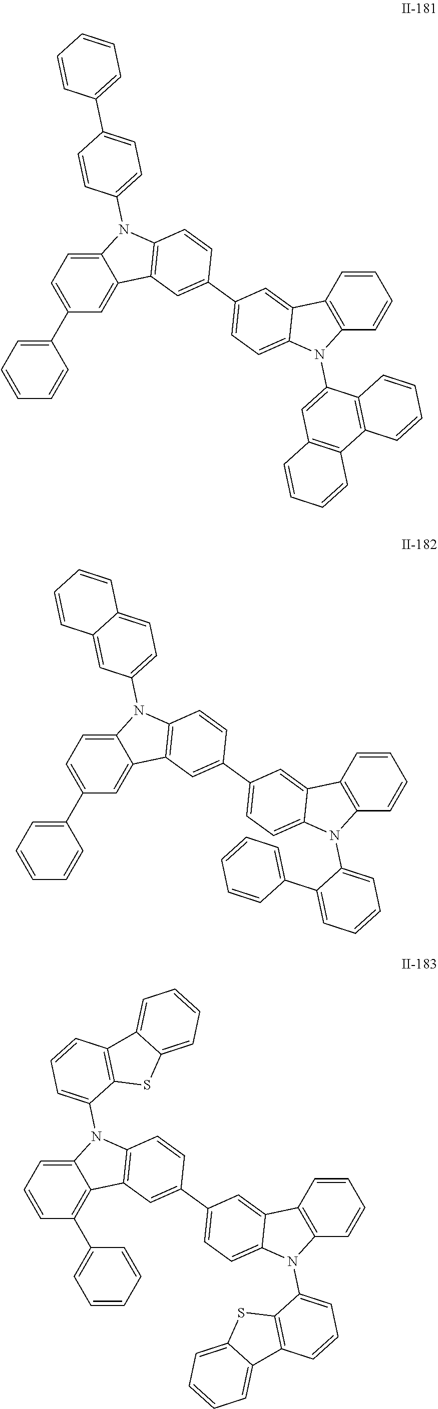 [SMILES: c1ccc(-c2ccc(-n3c4ccc(-c5ccccc5)cc4c4cc(-c5ccc6c(c5)c5ccccc5n6-c5cc6ccccc6c6ccccc56)ccc43)cc2)cc1 ; c1ccc(-c2ccc3c(c2)c2cc(-c4ccc5c(c4)c4ccccc4n5-c4ccccc4-c4ccccc4)ccc2n3-c2ccc3ccccc3c2)cc1 ; c1ccc(-c2cccc3c2c2cc(-c4ccc5c(c4)c4ccccc4n5-c4cccc5c4sc4ccccc45)ccc2n3-c2cccc3c2sc2ccccc23)cc1] 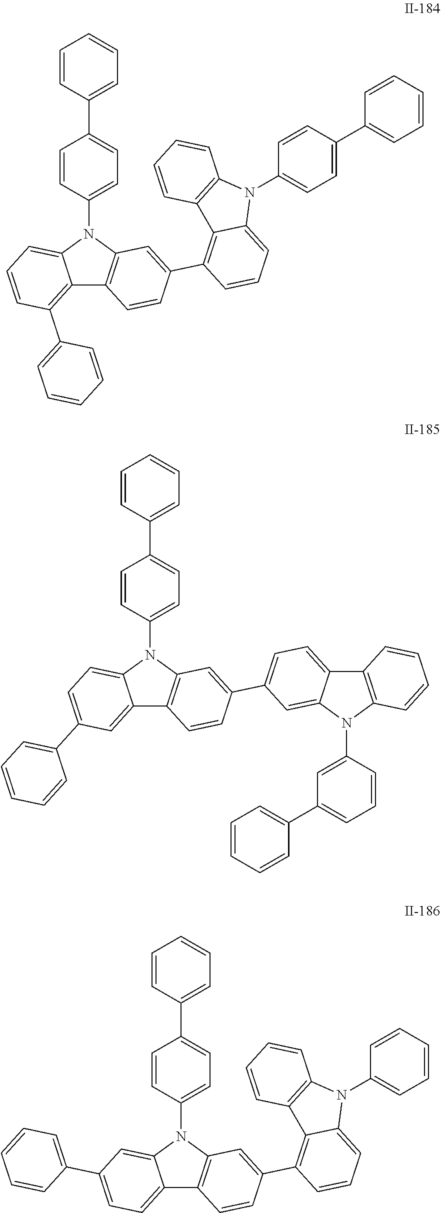 [SMILES: c1ccc(-c2ccc(-n3c4ccccc4c4c(-c5ccc6c7c(-c8ccccc8)cccc7n(-c7ccc(-c8ccccc8)cc7)c6c5)cccc43)cc2)cc1 ; c1ccc(-c2ccc(-n3c4ccc(-c5ccccc5)cc4c4ccc(-c5ccc6c7ccccc7n(-c7cccc(-c8ccccc8)c7)c6c5)cc43)cc2)cc1 ; c1ccc(-c2ccc(-n3c4cc(-c5ccccc5)ccc4c4ccc(-c5cccc6c5c5ccccc5n6-c5ccccc5)cc43)cc2)cc1] 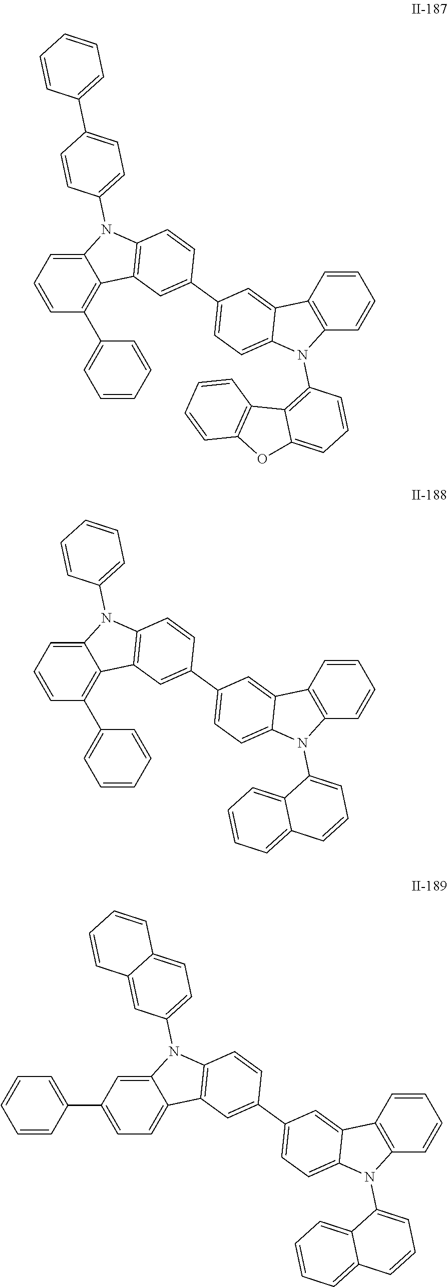 [SMILES: c1ccc(-c2ccc(-n3c4ccc(-c5ccc6c(c5)c5ccccc5n6-c5cccc6oc7ccccc7c56)cc4c4c(-c5ccccc5)cccc43)cc2)cc1 ; c1ccc(-c2cccc3c2c2cc(-c4ccc5c(c4)c4ccccc4n5-c4cccc5ccccc45)ccc2n3-c2ccccc2)cc1 ; c1ccc(-c2ccc3c4cc(-c5ccc6c(c5)c5ccccc5n6-c5cccc6ccccc56)ccc4n(-c4ccc5ccccc5c4)c3c2)cc1] 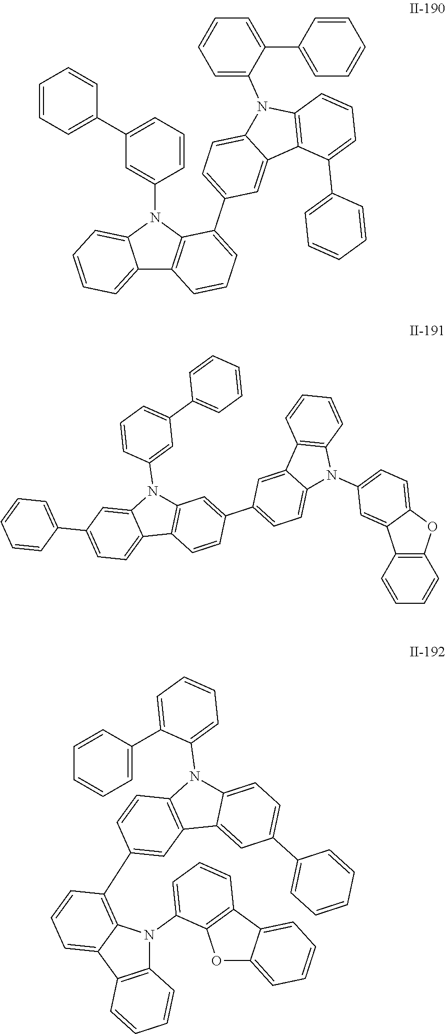 [SMILES: c1ccc(-c2cccc(-n3c4ccccc4c4cccc(-c5ccc6c(c5)c5c(-c7ccccc7)cccc5n6-c5ccccc5-c5ccccc5)c43)c2)cc1 ; c1ccc(-c2cccc(-n3c4cc(-c5ccccc5)ccc4c4ccc(-c5ccc6c(c5)c5ccccc5n6-c5ccc6oc7ccccc7c6c5)cc43)c2)cc1 ; c1ccc(-c2ccc3c(c2)c2cc(-c4cccc5c6ccccc6n(-c6cccc7c6oc6ccccc67)c45)ccc2n3-c2ccccc2-c2ccccc2)cc1] 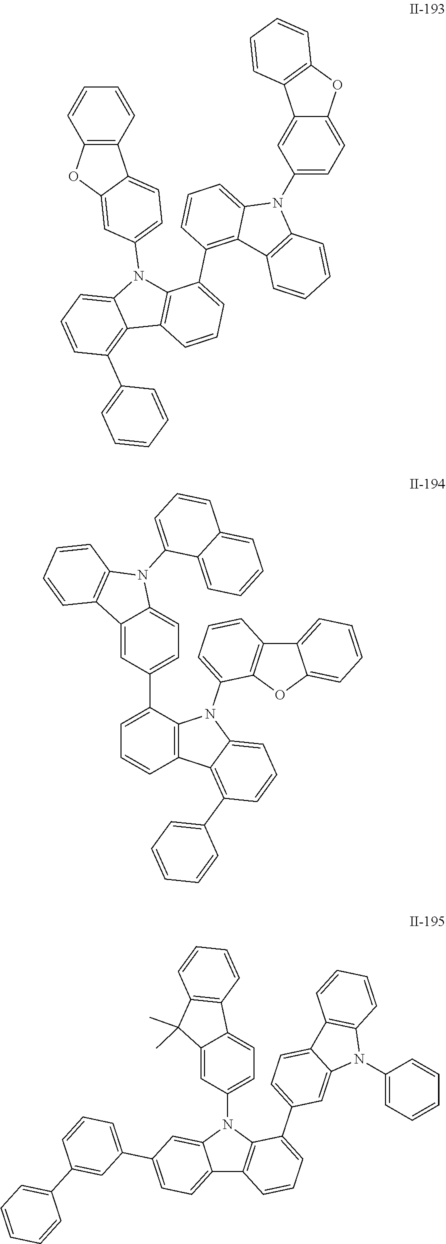 [SMILES: c1ccc(-c2cccc3c2c2cccc(-c4cccc5c4c4ccccc4n5-c4ccc5oc6ccccc6c5c4)c2n3-c2ccc3c(c2)oc2ccccc23)cc1 ; c1ccc(-c2cccc3c2c2cccc(-c4ccc5c(c4)c4ccccc4n5-c4cccc5ccccc45)c2n3-c2cccc3c2oc2ccccc23)cc1 ; CC1(C)c2ccccc2-c2ccc(-n3c4cc(-c5cccc(-c6ccccc6)c5)ccc4c4cccc(-c5ccc6c7ccccc7n(-c7ccccc7)c6c5)c43)cc21] 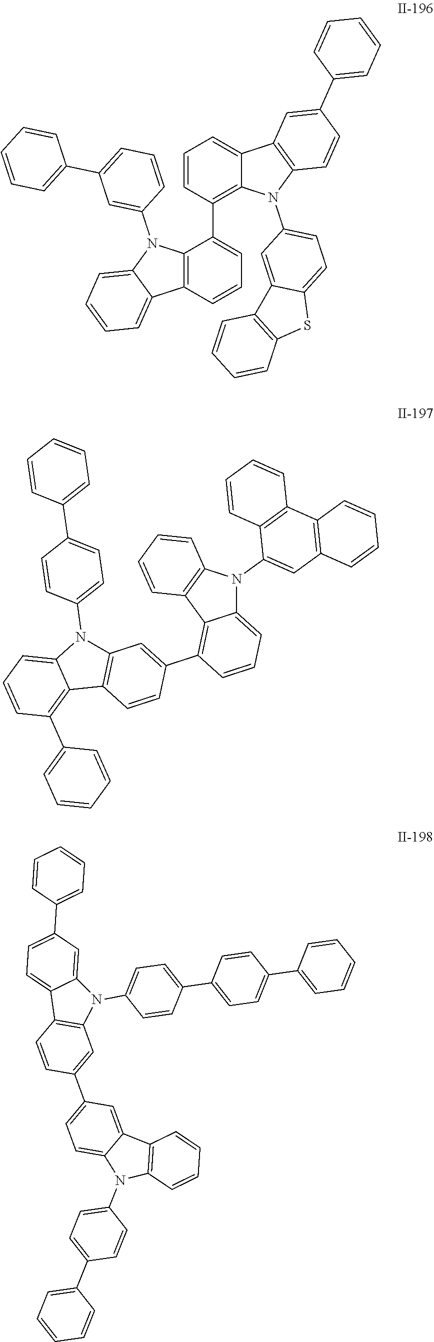 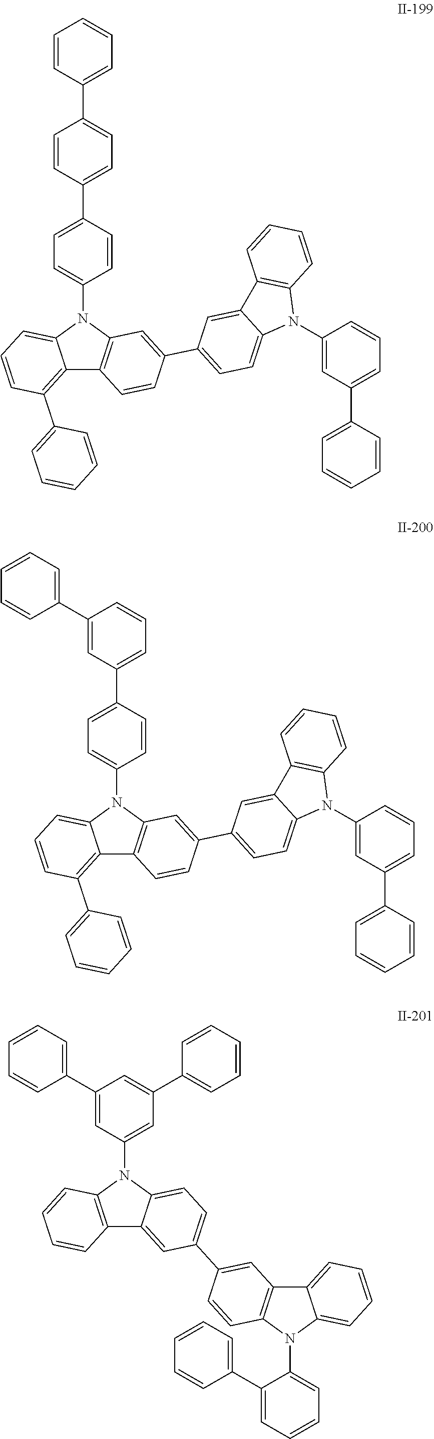 [SMILES: c1ccc(-c2ccc(-c3ccc(-n4c5cc(-c6ccc7c(c6)c6ccccc6n7-c6cccc(-c7ccccc7)c6)ccc5c5c(-c6ccccc6)cccc54)cc3)cc2)cc1 ; c1ccc(-c2cccc(-c3ccc(-n4c5cc(-c6ccc7c(c6)c6ccccc6n7-c6cccc(-c7ccccc7)c6)ccc5c5c(-c6ccccc6)cccc54)cc3)c2)cc1 ; c1ccc(-c2cc(-c3ccccc3)cc(-n3c4ccccc4c4cc(-c5ccc6c(c5)c5ccccc5n6-c5ccccc5-c5ccccc5)ccc43)c2)cc1] 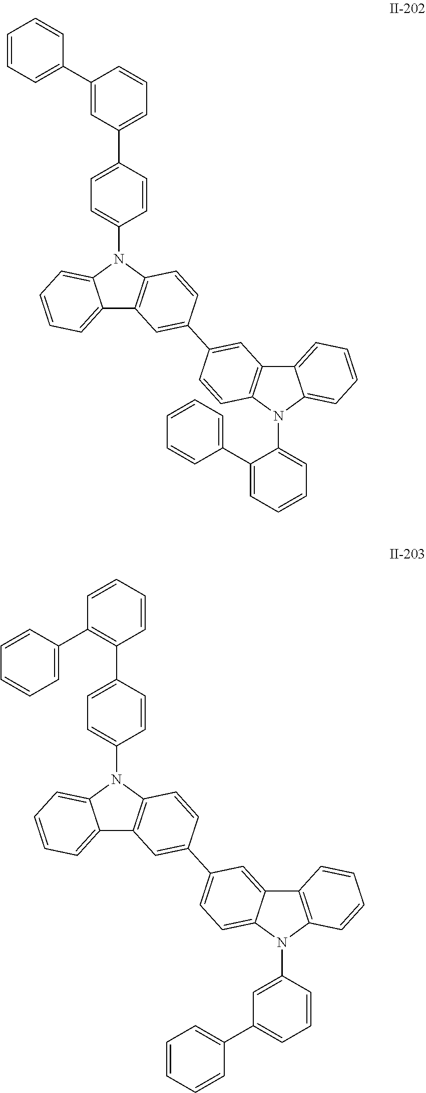 [SMILES: c1ccc(-c2cccc(-c3ccc(-n4c5ccccc5c5cc(-c6ccc7c(c6)c6ccccc6n7-c6ccccc6-c6ccccc6)ccc54)cc3)c2)cc1 ; c1ccc(-c2cccc(-n3c4ccccc4c4cc(-c5ccc6c(c5)c5ccccc5n6-c5ccc(-c6ccccc6-c6ccccc6)cc5)ccc43)c2)cc1] 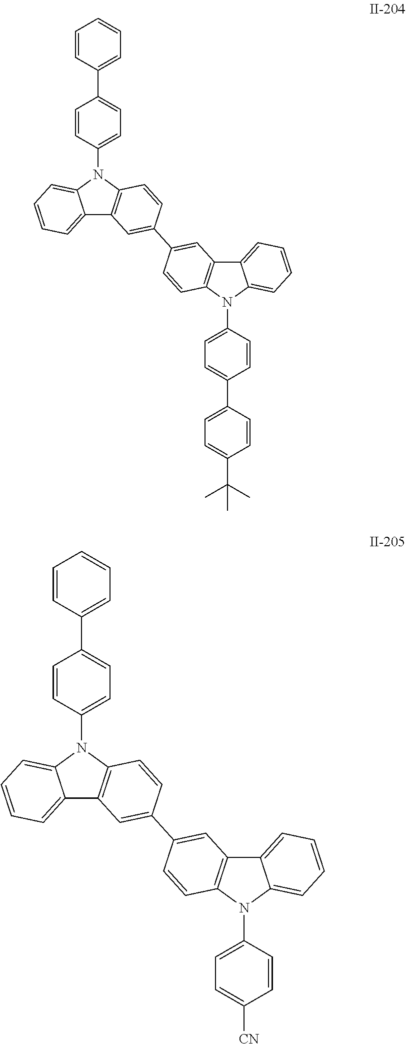 [SMILES: CC(C)(C)c1ccc(-c2ccc(-n3c4ccccc4c4cc(-c5ccc6c(c5)c5ccccc5n6-c5ccc(-c6ccccc6)cc5)ccc43)cc2)cc1 ; N#Cc1ccc(-n2c3ccccc3c3cc(-c4ccc5c(c4)c4ccccc4n5-c4ccc(-c5ccccc5)cc4)ccc32)cc1] 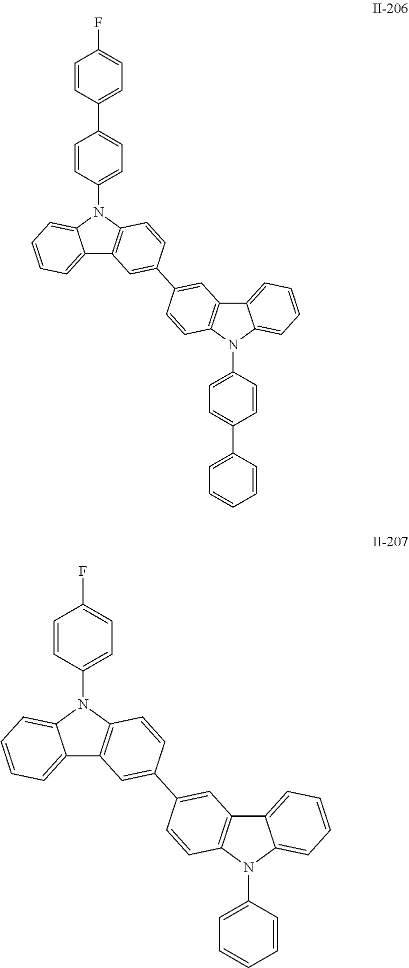 [SMILES: Fc1ccc(-c2ccc(-n3c4ccccc4c4cc(-c5ccc6c(c5)c5ccccc5n6-c5ccc(-c6ccccc6)cc5)ccc43)cc2)cc1 ; Fc1ccc(-n2c3ccccc3c3cc(-c4ccc5c(c4)c4ccccc4n5-c4ccccc4)ccc32)cc1] 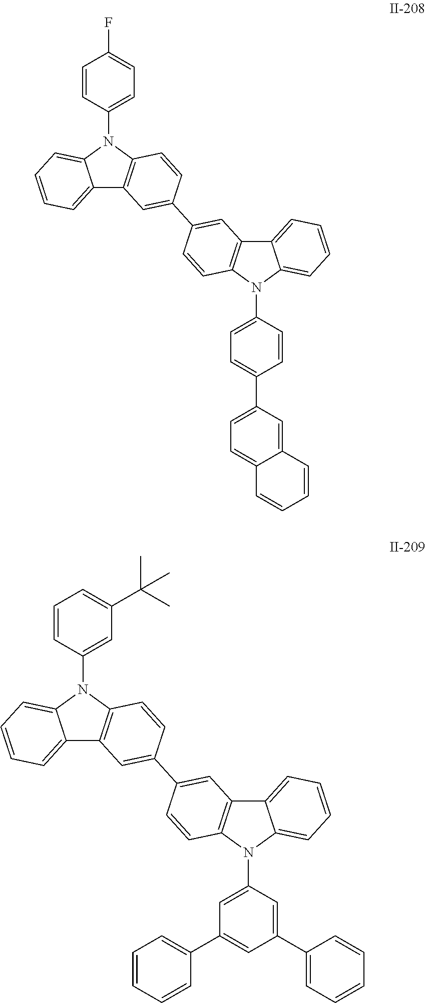 [SMILES: Fc1ccc(-n2c3ccccc3c3cc(-c4ccc5c(c4)c4ccccc4n5-c4ccc(-c5ccc6ccccc6c5)cc4)ccc32)cc1 ; CC(C)(C)c1cccc(-n2c3ccccc3c3cc(-c4ccc5c(c4)c4ccccc4n5-c4cc(-c5ccccc5)cc(-c5ccccc5)c4)ccc32)c1] 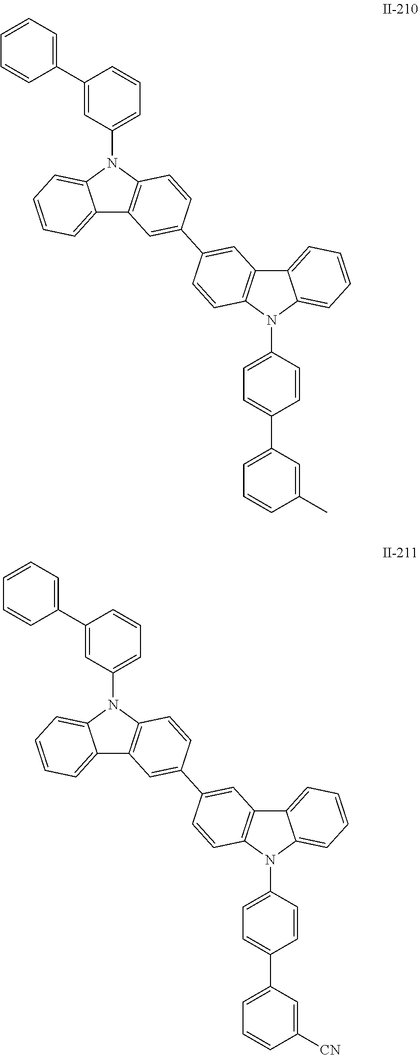 [SMILES: Cc1cccc(-c2ccc(-n3c4ccccc4c4cc(-c5ccc6c(c5)c5ccccc5n6-c5cccc(-c6ccccc6)c5)ccc43)cc2)c1 ; N#Cc1cccc(-c2ccc(-n3c4ccccc4c4cc(-c5ccc6c(c5)c5ccccc5n6-c5cccc(-c6ccccc6)c5)ccc43)cc2)c1] 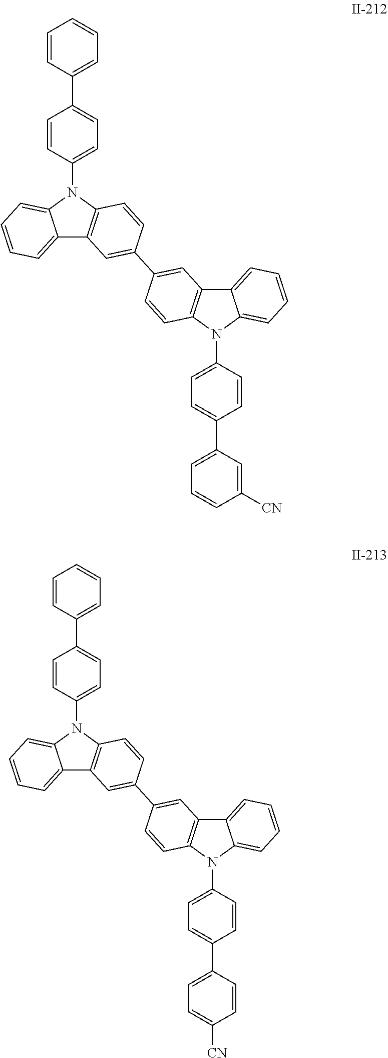 [SMILES: N#Cc1cccc(-c2ccc(-n3c4ccccc4c4cc(-c5ccc6c(c5)c5ccccc5n6-c5ccc(-c6ccccc6)cc5)ccc43)cc2)c1 ; N#Cc1ccc(-c2ccc(-n3c4ccccc4c4cc(-c5ccc6c(c5)c5ccccc5n6-c5ccc(-c6ccccc6)cc5)ccc43)cc2)cc1] 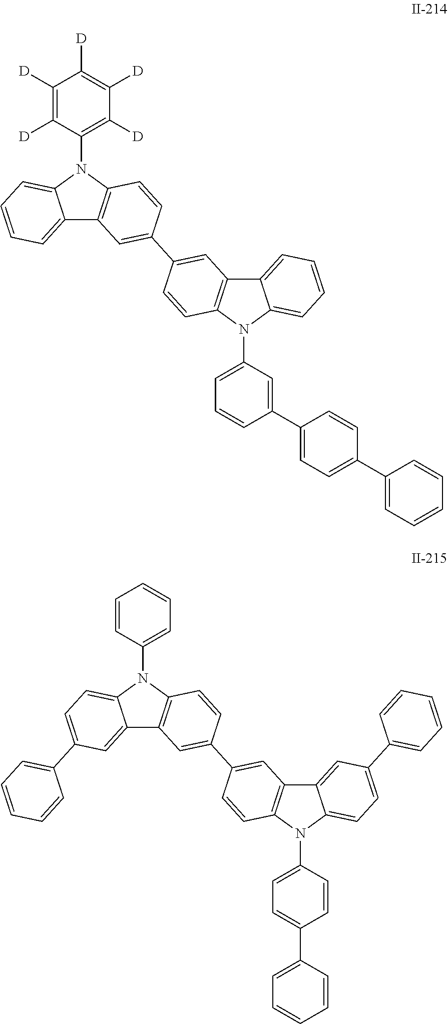 [SMILES: [2H]c1c([2H])c([2H])c(-n2c3ccccc3c3cc(-c4ccc5c(c4)c4ccccc4n5-c4cccc(-c5ccc(-c6ccccc6)cc5)c4)ccc32)c([2H])c1[2H] ; c1ccc(-c2ccc(-n3c4ccc(-c5ccccc5)cc4c4cc(-c5ccc6c(c5)c5cc(-c7ccccc7)ccc5n6-c5ccccc5)ccc43)cc2)cc1] 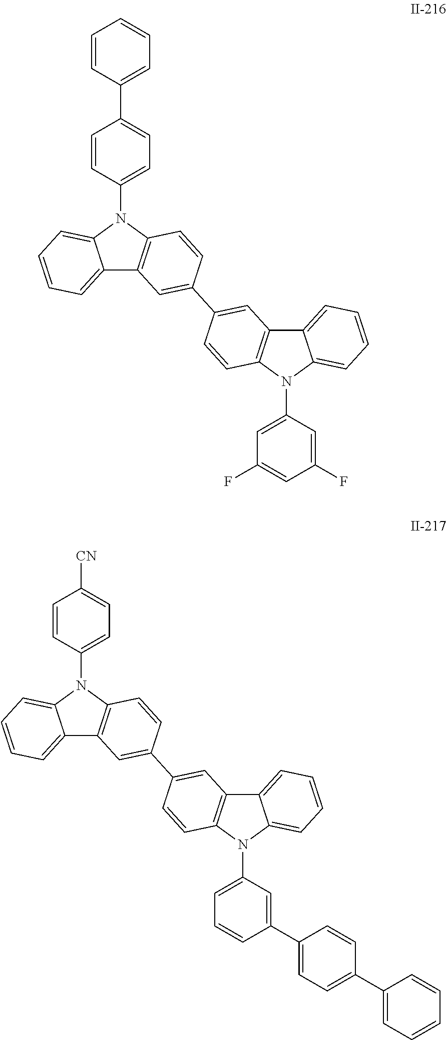 [SMILES: Fc1cc(F)cc(-n2c3ccccc3c3cc(-c4ccc5c(c4)c4ccccc4n5-c4ccc(-c5ccccc5)cc4)ccc32)c1 ; N#Cc1ccc(-n2c3ccccc3c3cc(-c4ccc5c(c4)c4ccccc4n5-c4cccc(-c5ccc(-c6ccccc6)cc5)c4)ccc32)cc1] 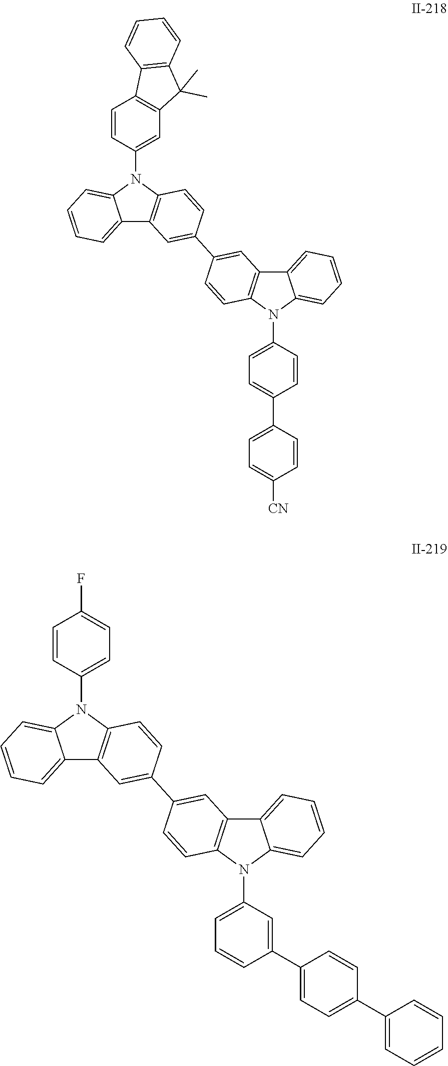 [SMILES: CC1(C)c2ccccc2-c2ccc(-n3c4ccccc4c4cc(-c5ccc6c(c5)c5ccccc5n6-c5ccc(-c6ccc(C#N)cc6)cc5)ccc43)cc21 ; Fc1ccc(-n2c3ccccc3c3cc(-c4ccc5c(c4)c4ccccc4n5-c4cccc(-c5ccc(-c6ccccc6)cc5)c4)ccc32)cc1] 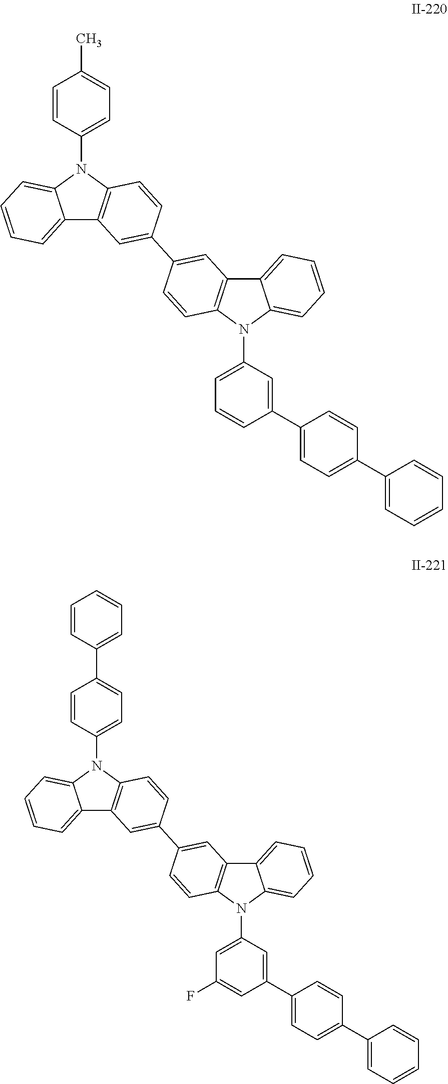 [SMILES: Cc1ccc(-n2c3ccccc3c3cc(-c4ccc5c(c4)c4ccccc4n5-c4cccc(-c5ccc(-c6ccccc6)cc5)c4)ccc32)cc1 ; Fc1cc(-c2ccc(-c3ccccc3)cc2)cc(-n2c3ccccc3c3cc(-c4ccc5c(c4)c4ccccc4n5-c4ccc(-c5ccccc5)cc4)ccc32)c1] 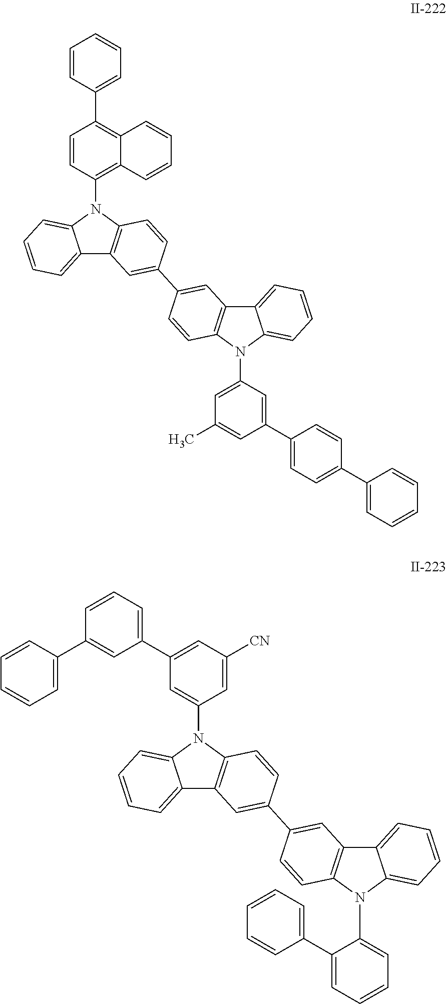 [SMILES: Cc1cc(-c2ccc(-c3ccccc3)cc2)cc(-n2c3ccccc3c3cc(-c4ccc5c(c4)c4ccccc4n5-c4ccc(-c5ccccc5)c5ccccc45)ccc32)c1 ; N#Cc1cc(-c2cccc(-c3ccccc3)c2)cc(-n2c3ccccc3c3cc(-c4ccc5c(c4)c4ccccc4n5-c4ccccc4-c4ccccc4)ccc32)c1] 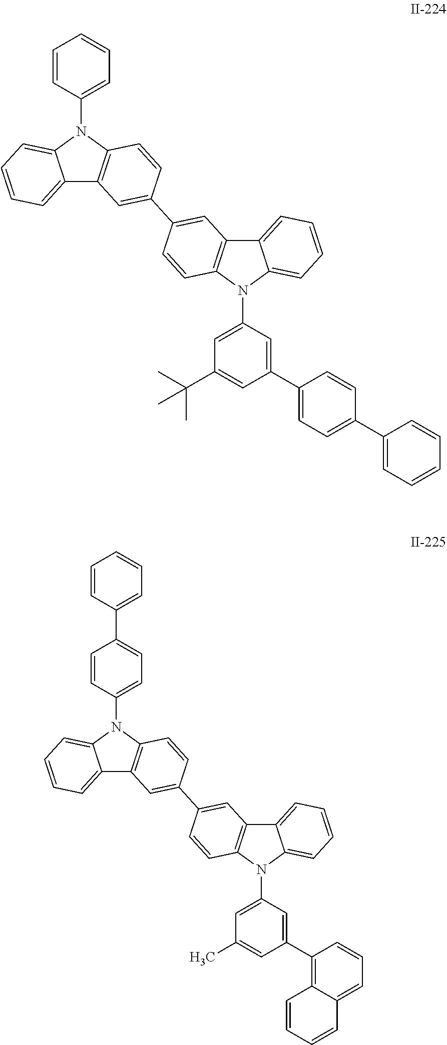 [SMILES: CC(C)(C)c1cc(-c2ccc(-c3ccccc3)cc2)cc(-n2c3ccccc3c3cc(-c4ccc5c(c4)c4ccccc4n5-c4ccccc4)ccc32)c1 ; Cc1cc(-c2cccc3ccccc23)cc(-n2c3ccccc3c3cc(-c4ccc5c(c4)c4ccccc4n5-c4ccc(-c5ccccc5)cc4)ccc32)c1] 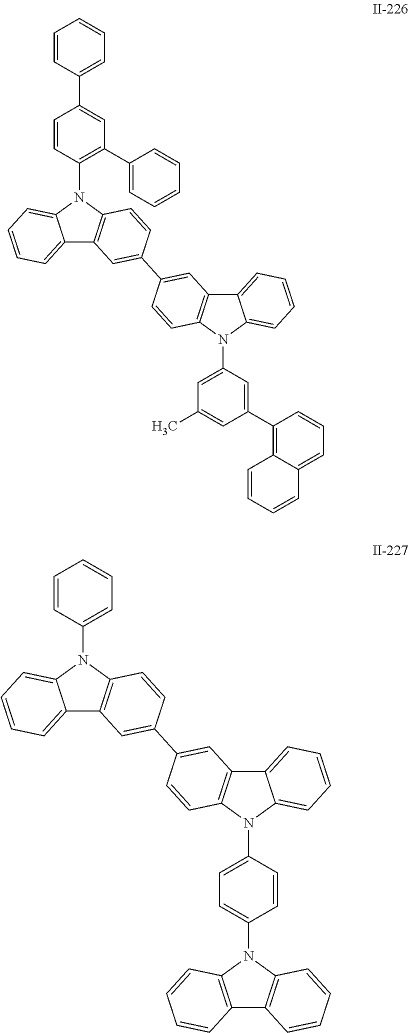 [SMILES: Cc1cc(-c2cccc3ccccc23)cc(-n2c3ccccc3c3cc(-c4ccc5c(c4)c4ccccc4n5-c4ccc(-c5ccccc5)cc4-c4ccccc4)ccc32)c1 ; c1ccc(-n2c3ccccc3c3cc(-c4ccc5c(c4)c4ccccc4n5-c4ccc(-n5c6ccccc6c6ccccc65)cc4)ccc32)cc1] 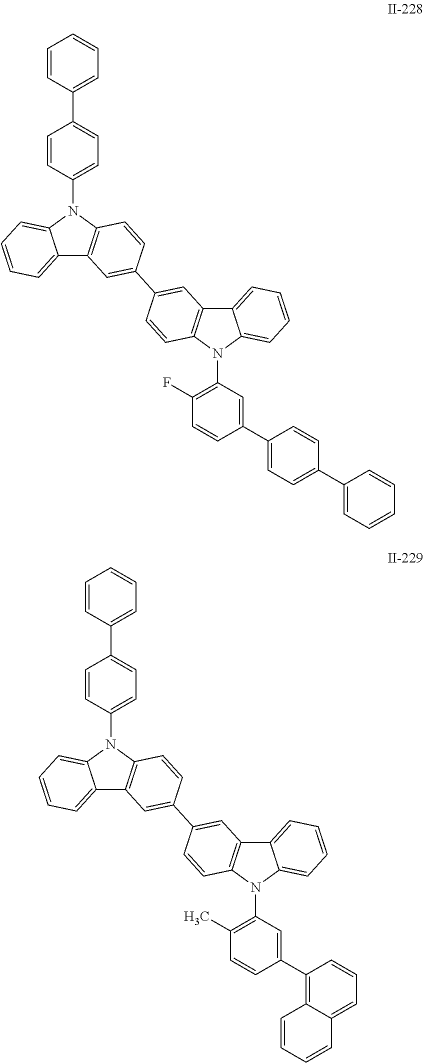 [SMILES: Fc1ccc(-c2ccc(-c3ccccc3)cc2)cc1-n1c2ccccc2c2cc(-c3ccc4c(c3)c3ccccc3n4-c3ccc(-c4ccccc4)cc3)ccc21 ; Cc1ccc(-c2cccc3ccccc23)cc1-n1c2ccccc2c2cc(-c3ccc4c(c3)c3ccccc3n4-c3ccc(-c4ccccc4)cc3)ccc21] 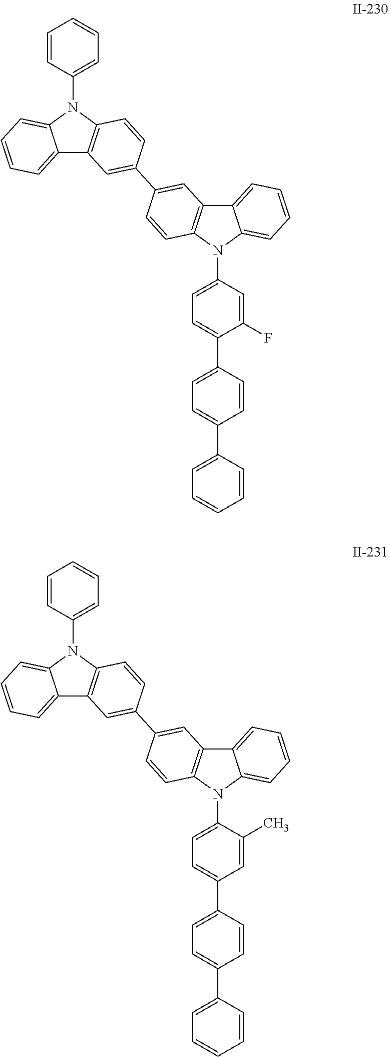 [SMILES: Fc1cc(-n2c3ccccc3c3cc(-c4ccc5c(c4)c4ccccc4n5-c4ccccc4)ccc32)ccc1-c1ccc(-c2ccccc2)cc1 ; Cc1cc(-c2ccc(-c3ccccc3)cc2)ccc1-n1c2ccccc2c2cc(-c3ccc4c(c3)c3ccccc3n4-c3ccccc3)ccc21] 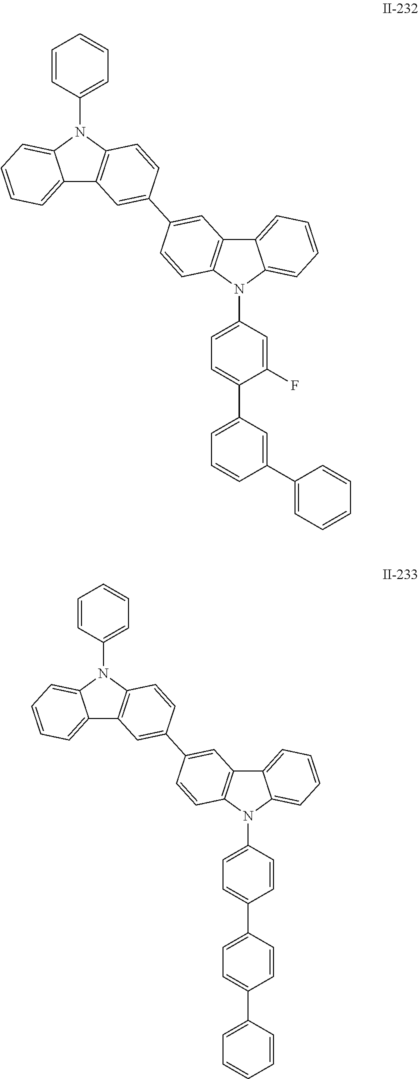 [SMILES: Fc1cc(-n2c3ccccc3c3cc(-c4ccc5c(c4)c4ccccc4n5-c4ccccc4)ccc32)ccc1-c1cccc(-c2ccccc2)c1 ; c1ccc(-c2ccc(-c3ccc(-n4c5ccccc5c5cc(-c6ccc7c(c6)c6ccccc6n7-c6ccccc6)ccc54)cc3)cc2)cc1] 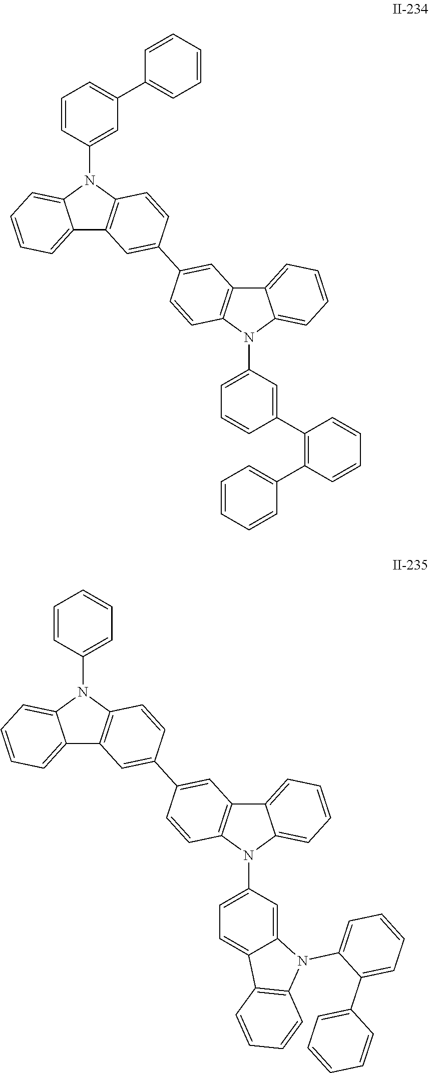 [SMILES: c1ccc(-c2cccc(-n3c4ccccc4c4cc(-c5ccc6c(c5)c5ccccc5n6-c5cccc(-c6ccccc6-c6ccccc6)c5)ccc43)c2)cc1 ; c1ccc(-c2ccccc2-n2c3ccccc3c3ccc(-n4c5ccccc5c5cc(-c6ccc7c(c6)c6ccccc6n7-c6ccccc6)ccc54)cc32)cc1] 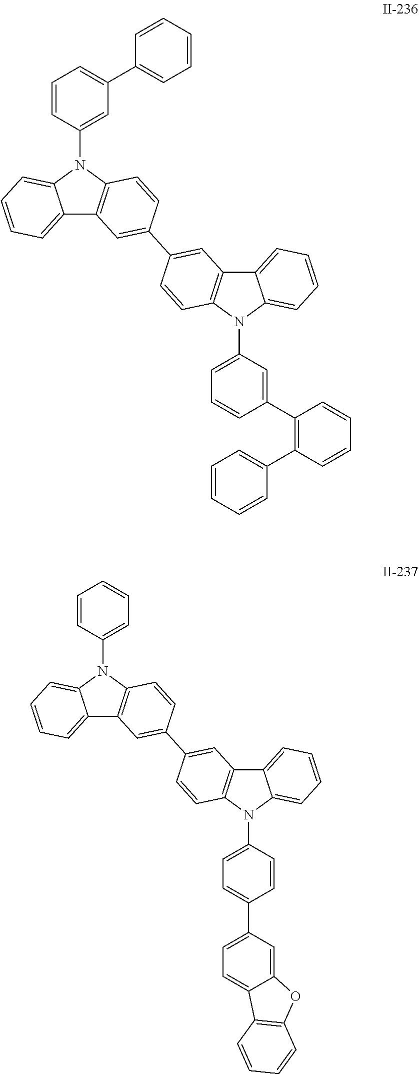 [SMILES: c1ccc(-c2cccc(-n3c4ccccc4c4cc(-c5ccc6c(c5)c5ccccc5n6-c5cccc(-c6ccccc6-c6ccccc6)c5)ccc43)c2)cc1 ; c1ccc(-n2c3ccccc3c3cc(-c4ccc5c(c4)c4ccccc4n5-c4ccc(-c5ccc6c(c5)oc5ccccc56)cc4)ccc32)cc1] 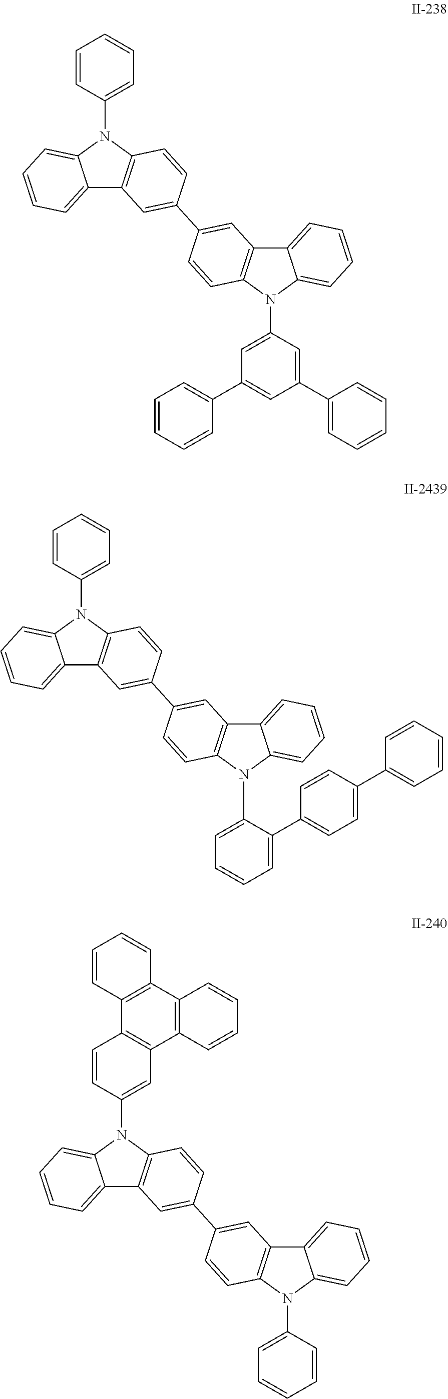 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3-n3c4ccccc4c4cc(-c5ccc6c(c5)c5ccccc5n6-c5ccccc5)ccc43)cc2)cc1 ; c1ccc(-n2c3ccccc3c3cc(-c4ccc5c(c4)c4ccccc4n5-c4ccc5c6ccccc6c6ccccc6c5c4)ccc32)cc1] 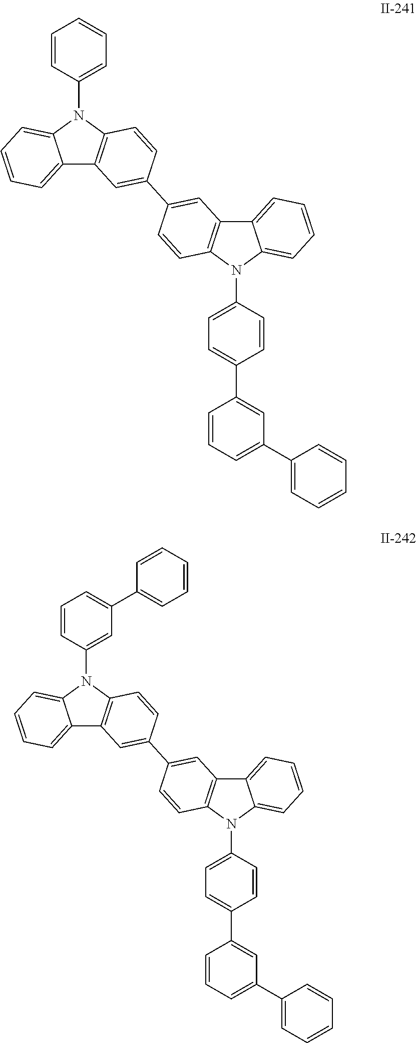 [SMILES: c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1] 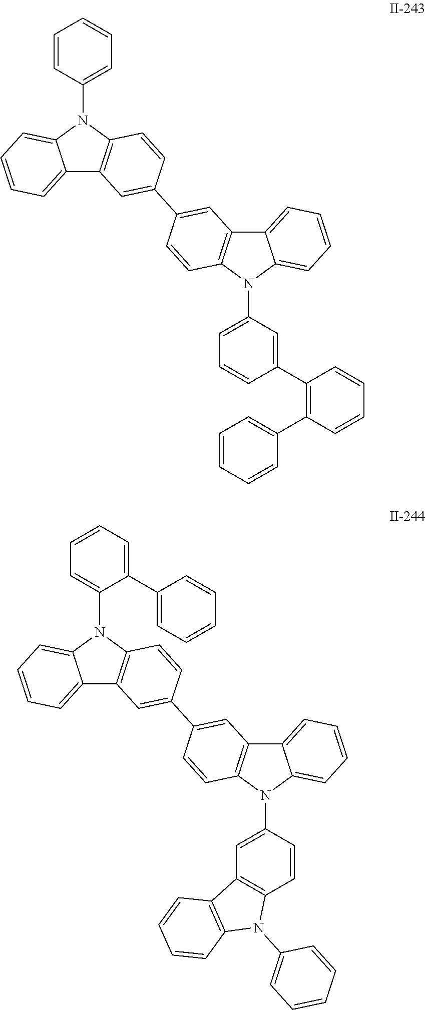 [SMILES: c1ccc(-c2ccccc2-c2cccc(-n3c4ccccc4c4cc(-c5ccc6c(c5)c5ccccc5n6-c5ccccc5)ccc43)c2)cc1 ; c1ccc(-c2ccccc2-n2c3ccccc3c3cc(-c4ccc5c(c4)c4ccccc4n5-c4ccc5c(c4)c4ccccc4n5-c4ccccc4)ccc32)cc1] 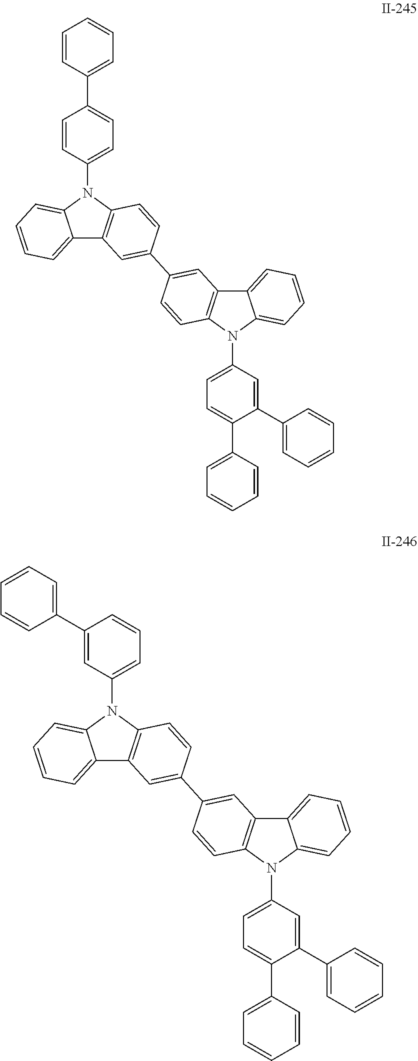 [SMILES: c1ccc(-c2ccc(-n3c4ccccc4c4cc(-c5ccc6c(c5)c5ccccc5n6-c5ccc(-c6ccccc6)c(-c6ccccc6)c5)ccc43)cc2)cc1 ; c1ccc(-c2cccc(-n3c4ccccc4c4cc(-c5ccc6c(c5)c5ccccc5n6-c5ccc(-c6ccccc6)c(-c6ccccc6)c5)ccc43)c2)cc1] 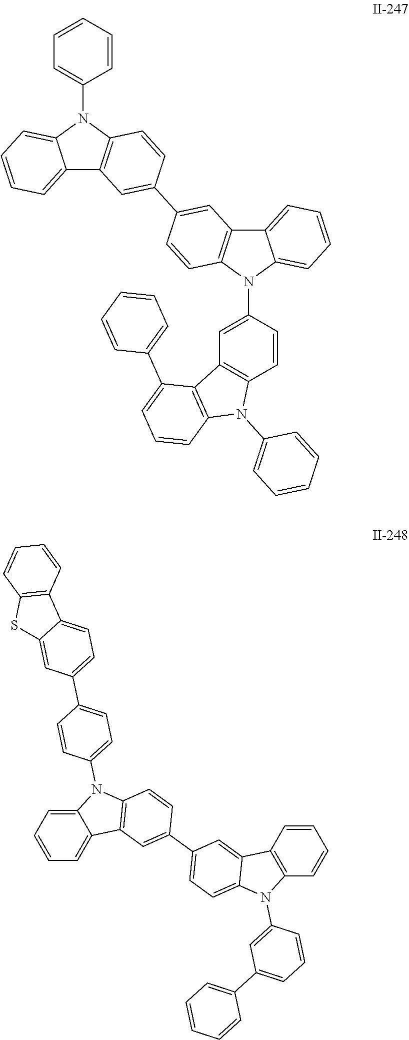 [SMILES: c1ccc(-c2cccc3c2c2cc(-n4c5ccccc5c5cc(-c6ccc7c(c6)c6ccccc6n7-c6ccccc6)ccc54)ccc2n3-c2ccccc2)cc1 ; c1ccc(-c2cccc(-n3c4ccccc4c4cc(-c5ccc6c(c5)c5ccccc5n6-c5ccc(-c6ccc7c(c6)sc6ccccc67)cc5)ccc43)c2)cc1] 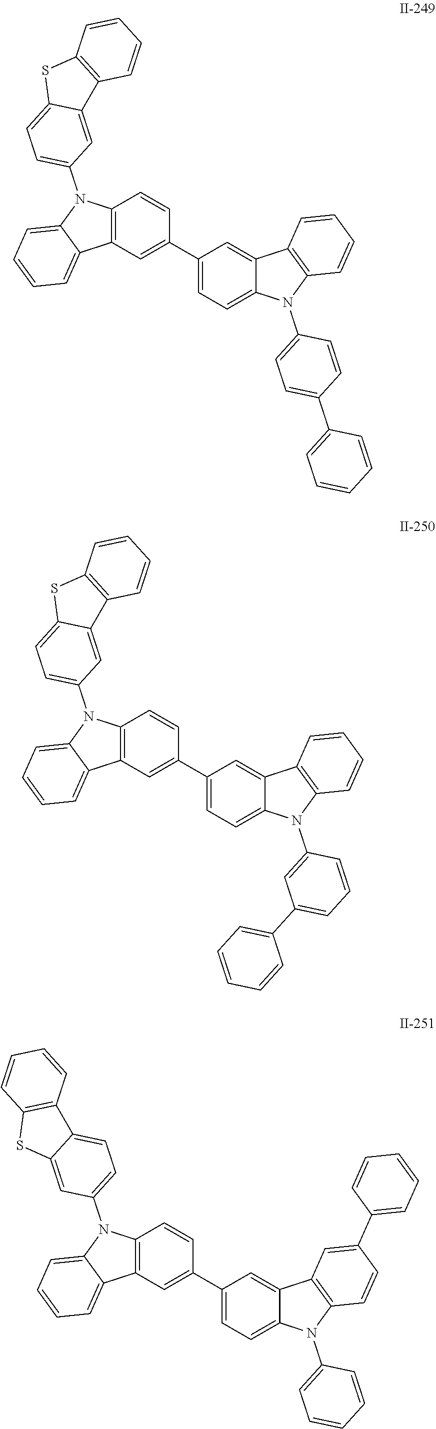 [SMILES: c1ccc(-c2ccc(-n3c4ccccc4c4cc(-c5ccc6c(c5)c5ccccc5n6-c5ccc6sc7ccccc7c6c5)ccc43)cc2)cc1 ; c1ccc(-c2cccc(-n3c4ccccc4c4cc(-c5ccc6c(c5)c5ccccc5n6-c5ccc6sc7ccccc7c6c5)ccc43)c2)cc1 ; c1ccc(-c2ccc3c(c2)c2cc(-c4ccc5c(c4)c4ccccc4n5-c4ccc5c(c4)sc4ccccc45)ccc2n3-c2ccccc2)cc1] 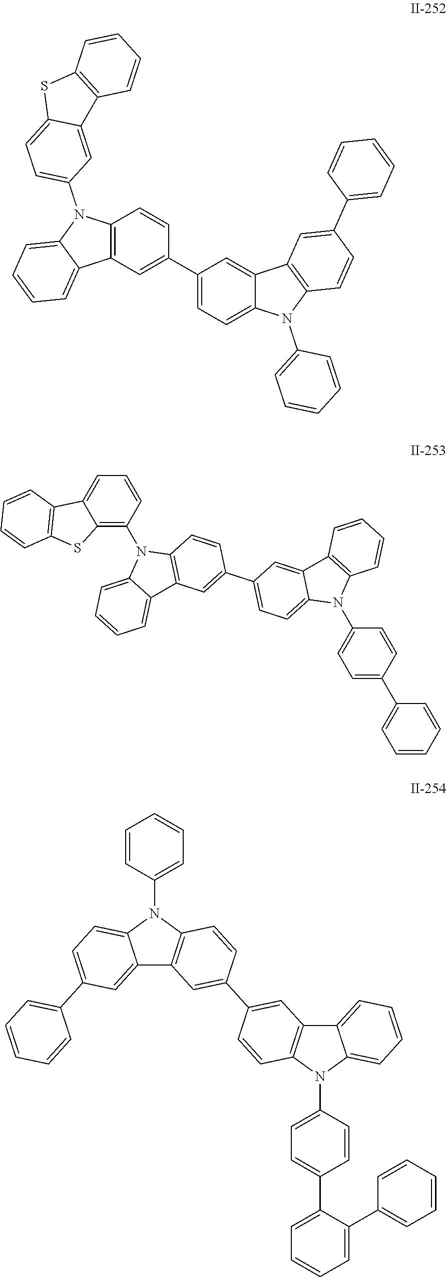 [SMILES: c1ccc(-c2ccc3c(c2)c2cc(-c4ccc5c(c4)c4ccccc4n5-c4ccc5sc6ccccc6c5c4)ccc2n3-c2ccccc2)cc1 ; c1ccc(-c2ccc(-n3c4ccccc4c4cc(-c5ccc6c(c5)c5ccccc5n6-c5cccc6c5sc5ccccc56)ccc43)cc2)cc1 ; c1ccc(-c2ccc3c(c2)c2cc(-c4ccc5c(c4)c4ccccc4n5-c4ccc(-c5ccccc5-c5ccccc5)cc4)ccc2n3-c2ccccc2)cc1] 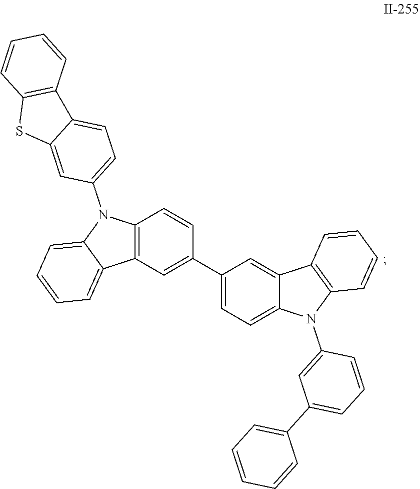 [SMILES: c1ccc(-c2cccc(-n3c4ccccc4c4cc(-c5ccc6c(c5)c5ccccc5n6-c5ccc6c(c5)sc5ccccc56)ccc43)c2)cc1]
the first compound is selected from a group consisting of the following compounds:

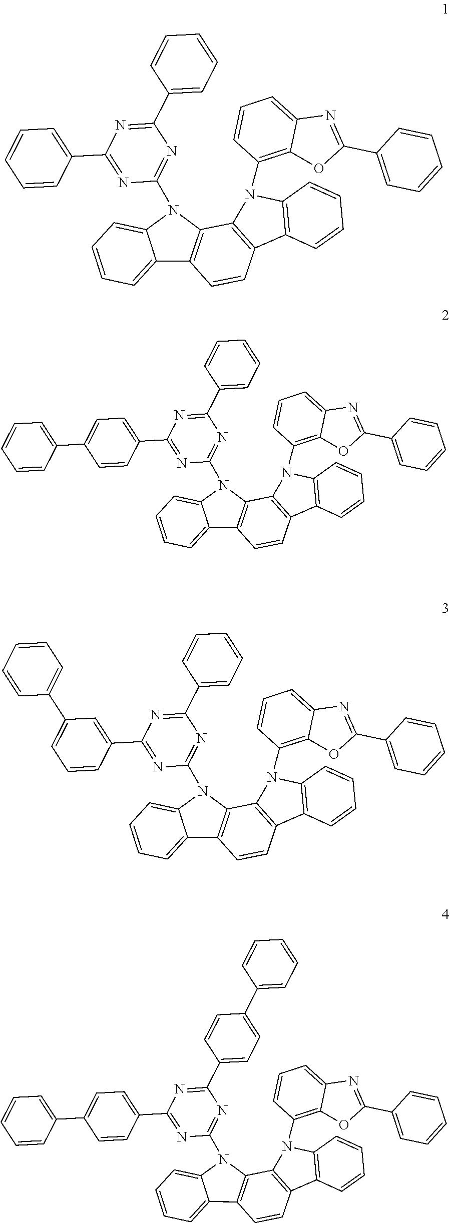 [SMILES: c1ccc(-c2nc(-c3ccccc3)nc(-n3c4ccccc4c4ccc5c6ccccc6n(-c6cccc7nc(-c8ccccc8)oc67)c5c43)n2)cc1 ; c1ccc(-c2ccc(-c3nc(-c4ccccc4)nc(-n4c5ccccc5c5ccc6c7ccccc7n(-c7cccc8nc(-c9ccccc9)oc78)c6c54)n3)cc2)cc1 ; c1ccc(-c2cccc(-c3nc(-c4ccccc4)nc(-n4c5ccccc5c5ccc6c7ccccc7n(-c7cccc8nc(-c9ccccc9)oc78)c6c54)n3)c2)cc1 ; c1ccc(-c2ccc(-c3nc(-c4ccc(-c5ccccc5)cc4)nc(-n4c5ccccc5c5ccc6c7ccccc7n(-c7cccc8nc(-c9ccccc9)oc78)c6c54)n3)cc2)cc1]

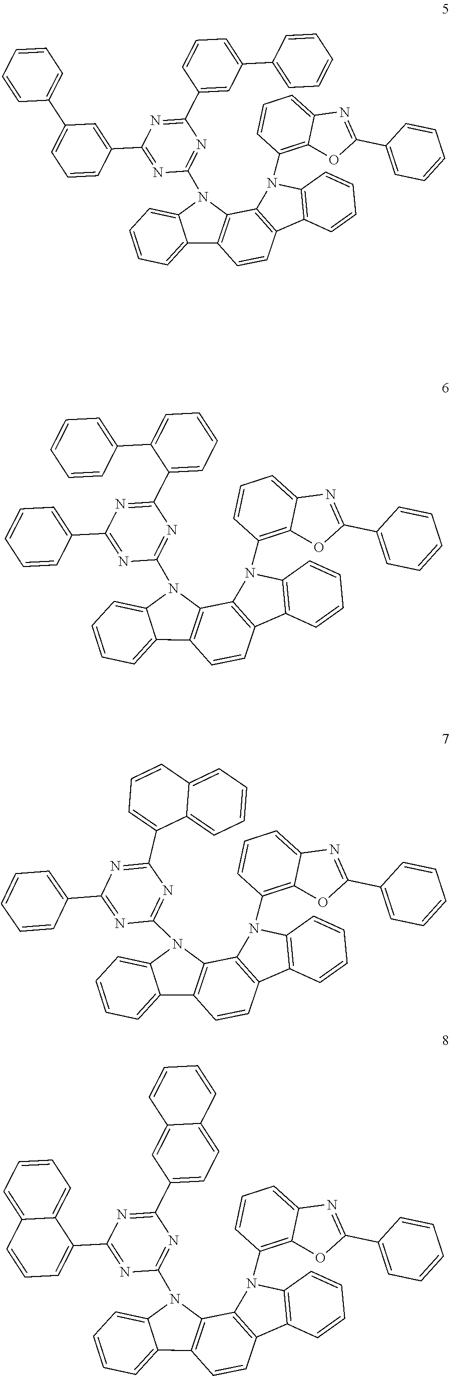 [SMILES: c1ccc(-c2cccc(-c3nc(-c4cccc(-c5ccccc5)c4)nc(-n4c5ccccc5c5ccc6c7ccccc7n(-c7cccc8nc(-c9ccccc9)oc78)c6c54)n3)c2)cc1 ; c1ccc(-c2nc(-c3ccccc3-c3ccccc3)nc(-n3c4ccccc4c4ccc5c6ccccc6n(-c6cccc7nc(-c8ccccc8)oc67)c5c43)n2)cc1 ; c1ccc(-c2nc(-c3cccc4ccccc34)nc(-n3c4ccccc4c4ccc5c6ccccc6n(-c6cccc7nc(-c8ccccc8)oc67)c5c43)n2)cc1 ; c1ccc(-c2nc3cccc(-n4c5ccccc5c5ccc6c7ccccc7n(-c7nc(-c8ccc9ccccc9c8)nc(-c8cccc9ccccc89)n7)c6c54)c3o2)cc1]

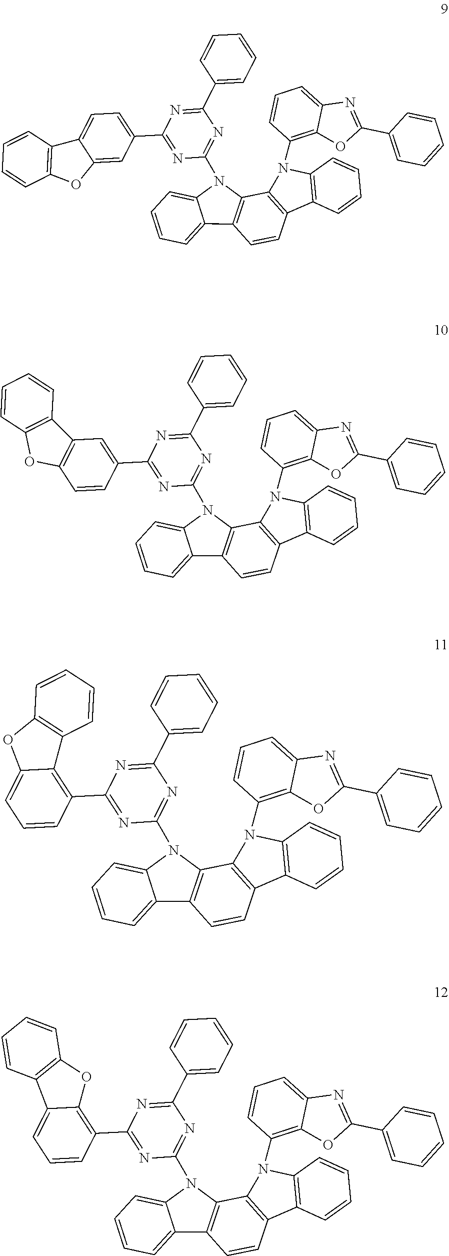 [SMILES: c1ccc(-c2nc(-c3ccc4c(c3)oc3ccccc34)nc(-n3c4ccccc4c4ccc5c6ccccc6n(-c6cccc7nc(-c8ccccc8)oc67)c5c43)n2)cc1 ; c1ccc(-c2nc(-c3ccc4oc5ccccc5c4c3)nc(-n3c4ccccc4c4ccc5c6ccccc6n(-c6cccc7nc(-c8ccccc8)oc67)c5c43)n2)cc1 ; c1ccc(-c2nc(-c3cccc4oc5ccccc5c34)nc(-n3c4ccccc4c4ccc5c6ccccc6n(-c6cccc7nc(-c8ccccc8)oc67)c5c43)n2)cc1 ; c1ccc(-c2nc(-c3cccc4c3oc3ccccc34)nc(-n3c4ccccc4c4ccc5c6ccccc6n(-c6cccc7nc(-c8ccccc8)oc67)c5c43)n2)cc1]

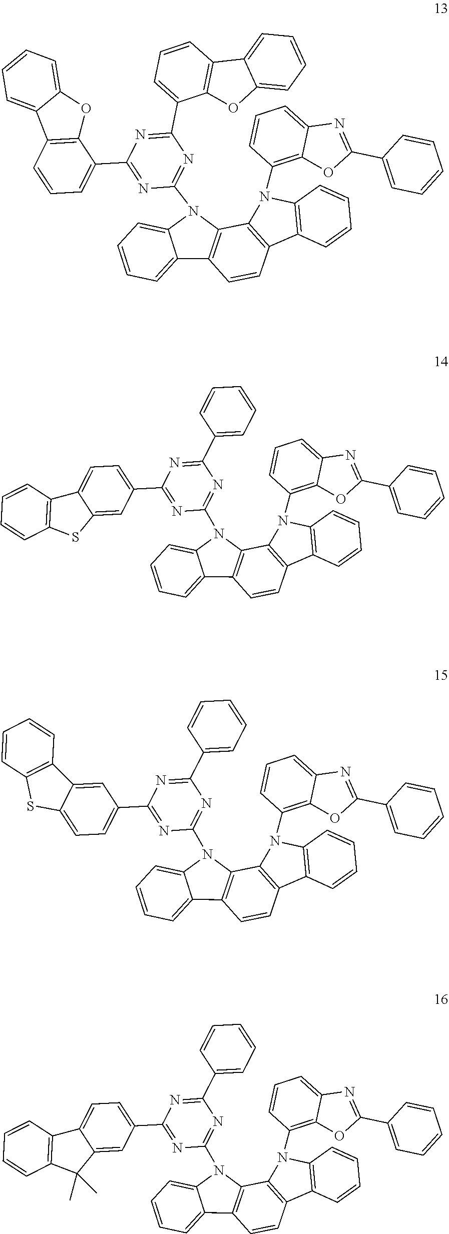 [SMILES: c1ccc(-c2nc3cccc(-n4c5ccccc5c5ccc6c7ccccc7n(-c7nc(-c8cccc9c8oc8ccccc89)nc(-c8cccc9c8oc8ccccc89)n7)c6c54)c3o2)cc1 ; c1ccc(-c2nc(-c3ccc4c(c3)sc3ccccc34)nc(-n3c4ccccc4c4ccc5c6ccccc6n(-c6cccc7nc(-c8ccccc8)oc67)c5c43)n2)cc1 ; c1ccc(-c2nc(-c3ccc4sc5ccccc5c4c3)nc(-n3c4ccccc4c4ccc5c6ccccc6n(-c6cccc7nc(-c8ccccc8)oc67)c5c43)n2)cc1 ; CC1(C)c2ccccc2-c2ccc(-c3nc(-c4ccccc4)nc(-n4c5ccccc5c5ccc6c7ccccc7n(-c7cccc8nc(-c9ccccc9)oc78)c6c54)n3)cc21]

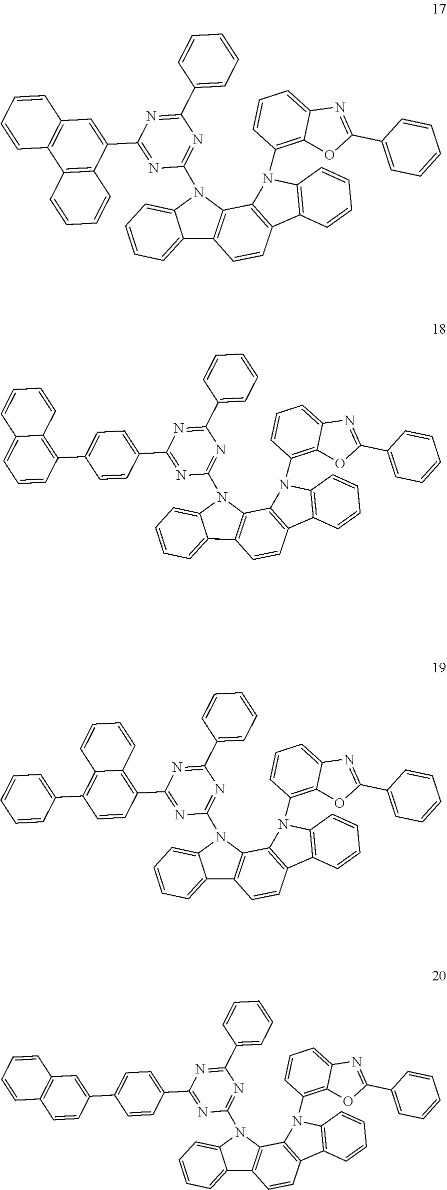 [SMILES: c1ccc(-c2nc(-c3cc4ccccc4c4ccccc34)nc(-n3c4ccccc4c4ccc5c6ccccc6n(-c6cccc7nc(-c8ccccc8)oc67)c5c43)n2)cc1 ; c1ccc(-c2nc(-c3ccc(-c4cccc5ccccc45)cc3)nc(-n3c4ccccc4c4ccc5c6ccccc6n(-c6cccc7nc(-c8ccccc8)oc67)c5c43)n2)cc1 ; c1ccc(-c2nc(-c3ccc(-c4ccccc4)c4ccccc34)nc(-n3c4ccccc4c4ccc5c6ccccc6n(-c6cccc7nc(-c8ccccc8)oc67)c5c43)n2)cc1 ; c1ccc(-c2nc(-c3ccc(-c4ccc5ccccc5c4)cc3)nc(-n3c4ccccc4c4ccc5c6ccccc6n(-c6cccc7nc(-c8ccccc8)oc67)c5c43)n2)cc1]

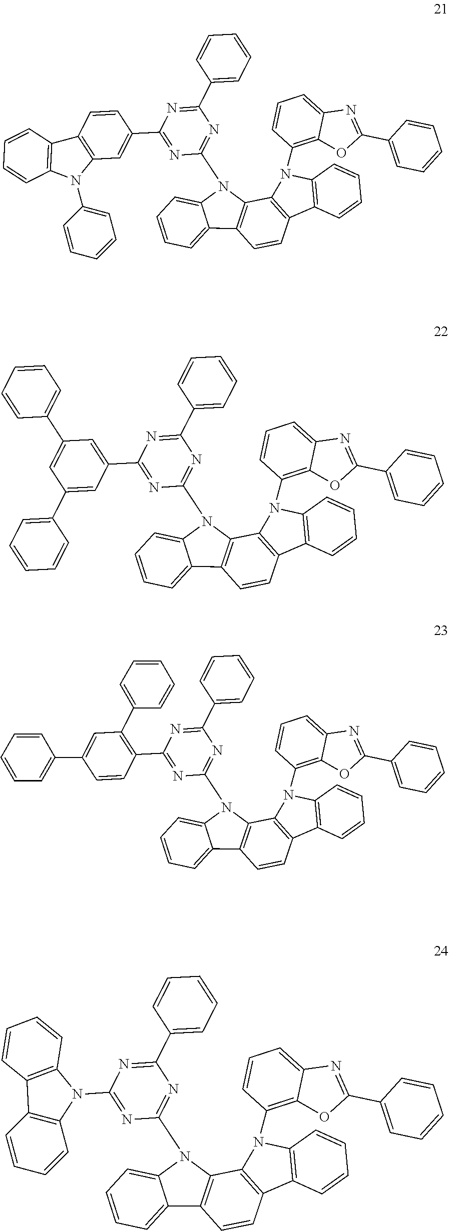 [SMILES: c1ccc(-c2nc(-c3ccc4c5ccccc5n(-c5ccccc5)c4c3)nc(-n3c4ccccc4c4ccc5c6ccccc6n(-c6cccc7nc(-c8ccccc8)oc67)c5c43)n2)cc1 ; c1ccc(-c2cc(-c3ccccc3)cc(-c3nc(-c4ccccc4)nc(-n4c5ccccc5c5ccc6c7ccccc7n(-c7cccc8nc(-c9ccccc9)oc78)c6c54)n3)c2)cc1 ; c1ccc(-c2ccc(-c3nc(-c4ccccc4)nc(-n4c5ccccc5c5ccc6c7ccccc7n(-c7cccc8nc(-c9ccccc9)oc78)c6c54)n3)c(-c3ccccc3)c2)cc1 ; c1ccc(-c2nc(-n3c4ccccc4c4ccccc43)nc(-n3c4ccccc4c4ccc5c6ccccc6n(-c6cccc7nc(-c8ccccc8)oc67)c5c43)n2)cc1]

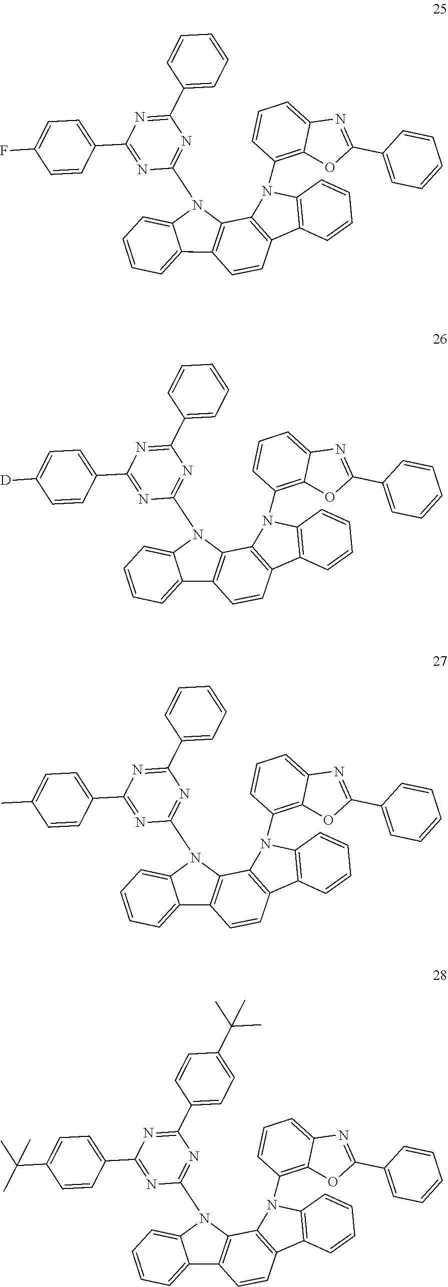 [SMILES: Fc1ccc(-c2nc(-c3ccccc3)nc(-n3c4ccccc4c4ccc5c6ccccc6n(-c6cccc7nc(-c8ccccc8)oc67)c5c43)n2)cc1 ; [2H]c1ccc(-c2nc(-c3ccccc3)nc(-n3c4ccccc4c4ccc5c6ccccc6n(-c6cccc7nc(-c8ccccc8)oc67)c5c43)n2)cc1 ; Cc1ccc(-c2nc(-c3ccccc3)nc(-n3c4ccccc4c4ccc5c6ccccc6n(-c6cccc7nc(-c8ccccc8)oc67)c5c43)n2)cc1 ; CC(C)(C)c1ccc(-c2nc(-c3ccc(C(C)(C)C)cc3)nc(-n3c4ccccc4c4ccc5c6ccccc6n(-c6cccc7nc(-c8ccccc8)oc67)c5c43)n2)cc1]

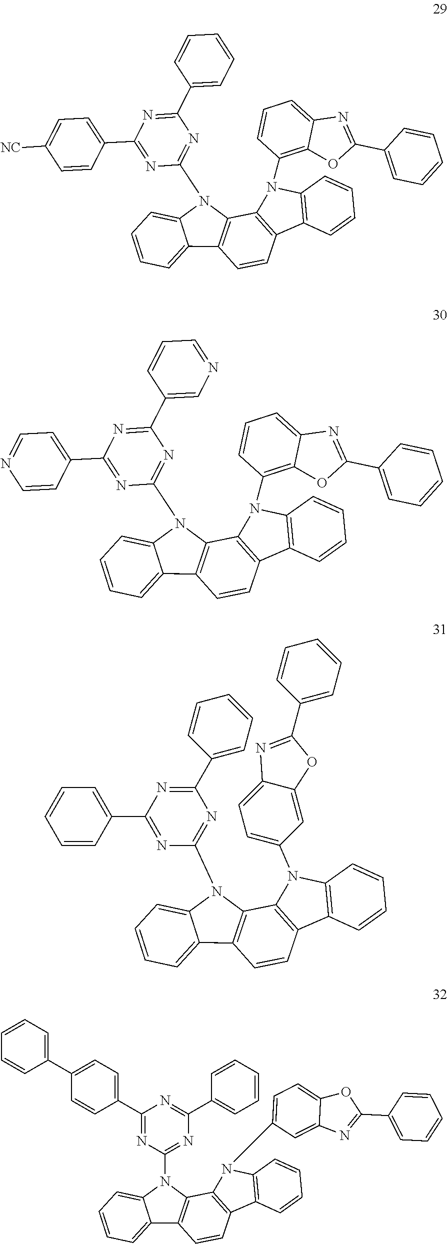 [SMILES: N#Cc1ccc(-c2nc(-c3ccccc3)nc(-n3c4ccccc4c4ccc5c6ccccc6n(-c6cccc7nc(-c8ccccc8)oc67)c5c43)n2)cc1 ; c1ccc(-c2nc3cccc(-n4c5ccccc5c5ccc6c7ccccc7n(-c7nc(-c8ccncc8)nc(-c8cccnc8)n7)c6c54)c3o2)cc1 ; c1ccc(-c2nc(-c3ccccc3)nc(-n3c4ccccc4c4ccc5c6ccccc6n(-c6ccc7nc(-c8ccccc8)oc7c6)c5c43)n2)cc1 ; c1ccc(-c2ccc(-c3nc(-c4ccccc4)nc(-n4c5ccccc5c5ccc6c7ccccc7n(-c7ccc8oc(-c9ccccc9)nc8c7)c6c54)n3)cc2)cc1]

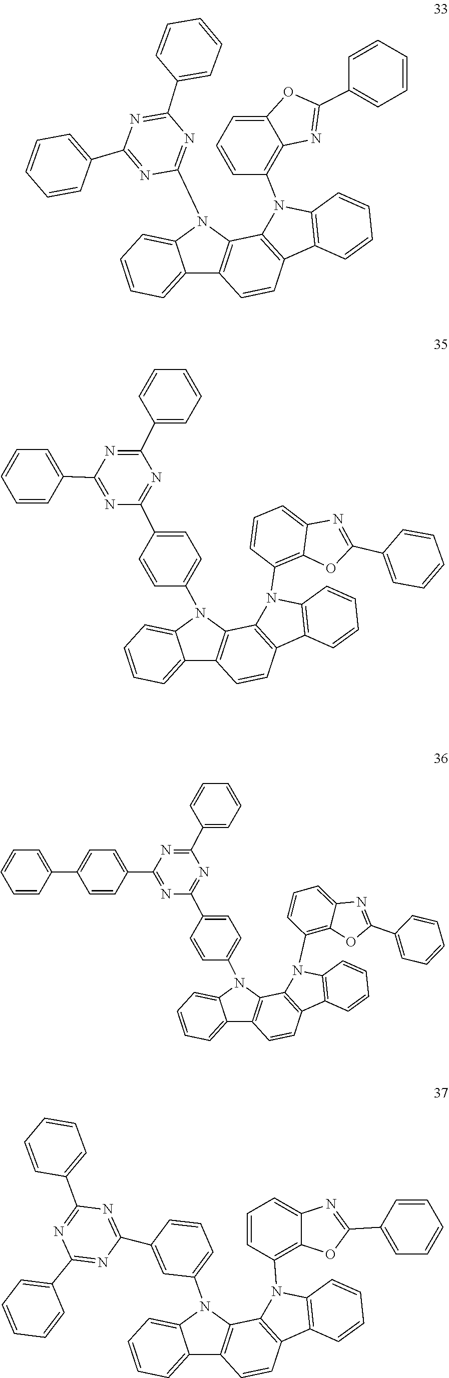 [SMILES: c1ccc(-c2nc(-c3ccccc3)nc(-n3c4ccccc4c4ccc5c6ccccc6n(-c6cccc7oc(-c8ccccc8)nc67)c5c43)n2)cc1 ; c1ccc(-c2nc(-c3ccccc3)nc(-c3ccc(-n4c5ccccc5c5ccc6c7ccccc7n(-c7cccc8nc(-c9ccccc9)oc78)c6c54)cc3)n2)cc1 ; c1ccc(-c2ccc(-c3nc(-c4ccccc4)nc(-c4ccc(-n5c6ccccc6c6ccc7c8ccccc8n(-c8cccc9nc(-c%10ccccc%10)oc89)c7c65)cc4)n3)cc2)cc1 ; c1ccc(-c2nc(-c3ccccc3)nc(-c3cccc(-n4c5ccccc5c5ccc6c7ccccc7n(-c7cccc8nc(-c9ccccc9)oc78)c6c54)c3)n2)cc1]

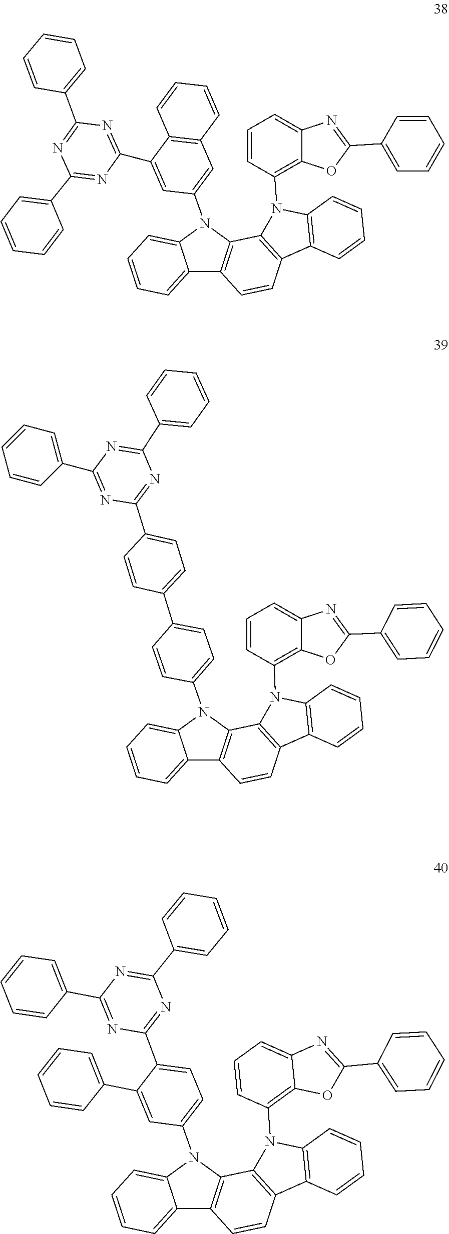 [SMILES: c1ccc(-c2nc(-c3ccccc3)nc(-c3cc(-n4c5ccccc5c5ccc6c7ccccc7n(-c7cccc8nc(-c9ccccc9)oc78)c6c54)cc4ccccc34)n2)cc1 ; c1ccc(-c2nc(-c3ccccc3)nc(-c3ccc(-c4ccc(-n5c6ccccc6c6ccc7c8ccccc8n(-c8cccc9nc(-c%10ccccc%10)oc89)c7c65)cc4)cc3)n2)cc1 ; c1ccc(-c2nc(-c3ccccc3)nc(-c3ccc(-n4c5ccccc5c5ccc6c7ccccc7n(-c7cccc8nc(-c9ccccc9)oc78)c6c54)cc3-c3ccccc3)n2)cc1]

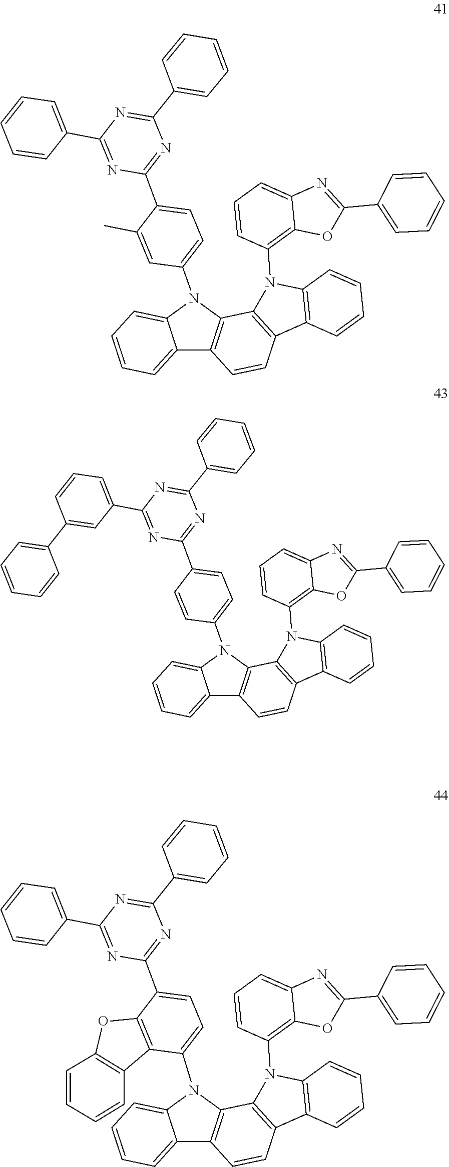 [SMILES: Cc1cc(-n2c3ccccc3c3ccc4c5ccccc5n(-c5cccc6nc(-c7ccccc7)oc56)c4c32)ccc1-c1nc(-c2ccccc2)nc(-c2ccccc2)n1 ; c1ccc(-c2cccc(-c3nc(-c4ccccc4)nc(-c4ccc(-n5c6ccccc6c6ccc7c8ccccc8n(-c8cccc9nc(-c%10ccccc%10)oc89)c7c65)cc4)n3)c2)cc1 ; c1ccc(-c2nc(-c3ccccc3)nc(-c3ccc(-n4c5ccccc5c5ccc6c7ccccc7n(-c7cccc8nc(-c9ccccc9)oc78)c6c54)c4c3oc3ccccc34)n2)cc1]

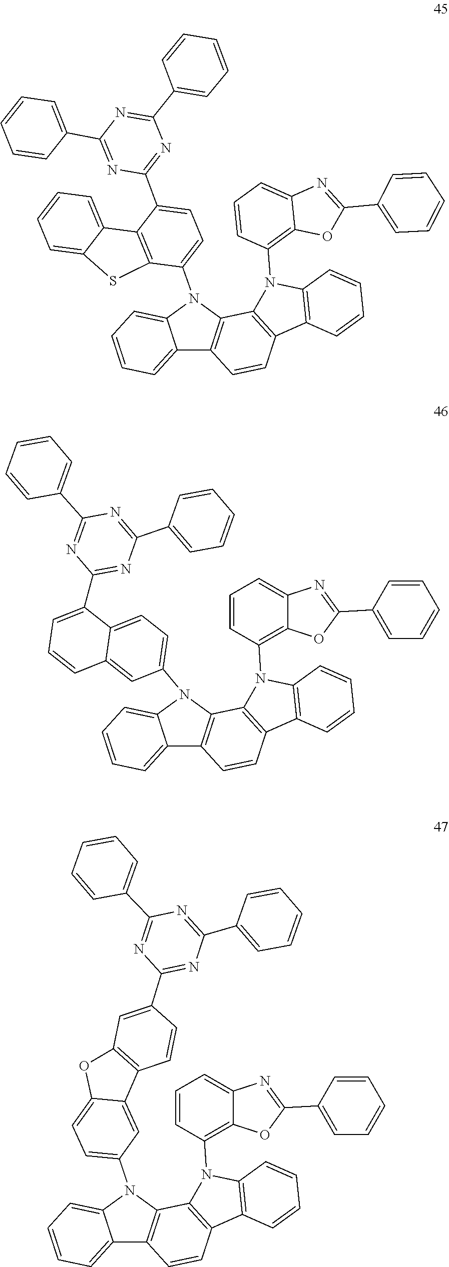 [SMILES: c1ccc(-c2nc(-c3ccccc3)nc(-c3ccc(-n4c5ccccc5c5ccc6c7ccccc7n(-c7cccc8nc(-c9ccccc9)oc78)c6c54)c4sc5ccccc5c34)n2)cc1 ; c1ccc(-c2nc(-c3ccccc3)nc(-c3cccc4cc(-n5c6ccccc6c6ccc7c8ccccc8n(-c8cccc9nc(-c%10ccccc%10)oc89)c7c65)ccc34)n2)cc1 ; c1ccc(-c2nc(-c3ccccc3)nc(-c3ccc4c(c3)oc3ccc(-n5c6ccccc6c6ccc7c8ccccc8n(-c8cccc9nc(-c%10ccccc%10)oc89)c7c65)cc34)n2)cc1]

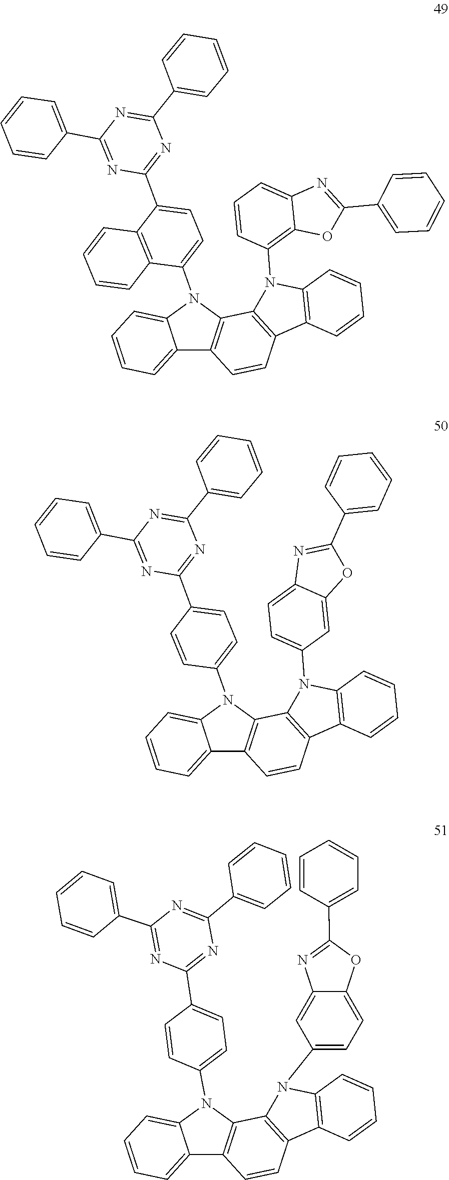 [SMILES: c1ccc(-c2nc(-c3ccccc3)nc(-c3ccc(-n4c5ccccc5c5ccc6c7ccccc7n(-c7cccc8nc(-c9ccccc9)oc78)c6c54)c4ccccc34)n2)cc1 ; c1ccc(-c2nc(-c3ccccc3)nc(-c3ccc(-n4c5ccccc5c5ccc6c7ccccc7n(-c7ccc8nc(-c9ccccc9)oc8c7)c6c54)cc3)n2)cc1 ; c1ccc(-c2nc(-c3ccccc3)nc(-c3ccc(-n4c5ccccc5c5ccc6c7ccccc7n(-c7ccc8oc(-c9ccccc9)nc8c7)c6c54)cc3)n2)cc1]

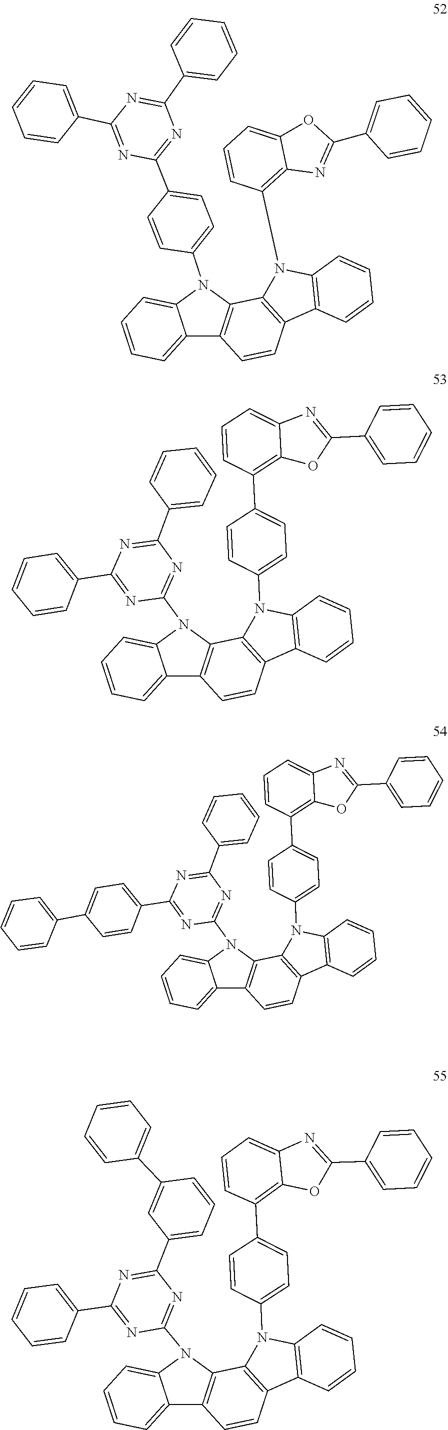 [SMILES: c1ccc(-c2nc(-c3ccccc3)nc(-c3ccc(-n4c5ccccc5c5ccc6c7ccccc7n(-c7cccc8oc(-c9ccccc9)nc78)c6c54)cc3)n2)cc1 ; c1ccc(-c2nc(-c3ccccc3)nc(-n3c4ccccc4c4ccc5c6ccccc6n(-c6ccc(-c7cccc8nc(-c9ccccc9)oc78)cc6)c5c43)n2)cc1 ; c1ccc(-c2ccc(-c3nc(-c4ccccc4)nc(-n4c5ccccc5c5ccc6c7ccccc7n(-c7ccc(-c8cccc9nc(-c%10ccccc%10)oc89)cc7)c6c54)n3)cc2)cc1 ; c1ccc(-c2cccc(-c3nc(-c4ccccc4)nc(-n4c5ccccc5c5ccc6c7ccccc7n(-c7ccc(-c8cccc9nc(-c%10ccccc%10)oc89)cc7)c6c54)n3)c2)cc1]

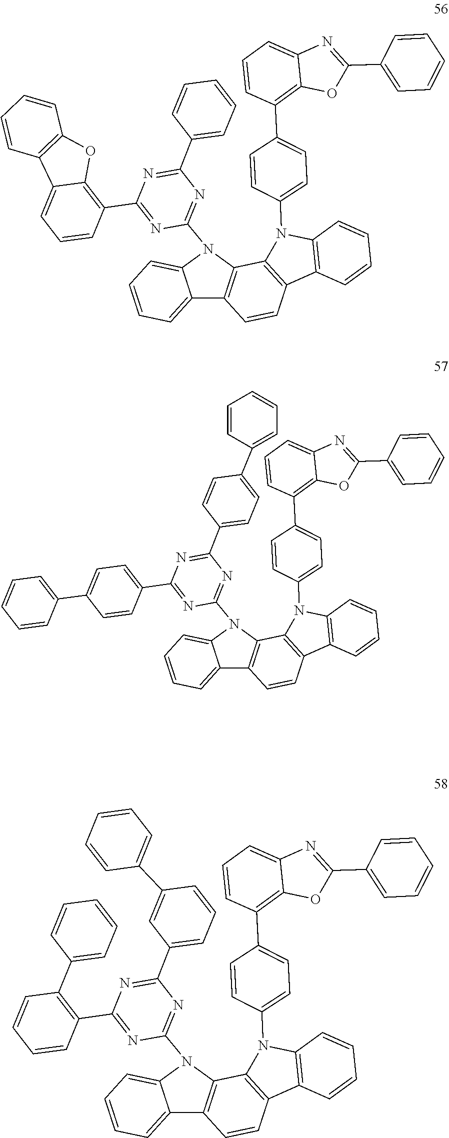 [SMILES: c1ccc(-c2nc(-c3cccc4c3oc3ccccc34)nc(-n3c4ccccc4c4ccc5c6ccccc6n(-c6ccc(-c7cccc8nc(-c9ccccc9)oc78)cc6)c5c43)n2)cc1 ; c1ccc(-c2ccc(-c3nc(-c4ccc(-c5ccccc5)cc4)nc(-n4c5ccccc5c5ccc6c7ccccc7n(-c7ccc(-c8cccc9nc(-c%10ccccc%10)oc89)cc7)c6c54)n3)cc2)cc1 ; c1ccc(-c2cccc(-c3nc(-c4ccccc4-c4ccccc4)nc(-n4c5ccccc5c5ccc6c7ccccc7n(-c7ccc(-c8cccc9nc(-c%10ccccc%10)oc89)cc7)c6c54)n3)c2)cc1]

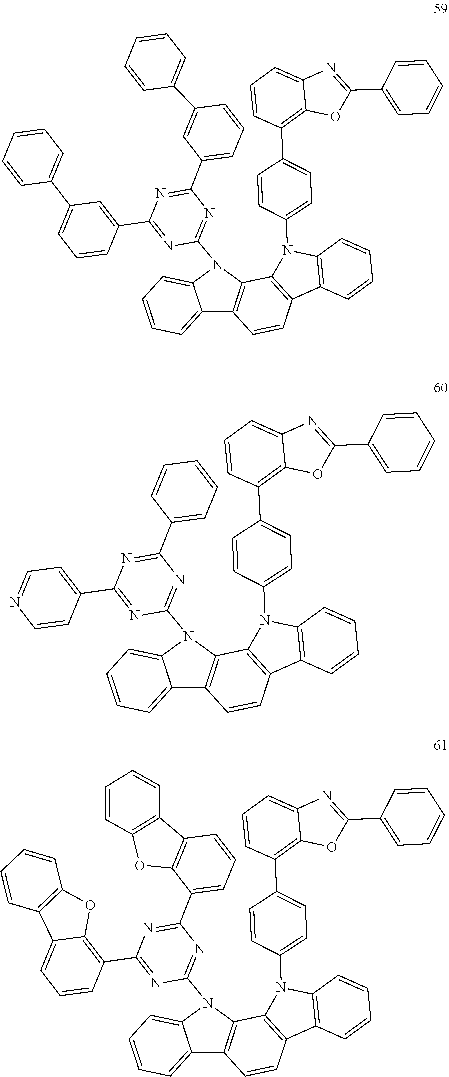 [SMILES: c1ccc(-c2cccc(-c3nc(-c4cccc(-c5ccccc5)c4)nc(-n4c5ccccc5c5ccc6c7ccccc7n(-c7ccc(-c8cccc9nc(-c%10ccccc%10)oc89)cc7)c6c54)n3)c2)cc1 ; c1ccc(-c2nc(-c3ccncc3)nc(-n3c4ccccc4c4ccc5c6ccccc6n(-c6ccc(-c7cccc8nc(-c9ccccc9)oc78)cc6)c5c43)n2)cc1 ; c1ccc(-c2nc3cccc(-c4ccc(-n5c6ccccc6c6ccc7c8ccccc8n(-c8nc(-c9cccc%10c9oc9ccccc9%10)nc(-c9cccc%10c9oc9ccccc9%10)n8)c7c65)cc4)c3o2)cc1]

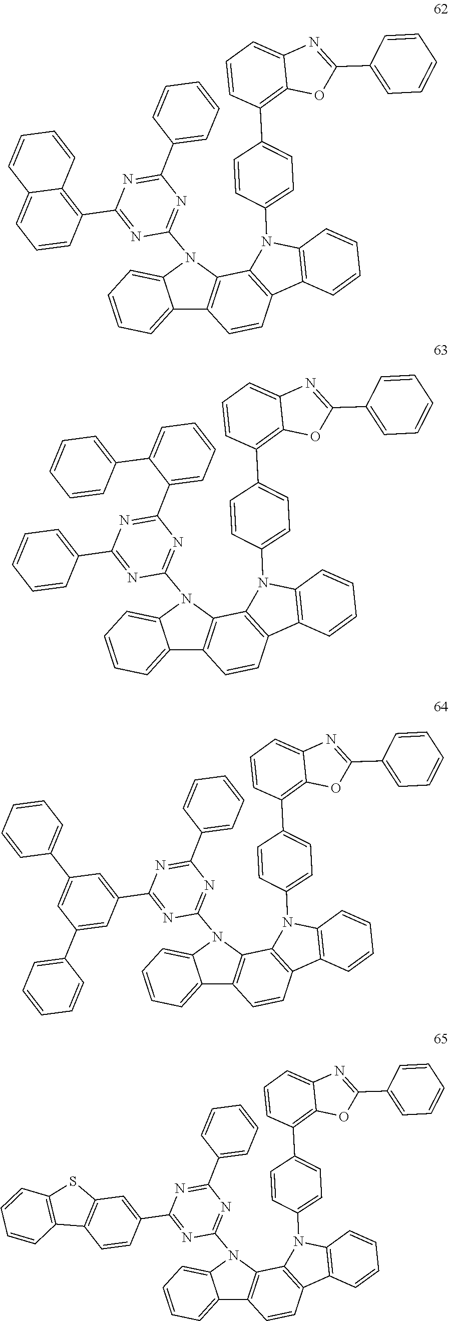 [SMILES: c1ccc(-c2nc(-c3cccc4ccccc34)nc(-n3c4ccccc4c4ccc5c6ccccc6n(-c6ccc(-c7cccc8nc(-c9ccccc9)oc78)cc6)c5c43)n2)cc1 ; c1ccc(-c2nc(-c3ccccc3-c3ccccc3)nc(-n3c4ccccc4c4ccc5c6ccccc6n(-c6ccc(-c7cccc8nc(-c9ccccc9)oc78)cc6)c5c43)n2)cc1 ; c1ccc(-c2cc(-c3ccccc3)cc(-c3nc(-c4ccccc4)nc(-n4c5ccccc5c5ccc6c7ccccc7n(-c7ccc(-c8cccc9nc(-c%10ccccc%10)oc89)cc7)c6c54)n3)c2)cc1 ; c1ccc(-c2nc(-c3ccc4c(c3)sc3ccccc34)nc(-n3c4ccccc4c4ccc5c6ccccc6n(-c6ccc(-c7cccc8nc(-c9ccccc9)oc78)cc6)c5c43)n2)cc1]

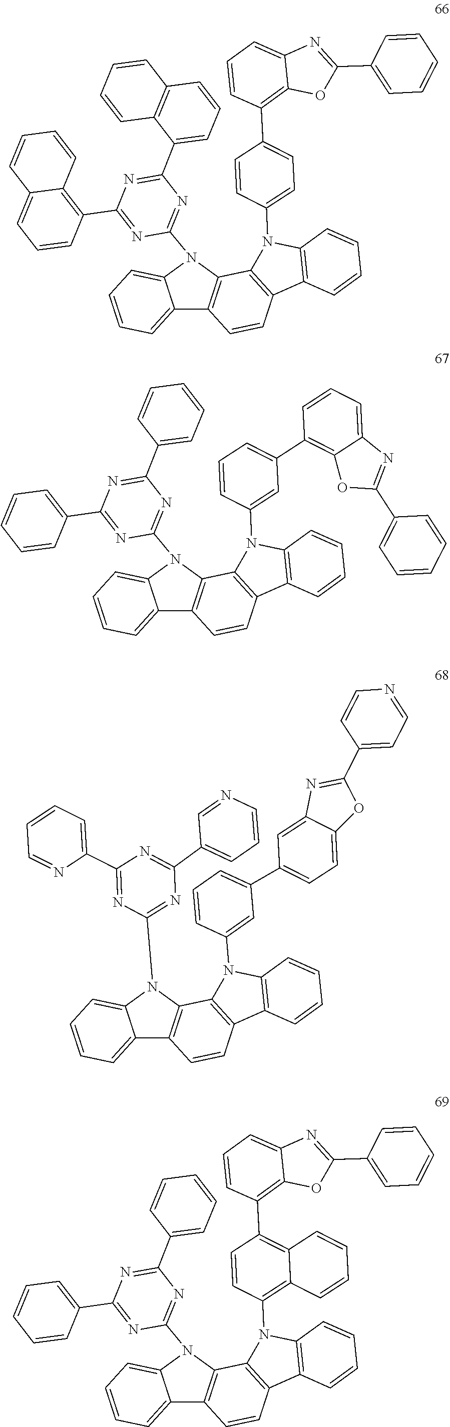 [SMILES: c1ccc(-c2nc3cccc(-c4ccc(-n5c6ccccc6c6ccc7c8ccccc8n(-c8nc(-c9cccc%10ccccc9%10)nc(-c9cccc%10ccccc9%10)n8)c7c65)cc4)c3o2)cc1 ; c1ccc(-c2nc(-c3ccccc3)nc(-n3c4ccccc4c4ccc5c6ccccc6n(-c6cccc(-c7cccc8nc(-c9ccccc9)oc78)c6)c5c43)n2)cc1 ; c1ccc(-c2nc(-c3cccnc3)nc(-n3c4ccccc4c4ccc5c6ccccc6n(-c6cccc(-c7ccc8oc(-c9ccncc9)nc8c7)c6)c5c43)n2)nc1 ; c1ccc(-c2nc(-c3ccccc3)nc(-n3c4ccccc4c4ccc5c6ccccc6n(-c6ccc(-c7cccc8nc(-c9ccccc9)oc78)c7ccccc67)c5c43)n2)cc1]

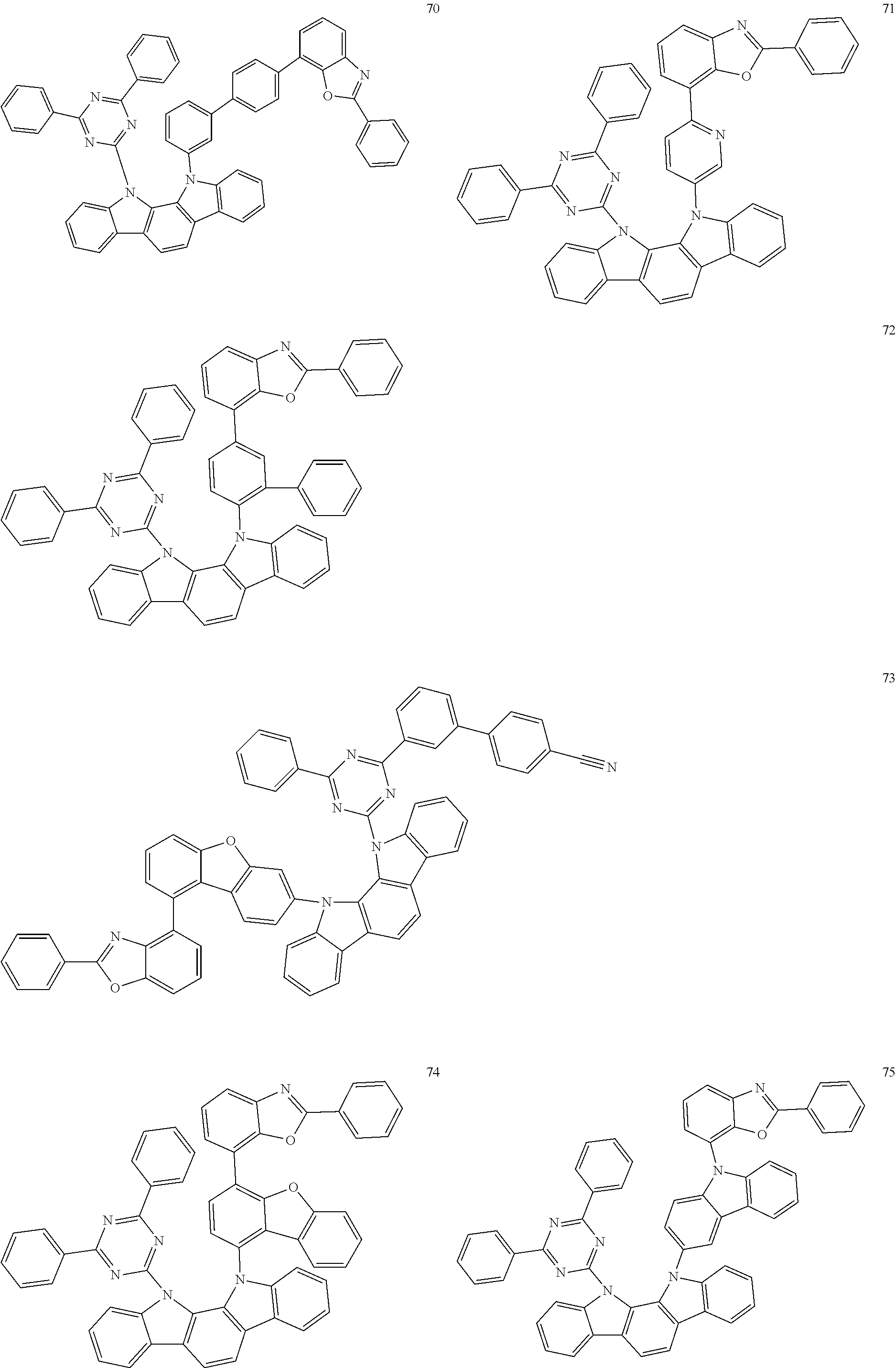

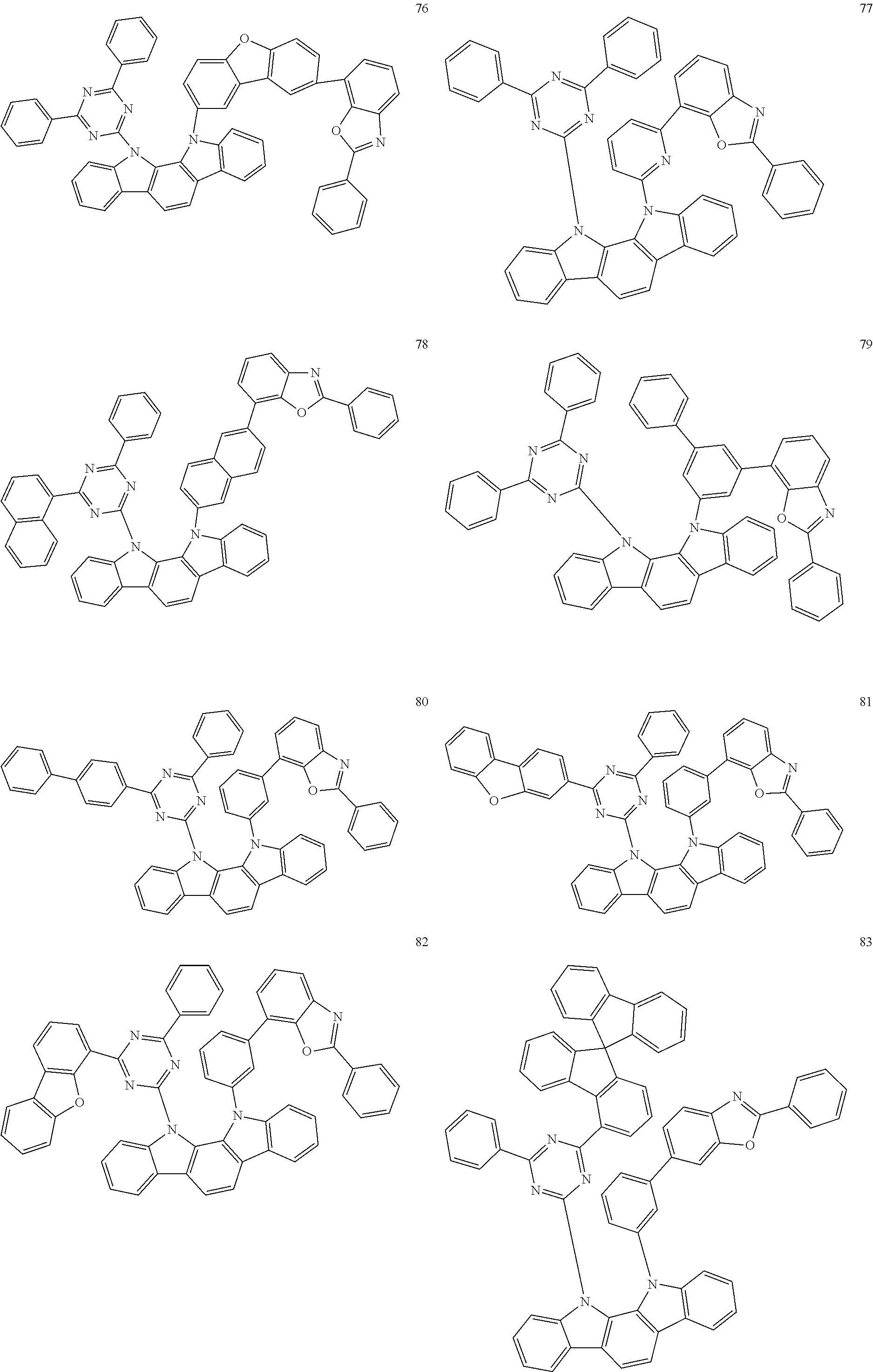

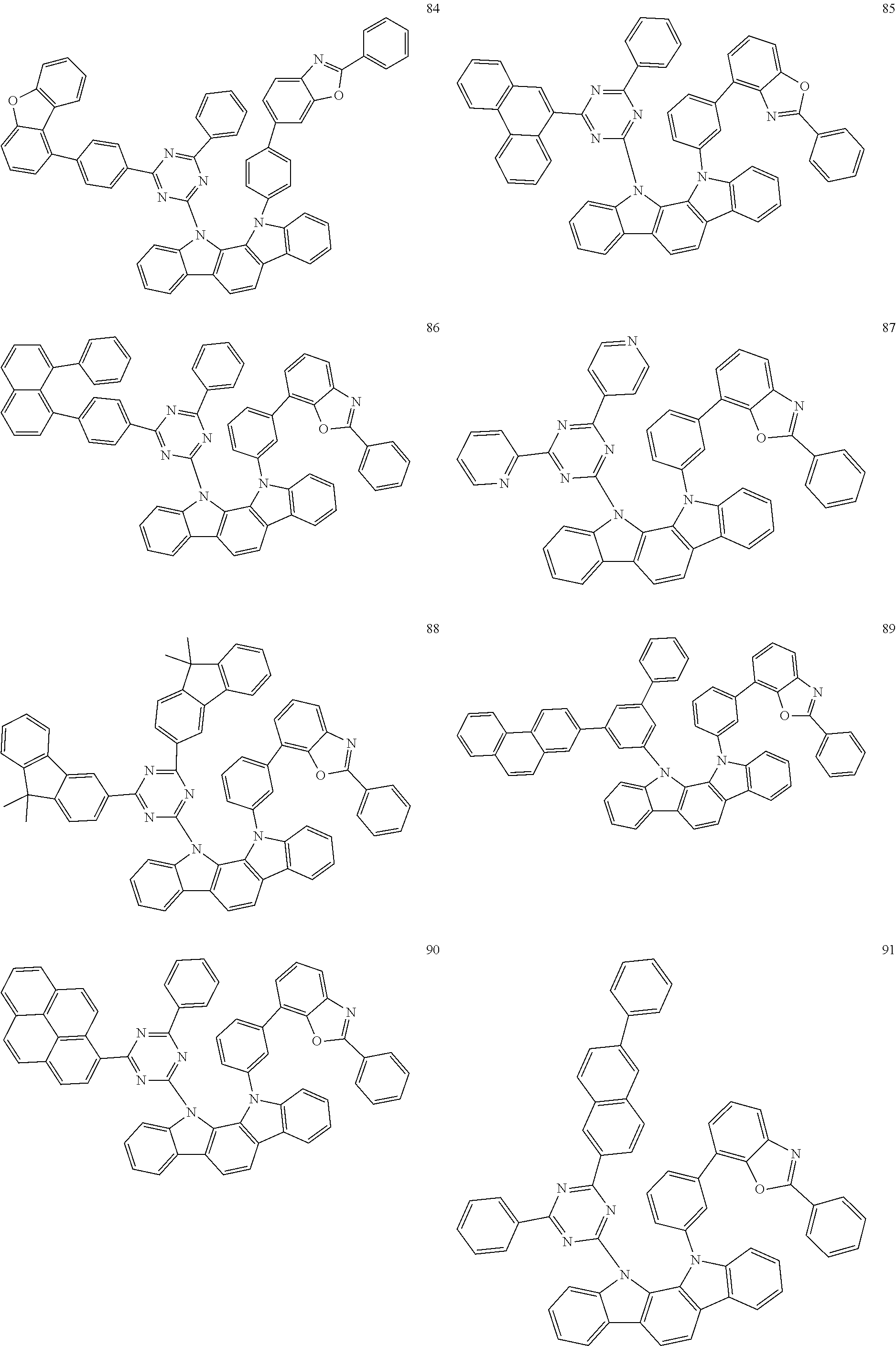

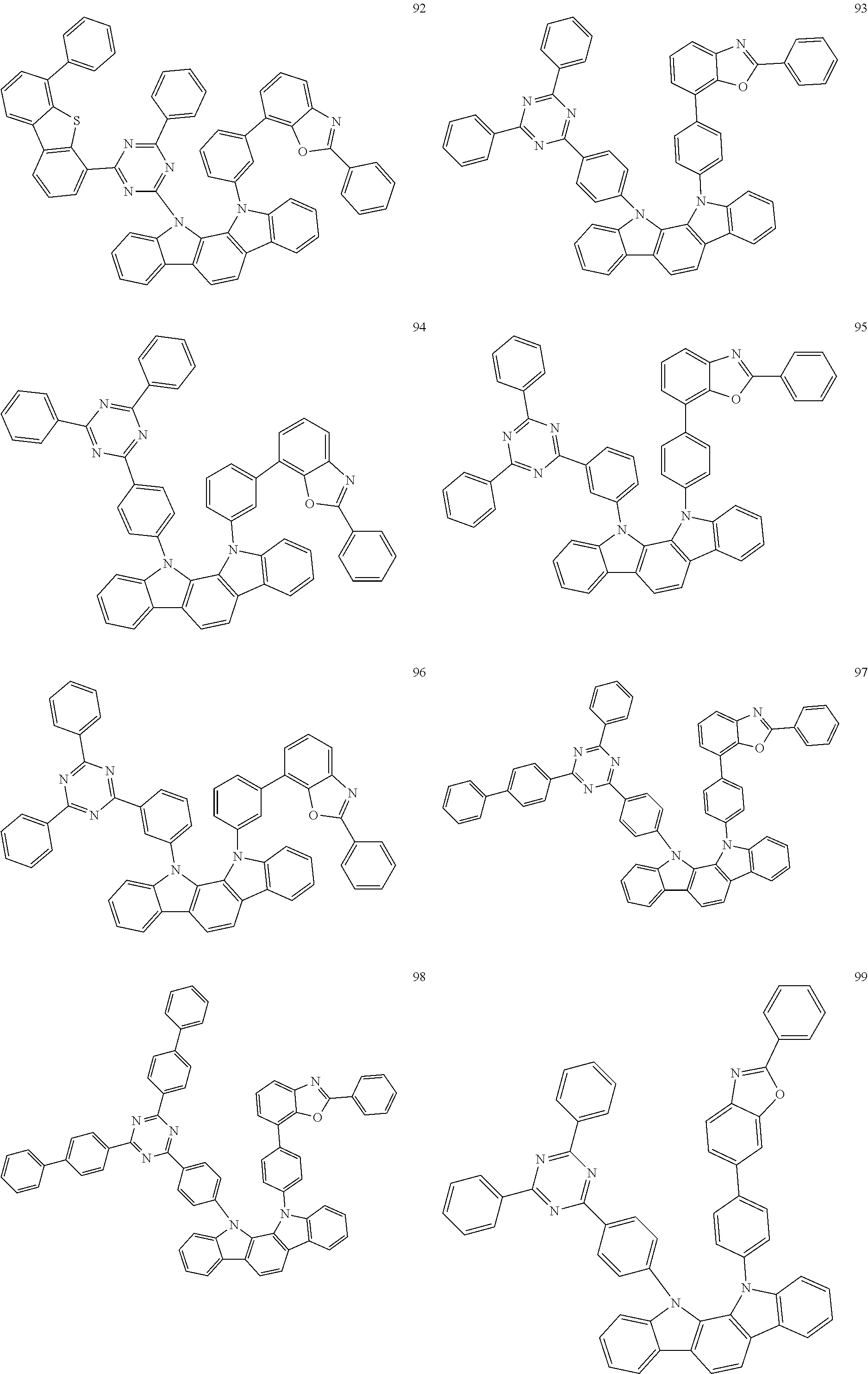

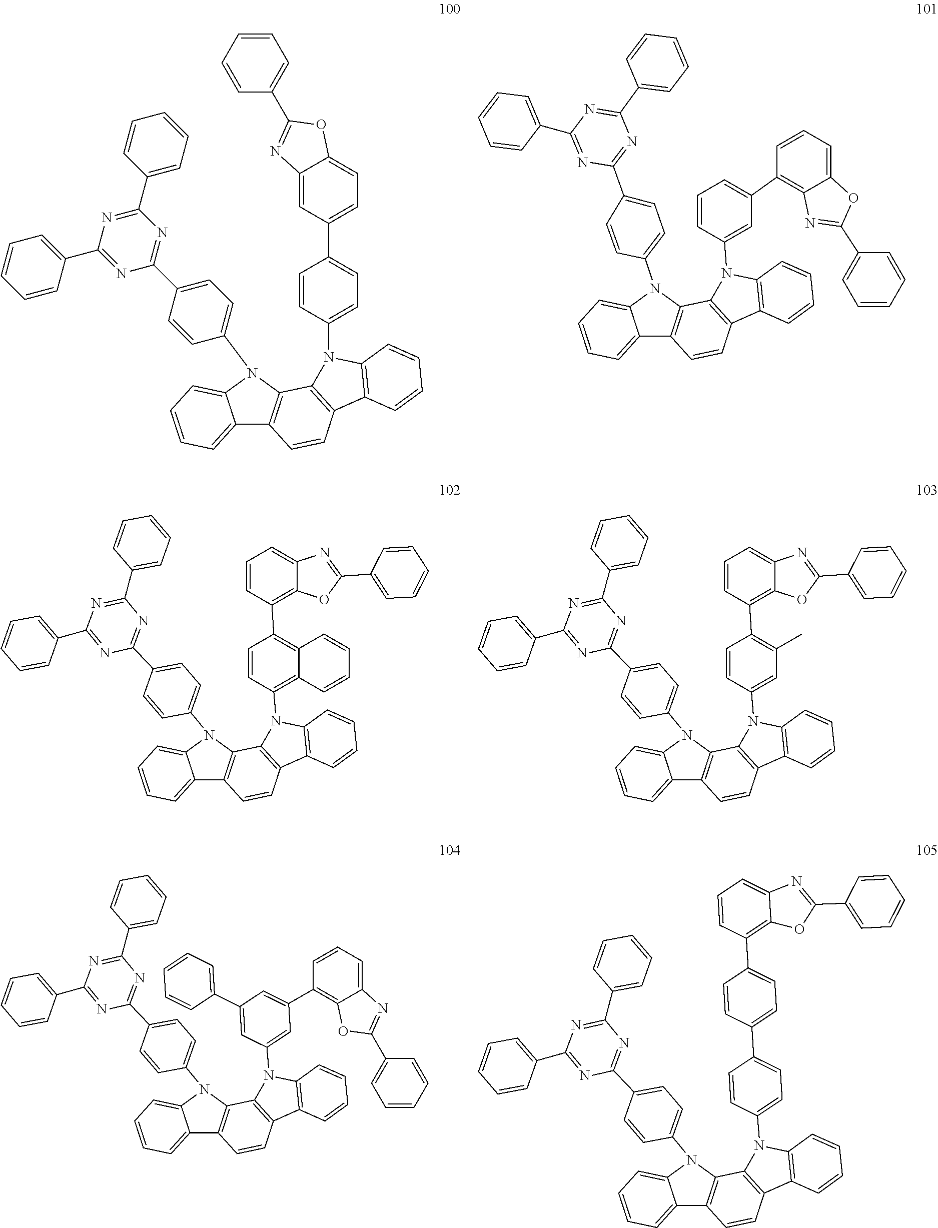

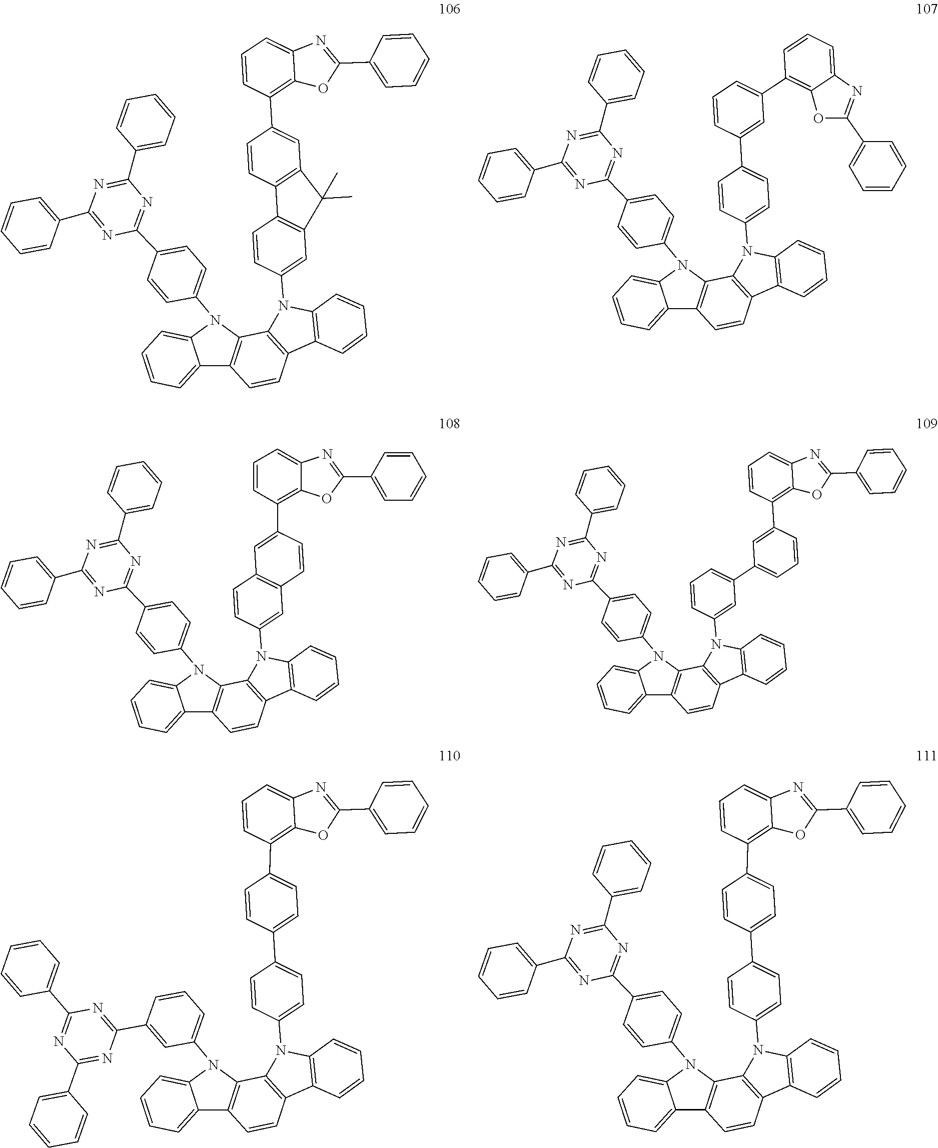

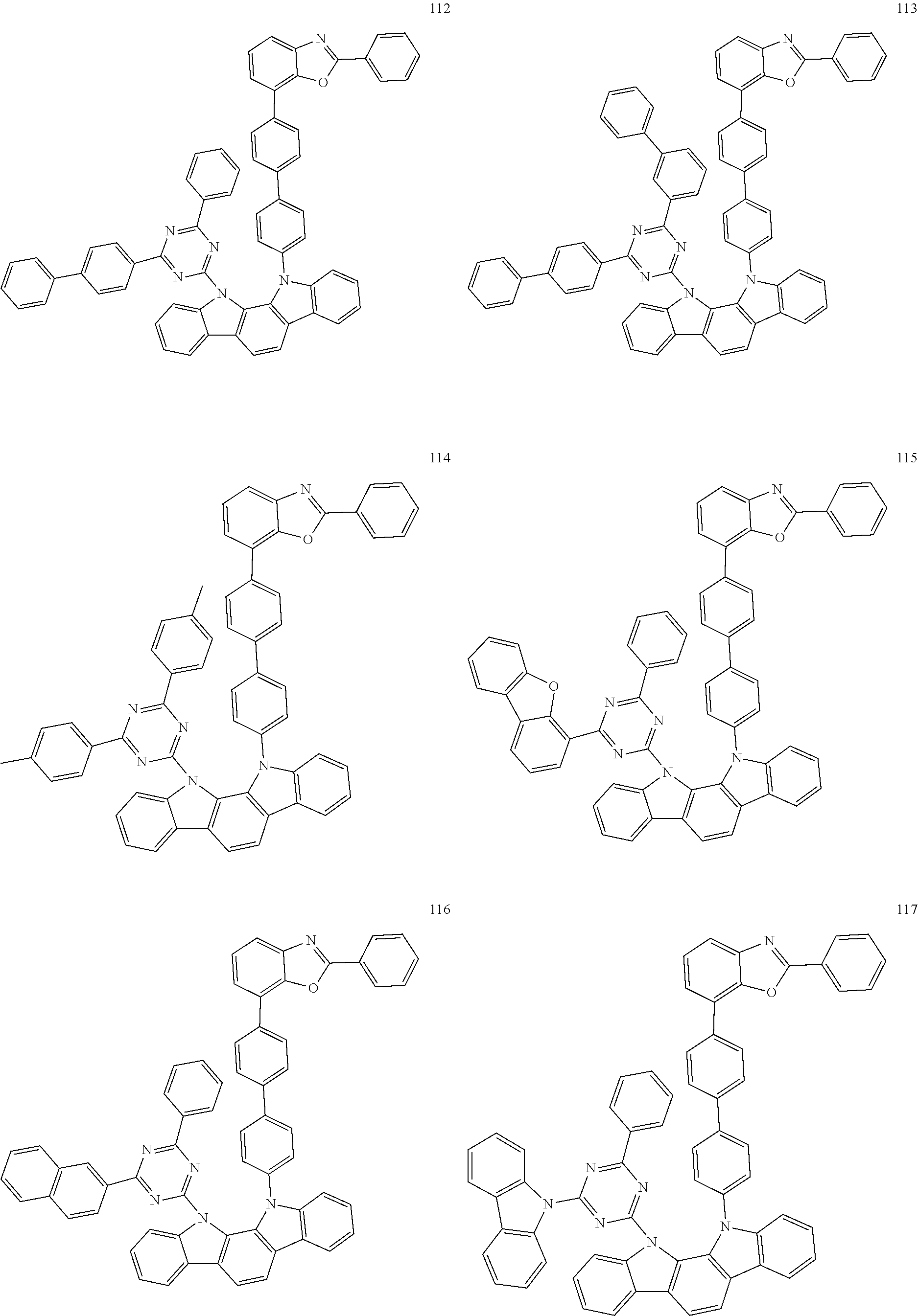

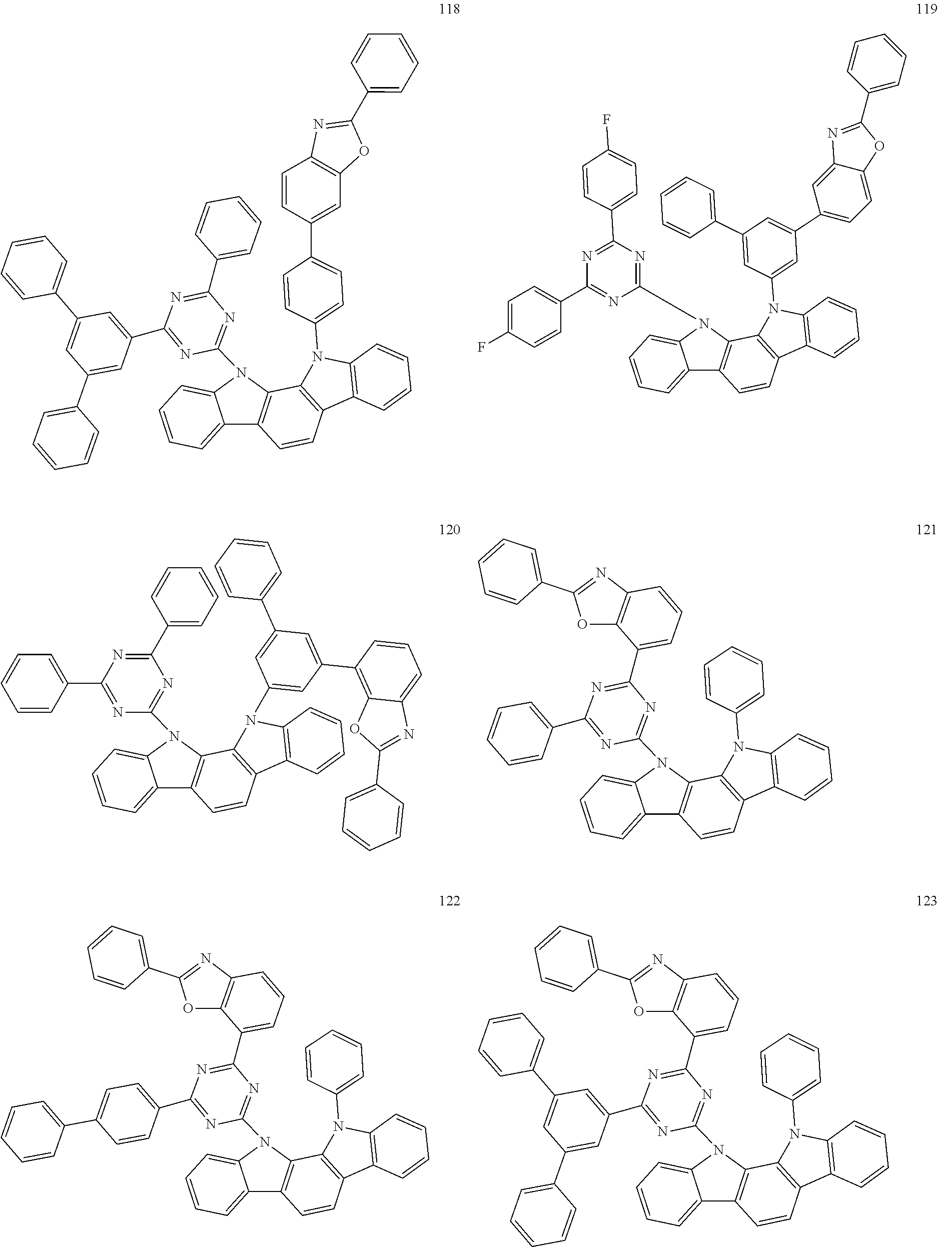

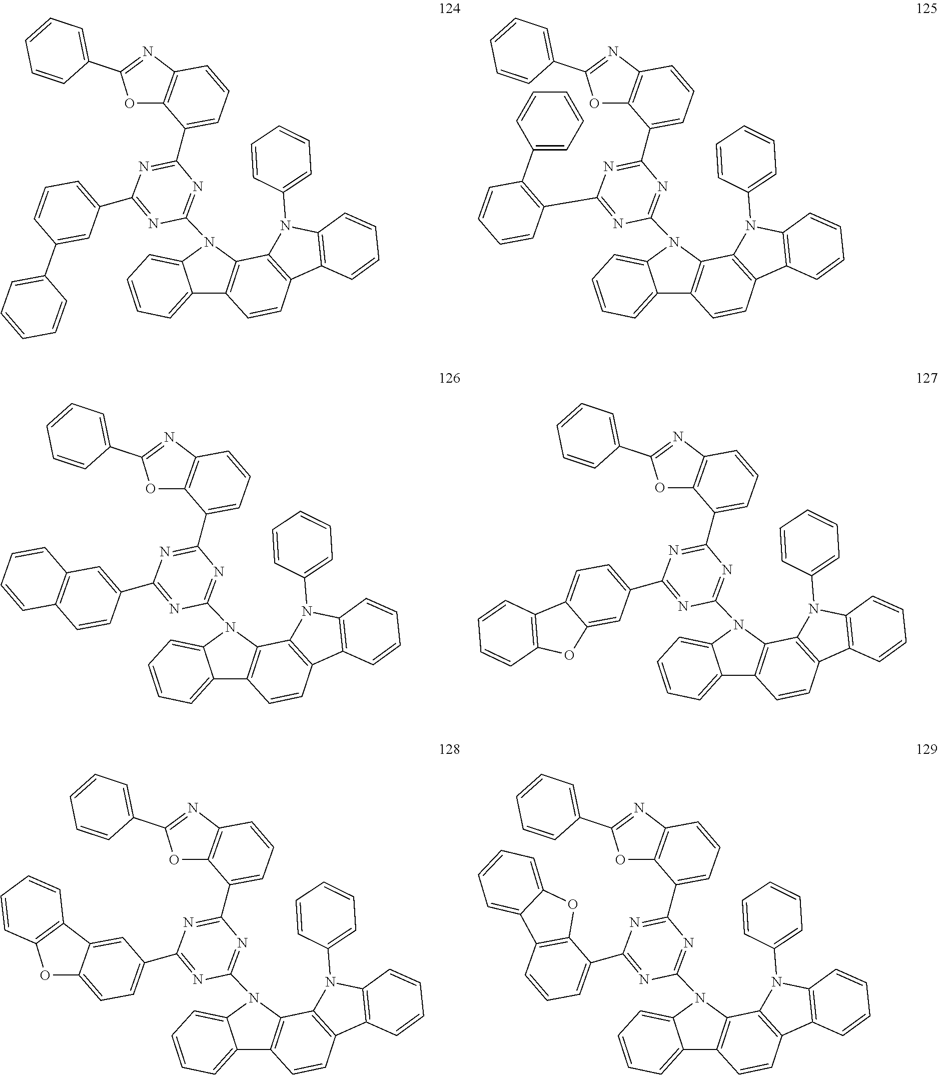

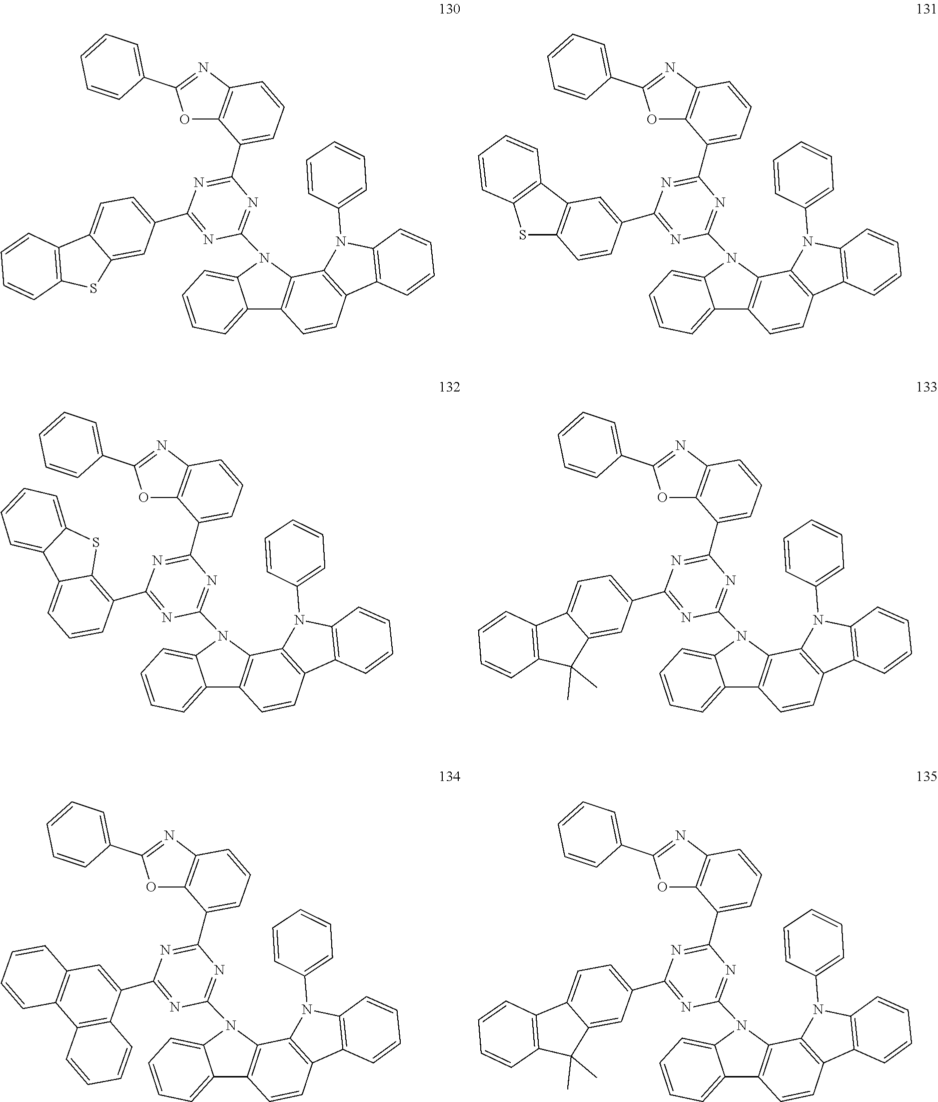

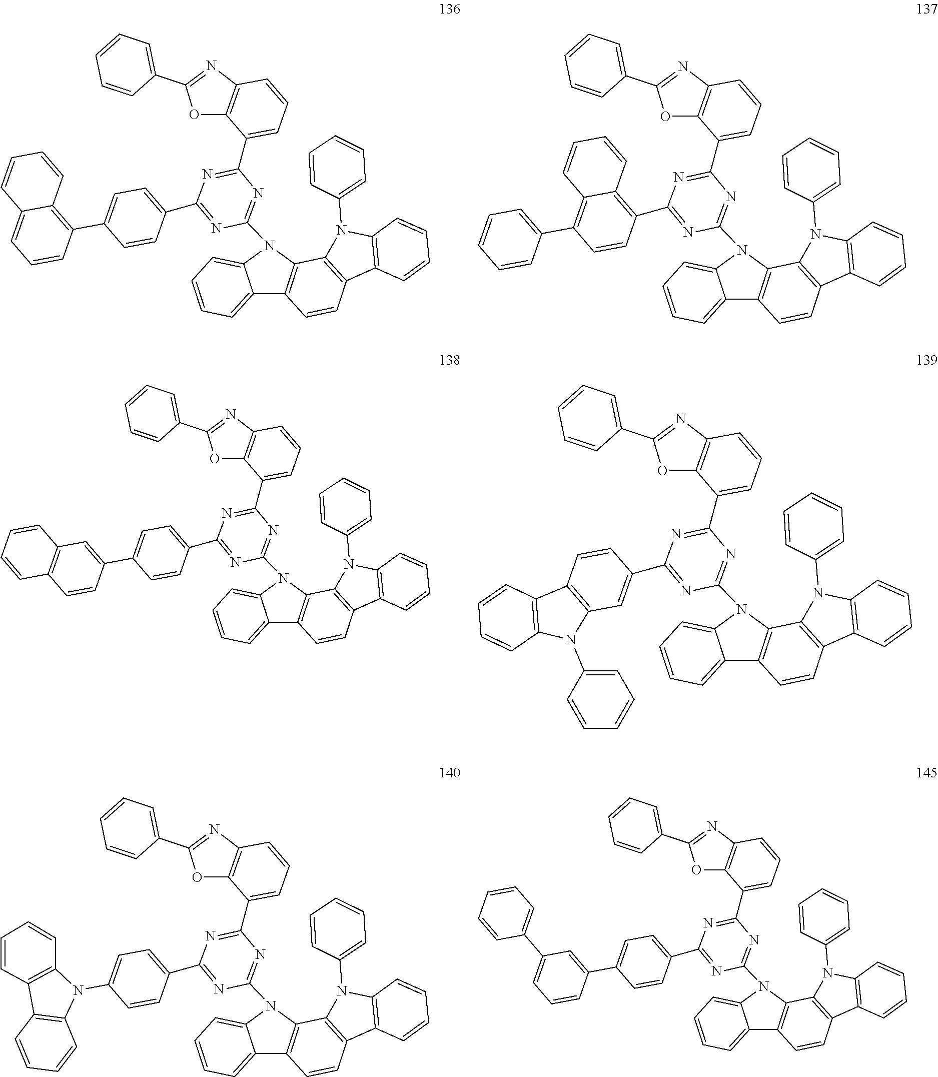

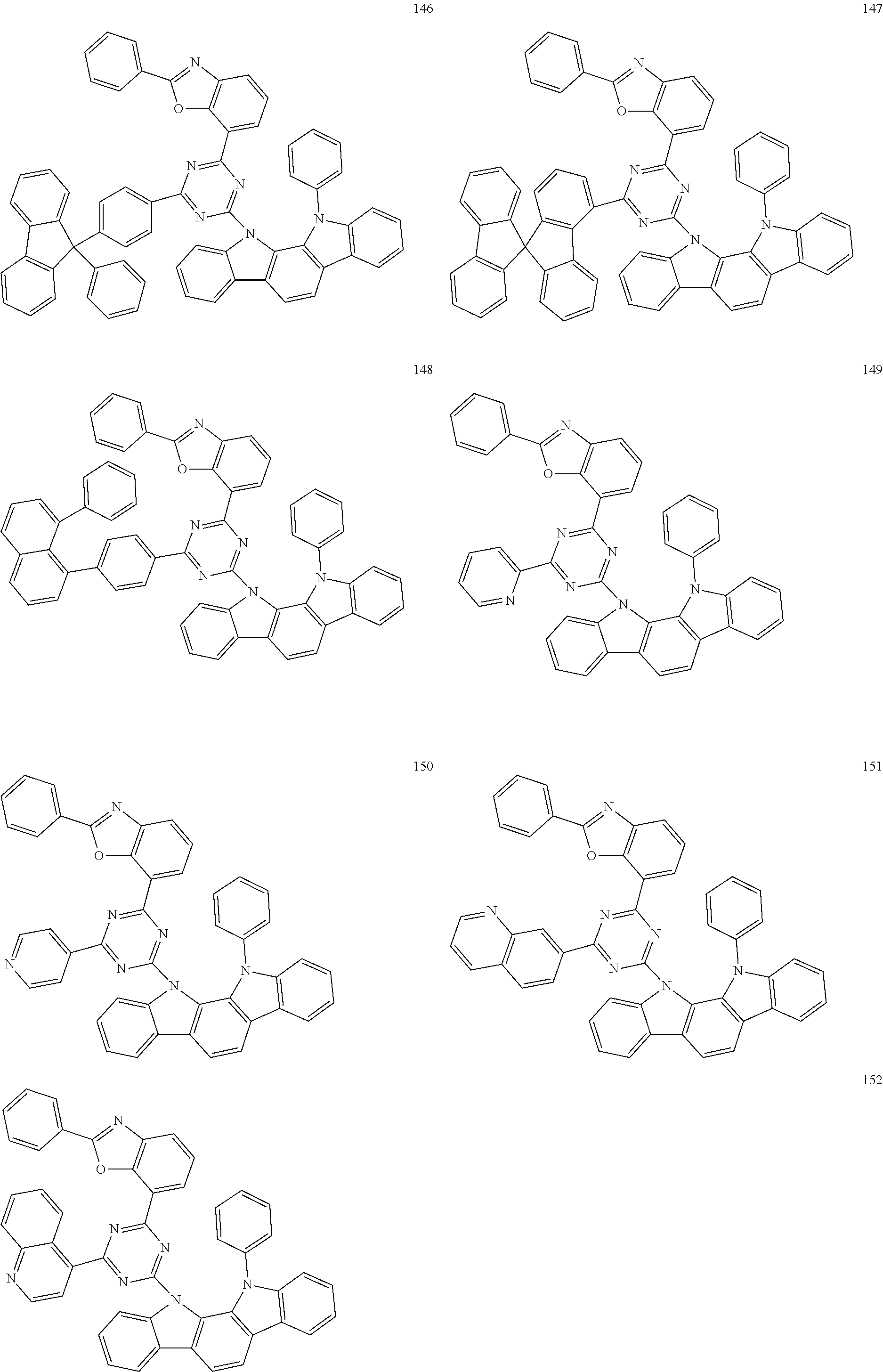

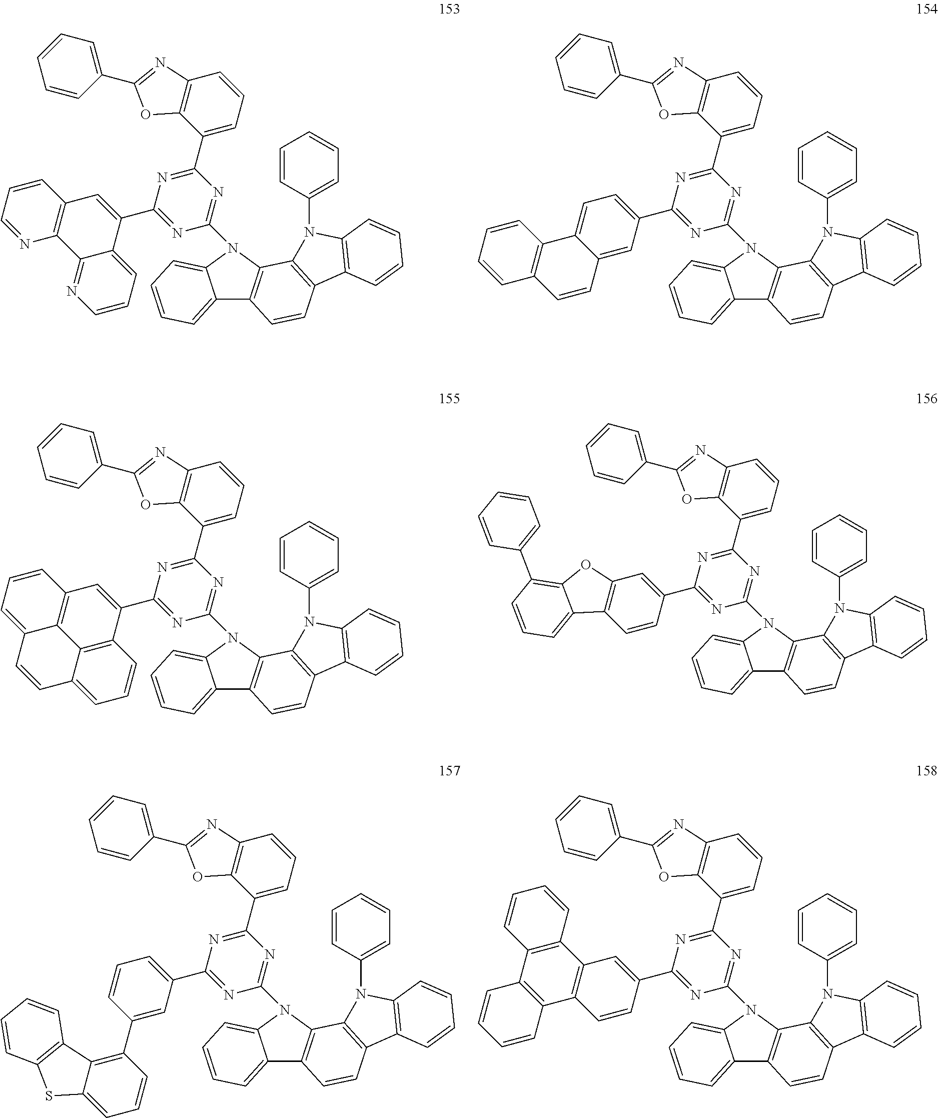

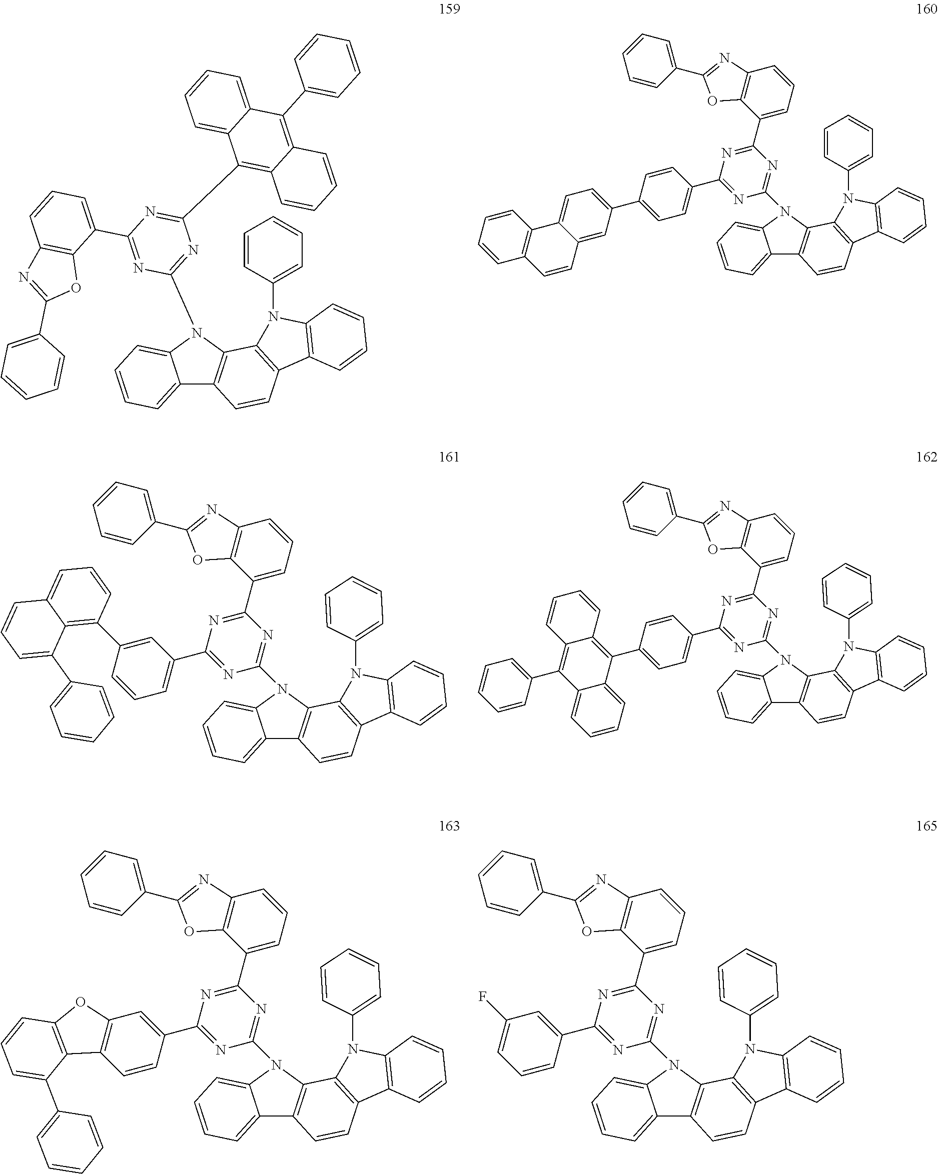

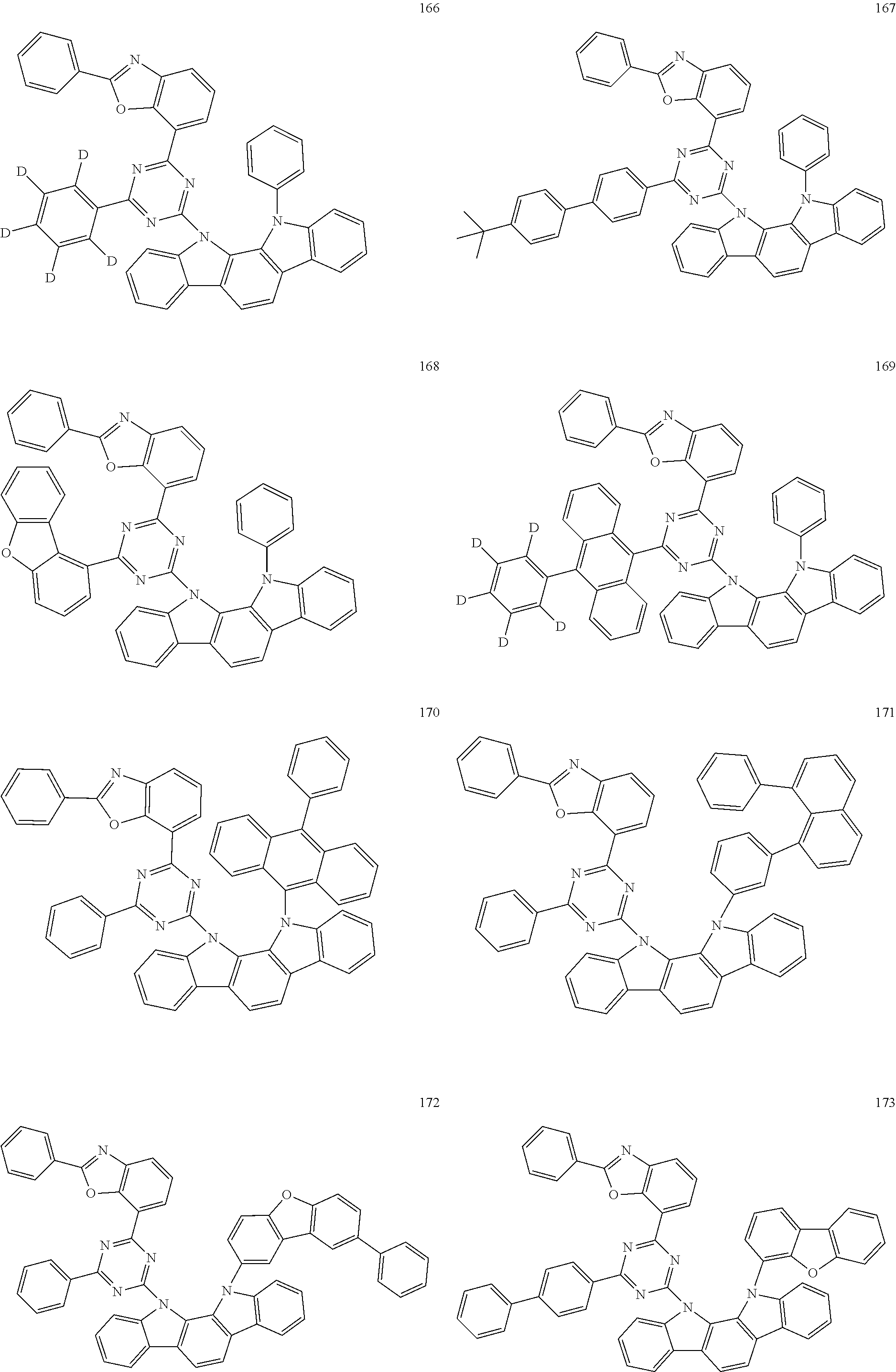

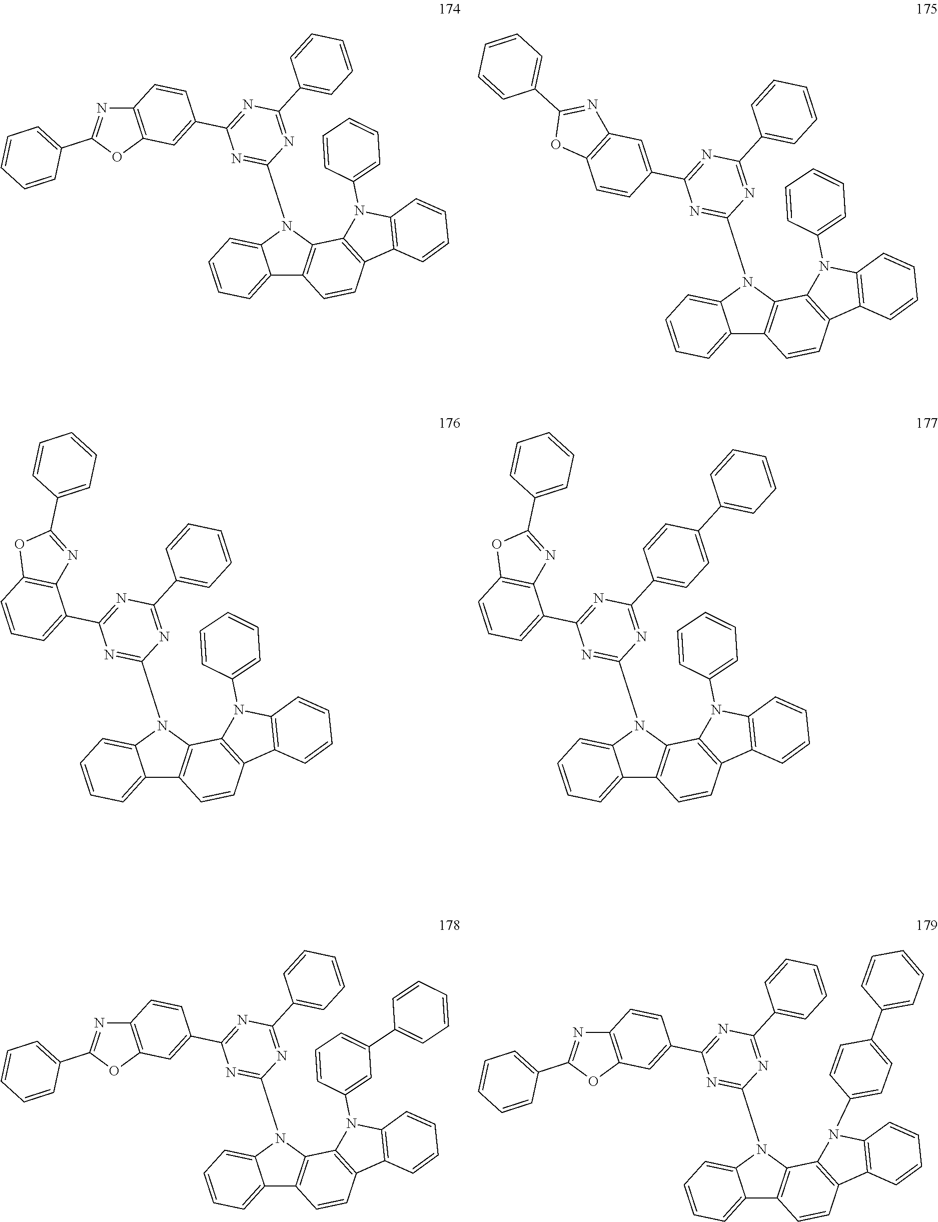

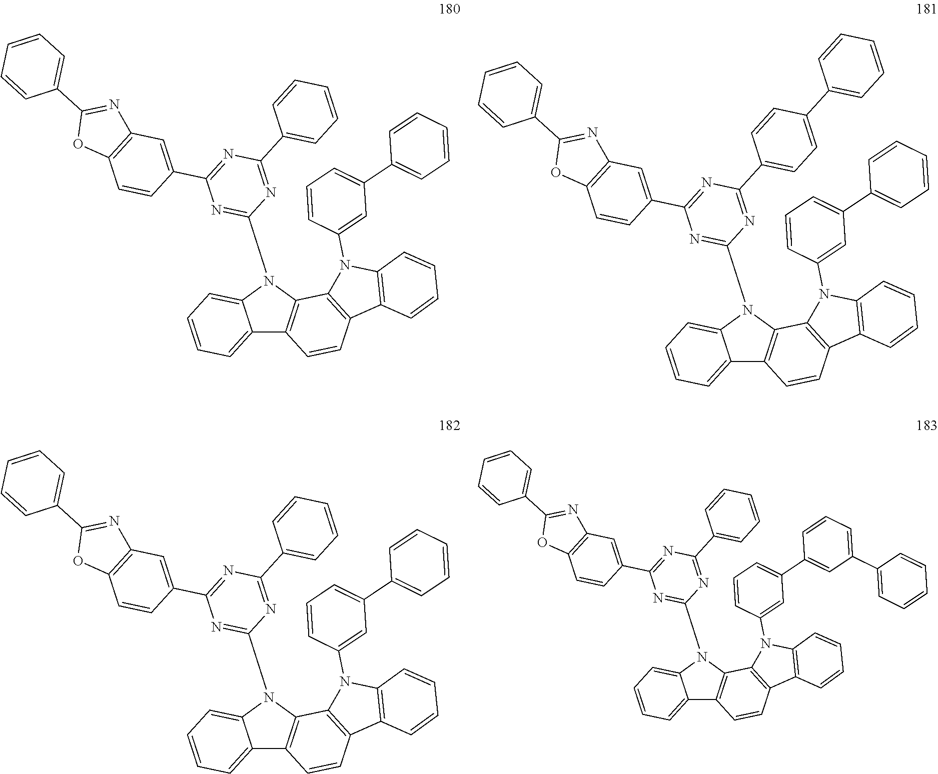

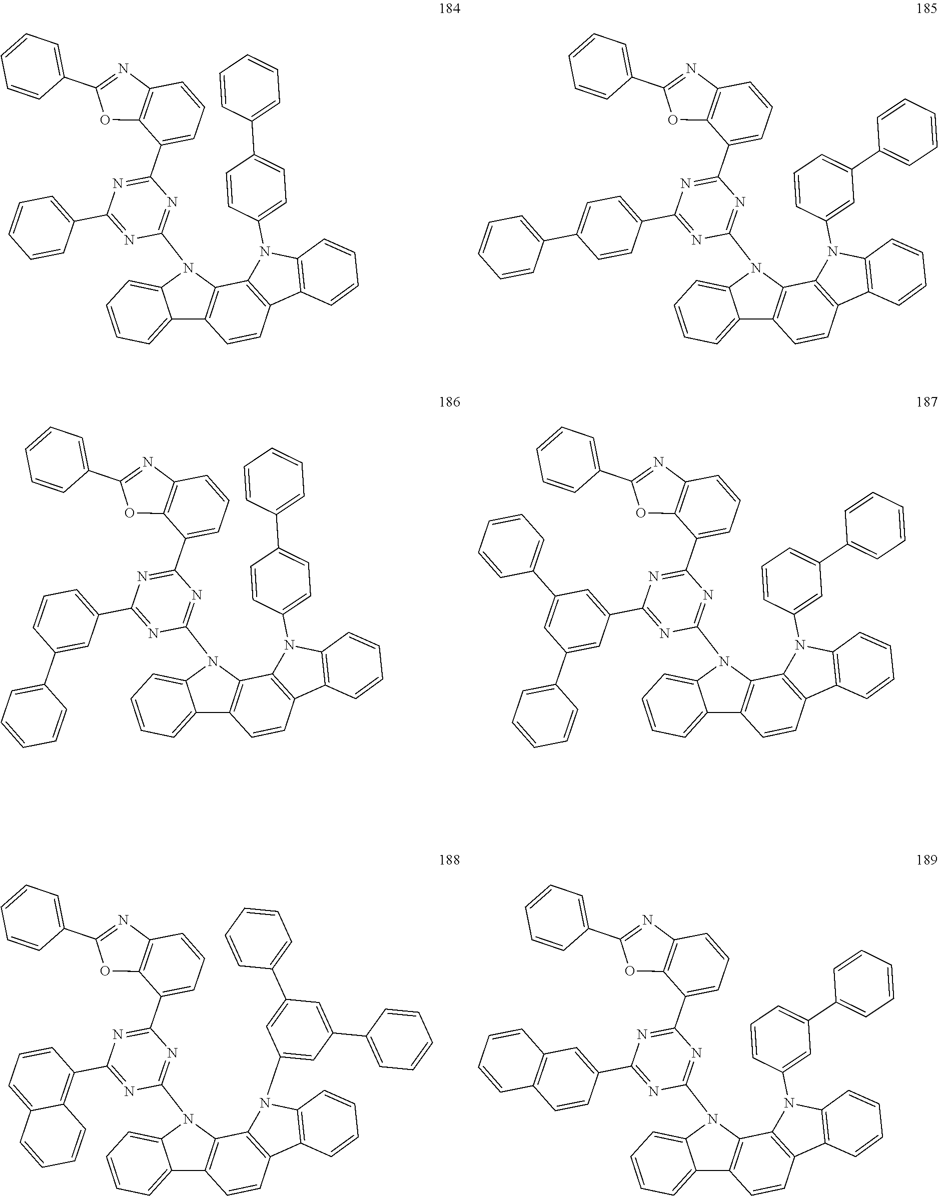

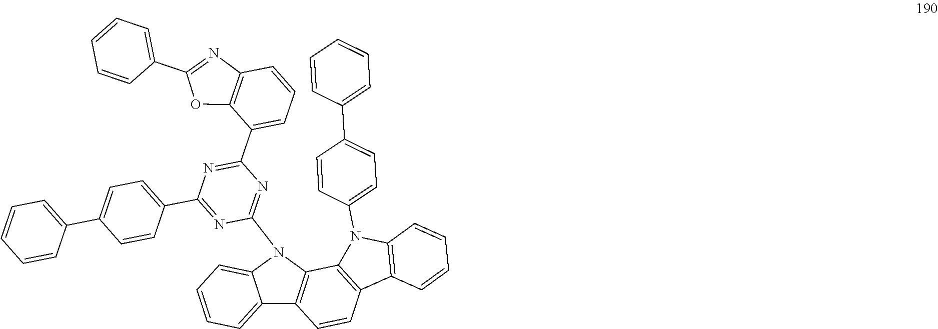 [SMILES: c1ccc(-c2ccc(-c3nc(-c4cccc5nc(-c6ccccc6)oc45)nc(-n4c5ccccc5c5ccc6c7ccccc7n(-c7ccc(-c8ccccc8)cc7)c6c54)n3)cc2)cc1]

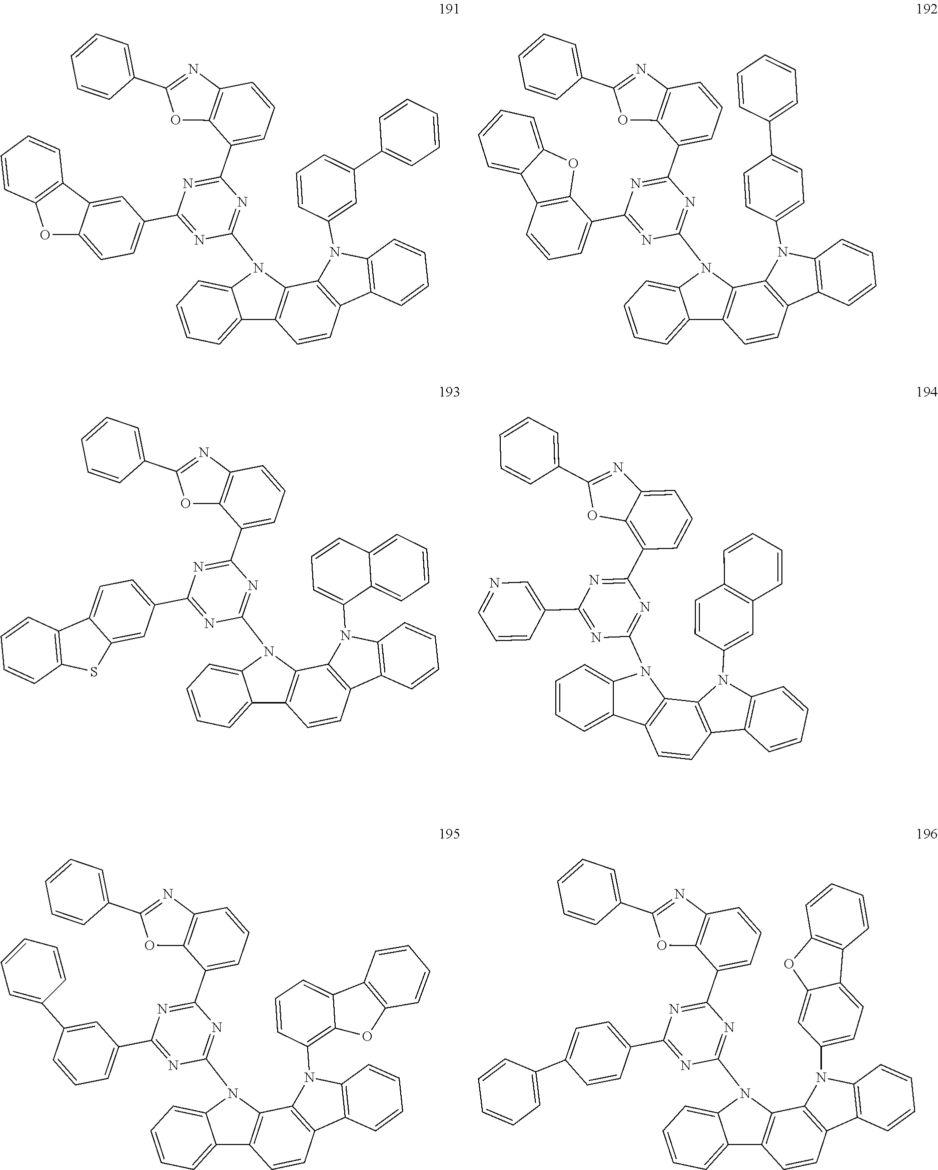

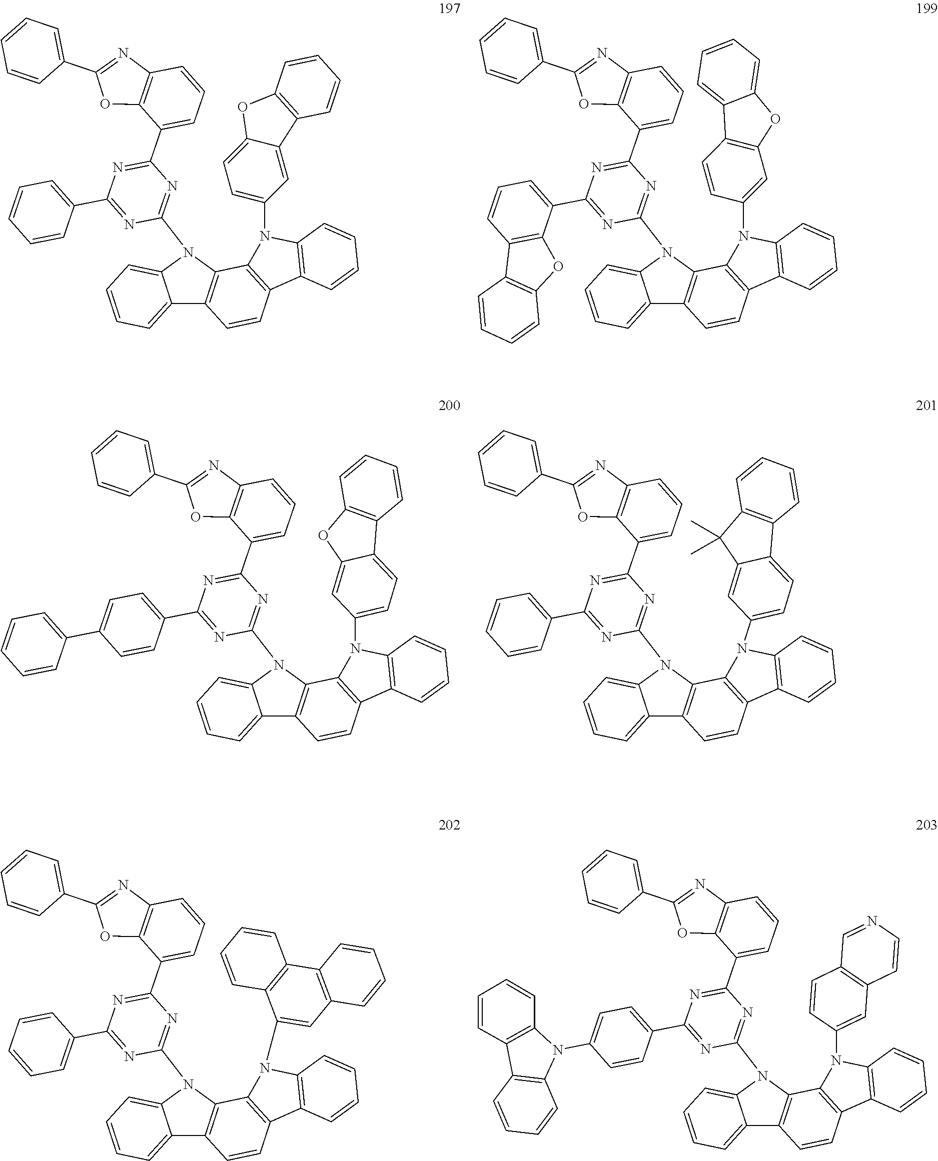

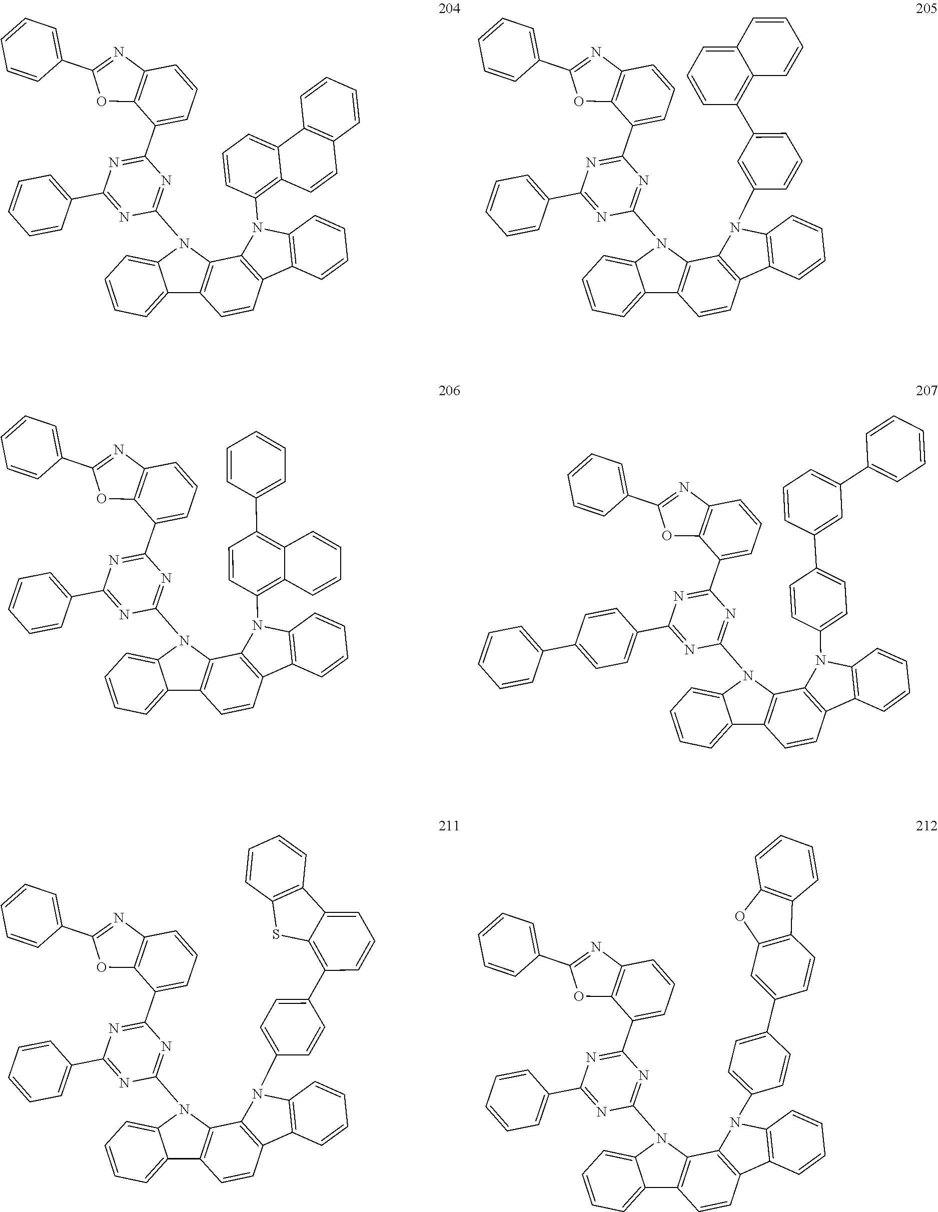

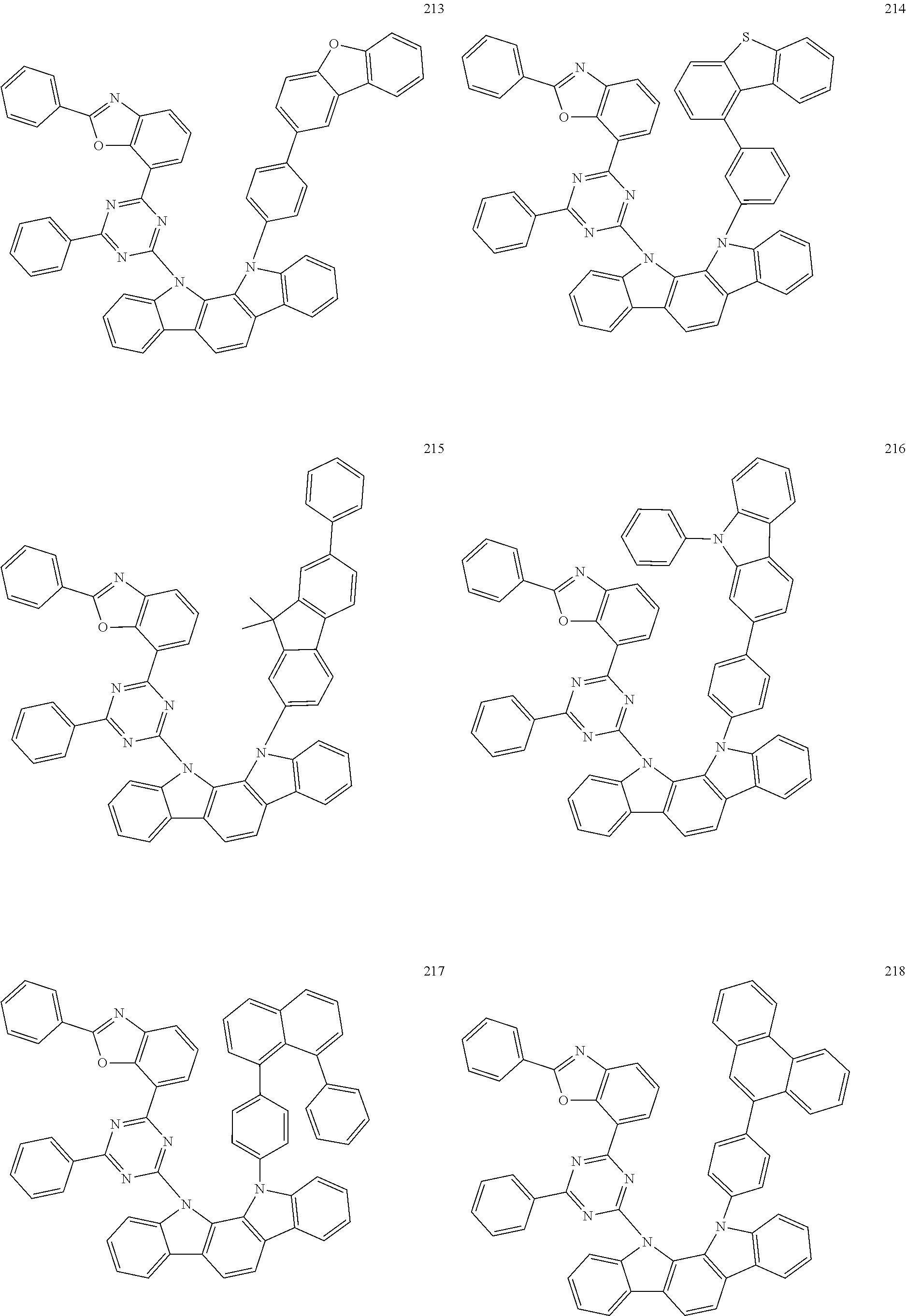

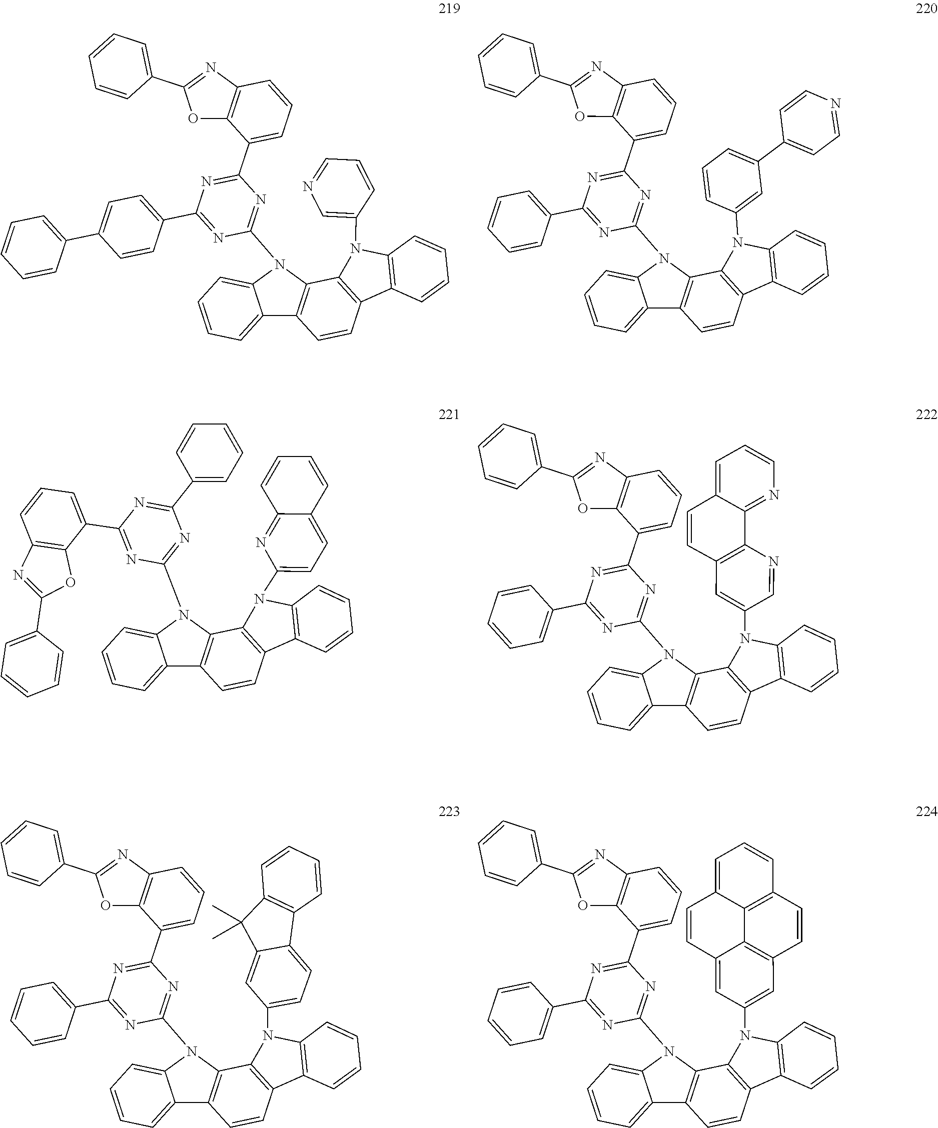

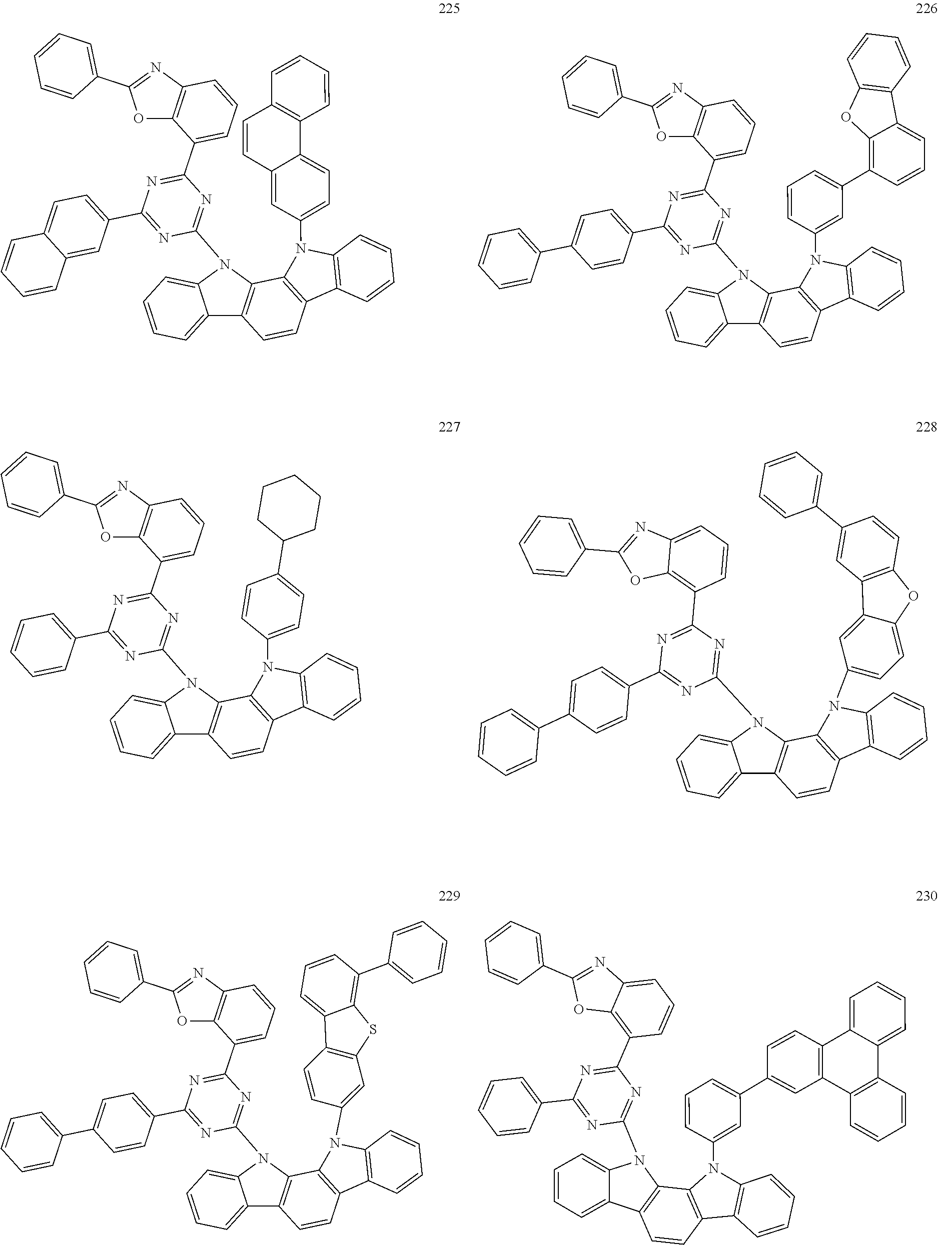

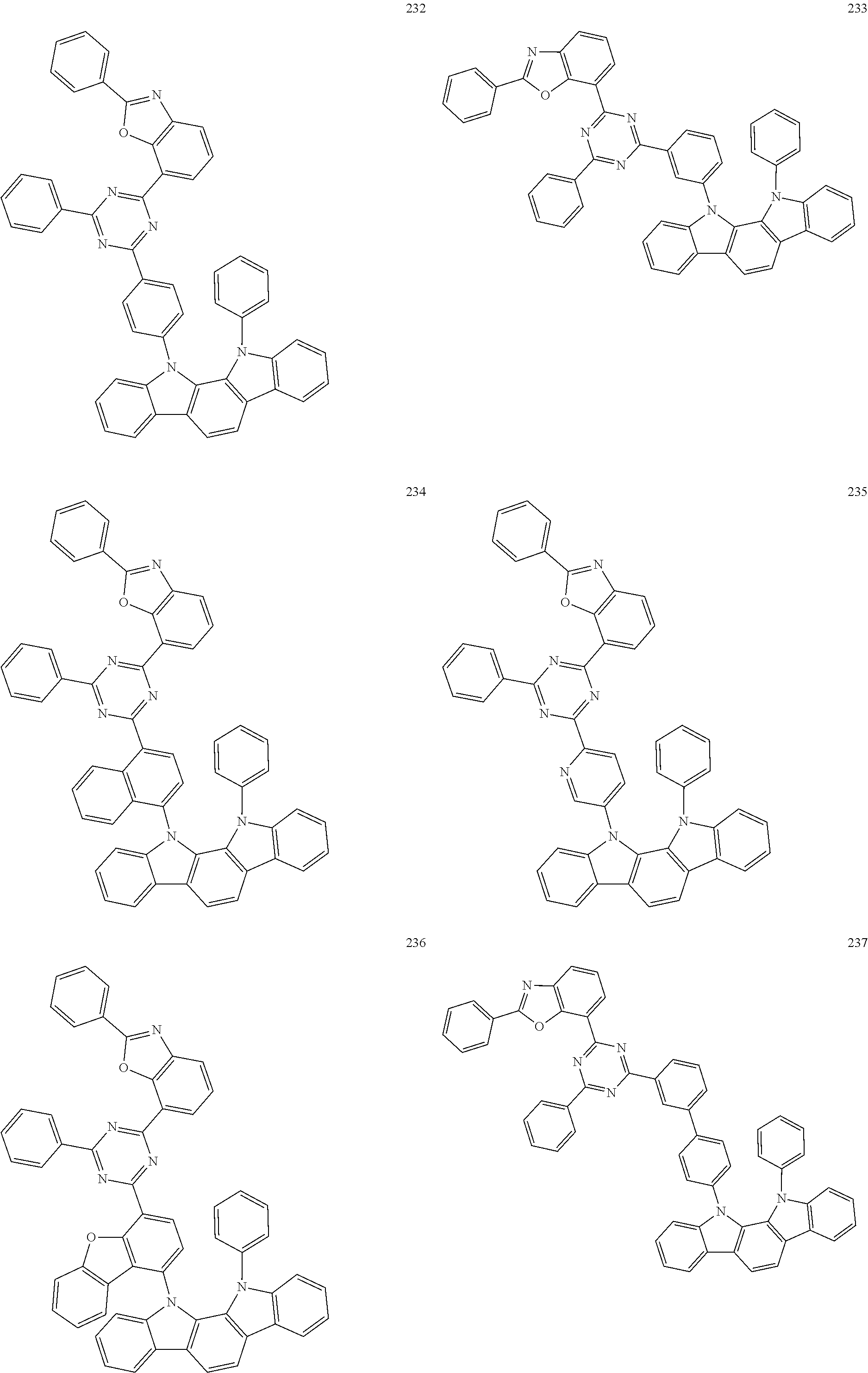

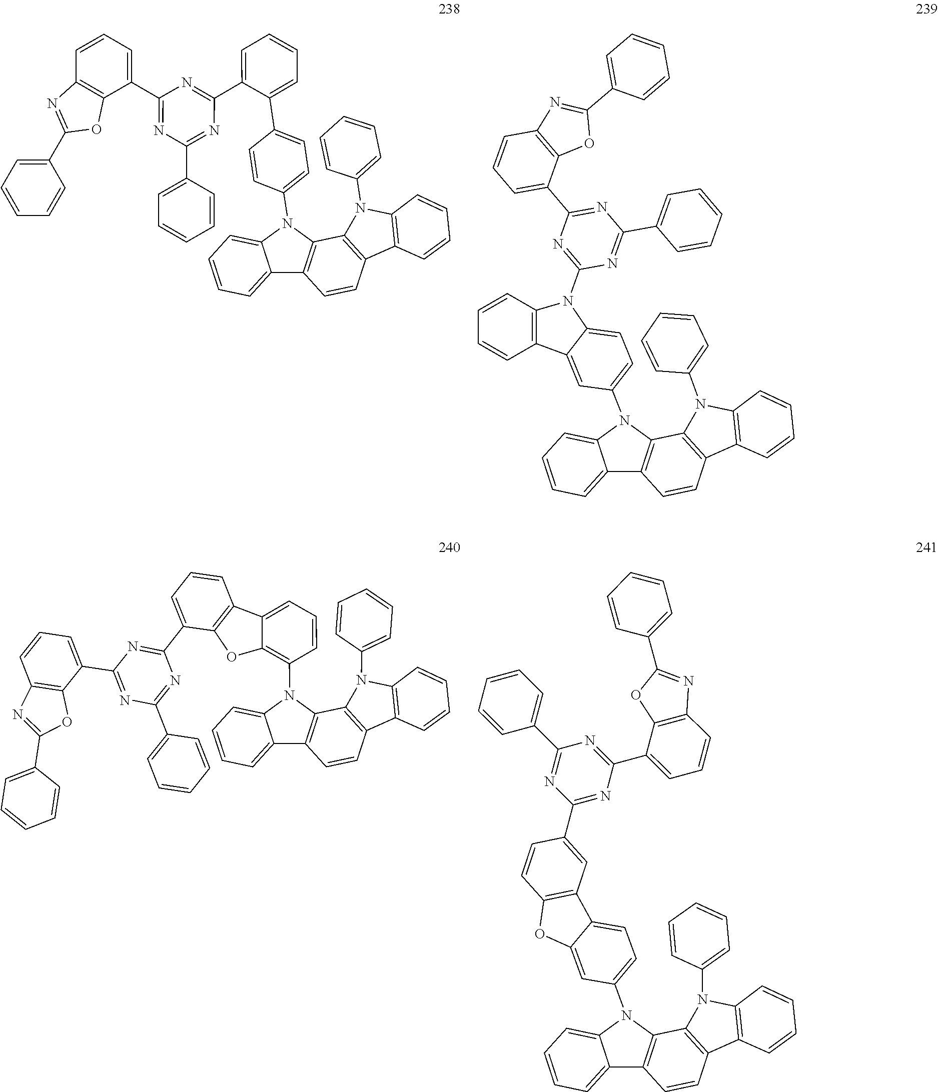

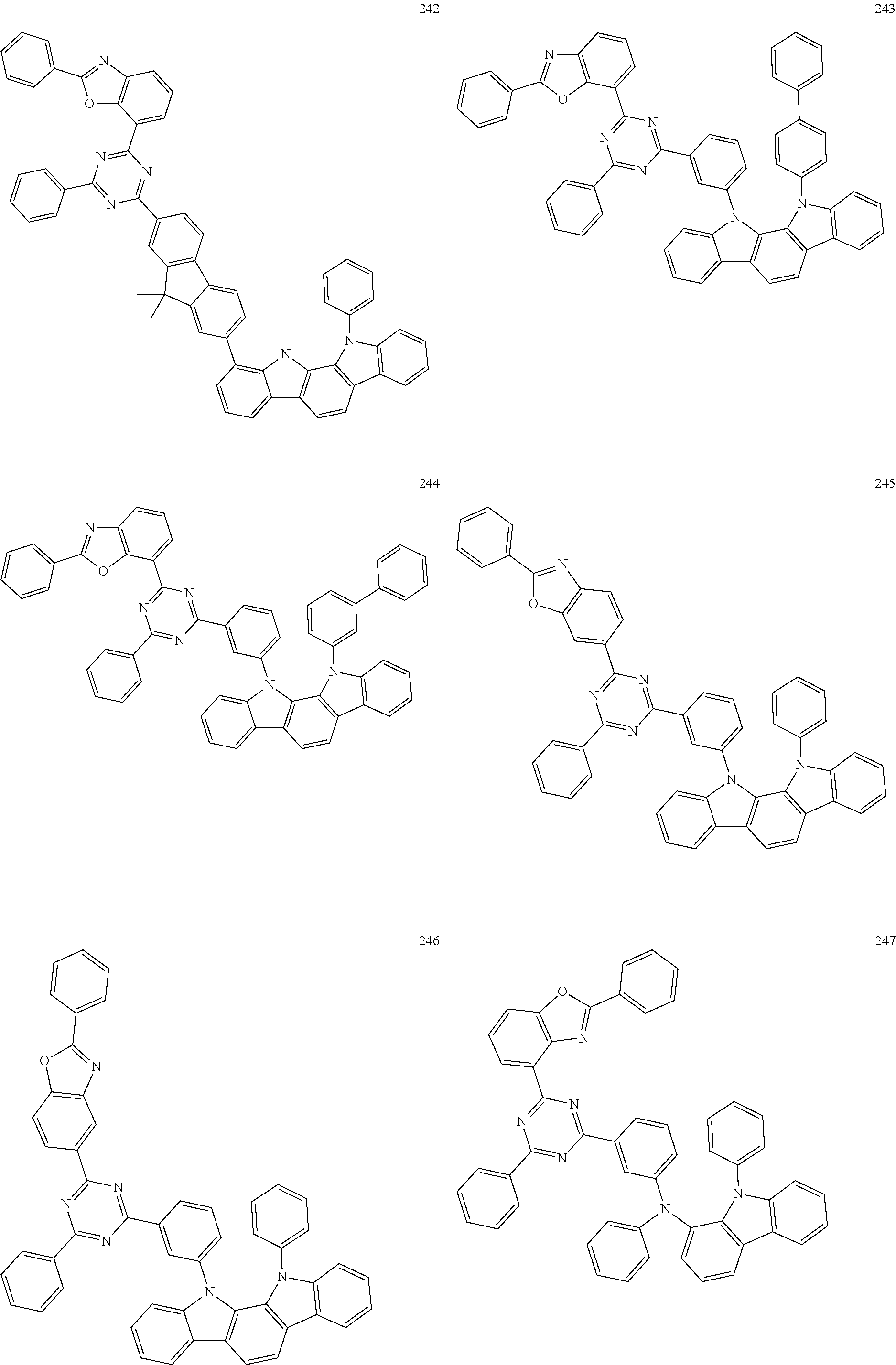

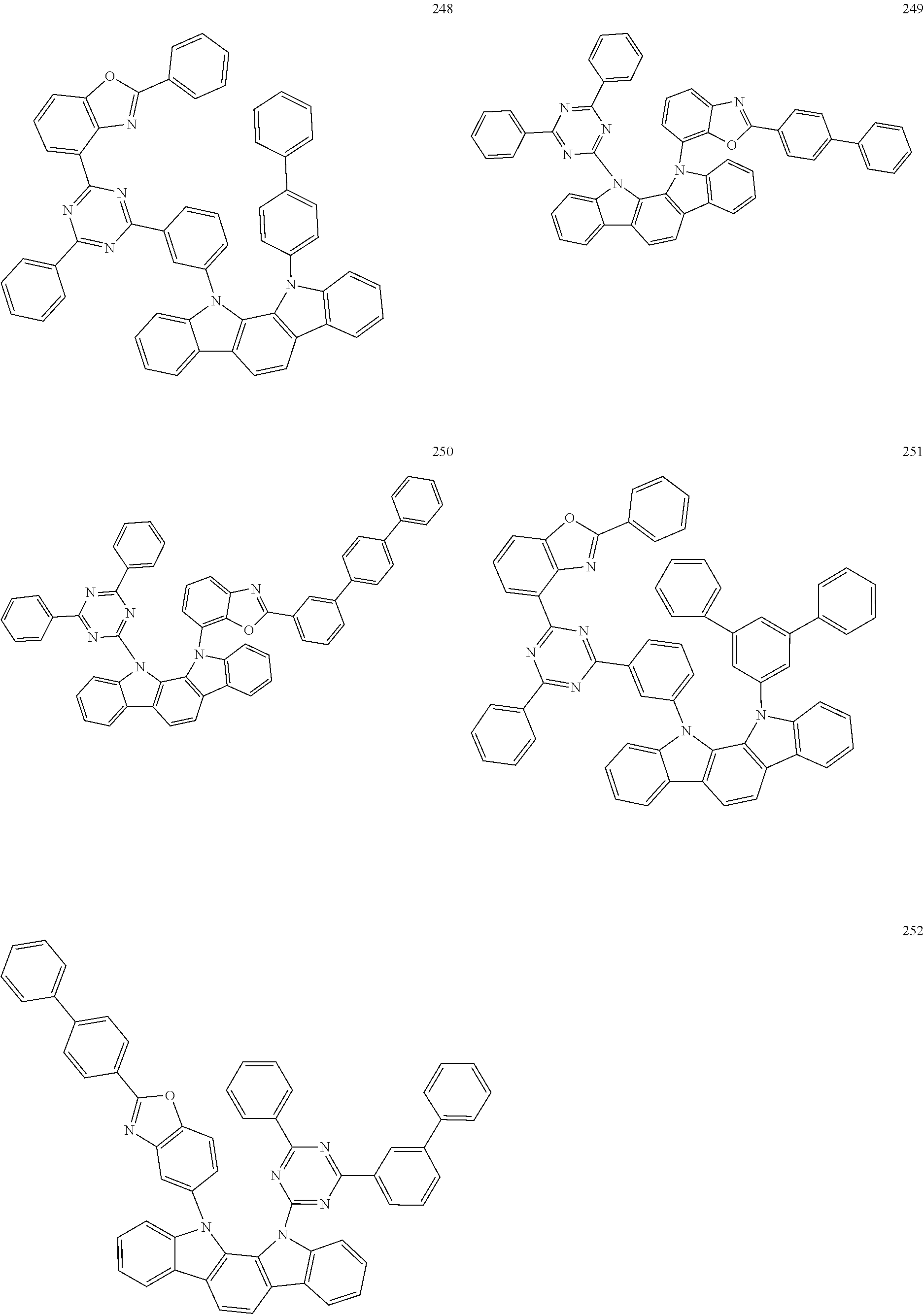

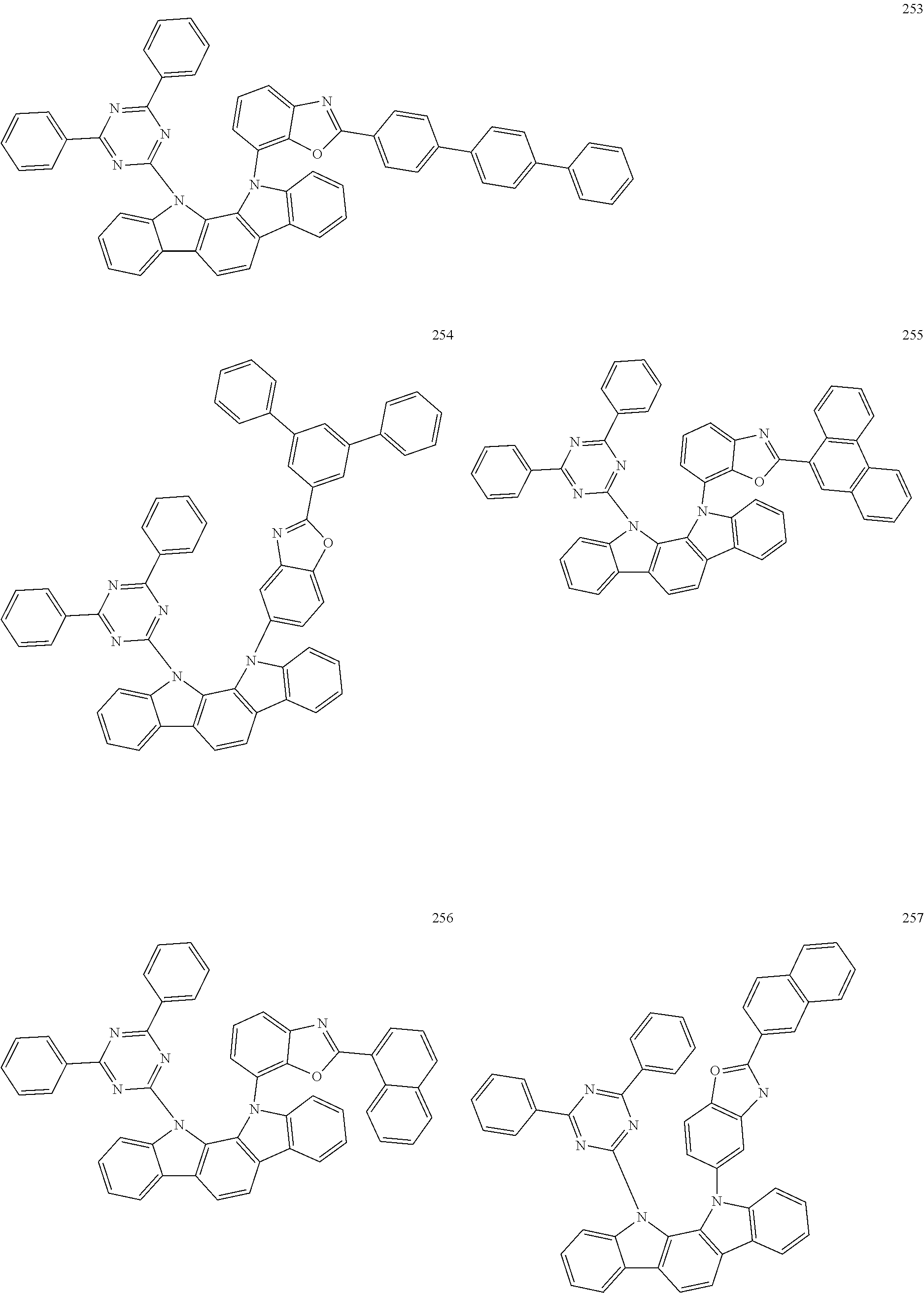

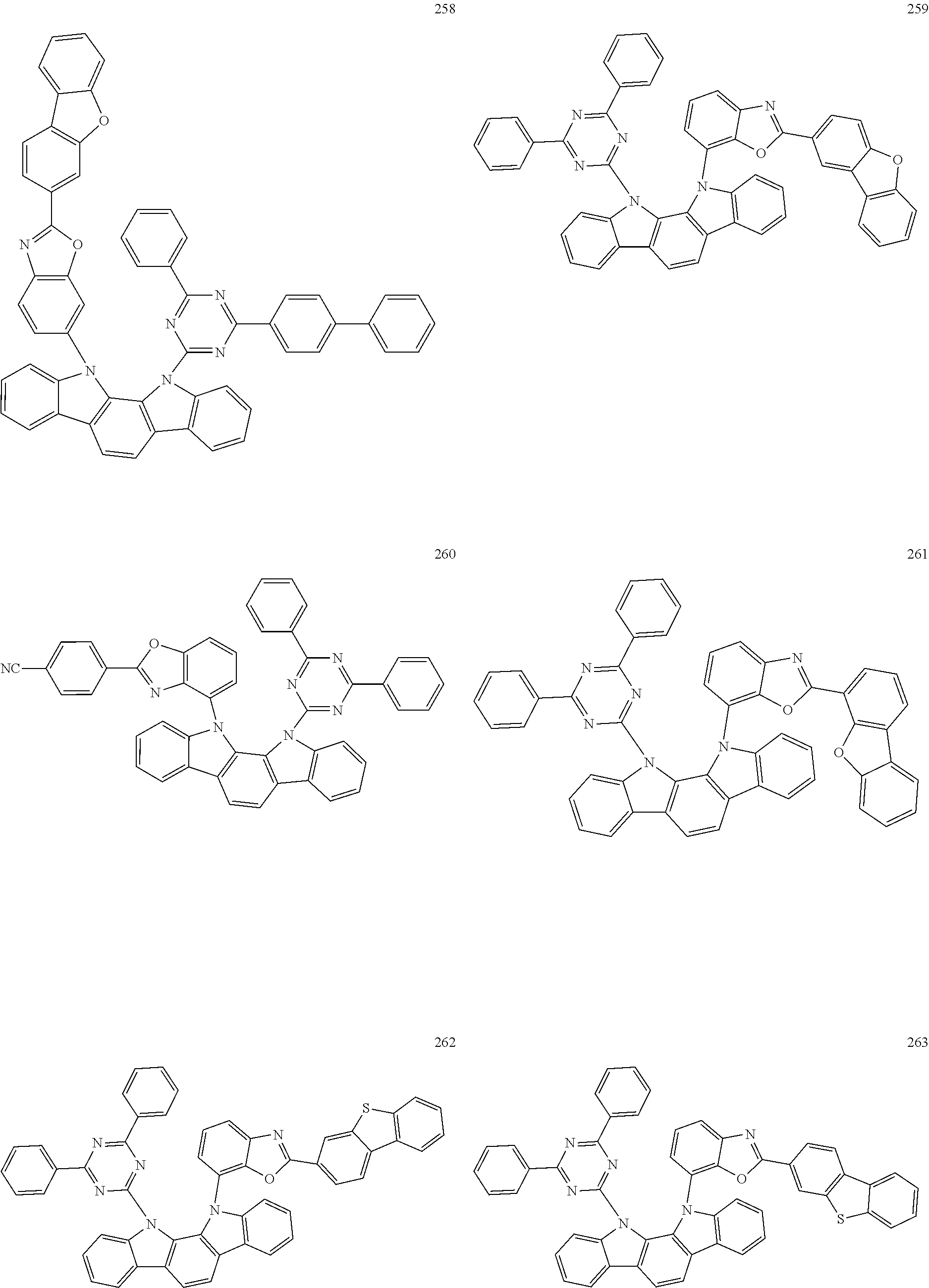

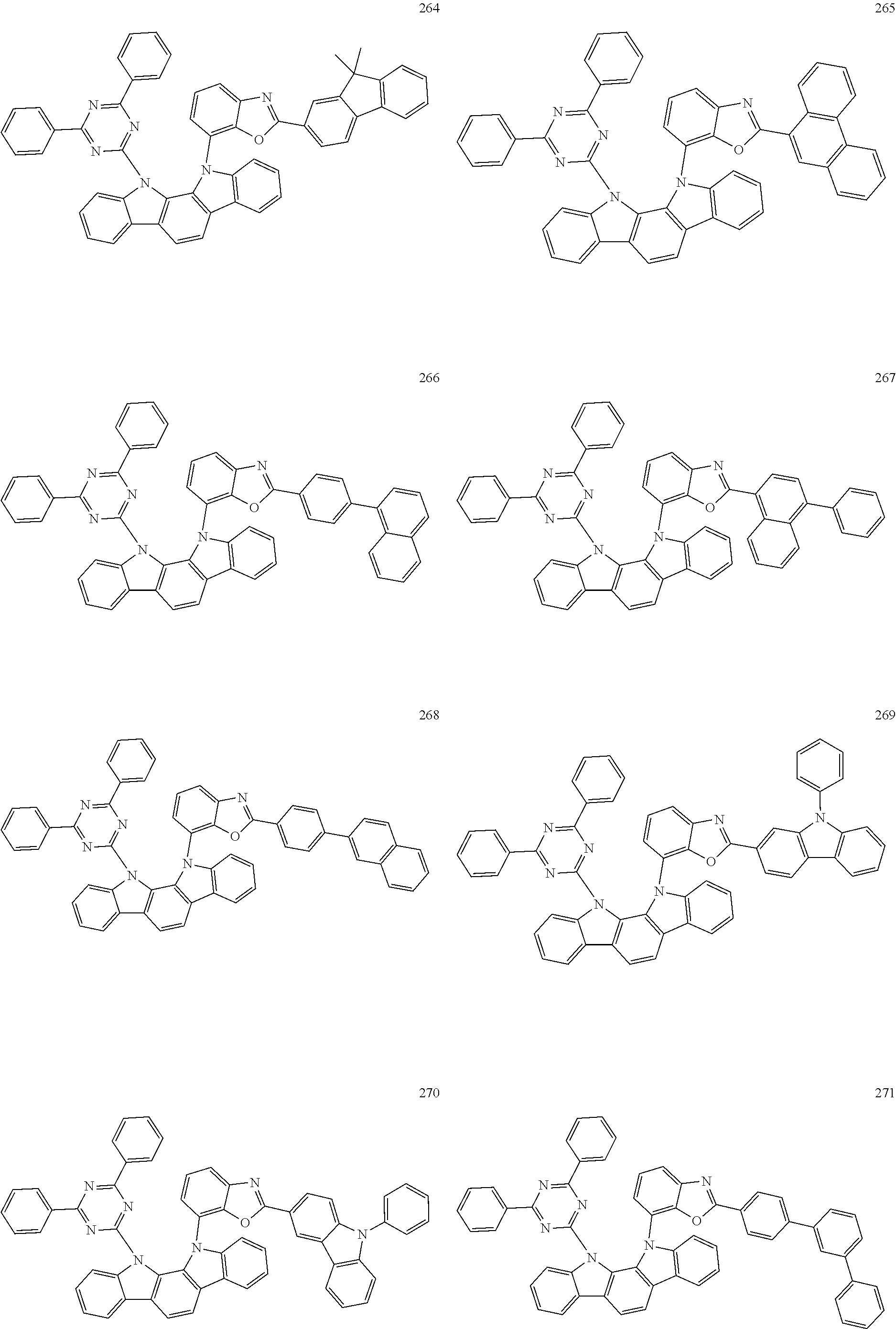

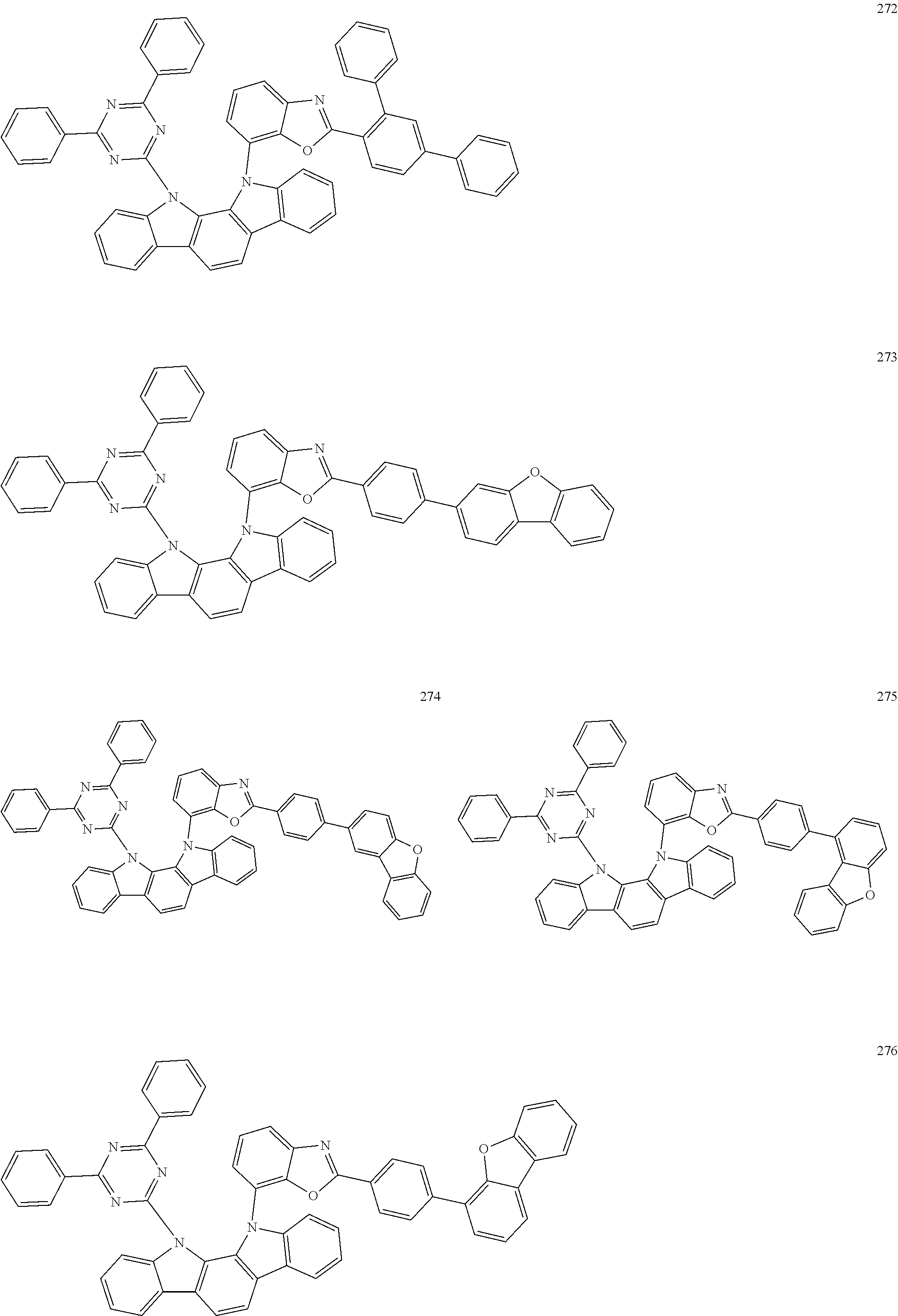

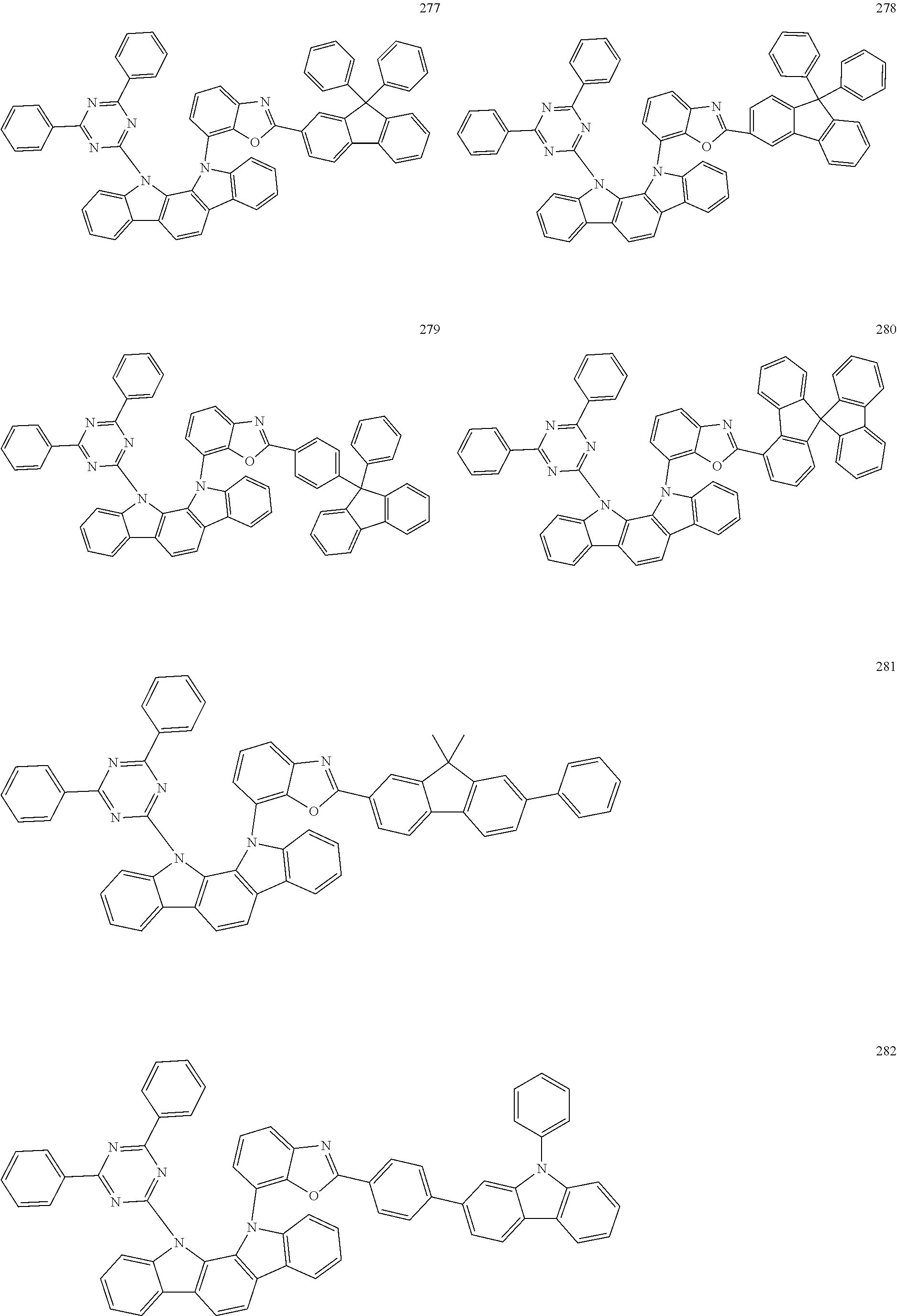

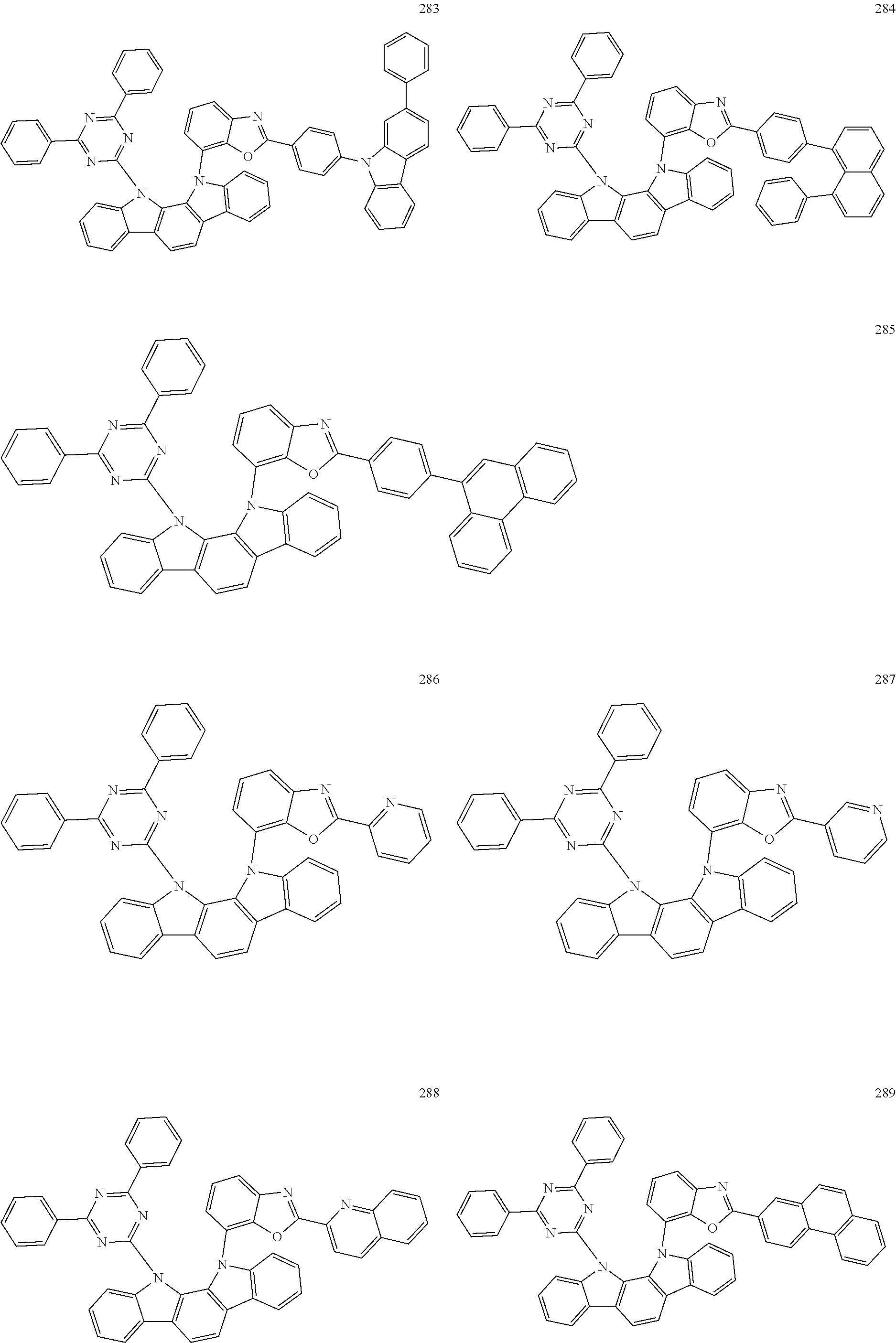

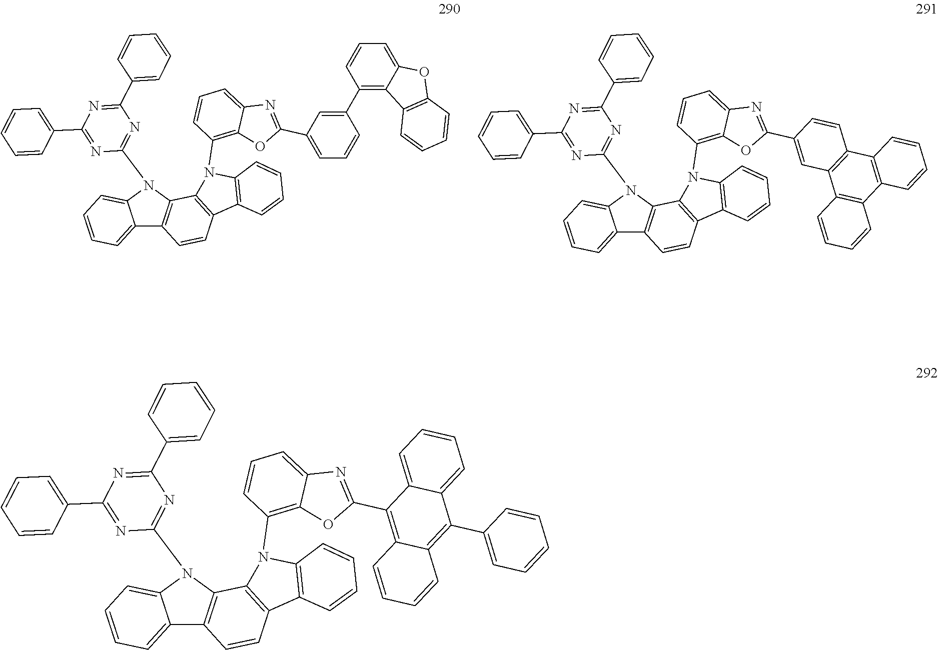

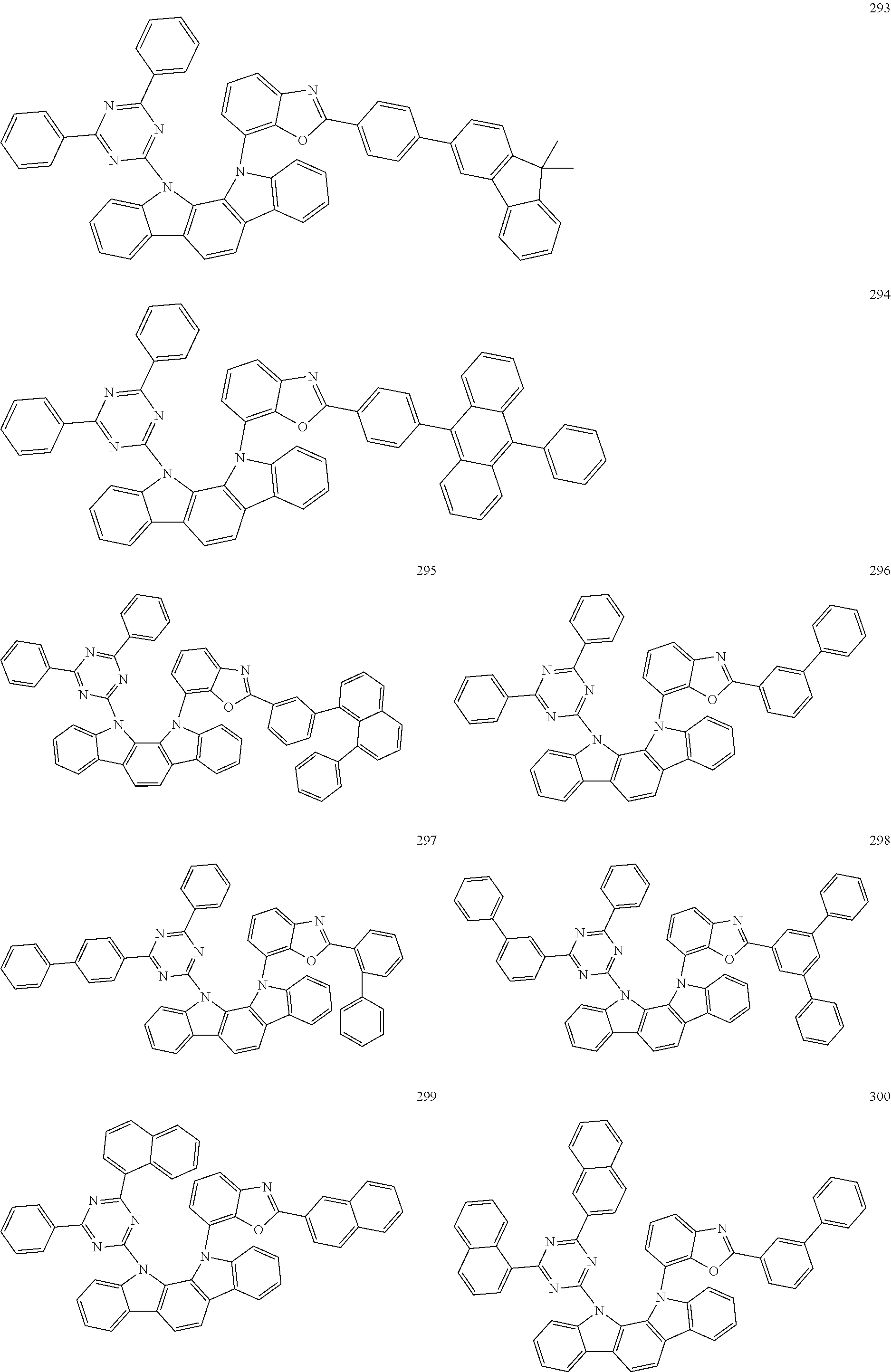

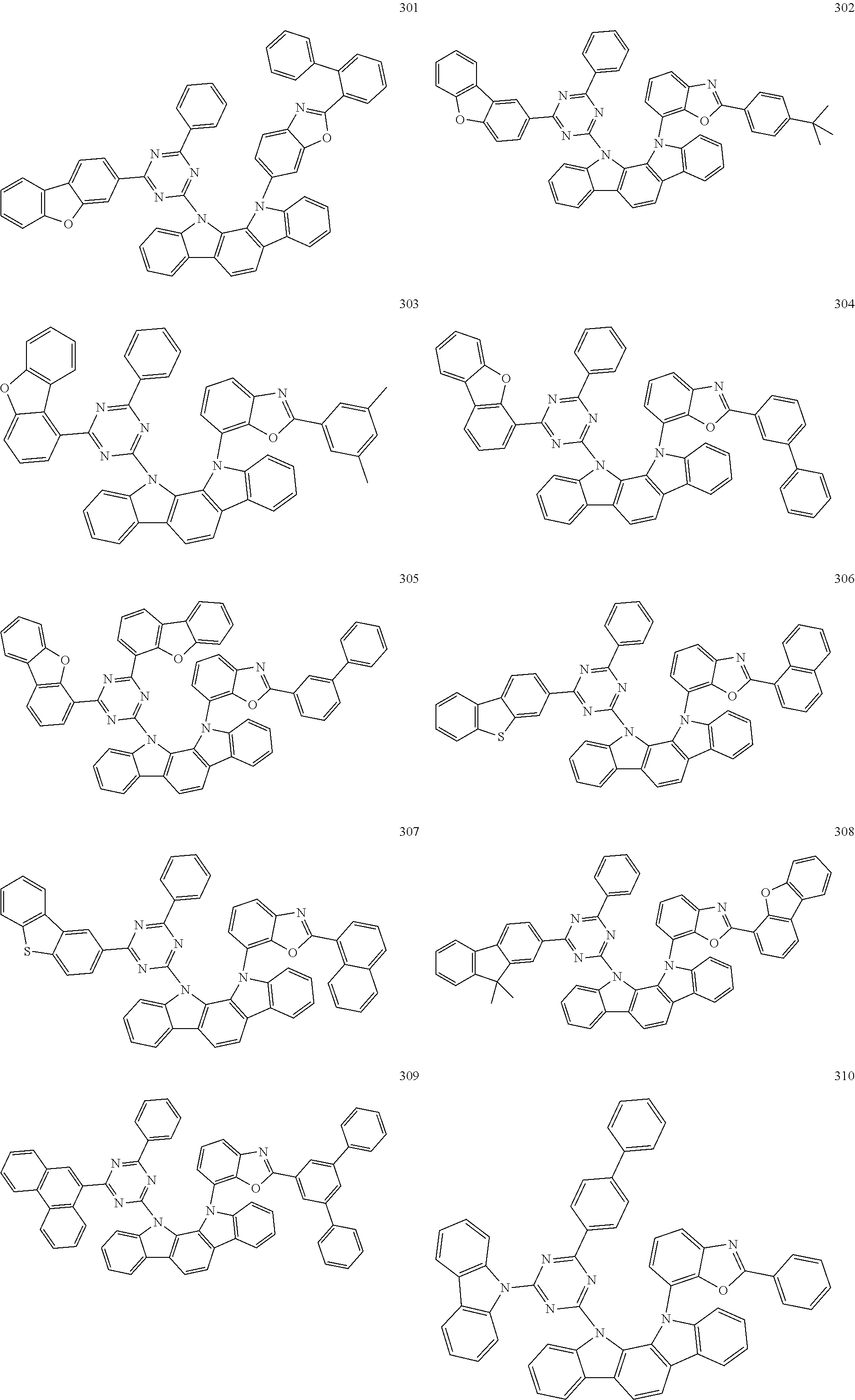

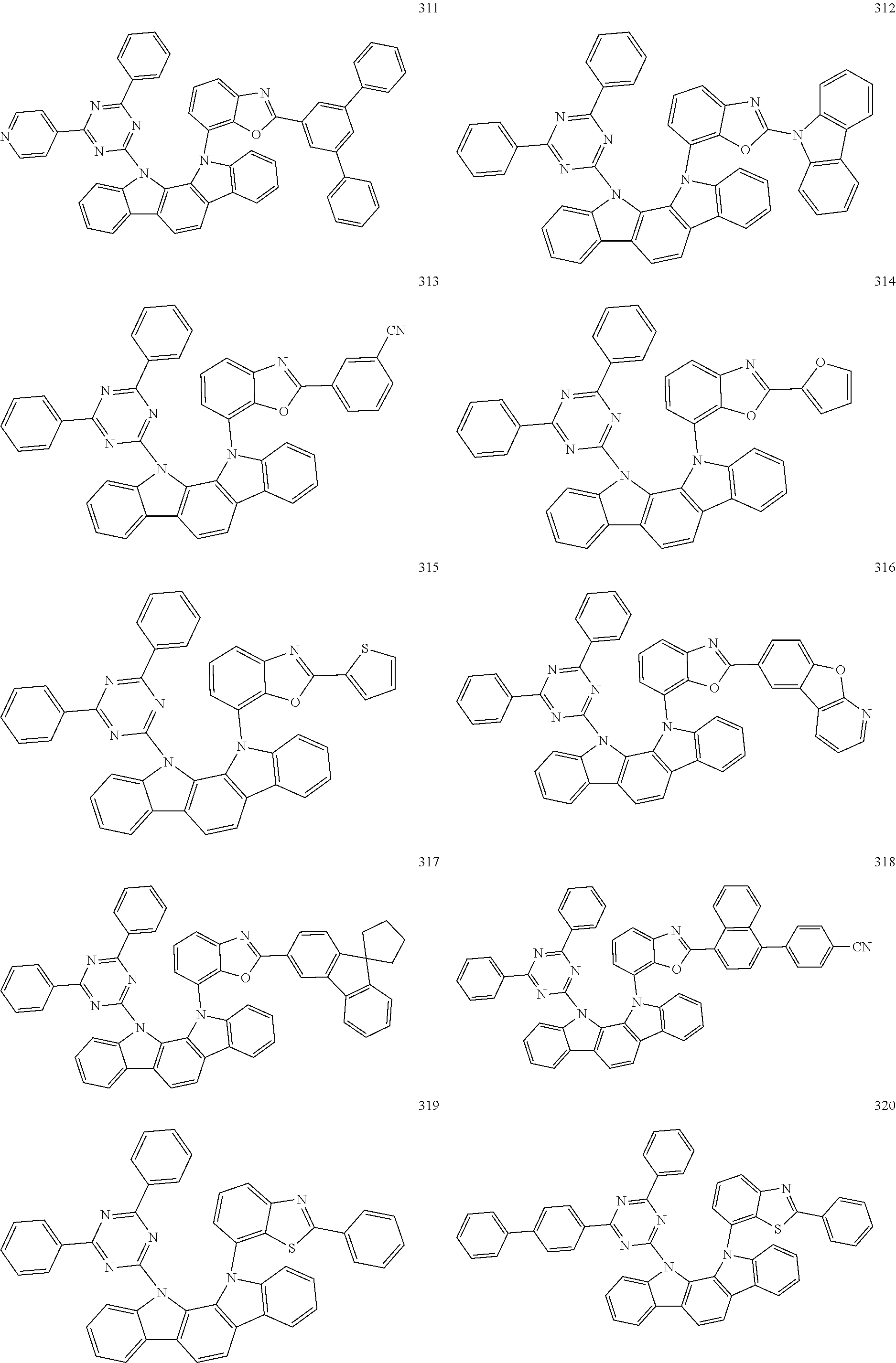

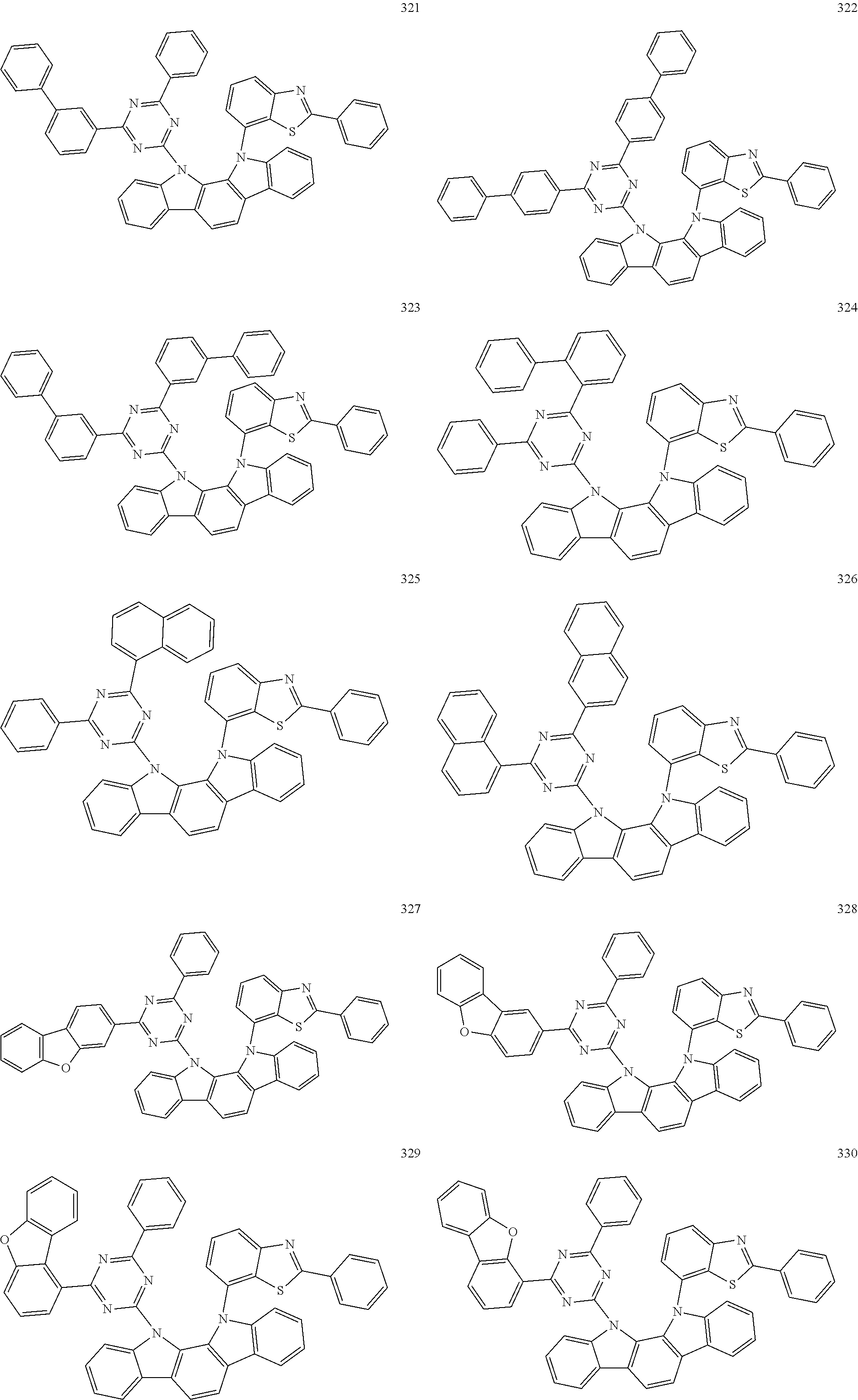

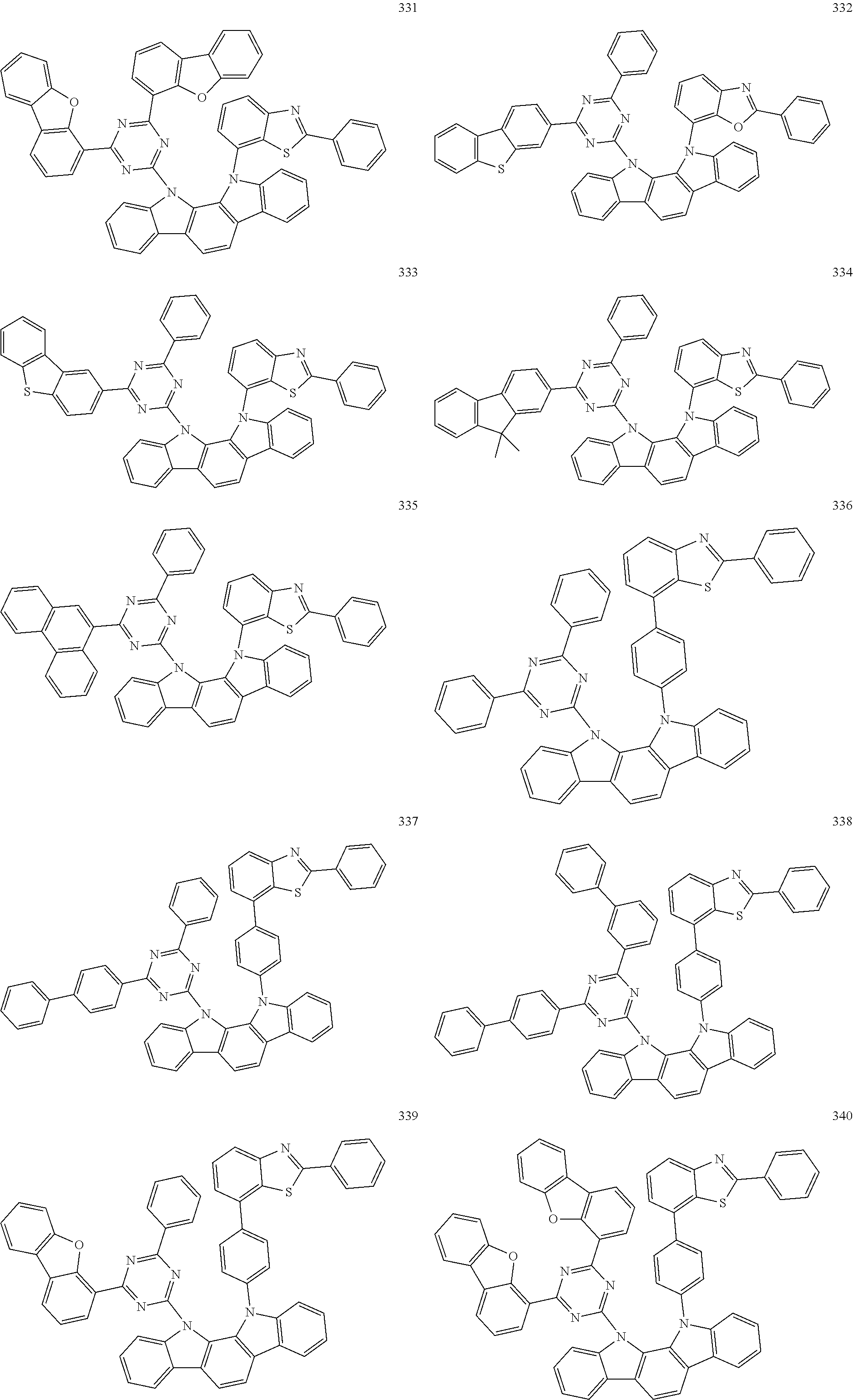

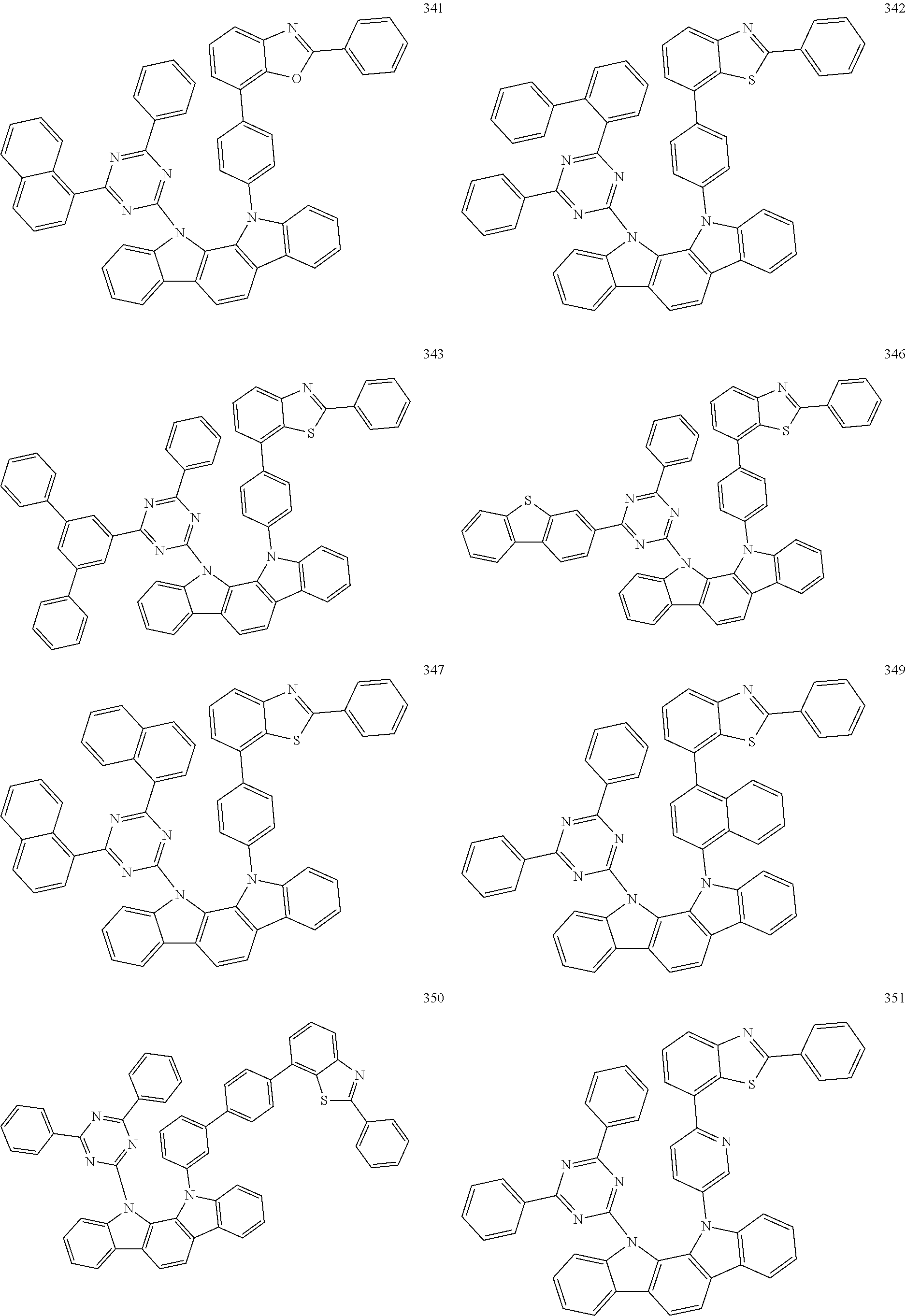

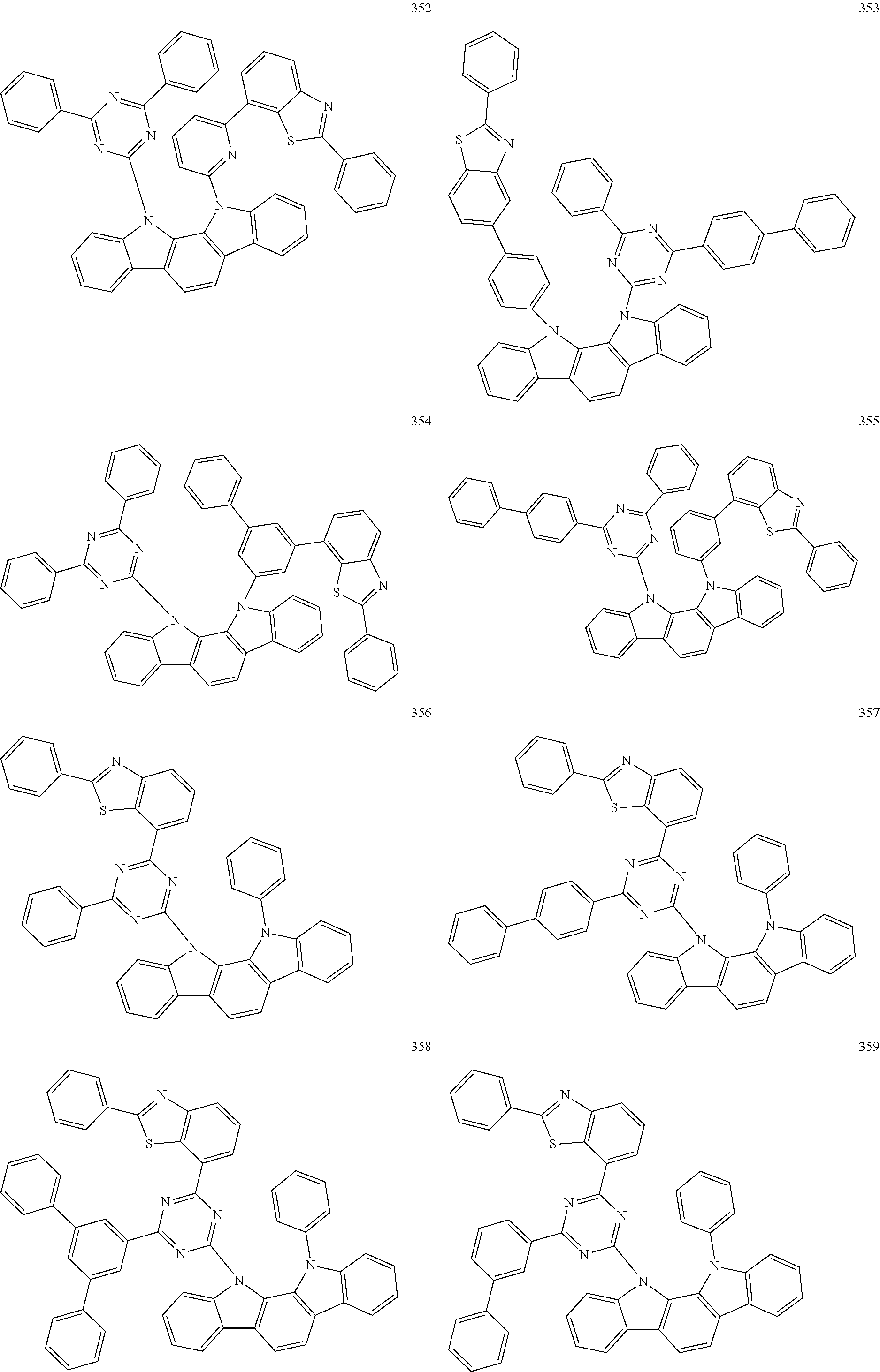

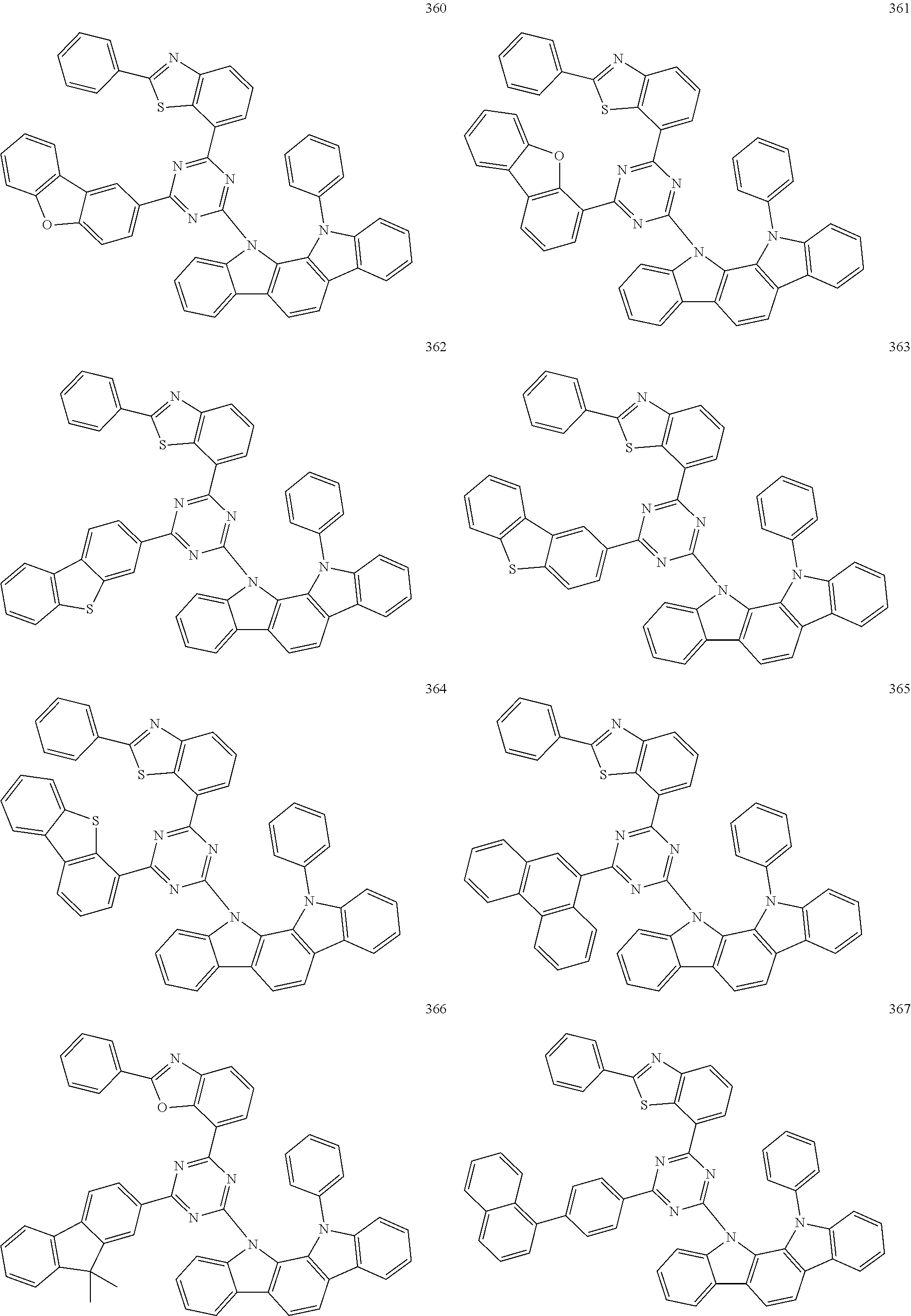

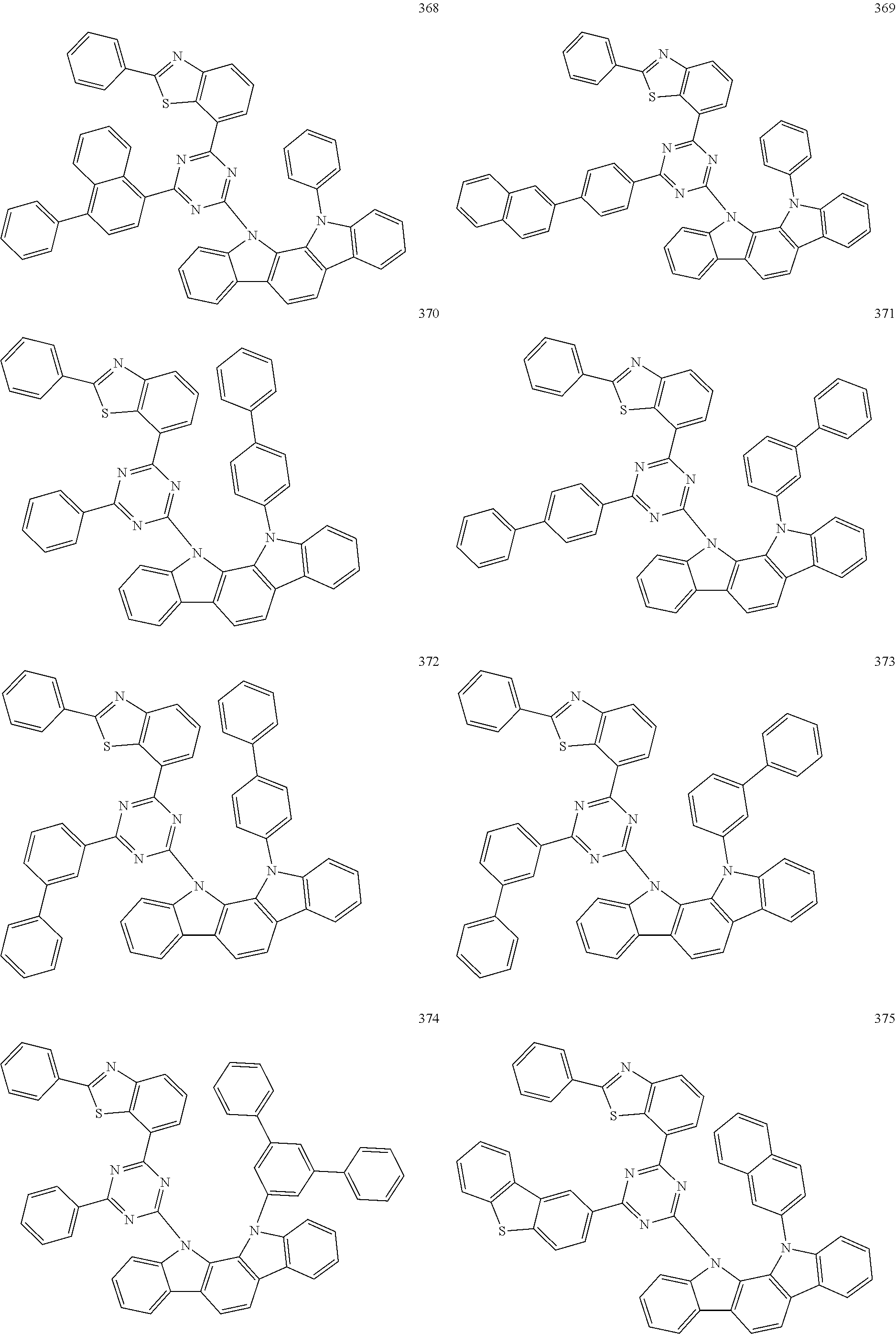

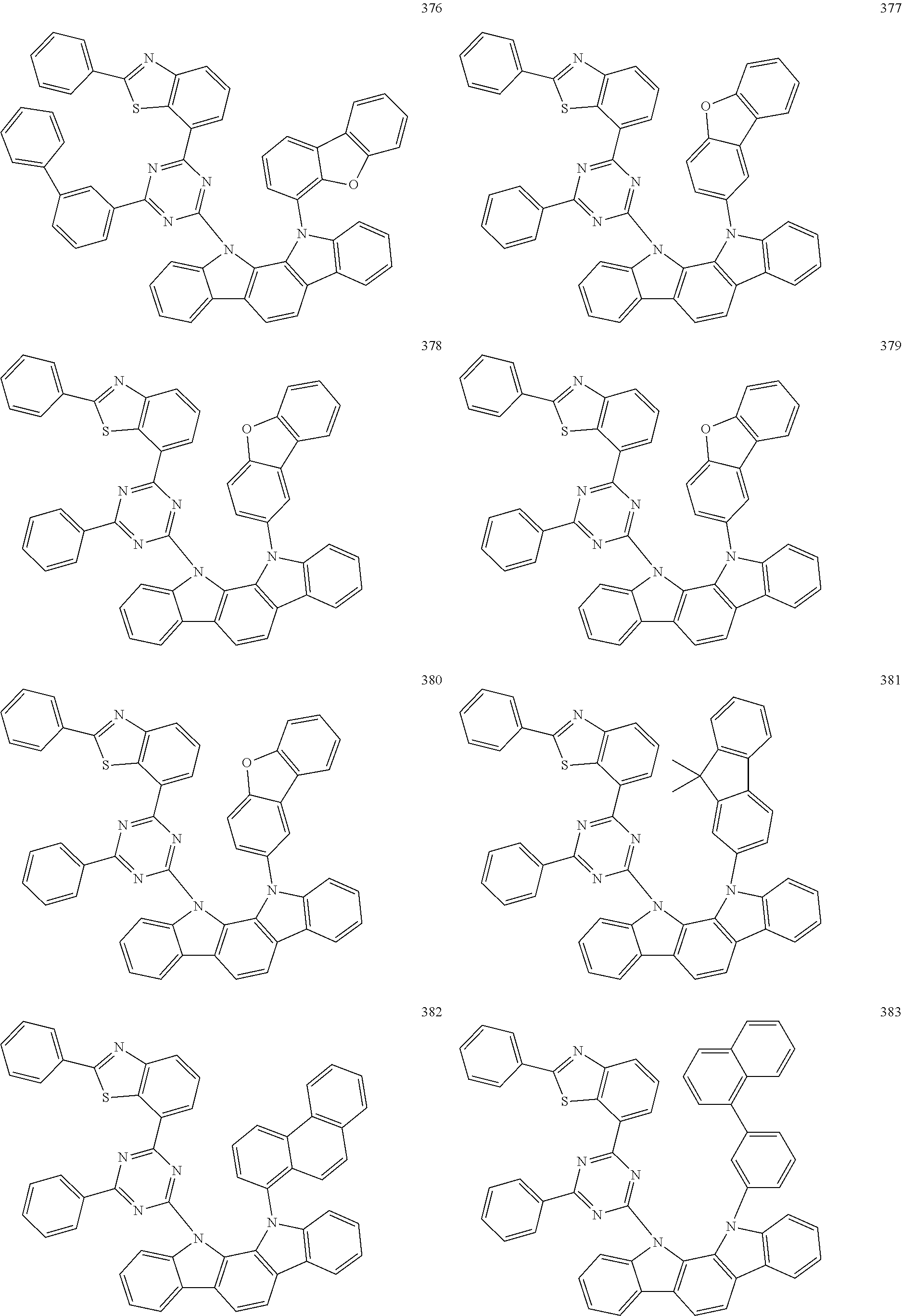

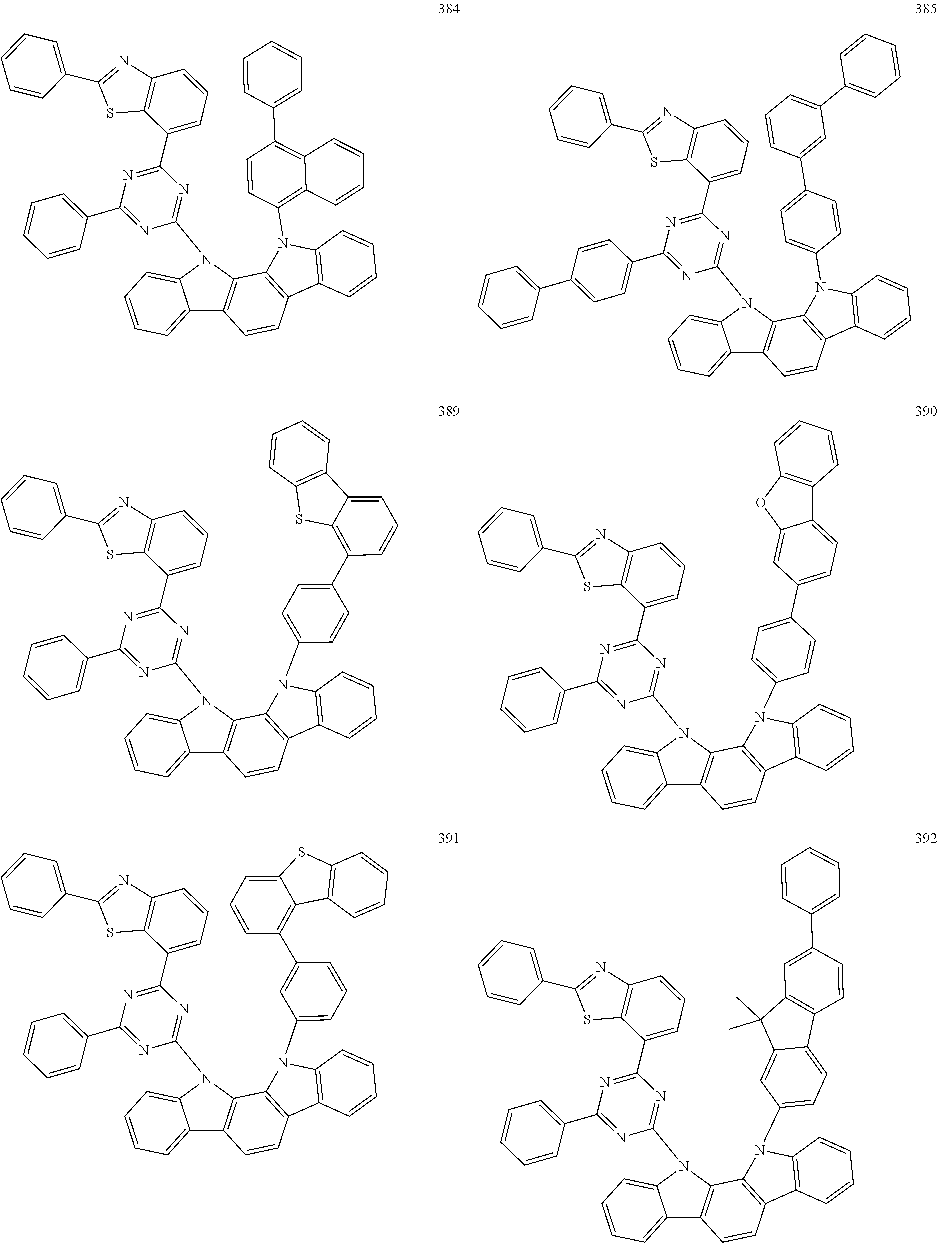

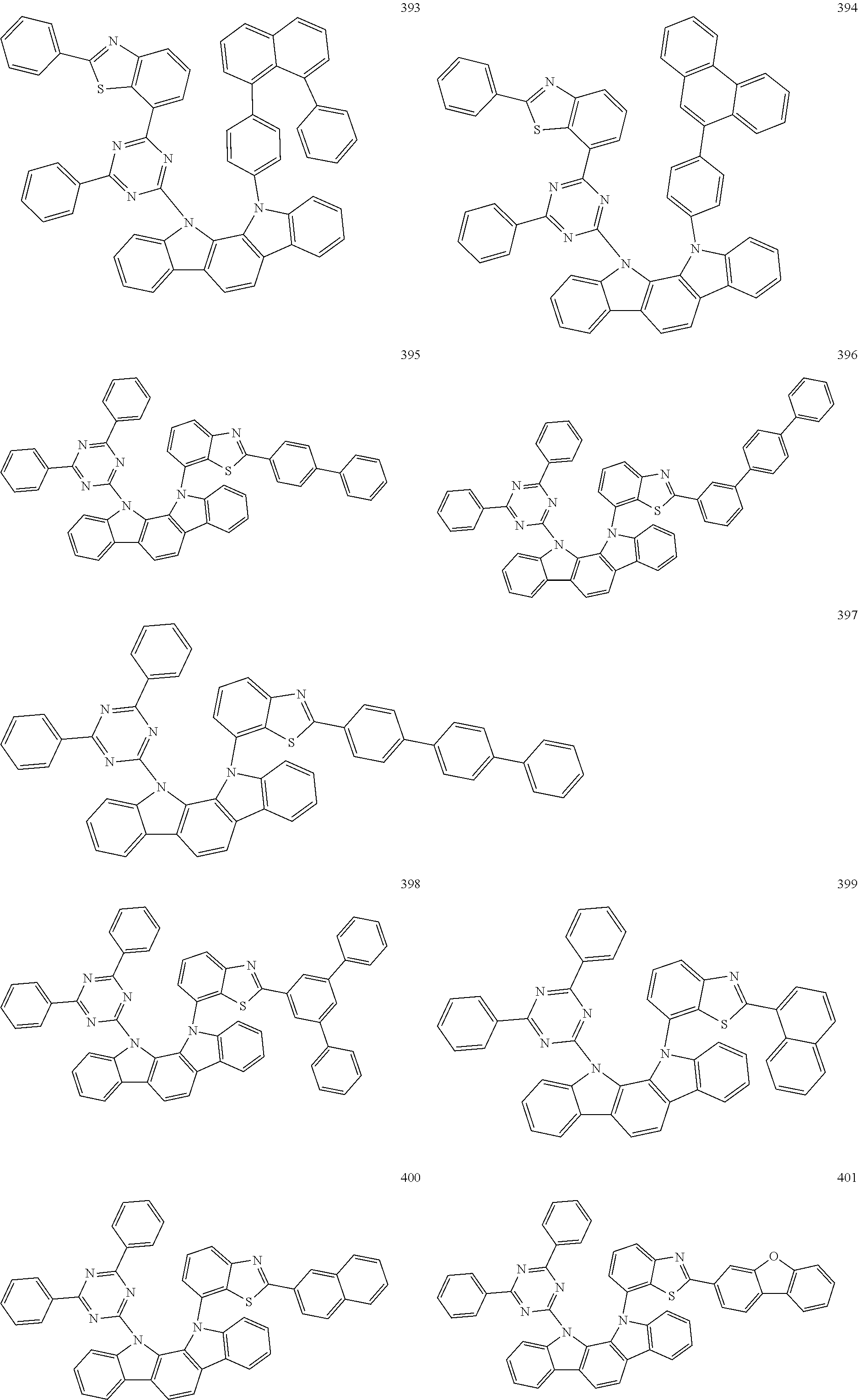

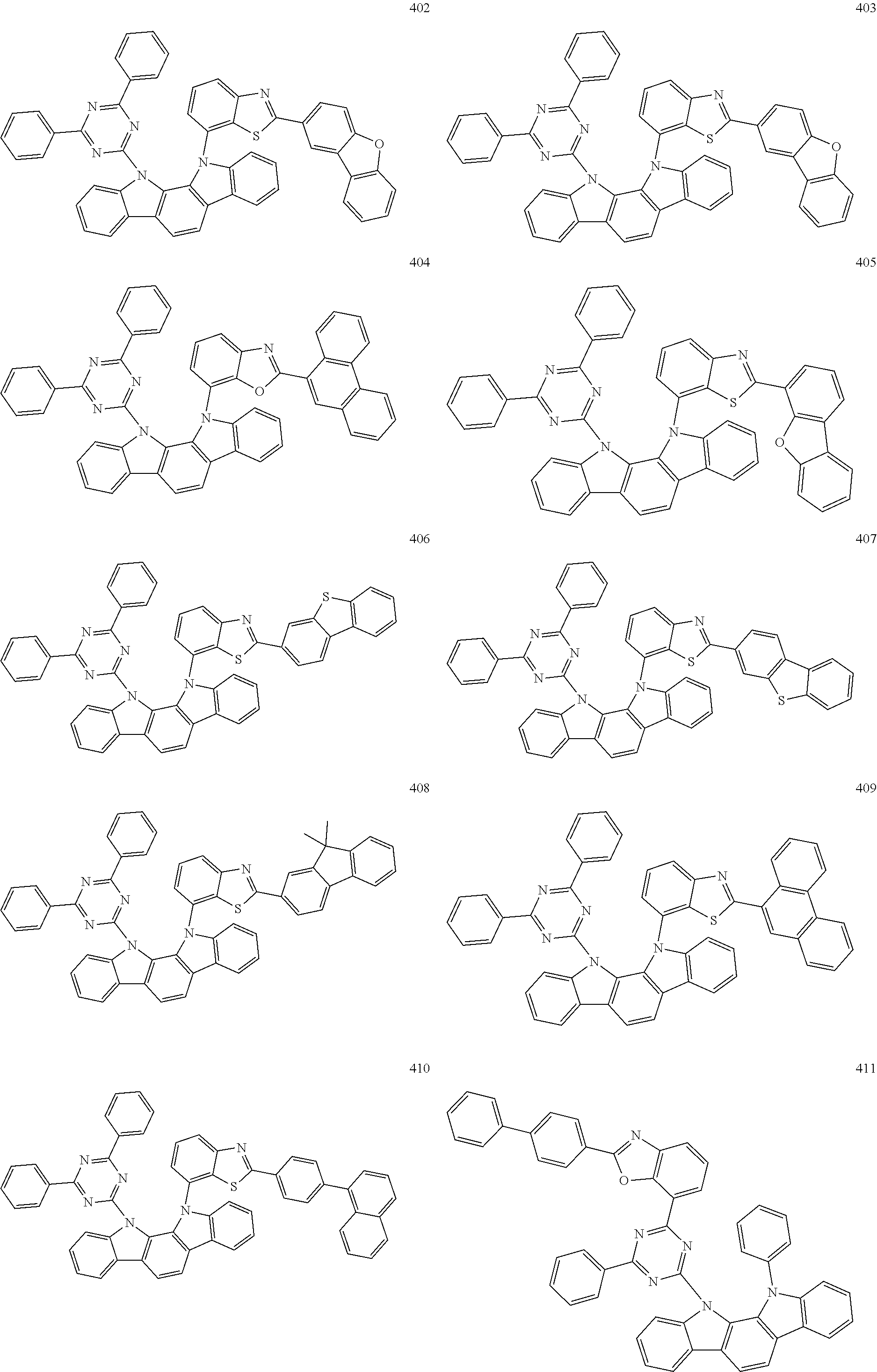

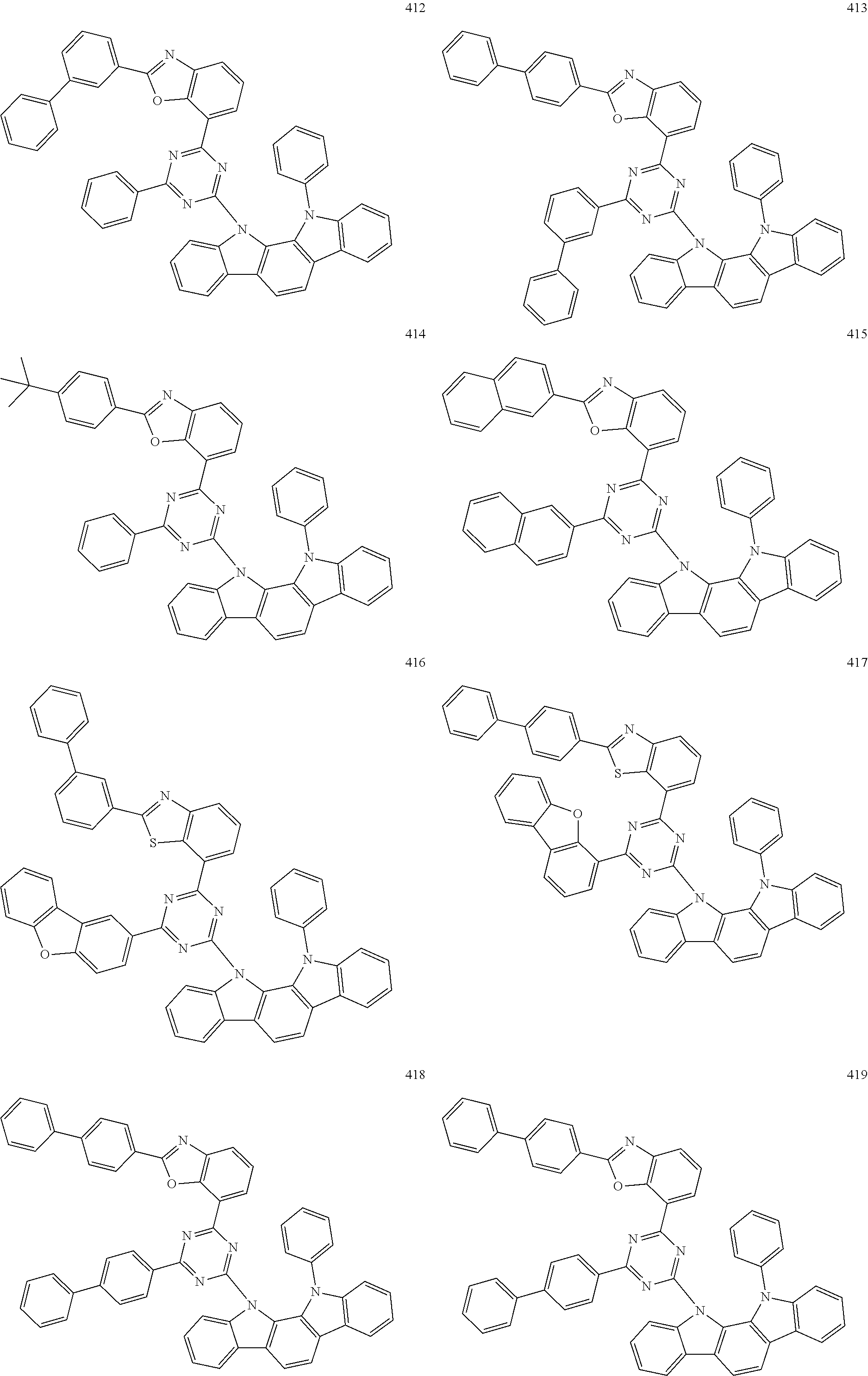

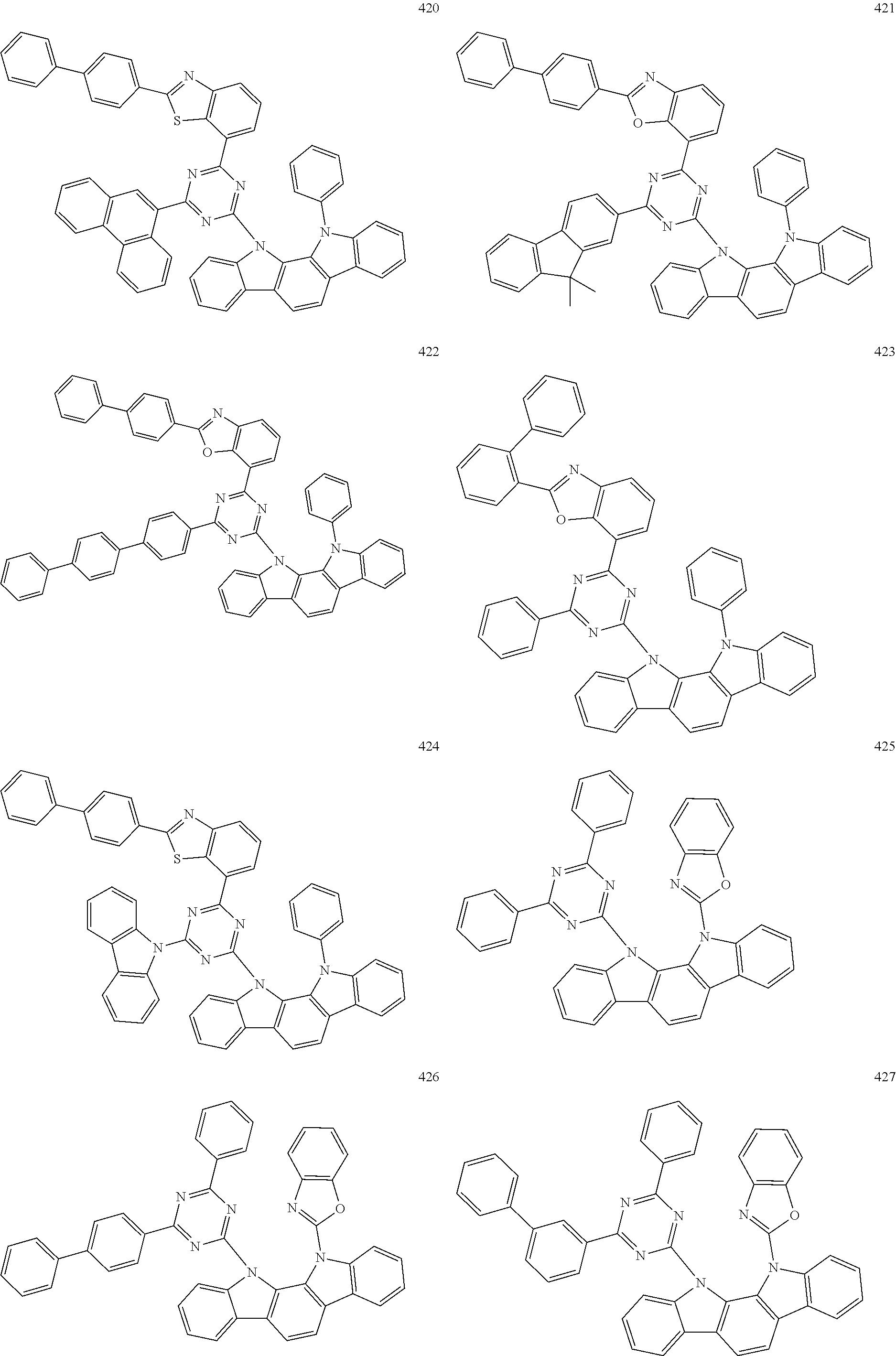

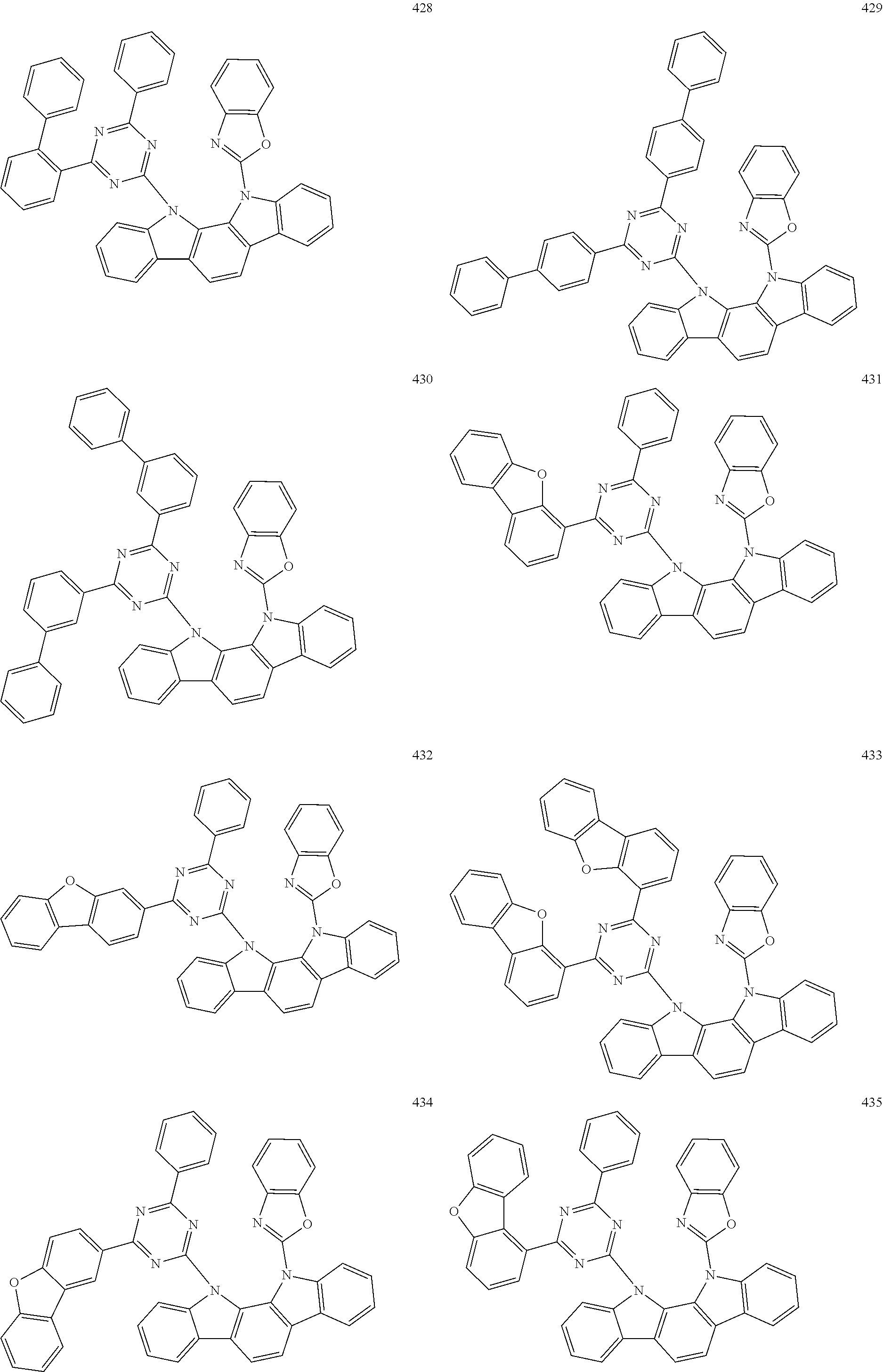

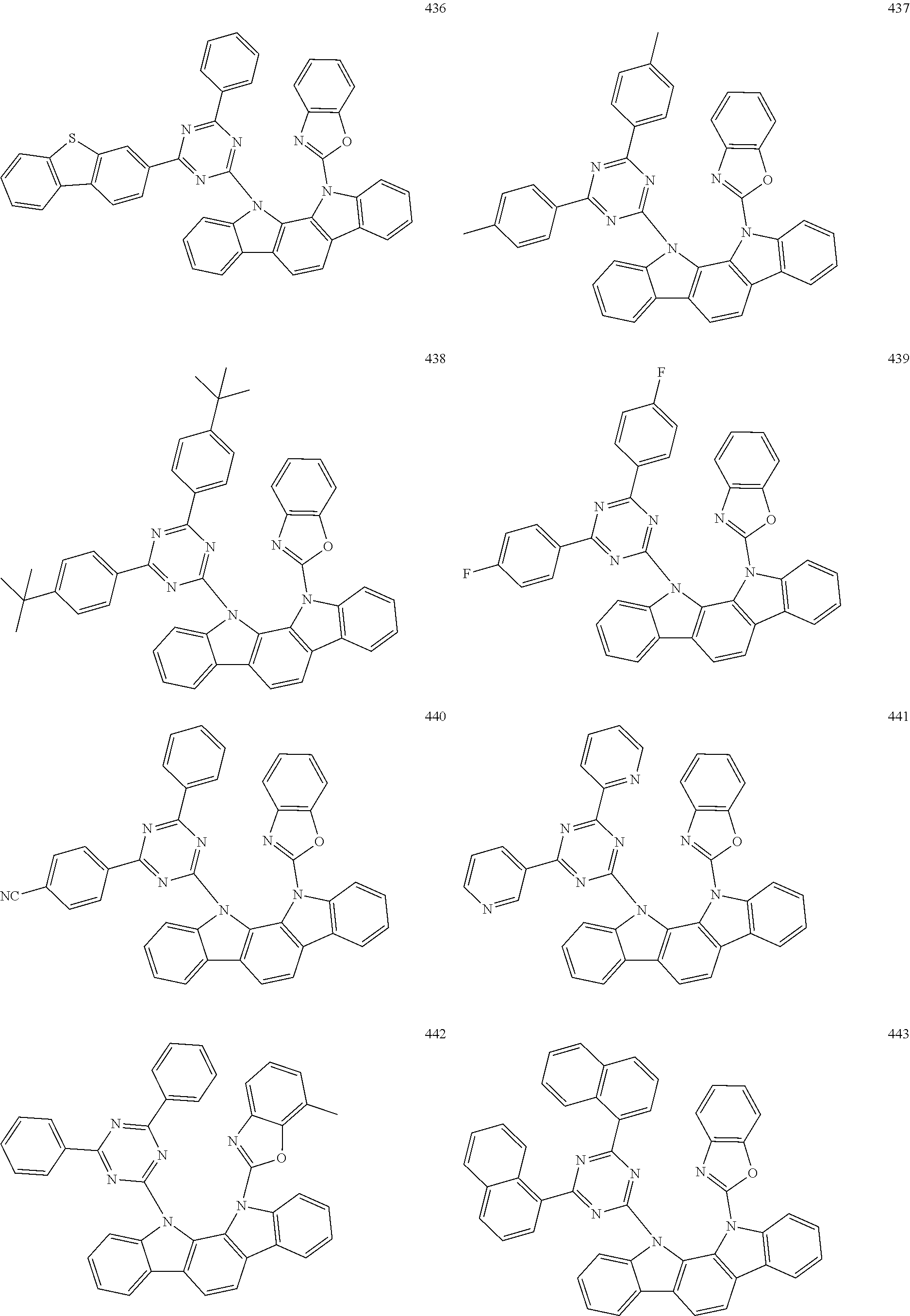

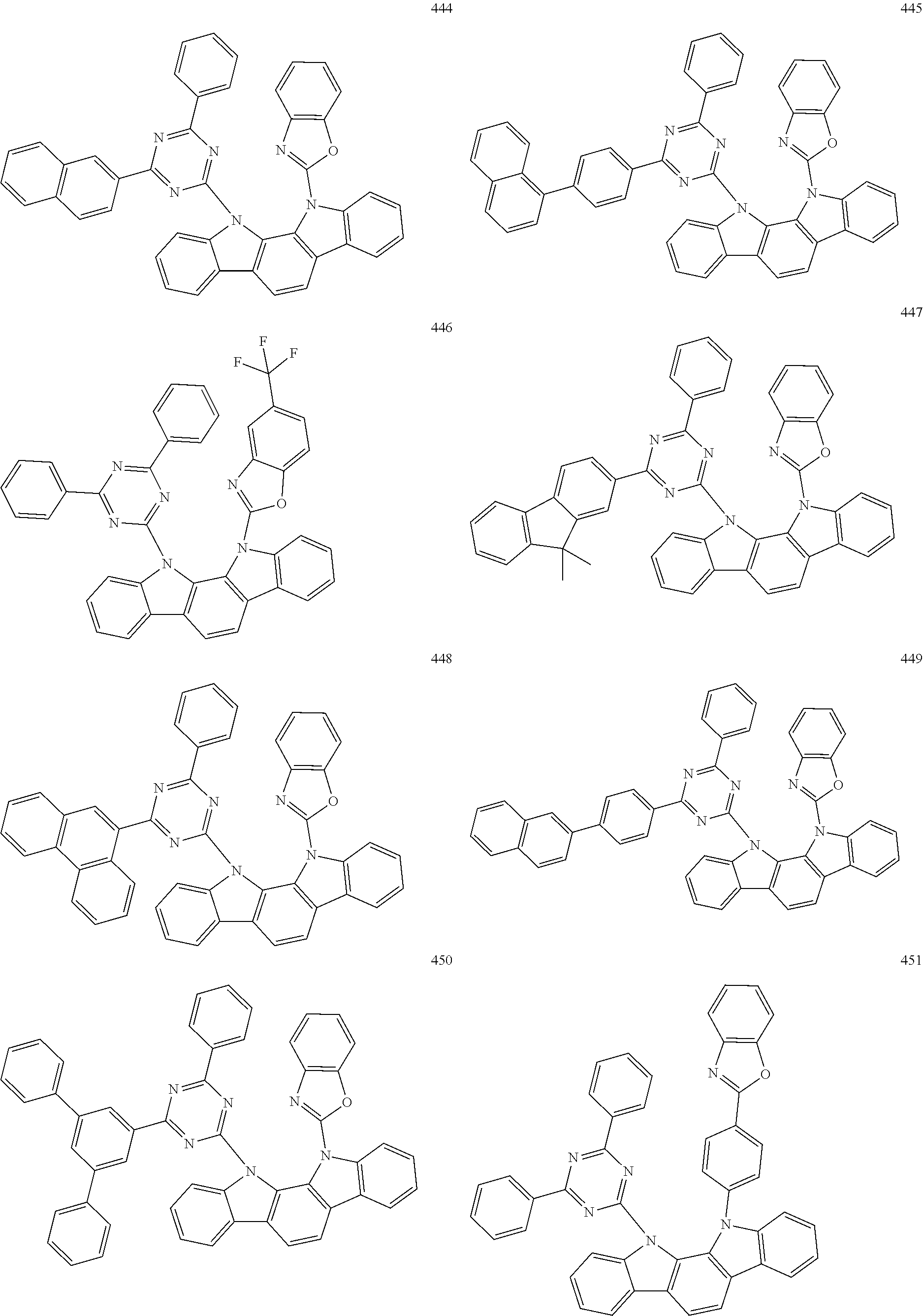

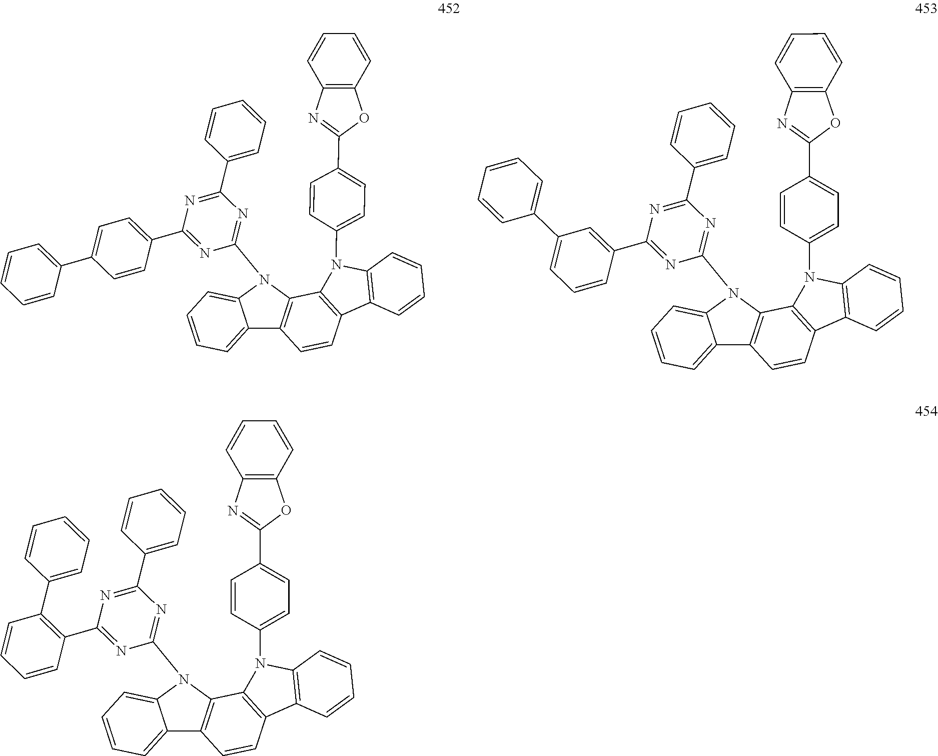 [SMILES: c1ccc(-c2ccc(-c3nc(-c4ccccc4)nc(-n4c5ccccc5c5ccc6c7ccccc7n(-c7ccc(-c8nc9ccccc9o8)cc7)c6c54)n3)cc2)cc1 ; c1ccc(-c2cccc(-c3nc(-c4ccccc4)nc(-n4c5ccccc5c5ccc6c7ccccc7n(-c7ccc(-c8nc9ccccc9o8)cc7)c6c54)n3)c2)cc1 ; c1ccc(-c2nc(-c3ccccc3-c3ccccc3)nc(-n3c4ccccc4c4ccc5c6ccccc6n(-c6ccc(-c7nc8ccccc8o7)cc6)c5c43)n2)cc1]

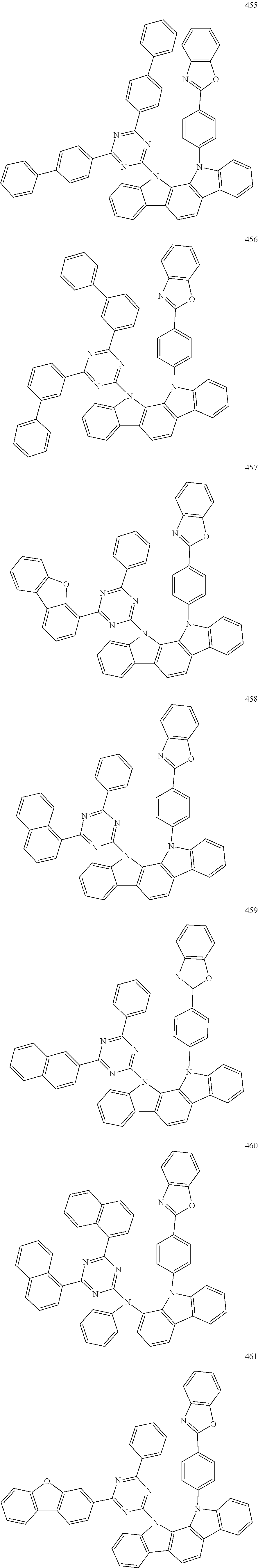

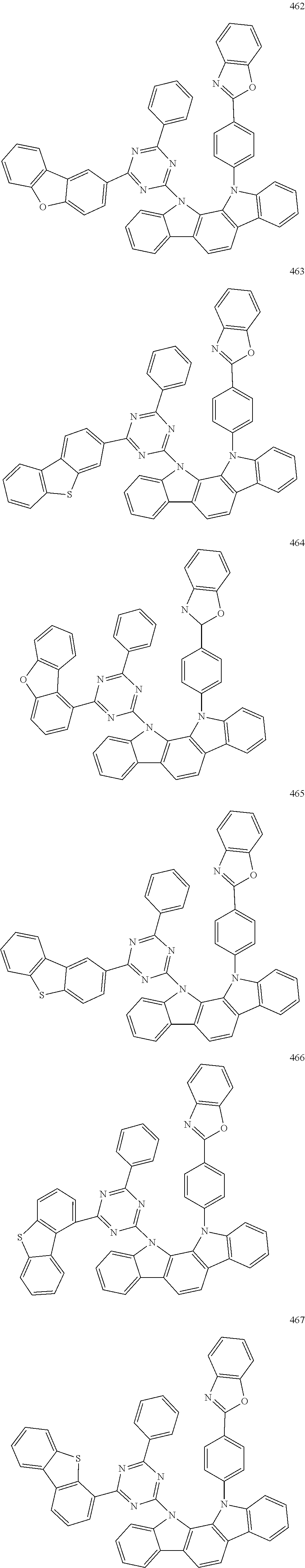

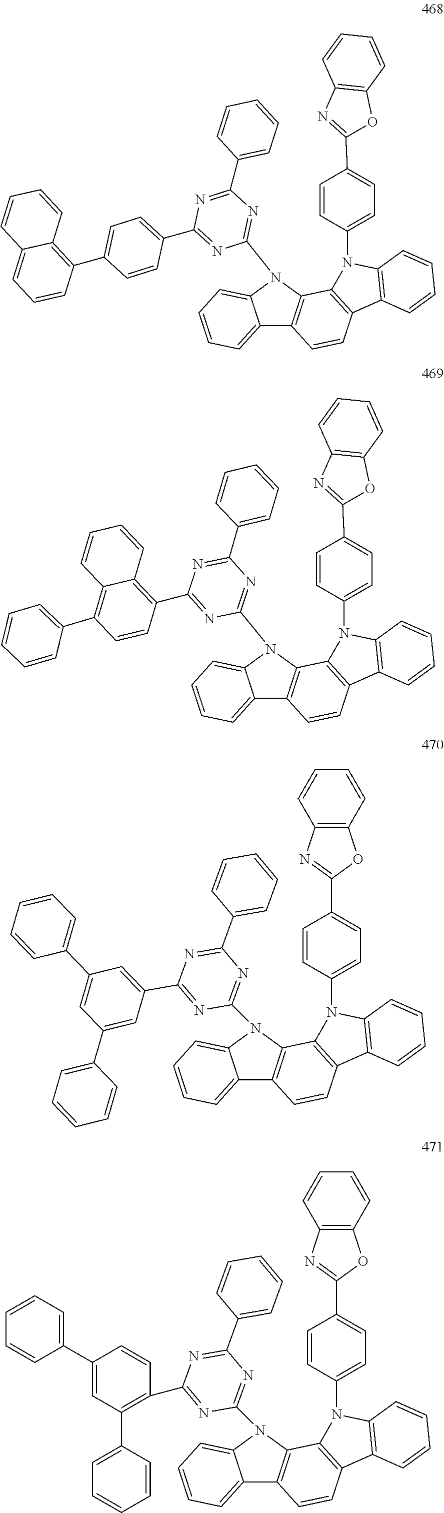 [SMILES: c1ccc(-c2nc(-c3ccc(-c4cccc5ccccc45)cc3)nc(-n3c4ccccc4c4ccc5c6ccccc6n(-c6ccc(-c7nc8ccccc8o7)cc6)c5c43)n2)cc1 ; c1ccc(-c2nc(-c3ccc(-c4ccccc4)c4ccccc34)nc(-n3c4ccccc4c4ccc5c6ccccc6n(-c6ccc(-c7nc8ccccc8o7)cc6)c5c43)n2)cc1 ; c1ccc(-c2cc(-c3ccccc3)cc(-c3nc(-c4ccccc4)nc(-n4c5ccccc5c5ccc6c7ccccc7n(-c7ccc(-c8nc9ccccc9o8)cc7)c6c54)n3)c2)cc1 ; c1ccc(-c2ccc(-c3nc(-c4ccccc4)nc(-n4c5ccccc5c5ccc6c7ccccc7n(-c7ccc(-c8nc9ccccc9o8)cc7)c6c54)n3)c(-c3ccccc3)c2)cc1]

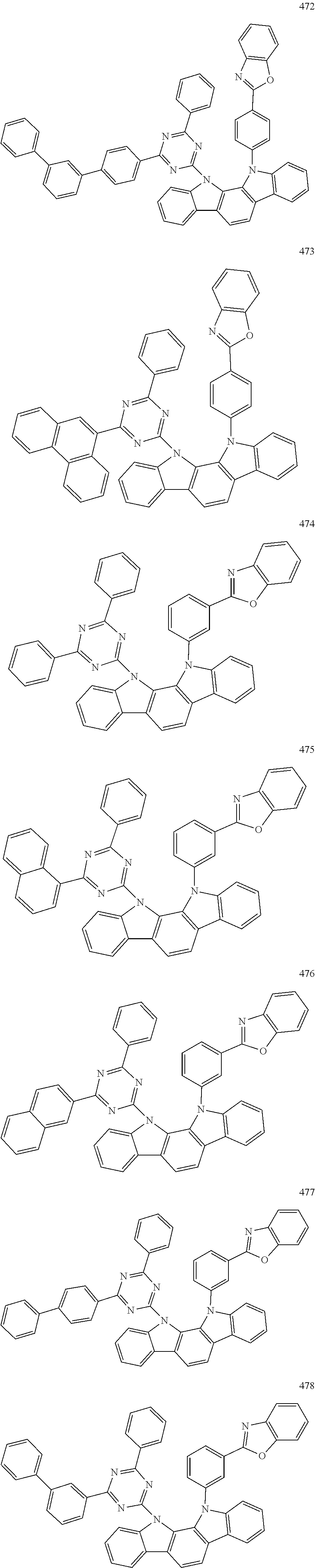

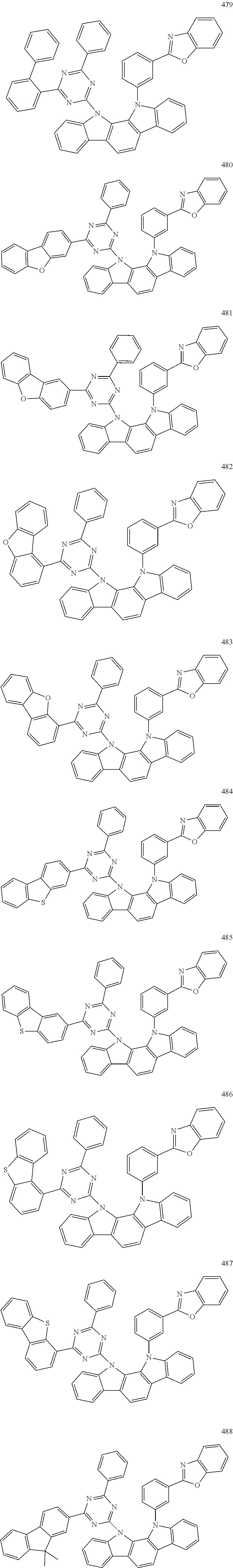

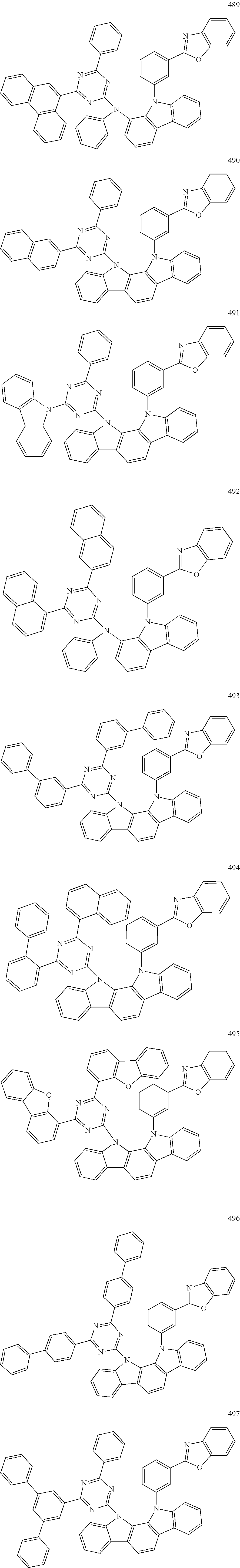

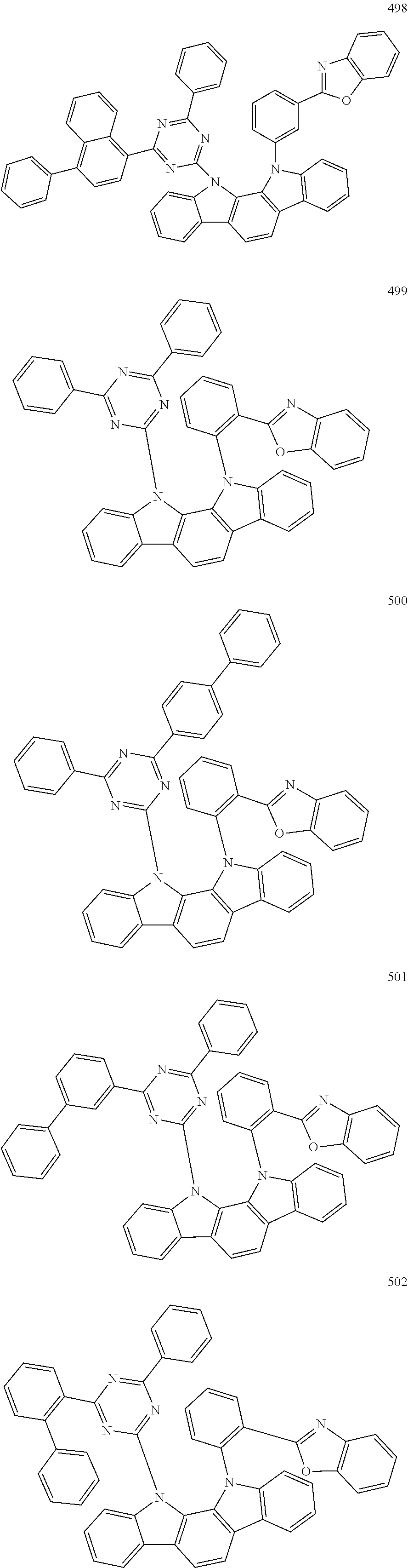

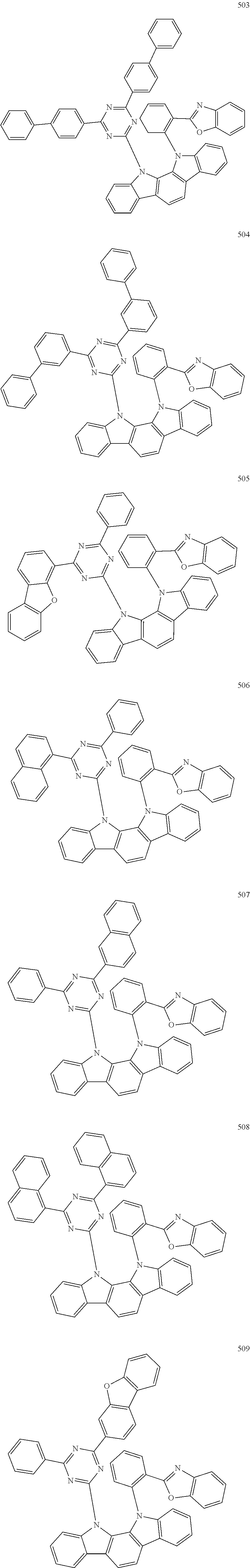

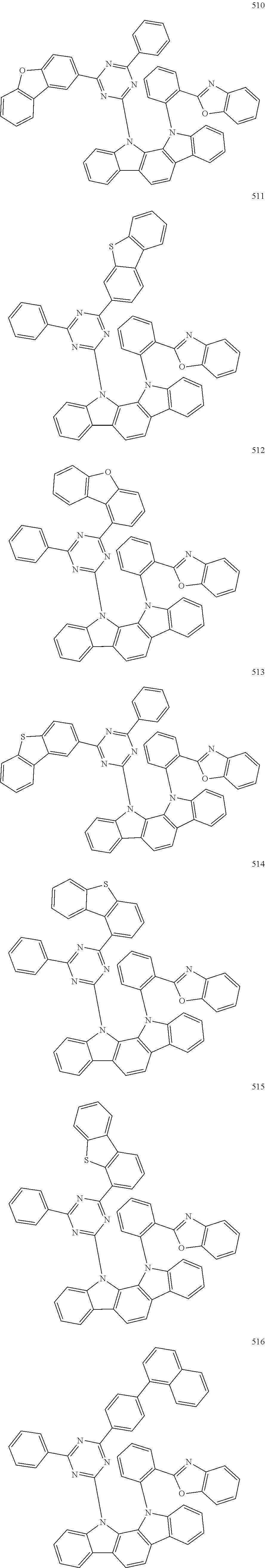

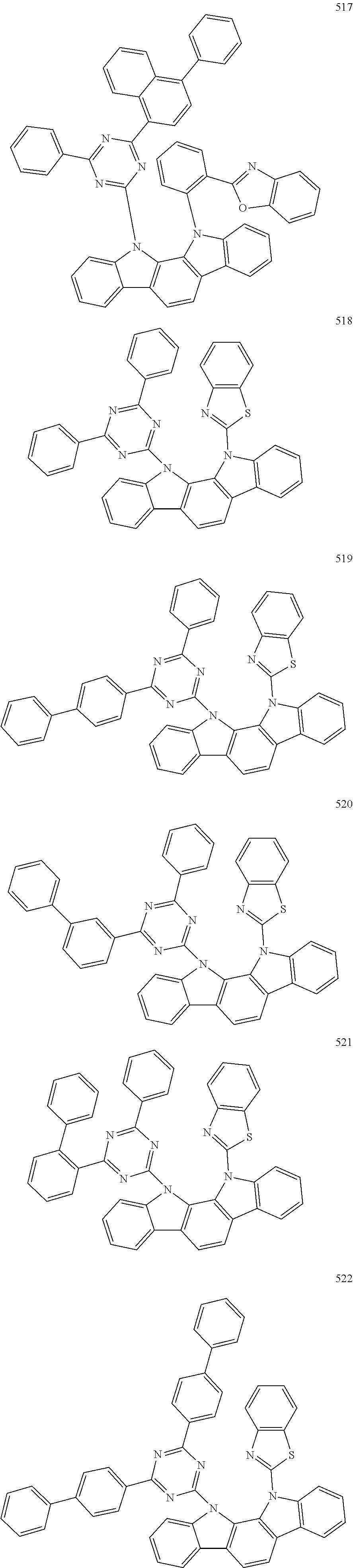

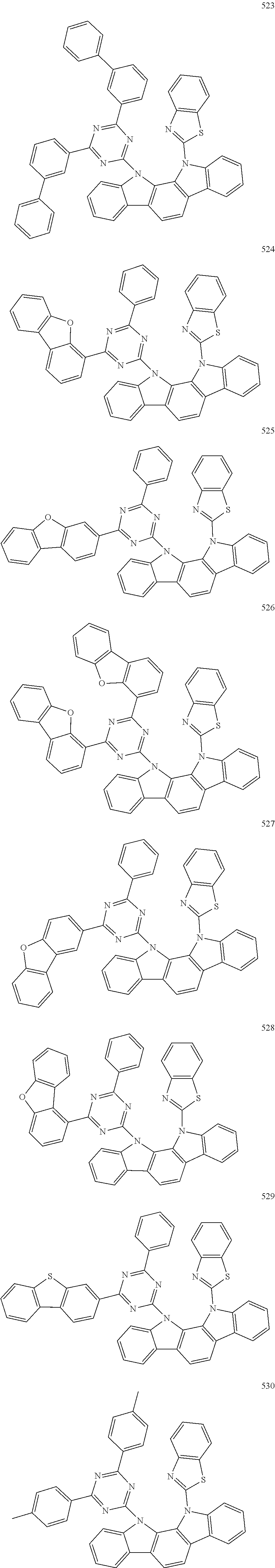

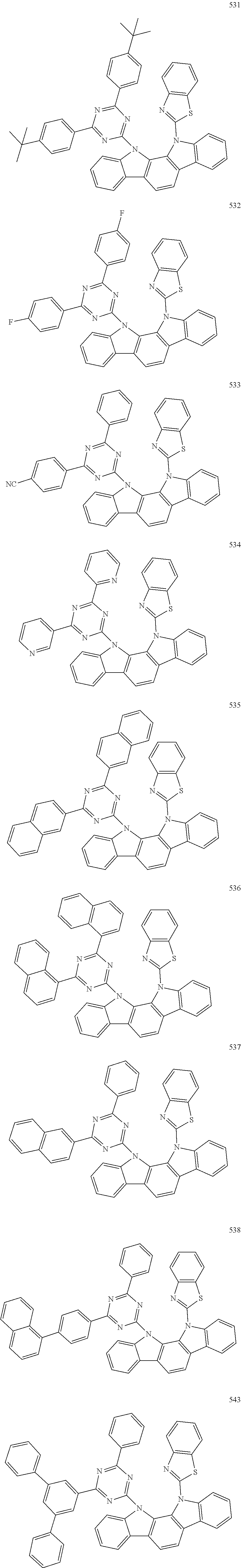

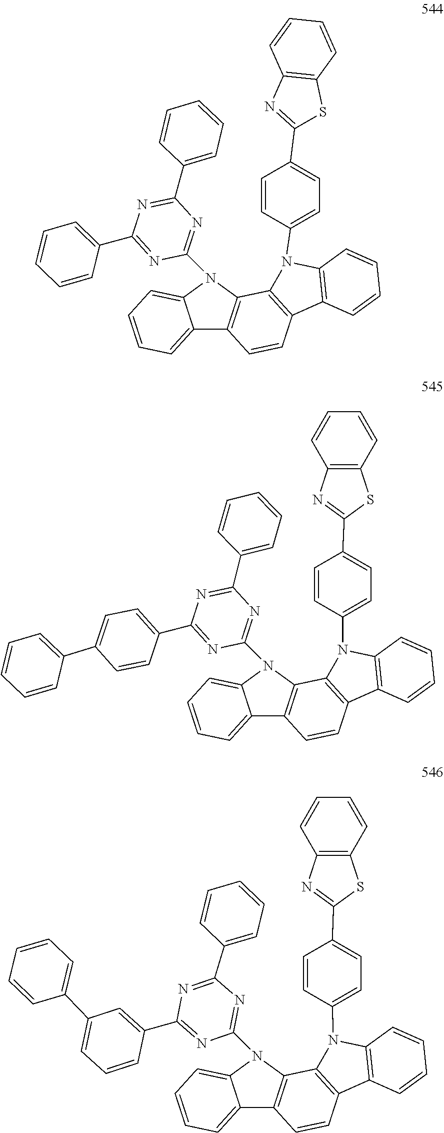 [SMILES: c1ccc(-c2nc(-c3ccccc3)nc(-n3c4ccccc4c4ccc5c6ccccc6n(-c6ccc(-c7nc8ccccc8s7)cc6)c5c43)n2)cc1 ; c1ccc(-c2ccc(-c3nc(-c4ccccc4)nc(-n4c5ccccc5c5ccc6c7ccccc7n(-c7ccc(-c8nc9ccccc9s8)cc7)c6c54)n3)cc2)cc1 ; c1ccc(-c2cccc(-c3nc(-c4ccccc4)nc(-n4c5ccccc5c5ccc6c7ccccc7n(-c7ccc(-c8nc9ccccc9s8)cc7)c6c54)n3)c2)cc1]

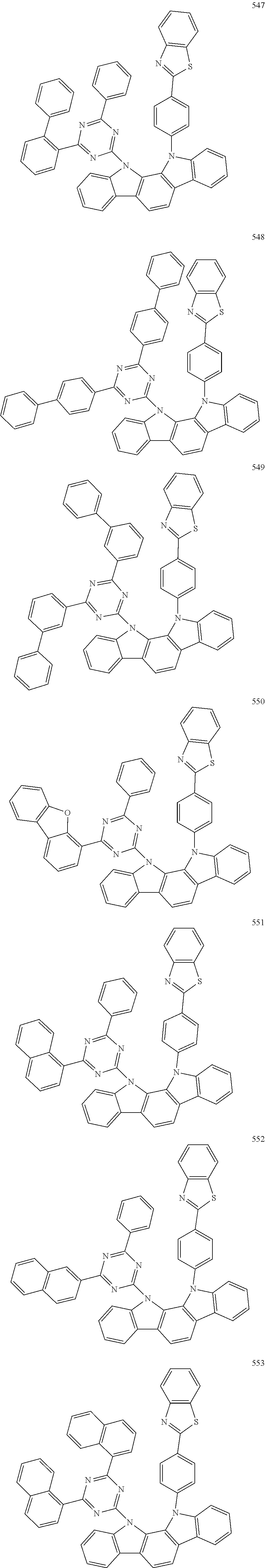

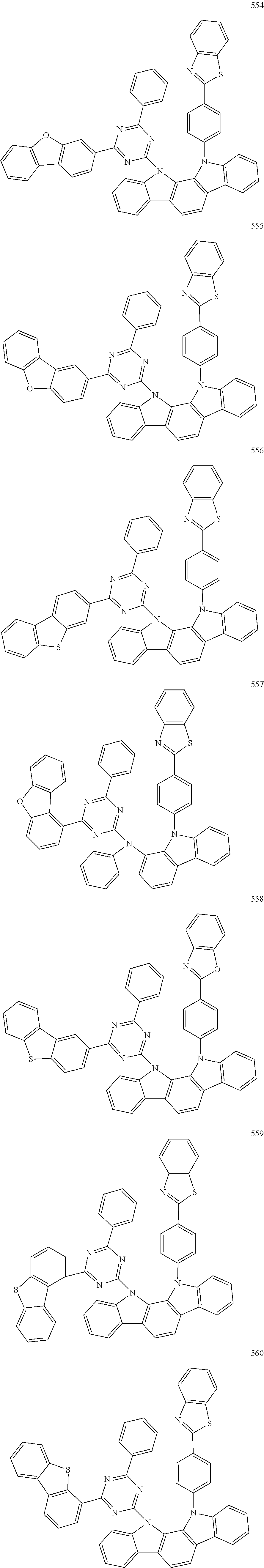

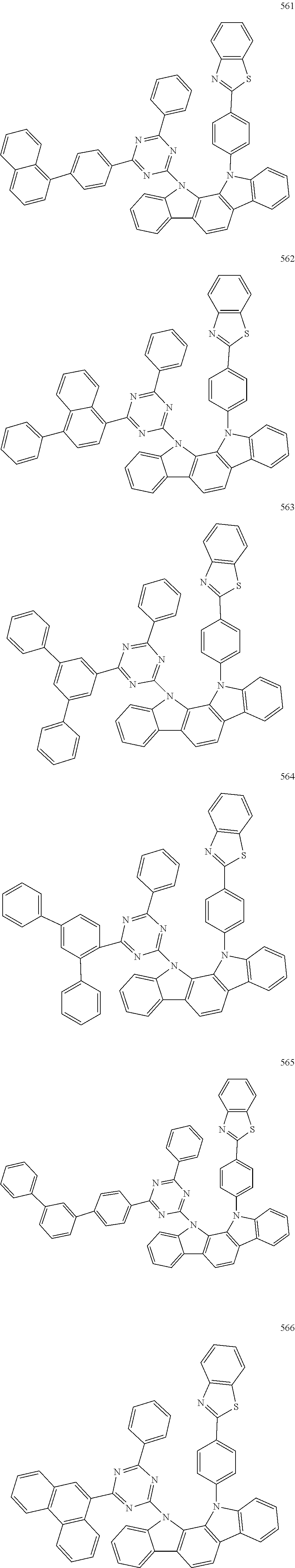

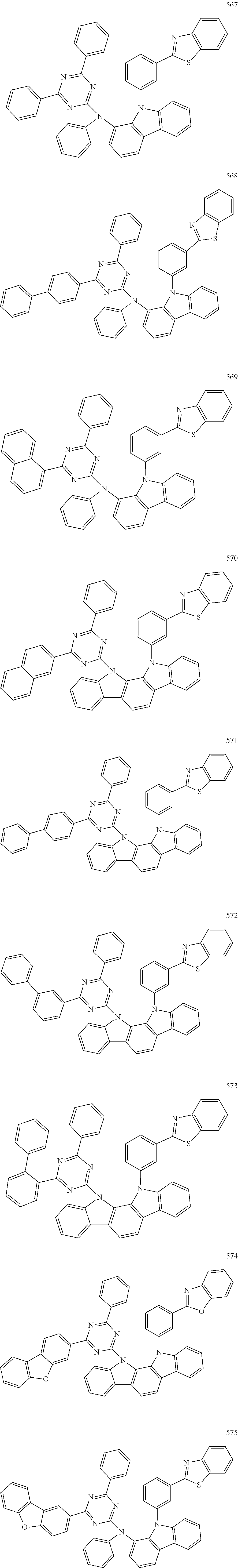

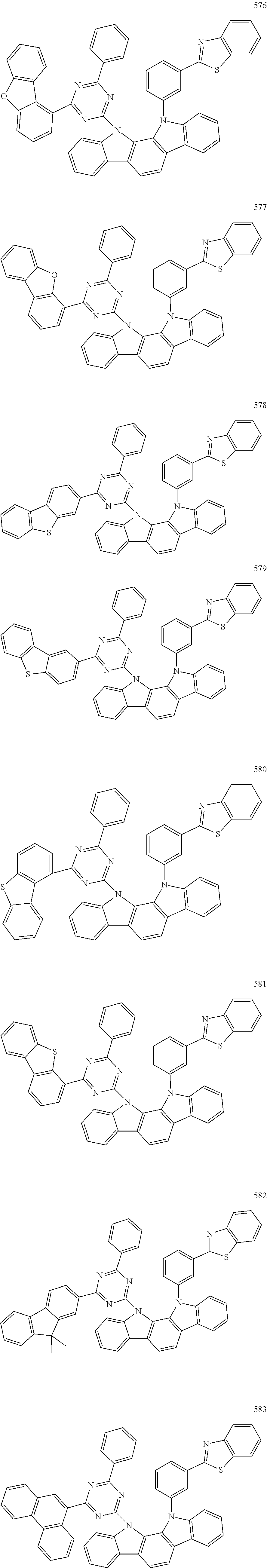

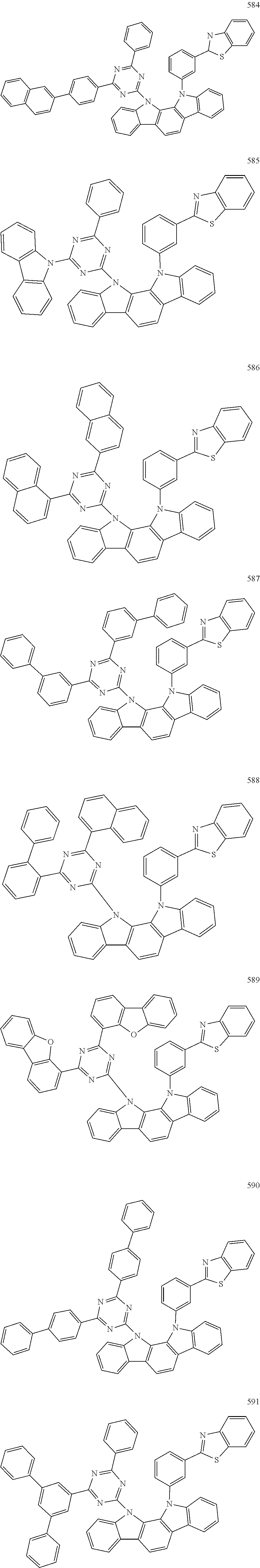

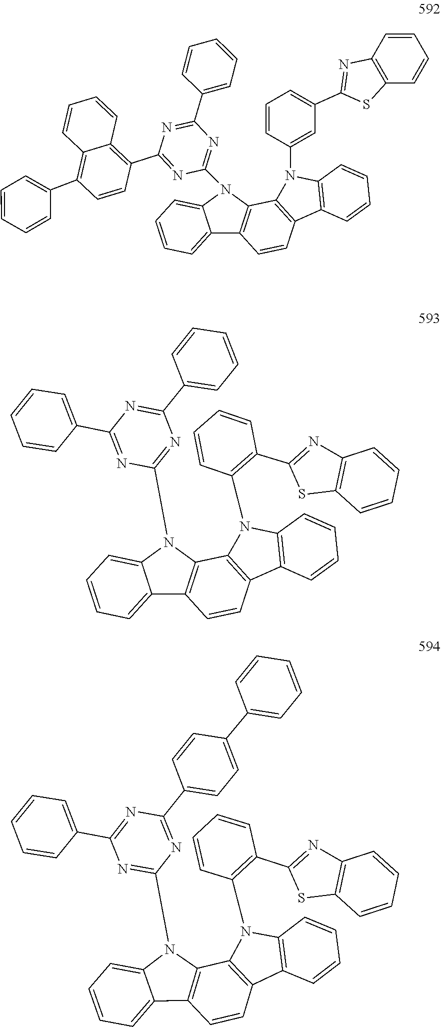 [SMILES: c1ccc(-c2nc(-c3ccc(-c4ccccc4)c4ccccc34)nc(-n3c4ccccc4c4ccc5c6ccccc6n(-c6cccc(-c7nc8ccccc8s7)c6)c5c43)n2)cc1 ; c1ccc(-c2nc(-c3ccccc3)nc(-n3c4ccccc4c4ccc5c6ccccc6n(-c6ccccc6-c6nc7ccccc7s6)c5c43)n2)cc1 ; c1ccc(-c2ccc(-c3nc(-c4ccccc4)nc(-n4c5ccccc5c5ccc6c7ccccc7n(-c7ccccc7-c7nc8ccccc8s7)c6c54)n3)cc2)cc1]

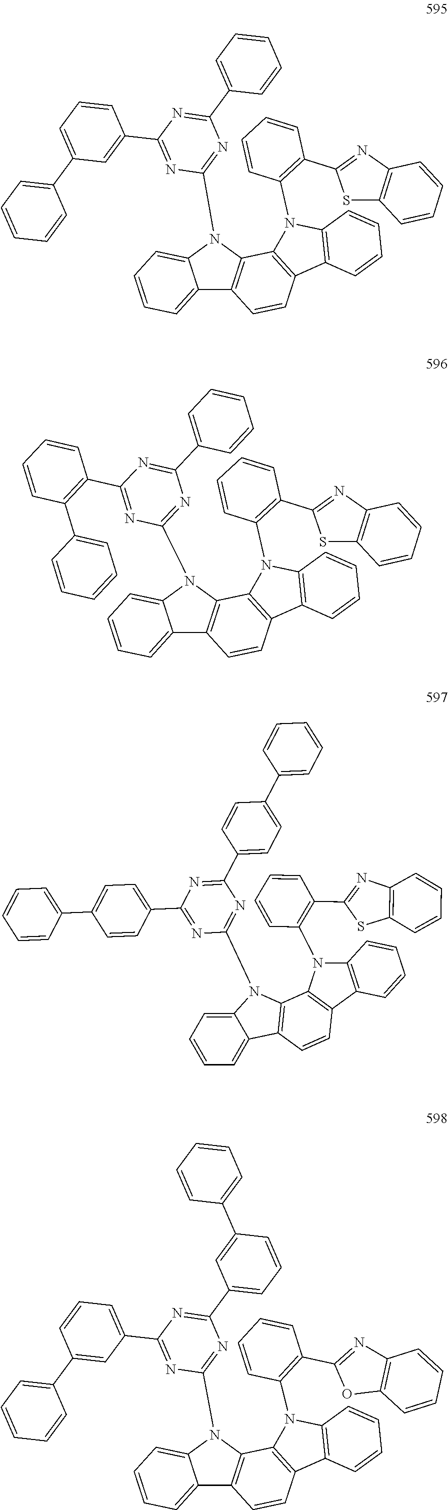 [SMILES: c1ccc(-c2cccc(-c3nc(-c4ccccc4)nc(-n4c5ccccc5c5ccc6c7ccccc7n(-c7ccccc7-c7nc8ccccc8s7)c6c54)n3)c2)cc1 ; c1ccc(-c2nc(-c3ccccc3-c3ccccc3)nc(-n3c4ccccc4c4ccc5c6ccccc6n(-c6ccccc6-c6nc7ccccc7s6)c5c43)n2)cc1 ; c1ccc(-c2ccc(-c3nc(-c4ccc(-c5ccccc5)cc4)nc(-n4c5ccccc5c5ccc6c7ccccc7n(-c7ccccc7-c7nc8ccccc8s7)c6c54)n3)cc2)cc1 ; c1ccc(-c2cccc(-c3nc(-c4cccc(-c5ccccc5)c4)nc(-n4c5ccccc5c5ccc6c7ccccc7n(-c7ccccc7-c7nc8ccccc8o7)c6c54)n3)c2)cc1]

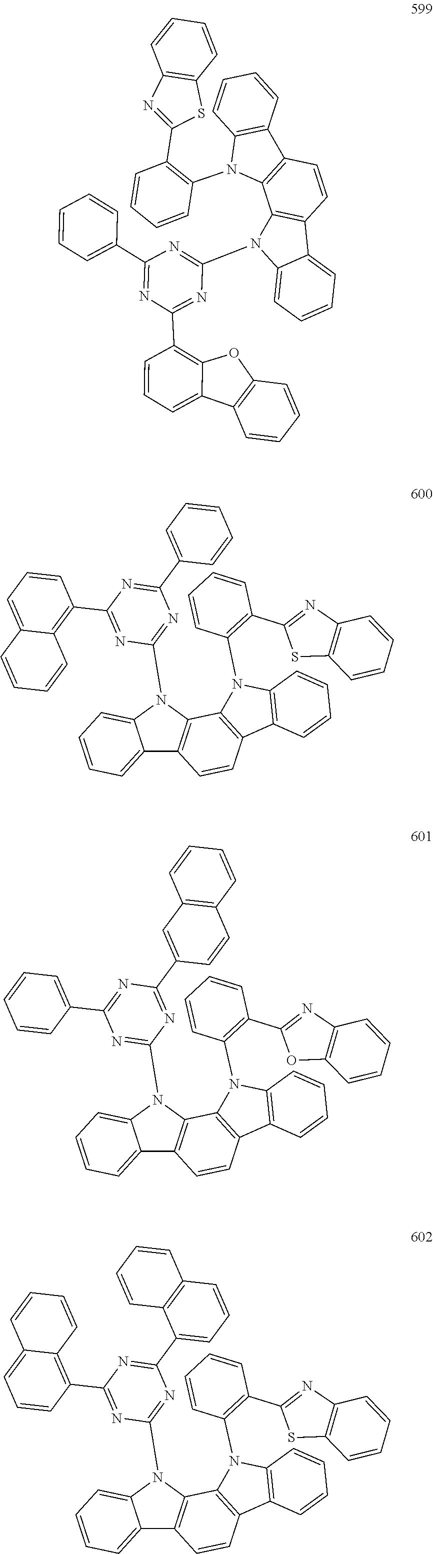 [SMILES: c1ccc(-c2nc(-c3cccc4c3oc3ccccc34)nc(-n3c4ccccc4c4ccc5c6ccccc6n(-c6ccccc6-c6nc7ccccc7s6)c5c43)n2)cc1 ; c1ccc(-c2nc(-c3cccc4ccccc34)nc(-n3c4ccccc4c4ccc5c6ccccc6n(-c6ccccc6-c6nc7ccccc7s6)c5c43)n2)cc1 ; c1ccc(-c2nc(-c3ccc4ccccc4c3)nc(-n3c4ccccc4c4ccc5c6ccccc6n(-c6ccccc6-c6nc7ccccc7o6)c5c43)n2)cc1 ; c1ccc(-n2c3ccccc3c3ccc4c5ccccc5n(-c5nc(-c6cccc7ccccc67)nc(-c6cccc7ccccc67)n5)c4c32)c(-c2nc3ccccc3s2)c1]

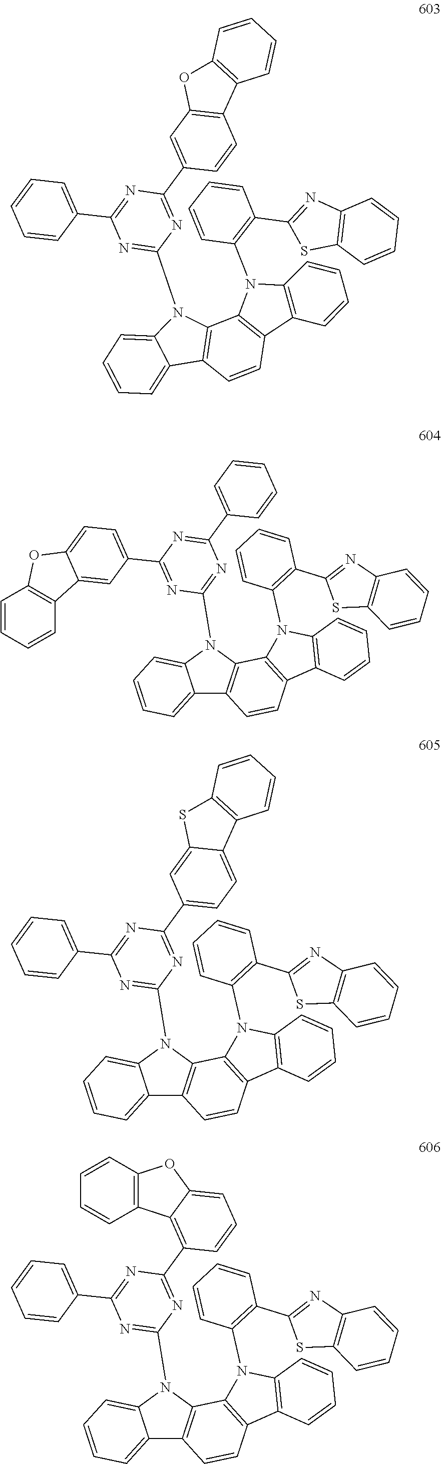

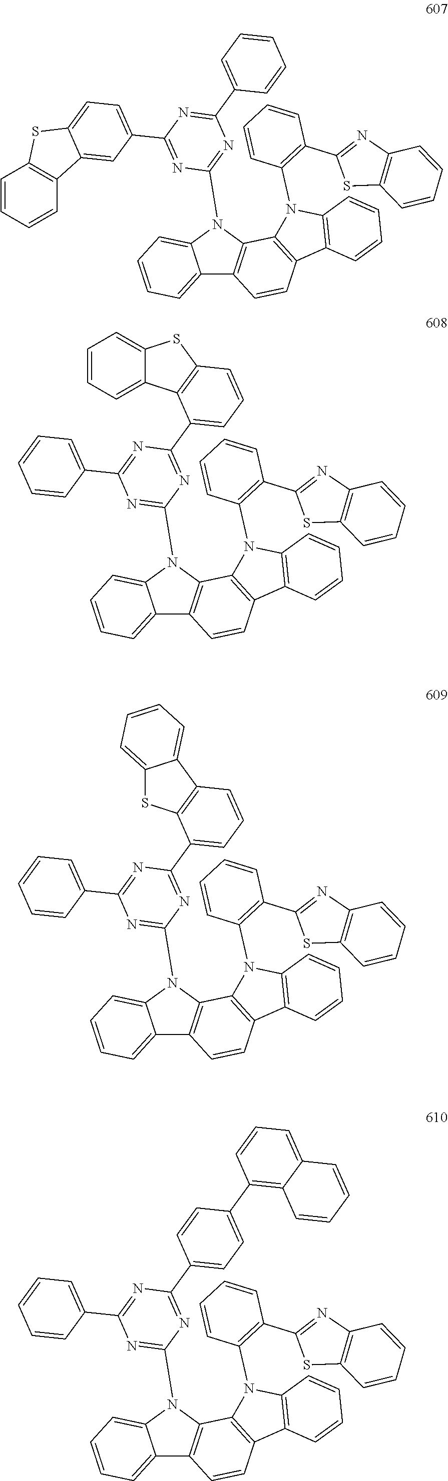

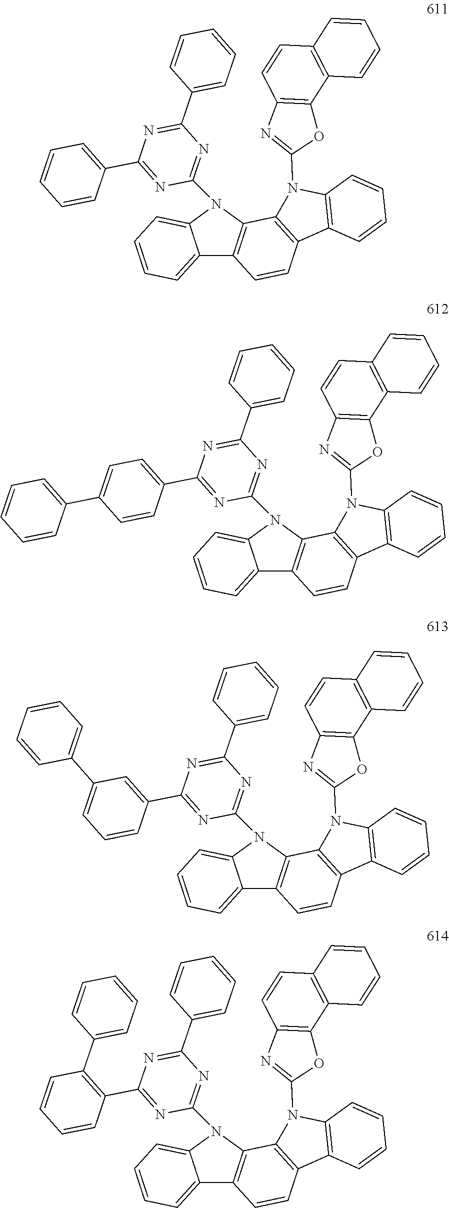

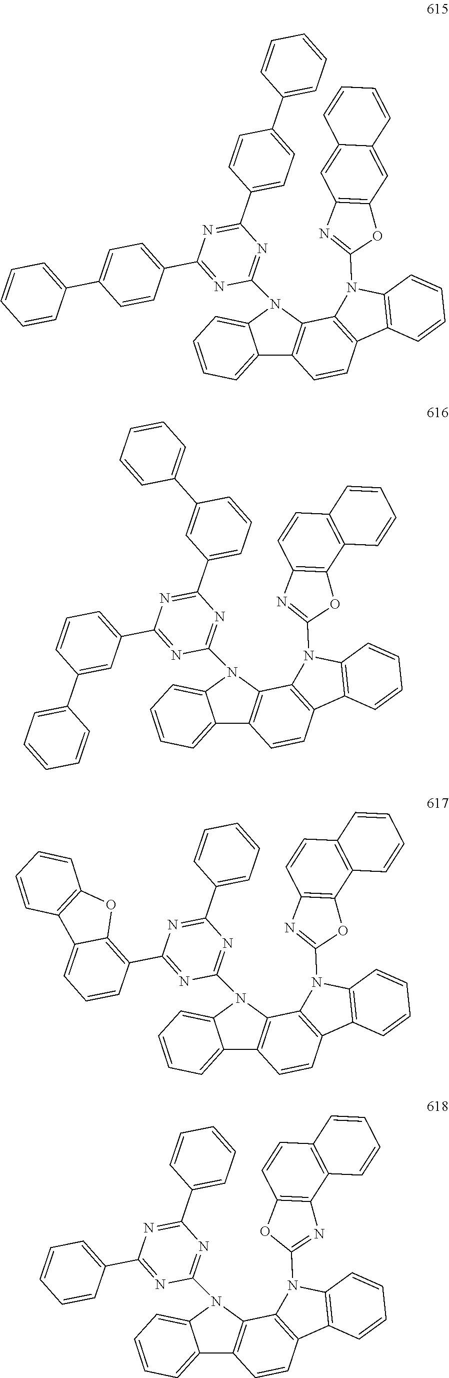 [SMILES: c1ccc(-c2ccc(-c3nc(-c4ccc(-c5ccccc5)cc4)nc(-n4c5ccccc5c5ccc6c7ccccc7n(-c7nc8cc9ccccc9cc8o7)c6c54)n3)cc2)cc1 ; c1ccc(-c2cccc(-c3nc(-c4cccc(-c5ccccc5)c4)nc(-n4c5ccccc5c5ccc6c7ccccc7n(-c7nc8ccc9ccccc9c8o7)c6c54)n3)c2)cc1 ; c1ccc(-c2nc(-c3cccc4c3oc3ccccc34)nc(-n3c4ccccc4c4ccc5c6ccccc6n(-c6nc7ccc8ccccc8c7o6)c5c43)n2)cc1 ; c1ccc(-c2nc(-c3ccccc3)nc(-n3c4ccccc4c4ccc5c6ccccc6n(-c6nc7c(ccc8ccccc87)o6)c5c43)n2)cc1]

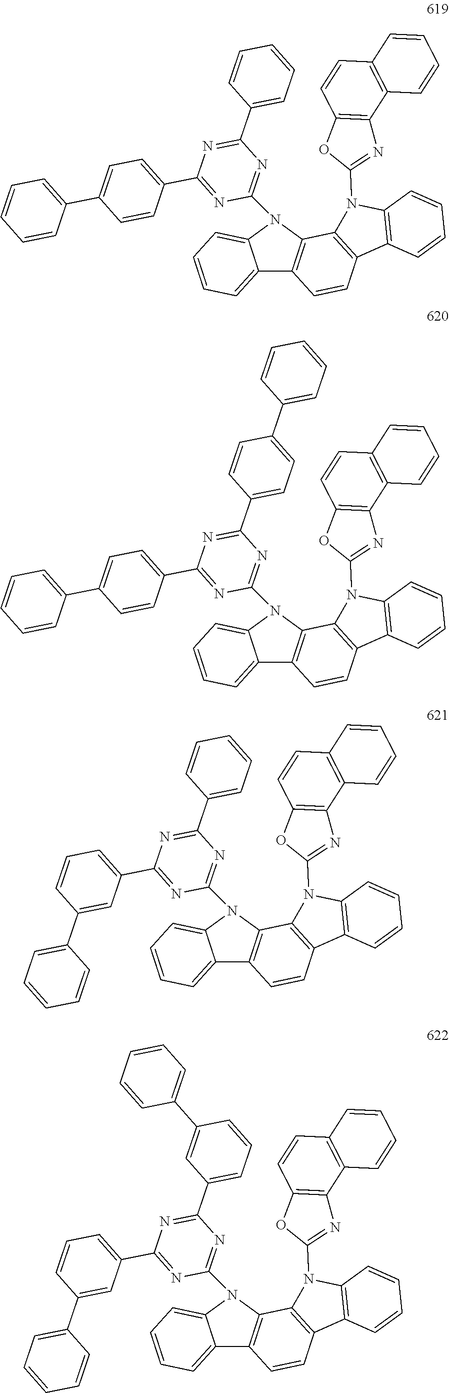

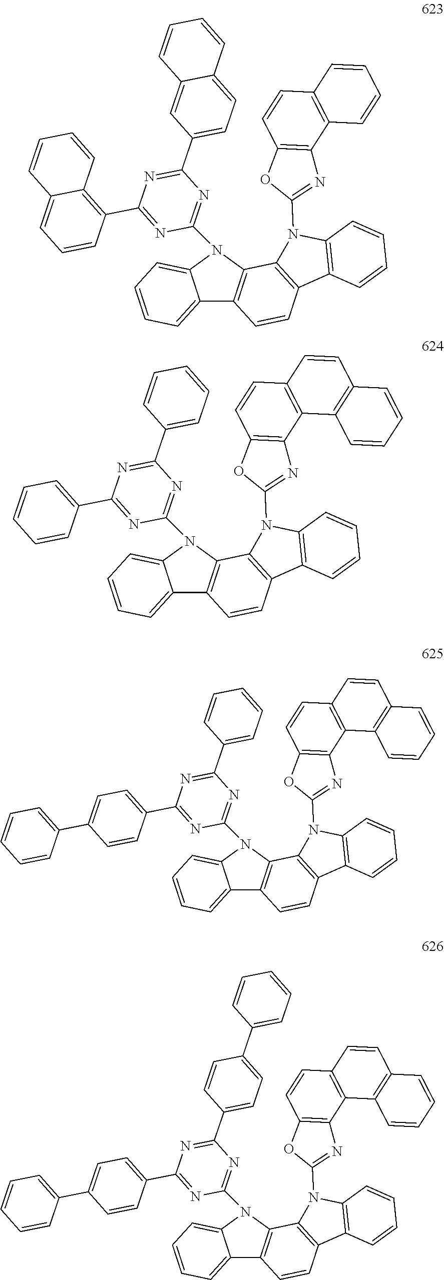

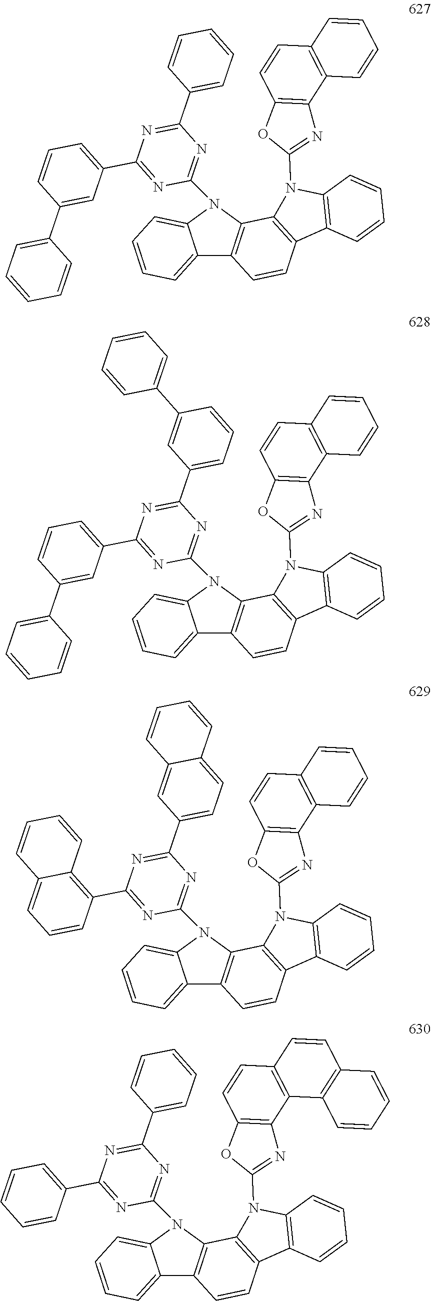

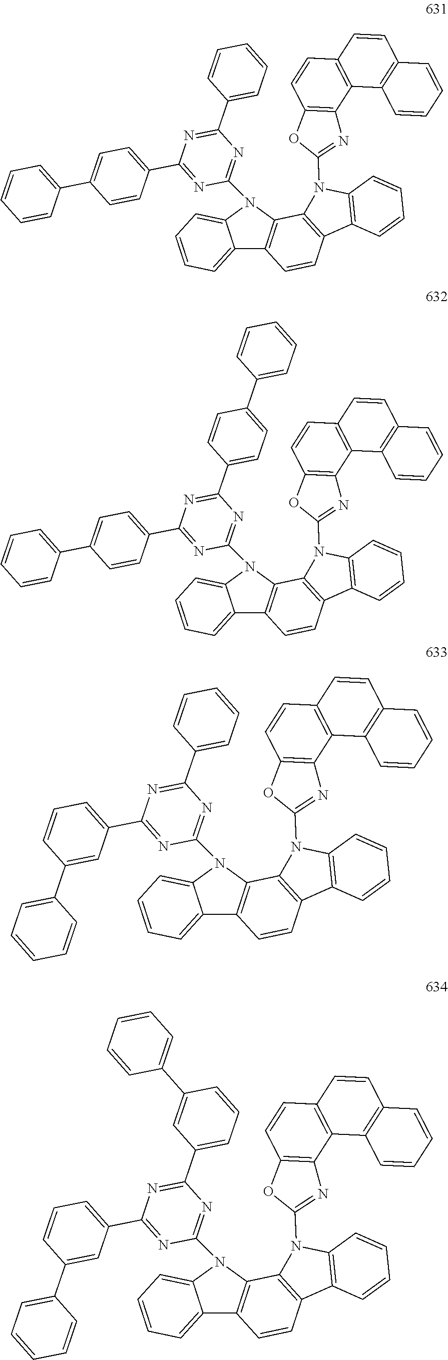 [SMILES: c1ccc(-c2ccc(-c3nc(-c4ccccc4)nc(-n4c5ccccc5c5ccc6c7ccccc7n(-c7nc8c(ccc9ccc%10ccccc%10c98)o7)c6c54)n3)cc2)cc1 ; c1ccc(-c2ccc(-c3nc(-c4ccc(-c5ccccc5)cc4)nc(-n4c5ccccc5c5ccc6c7ccccc7n(-c7nc8c(ccc9ccc%10ccccc%10c98)o7)c6c54)n3)cc2)cc1 ; c1ccc(-c2cccc(-c3nc(-c4ccccc4)nc(-n4c5ccccc5c5ccc6c7ccccc7n(-c7nc8c(ccc9ccc%10ccccc%10c98)o7)c6c54)n3)c2)cc1 ; c1ccc(-c2cccc(-c3nc(-c4cccc(-c5ccccc5)c4)nc(-n4c5ccccc5c5ccc6c7ccccc7n(-c7nc8c(ccc9ccc%10ccccc%10c98)o7)c6c54)n3)c2)cc1]

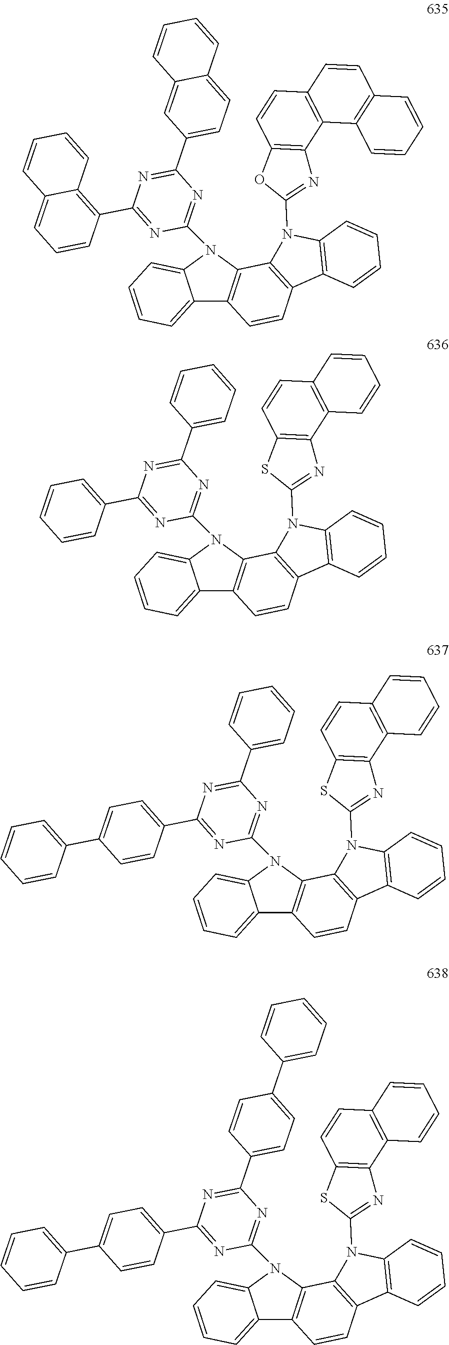

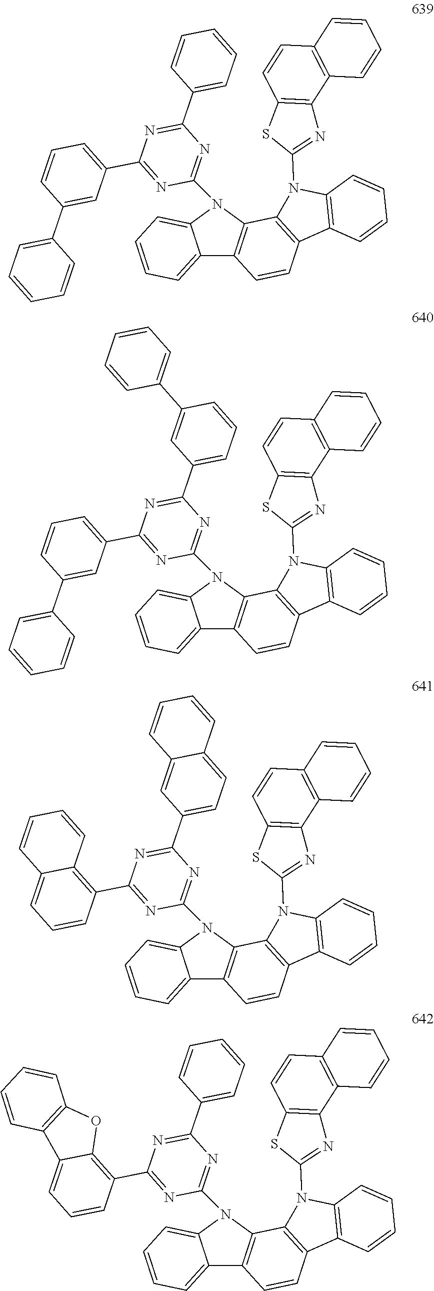

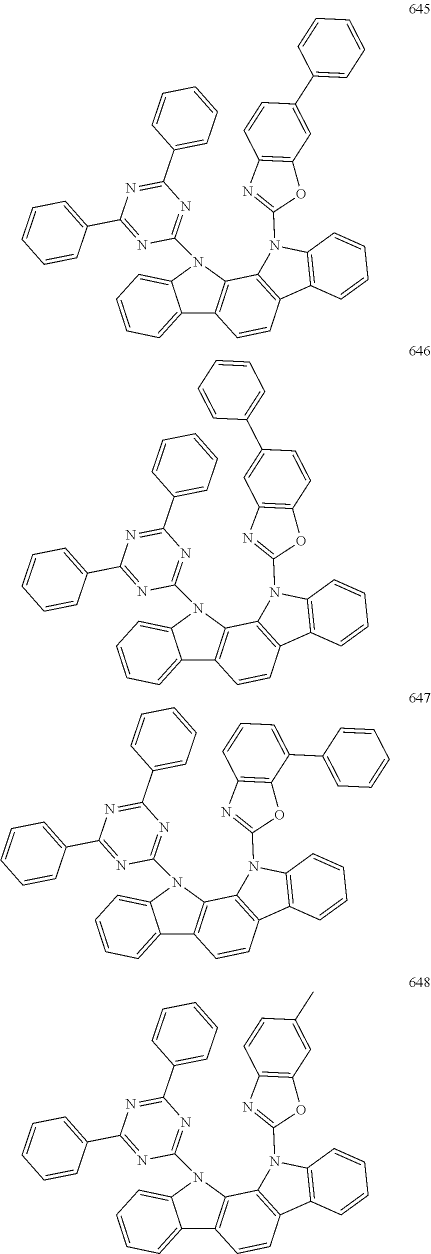

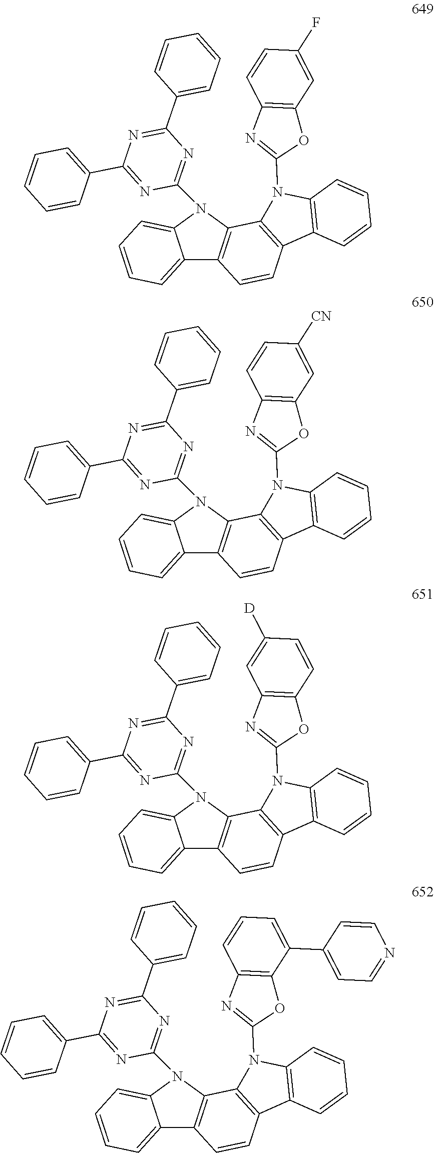

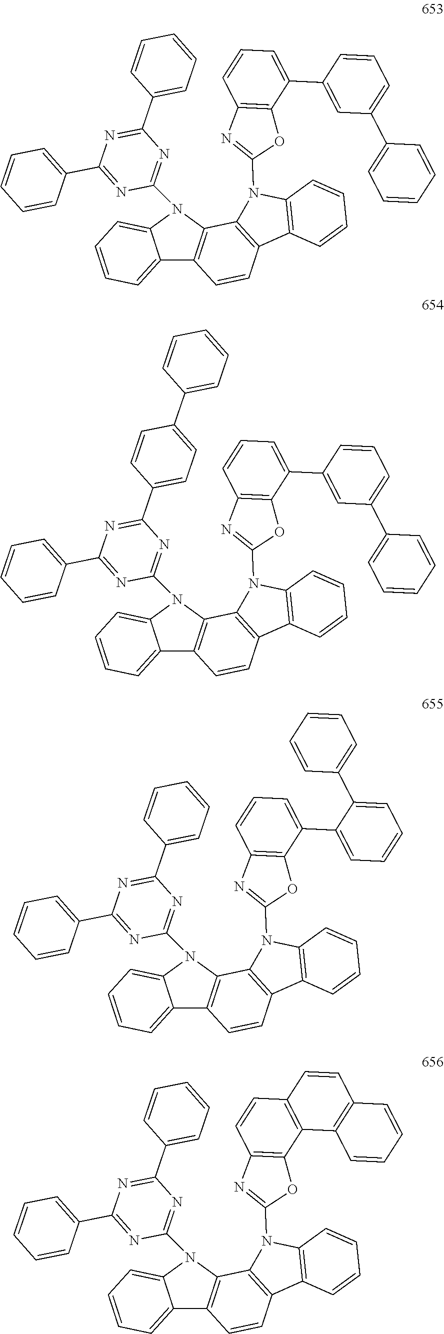

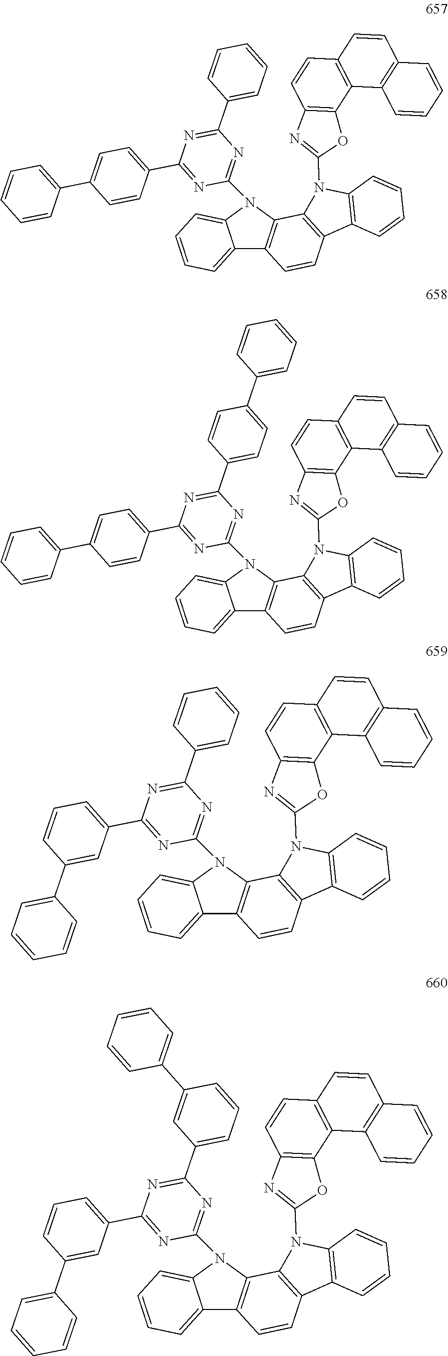 [SMILES: c1ccc(-c2ccc(-c3nc(-c4ccccc4)nc(-n4c5ccccc5c5ccc6c7ccccc7n(-c7nc8ccc9ccc%10ccccc%10c9c8o7)c6c54)n3)cc2)cc1 ; c1ccc(-c2ccc(-c3nc(-c4ccc(-c5ccccc5)cc4)nc(-n4c5ccccc5c5ccc6c7ccccc7n(-c7nc8ccc9ccc%10ccccc%10c9c8o7)c6c54)n3)cc2)cc1 ; c1ccc(-c2cccc(-c3nc(-c4ccccc4)nc(-n4c5ccccc5c5ccc6c7ccccc7n(-c7nc8ccc9ccc%10ccccc%10c9c8o7)c6c54)n3)c2)cc1 ; c1ccc(-c2cccc(-c3nc(-c4cccc(-c5ccccc5)c4)nc(-n4c5ccccc5c5ccc6c7ccccc7n(-c7nc8ccc9ccc%10ccccc%10c9c8o7)c6c54)n3)c2)cc1]

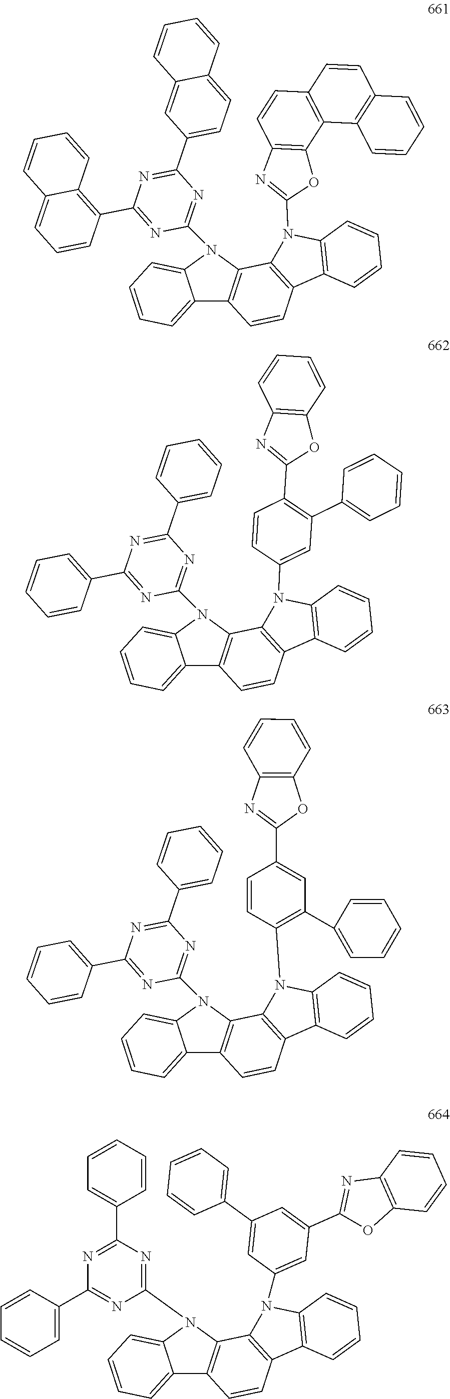

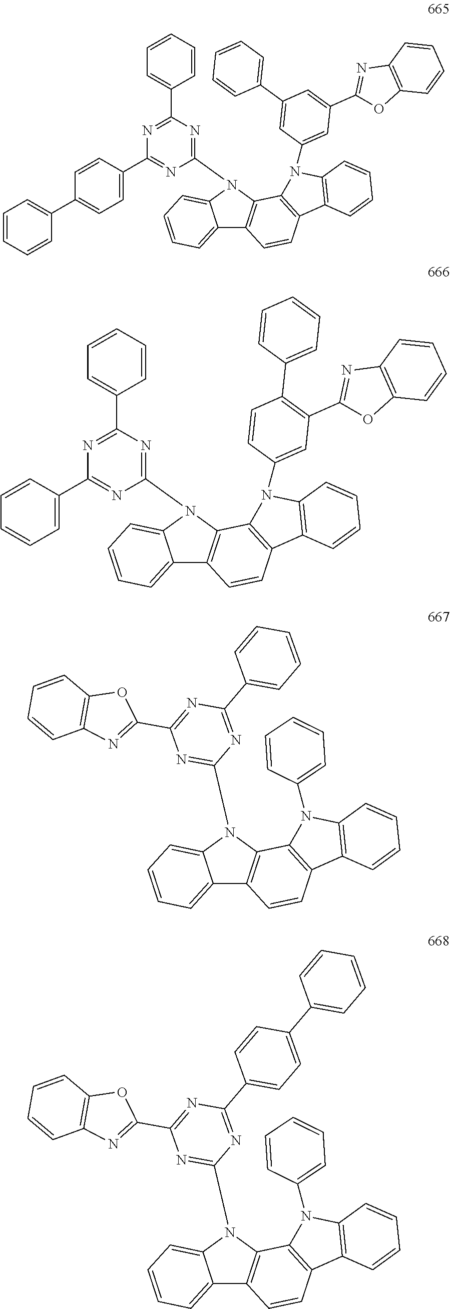

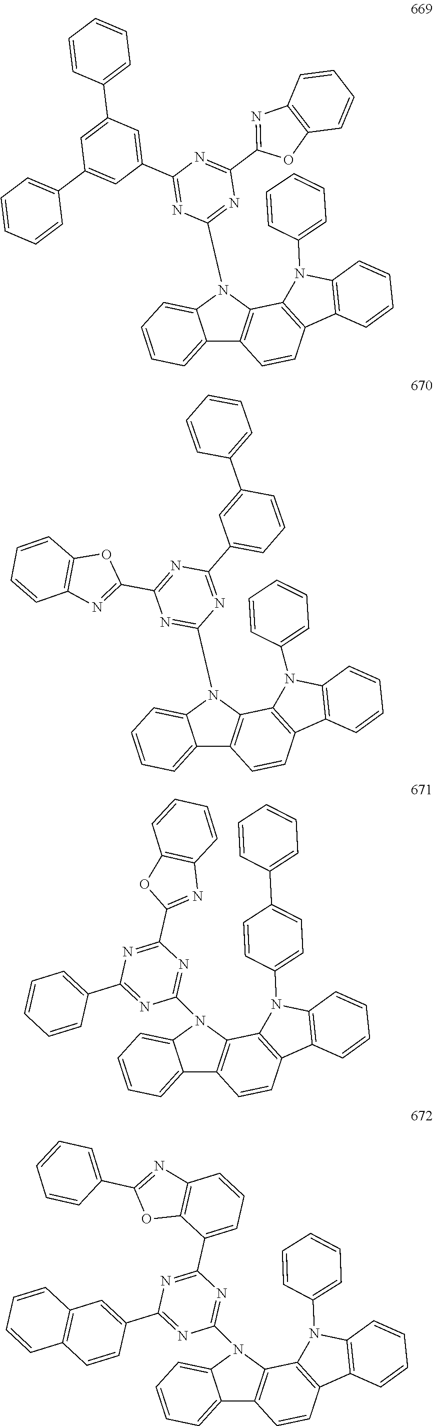

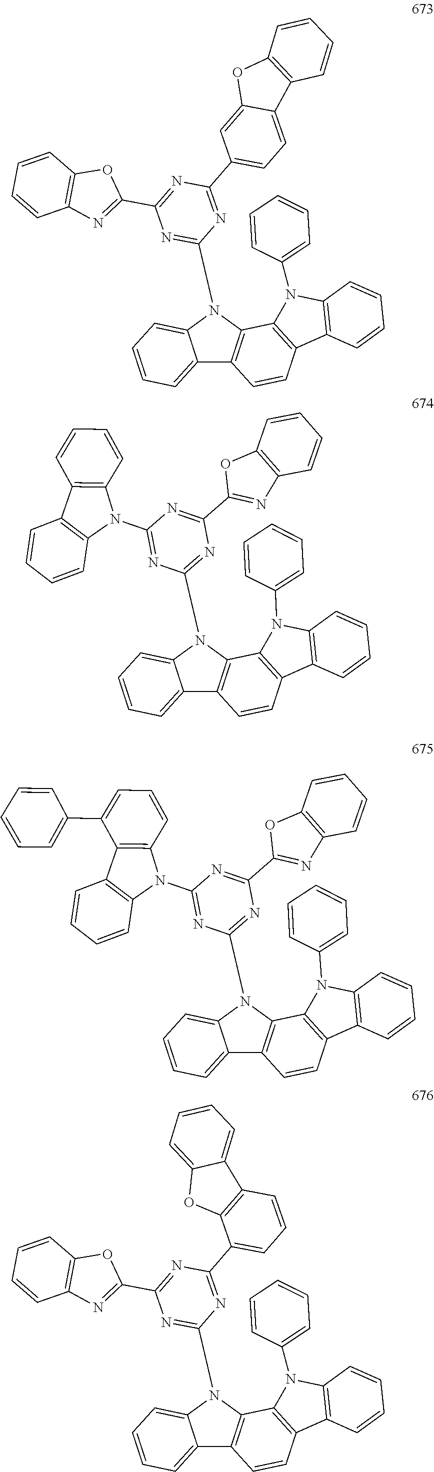

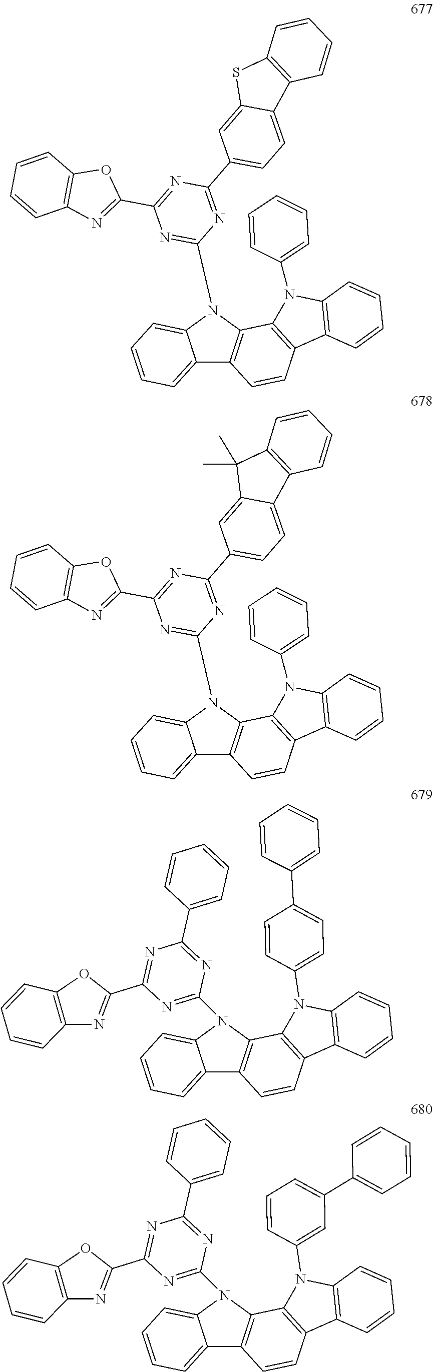

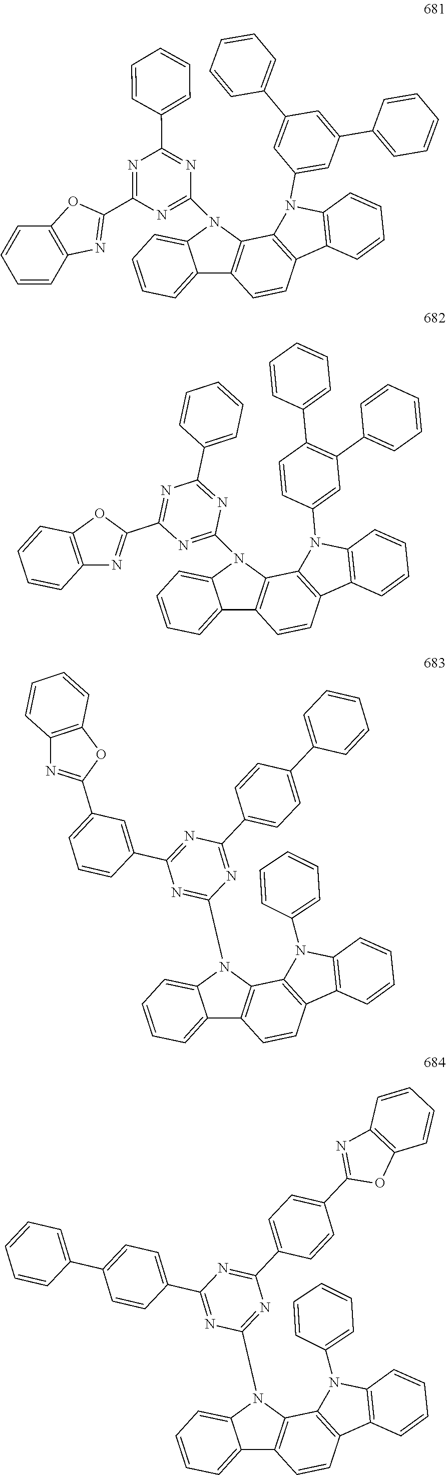 [SMILES: c1ccc(-c2cc(-c3ccccc3)cc(-n3c4ccccc4c4ccc5c6ccccc6n(-c6nc(-c7ccccc7)nc(-c7nc8ccccc8o7)n6)c5c43)c2)cc1 ; c1ccc(-c2nc(-c3nc4ccccc4o3)nc(-n3c4ccccc4c4ccc5c6ccccc6n(-c6ccc(-c7ccccc7)c(-c7ccccc7)c6)c5c43)n2)cc1 ; c1ccc(-c2ccc(-c3nc(-c4cccc(-c5nc6ccccc6o5)c4)nc(-n4c5ccccc5c5ccc6c7ccccc7n(-c7ccccc7)c6c54)n3)cc2)cc1 ; c1ccc(-c2ccc(-c3nc(-c4ccc(-c5nc6ccccc6o5)cc4)nc(-n4c5ccccc5c5ccc6c7ccccc7n(-c7ccccc7)c6c54)n3)cc2)cc1]

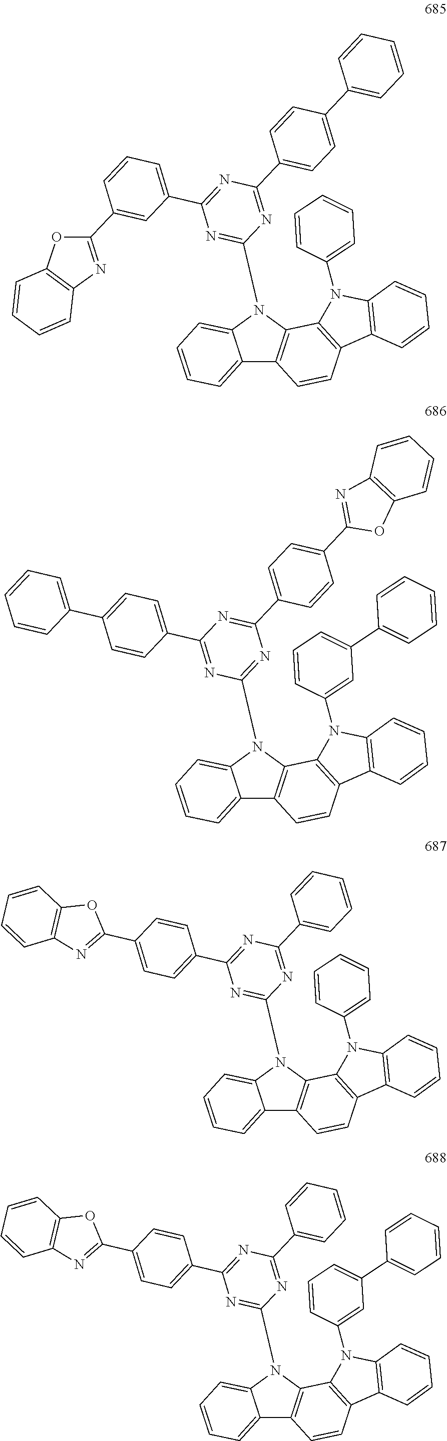 [SMILES: c1ccc(-c2ccc(-c3nc(-c4cccc(-c5nc6ccccc6o5)c4)nc(-n4c5ccccc5c5ccc6c7ccccc7n(-c7ccccc7)c6c54)n3)cc2)cc1 ; c1ccc(-c2ccc(-c3nc(-c4ccc(-c5nc6ccccc6o5)cc4)nc(-n4c5ccccc5c5ccc6c7ccccc7n(-c7cccc(-c8ccccc8)c7)c6c54)n3)cc2)cc1 ; c1ccc(-c2nc(-c3ccc(-c4nc5ccccc5o4)cc3)nc(-n3c4ccccc4c4ccc5c6ccccc6n(-c6ccccc6)c5c43)n2)cc1 ; c1ccc(-c2cccc(-n3c4ccccc4c4ccc5c6ccccc6n(-c6nc(-c7ccccc7)nc(-c7ccc(-c8nc9ccccc9o8)cc7)n6)c5c43)c2)cc1]

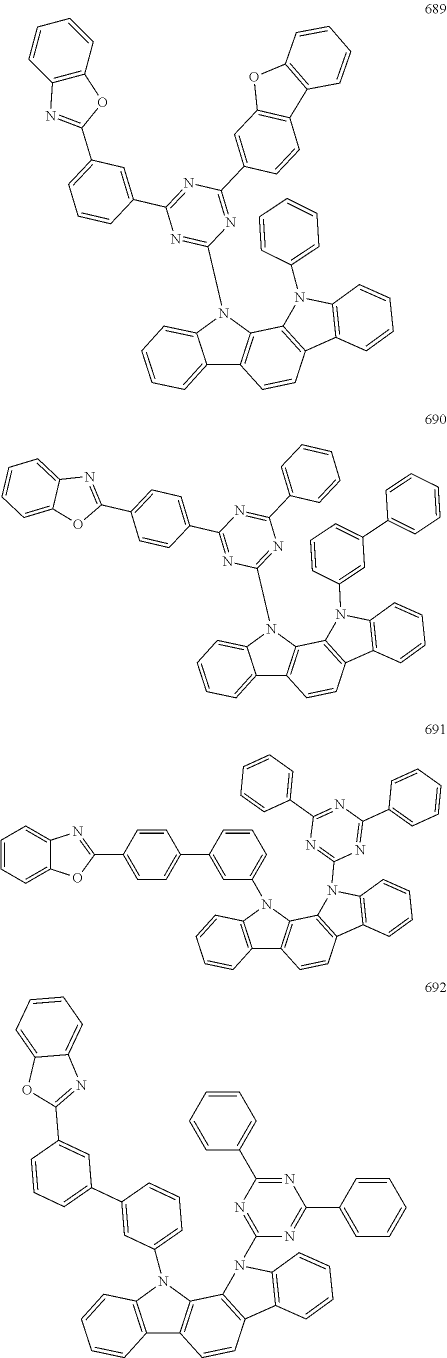 [SMILES: c1ccc(-n2c3ccccc3c3ccc4c5ccccc5n(-c5nc(-c6cccc(-c7nc8ccccc8o7)c6)nc(-c6ccc7c(c6)oc6ccccc67)n5)c4c32)cc1 ; c1ccc(-c2cccc(-n3c4ccccc4c4ccc5c6ccccc6n(-c6nc(-c7ccccc7)nc(-c7ccc(-c8nc9ccccc9o8)cc7)n6)c5c43)c2)cc1 ; c1ccc(-c2nc(-c3ccccc3)nc(-n3c4ccccc4c4ccc5c6ccccc6n(-c6cccc(-c7ccc(-c8nc9ccccc9o8)cc7)c6)c5c43)n2)cc1 ; c1ccc(-c2nc(-c3ccccc3)nc(-n3c4ccccc4c4ccc5c6ccccc6n(-c6cccc(-c7cccc(-c8nc9ccccc9o8)c7)c6)c5c43)n2)cc1]

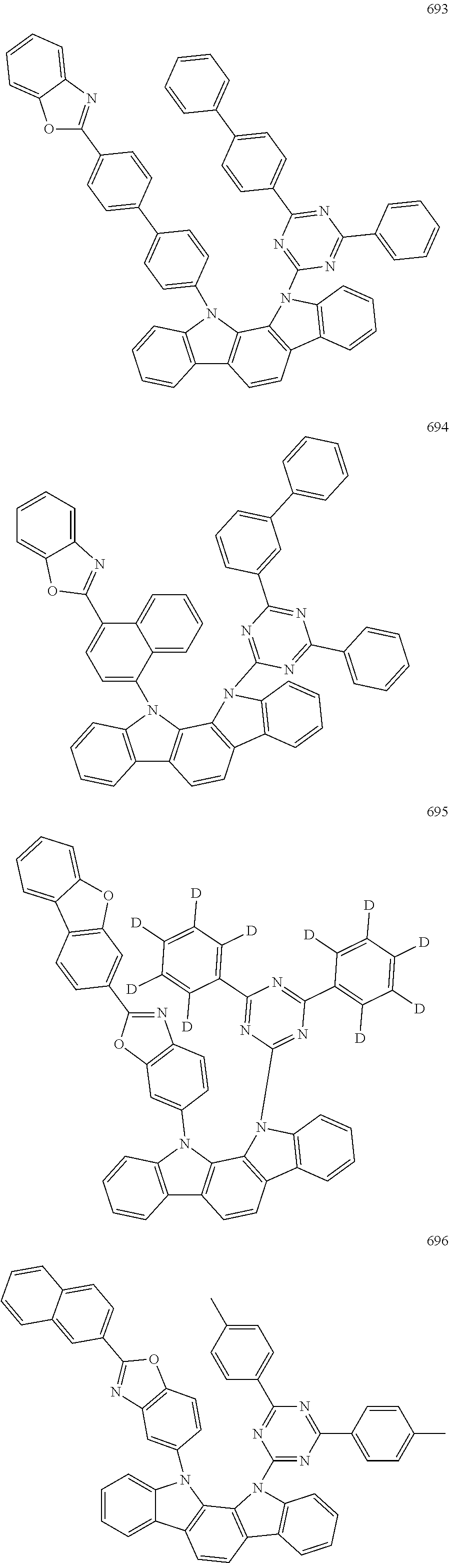 [SMILES: c1ccc(-c2ccc(-c3nc(-c4ccccc4)nc(-n4c5ccccc5c5ccc6c7ccccc7n(-c7ccc(-c8ccc(-c9nc%10ccccc%10o9)cc8)cc7)c6c54)n3)cc2)cc1 ; c1ccc(-c2cccc(-c3nc(-c4ccccc4)nc(-n4c5ccccc5c5ccc6c7ccccc7n(-c7ccc(-c8nc9ccccc9o8)c8ccccc78)c6c54)n3)c2)cc1 ; [2H]c1c([2H])c([2H])c(-c2nc(-c3c([2H])c([2H])c([2H])c([2H])c3[2H])nc(-n3c4ccccc4c4ccc5c6ccccc6n(-c6ccc7nc(-c8ccc9c(c8)oc8ccccc89)oc7c6)c5c43)n2)c([2H])c1[2H] ; Cc1ccc(-c2nc(-c3ccc(C)cc3)nc(-n3c4ccccc4c4ccc5c6ccccc6n(-c6ccc7oc(-c8ccc9ccccc9c8)nc7c6)c5c43)n2)cc1]

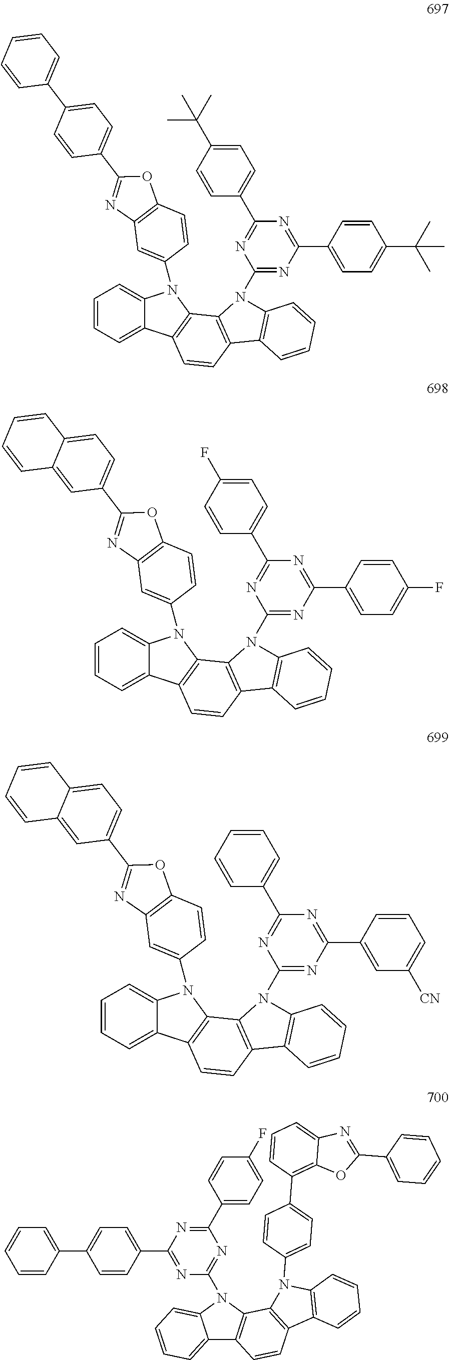 [SMILES: CC(C)(C)c1ccc(-c2nc(-c3ccc(C(C)(C)C)cc3)nc(-n3c4ccccc4c4ccc5c6ccccc6n(-c6ccc7oc(-c8ccc(-c9ccccc9)cc8)nc7c6)c5c43)n2)cc1 ; Fc1ccc(-c2nc(-c3ccc(F)cc3)nc(-n3c4ccccc4c4ccc5c6ccccc6n(-c6ccc7oc(-c8ccc9ccccc9c8)nc7c6)c5c43)n2)cc1 ; N#Cc1cccc(-c2nc(-c3ccccc3)nc(-n3c4ccccc4c4ccc5c6ccccc6n(-c6ccc7oc(-c8ccc9ccccc9c8)nc7c6)c5c43)n2)c1 ; Fc1ccc(-c2nc(-c3ccc(-c4ccccc4)cc3)nc(-n3c4ccccc4c4ccc5c6ccccc6n(-c6ccc(-c7cccc8nc(-c9ccccc9)oc78)cc6)c5c43)n2)cc1]

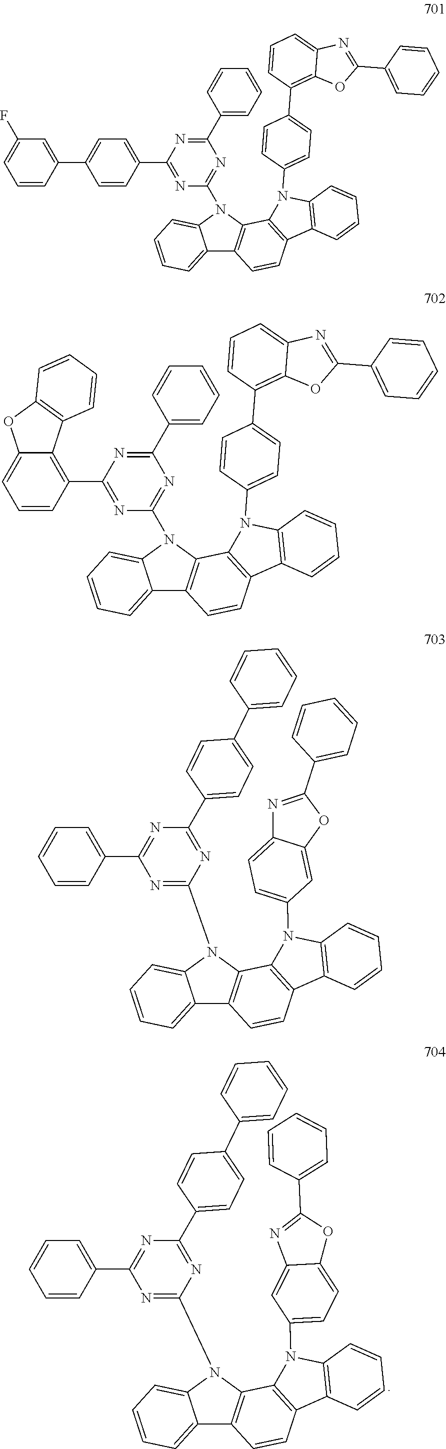

19. The composition for an organic optoelectronic device of claim 1, consisting of the first compound and the second compound, wherein based on the total weight of the composition, the mass percentage of the first compound is 20% to 80%, and the mass percentage of the second compound is 20% to 80%;
alternatively, the mass percentage of the first compound is 40% to 60%, and the mass percentage of the second compound is 40% to 60%.

20. An electronic component, comprising an anode, a cathode, and at least one functional layer between the anode and the cathode, wherein the functional layer comprises the composition of claim 1; or
alternatively, the functional layer comprises an organic electroluminescent layer, and the organic electroluminescent layer comprises the composition.

21. The electronic element of claim 20, wherein the electronic component is an organic electroluminescent device;
alternatively, the organic electroluminescent device is a green organic electroluminescent device.

22. An electronic device, comprising the electronic component of claim 20.
